(19) United States
(12) Patent Application Publication
(10) Pub. No.: US 2023/0329025 A1
(43) Pub. Date: Oct. 12, 2023

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Hiroaki ITOI, Tokyo (JP); Yusuke TAKAHASHI, Tokyo (JP); Shota TANAKA, Tokyo (JP); Takuto FUKAMI, Tokyo (JP); Tsukasa SAWATO, Tokyo (JP)

(73) Assignee: IDEMITSU KOSAN CO.,LTD., Tokyo (JP)

(21) Appl. No.: 18/120,882

(22) Filed: Mar. 13, 2023

(30) Foreign Application Priority Data
Apr. 8, 2022 (JP) 2022-064542

(51) Int. Cl. H10K 50/11; H10K 50/15; H10K 85/60

(52) U.S. Cl. CPC H10K 50/11; H10K 50/156; H10K 85/615; H10K 85/633; H10K 85/653; H10K 85/654

(57) ABSTRACT

An organic electroluminescence device includes: an emitting zone provided between an anode and a cathode; and a hole transporting zone provided between the anode and the emitting zone. The emitting zone includes at least one emitting layer, and a first host material, a second host material, and an emitting compound are contained in a single emitting layer included in the at least one emitting layer. The first host material and the second host material are each independently a compound represented by a formula (1). The first host material and the second host material are mutually different. At least one organic layer included in the hole transporting zone contains a third compound represented by a formula (EB1).

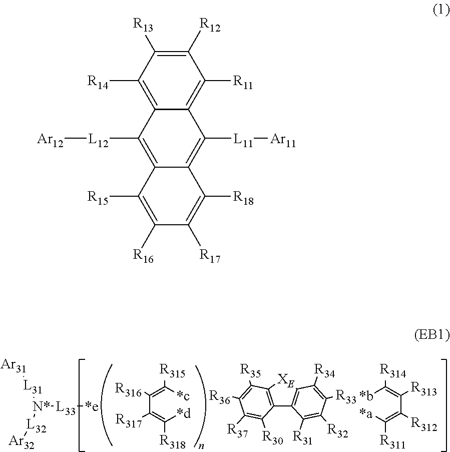

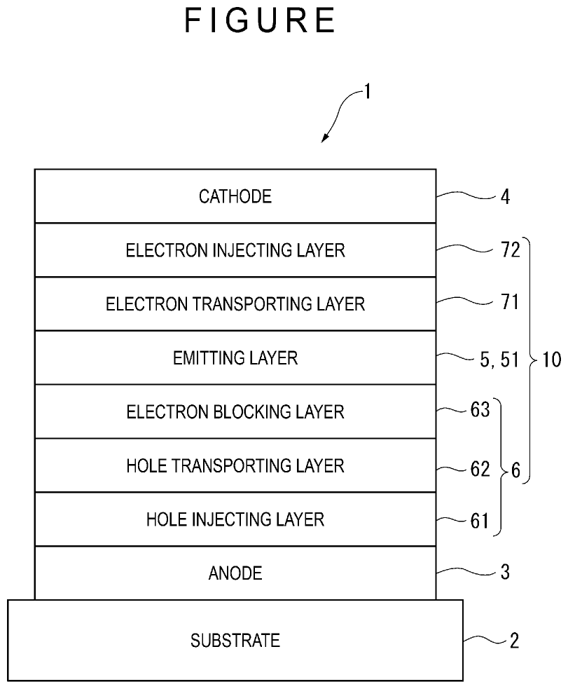

The entire disclosure of Japanese Patent Application No. 2022-064542, filed Apr. 8, 2022, is expressly incorporated by reference herein.

### TECHNICAL FIELD

The present invention relates to an organic electroluminescence device and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

The performance of the organic EL device is evaluable in terms of, for instance, luminance, emission wavelength, chromaticity, luminous efficiency, drive voltage, and lifetime. For instance, in Patent Literature 1 (International Publication No. WO 2022/009999) and Patent Literature 2 (International Publication No. WO 2021/132651), a material and device arrangement used for the organic EL device are studied to improve the performance of the organic EL device.

### SUMMARY OF THE INVENTION

An object of the invention is to provide an organic electroluminescence device capable of reducing drive voltage and having a long lifetime, and an electronic device including the organic electroluminescence device.

According to an aspect of the invention, there is provided an organic electroluminescence device including: an anode; a cathode; an emitting zone provided between the anode and the cathode; and a hole transporting zone provided between the anode and the emitting zone, in which the emitting zone includes at least one emitting layer, a first host material, a second host material, and an emitting compound being contained in a single emitting layer included in the at least one emitting layer, the first host material and the second host material are each independently a compound represented by a formula (1) below, the first host material and the second host material are mutually different, the hole transporting zone includes one or more organic layers, and at least one of the organic layers contains a third compound represented by a formula (EB1) below.

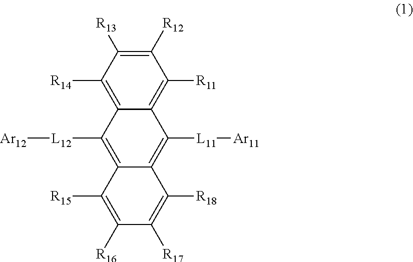

In the formula (1):
R₁₁ to R₁₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 5 to 50 ring carbon atoms, or a substituted or unsubstituted heterocyclic group having 5 to 50 ring atoms;
L₁₁ and L₁₂ are each independently a single bond, a substituted or unsubstituted arylene group having 6 to 50 ring carbon atoms, or a substituted or unsubstituted divalent heterocyclic group having 5 to 50 ring atoms; and
Ar₁₁ and Ar₁₂ are each independently a substituted or unsubstituted aryl group having 6 to 50 ring carbon atoms, or a substituted or unsubstituted heterocyclic group having 5 to 50 ring atoms.

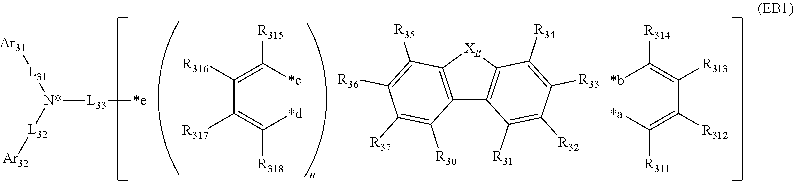

In the formula (EB1):
N* is a central nitrogen atom;
R₃₁ to R₃₈ and R₃₁₁ to R₃₁₈ are each independently a hydrogen atom, a halogen atom, a cyano group, a nitro group, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms;
n is 0 or 1
when n is 0,
one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b;
one selected from R₃₁ to R₃₄ being neither the single bond with *a nor the single bond with *b, R₃₅ to R₃₈, and R₃₁₁ to R₃₁₄ is a single bond with *e;
when n is 1,
one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b;
one of R₃₅ and R₃₆, one of R₃₆ and R₃₇, or one of R₃₇ and R₃₈ is a single bond with *c, and the other of R₃₅ and R₃₆, the other of R₃₆ and R₃₇, or the other of R₃₇ and R₃₈ is a single bond with *d;
one selected from R₃₁ to R₃₄ being neither the single bond with *a nor the single bond with *b, R₃₅ to R₃₈ being neither the single bond with *c nor the single bond with *d, R₃₁₁ to R₃₁₄, and R₃₁₅ to R₃₁₈ is a single bond with *e;
X_{E} is an oxygen atom or a sulfur atom;
Ar₃₁ and Ar₃₂ are each independently a substituted or unsubstituted aryl group having 6 to 30 ring carbon atoms, or a substituted or unsubstituted heterocyclic group having 5 to 30 ring atoms; and
L₃₁ to L₃₃ are each independently a single bond, a substituted or unsubstituted arylene group having 6 to 30 ring carbon atoms, or a substituted or unsubstituted divalent heterocyclic group having 5 to 30 ring atoms.

In the first host material, the second host material, and the third compound, R₉₀₁, R₉₀₂, R₉₀₃, R₉₀₄, R₉₀₅, R₉₀₆, R₉₀₇, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

According to another aspect of the invention, there is provided an electronic device including the organic electroluminescence device according to the aspect of the invention.

According to the aspect of the invention, there can be provided an organic electroluminescence device capable of reducing drive voltage and having a long lifetime. According to the aspect of the invention, there can be provided an electronic device including the organic electroluminescence device.

### BRIEF DESCRIPTION OF DRAWING(S)

The FIGURE schematically shows an exemplary arrangement of an organic electroluminescence device according to a first exemplary embodiment.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, cross-linking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless otherwise specified, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent are not counted as the pyridine ring atoms. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituent Mentioned Herein

Substituent mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). Herein, an unsubstituted aryl group refers to an “unsubstituted aryl group” in a “substituted or unsubstituted aryl group,” and a substituted aryl group refers to a “substituted aryl group” in a “substituted or unsubstituted aryl group.” A simply termed “aryl group” herein includes both of an “unsubstituted aryl group” and a “substituted aryl group.”

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

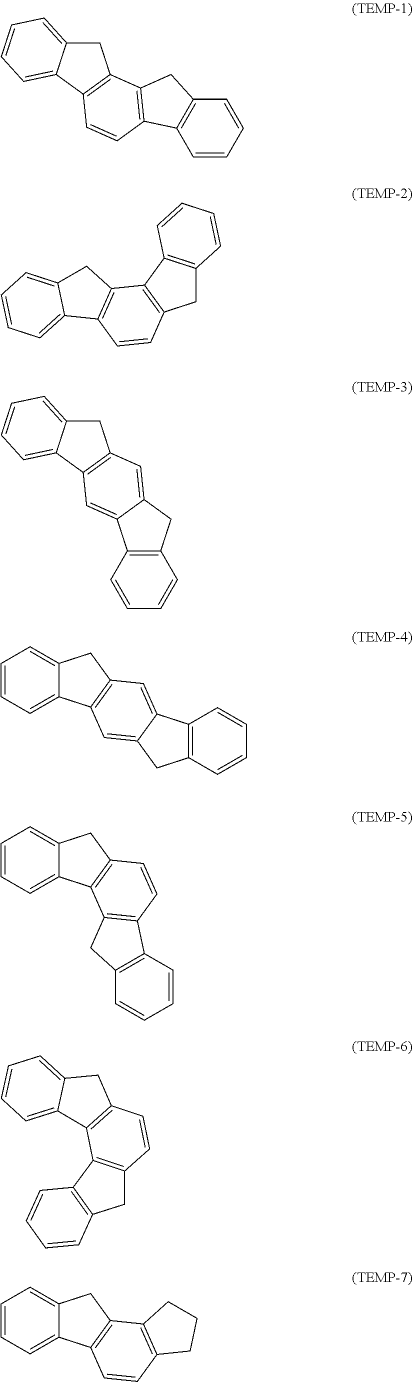

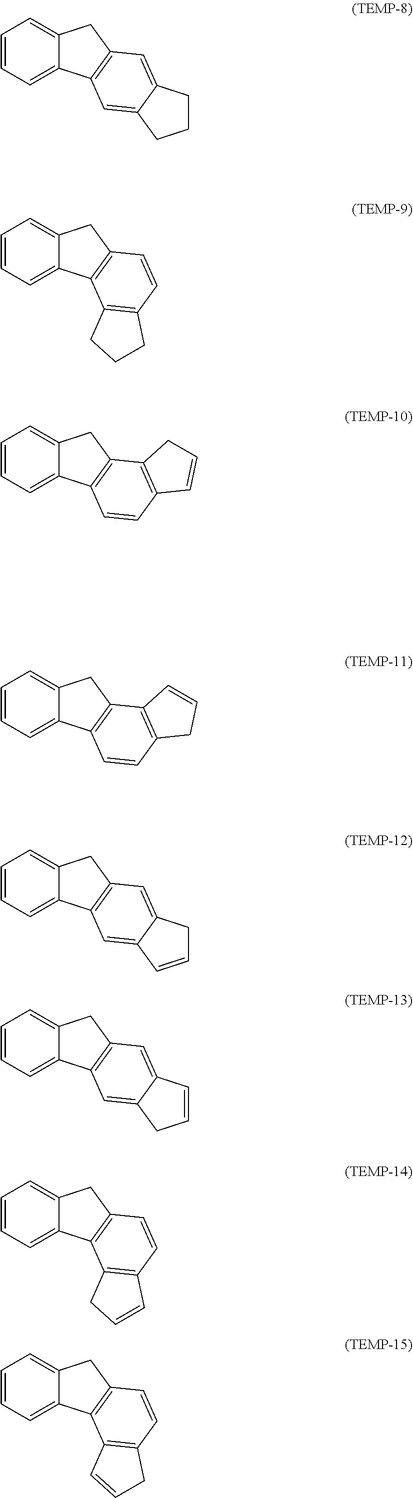

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethyl phenyl group, 9,9-dimethylfluorenyl group, 9,9-diphenylfluorenyl group, 9,9-bis(4-methyl phenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G28). Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.” A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G28 below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G28 below, and a group derived by further substituting a hydrogen atom of a substituent of the “substituted heterocyclic group” in the specific example group G28 below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G28 includes, for instance, substituted heterocyclic groups including a nitrogen atom (specific example group G281) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

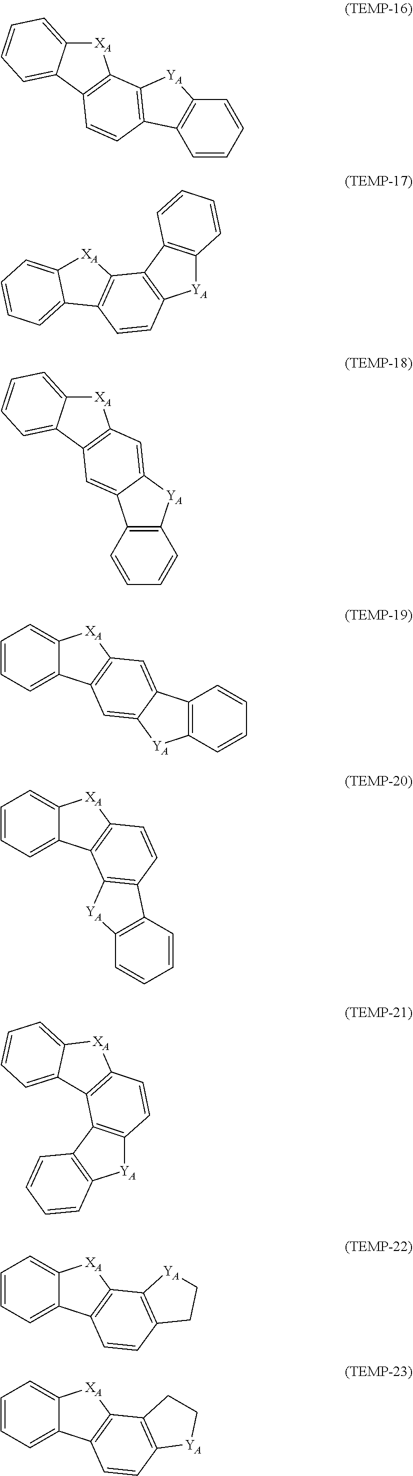

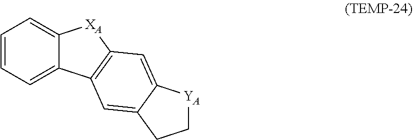

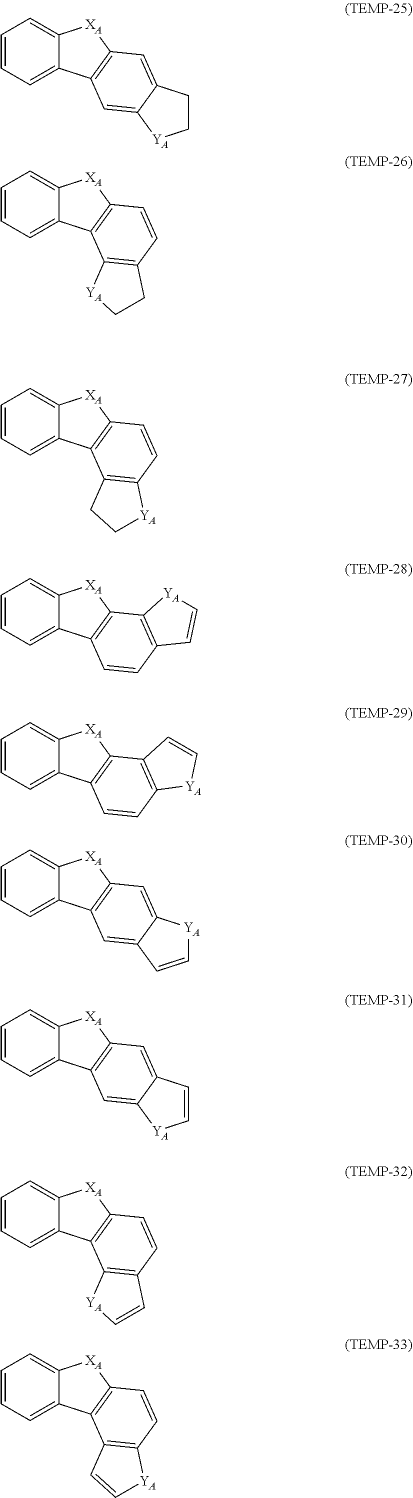

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B31):

(9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G282):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G283):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.” A simply termed “alkyl group” herein includes both of an “unsubstituted alkyl group” and a “substituted alkyl group.”

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.” A simply termed “alkenyl group” herein includes both of an “unsubstituted alkenyl group” and a “substituted alkenyl group.”

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. Herein, an unsubstituted alkynyl group refers to an “unsubstituted alkynyl group” in a “substituted or unsubstituted alkynyl group.” A simply termed “alkynyl group” herein includes both of “unsubstituted alkynyl group” and “substituted alkynyl group.”

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.” A simply termed “cycloalkyl group” herein includes both of “unsubstituted cycloalkyl group” and “substituted cycloalkyl group.”

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include: —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different. Group Represented by —O—(R₉₀₄)

Specific examples (specific example group G8) of a group represented by —O—(R₉₀₄) herein include: —O(G1); —O(G2); —O(G3); and —O(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “substituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “substituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 13 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1 An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. The plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-p-naphthylethyl group, 2-p-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

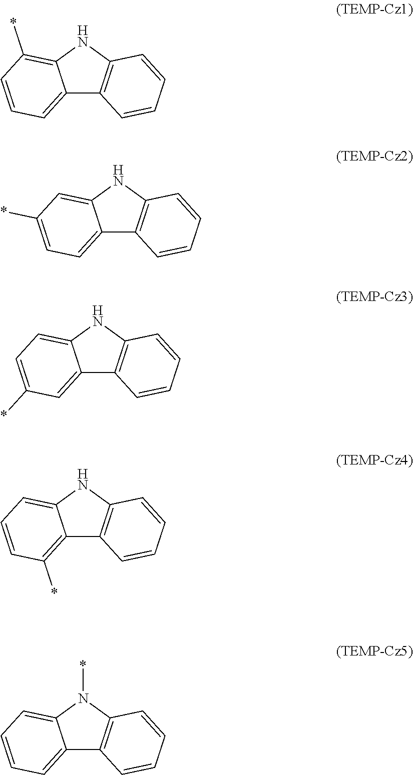 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

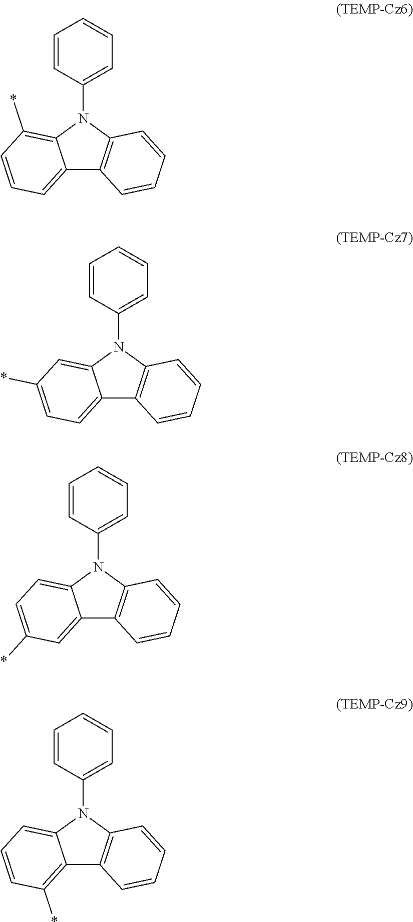 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

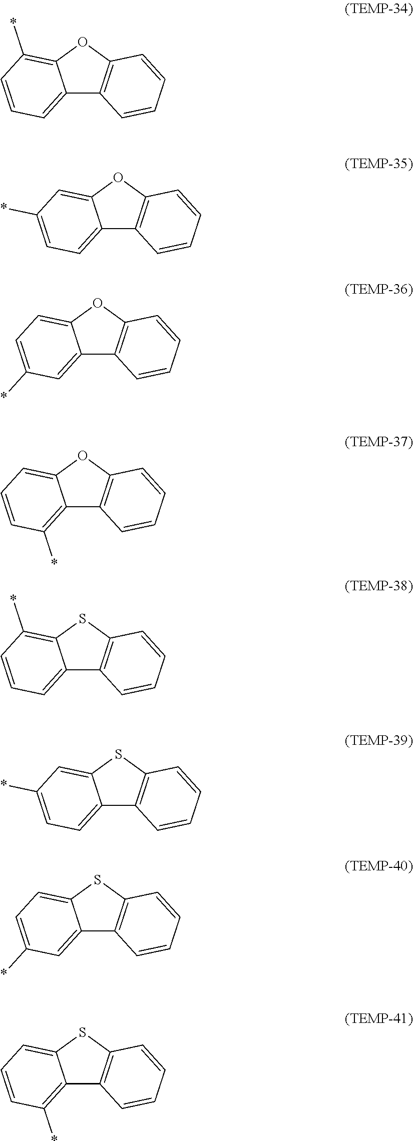

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

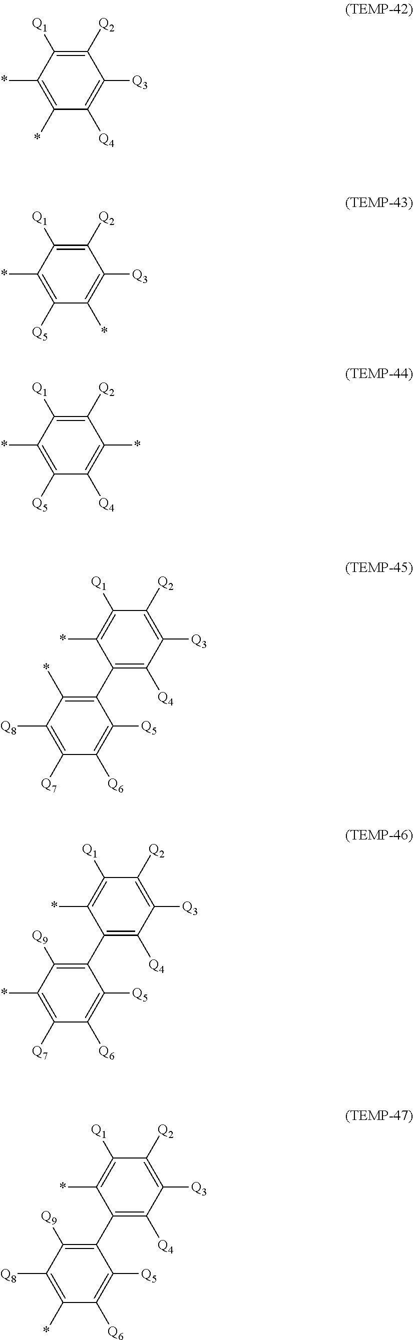

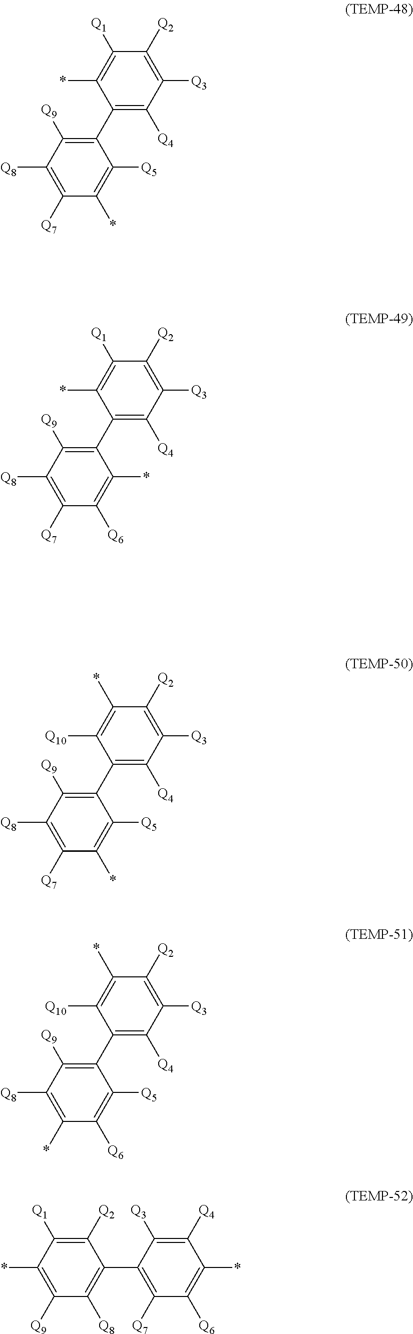

In the formulae (TEMP-42) to (TEMP-52), Q₁ to Q₁₀ are each independently a hydrogen atom or a substituent.

In the formulae (TEMP-42) to (TEMP-52), * represents a bonding position.

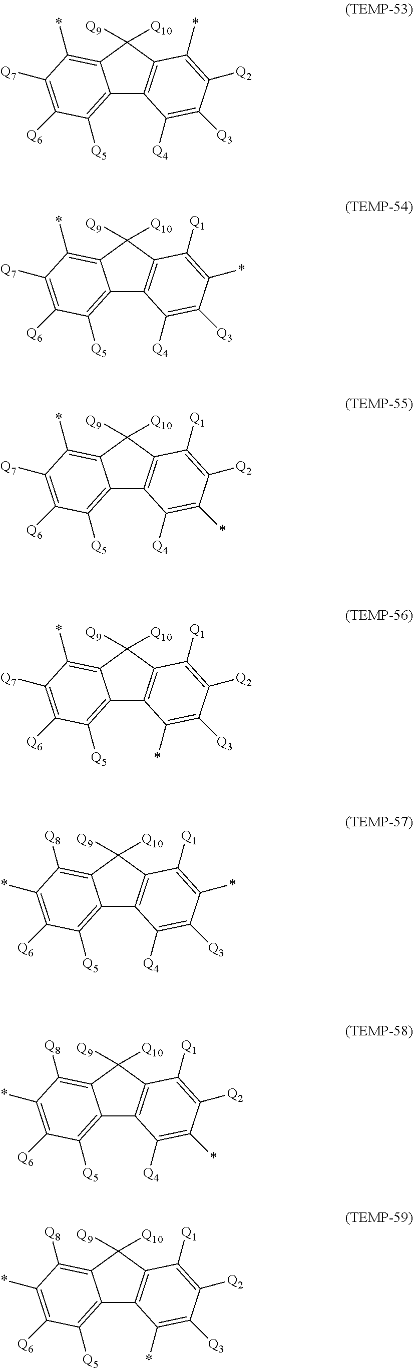

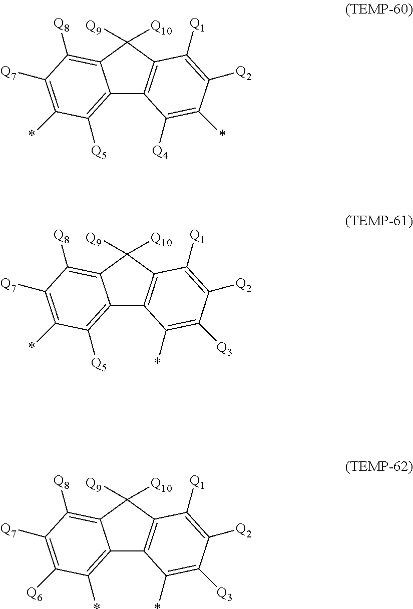

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * represents a bonding position,

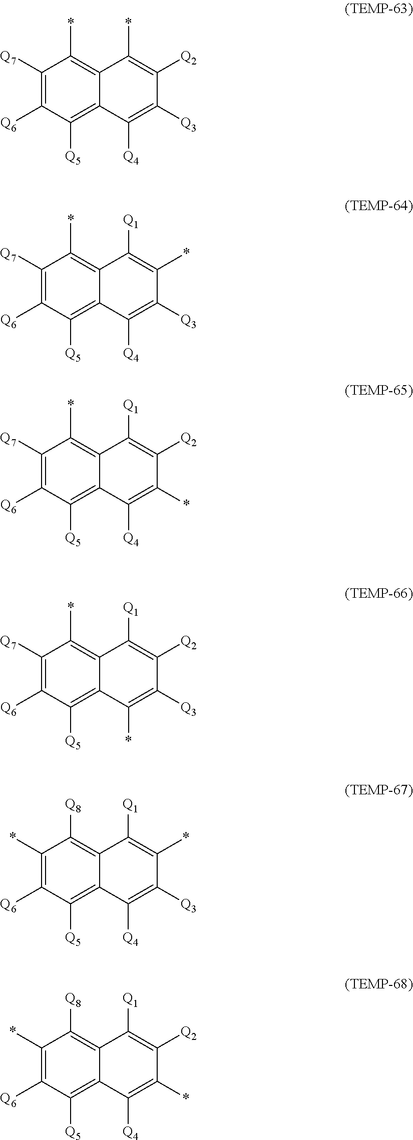

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

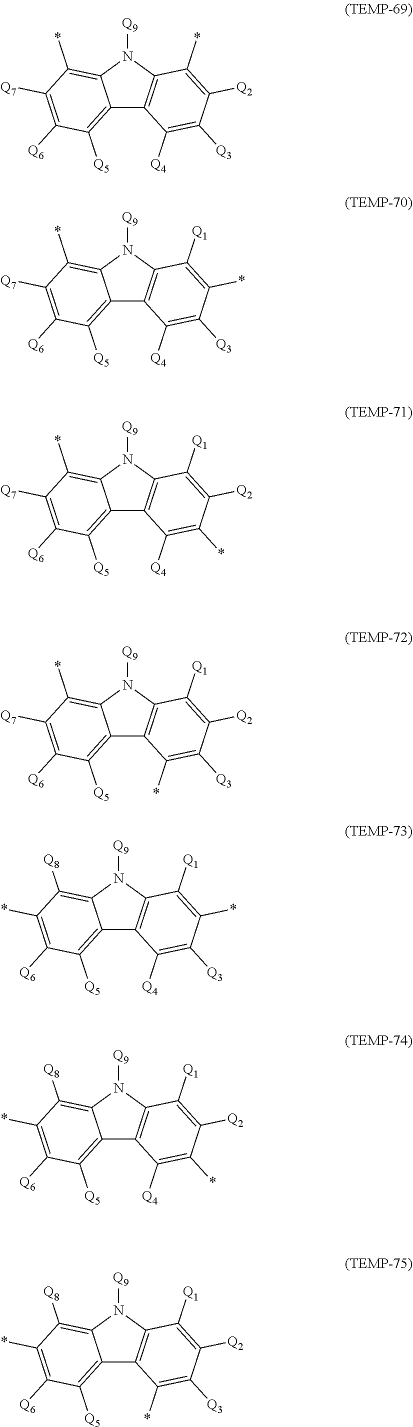

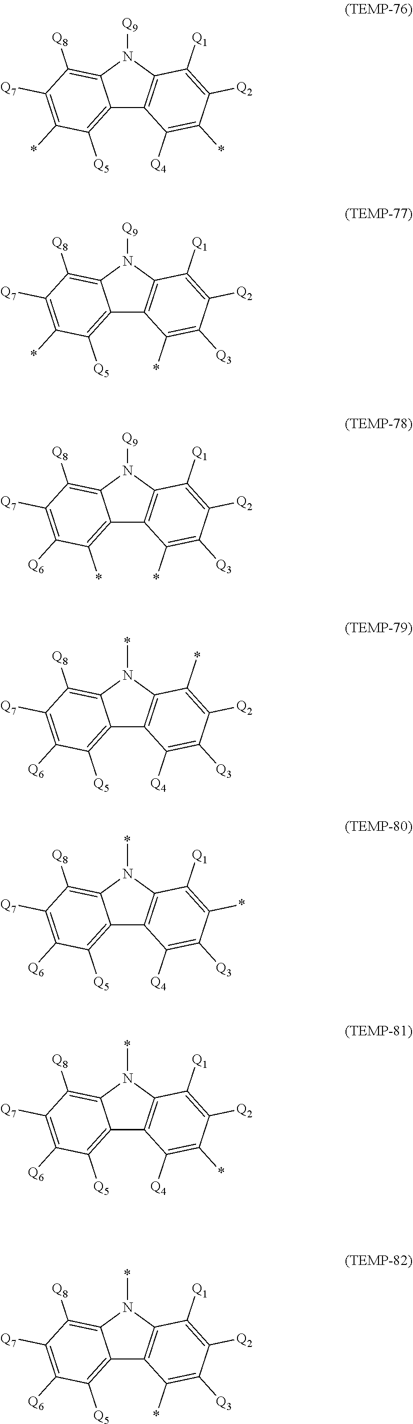

In the formulae (TEMP-69) to (TEMP-82), Q₁ to Q₉ are each independently a hydrogen atom or a substituent.

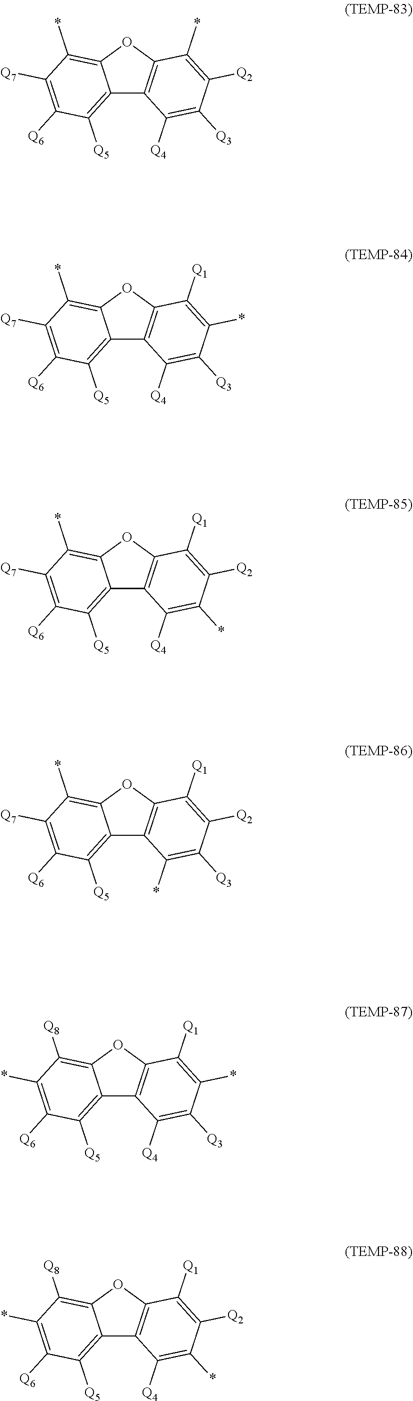

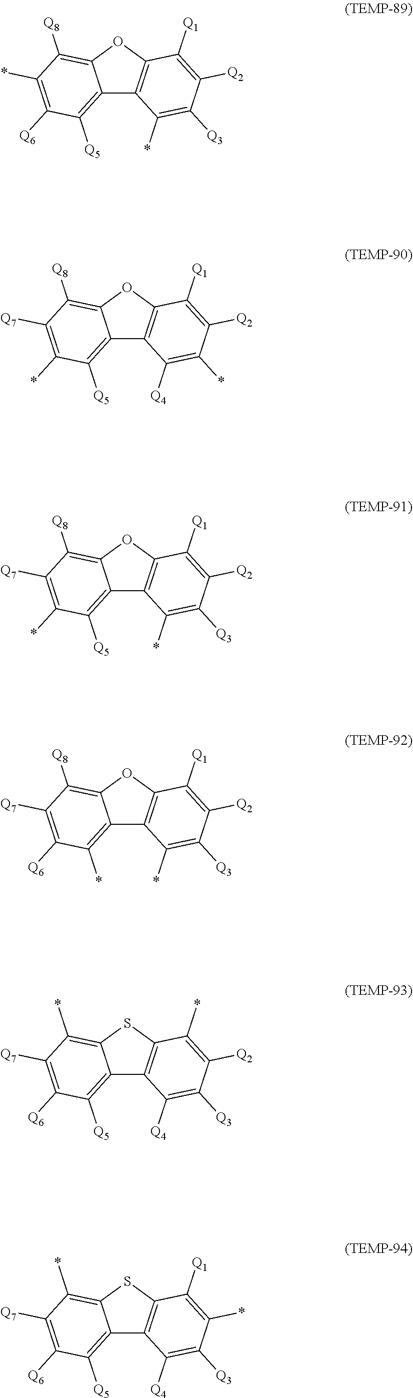

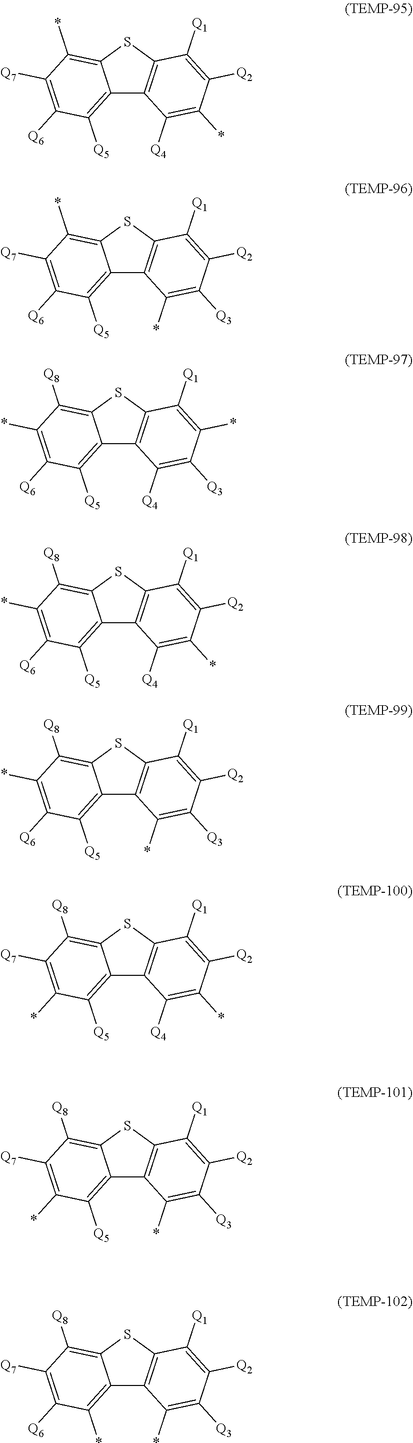

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

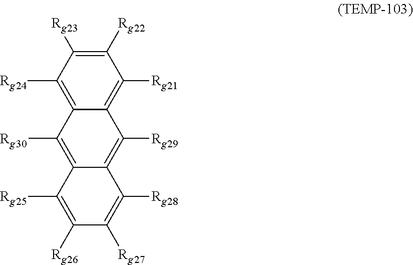

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

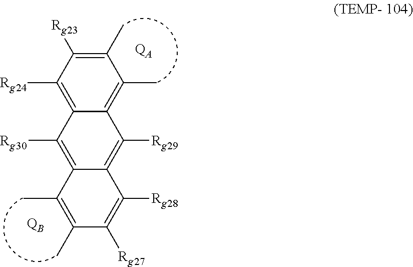

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

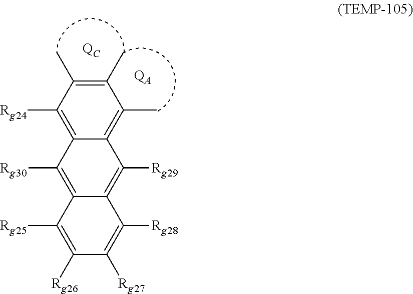

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific example of the specific example group G1 with a hydrogen atom.

Specific examples of the aromatic heterocycle include a ring formed by terminating a bond of an aromatic heterocyclic group in the specific example of the specific example group G2 with a hydrogen atom.

Specific examples of the aliphatic hydrocarbon ring include a ring formed by terminating a bond of a group in the specific example of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;

R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

When two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

Herein, a numerical formula represented by “A≥B” means that the value A is equal to the value B, or the value A is larger than the value B.

Herein, a numerical formula represented by “A≤B” means that the value A is equal to the value B, or the value A is smaller than the value B.

### First Exemplary Embodiment

An organic electroluminescence device according to the exemplary embodiment includes: an anode; a cathode; an emitting zone provided between the anode and the cathode; and a hole transporting zone provided between the anode and the emitting zone, in which the emitting zone includes at least one emitting layer, a first host material, a second host material, and an emitting compound being contained in a single emitting layer included in the at least one emitting layer, the first host material and the second host material are each independently a compound represented by a formula (1) below, the first host material and the second host material are mutually different, the hole transporting zone includes one or more organic layers, and at least one of the organic layers contains a third compound represented by a formula (EB1).

The third compound represented by the formula (EB1) that is contained in the organic EL device of the exemplary embodiment has high hole mobility. In an arrangement where the organic layer in the hole transporting zone arranged at a side of the emitting zone close to the anode contains the third compound represented by the formula (EB1), the drive voltage of the organic EL device is decreased and the stability against electrons of the organic layer is improved, providing the long lifetime of the organic EL device.

In an exemplary arrangement of the organic EL device of the exemplary embodiment, at least one of the first host material, the second host material, or the third compound contains at least one deuterium atom in a molecule.

### Hole Transporting Zone

The hole transporting zone is provided between the anode and the emitting zone.

The hole transporting zone includes one or more organic layers. At least one of the organic layers included in the hole transporting zone contains the third compound represented by the formula (EB1).

In an exemplary arrangement of the organic EL device of the exemplary embodiment, the hole transporting zone includes two or more organic layers. In an exemplary arrangement of the organic EL device of the exemplary embodiment, at least one of two or more organic layers included in the hole transporting zone contains the third compound represented by the formula (EB1).

In an exemplary arrangement of the organic EL device of the exemplary embodiment, the hole transporting zone includes a hole injecting layer and a hole transporting layer.

In an exemplary arrangement of the organic EL device of the exemplary embodiment, when the hole transporting zone includes two organic layers that are the hole injecting layer and the hole transporting layer, the hole transporting layer contains the third compound represented by the formula (EB1).

In an exemplary arrangement of the organic EL device of the exemplary embodiment, the hole transporting layer is in direct contact with the emitting layer in the emitting zone.

In an exemplary arrangement of the organic EL device of the exemplary embodiment, the hole transporting zone includes three or more organic layers. In an exemplary arrangement of the organic EL device of the exemplary embodiment, at least one of three or more organic layers included in the hole transporting zone contains the third compound represented by the formula (EB1).

In an exemplary arrangement of the organic EL device of the exemplary embodiment, the hole transporting zone includes the hole injecting layer, the hole transporting layer, and an electron blocking layer.

In an exemplary arrangement of the organic EL device of the exemplary embodiment, when the hole transporting zone includes three organic layers that are the hole injecting layer, the hole transporting layer, and the electron blocking layer, the electron blocking layer contains the third compound represented by the formula (EB1).

In an exemplary arrangement of the organic EL device of the exemplary embodiment, the electron blocking layer is preferably in direct contact with the emitting layer in the emitting zone.

In an exemplary arrangement of the organic EL device of the exemplary embodiment, one of the organic layers included in the hole transporting zone and disposed closest to the cathode contains the third compound represented by the formula (EB1).

In an exemplary arrangement of the organic EL device of the exemplary embodiment, one of the organic layers included in the hole transporting zone and being in direct contact with the emitting layer in the emitting zone contains the third compound represented by the formula (EB1).

### Third Compound

Explanation will be made about the third compound in the exemplary embodiment.

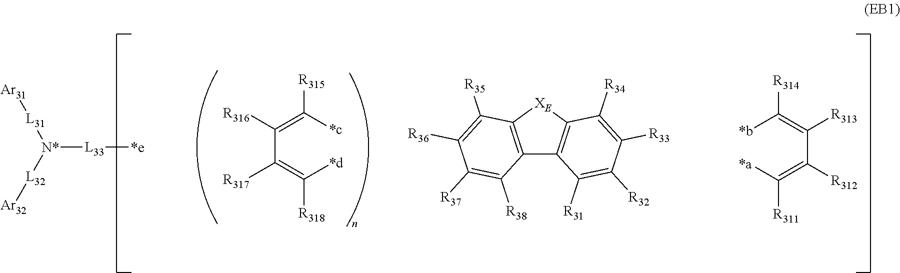

In the formula (EB1):
N* is a central nitrogen atom;
R₃₁ to R₃₈ and R₃₁₁ to R₃₁₈ are each independently a hydrogen atom, a halogen atom, a cyano group, a nitro group, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms;
n is 0 or 1;
when n is 0,
one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b;
one selected from R₃₁ to R₃₄ being neither the single bond with *a nor the single bond with *b, R₃₅ to R₃₈, and R₃₁₁ to R₃₁₄ is a single bond with *e;
when n is 1,
one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b;
one of R₃₅ and R₃₆, one of R₃₆ and R₃₇, or one of R₃₇ and R₃₈ is a single bond with *c, and the other of R₃₅ and R₃₆, the other of R₃₆ and R₃₇, or the other of R₃₇ and R₃₈ is a single bond with *d;
one selected from R₃₁ to R₃₄ being neither the single bond with *a nor the single bond with *b, R₃₅ to R₃₈ being neither the single bond with *c nor the single bond with *d, R₃₁₁ to R₃₁₄, and R₃₁₅ to R₃₁₈ is a single bond with *e;
X_{E} is an oxygen atom or a sulfur atom;
Ar₃₁ and Ar₃₂ are each independently a substituted or unsubstituted aryl group having 6 to 30 ring carbon atoms, or a substituted or unsubstituted heterocyclic group having 5 to 30 ring atoms; and
L₃₁ to L₃₃ are each independently a single bond, a substituted or unsubstituted arylene group having 6 to 30 ring carbon atoms, or a substituted or unsubstituted divalent heterocyclic group having 5 to 30 ring atoms.

In the compound according to the exemplary embodiment, “one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b” means that: one of R₃₁ and R₃₂ is a single bond with *a and the other of R₃₁ and R₃₂ is a single bond with *b; one of R₃₂ and R₃₃ is a single bond with *a and the other of R₃₂ and R₃₃ is a single bond with *b; or one of R₃₃ and R₃₄ is a single bond with *a and the other of R₃₃ and R₃₄ is a single bond with *b.

In the compound according to the exemplary embodiment, “one of R₃₅ and R₃₆, one of R₃₆ and R₃₇, or one of R₃₇ and R₃₈ is a single bond with *c, and the other of R₃₅ and R₃₆, the other of R₃₆ and R₃₇, or the other of R₃₇ and R₃₈ is a single bond with *d” means that one of R₃₅ and R₃₆ is a single bond with *c and the other of R₃₅ and R₃₆ is a single bond with *d; one of R₃₆ and R₃₇ is a single bond with *c and the other of R₃₆ and R₃₇ is a single bond with *d; or one of R₃₇ and R₃₈ is a single bond with *c and the other of R₃₇ and R₃₈ is a single bond with *d.

In an exemplary arrangement of the organic EL device of the exemplary embodiment, R₃₈ is a single bond with *e.

In an exemplary arrangement of the organic EL device of the exemplary embodiment, the third compound represented by the formula (EB1) is a compound represented by any of formulae (EB11) to (EB13) below.

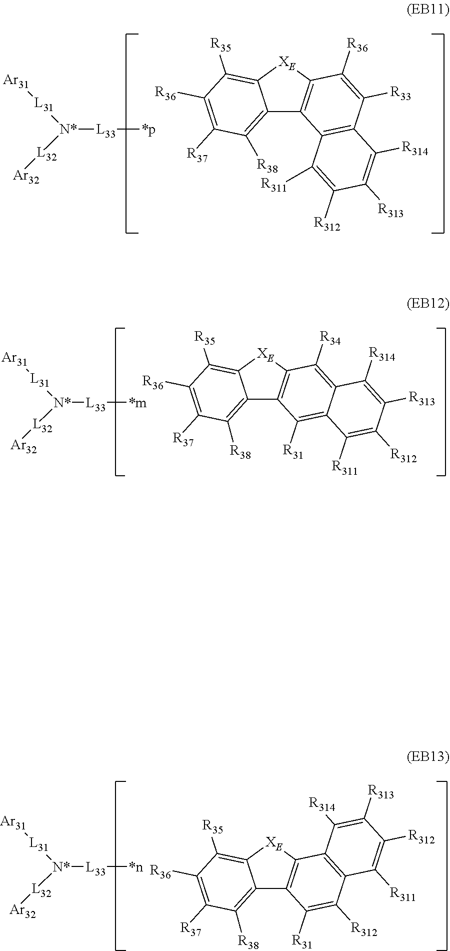

In the formulae (EB11) to (EB13):
N*, R₃₁ to R₃₈, R₃₁₁ to R₃₁₄, X_{E}, Ar₃₁, Ar₃₂, and L₃₁ to L₃₃ respectively represent the same as those defined in the formula (EB1);
when the compound represented by the formula (EB1) is a compound represented by the formula (EB11), one selected from R₃₃ to R₃₈ and R₃₁₁ to R₃₁₄ is a single bond with *p;
when the compound represented by the formula (EB1) is a compound represented by the formula (EB12), one selected from R₃₁, R₃₄ to R₃₈, and R₃₁₁ to R₃₁₄ is a single bond with *m; and
when the compound represented by the formula (EB1) is a compound represented by the formula (EB13), one selected from R₃₁, R₃₂, R₃₅ to R₃₈, and R₃₁₁ to R₃₁₄ is a single bond with *n.

In an exemplary arrangement of the organic EL device of the exemplary embodiment, the compound represented by the formula (EB1) is a compound represented by the formula (EB13).

In an exemplary arrangement of the organic EL device of the exemplary embodiment, R₃₁, R₃₅, R₃₈ or R₃₁₁ in the formula (EB11), (EB12), or (EB13) is a single bond with *p, *m, or *n.

In an exemplary arrangement of the organic EL device of the exemplary embodiment, R₃₈ in the formula (EB11), (EB12), or (EB13) is a single bond with *p, *m, or *n.

In an exemplary arrangement of the organic EL device of the exemplary embodiment, the compound represented by the formula (EB1) is a compound represented by a formula (EB131) below.

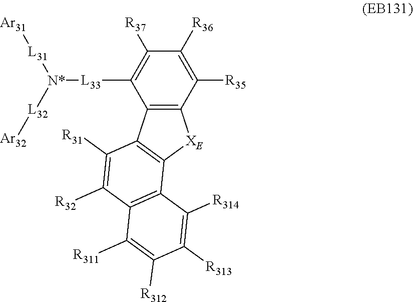

In the formula (EB131), N*, R₃₁, R₃₂, R₃₅ to R₃₇, R₃₁₁ to R₃₁₄, X_{E}, Ar₃₁, Ar₃₂, and L₃₁ to L₃₃ respectively represent the same as those defined in the formula (EB1).

In an exemplary arrangement of the organic EL device of the exemplary embodiment, L₃₃ is a substituted or unsubstituted phenylene group.

In an exemplary arrangement of the organic EL device of the exemplary embodiment, L₃₃ is an unsubstituted phenylene group.

In an exemplary arrangement of the organic EL device of the exemplary embodiment, L₃₃ is a substituted or unsubstituted o-phenylene group, a substituted or unsubstituted m-phenylene group, or a substituted or unsubstituted p-phenylene group.

In an exemplary arrangement of the organic EL device of the exemplary embodiment, L₃₃ is a substituted or unsubstituted o-phenylene group or a substituted or unsubstituted p-phenylene group.

In an exemplary arrangement of the organic EL device of the exemplary embodiment, also preferably, L₃₁ to L₃₃ are each independently a single bond or a group represented by a formula (L1) below.

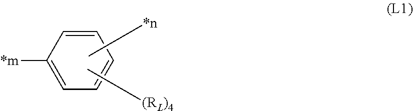

In the formula (L1):
R_{L} is a hydrogen atom, a substituted or unsubstituted alkyl group having 1 to 6 carbon atoms, or a substituted or unsubstituted aryl group having 6 to 12 ring carbon atoms;
a plurality of R_{L} are mutually the same or different; and
*m and *n each represent a bonding position.

One of *m and *n represents a bonding position to the central nitrogen atom N*, and the other of *m and *n represents a bonding position to A₃₁, Ar₃₂, *e, *p, *m, or *n.

In an exemplary arrangement of the organic EL device of the exemplary embodiment, L₃₃ is also preferably a group represented by the formula (L1).

In an exemplary arrangement of the organic EL device of the exemplary embodiment, the compound represented by the formula (EB1) is a compound represented by a formula (EB101) below.

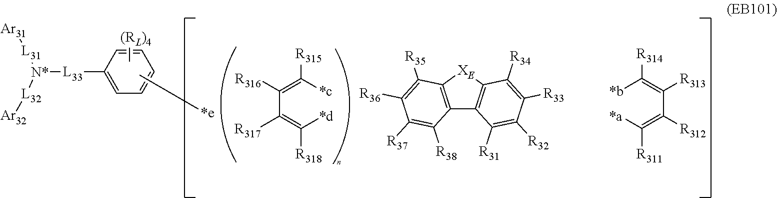

In the formula (EB101), N*, R₃₁ to R₃₈, R₃₁₁ to R₃₁₈, X_{E}, Ar₃₁, Ar₃₂, L₃₁, L₃₂, *a, *b, *c, *d, *e, and n respectively represent the same as those defined in the formula (EB1), and R_{L} represents the same as that defined in the formula (L1).

In an exemplary arrangement of the organic EL device of the exemplary embodiment, the compound represented by the formula (EB1) is a compound represented by a formula (EB111), (EB112), or (EB113) below.

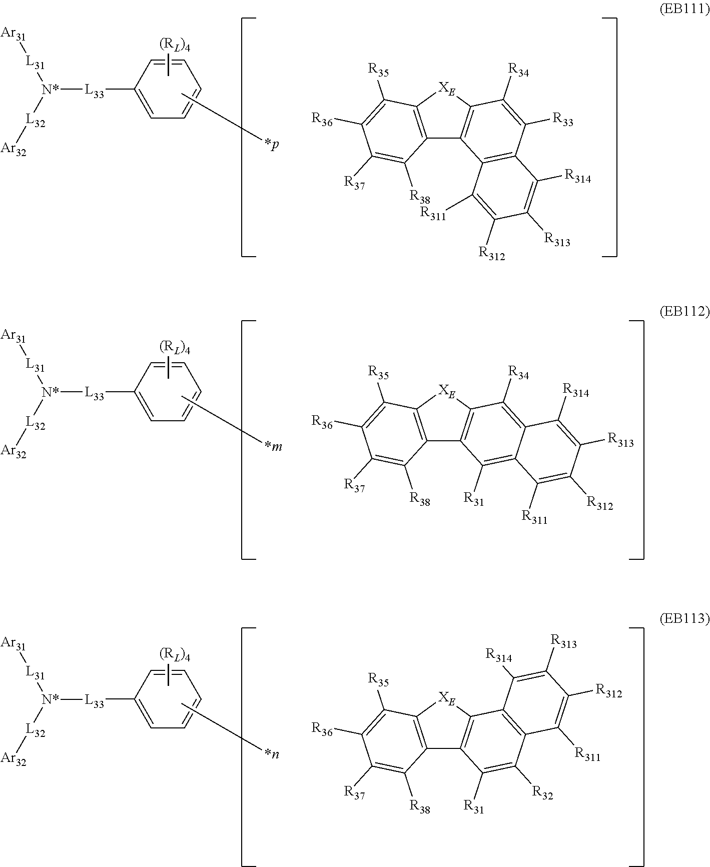

In the formulae (EB111), (EB112), and (EB113):
N*, R₃₁ to R₃₈, R₃₁₁ to R₃₁₄, X_{E}, Ar₃₁, Ar₃₂, L₃₁ and L₃₂ respectively represent the same as those defined in the formula (EB1);
R_{L} represents the same as that defined in the formula (L11);
when the compound represented by the formula (EB1) is a Compound represented by the formula (EB111), one selected from R₃₃ to R₃₈ and R₃₁₁ to R₃₁₄ is a single bond with *p;
when the compound represented by the formula (EB1) is a compound represented by the formula (EB112), one selected from R₃₁, R₃₄ to R₃₈, and R₃₁₁ to R₃₁₄ is a single bond with *m; and
when the compound represented by the formula (EB1) is a compound represented by the formula (EB113), one selected from R₃₁, R₃₂, R₃₅ to R₃₈, and R₃₁₁ to R₃₁₄ is a single bond with *n.

In an exemplary arrangement of the organic EL device of the exemplary embodiment, R₃₁, R₃₅, R₃₈, or R₃₁₁ in the formula (EB111), (EB112), or (EB113) is a single bond with *p, *m, or *n.

In an exemplary arrangement of the organic EL device of the exemplary embodiment, R₃₈ in the formula (EB111), (EB112), or (EB113) is a single bond with *p, *m, or *n.

In an exemplary arrangement of the organic EL device of the exemplary embodiment, when R₃₈ in the formula (EB113) is a single bond with *n, the compound represented by the formula (EB113) is a compound represented by a formula (EB114) below.

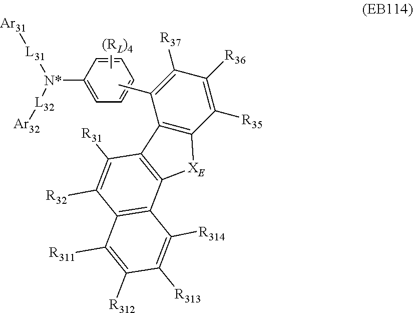

In the formula (EB114), N*, R₃₁, R₃₂, R₃₅ to R₃₇, R₃₁₁ to R₃₁₄, X_{E}, Ar₃₁, Ar₃₂, L₃₁, and L₃₂ respectively represent the same as those defined in the formula (EB1), and R_{L} represents the same as that defined in the formula (L1).

In an exemplary arrangement of the organic EL device of the exemplary embodiment, the compound represented by the formula (EB1) is a compound represented by a formula (EB132) below.

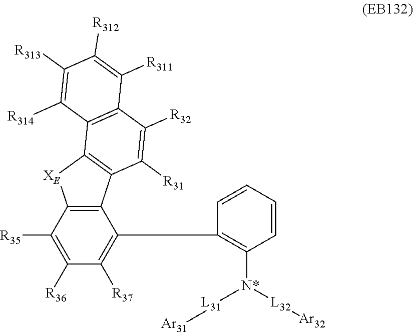

In the formula (EB132), N*, R₃₁, R₃₂, R₃₅ to R₃₇, R₃₁₁ to R₃₁₄, X_{E}, Ar₃₁, Ar₃₂, L₃₁, and L₃₂ respectively represent the same as those defined in the formula (EB1).

In an exemplary arrangement of the organic EL device of the exemplary embodiment, X_{E} is an oxygen atom.

In an exemplary arrangement of the organic EL device of the exemplary embodiment, Ar₃₁ and Ar₃₂ are each independently a group represented by any of formulae (1-a) to (1-f) below.

In an exemplary arrangement of the organic EL device of the exemplary embodiment, Ar₃₁ and Ar₃₂ in the formula (EB1) are each independently a group represented by any of the formulae (1-a) to (1-f);
when Ar₃₁ is a group represented by any of the formulae (1-a) to (1-f), L₃₁ is a single bond or an unsubstituted arylene group having 6 to 30 ring carbon atoms; and
when Ar₃₂ is a group represented by any of the formulae (1-a) to (1-f), L₃₂ is a single bond or an unsubstituted arylene group having 6 to 30 ring carbon atoms.

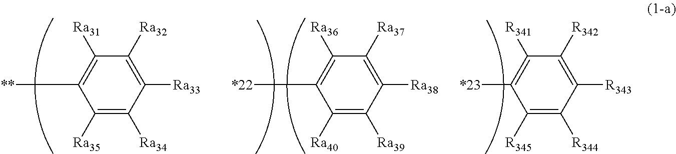

In the formula (1-a):
R₃₄₁ to R₃₄₅ are each independently a hydrogen atom, a substituted or unsubstituted alkyl group having 1 to 10 carbon atoms, or a substituted or unsubstituted aryl group having 6 to 12 ring carbon atoms,
adjacent two selected from R₃₄₁ to R₃₄₅ are not mutually bonded and thus form no ring;
one selected from Ra₃₁ to Ra₃₅ is a single bond with *22;
one selected from Ra₃₆ to Ra₄₀ is a single bond with *23;
Ra₃₁ to Ra₄₀ not being the single bond are each independently a hydrogen atom, an unsubstituted alkyl group having 1 to 10 carbon atoms, or an unsubstituted aryl group having 6 to 12 ring carbon atoms;
adjacent two selected from Ra₃₁ to Ra₃₅ not being the single bond are not mutually bonded and thus form no ring;
adjacent two selected from Ra₃₆ to Ra₄₀ not being the single bond are not mutually bonded and thus form no ring;
** represents a bonding position to L₃₁ or L₃₂;
m is 0 or 1, and n is 0 or 1;
when m and n are 0, *23 represents a bonding position to L₃₁ or L₃₂;
when m is 0 and n is 1, *22 represents a bonding position to L₃₁ or L₃₂;
when m is 1 and n is 0, one selected from Ra₃₁ to Ra₃₅ is a single bond with *23;
when L₃₁ is a single bond, **, *22, or *23 of the group represented by the formula (1-a), which is Ar₃₁, represents a bonding position to the central nitrogen atom N*; and
when L₃₂ is a single bond, **, *22, or *23 of the group represented by the formula (1-a), which is Ar₃₂, represents a bonding position to the central nitrogen atom N*.

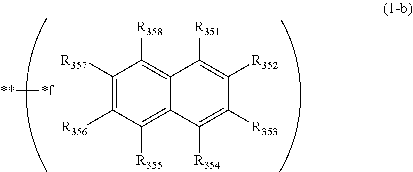

In the formula (1-b):
R₃₅₁ to R₃₅₈ are each independently a hydrogen atom, a substituted or unsubstituted alkyl group having 1 to 6 carbon atoms, or a substituted or unsubstituted aryl group having 6 to 12 ring carbon atoms;
one selected from R₃₅₁ to R₃₅₈ is a single bond with *f;
adjacent two selected from R₃₅₁ to R₃₅₈ not being the single bond are not mutually bonded and thus form no cyclic structure;
** represents a bonding position to L₃₁ or L₃₂;
when L₃₁ is a single bond, ** of the group represented by the formula (1-b), which is Ar₃₁, represents a bonding position to the central nitrogen atom N*; and
when L₃₂ is a single bond, ** of the group represented by the formula (1-b), which is Ar₃₂, represents a bonding position to the central nitrogen atom N*.

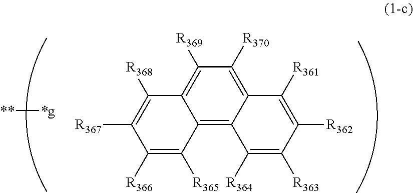

In the formula (1-c):
R₃₆₁ to R₃₇₀ are each independently a hydrogen atom, a substituted or unsubstituted alkyl group having 1 to 6 carbon atoms, or a substituted or unsubstituted aryl group having 6 to 12 ring carbon atoms;
one selected from R₃₆₁ to R₃₇₀ is a single bond with *g;
adjacent two selected from R₃₆₁ to R₃₇₀ not being the single bond are not mutually bonded and thus form no cyclic structure;
** represents a bonding position to L₃₁ or L₃₂;
when L₃₁ is a single bond, ** of the group represented by the formula (1-c), which is Ar₃₁, represents a bonding position to the central nitrogen atom N*; and
when L₃₂ is a single bond, ** of the group represented by the formula (1-c), which is Ar₃₂, represents a bonding position to the central nitrogen atom N*.

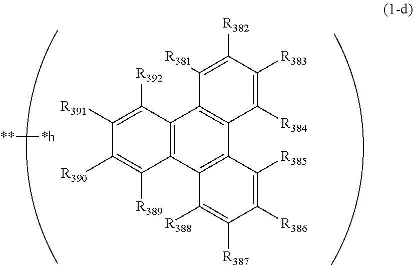

In the formula (1-d):
R₃₈₁ to R₃₉₂ are each independently a hydrogen atom, a substituted or unsubstituted alkyl group having 1 to 6 carbon atoms, or a substituted or unsubstituted aryl group having 6 to 12 ring carbon atoms;
one selected from R₃₈₁ to R₃₉₂ is a single bond with *h;
adjacent two selected from R₃₈₁ to R₃₉₂ not being the single bond are not mutually bonded and thus form no cyclic structure;
** represents a bonding position to L₃₁ or L₃₂;
when L₃₁ is a single bond, ** of the group represented by the formula (1-d), which is Ar₃₁, represents a bonding position to the central nitrogen atom N*; and
when L₃₂ is a single bond, ** of the group represented by the formula (1-d), which is Ar₃₂, represents a bonding position to the central nitrogen atom N*.

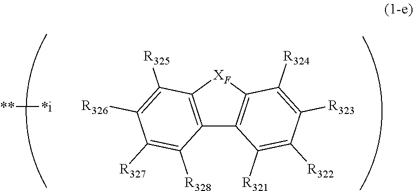

In the formula (1-e):
R₃₂₁ to R₃₂₃ are each independently a hydrogen atom, a substituted or unsubstituted alkyl group having 1 to 6 carbon atoms, a substituted or unsubstituted aryl group having 6 to 12 ring carbon atoms, or a substituted or unsubstituted aromatic heterocyclic group having 5 to 13 ring atoms;
X_{F} is an oxygen atom, a sulfur atom, NR_{F1}, or CR_{F2}R_{F3};
R_{F1} is a hydrogen atom, a substituted or unsubstituted alkyl group having 1 to 6 carbon atoms, a substituted or unsubstituted aryl group having 6 to 12 ring carbon atoms, or a substituted or unsubstituted aromatic heterocyclic group having to 13 ring atoms;
R_{F2} and R_{F3} are each independently a hydrogen atom, a substituted or unsubstituted alkyl group having 1 to 50 carbon atoms, or a substituted or unsubstituted aryl group having 6 to 50 ring carbon atoms;
R_{F2} and R_{F3} are mutually bonded to form a substituted or unsubstituted monocyclic ring, mutually bonded to form a substituted or unsubstituted fused ring, or not mutually bonded;
one selected from R₃₂₁ to R₃₂₈, R_{F1}, R_{F2}, and R_{F3} is a single bond with *i;
adjacent two selected from R₃₂₁ to R₃₂₈ not being the single bond are mutually bonded to form a substituted or unsubstituted benzene ring, or not mutually bonded;
** represents a bonding position to L₃₁ or L₃₂;
when L₃₁ is a single bond, ** of the group represented by the formula (1-e), which is Ar₃₁, represents a bonding position to the central nitrogen atom N*; and
when L₃₂ is a single bond, ** of the group represented by the formula (1-e), which is Ar₃₂, represents a bonding position to the central nitrogen atom N*.

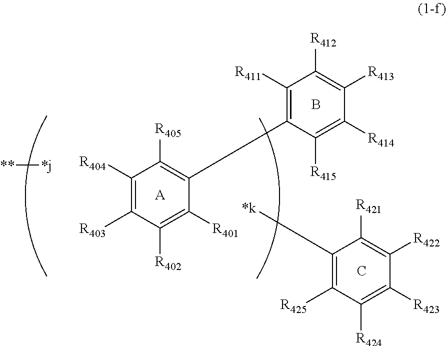

In the formula (1-f):
R₄₀₁ to R₄₀₅ are each independently a hydrogen atom, an unsubstituted alkyl group having 1 to 6 carbon atoms, or an unsubstituted phenyl group;
R₄₁₁ to R₄₁₅ and R₄₂₁ to R₄₂₅ are each independently a hydrogen atom or an unsubstituted alkyl group having 1 to 6 carbon atoms;
one selected from R₄₀₁ to R₄₀₅ is a single bond with *j;
any other one selected from R₄₀₁ to R₄₀₅ is a single bond with *k;
adjacent two selected from R₄₀₁ to R₄₀₅ not being the single bond are not mutually bonded and thus form no cyclic structure;
adjacent two selected from R₄₁₁ to R₄₁₅ and R₄₂₁ to R₄₂₅ are mutually bonded to form a substituted or unsubstituted benzene ring, or not mutually bonded;
** represents a bonding position to L₃₁ or L₃₂;
when L₃₁ is a single bond, ** of the group represented by the formula (1-f), which is Ar₃₁, represents a bonding position to the central nitrogen atom N*; and
when L₃₂ is a single bond, ** of the group represented by the formula (1-f), which is Ar₃₂, represents a bonding position to the central nitrogen atom N*.

In an exemplary arrangement of the organic EL device of the exemplary embodiment, L₃₁ and L₃₂ are each independently a single bond or a substituted or unsubstituted phenylene group.

In an exemplary arrangement of the organic EL device of the exemplary embodiment, L₃₁ and L₃₂ are each independently a single bond or an unsubstituted phenylene group.

In an exemplary arrangement of the organic EL device of the exemplary embodiment, also preferably, the groups specified to be “substituted or unsubstituted” in the third compound are each an “unsubstituted” group.

In the third compound, R₉₀₁, R₉₀₂, R₉₀₃, R₉₀₄, R₉₀₅, R₉₀₆, R₉₀₇, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

### Manufacturing Method of Third Compound

The third compound can be manufactured by a known method. The third compound can also be manufactured based on a known method through a known alternative reaction using a known material(s) tailored for the target compound.

### Specific Examples of Third Compound

Specific examples of the third compound include compounds below. However, the invention is not limited to the specific examples of the third compound.

In the specific examples herein, D represents a deuterium atom, Me represents a methyl group, tBu represents a tert-butyl group, and Ph represents a phenyl group.

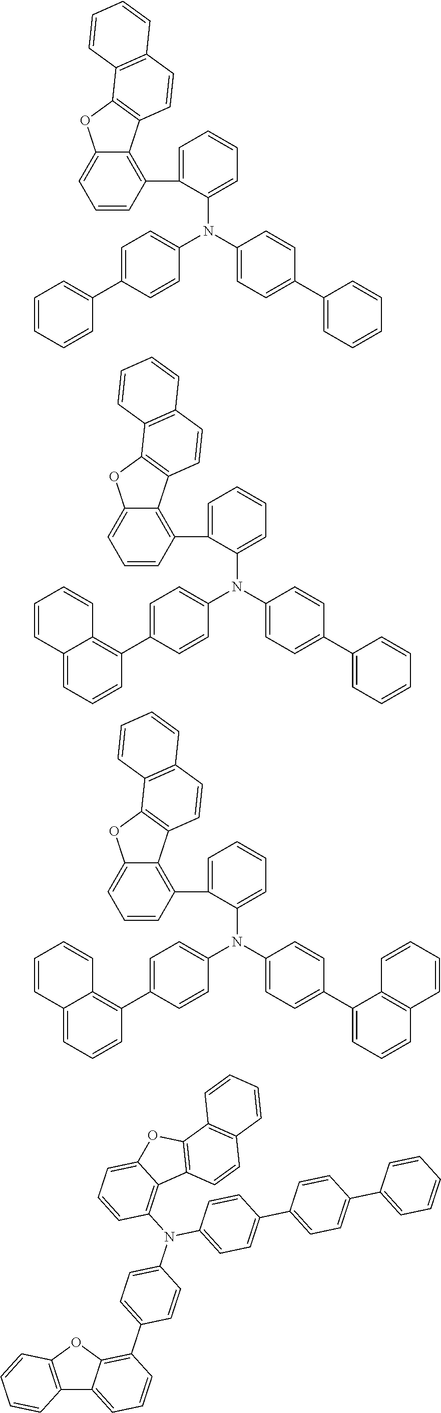

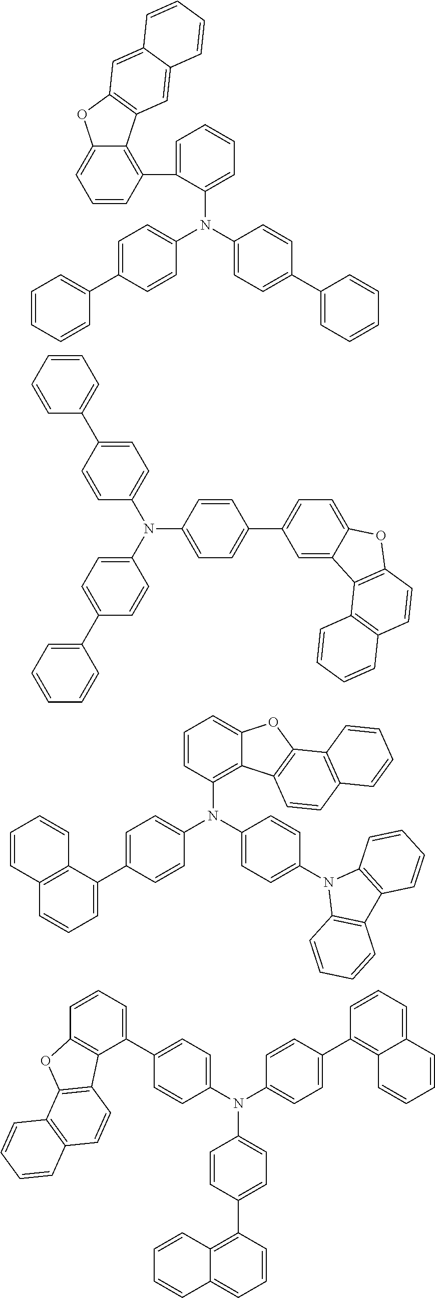

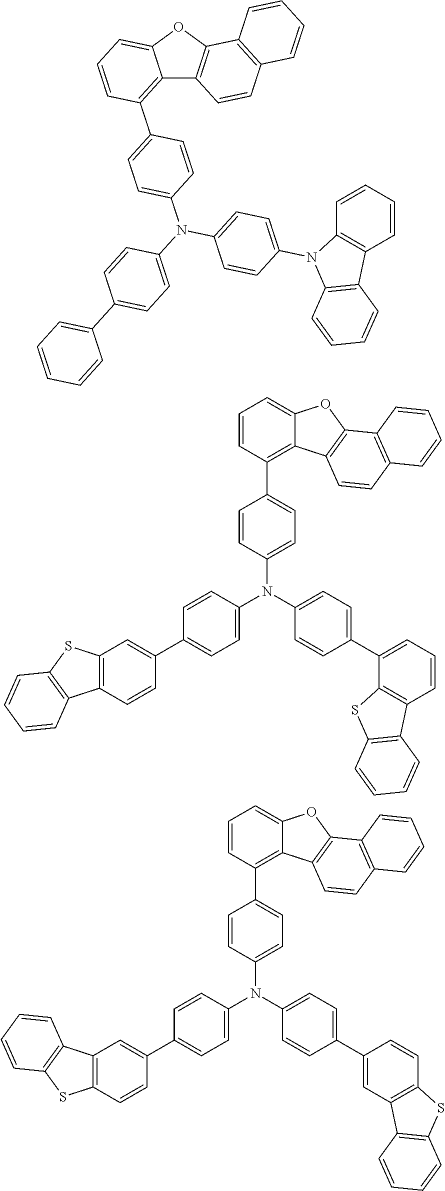

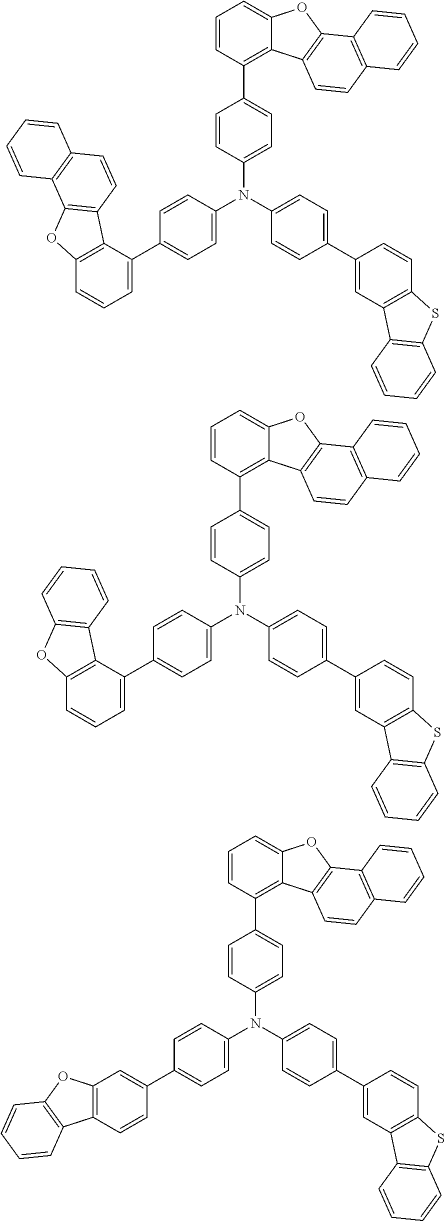

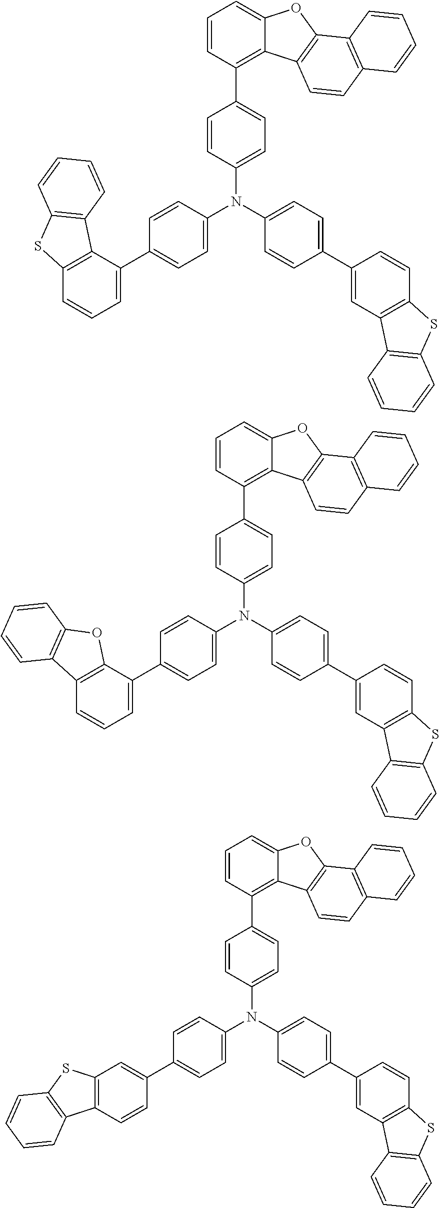

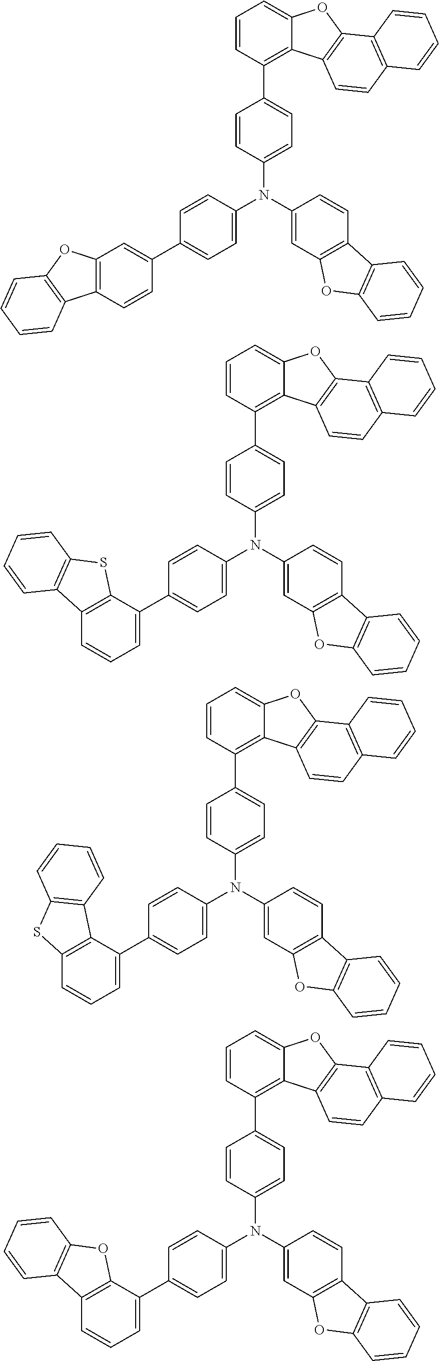

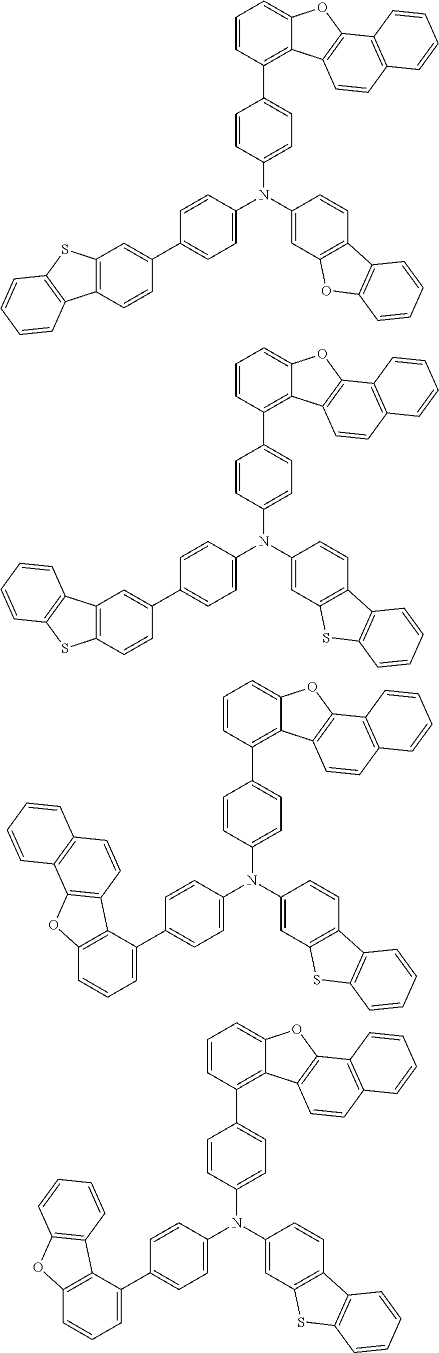

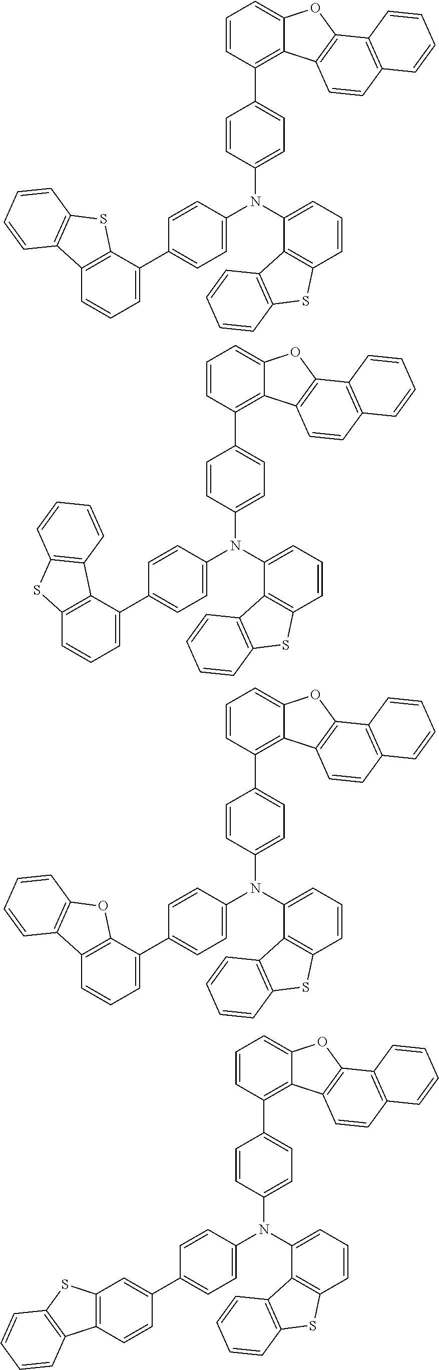

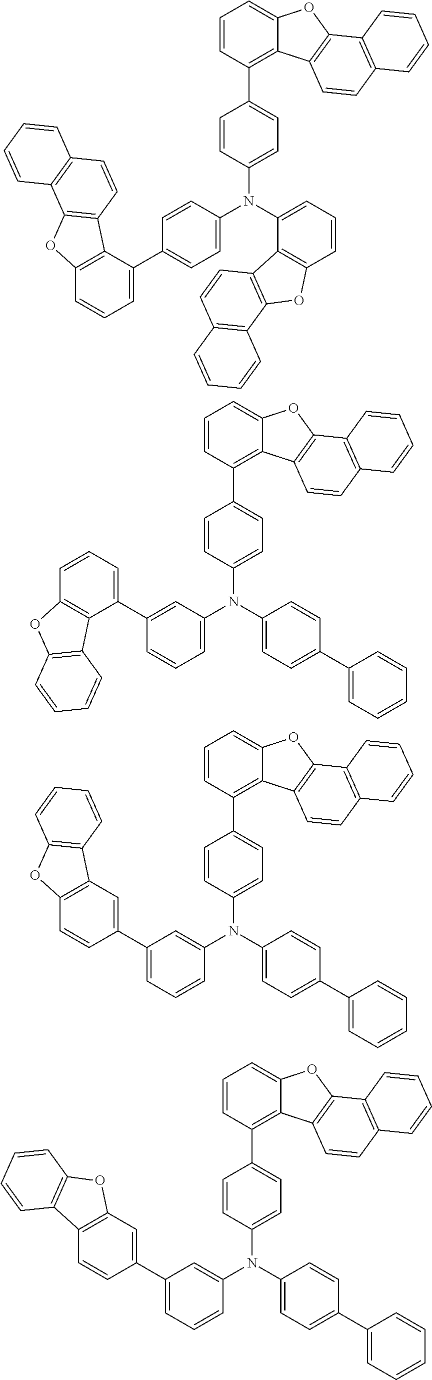

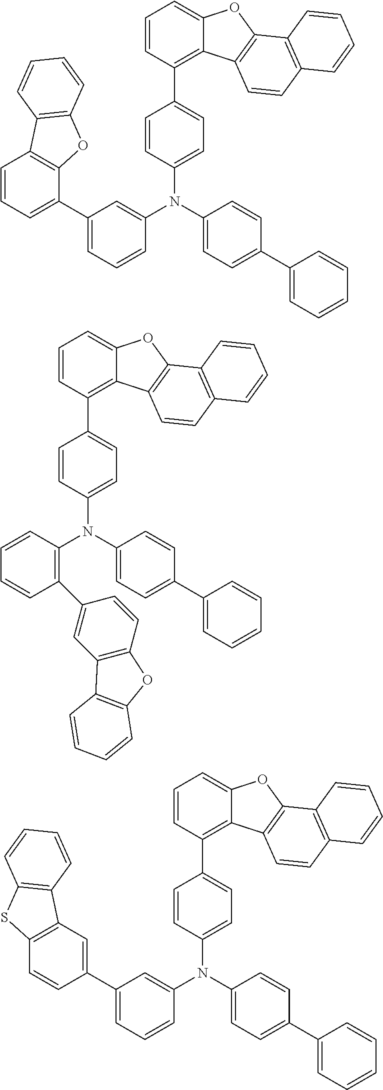 [SMILES: c1ccc(-c2ccc(N(c3ccc(-c4cccc5oc6c7ccccc7ccc6c45)cc3)c3cccc(-c4cccc5c4oc4ccccc45)c3)cc2)cc1 ; c1ccc(-c2ccc(N(c3ccc(-c4cccc5oc6c7ccccc7ccc6c45)cc3)c3ccccc3-c3ccc4oc5ccccc5c4c3)cc2)cc1 ; c1ccc(-c2ccc(N(c3ccc(-c4cccc5oc6c7ccccc7ccc6c45)cc3)c3cccc(-c4ccc5sc6ccccc6c5c4)c3)cc2)cc1]

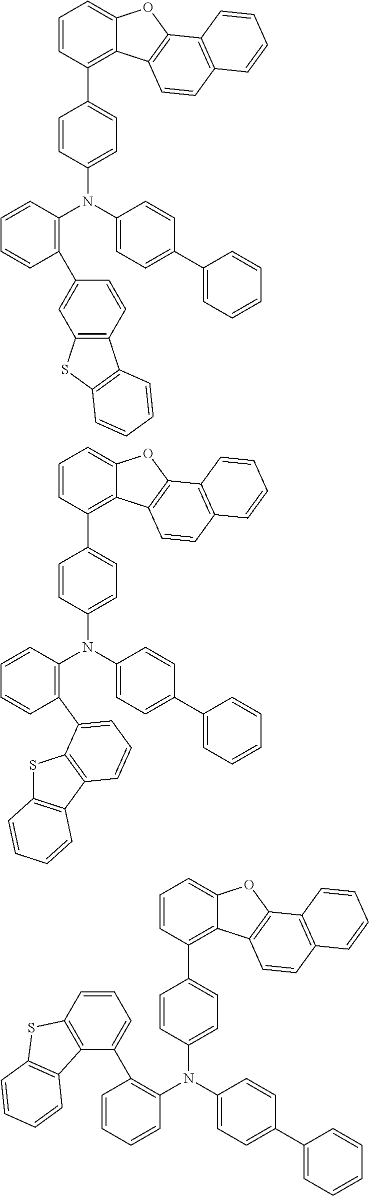

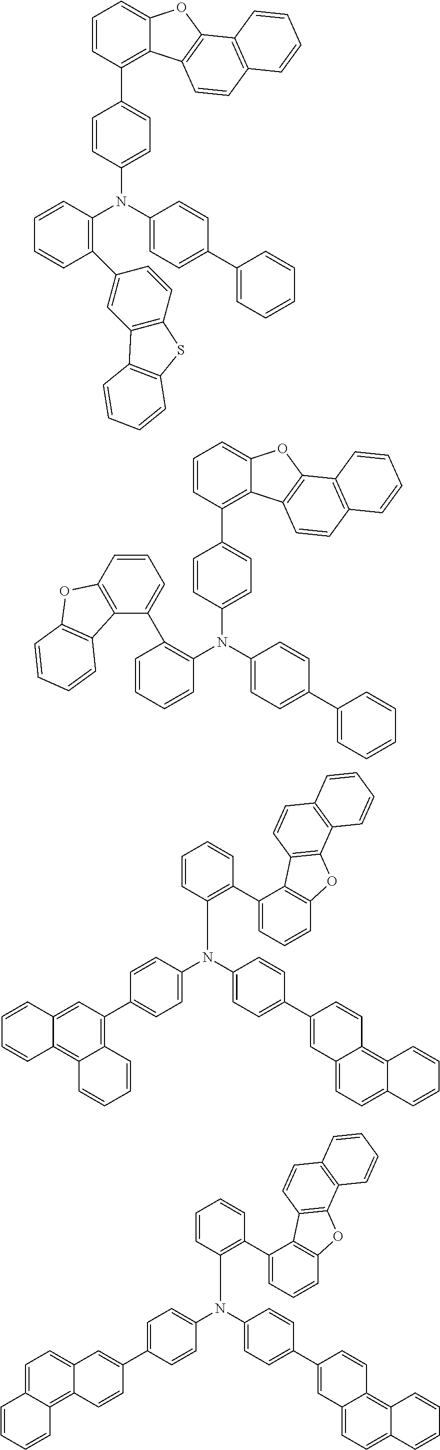

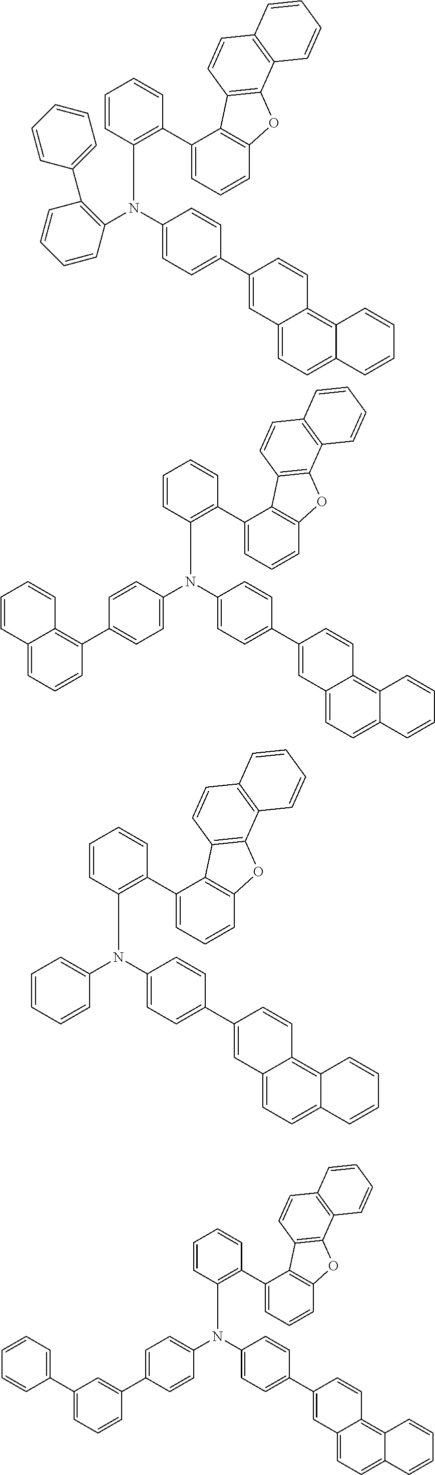

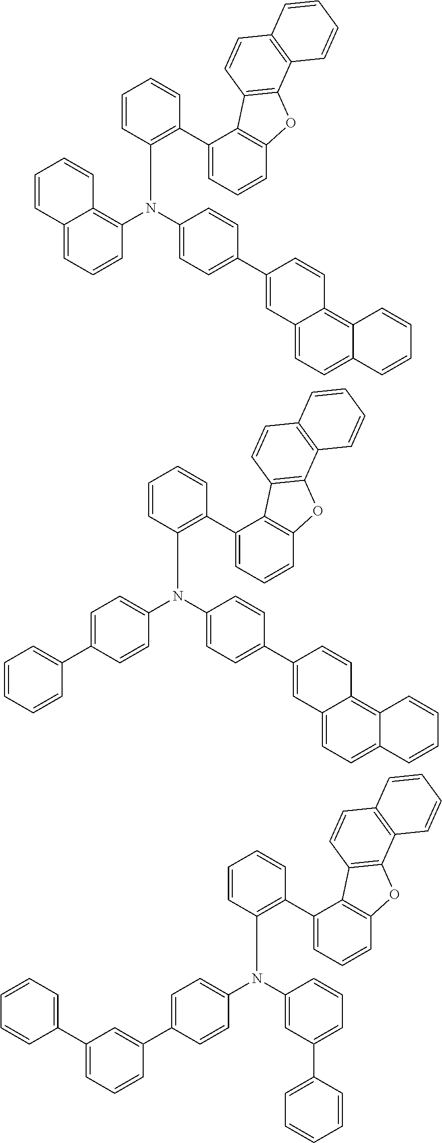

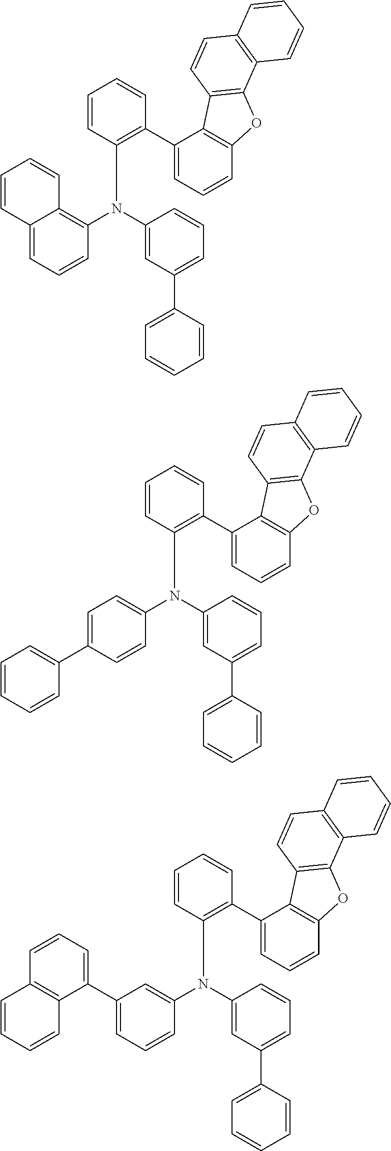 [SMILES: c1ccc(-c2cccc(N(c3ccccc3-c3cccc4oc5c6ccccc6ccc5c34)c3cccc4ccccc34)c2)cc1 ; c1ccc(-c2ccc(N(c3cccc(-c4ccccc4)c3)c3ccccc3-c3cccc4oc5c6ccccc6ccc5c34)cc2)cc1 ; c1ccc(-c2cccc(N(c3cccc(-c4cccc5ccccc45)c3)c3ccccc3-c3cccc4oc5c6ccccc6ccc5c34)c2)cc1]

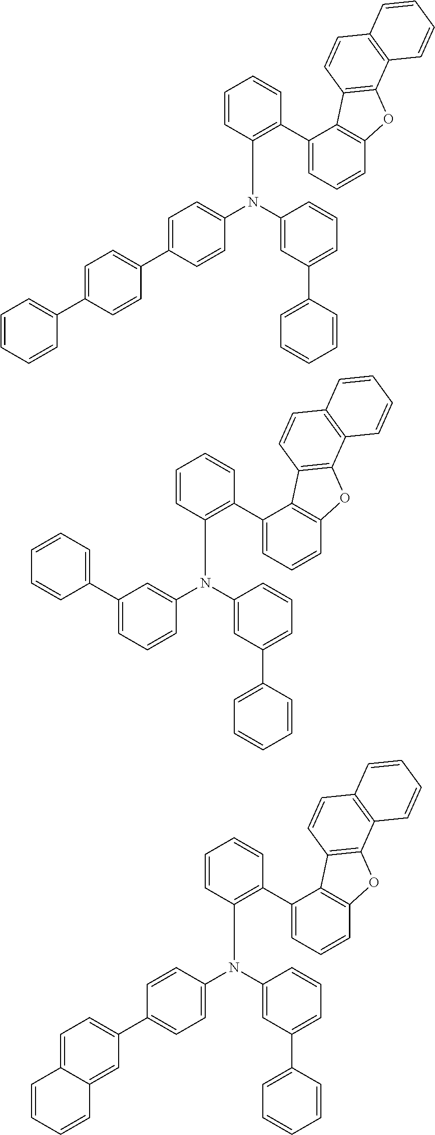

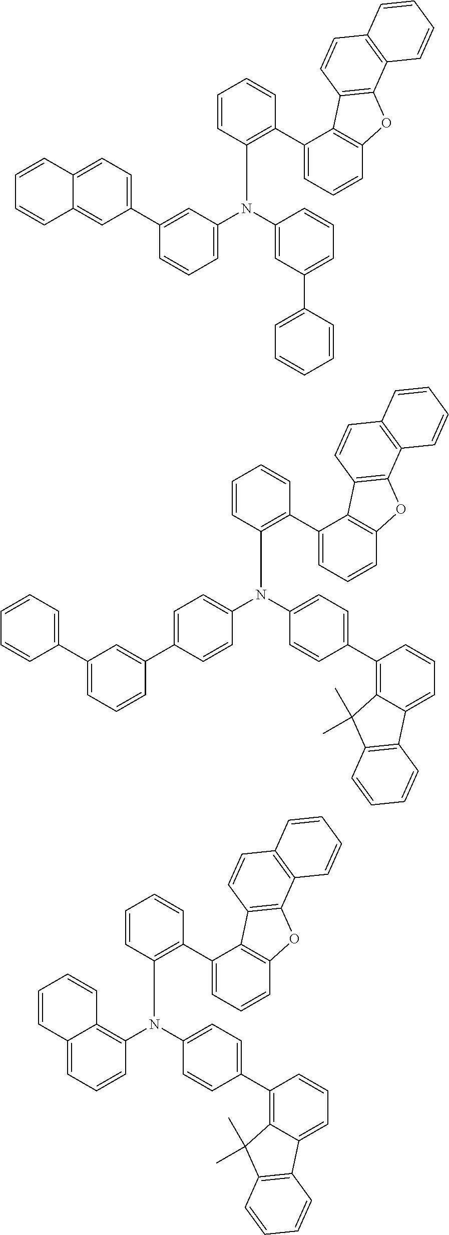 [SMILES: c1ccc(-c2cccc(N(c3cccc(-c4ccc5ccccc5c4)c3)c3ccccc3-c3cccc4oc5c6ccccc6ccc5c34)c2)cc1 ; CC1(C)c2ccccc2-c2cccc(-c3ccc(N(c4ccc(-c5cccc(-c6ccccc6)c5)cc4)c4ccccc4-c4cccc5oc6c7ccccc7ccc6c45)cc3)c21 ; CC1(C)c2ccccc2-c2cccc(-c3ccc(N(c4ccccc4-c4cccc5oc6c7ccccc7ccc6c45)c4cccc5ccccc45)cc3)c21]

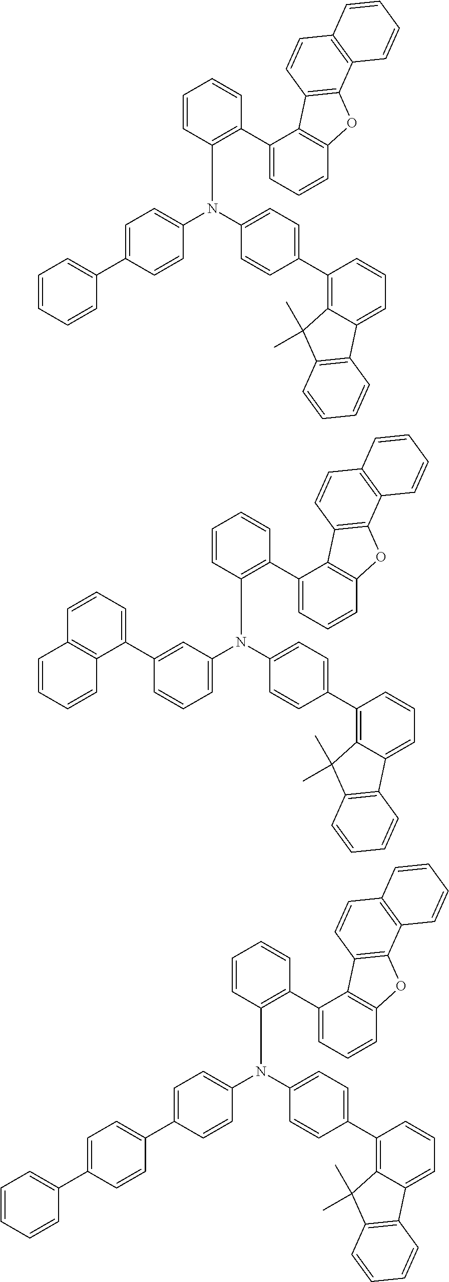

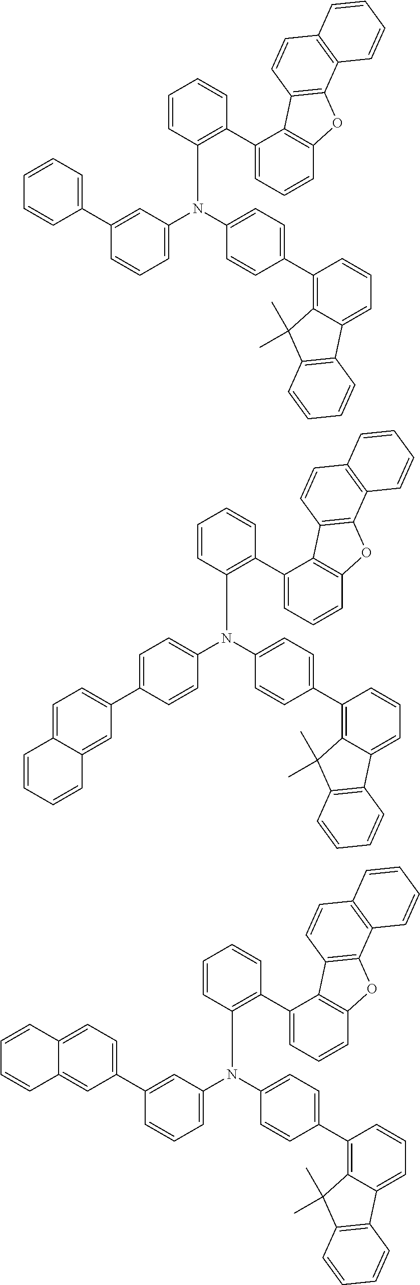

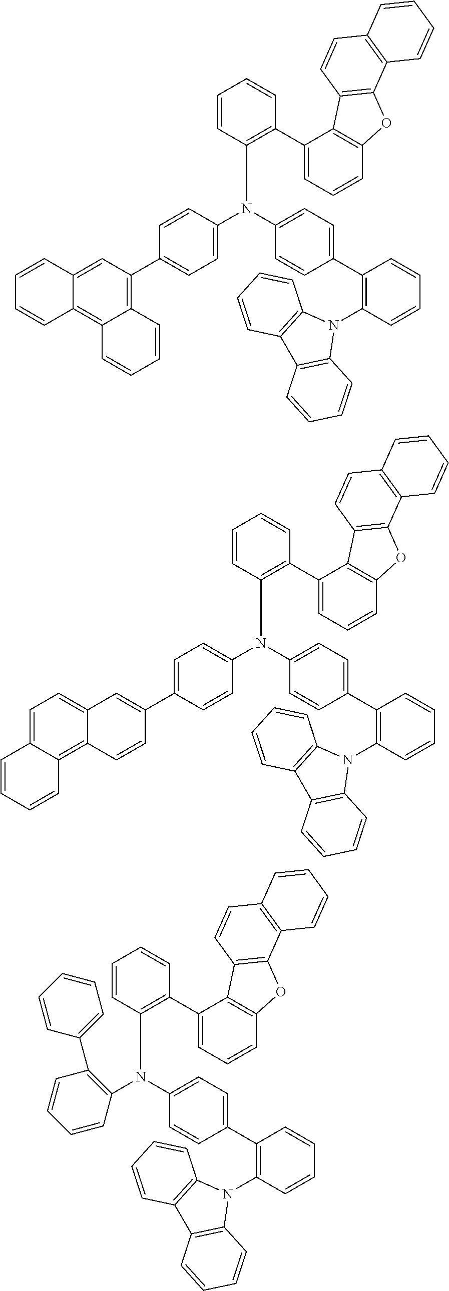

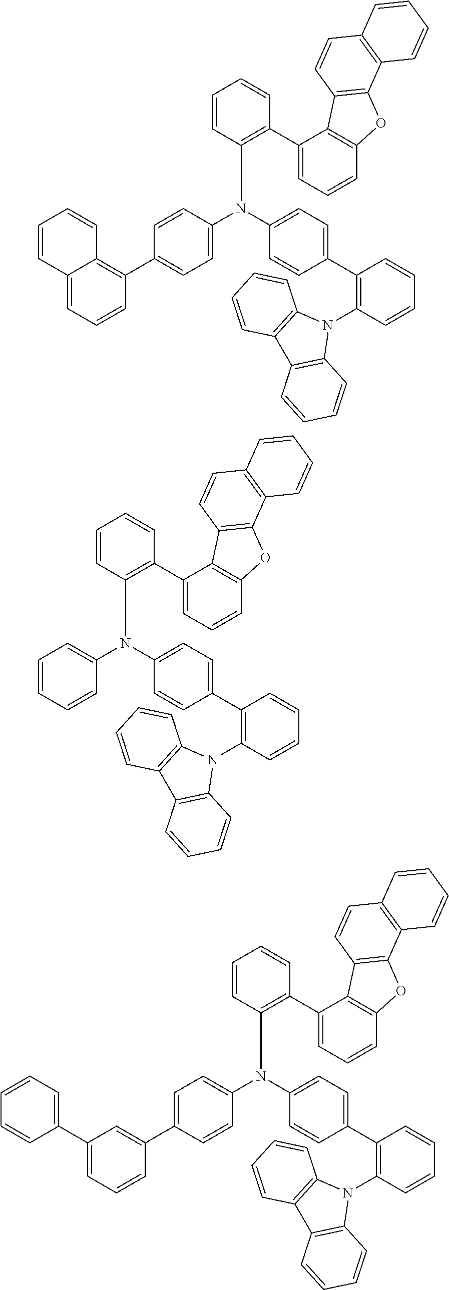

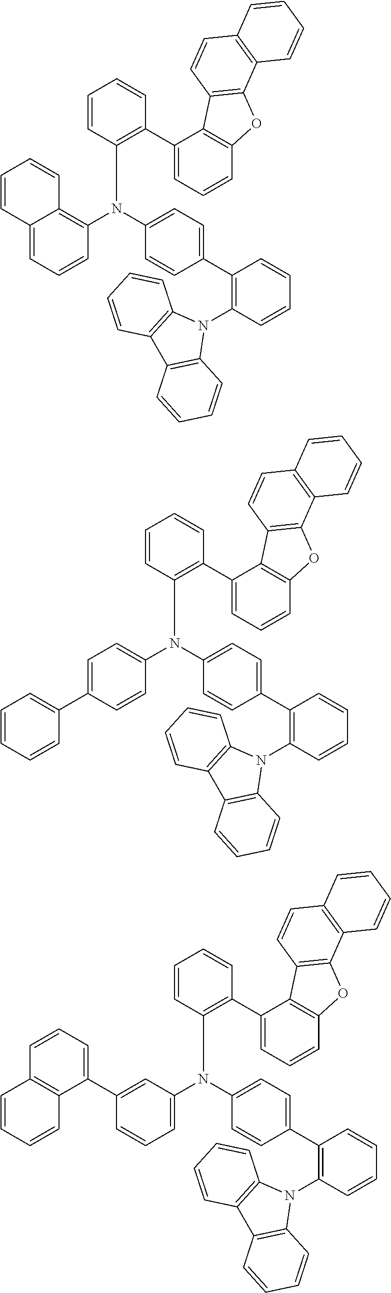 [SMILES: c1ccc(N(c2ccc(-c3ccccc3-n3c4ccccc4c4ccccc43)cc2)c2cccc3ccccc23)c(-c2cccc3oc4c5ccccc5ccc4c23)c1 ; c1ccc(-c2ccc(N(c3ccc(-c4ccccc4-n4c5ccccc5c5ccccc54)cc3)c3ccccc3-c3cccc4oc5c6ccccc6ccc5c34)cc2)cc1 ; c1cc(-c2cccc3ccccc23)cc(N(c2ccc(-c3ccccc3-n3c4ccccc4c4ccccc43)cc2)c2ccccc2-c2cccc3oc4c5ccccc5ccc4c23)c1]

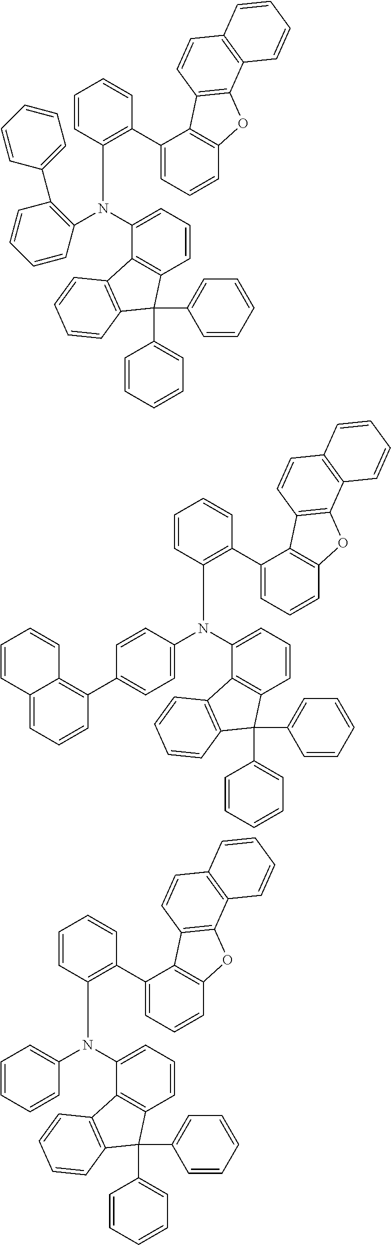

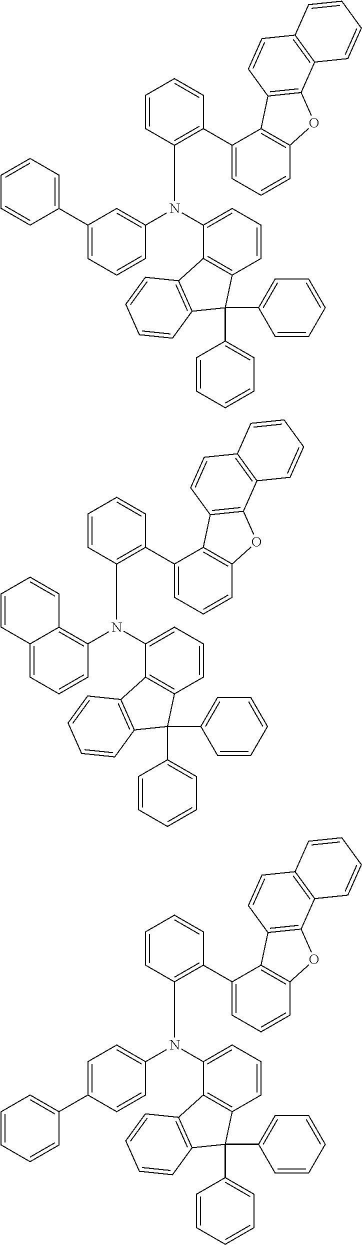

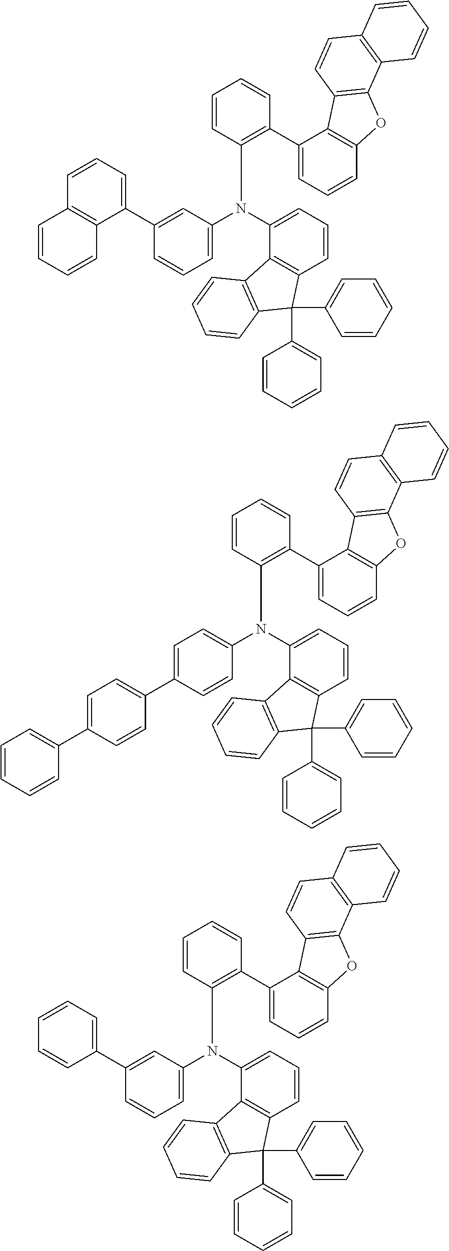

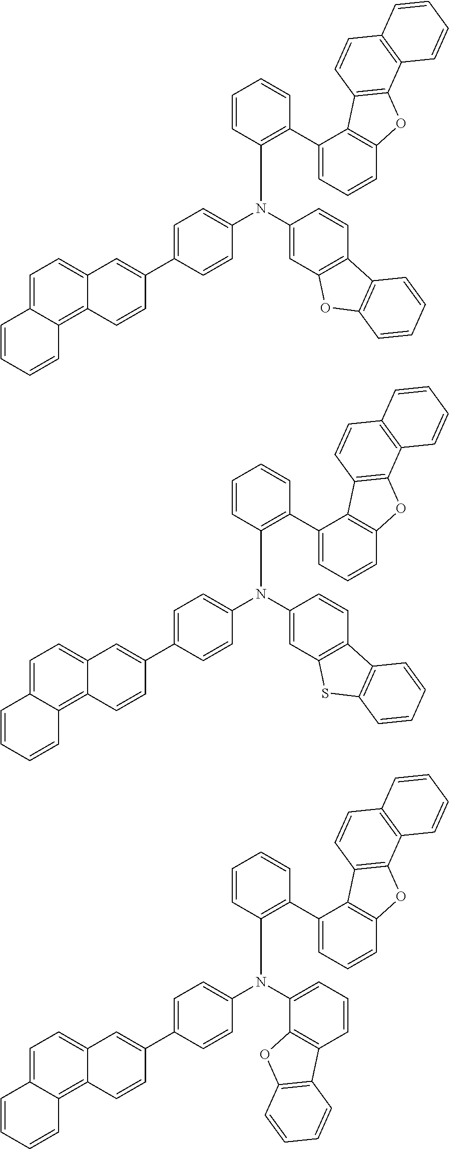 [SMILES: c1ccc(N(c2ccc(-c3ccc4c(ccc5ccccc54)c3)cc2)c2ccc3c(c2)oc2ccccc23)c(-c2cccc3oc4c5ccccc5ccc4c23)c1 ; c1ccc(N(c2ccc(-c3ccc4c(ccc5ccccc54)c3)cc2)c2ccc3c(c2)sc2ccccc23)c(-c2cccc3oc4c5ccccc5ccc4c23)c1 ; c1ccc(N(c2ccc(-c3ccc4c(ccc5ccccc54)c3)cc2)c2cccc3c2oc2ccccc23)c(-c2cccc3oc4c5ccccc5ccc4c23)c1]

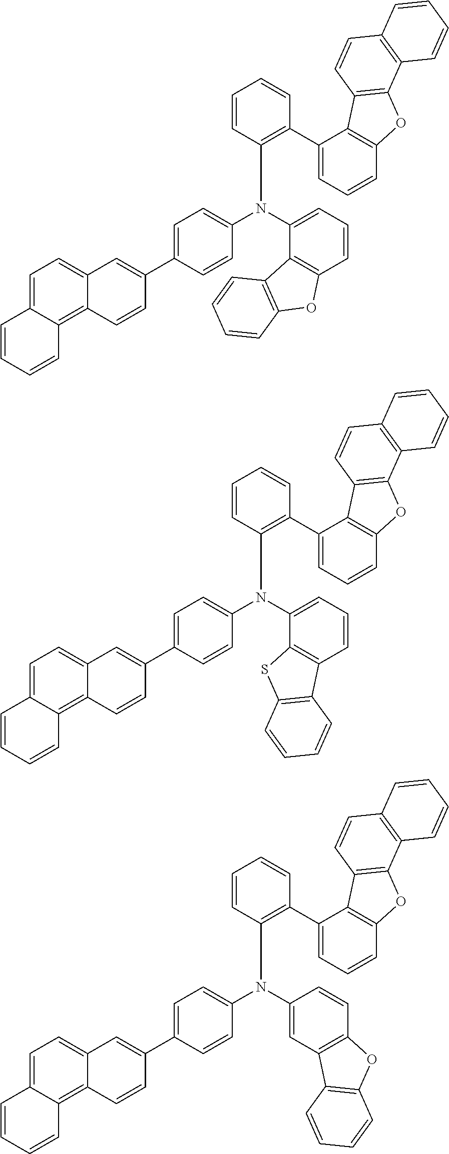 [SMILES: c1ccc(N(c2ccc(-c3ccc4c(ccc5ccccc54)c3)cc2)c2cccc3oc4ccccc4c23)c(-c2cccc3oc4c5ccccc5ccc4c23)c1 ; c1ccc(N(c2ccc(-c3ccc4c(ccc5ccccc54)c3)cc2)c2cccc3c2sc2ccccc23)c(-c2cccc3oc4c5ccccc5ccc4c23)c1 ; c1ccc(N(c2ccc(-c3ccc4c(ccc5ccccc54)c3)cc2)c2ccc3oc4ccccc4c3c2)c(-c2cccc3oc4c5ccccc5ccc4c23)c1]

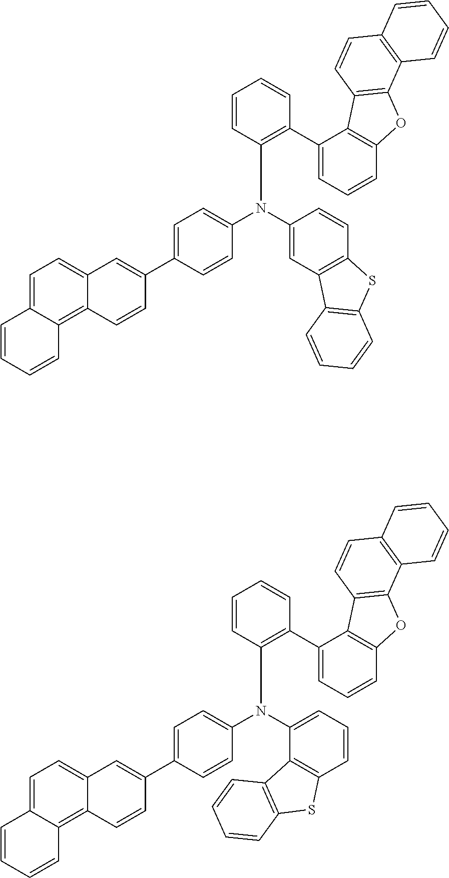 [SMILES: c1ccc(N(c2ccc(-c3ccc4c(ccc5ccccc54)c3)cc2)c2ccc3sc4ccccc4c3c2)c(-c2cccc3oc4c5ccccc5ccc4c23)c1 ; c1ccc(N(c2ccc(-c3ccc4c(ccc5ccccc54)c3)cc2)c2cccc3sc4ccccc4c23)c(-c2cccc3oc4c5ccccc5ccc4c23)c1]

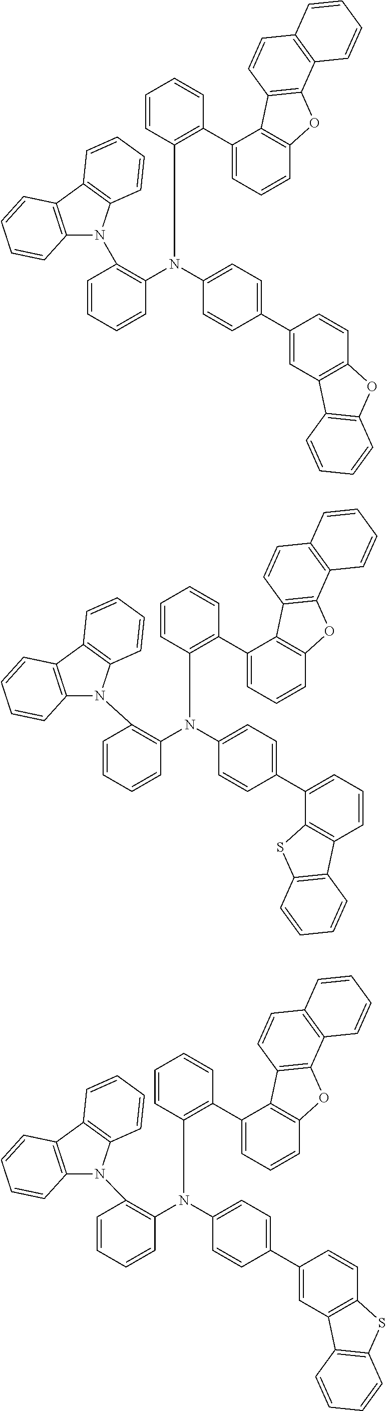

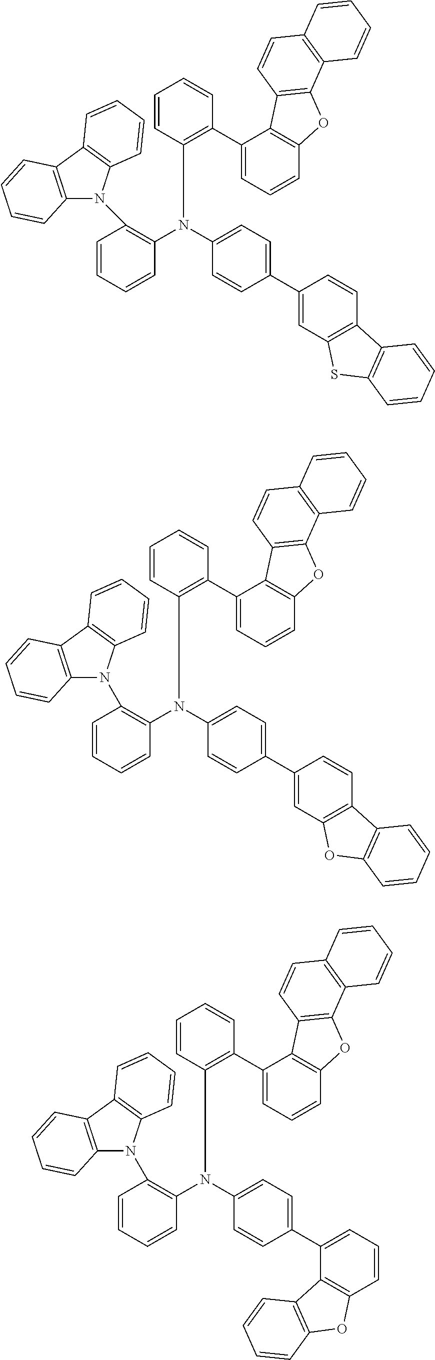

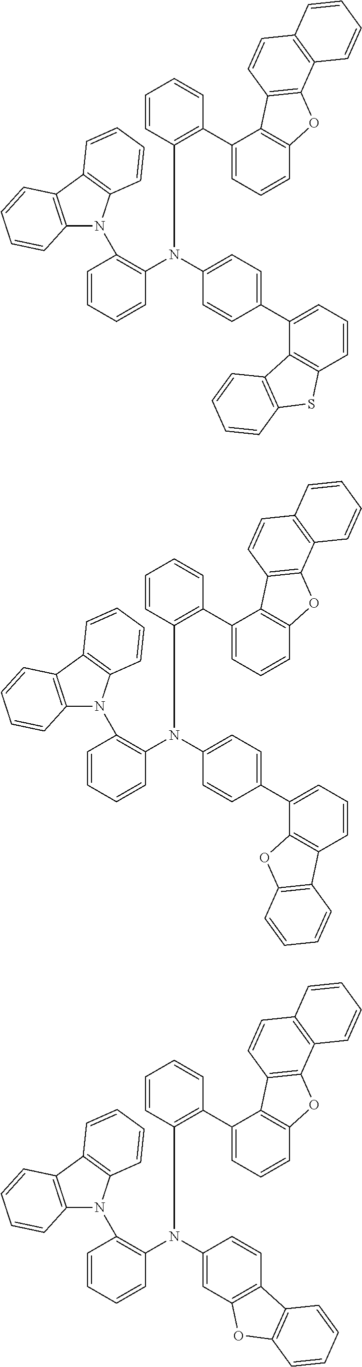

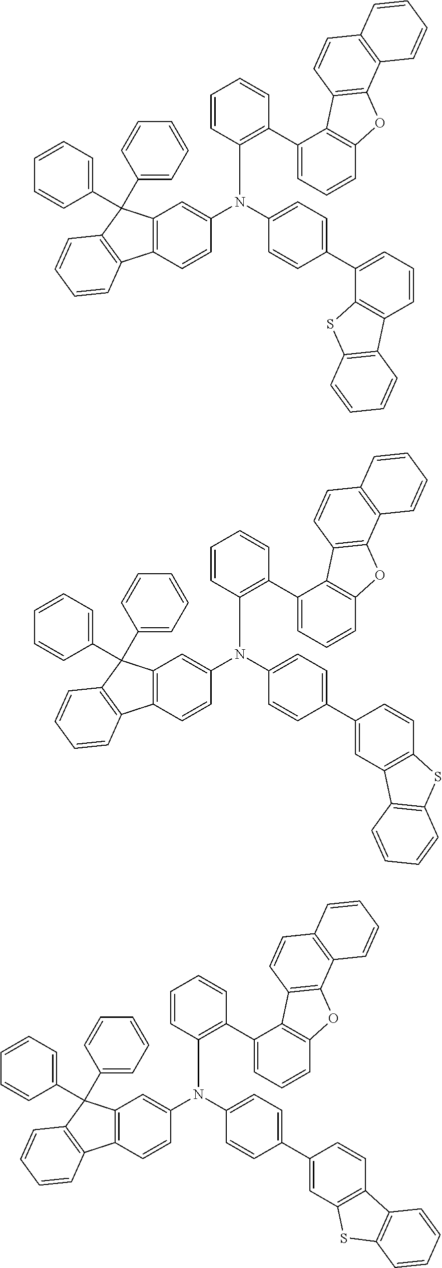 [SMILES: c1ccc(C2(c3ccccc3)c3ccccc3-c3ccc(N(c4ccc(-c5cccc6c5sc5ccccc56)cc4)c4ccccc4-c4cccc5oc6c7ccccc7ccc6c45)cc32)cc1 ; c1ccc(C2(c3ccccc3)c3ccccc3-c3ccc(N(c4ccc(-c5ccc6sc7ccccc7c6c5)cc4)c4ccccc4-c4cccc5oc6c7ccccc7ccc6c45)cc32)cc1 ; c1ccc(C2(c3ccccc3)c3ccccc3-c3ccc(N(c4ccc(-c5ccc6c(c5)sc5ccccc56)cc4)c4ccccc4-c4cccc5oc6c7ccccc7ccc6c45)cc32)cc1]

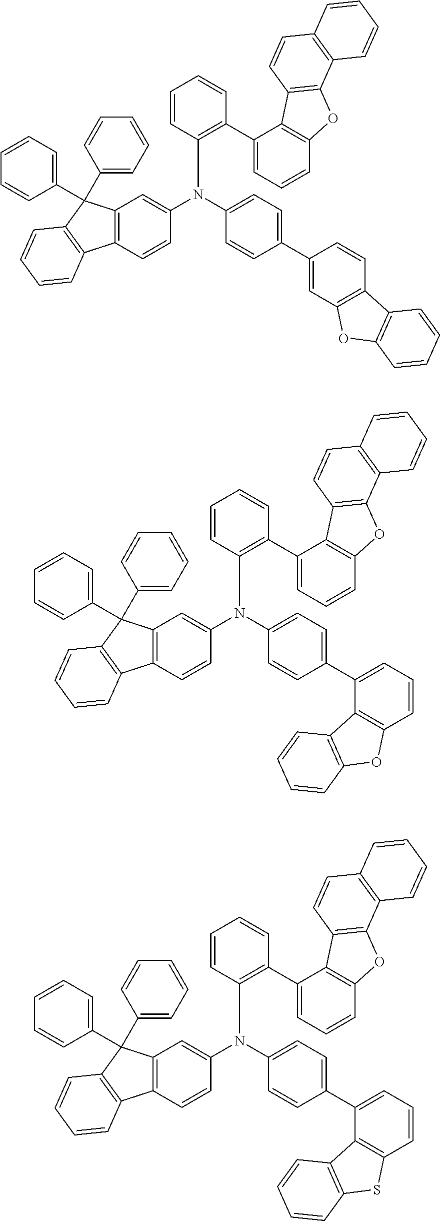

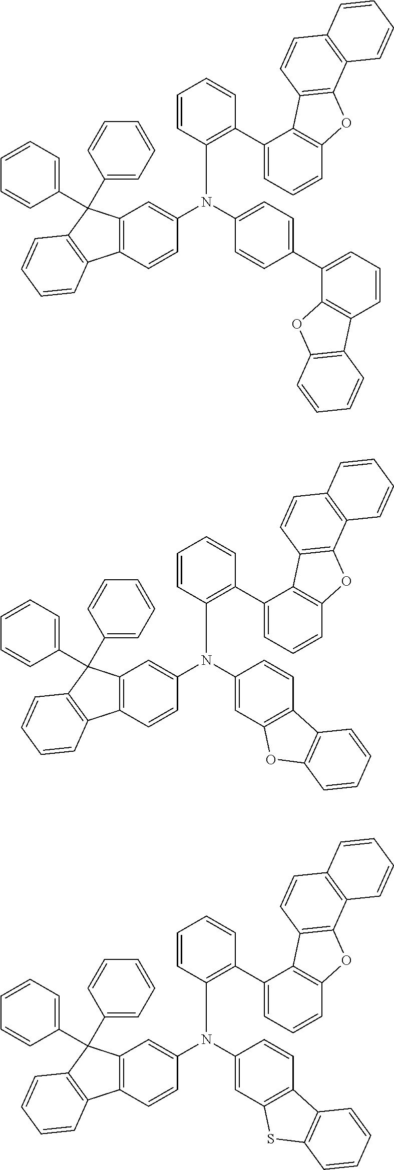 [SMILES: c1ccc(C2(c3ccccc3)c3ccccc3-c3ccc(N(c4ccc(-c5cccc6c5oc5ccccc56)cc4)c4ccccc4-c4cccc5oc6c7ccccc7ccc6c45)cc32)cc1 ; c1ccc(C2(c3ccccc3)c3ccccc3-c3ccc(N(c4ccc5c(c4)oc4ccccc45)c4ccccc4-c4cccc5oc6c7ccccc7ccc6c45)cc32)cc1 ; c1ccc(C2(c3ccccc3)c3ccccc3-c3ccc(N(c4ccc5c(c4)sc4ccccc45)c4ccccc4-c4cccc5oc6c7ccccc7ccc6c45)cc32)cc1]

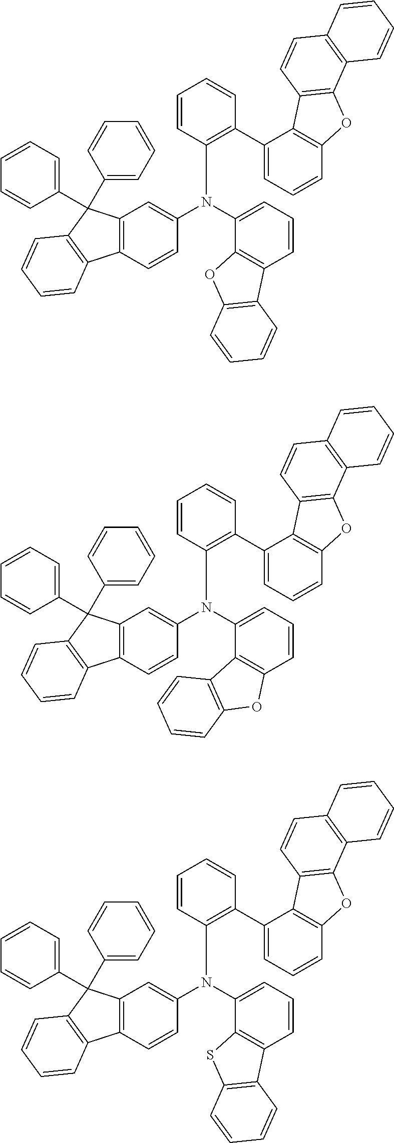 [SMILES: c1ccc(C2(c3ccccc3)c3ccccc3-c3ccc(N(c4ccccc4-c4cccc5oc6c7ccccc7ccc6c45)c4cccc5c4oc4ccccc45)cc32)cc1 ; c1ccc(C2(c3ccccc3)c3ccccc3-c3ccc(N(c4ccccc4-c4cccc5oc6c7ccccc7ccc6c45)c4cccc5oc6ccccc6c45)cc32)cc1 ; c1ccc(C2(c3ccccc3)c3ccccc3-c3ccc(N(c4ccccc4-c4cccc5oc6c7ccccc7ccc6c45)c4cccc5c4sc4ccccc45)cc32)cc1]

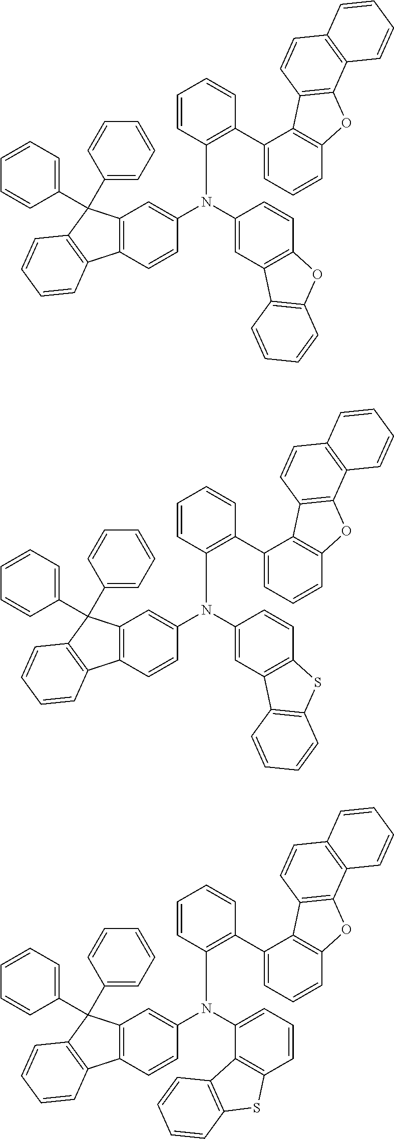 [SMILES: c1ccc(C2(c3ccccc3)c3ccccc3-c3ccc(N(c4ccc5oc6ccccc6c5c4)c4ccccc4-c4cccc5oc6c7ccccc7ccc6c45)cc32)cc1 ; c1ccc(C2(c3ccccc3)c3ccccc3-c3ccc(N(c4ccc5sc6ccccc6c5c4)c4ccccc4-c4cccc5oc6c7ccccc7ccc6c45)cc32)cc1 ; c1ccc(C2(c3ccccc3)c3ccccc3-c3ccc(N(c4ccccc4-c4cccc5oc6c7ccccc7ccc6c45)c4cccc5sc6ccccc6c45)cc32)cc1]

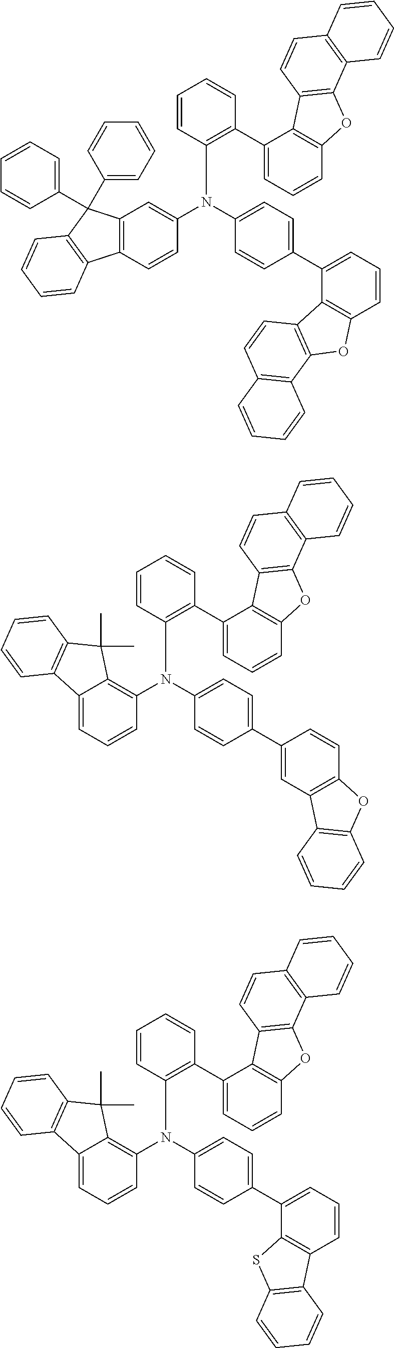

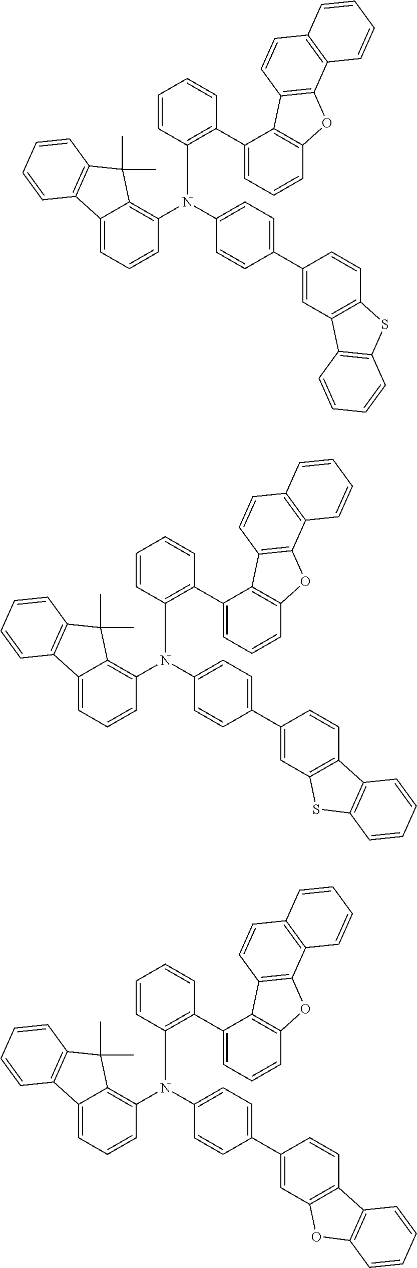 [SMILES: CC1(C)c2ccccc2-c2cccc(N(c3ccc(-c4ccc5sc6ccccc6c5c4)cc3)c3ccccc3-c3cccc4oc5c6ccccc6ccc5c34)c21 ; CC1(C)c2ccccc2-c2cccc(N(c3ccc(-c4ccc5c(c4)sc4ccccc45)cc3)c3ccccc3-c3cccc4oc5c6ccccc6ccc5c34)c21 ; CC1(C)c2ccccc2-c2cccc(N(c3ccc(-c4ccc5c(c4)oc4ccccc45)cc3)c3ccccc3-c3cccc4oc5c6ccccc6ccc5c34)c21]

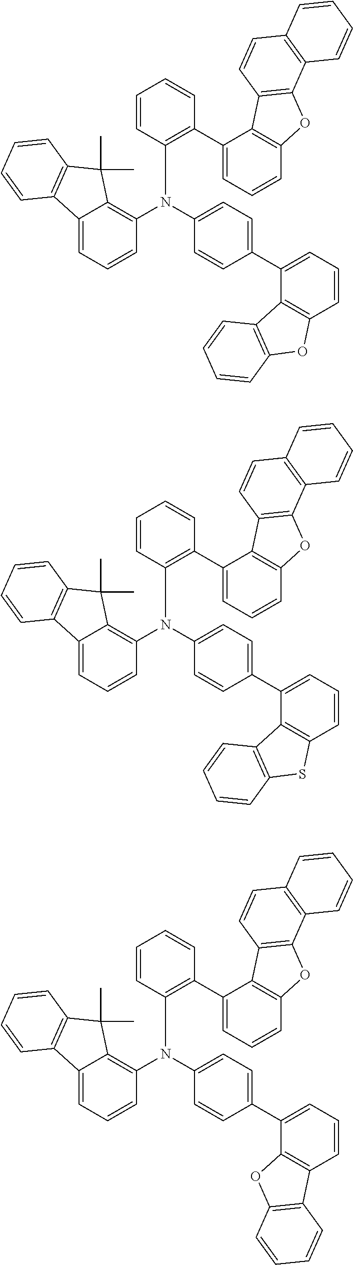 [SMILES: CC1(C)c2ccccc2-c2cccc(N(c3ccc(-c4cccc5oc6ccccc6c45)cc3)c3ccccc3-c3cccc4oc5c6ccccc6ccc5c34)c21 ; CC1(C)c2ccccc2-c2cccc(N(c3ccc(-c4cccc5sc6ccccc6c45)cc3)c3ccccc3-c3cccc4oc5c6ccccc6ccc5c34)c21 ; CC1(C)c2ccccc2-c2cccc(N(c3ccc(-c4cccc5c4oc4ccccc45)cc3)c3ccccc3-c3cccc4oc5c6ccccc6ccc5c34)c21]

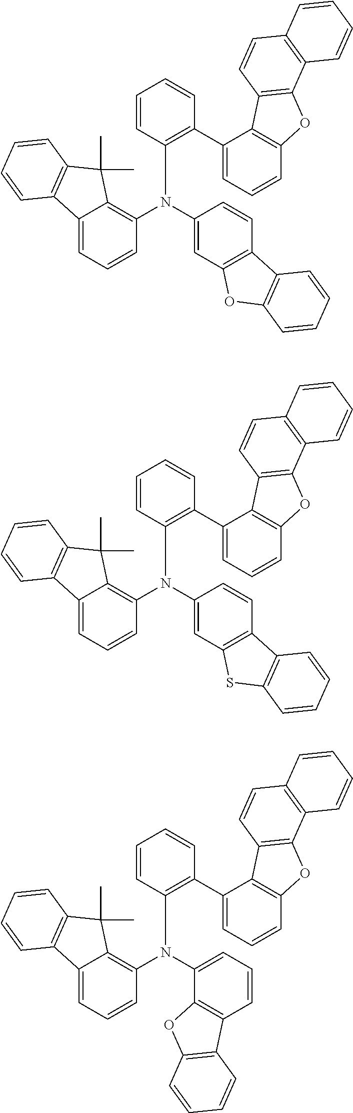

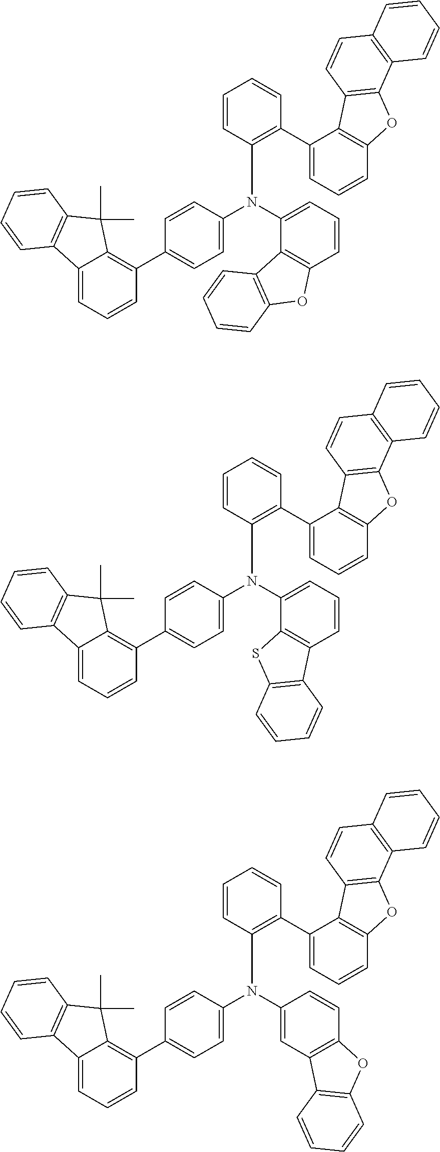 [SMILES: CC1(C)c2ccccc2-c2cccc(-c3ccc(N(c4ccccc4-c4cccc5oc6c7ccccc7ccc6c45)c4cccc5oc6ccccc6c45)cc3)c21 ; CC1(C)c2ccccc2-c2cccc(-c3ccc(N(c4ccccc4-c4cccc5oc6c7ccccc7ccc6c45)c4cccc5c4sc4ccccc45)cc3)c21 ; CC1(C)c2ccccc2-c2cccc(-c3ccc(N(c4ccc5oc6ccccc6c5c4)c4ccccc4-c4cccc5oc6c7ccccc7ccc6c45)cc3)c21]

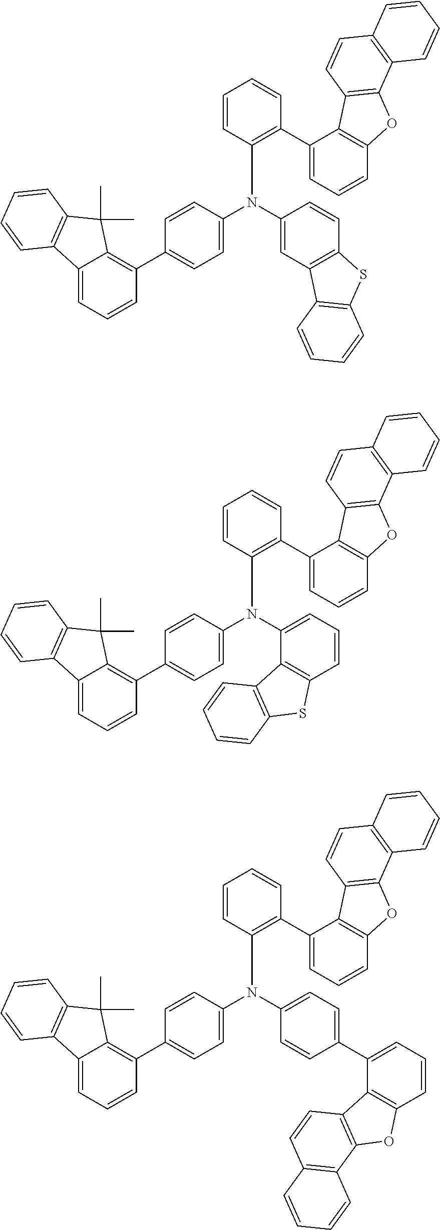 [SMILES: CC1(C)c2ccccc2-c2cccc(-c3ccc(N(c4ccc5sc6ccccc6c5c4)c4ccccc4-c4cccc5oc6c7ccccc7ccc6c45)cc3)c21 ; CC1(C)c2ccccc2-c2cccc(-c3ccc(N(c4ccccc4-c4cccc5oc6c7ccccc7ccc6c45)c4cccc5sc6ccccc6c45)cc3)c21 ; CC1(C)c2ccccc2-c2cccc(-c3ccc(N(c4ccc(-c5cccc6oc7c8ccccc8ccc7c56)cc4)c4ccccc4-c4cccc5oc6c7ccccc7ccc6c45)cc3)c21]

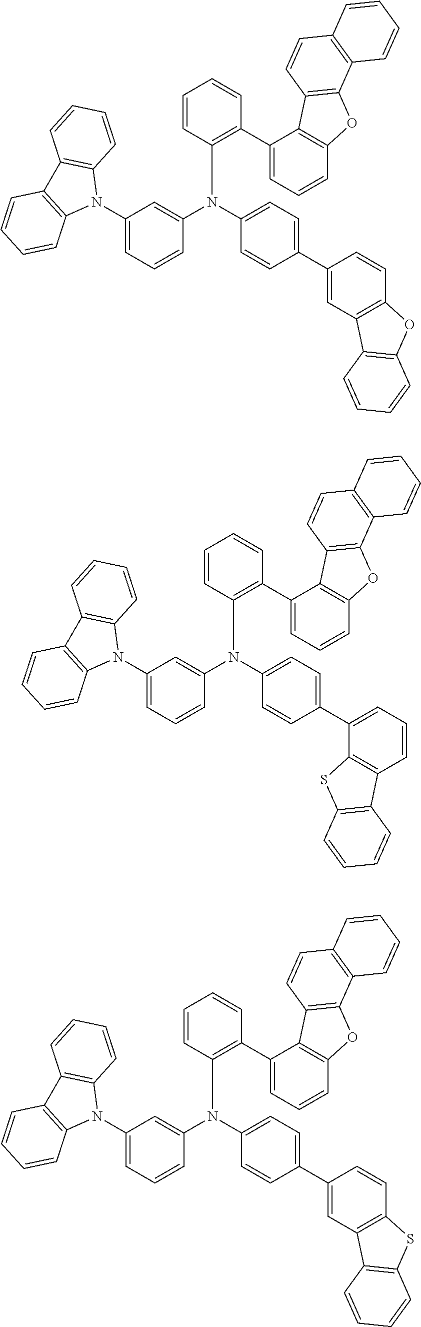

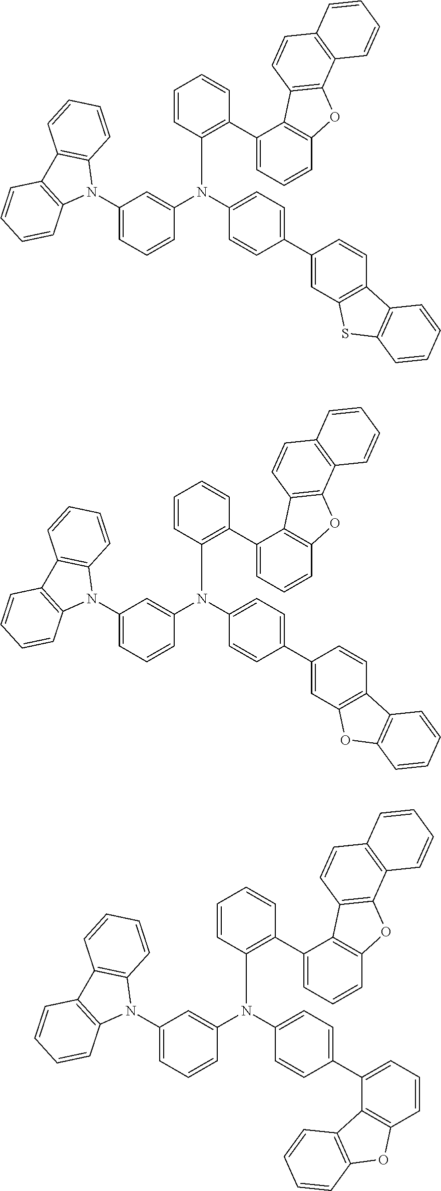

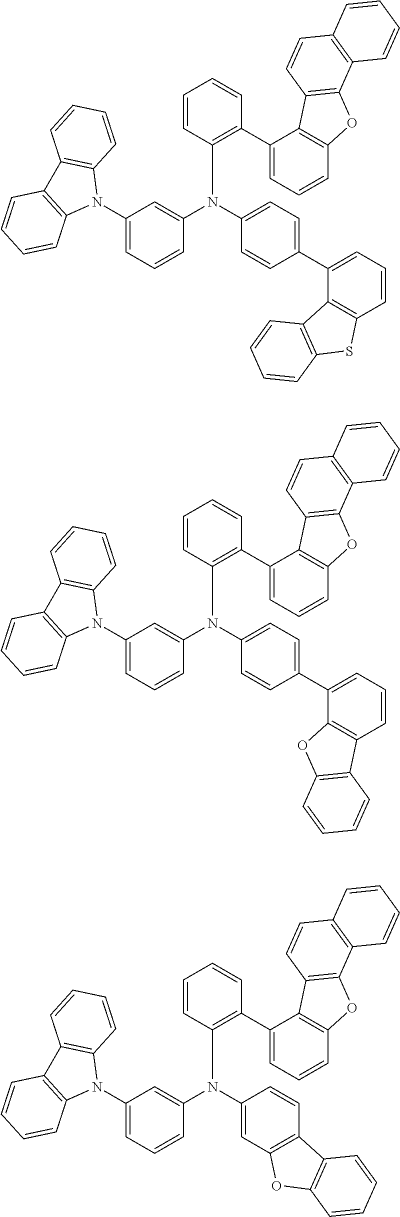 [SMILES: c1cc(N(c2ccc(-c3cccc4sc5ccccc5c34)cc2)c2ccccc2-c2cccc3oc4c5ccccc5ccc4c23)cc(-n2c3ccccc3c3ccccc32)c1 ; c1cc(N(c2ccc(-c3cccc4c3oc3ccccc34)cc2)c2ccccc2-c2cccc3oc4c5ccccc5ccc4c23)cc(-n2c3ccccc3c3ccccc32)c1 ; c1cc(N(c2ccc3c(c2)oc2ccccc23)c2ccccc2-c2cccc3oc4c5ccccc5ccc4c23)cc(-n2c3ccccc3c3ccccc32)c1]

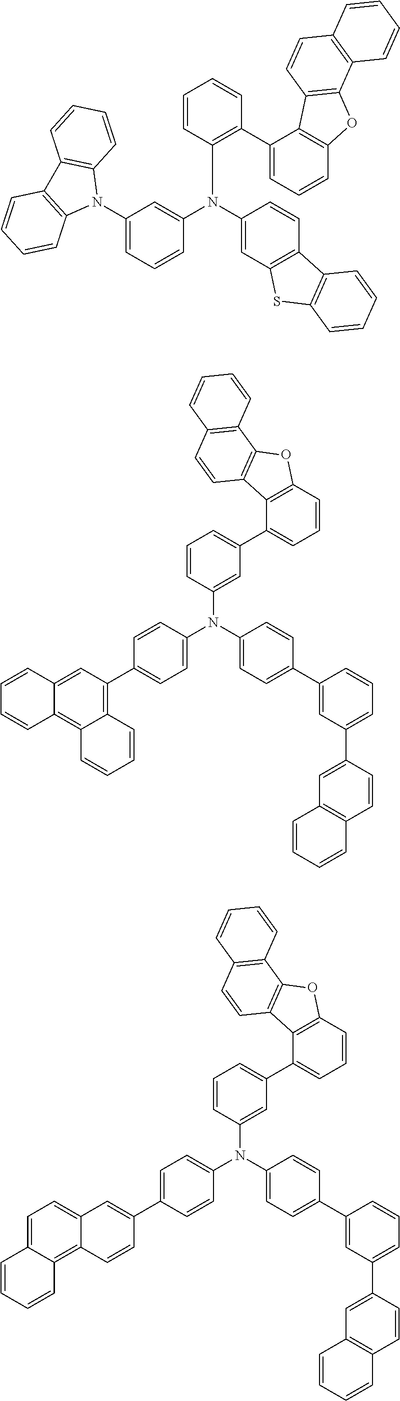 [SMILES: c1cc(N(c2ccc3c(c2)sc2ccccc23)c2ccccc2-c2cccc3oc4c5ccccc5ccc4c23)cc(-n2c3ccccc3c3ccccc32)c1 ; c1cc(-c2ccc(N(c3ccc(-c4cc5ccccc5c5ccccc45)cc3)c3cccc(-c4cccc5oc6c7ccccc7ccc6c45)c3)cc2)cc(-c2ccc3ccccc3c2)c1 ; c1cc(-c2ccc(N(c3ccc(-c4ccc5c(ccc6ccccc65)c4)cc3)c3cccc(-c4cccc5oc6c7ccccc7ccc6c45)c3)cc2)cc(-c2ccc3ccccc3c2)c1]

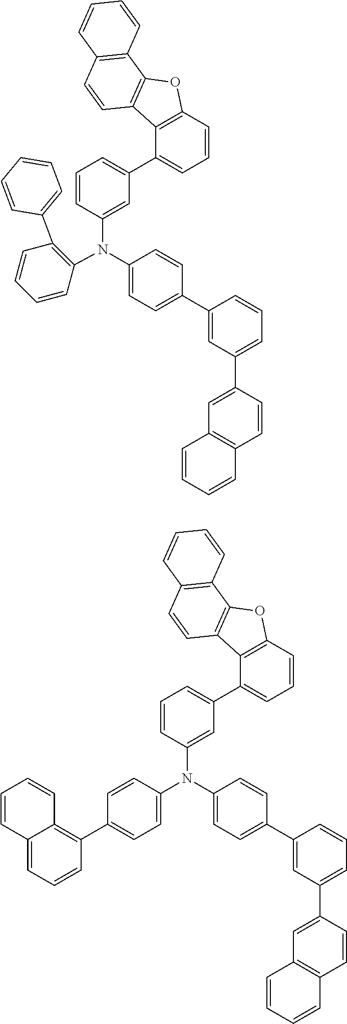

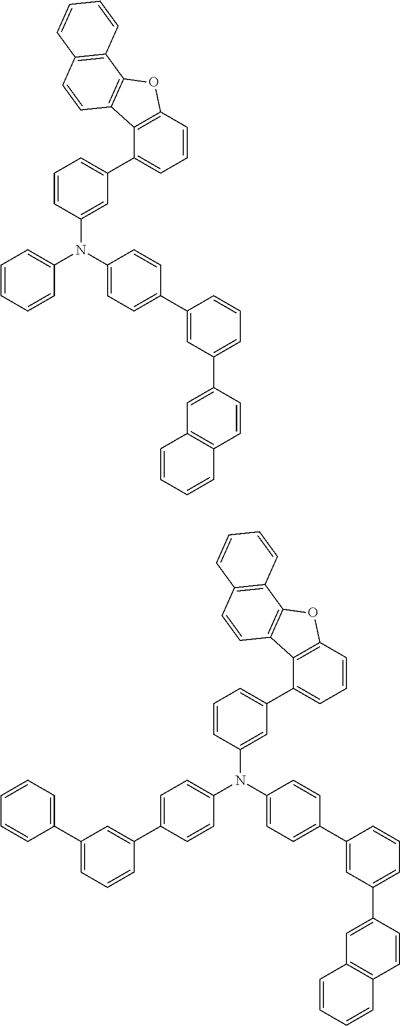 [SMILES: c1ccc(N(c2ccc(-c3cccc(-c4ccc5ccccc5c4)c3)cc2)c2cccc(-c3cccc4oc5c6ccccc6ccc5c34)c2)cc1 ; c1ccc(-c2cccc(-c3ccc(N(c4ccc(-c5cccc(-c6ccc7ccccc7c6)c5)cc4)c4cccc(-c5cccc6oc7c8ccccc8ccc7c56)c4)cc3)c2)cc1]

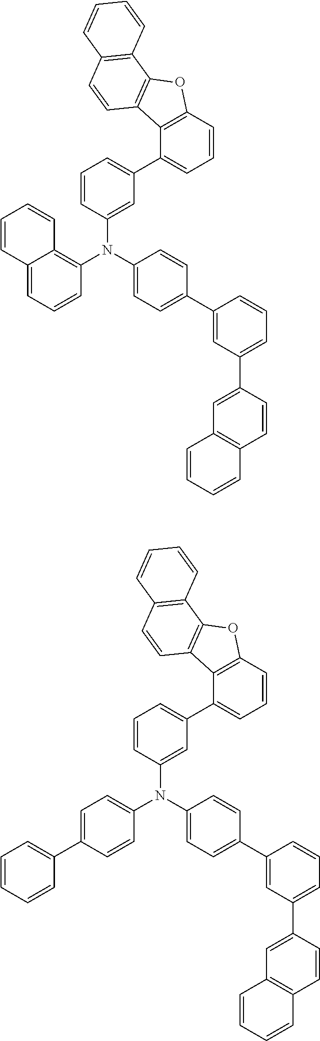 [SMILES: c1cc(-c2ccc(N(c3cccc(-c4cccc5oc6c7ccccc7ccc6c45)c3)c3cccc4ccccc34)cc2)cc(-c2ccc3ccccc3c2)c1 ; c1ccc(-c2ccc(N(c3ccc(-c4cccc(-c5ccc6ccccc6c5)c4)cc3)c3cccc(-c4cccc5oc6c7ccccc7ccc6c45)c3)cc2)cc1]

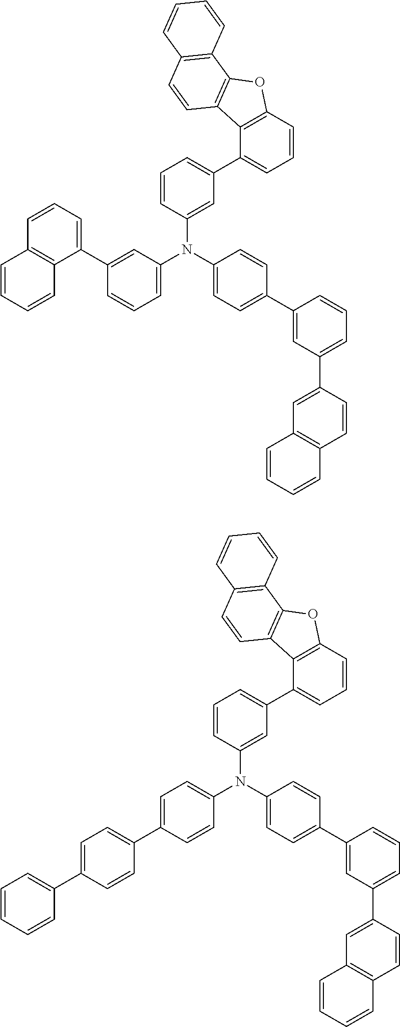 [SMILES: c1cc(-c2ccc(N(c3cccc(-c4cccc5ccccc45)c3)c3cccc(-c4cccc5oc6c7ccccc7ccc6c45)c3)cc2)cc(-c2ccc3ccccc3c2)c1 ; c1ccc(-c2ccc(-c3ccc(N(c4ccc(-c5cccc(-c6ccc7ccccc7c6)c5)cc4)c4cccc(-c5cccc6oc7c8ccccc8ccc7c56)c4)cc3)cc2)cc1]

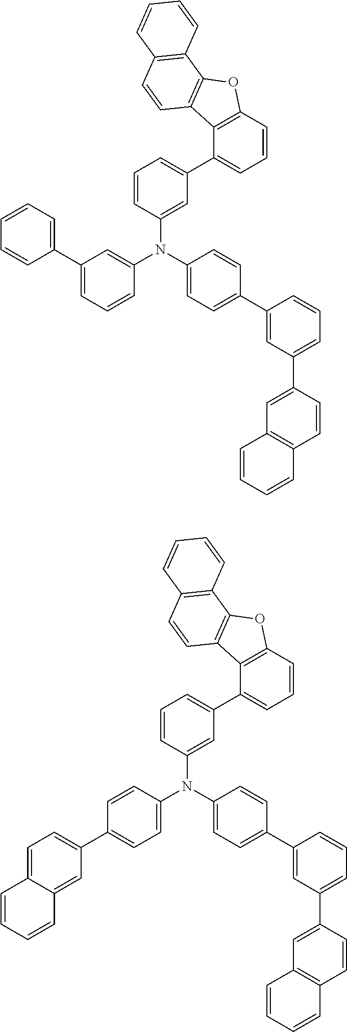 [SMILES: c1ccc(-c2cccc(N(c3ccc(-c4cccc(-c5ccc6ccccc6c5)c4)cc3)c3cccc(-c4cccc5oc6c7ccccc7ccc6c45)c3)c2)cc1 ; c1cc(-c2ccc(N(c3ccc(-c4ccc5ccccc5c4)cc3)c3cccc(-c4cccc5oc6c7ccccc7ccc6c45)c3)cc2)cc(-c2ccc3ccccc3c2)c1]

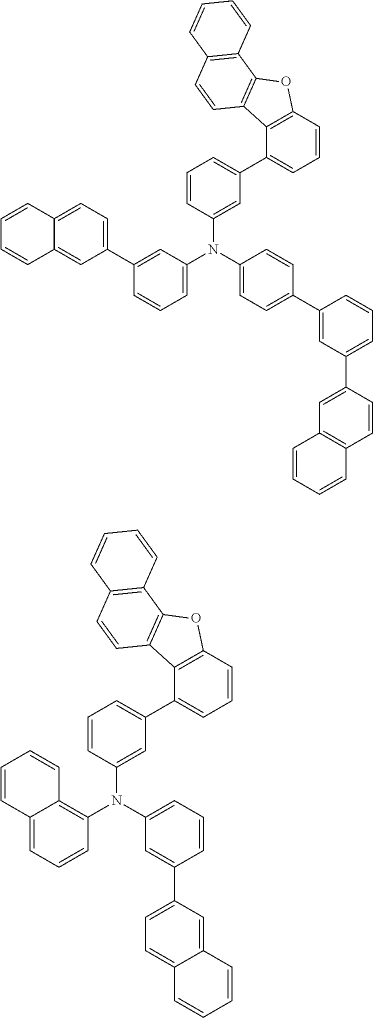 [SMILES: c1cc(-c2ccc(N(c3cccc(-c4ccc5ccccc5c4)c3)c3cccc(-c4cccc5oc6c7ccccc7ccc6c45)c3)cc2)cc(-c2ccc3ccccc3c2)c1 ; c1cc(-c2ccc3ccccc3c2)cc(N(c2cccc(-c3cccc4oc5c6ccccc6ccc5c34)c2)c2cccc3ccccc23)c1]

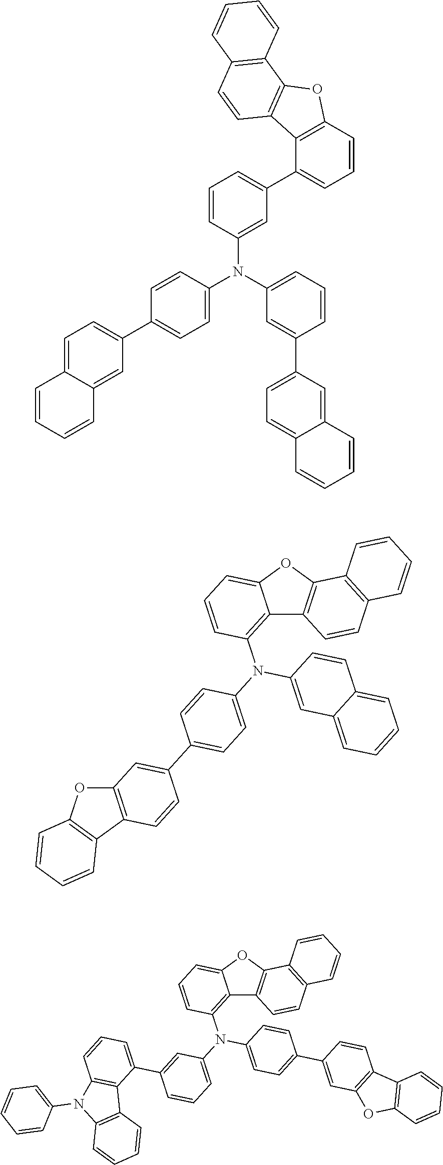 [SMILES: c1cc(-c2ccc3ccccc3c2)cc(N(c2ccc(-c3ccc4ccccc4c3)cc2)c2cccc(-c3cccc4oc5c6ccccc6ccc5c34)c2)c1 ; c1ccc2cc(N(c3ccc(-c4ccc5c(c4)oc4ccccc45)cc3)c3cccc4oc5c6ccccc6ccc5c34)ccc2c1 ; c1ccc(-n2c3ccccc3c3c(-c4cccc(N(c5ccc(-c6ccc7c(c6)oc6ccccc67)cc5)c5cccc6oc7c8ccccc8ccc7c56)c4)cccc32)cc1]

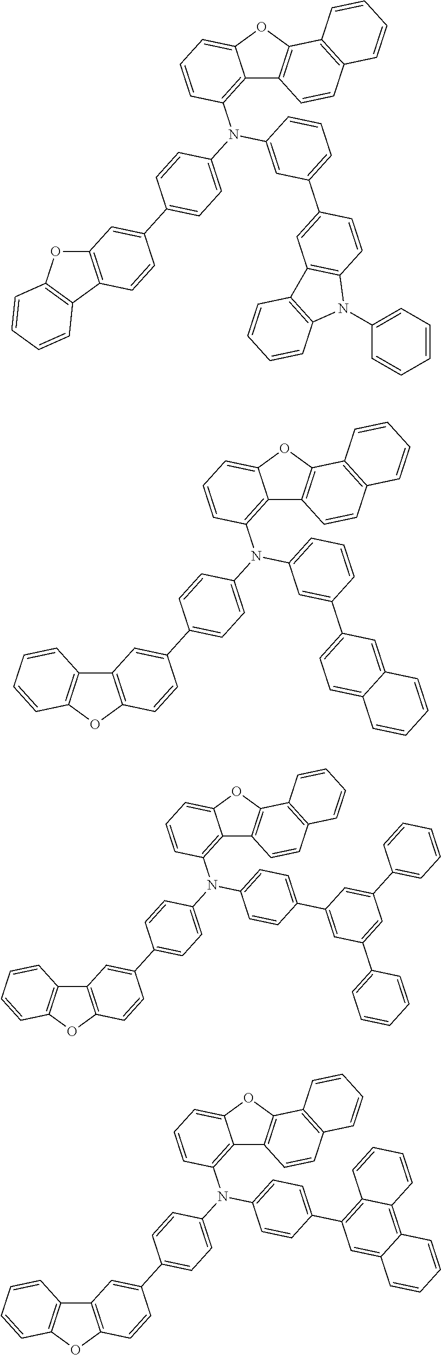 [SMILES: c1ccc(-n2c3ccccc3c3cc(-c4cccc(N(c5ccc(-c6ccc7c(c6)oc6ccccc67)cc5)c5cccc6oc7c8ccccc8ccc7c56)c4)ccc32)cc1 ; c1cc(-c2ccc3ccccc3c2)cc(N(c2ccc(-c3ccc4oc5ccccc5c4c3)cc2)c2cccc3oc4c5ccccc5ccc4c23)c1 ; c1ccc(-c2cc(-c3ccccc3)cc(-c3ccc(N(c4ccc(-c5ccc6oc7ccccc7c6c5)cc4)c4cccc5oc6c7ccccc7ccc6c45)cc3)c2)cc1 ; c1ccc2c(c1)cc(-c1ccc(N(c3ccc(-c4ccc5oc6ccccc6c5c4)cc3)c3cccc4oc5c6ccccc6ccc5c34)cc1)c1ccccc12]

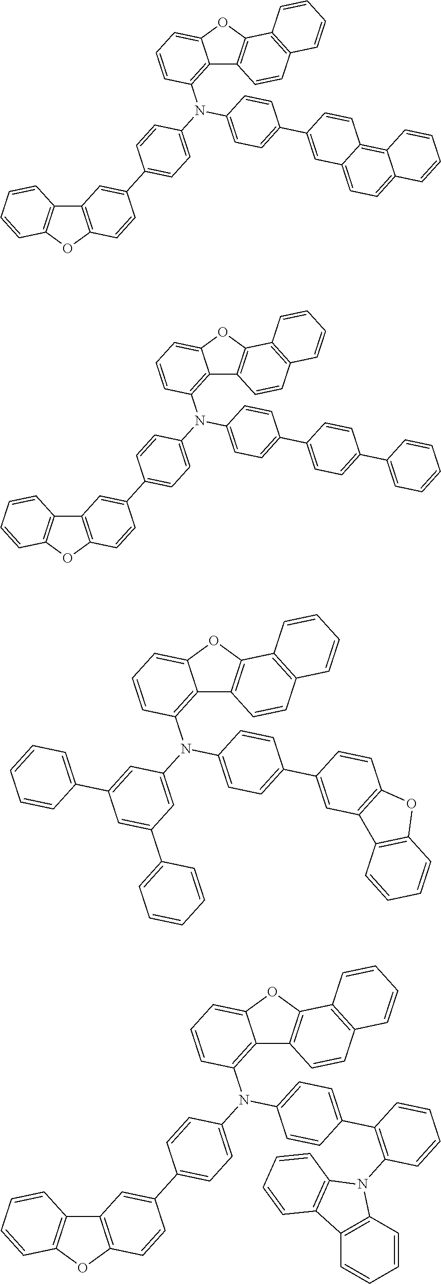 [SMILES: c1ccc2c(c1)ccc1cc(-c3ccc(N(c4ccc(-c5ccc6oc7ccccc7c6c5)cc4)c4cccc5oc6c7ccccc7ccc6c45)cc3)ccc12 ; c1ccc(-c2ccc(-c3ccc(N(c4ccc(-c5ccc6oc7ccccc7c6c5)cc4)c4cccc5oc6c7ccccc7ccc6c45)cc3)cc2)cc1 ; c1ccc(-c2cc(-c3ccccc3)cc(N(c3ccc(-c4ccc5oc6ccccc6c5c4)cc3)c3cccc4oc5c6ccccc6ccc5c34)c2)cc1 ; c1ccc(-n2c3ccccc3c3ccccc32)c(-c2ccc(N(c3ccc(-c4ccc5oc6ccccc6c5c4)cc3)c3cccc4oc5c6ccccc6ccc5c34)cc2)c1]

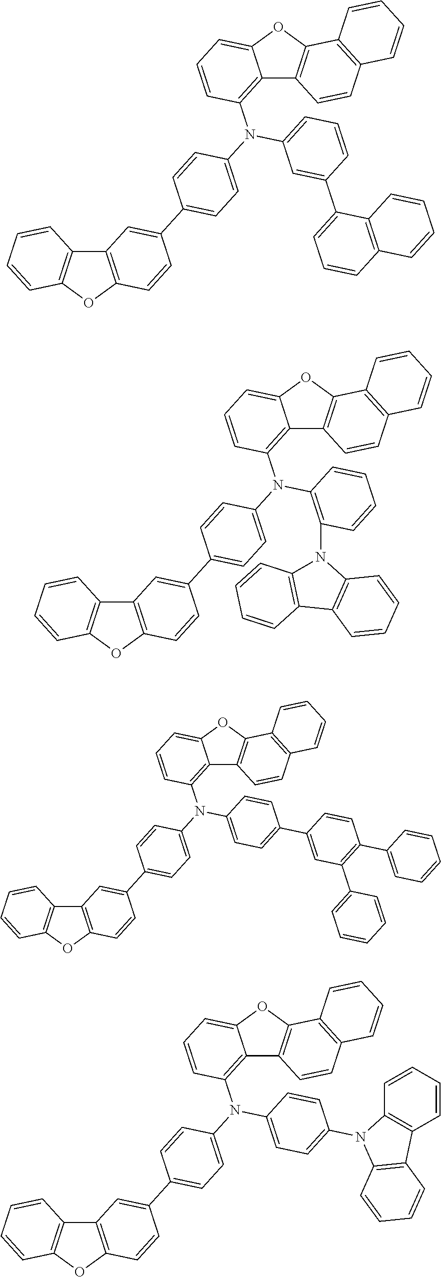

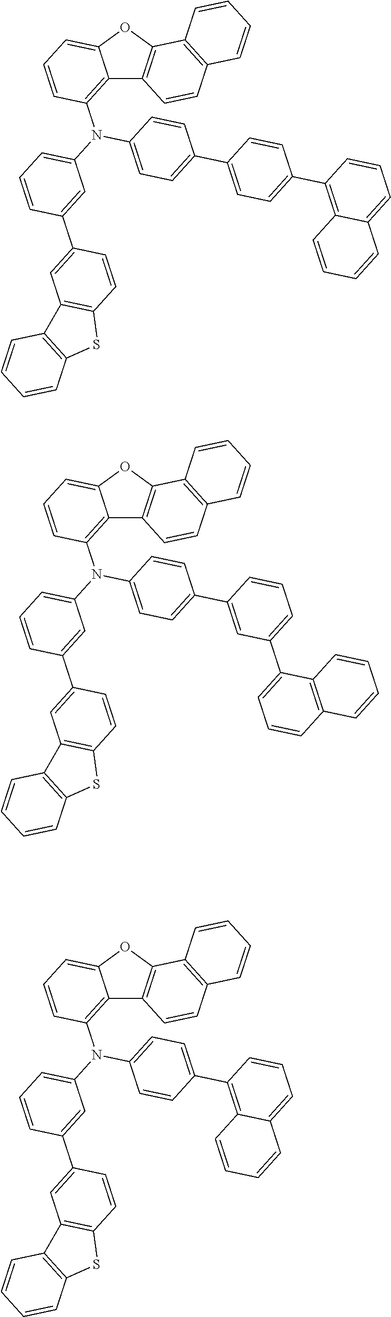 [SMILES: c1cc(-c2ccc3sc4ccccc4c3c2)cc(N(c2ccc(-c3ccc(-c4cccc5ccccc45)cc3)cc2)c2cccc3oc4c5ccccc5ccc4c23)c1 ; c1cc(-c2ccc(N(c3cccc(-c4ccc5sc6ccccc6c5c4)c3)c3cccc4oc5c6ccccc6ccc5c34)cc2)cc(-c2cccc3ccccc23)c1 ; c1cc(-c2ccc3sc4ccccc4c3c2)cc(N(c2ccc(-c3cccc4ccccc34)cc2)c2cccc3oc4c5ccccc5ccc4c23)c1]

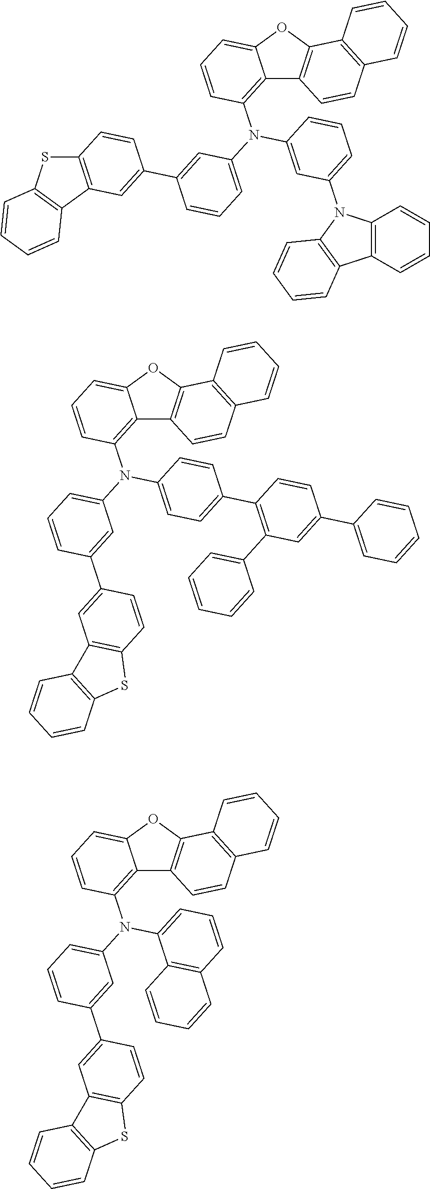 [SMILES: c1cc(-c2ccc3sc4ccccc4c3c2)cc(N(c2cccc(-n3c4ccccc4c4ccccc43)c2)c2cccc3oc4c5ccccc5ccc4c23)c1 ; c1ccc(-c2ccc(-c3ccc(N(c4cccc(-c5ccc6sc7ccccc7c6c5)c4)c4cccc5oc6c7ccccc7ccc6c45)cc3)c(-c3ccccc3)c2)cc1 ; c1cc(-c2ccc3sc4ccccc4c3c2)cc(N(c2cccc3ccccc23)c2cccc3oc4c5ccccc5ccc4c23)c1]

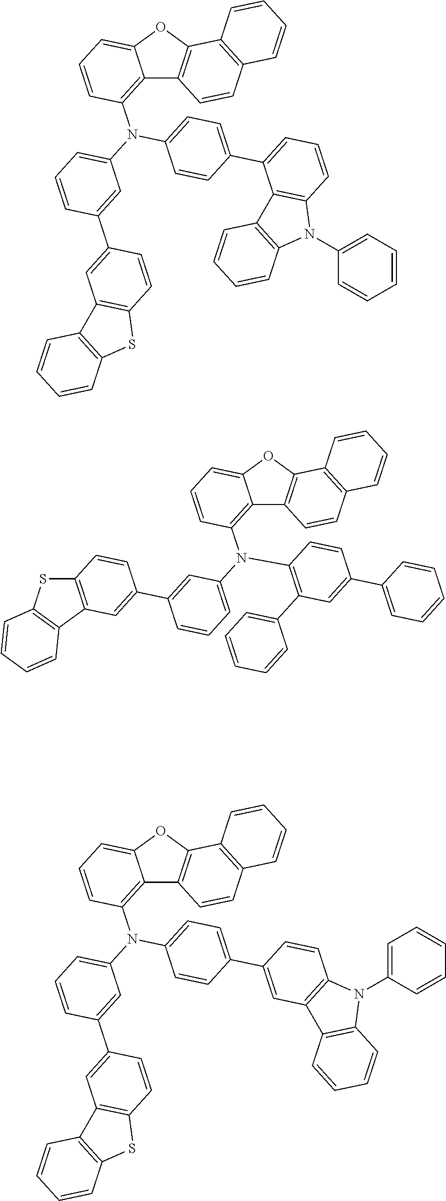 [SMILES: c1ccc(-n2c3ccccc3c3c(-c4ccc(N(c5cccc(-c6ccc7sc8ccccc8c7c6)c5)c5cccc6oc7c8ccccc8ccc7c56)cc4)cccc32)cc1 ; c1ccc(-c2ccc(N(c3cccc(-c4ccc5sc6ccccc6c5c4)c3)c3cccc4oc5c6ccccc6ccc5c34)c(-c3ccccc3)c2)cc1 ; c1ccc(-n2c3ccccc3c3cc(-c4ccc(N(c5cccc(-c6ccc7sc8ccccc8c7c6)c5)c5cccc6oc7c8ccccc8ccc7c56)cc4)ccc32)cc1]

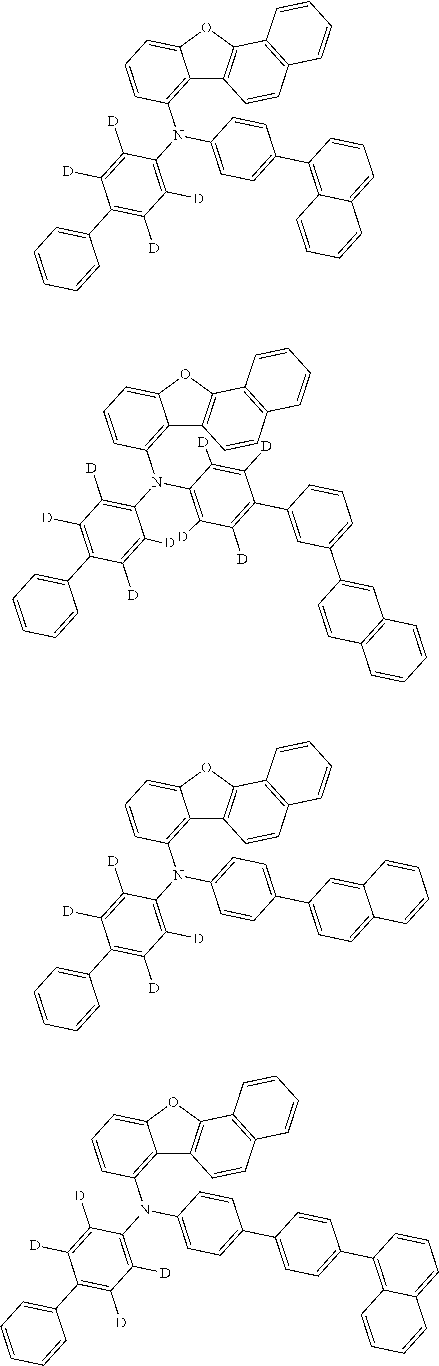 [SMILES: [2H]c1c([2H])c(N(c2ccc(-c3cccc4ccccc34)cc2)c2cccc3oc4c5ccccc5ccc4c23)c([2H])c([2H])c1-c1ccccc1 ; [2H]c1c([2H])c(N(c2c([2H])c([2H])c(-c3cccc(-c4ccc5ccccc5c4)c3)c([2H])c2[2H])c2cccc3oc4c5ccccc5ccc4c23)c([2H])c([2H])c1-c1ccccc1 ; [2H]c1c([2H])c(N(c2ccc(-c3ccc4ccccc4c3)cc2)c2cccc3oc4c5ccccc5ccc4c23)c([2H])c([2H])c1-c1ccccc1 ; [2H]c1c([2H])c(N(c2ccc(-c3ccc(-c4cccc5ccccc45)cc3)cc2)c2cccc3oc4c5ccccc5ccc4c23)c([2H])c([2H])c1-c1ccccc1]

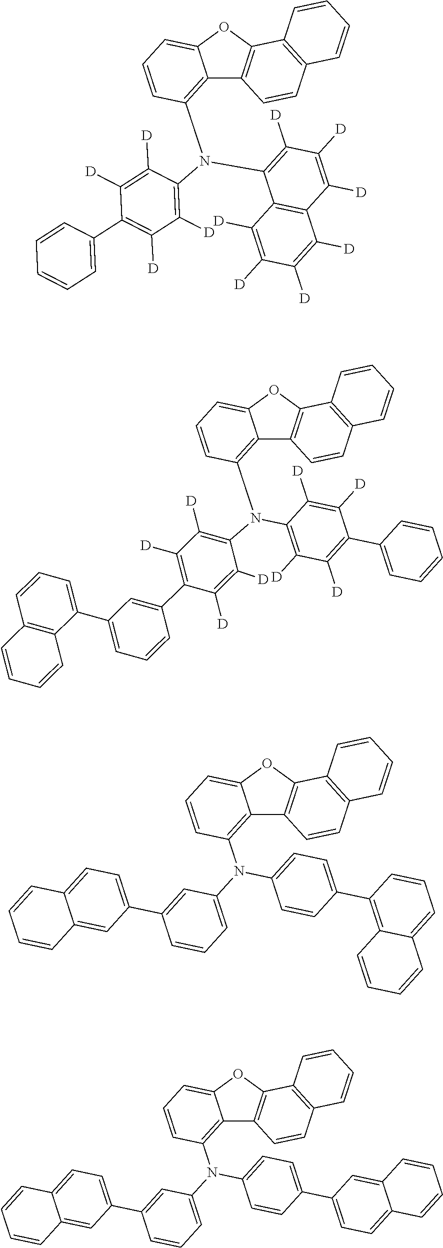 [SMILES: [2H]c1c([2H])c(N(c2c([2H])c([2H])c([2H])c3c([2H])c([2H])c([2H])c([2H])c23)c2cccc3oc4c5ccccc5ccc4c23)c([2H])c([2H])c1-c1ccccc1 ; [2H]c1c([2H])c(N(c2c([2H])c([2H])c(-c3cccc(-c4cccc5ccccc45)c3)c([2H])c2[2H])c2cccc3oc4c5ccccc5ccc4c23)c([2H])c([2H])c1-c1ccccc1 ; c1cc(-c2ccc3ccccc3c2)cc(N(c2ccc(-c3cccc4ccccc34)cc2)c2cccc3oc4c5ccccc5ccc4c23)c1 ; c1cc(-c2ccc3ccccc3c2)cc(N(c2ccc(-c3ccc4ccccc4c3)cc2)c2cccc3oc4c5ccccc5ccc4c23)c1]

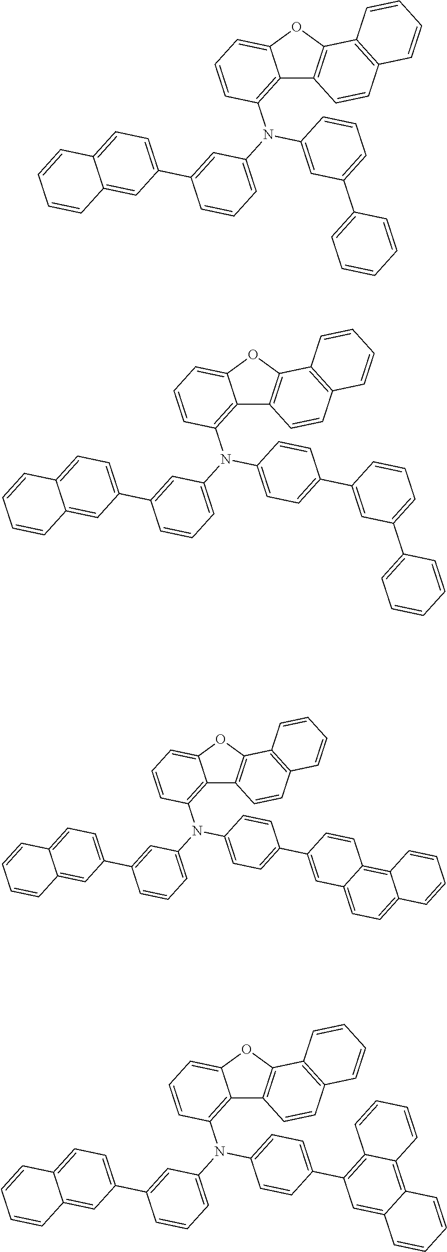 [SMILES: c1ccc(-c2cccc(N(c3cccc(-c4ccc5ccccc5c4)c3)c3cccc4oc5c6ccccc6ccc5c34)c2)cc1 ; c1ccc(-c2cccc(-c3ccc(N(c4cccc(-c5ccc6ccccc6c5)c4)c4cccc5oc6c7ccccc7ccc6c45)cc3)c2)cc1 ; c1cc(-c2ccc3ccccc3c2)cc(N(c2ccc(-c3ccc4c(ccc5ccccc54)c3)cc2)c2cccc3oc4c5ccccc5ccc4c23)c1 ; c1cc(-c2ccc3ccccc3c2)cc(N(c2ccc(-c3cc4ccccc4c4ccccc34)cc2)c2cccc3oc4c5ccccc5ccc4c23)c1]

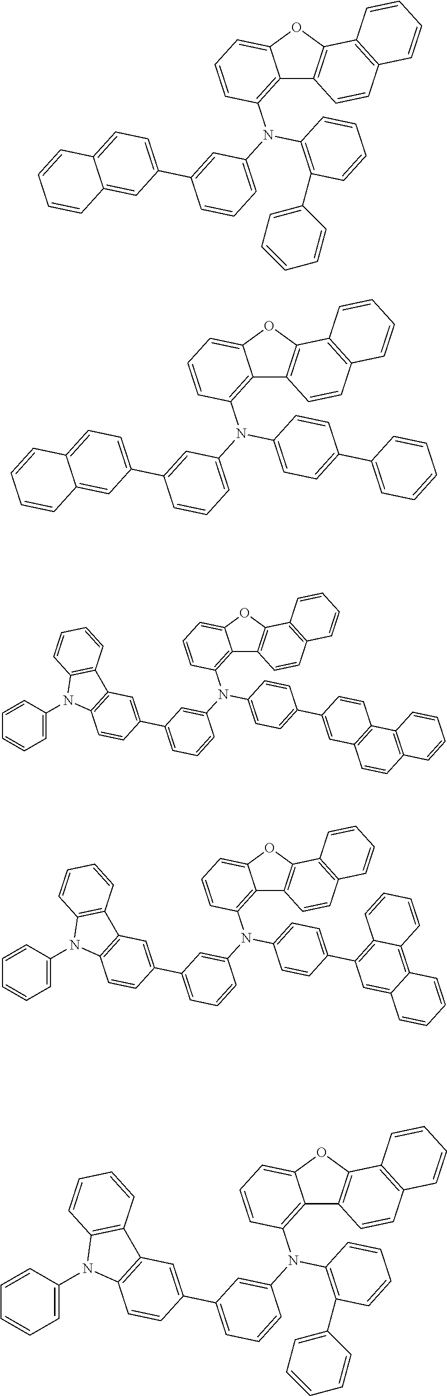 [SMILES: c1ccc(-c2ccccc2N(c2cccc(-c3ccc4ccccc4c3)c2)c2cccc3oc4c5ccccc5ccc4c23)cc1 ; c1ccc(-c2ccc(N(c3cccc(-c4ccc5ccccc5c4)c3)c3cccc4oc5c6ccccc6ccc5c34)cc2)cc1 ; c1ccc(-n2c3ccccc3c3cc(-c4cccc(N(c5ccc(-c6ccc7c(ccc8ccccc87)c6)cc5)c5cccc6oc7c8ccccc8ccc7c56)c4)ccc32)cc1 ; c1ccc(-n2c3ccccc3c3cc(-c4cccc(N(c5ccc(-c6cc7ccccc7c7ccccc67)cc5)c5cccc6oc7c8ccccc8ccc7c56)c4)ccc32)cc1 ; c1ccc(-c2ccccc2N(c2cccc(-c3ccc4c(c3)c3ccccc3n4-c3ccccc3)c2)c2cccc3oc4c5ccccc5ccc4c23)cc1]

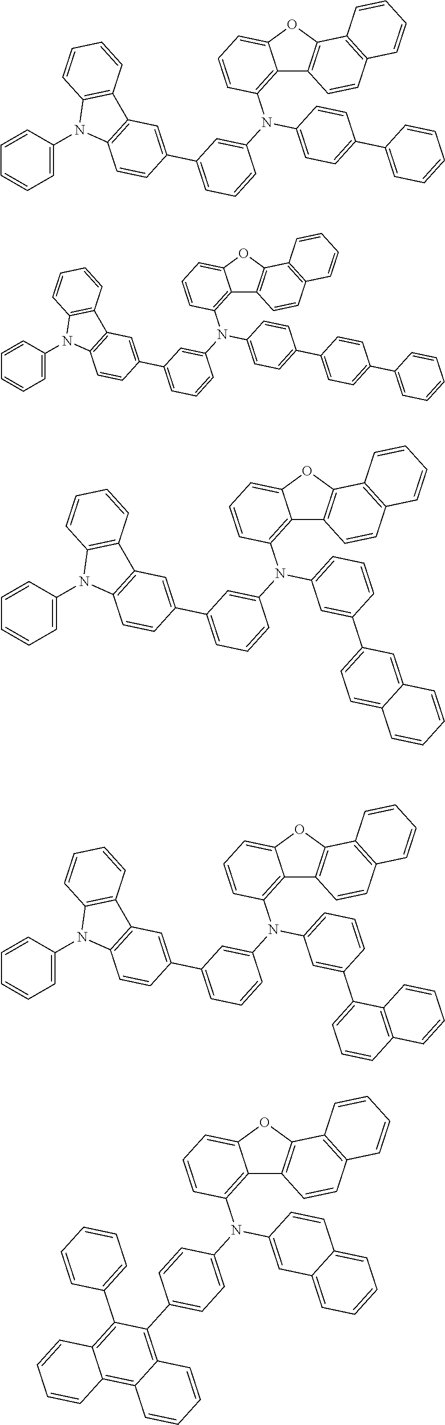

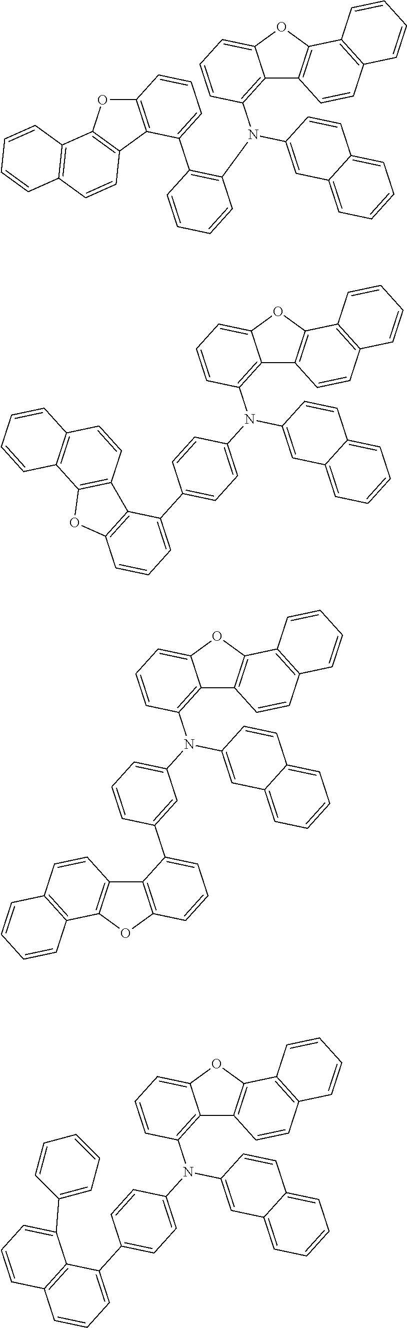 [SMILES: c1ccc(N(c2ccc3ccccc3c2)c2cccc3oc4c5ccccc5ccc4c23)c(-c2cccc3oc4c5ccccc5ccc4c23)c1 ; c1ccc2cc(N(c3ccc(-c4cccc5oc6c7ccccc7ccc6c45)cc3)c3cccc4oc5c6ccccc6ccc5c34)ccc2c1 ; c1cc(-c2cccc3oc4c5ccccc5ccc4c23)cc(N(c2ccc3ccccc3c2)c2cccc3oc4c5ccccc5ccc4c23)c1 ; c1ccc(-c2cccc3cccc(-c4ccc(N(c5ccc6ccccc6c5)c5cccc6oc7c8ccccc8ccc7c56)cc4)c23)cc1]

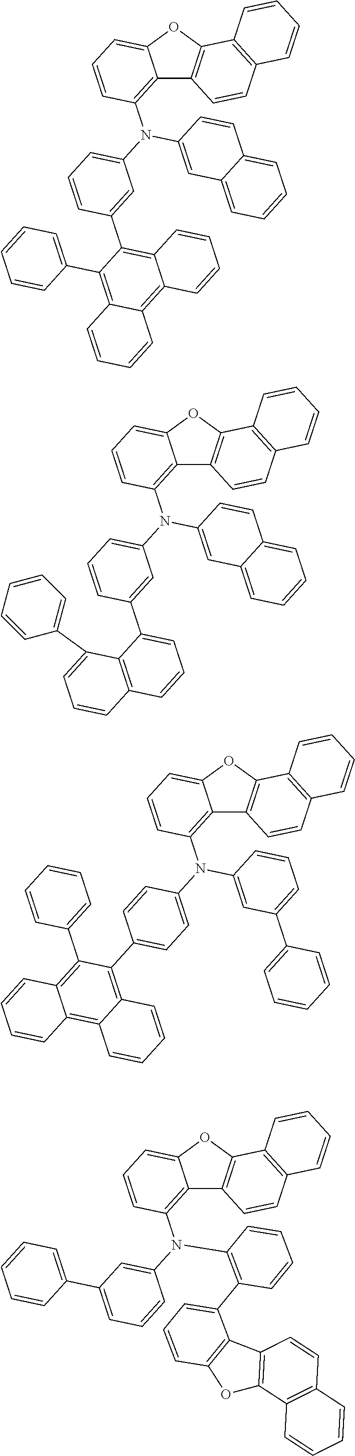 [SMILES: c1ccc(-c2c(-c3cccc(N(c4ccc5ccccc5c4)c4cccc5oc6c7ccccc7ccc6c45)c3)c3ccccc3c3ccccc23)cc1 ; c1ccc(-c2cccc3cccc(-c4cccc(N(c5ccc6ccccc6c5)c5cccc6oc7c8ccccc8ccc7c56)c4)c23)cc1 ; c1ccc(-c2cccc(N(c3ccc(-c4c(-c5ccccc5)c5ccccc5c5ccccc45)cc3)c3cccc4oc5c6ccccc6ccc5c34)c2)cc1 ; c1ccc(-c2cccc(N(c3ccccc3-c3cccc4oc5c6ccccc6ccc5c34)c3cccc4oc5c6ccccc6ccc5c34)c2)cc1]

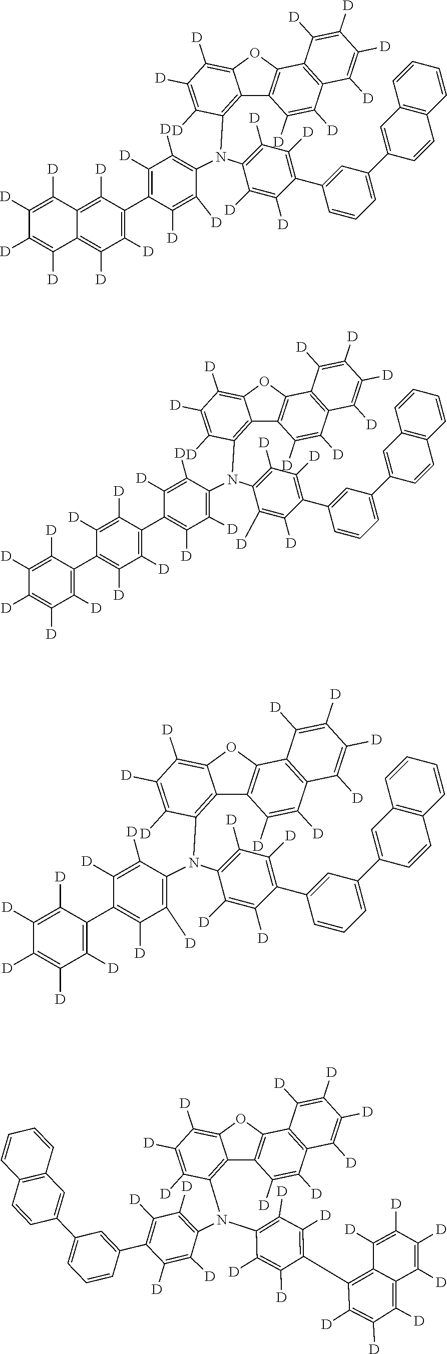

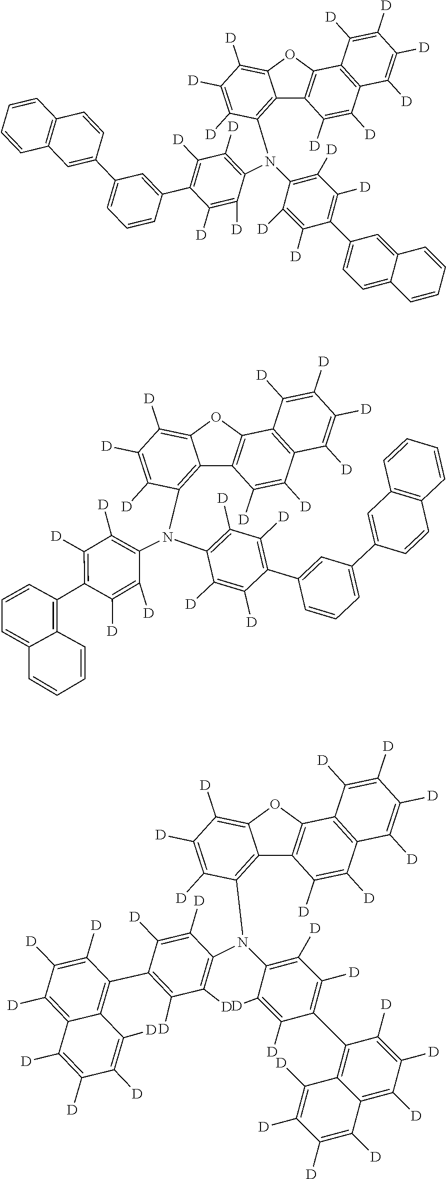

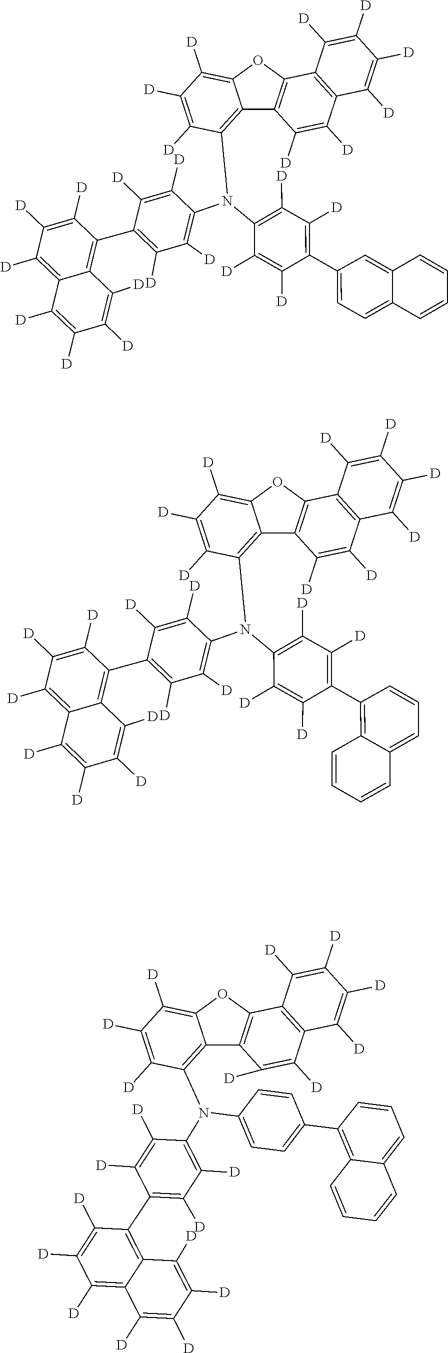

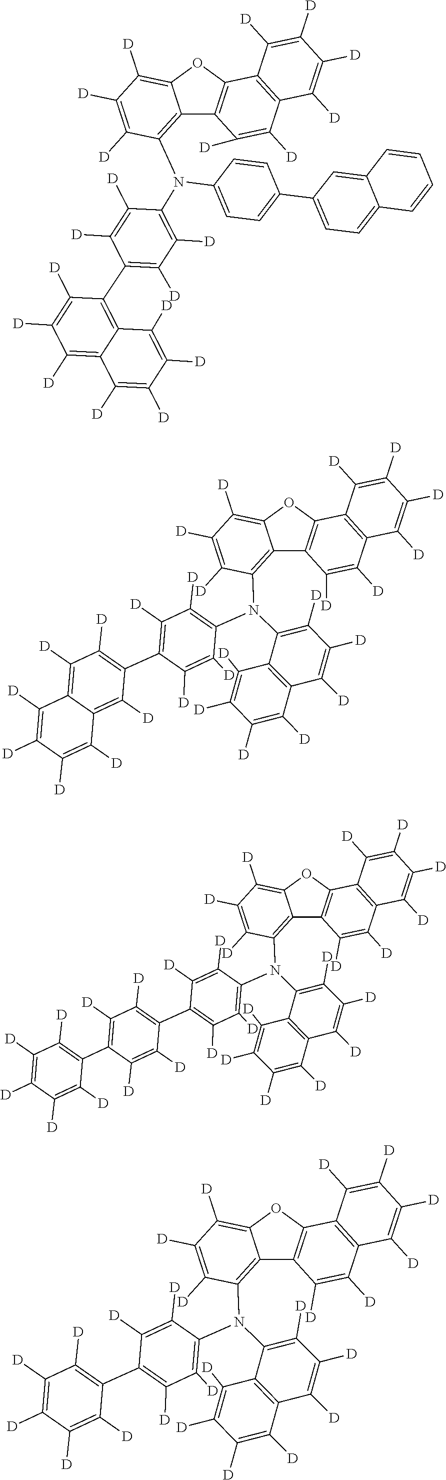

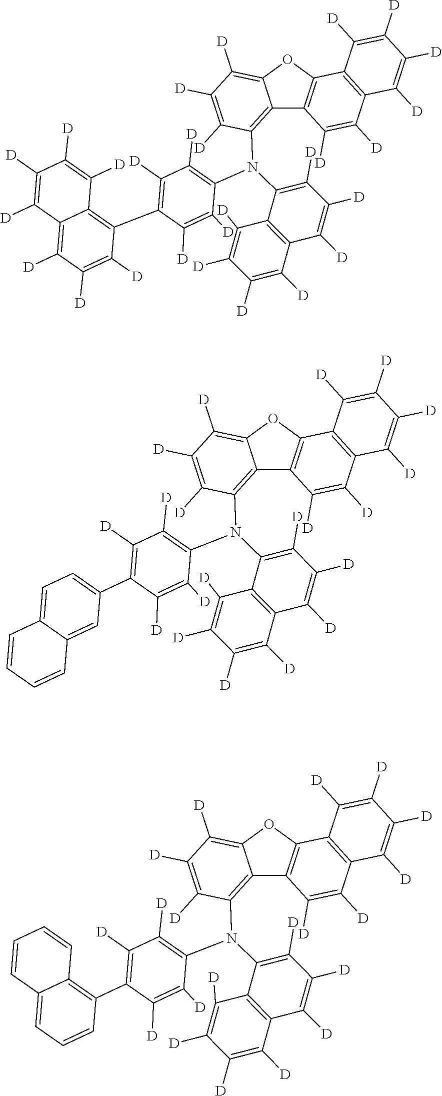

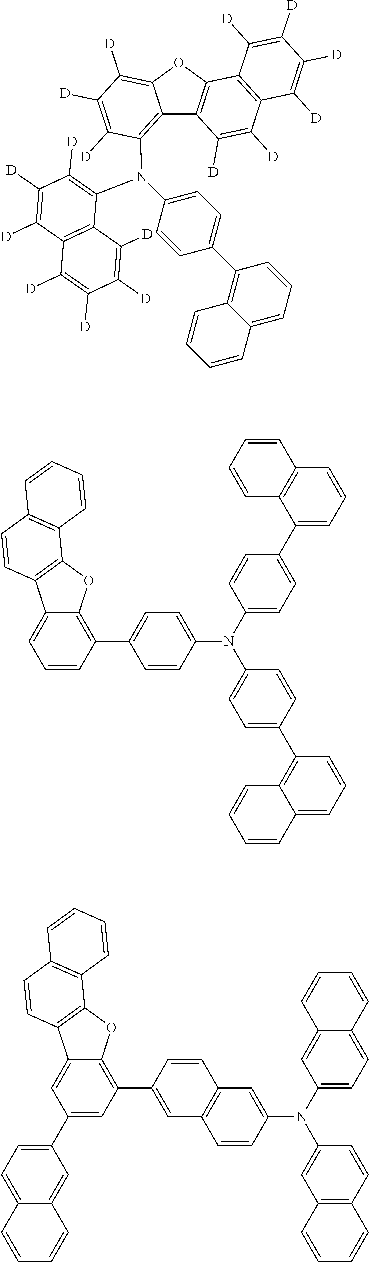 [SMILES: [2H]c1c([2H])c(N(c2ccc(-c3cccc4ccccc34)cc2)c2c([2H])c([2H])c([2H])c3c([2H])c([2H])c([2H])c([2H])c23)c2c(oc3c4c([2H])c([2H])c([2H])c([2H])c4c([2H])c([2H])c32)c1[2H] ; c1ccc2c(-c3ccc(N(c4ccc(-c5cccc6ccccc56)cc4)c4ccc(-c5cccc6c5oc5c7ccccc7ccc65)cc4)cc3)cccc2c1 ; c1ccc2cc(-c3cc(-c4ccc5cc(N(c6ccc7ccccc7c6)c6ccc7ccccc7c6)ccc5c4)c4oc5c6ccccc6ccc5c4c3)ccc2c1]

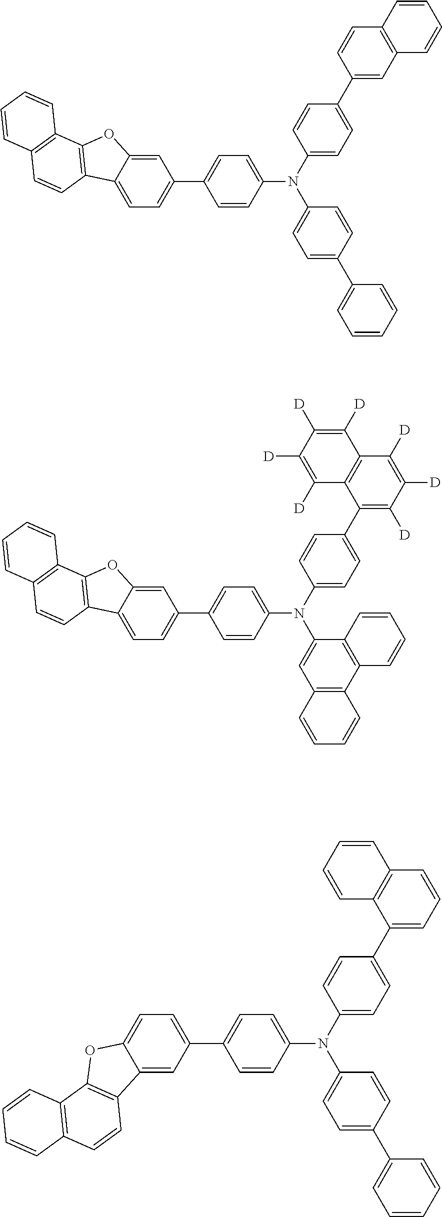 [SMILES: c1ccc(-c2ccc(N(c3ccc(-c4ccc5ccccc5c4)cc3)c3ccc(-c4ccc5c(c4)oc4c6ccccc6ccc54)cc3)cc2)cc1 ; [2H]c1c([2H])c([2H])c2c(-c3ccc(N(c4ccc(-c5ccc6c(c5)oc5c7ccccc7ccc65)cc4)c4cc5ccccc5c5ccccc45)cc3)c([2H])c([2H])c([2H])c2c1[2H] ; c1ccc(-c2ccc(N(c3ccc(-c4ccc5oc6c7ccccc7ccc6c5c4)cc3)c3ccc(-c4cccc5ccccc45)cc3)cc2)cc1]

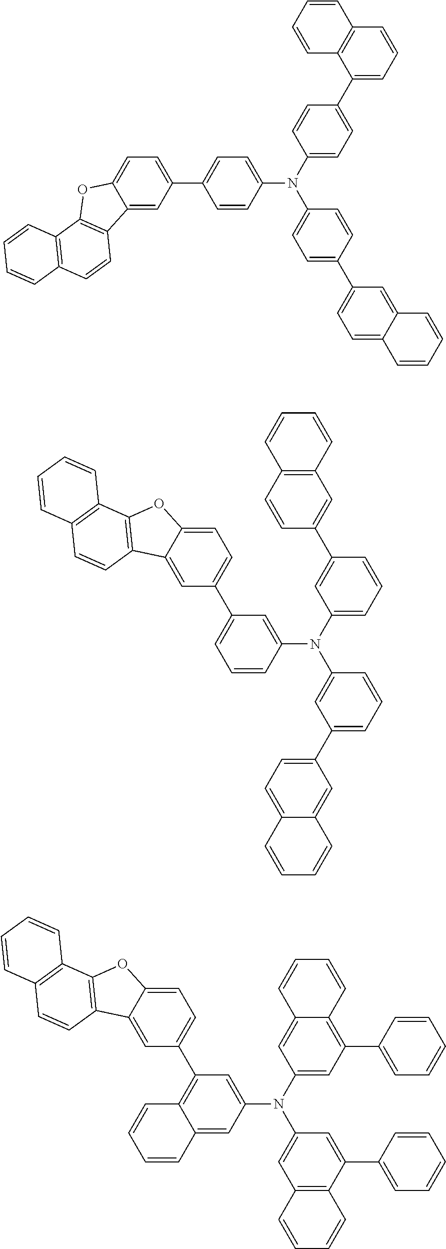 [SMILES: c1ccc2cc(-c3ccc(N(c4ccc(-c5ccc6oc7c8ccccc8ccc7c6c5)cc4)c4ccc(-c5cccc6ccccc56)cc4)cc3)ccc2c1 ; c1cc(-c2ccc3ccccc3c2)cc(N(c2cccc(-c3ccc4ccccc4c3)c2)c2cccc(-c3ccc4oc5c6ccccc6ccc5c4c3)c2)c1 ; c1ccc(-c2cc(N(c3cc(-c4ccccc4)c4ccccc4c3)c3cc(-c4ccc5oc6c7ccccc7ccc6c5c4)c4ccccc4c3)cc3ccccc23)cc1]

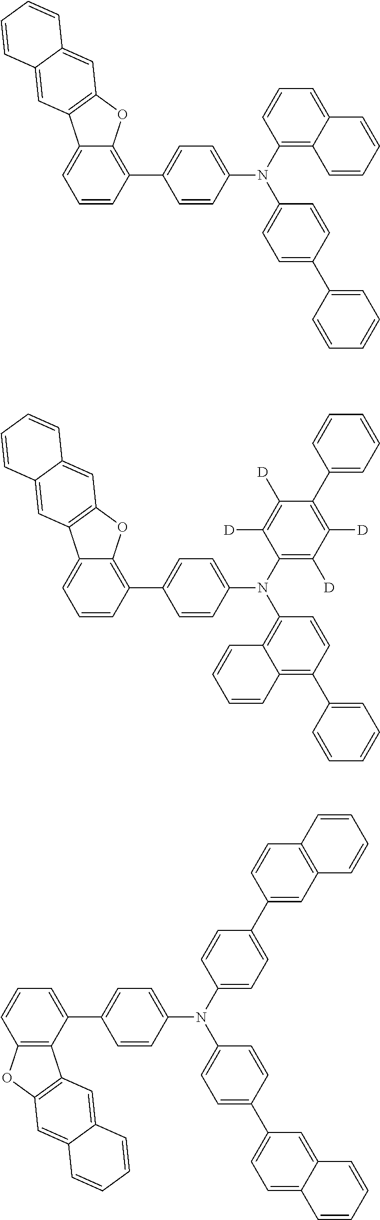 [SMILES: c1ccc(-c2ccc(N(c3ccc(-c4cccc5c4oc4cc6ccccc6cc45)cc3)c3cccc4ccccc34)cc2)cc1 ; [2H]c1c([2H])c(N(c2ccc(-c3cccc4c3oc3cc5ccccc5cc34)cc2)c2ccc(-c3ccccc3)c3ccccc23)c([2H])c([2H])c1-c1ccccc1 ; c1ccc2cc(-c3ccc(N(c4ccc(-c5ccc6ccccc6c5)cc4)c4ccc(-c5cccc6oc7cc8ccccc8cc7c56)cc4)cc3)ccc2c1]

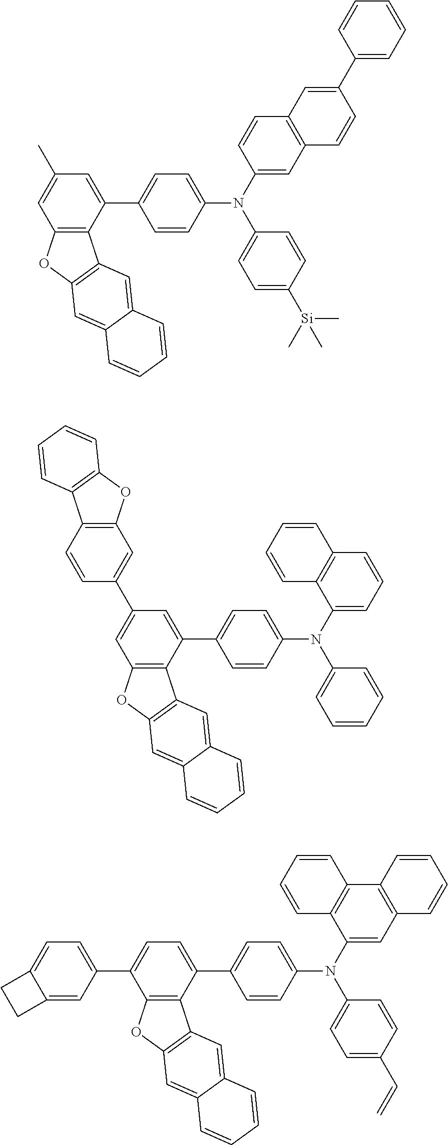 [SMILES: Cc1cc(-c2ccc(N(c3ccc([Si](C)(C)C)cc3)c3ccc4cc(-c5ccccc5)ccc4c3)cc2)c2c(c1)oc1cc3ccccc3cc12 ; c1ccc(N(c2ccc(-c3cc(-c4ccc5c(c4)oc4ccccc45)cc4oc5cc6ccccc6cc5c34)cc2)c2cccc3ccccc23)cc1 ; C=Cc1ccc(N(c2ccc(-c3ccc(-c4ccc5c(c4)CC5)c4oc5cc6ccccc6cc5c34)cc2)c2cc3ccccc3c3ccccc23)cc1]

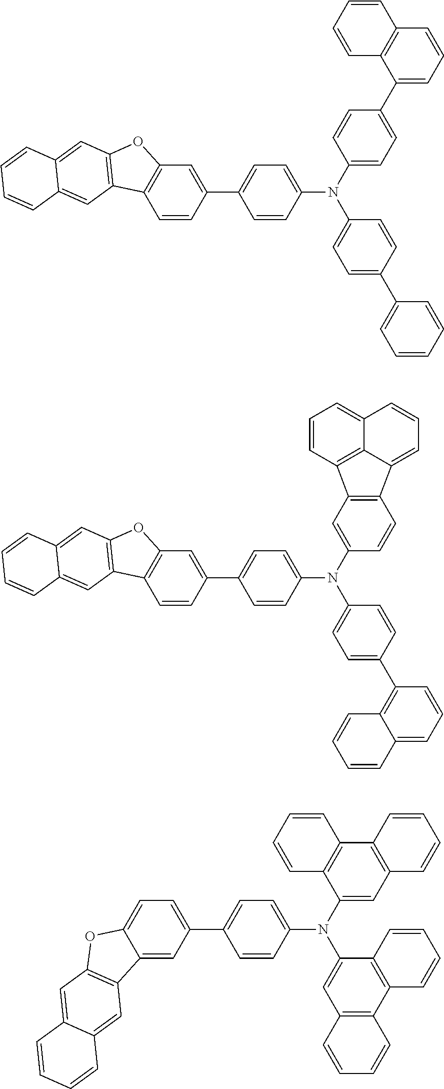 [SMILES: c1ccc(-c2ccc(N(c3ccc(-c4ccc5c(c4)oc4cc6ccccc6cc45)cc3)c3ccc(-c4cccc5ccccc45)cc3)cc2)cc1 ; c1ccc2cc3c(cc2c1)oc1cc(-c2ccc(N(c4ccc(-c5cccc6ccccc56)cc4)c4ccc5c(c4)-c4cccc6cccc-5c46)cc2)ccc13 ; c1ccc2cc3c(cc2c1)oc1ccc(-c2ccc(N(c4cc5ccccc5c5ccccc45)c4cc5ccccc5c5ccccc45)cc2)cc13]

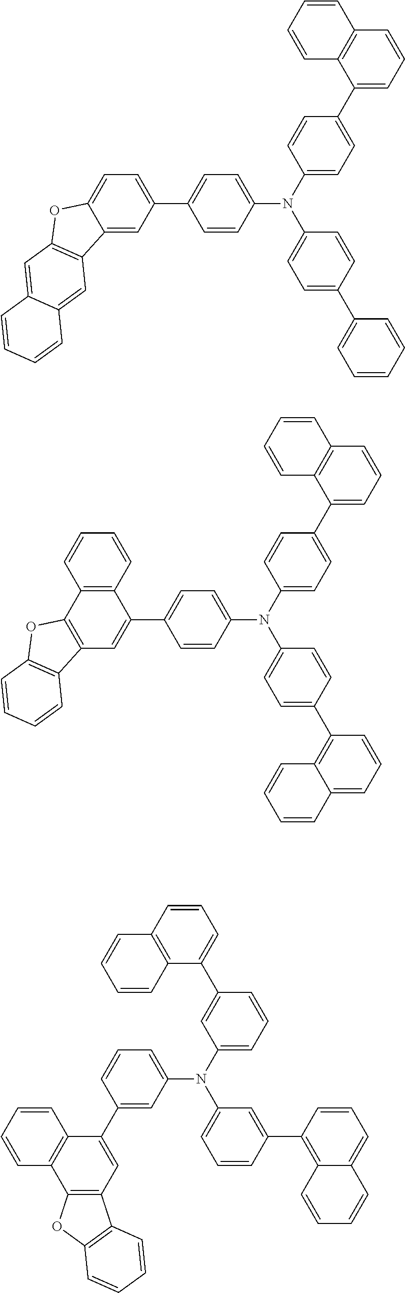 [SMILES: c1ccc(-c2ccc(N(c3ccc(-c4ccc5oc6cc7ccccc7cc6c5c4)cc3)c3ccc(-c4cccc5ccccc45)cc3)cc2)cc1 ; c1ccc2c(-c3ccc(N(c4ccc(-c5cccc6ccccc56)cc4)c4ccc(-c5cc6c7ccccc7oc6c6ccccc56)cc4)cc3)cccc2c1 ; c1cc(-c2cccc3ccccc23)cc(N(c2cccc(-c3cccc4ccccc34)c2)c2cccc(-c3cc4c5ccccc5oc4c4ccccc34)c2)c1]

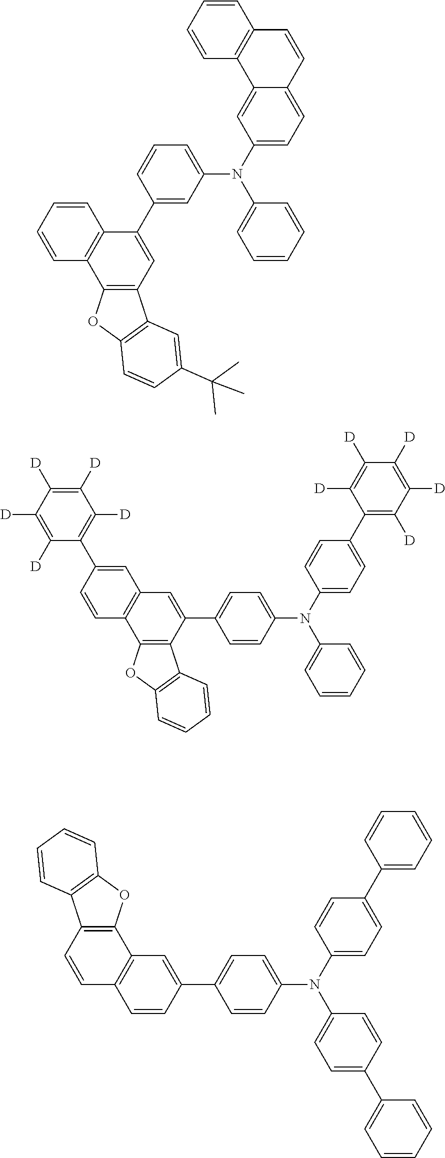 [SMILES: CC(C)(C)c1ccc2oc3c4ccccc4c(-c4cccc(N(c5ccccc5)c5ccc6ccc7ccccc7c6c5)c4)cc3c2c1 ; [2H]c1c([2H])c([2H])c(-c2ccc(N(c3ccccc3)c3ccc(-c4cc5cc(-c6c([2H])c([2H])c([2H])c([2H])c6[2H])ccc5c5oc6ccccc6c45)cc3)cc2)c([2H])c1[2H] ; c1ccc(-c2ccc(N(c3ccc(-c4ccccc4)cc3)c3ccc(-c4ccc5ccc6c7ccccc7oc6c5c4)cc3)cc2)cc1]

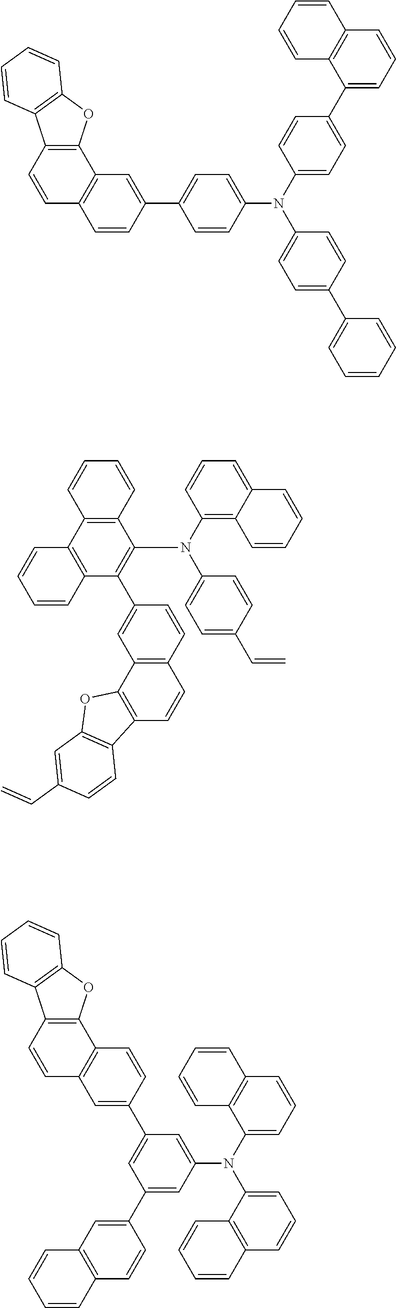 [SMILES: c1ccc(-c2ccc(N(c3ccc(-c4ccc5ccc6c7ccccc7oc6c5c4)cc3)c3ccc(-c4cccc5ccccc45)cc3)cc2)cc1 ; C=Cc1ccc(N(c2cccc3ccccc23)c2c(-c3ccc4ccc5c6ccc(C=C)cc6oc5c4c3)c3ccccc3c3ccccc23)cc1 ; c1ccc2cc(-c3cc(-c4ccc5c(ccc6c7ccccc7oc56)c4)cc(N(c4cccc5ccccc45)c4cccc5ccccc45)c3)ccc2c1]

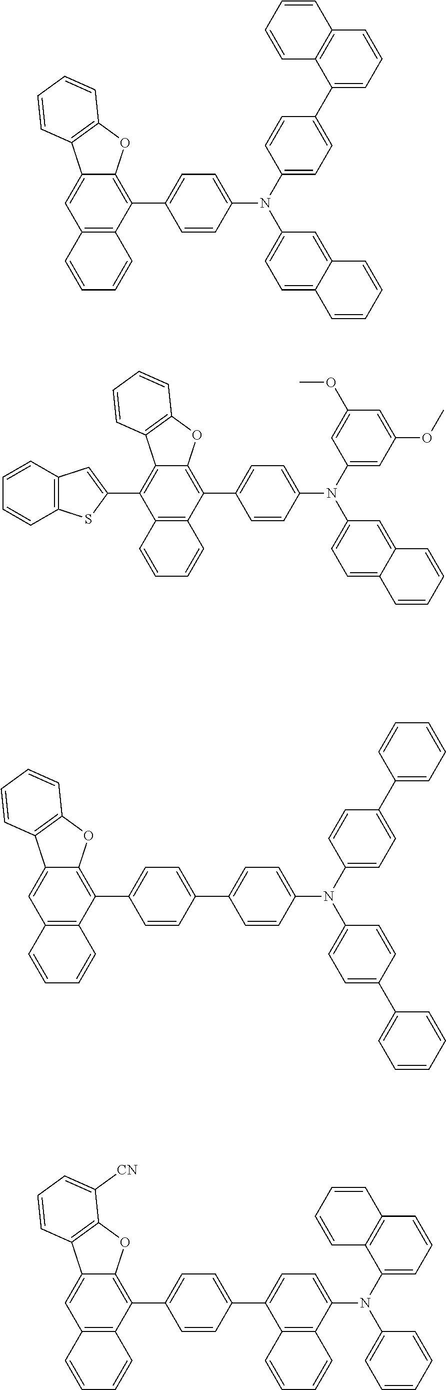 [SMILES: c1ccc2cc(N(c3ccc(-c4cccc5ccccc45)cc3)c3ccc(-c4c5ccccc5cc5c4oc4ccccc45)cc3)ccc2c1 ; COc1cc(OC)cc(N(c2ccc(-c3c4ccccc4c(-c4cc5ccccc5s4)c4c3oc3ccccc34)cc2)c2ccc3ccccc3c2)c1 ; c1ccc(-c2ccc(N(c3ccc(-c4ccccc4)cc3)c3ccc(-c4ccc(-c5c6ccccc6cc6c5oc5ccccc56)cc4)cc3)cc2)cc1 ; N#Cc1cccc2c1oc1c(-c3ccc(-c4ccc(N(c5ccccc5)c5cccc6ccccc56)c5ccccc45)cc3)c3ccccc3cc12]

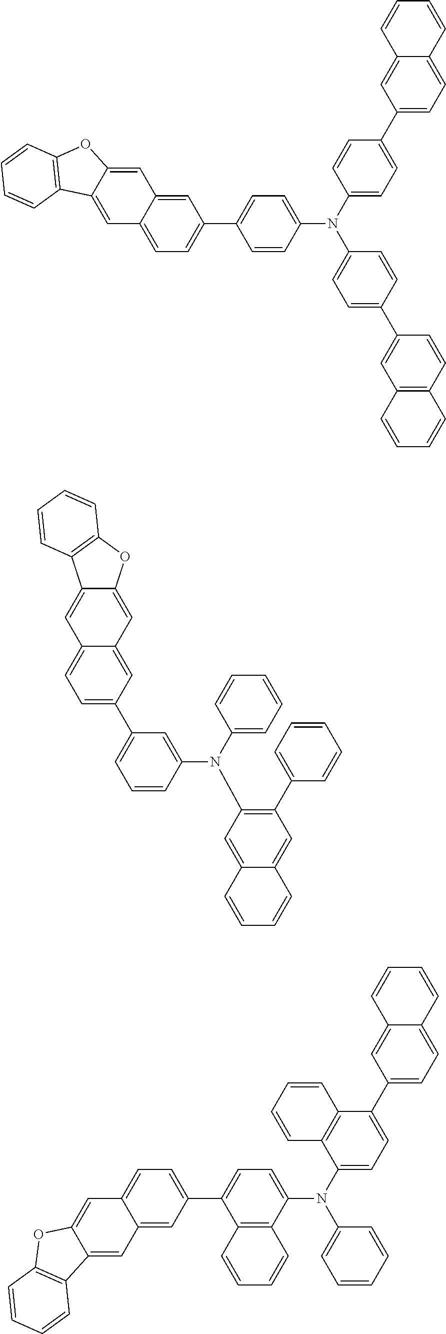 [SMILES: c1ccc2cc(-c3ccc(N(c4ccc(-c5ccc6ccccc6c5)cc4)c4ccc(-c5ccc6cc7c(cc6c5)oc5ccccc57)cc4)cc3)ccc2c1 ; c1ccc(-c2cc3ccccc3cc2N(c2ccccc2)c2cccc(-c3ccc4cc5c(cc4c3)oc3ccccc35)c2)cc1 ; c1ccc(N(c2ccc(-c3ccc4ccccc4c3)c3ccccc23)c2ccc(-c3ccc4cc5oc6ccccc6c5cc4c3)c3ccccc23)cc1]

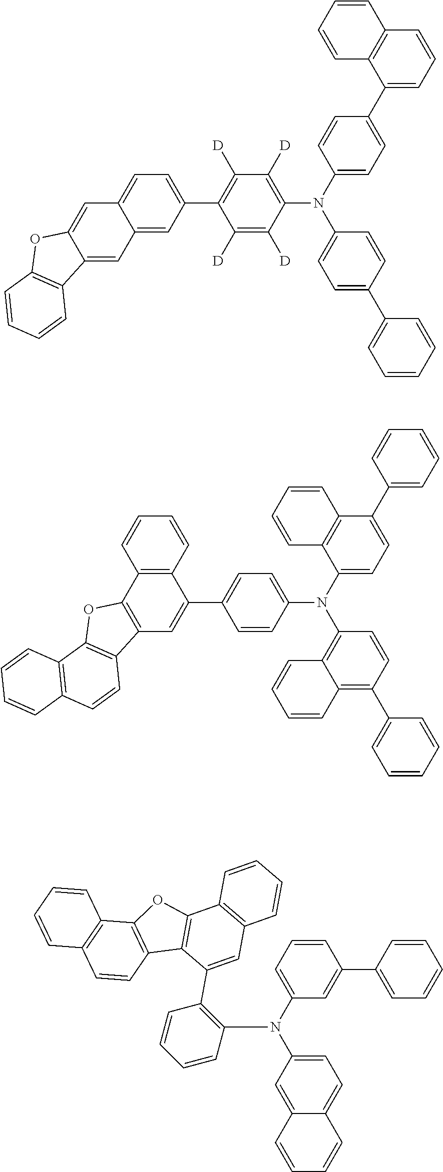 [SMILES: [2H]c1c([2H])c(N(c2ccc(-c3ccccc3)cc2)c2ccc(-c3cccc4ccccc34)cc2)c([2H])c([2H])c1-c1ccc2cc3oc4ccccc4c3cc2c1 ; c1ccc(-c2ccc(N(c3ccc(-c4cc5c6ccc7ccccc7c6oc5c5ccccc45)cc3)c3ccc(-c4ccccc4)c4ccccc34)c3ccccc23)cc1 ; c1ccc(-c2cccc(N(c3ccc4ccccc4c3)c3ccccc3-c3cc4ccccc4c4oc5c6ccccc6ccc5c34)c2)cc1]

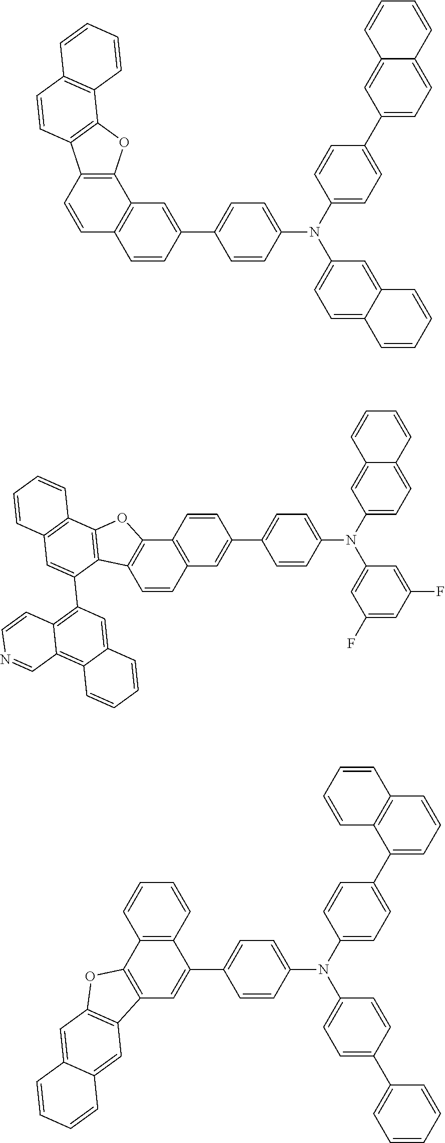 [SMILES: c1ccc2cc(-c3ccc(N(c4ccc(-c5ccc6ccc7c8ccc9ccccc9c8oc7c6c5)cc4)c4ccc5ccccc5c4)cc3)ccc2c1 ; Fc1cc(F)cc(N(c2ccc(-c3ccc4c(ccc5c4oc4c6ccccc6cc(-c6cc7ccccc7c7cnccc67)c54)c3)cc2)c2ccc3ccccc3c2)c1 ; c1ccc(-c2ccc(N(c3ccc(-c4cccc5ccccc45)cc3)c3ccc(-c4cc5c6cc7ccccc7cc6oc5c5ccccc45)cc3)cc2)cc1]

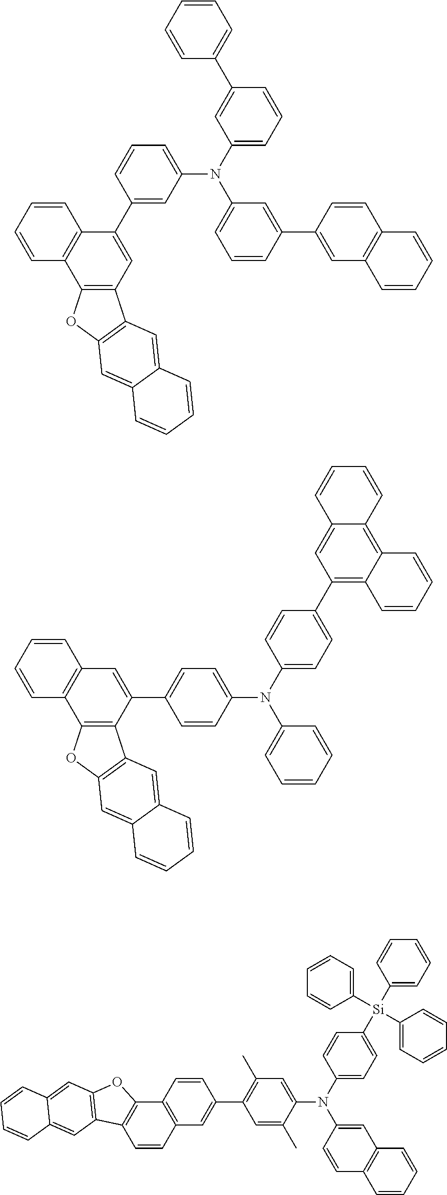 [SMILES: c1ccc(-c2cccc(N(c3cccc(-c4ccc5ccccc5c4)c3)c3cccc(-c4cc5c6cc7ccccc7cc6oc5c5ccccc45)c3)c2)cc1 ; c1ccc(N(c2ccc(-c3cc4ccccc4c4ccccc34)cc2)c2ccc(-c3cc4ccccc4c4oc5cc6ccccc6cc5c34)cc2)cc1 ; Cc1cc(N(c2ccc([Si](c3ccccc3)(c3ccccc3)c3ccccc3)cc2)c2ccc3ccccc3c2)c(C)cc1-c1ccc2c(ccc3c4cc5ccccc5cc4oc23)c1]

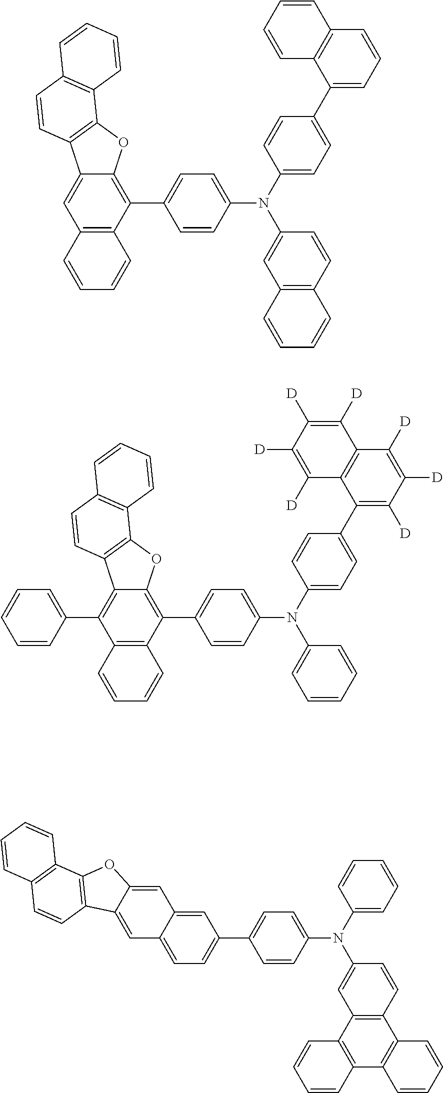 [SMILES: c1ccc2cc(N(c3ccc(-c4cccc5ccccc45)cc3)c3ccc(-c4c5ccccc5cc5c4oc4c6ccccc6ccc54)cc3)ccc2c1 ; [2H]c1c([2H])c([2H])c2c(-c3ccc(N(c4ccccc4)c4ccc(-c5c6ccccc6c(-c6ccccc6)c6c5oc5c7ccccc7ccc56)cc4)cc3)c([2H])c([2H])c([2H])c2c1[2H] ; c1ccc(N(c2ccc(-c3ccc4cc5c(cc4c3)oc3c4ccccc4ccc53)cc2)c2ccc3c4ccccc4c4ccccc4c3c2)cc1]

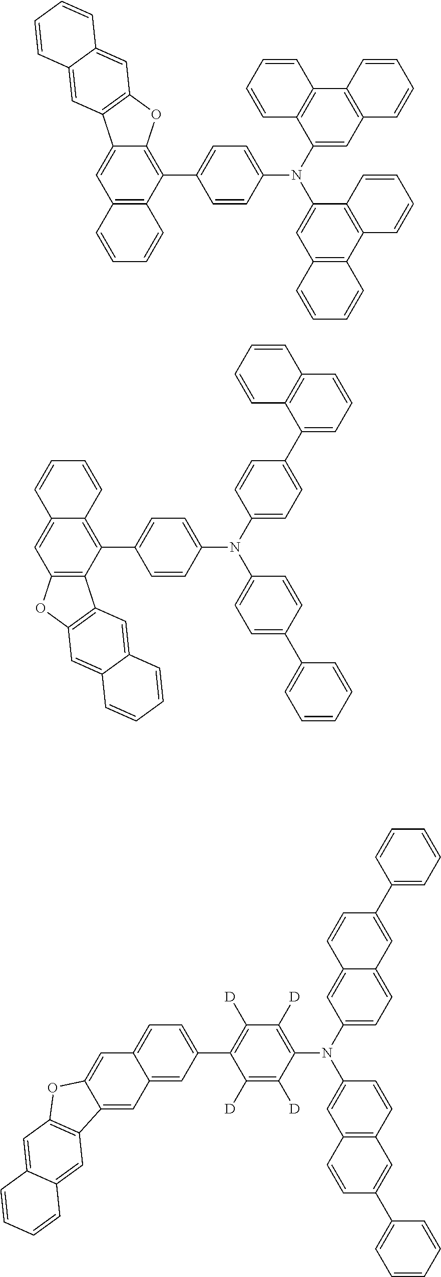

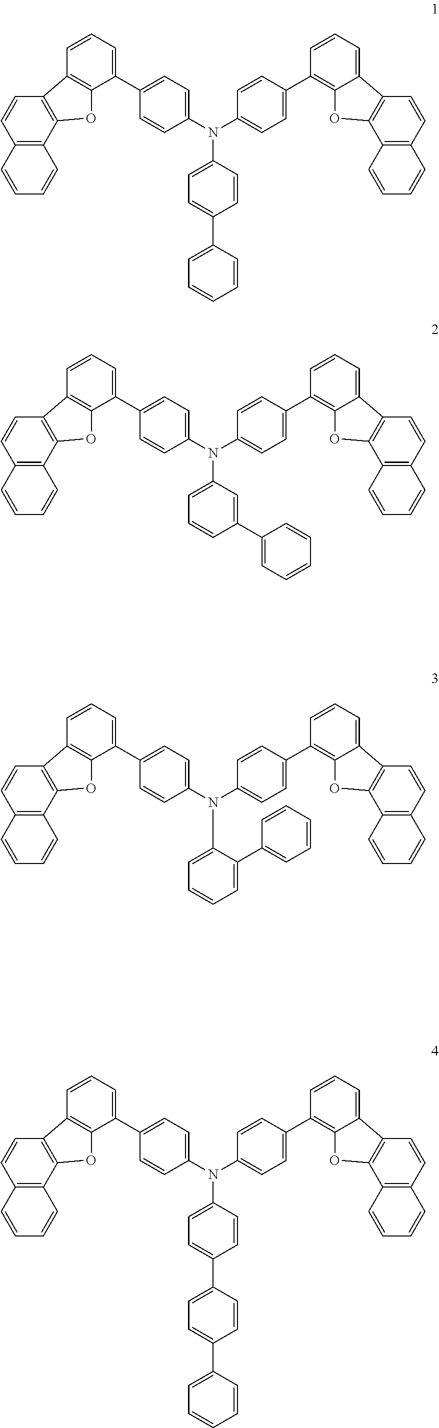 [SMILES: c1ccc(-c2ccc(N(c3ccc(-c4cccc5c4oc4c6ccccc6ccc54)cc3)c3ccc(-c4cccc5c4oc4c6ccccc6ccc54)cc3)cc2)cc1 ; c1ccc(-c2cccc(N(c3ccc(-c4cccc5c4oc4c6ccccc6ccc54)cc3)c3ccc(-c4cccc5c4oc4c6ccccc6ccc54)cc3)c2)cc1 ; c1ccc(-c2ccccc2N(c2ccc(-c3cccc4c3oc3c5ccccc5ccc43)cc2)c2ccc(-c3cccc4c3oc3c5ccccc5ccc43)cc2)cc1 ; c1ccc(-c2ccc(-c3ccc(N(c4ccc(-c5cccc6c5oc5c7ccccc7ccc65)cc4)c4ccc(-c5cccc6c5oc5c7ccccc7ccc65)cc4)cc3)cc2)cc1]

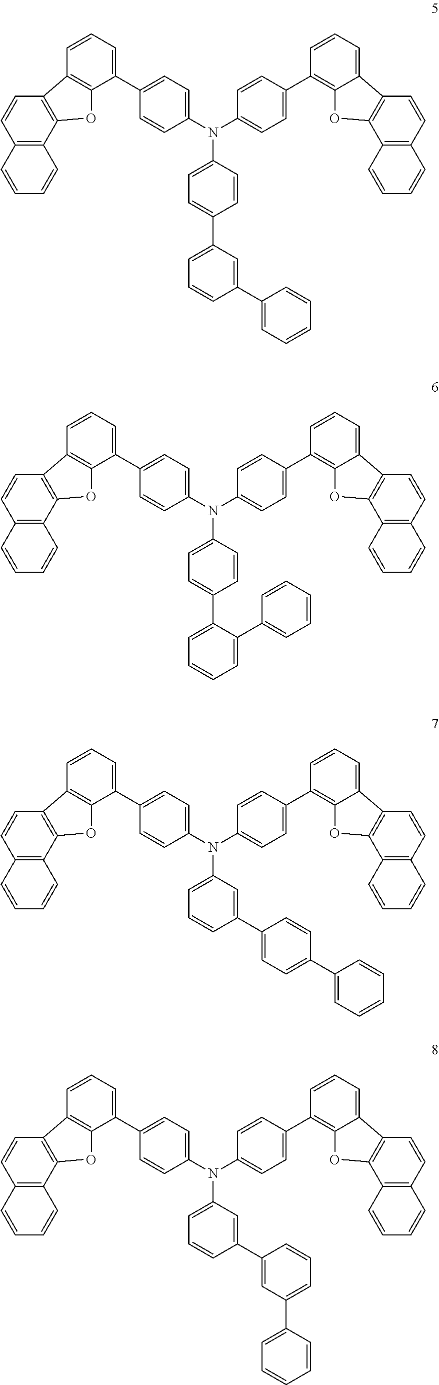 [SMILES: c1ccc(-c2cccc(-c3ccc(N(c4ccc(-c5cccc6c5oc5c7ccccc7ccc65)cc4)c4ccc(-c5cccc6c5oc5c7ccccc7ccc65)cc4)cc3)c2)cc1 ; c1ccc(-c2ccccc2-c2ccc(N(c3ccc(-c4cccc5c4oc4c6ccccc6ccc54)cc3)c3ccc(-c4cccc5c4oc4c6ccccc6ccc54)cc3)cc2)cc1 ; c1ccc(-c2ccc(-c3cccc(N(c4ccc(-c5cccc6c5oc5c7ccccc7ccc65)cc4)c4ccc(-c5cccc6c5oc5c7ccccc7ccc65)cc4)c3)cc2)cc1 ; c1ccc(-c2cccc(-c3cccc(N(c4ccc(-c5cccc6c5oc5c7ccccc7ccc65)cc4)c4ccc(-c5cccc6c5oc5c7ccccc7ccc65)cc4)c3)c2)cc1]

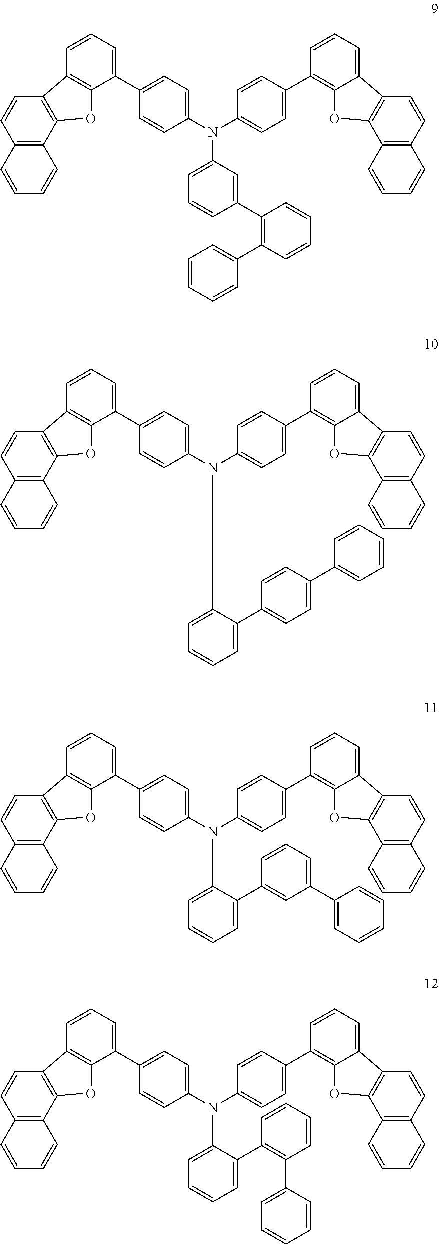 [SMILES: c1ccc(-c2ccccc2-c2cccc(N(c3ccc(-c4cccc5c4oc4c6ccccc6ccc54)cc3)c3ccc(-c4cccc5c4oc4c6ccccc6ccc54)cc3)c2)cc1 ; c1ccc(-c2ccc(-c3ccccc3N(c3ccc(-c4cccc5c4oc4c6ccccc6ccc54)cc3)c3ccc(-c4cccc5c4oc4c6ccccc6ccc54)cc3)cc2)cc1 ; c1ccc(-c2cccc(-c3ccccc3N(c3ccc(-c4cccc5c4oc4c6ccccc6ccc54)cc3)c3ccc(-c4cccc5c4oc4c6ccccc6ccc54)cc3)c2)cc1 ; c1ccc(-c2ccccc2-c2ccccc2N(c2ccc(-c3cccc4c3oc3c5ccccc5ccc43)cc2)c2ccc(-c3cccc4c3oc3c5ccccc5ccc43)cc2)cc1]

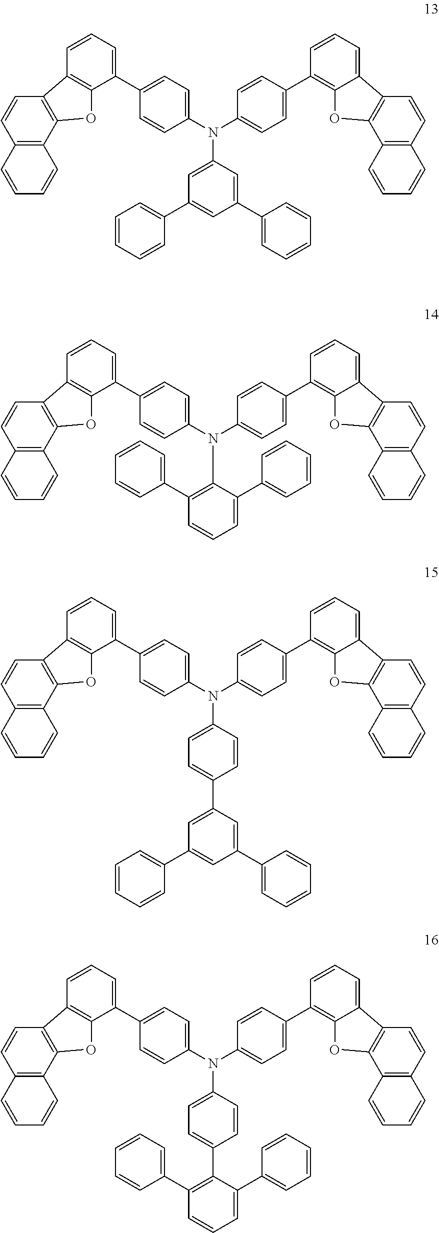 [SMILES: c1ccc(-c2cc(-c3ccccc3)cc(N(c3ccc(-c4cccc5c4oc4c6ccccc6ccc54)cc3)c3ccc(-c4cccc5c4oc4c6ccccc6ccc54)cc3)c2)cc1 ; c1ccc(-c2cccc(-c3ccccc3)c2N(c2ccc(-c3cccc4c3oc3c5ccccc5ccc43)cc2)c2ccc(-c3cccc4c3oc3c5ccccc5ccc43)cc2)cc1 ; c1ccc(-c2cc(-c3ccccc3)cc(-c3ccc(N(c4ccc(-c5cccc6c5oc5c7ccccc7ccc65)cc4)c4ccc(-c5cccc6c5oc5c7ccccc7ccc65)cc4)cc3)c2)cc1 ; c1ccc(-c2cccc(-c3ccccc3)c2-c2ccc(N(c3ccc(-c4cccc5c4oc4c6ccccc6ccc54)cc3)c3ccc(-c4cccc5c4oc4c6ccccc6ccc54)cc3)cc2)cc1]

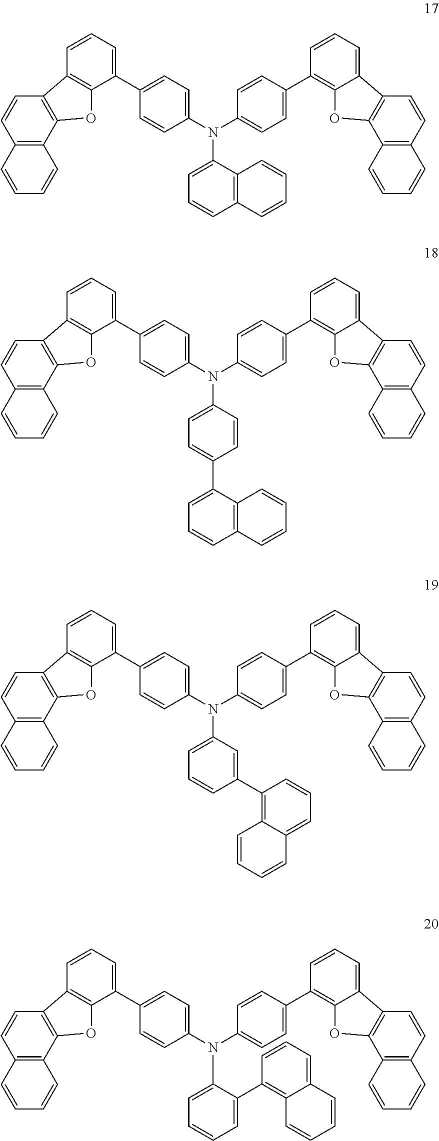 [SMILES: c1ccc2c(N(c3ccc(-c4cccc5c4oc4c6ccccc6ccc54)cc3)c3ccc(-c4cccc5c4oc4c6ccccc6ccc54)cc3)cccc2c1 ; c1ccc2c(-c3ccc(N(c4ccc(-c5cccc6c5oc5c7ccccc7ccc65)cc4)c4ccc(-c5cccc6c5oc5c7ccccc7ccc65)cc4)cc3)cccc2c1 ; c1cc(-c2cccc3ccccc23)cc(N(c2ccc(-c3cccc4c3oc3c5ccccc5ccc43)cc2)c2ccc(-c3cccc4c3oc3c5ccccc5ccc43)cc2)c1 ; c1ccc(N(c2ccc(-c3cccc4c3oc3c5ccccc5ccc43)cc2)c2ccc(-c3cccc4c3oc3c5ccccc5ccc43)cc2)c(-c2cccc3ccccc23)c1]

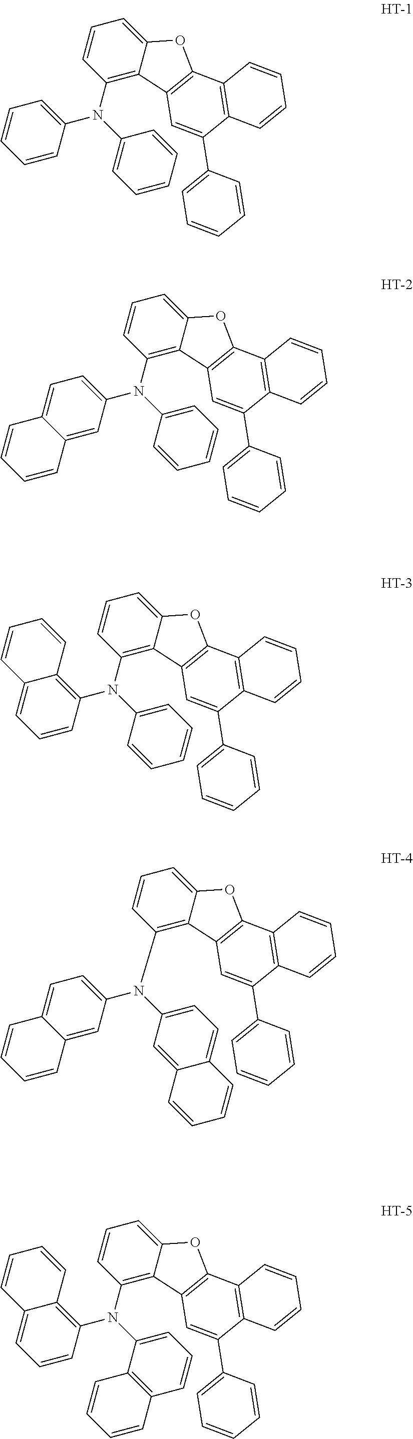 [SMILES: c1ccc(-c2cc3c(oc4cccc(N(c5ccccc5)c5ccccc5)c43)c3ccccc23)cc1 ; c1ccc(-c2cc3c(oc4cccc(N(c5ccccc5)c5ccc6ccccc6c5)c43)c3ccccc23)cc1 ; c1ccc(-c2cc3c(oc4cccc(N(c5ccccc5)c5cccc6ccccc56)c43)c3ccccc23)cc1 ; c1ccc(-c2cc3c(oc4cccc(N(c5ccc6ccccc6c5)c5ccc6ccccc6c5)c43)c3ccccc23)cc1 ; c1ccc(-c2cc3c(oc4cccc(N(c5cccc6ccccc56)c5cccc6ccccc56)c43)c3ccccc23)cc1]

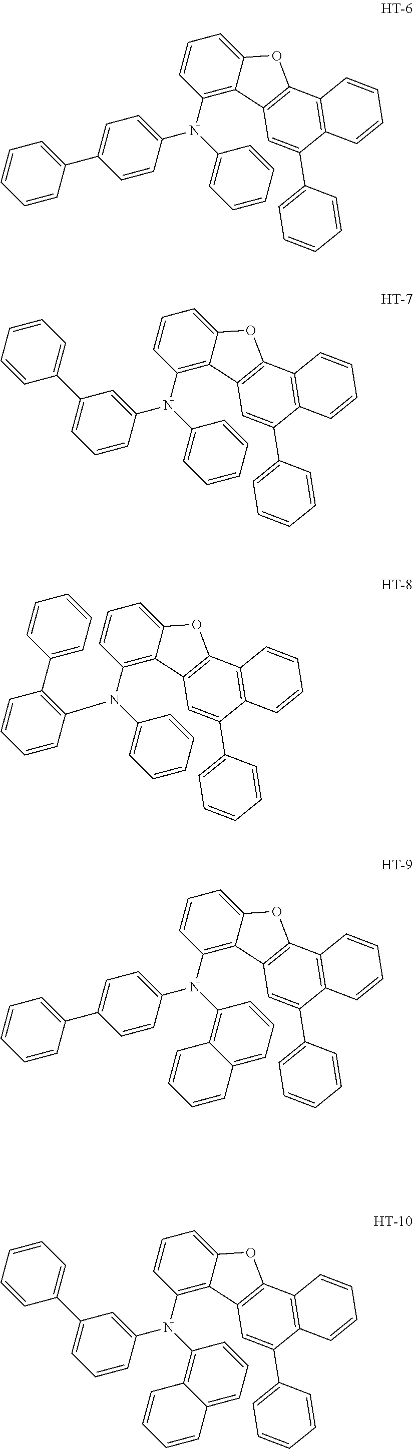 [SMILES: c1ccc(-c2ccc(N(c3ccccc3)c3cccc4oc5c6ccccc6c(-c6ccccc6)cc5c34)cc2)cc1 ; c1ccc(-c2cccc(N(c3ccccc3)c3cccc4oc5c6ccccc6c(-c6ccccc6)cc5c34)c2)cc1 ; c1ccc(-c2ccccc2N(c2ccccc2)c2cccc3oc4c5ccccc5c(-c5ccccc5)cc4c23)cc1 ; c1ccc(-c2ccc(N(c3cccc4ccccc34)c3cccc4oc5c6ccccc6c(-c6ccccc6)cc5c34)cc2)cc1 ; c1ccc(-c2cccc(N(c3cccc4ccccc34)c3cccc4oc5c6ccccc6c(-c6ccccc6)cc5c34)c2)cc1]

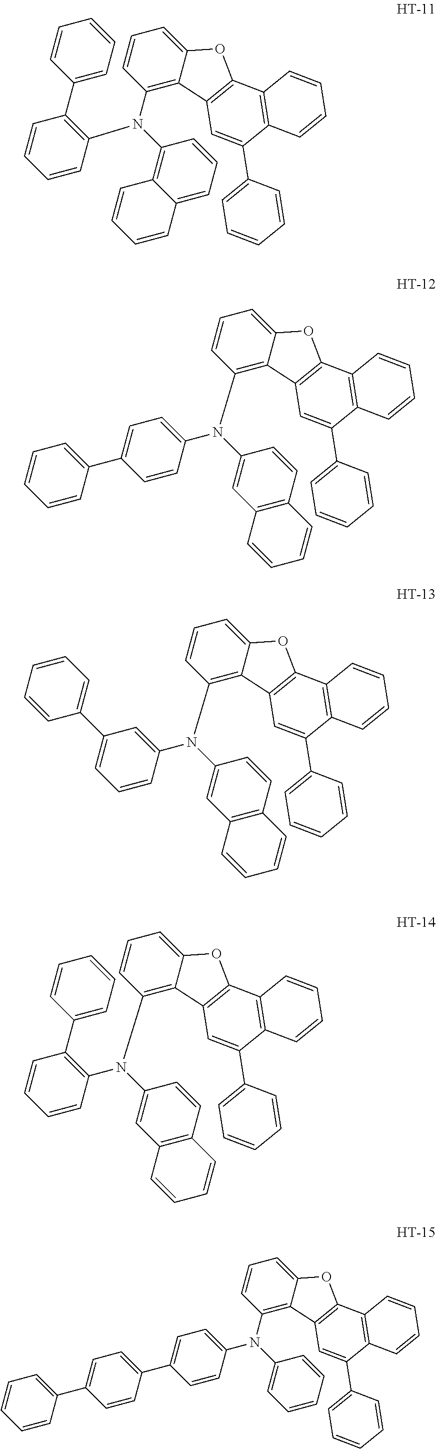 [SMILES: c1ccc(-c2ccccc2N(c2cccc3ccccc23)c2cccc3oc4c5ccccc5c(-c5ccccc5)cc4c23)cc1 ; c1ccc(-c2ccc(N(c3ccc4ccccc4c3)c3cccc4oc5c6ccccc6c(-c6ccccc6)cc5c34)cc2)cc1 ; c1ccc(-c2cccc(N(c3ccc4ccccc4c3)c3cccc4oc5c6ccccc6c(-c6ccccc6)cc5c34)c2)cc1 ; c1ccc(-c2ccccc2N(c2ccc3ccccc3c2)c2cccc3oc4c5ccccc5c(-c5ccccc5)cc4c23)cc1 ; c1ccc(-c2ccc(-c3ccc(N(c4ccccc4)c4cccc5oc6c7ccccc7c(-c7ccccc7)cc6c45)cc3)cc2)cc1]

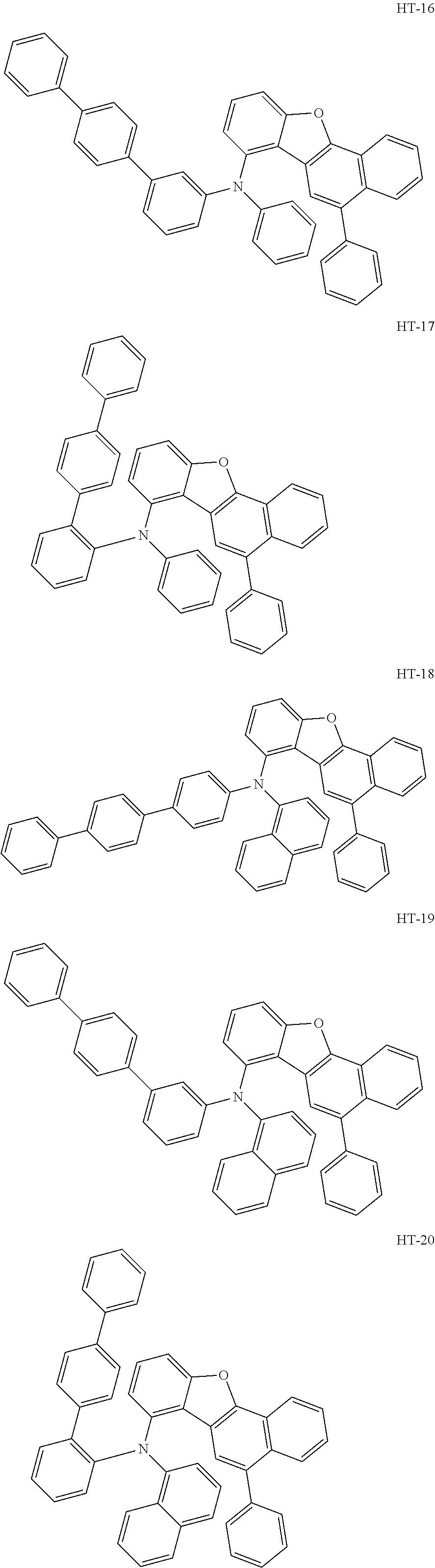 [SMILES: c1ccc(-c2ccc(-c3cccc(N(c4ccccc4)c4cccc5oc6c7ccccc7c(-c7ccccc7)cc6c45)c3)cc2)cc1 ; c1ccc(-c2ccc(-c3ccccc3N(c3ccccc3)c3cccc4oc5c6ccccc6c(-c6ccccc6)cc5c34)cc2)cc1 ; c1ccc(-c2ccc(-c3ccc(N(c4cccc5ccccc45)c4cccc5oc6c7ccccc7c(-c7ccccc7)cc6c45)cc3)cc2)cc1 ; c1ccc(-c2ccc(-c3cccc(N(c4cccc5ccccc45)c4cccc5oc6c7ccccc7c(-c7ccccc7)cc6c45)c3)cc2)cc1 ; c1ccc(-c2ccc(-c3ccccc3N(c3cccc4ccccc34)c3cccc4oc5c6ccccc6c(-c6ccccc6)cc5c34)cc2)cc1]

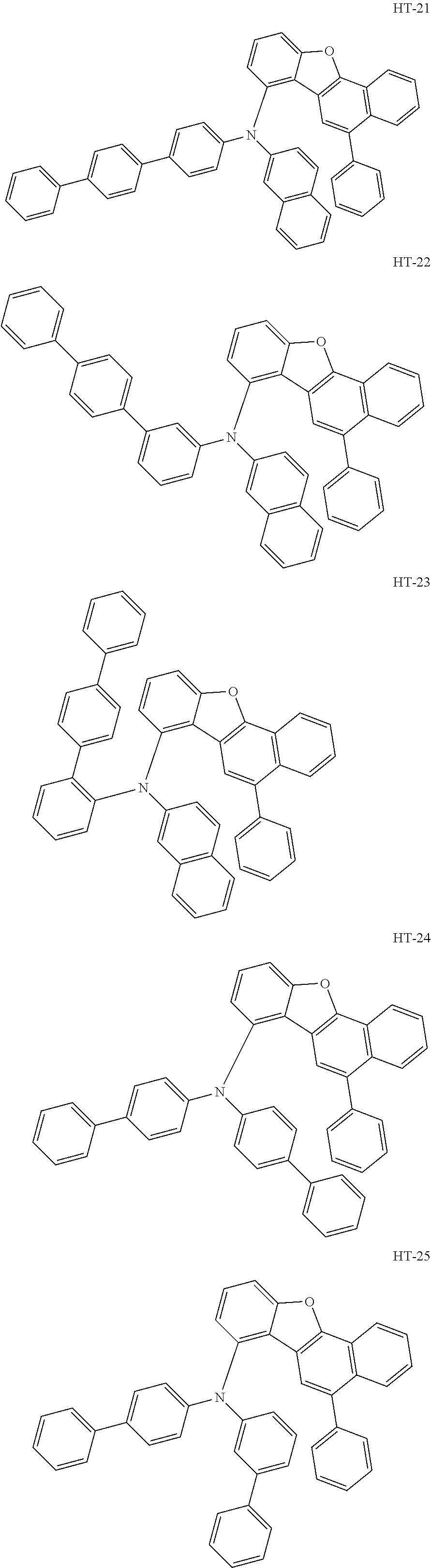 [SMILES: c1ccc(-c2ccc(-c3ccc(N(c4ccc5ccccc5c4)c4cccc5oc6c7ccccc7c(-c7ccccc7)cc6c45)cc3)cc2)cc1 ; c1ccc(-c2ccc(-c3cccc(N(c4ccc5ccccc5c4)c4cccc5oc6c7ccccc7c(-c7ccccc7)cc6c45)c3)cc2)cc1 ; c1ccc(-c2ccc(-c3ccccc3N(c3ccc4ccccc4c3)c3cccc4oc5c6ccccc6c(-c6ccccc6)cc5c34)cc2)cc1 ; c1ccc(-c2ccc(N(c3ccc(-c4ccccc4)cc3)c3cccc4oc5c6ccccc6c(-c6ccccc6)cc5c34)cc2)cc1 ; c1ccc(-c2ccc(N(c3cccc(-c4ccccc4)c3)c3cccc4oc5c6ccccc6c(-c6ccccc6)cc5c34)cc2)cc1]

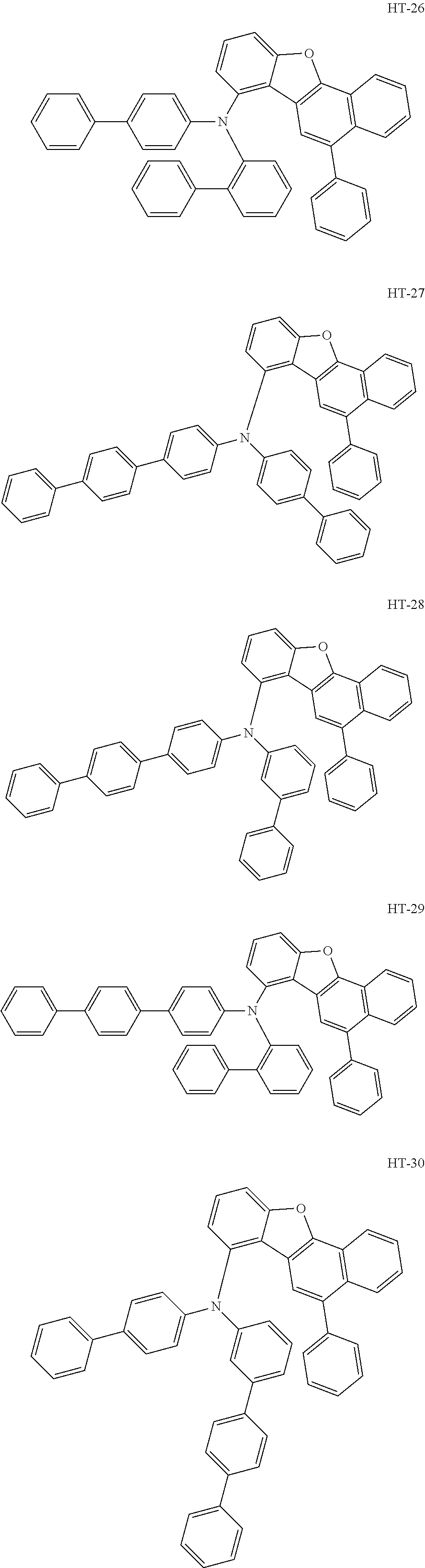 [SMILES: c1ccc(-c2ccc(N(c3ccccc3-c3ccccc3)c3cccc4oc5c6ccccc6c(-c6ccccc6)cc5c34)cc2)cc1 ; c1ccc(-c2ccc(-c3ccc(N(c4ccc(-c5ccccc5)cc4)c4cccc5oc6c7ccccc7c(-c7ccccc7)cc6c45)cc3)cc2)cc1 ; c1ccc(-c2ccc(-c3ccc(N(c4cccc(-c5ccccc5)c4)c4cccc5oc6c7ccccc7c(-c7ccccc7)cc6c45)cc3)cc2)cc1 ; c1ccc(-c2ccc(-c3ccc(N(c4ccccc4-c4ccccc4)c4cccc5oc6c7ccccc7c(-c7ccccc7)cc6c45)cc3)cc2)cc1 ; c1ccc(-c2ccc(-c3cccc(N(c4ccc(-c5ccccc5)cc4)c4cccc5oc6c7ccccc7c(-c7ccccc7)cc6c45)c3)cc2)cc1]

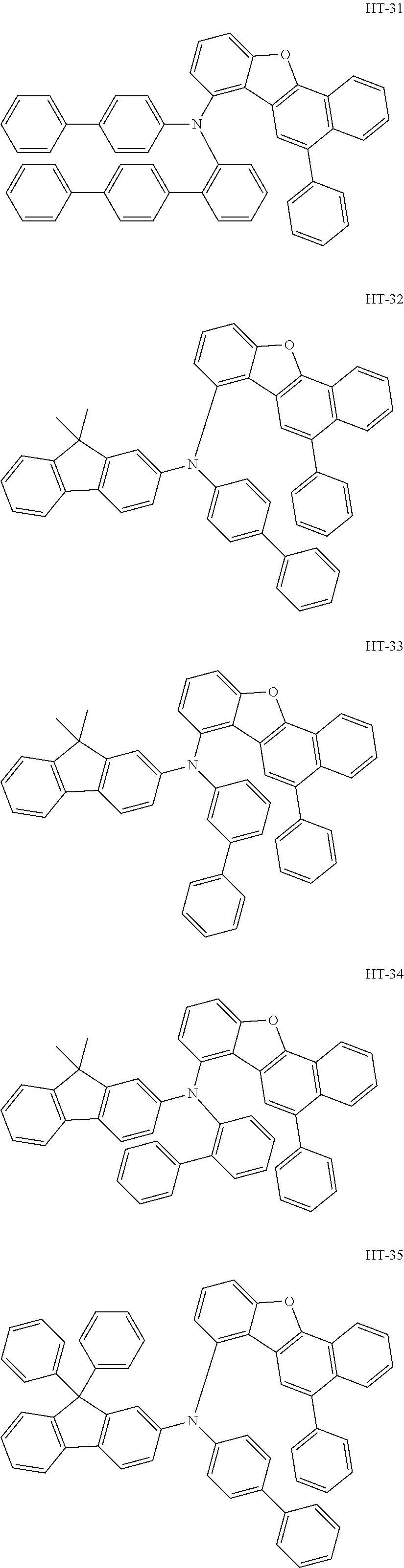 [SMILES: c1ccc(-c2ccc(-c3ccccc3N(c3ccc(-c4ccccc4)cc3)c3cccc4oc5c6ccccc6c(-c6ccccc6)cc5c34)cc2)cc1 ; CC1(C)c2ccccc2-c2ccc(N(c3ccc(-c4ccccc4)cc3)c3cccc4oc5c6ccccc6c(-c6ccccc6)cc5c34)cc21 ; CC1(C)c2ccccc2-c2ccc(N(c3cccc(-c4ccccc4)c3)c3cccc4oc5c6ccccc6c(-c6ccccc6)cc5c34)cc21 ; CC1(C)c2ccccc2-c2ccc(N(c3ccccc3-c3ccccc3)c3cccc4oc5c6ccccc6c(-c6ccccc6)cc5c34)cc21 ; c1ccc(-c2ccc(N(c3ccc4c(c3)C(c3ccccc3)(c3ccccc3)c3ccccc3-4)c3cccc4oc5c6ccccc6c(-c6ccccc6)cc5c34)cc2)cc1]

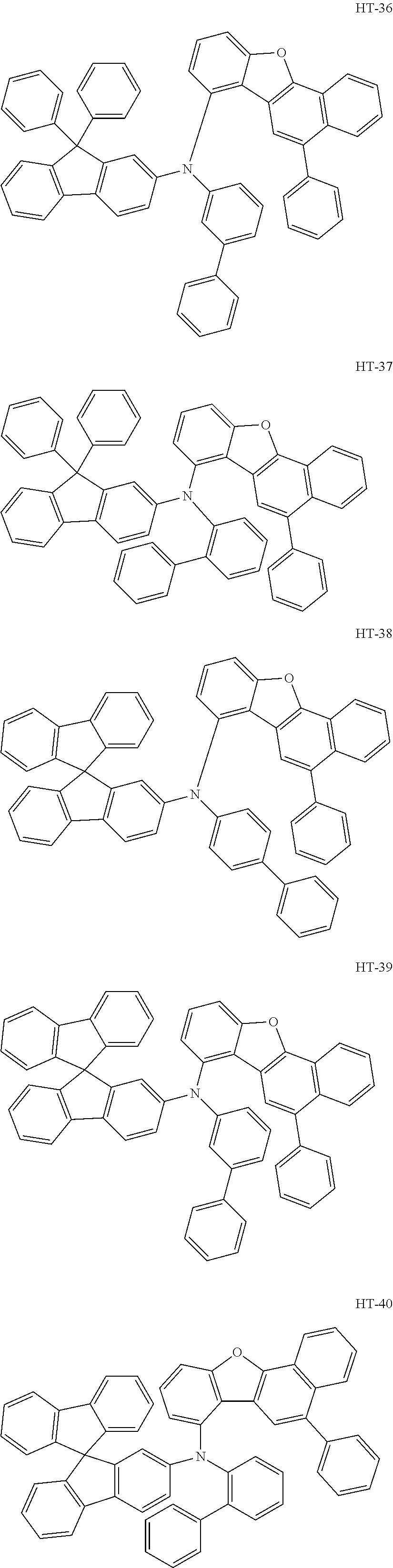

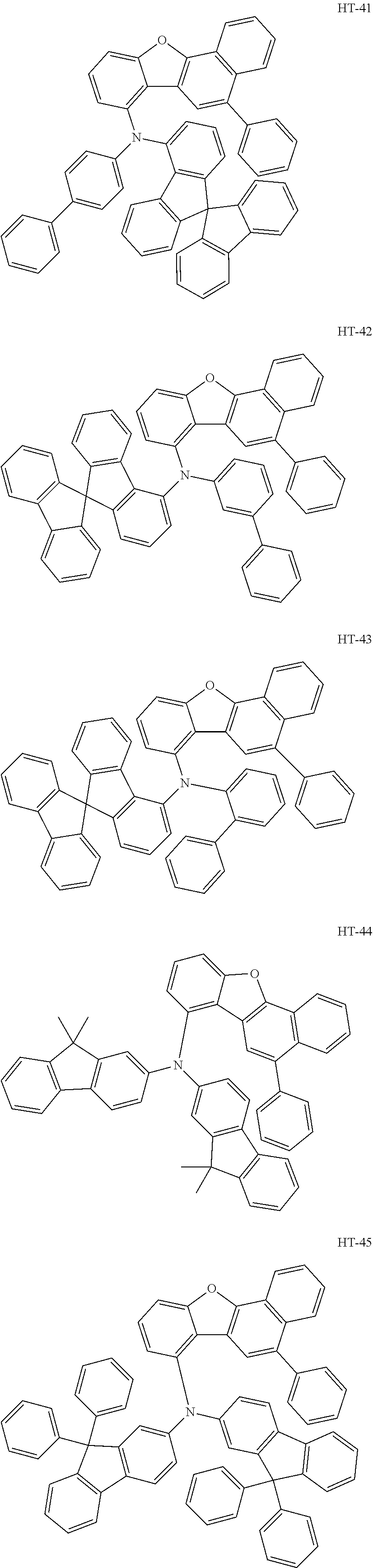

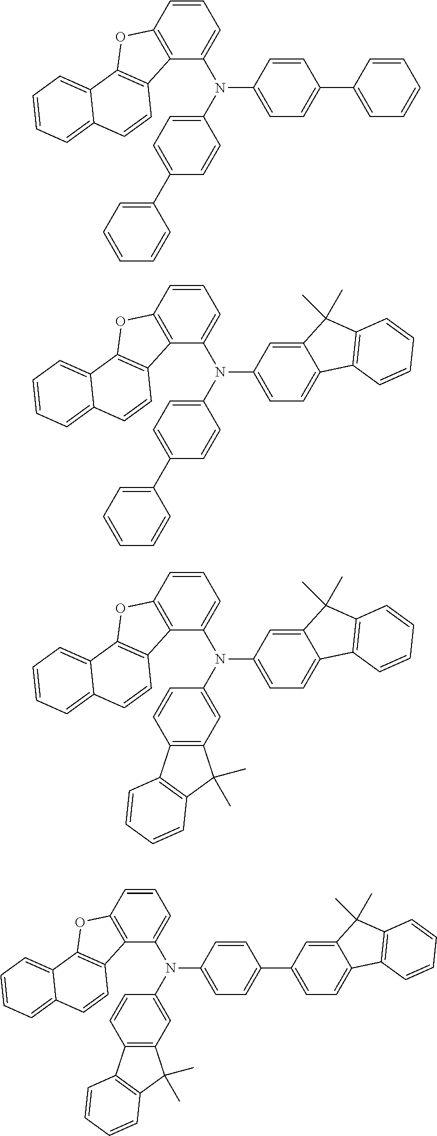

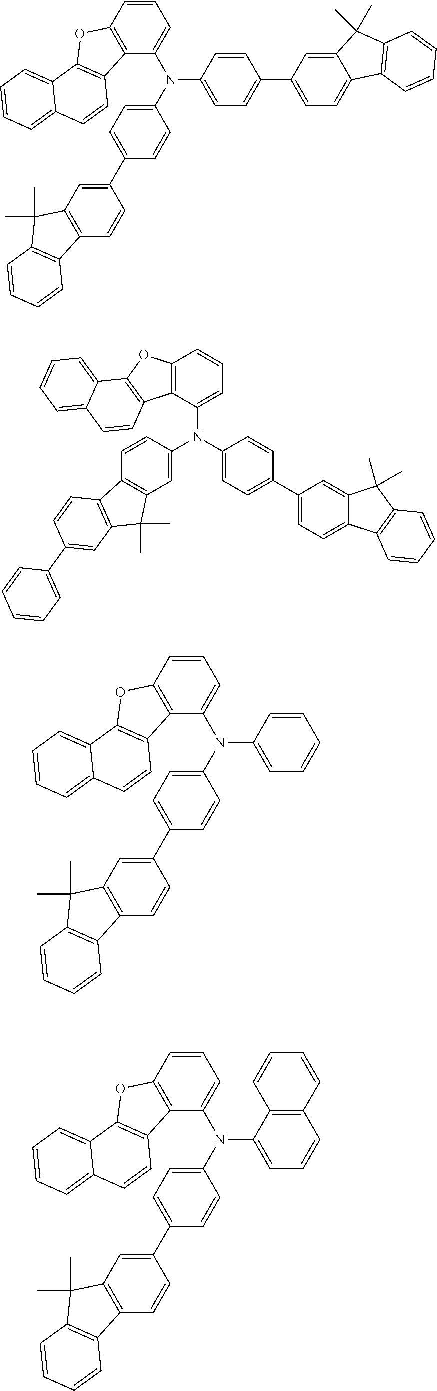 [SMILES: CC1(C)c2ccccc2-c2ccc(-c3ccc(N(c4ccc(-c5ccc6c(c5)C(C)(C)c5ccccc5-6)cc4)c4cccc5oc6c7ccccc7ccc6c45)cc3)cc21 ; CC1(C)c2ccccc2-c2ccc(-c3ccc(N(c4ccc5c(c4)C(C)(C)c4cc(-c6ccccc6)ccc4-5)c4cccc5oc6c7ccccc7ccc6c45)cc3)cc21 ; CC1(C)c2ccccc2-c2ccc(-c3ccc(N(c4ccccc4)c4cccc5oc6c7ccccc7ccc6c45)cc3)cc21 ; CC1(C)c2ccccc2-c2ccc(-c3ccc(N(c4cccc5ccccc45)c4cccc5oc6c7ccccc7ccc6c45)cc3)cc21]

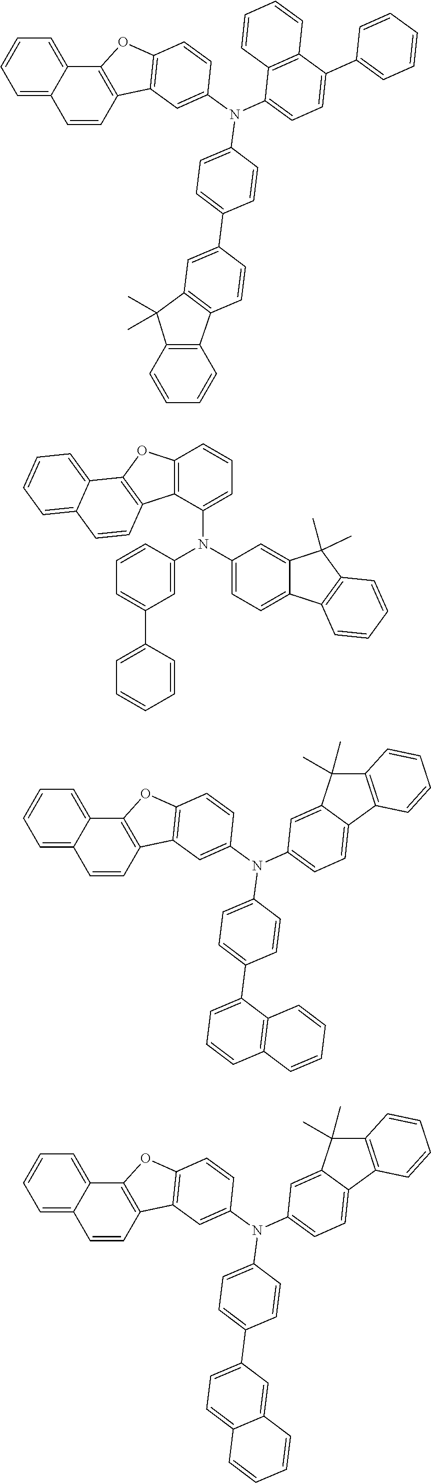

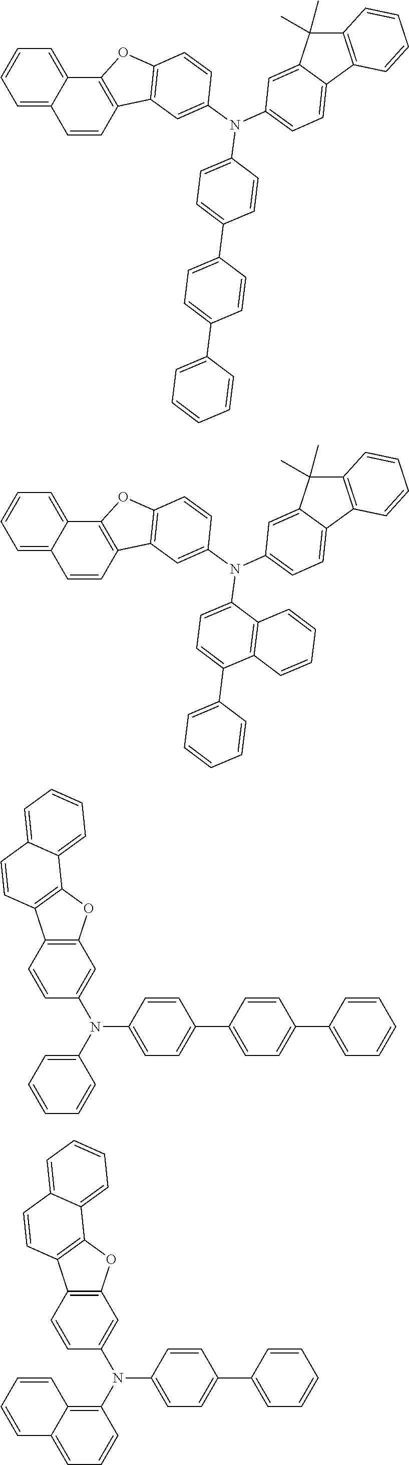

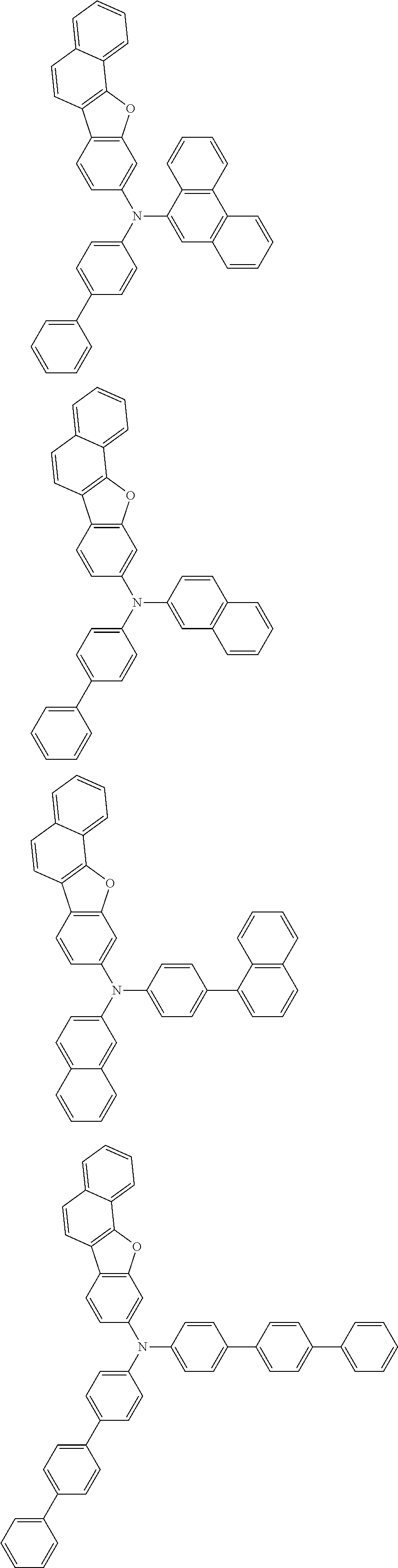

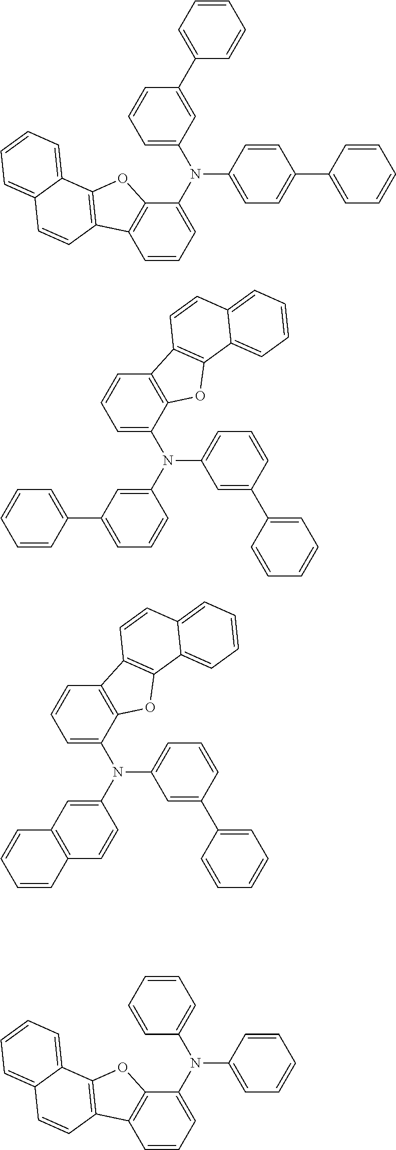

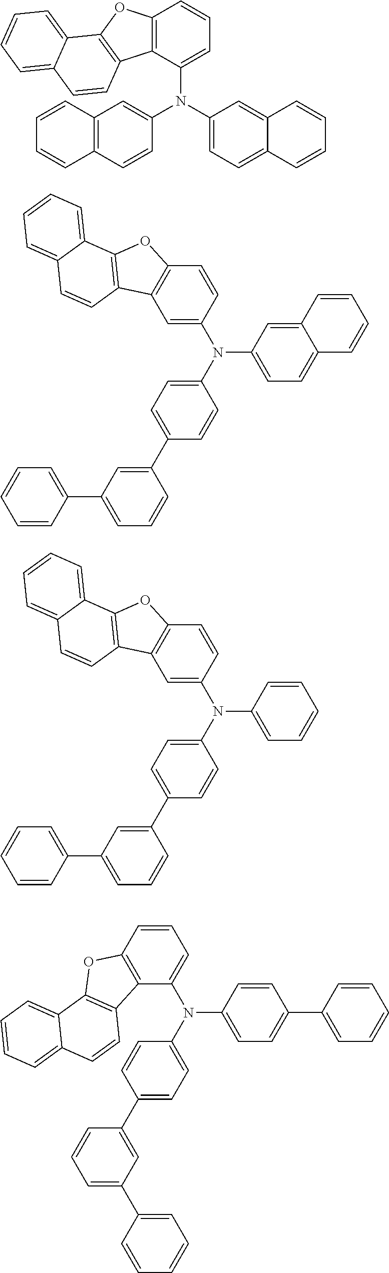

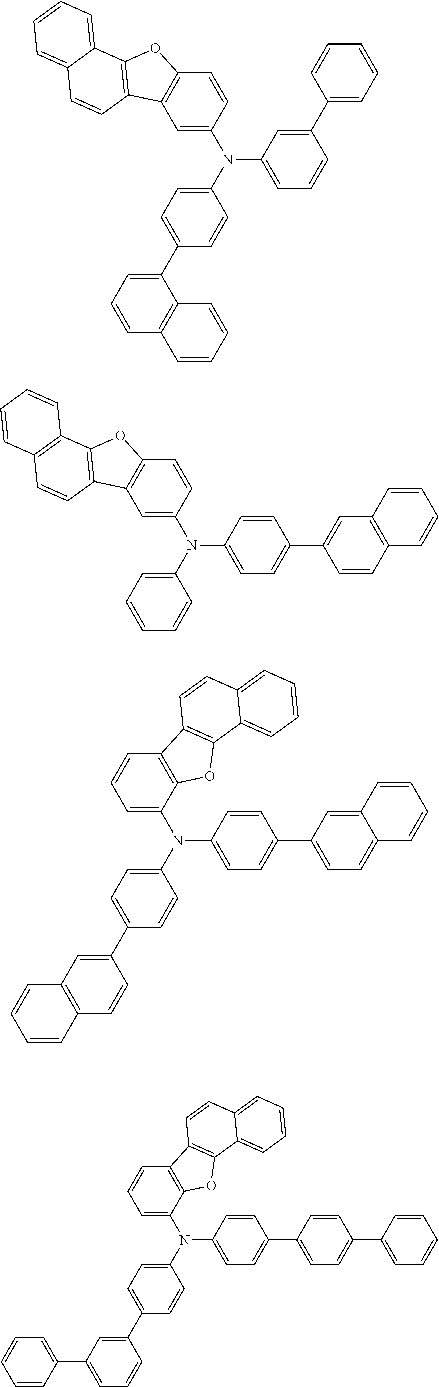 [SMILES: c1ccc(-c2cccc(N(c3ccc(-c4cccc5ccccc45)cc3)c3ccc4oc5c6ccccc6ccc5c4c3)c2)cc1 ; c1ccc(N(c2ccc(-c3ccc4ccccc4c3)cc2)c2ccc3oc4c5ccccc5ccc4c3c2)cc1 ; c1ccc2cc(-c3ccc(N(c4ccc(-c5ccc6ccccc6c5)cc4)c4cccc5c4oc4c6ccccc6ccc54)cc3)ccc2c1 ; c1ccc(-c2ccc(-c3ccc(N(c4ccc(-c5cccc(-c6ccccc6)c5)cc4)c4cccc5c4oc4c6ccccc6ccc54)cc3)cc2)cc1]

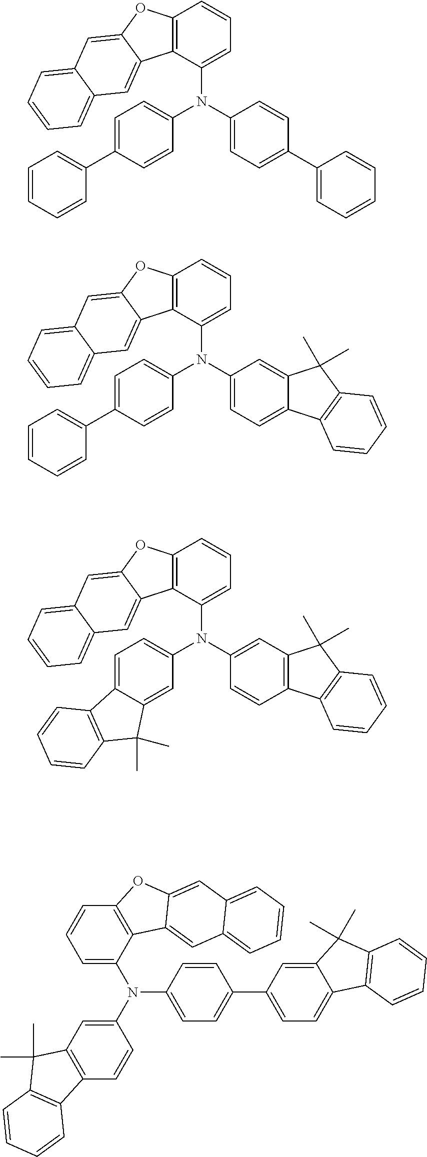 [SMILES: c1ccc(-c2ccc(N(c3ccc(-c4ccccc4)cc3)c3cccc4oc5cc6ccccc6cc5c34)cc2)cc1 ; CC1(C)c2ccccc2-c2ccc(N(c3ccc(-c4ccccc4)cc3)c3cccc4oc5cc6ccccc6cc5c34)cc21 ; CC1(C)c2ccccc2-c2ccc(N(c3ccc4c(c3)C(C)(C)c3ccccc3-4)c3cccc4oc5cc6ccccc6cc5c34)cc21 ; CC1(C)c2ccccc2-c2ccc(-c3ccc(N(c4ccc5c(c4)C(C)(C)c4ccccc4-5)c4cccc5oc6cc7ccccc7cc6c45)cc3)cc21]

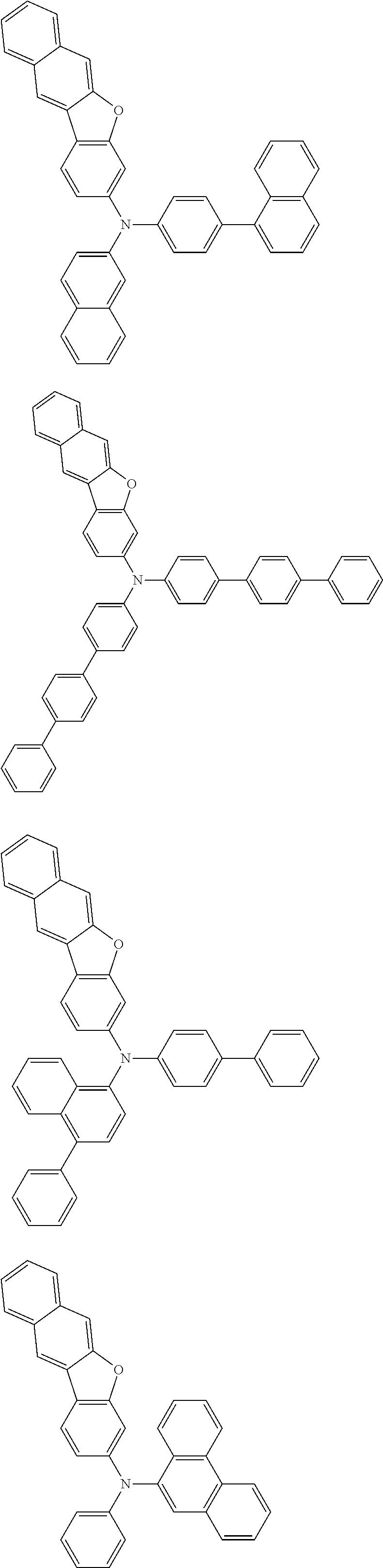

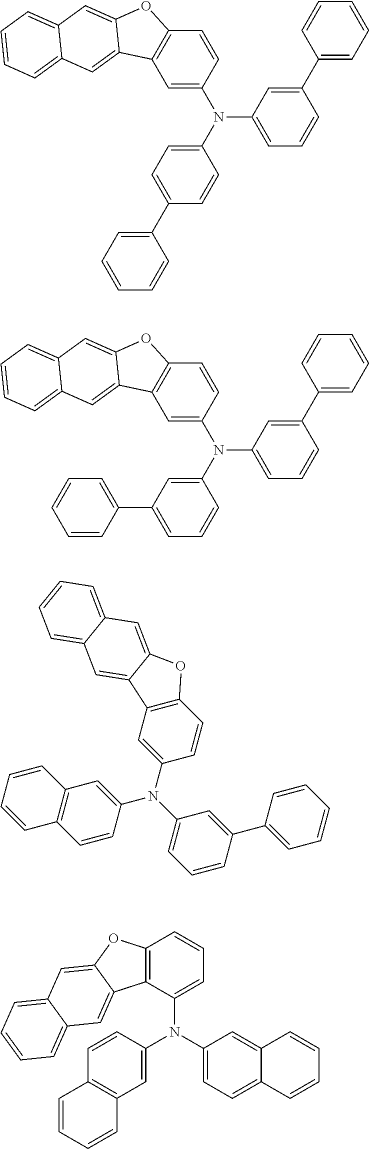

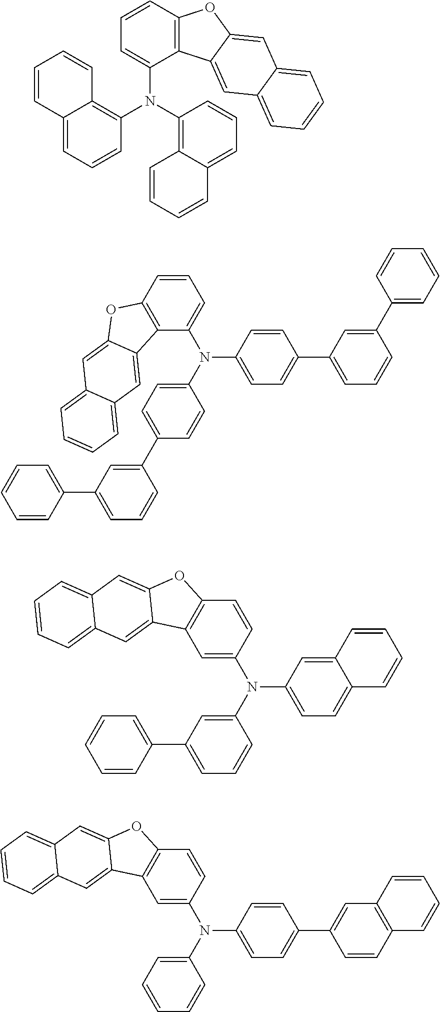 [SMILES: c1ccc2cc3c(cc2c1)oc1cccc(N(c2cccc4ccccc24)c2cccc4ccccc24)c13 ; c1ccc(-c2cccc(-c3ccc(N(c4ccc(-c5cccc(-c6ccccc6)c5)cc4)c4cccc5oc6cc7ccccc7cc6c45)cc3)c2)cc1 ; c1ccc(-c2cccc(N(c3ccc4ccccc4c3)c3ccc4oc5cc6ccccc6cc5c4c3)c2)cc1 ; c1ccc(N(c2ccc(-c3ccc4ccccc4c3)cc2)c2ccc3oc4cc5ccccc5cc4c3c2)cc1]

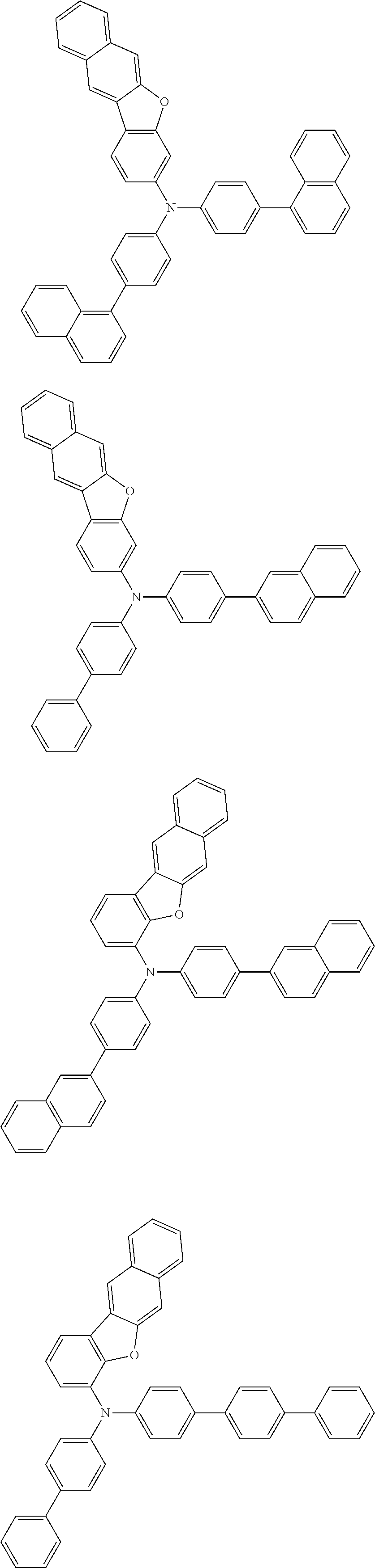

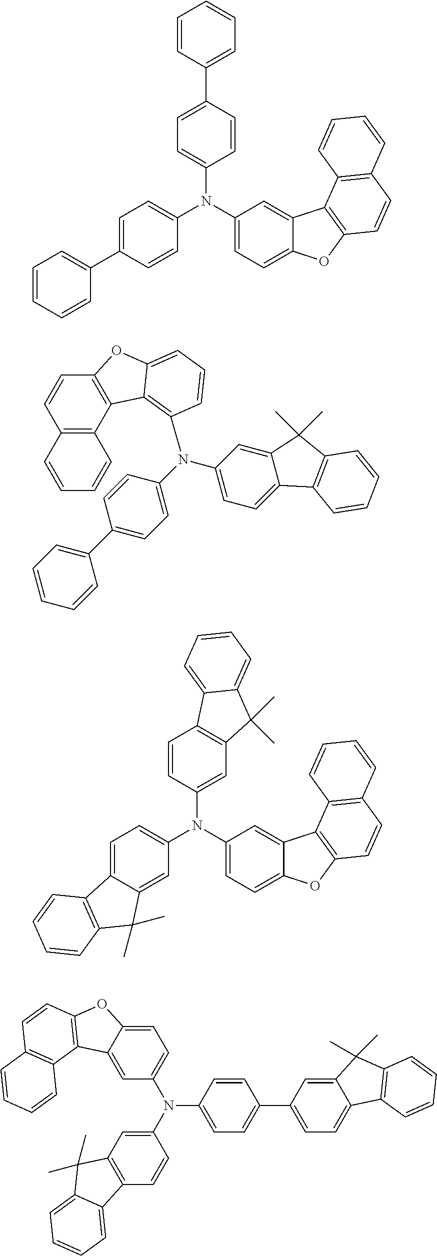 [SMILES: c1ccc(-c2ccc(N(c3ccc(-c4ccccc4)cc3)c3ccc4oc5ccc6ccccc6c5c4c3)cc2)cc1 ; CC1(C)c2ccccc2-c2ccc(N(c3ccc(-c4ccccc4)cc3)c3cccc4oc5ccc6ccccc6c5c34)cc21 ; CC1(C)c2ccccc2-c2ccc(N(c3ccc4c(c3)C(C)(C)c3ccccc3-4)c3ccc4oc5ccc6ccccc6c5c4c3)cc21 ; CC1(C)c2ccccc2-c2ccc(-c3ccc(N(c4ccc5c(c4)C(C)(C)c4ccccc4-5)c4ccc5oc6ccc7ccccc7c6c5c4)cc3)cc21]

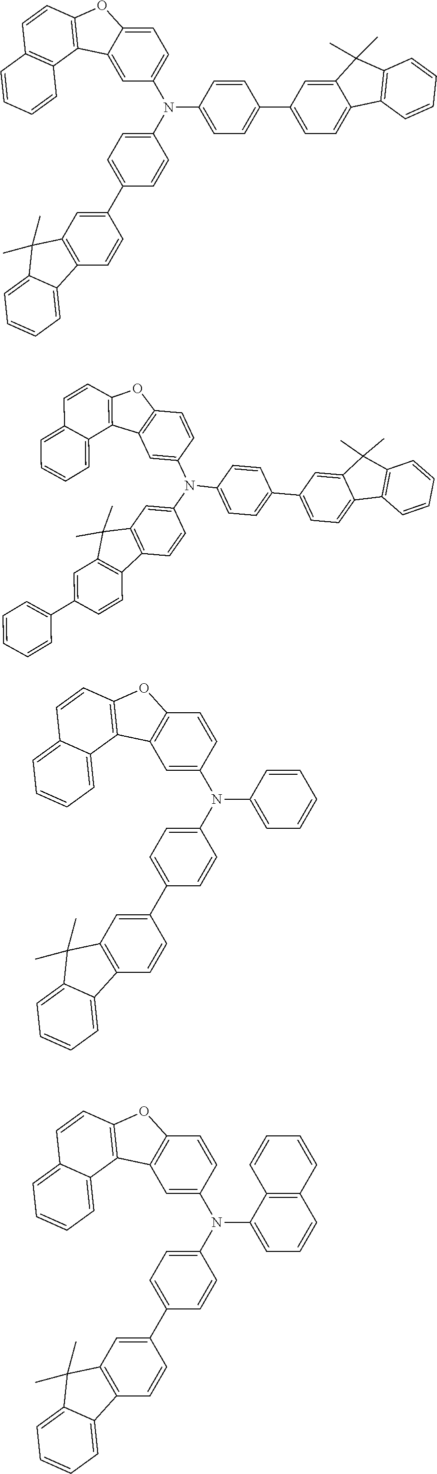 [SMILES: CC1(C)c2ccccc2-c2ccc(-c3ccc(N(c4ccc(-c5ccc6c(c5)C(C)(C)c5ccccc5-6)cc4)c4ccc5oc6ccc7ccccc7c6c5c4)cc3)cc21 ; CC1(C)c2ccccc2-c2ccc(-c3ccc(N(c4ccc5c(c4)C(C)(C)c4cc(-c6ccccc6)ccc4-5)c4ccc5oc6ccc7ccccc7c6c5c4)cc3)cc21 ; CC1(C)c2ccccc2-c2ccc(-c3ccc(N(c4ccccc4)c4ccc5oc6ccc7ccccc7c6c5c4)cc3)cc21 ; CC1(C)c2ccccc2-c2ccc(-c3ccc(N(c4ccc5oc6ccc7ccccc7c6c5c4)c4cccc5ccccc45)cc3)cc21]

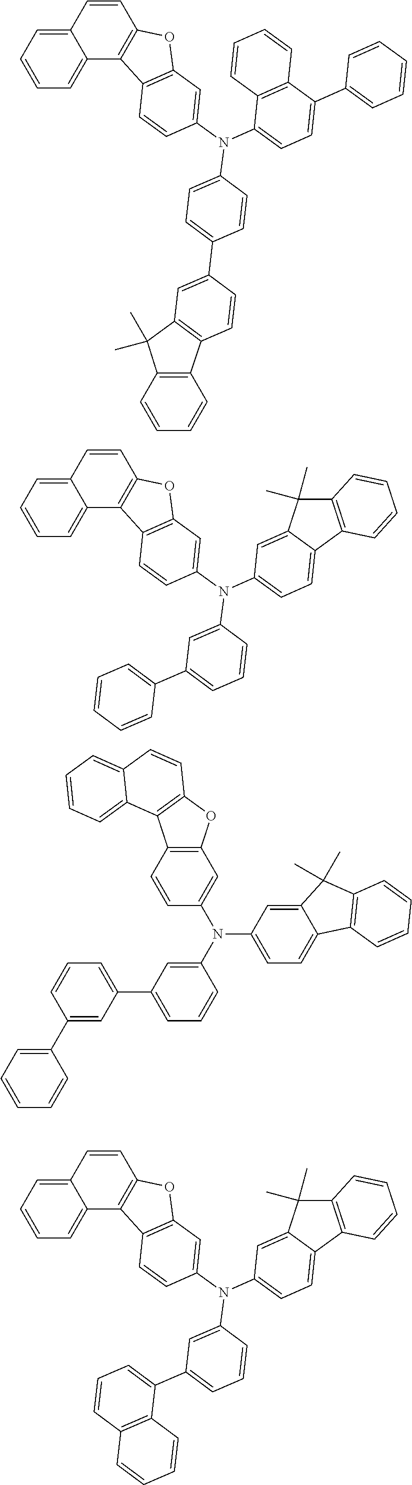

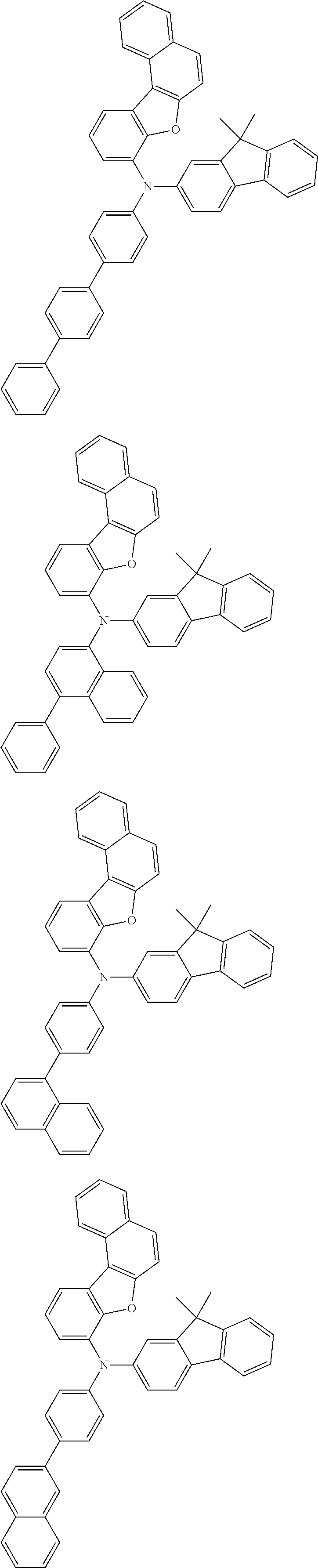

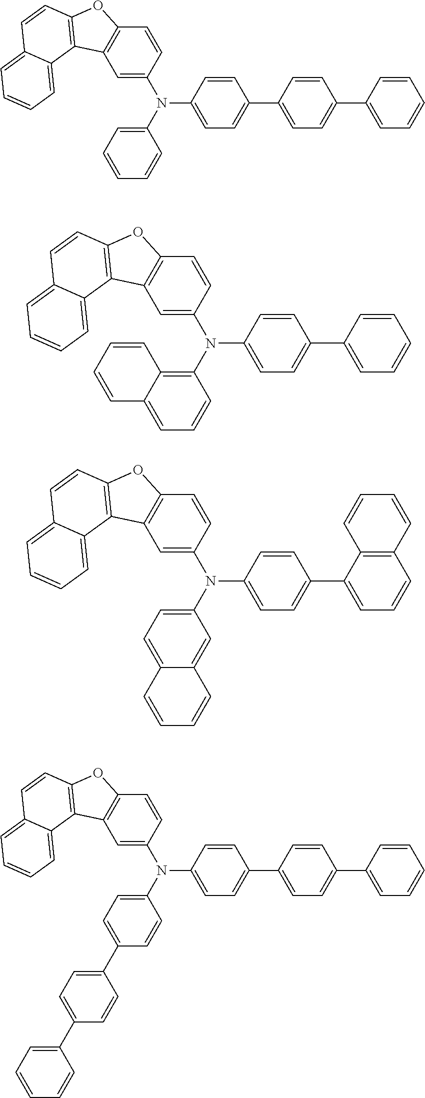 [SMILES: c1ccc(-c2ccc(-c3ccc(N(c4ccccc4)c4ccc5oc6ccc7ccccc7c6c5c4)cc3)cc2)cc1 ; c1ccc(-c2ccc(N(c3ccc4oc5ccc6ccccc6c5c4c3)c3cccc4ccccc34)cc2)cc1 ; c1ccc2cc(N(c3ccc(-c4cccc5ccccc45)cc3)c3ccc4oc5ccc6ccccc6c5c4c3)ccc2c1 ; c1ccc(-c2ccc(-c3ccc(N(c4ccc(-c5ccc(-c6ccccc6)cc5)cc4)c4ccc5oc6ccc7ccccc7c6c5c4)cc3)cc2)cc1]

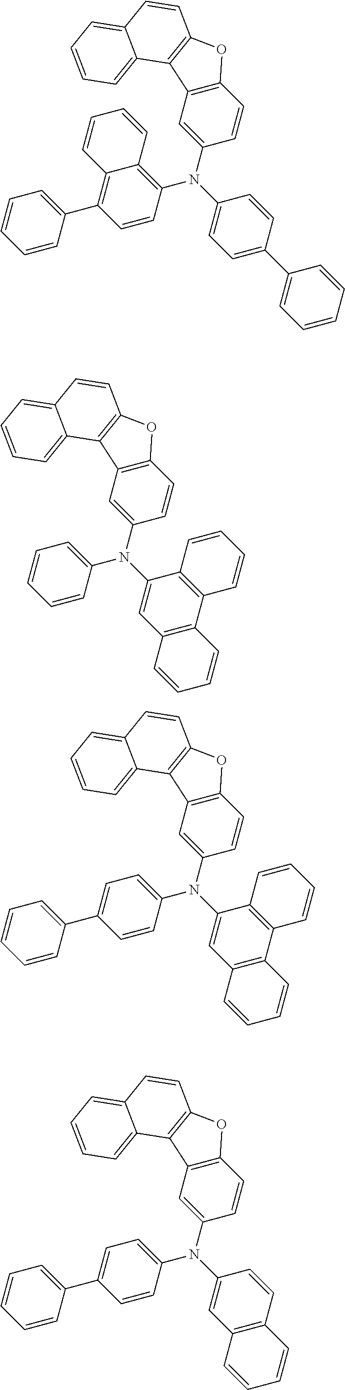

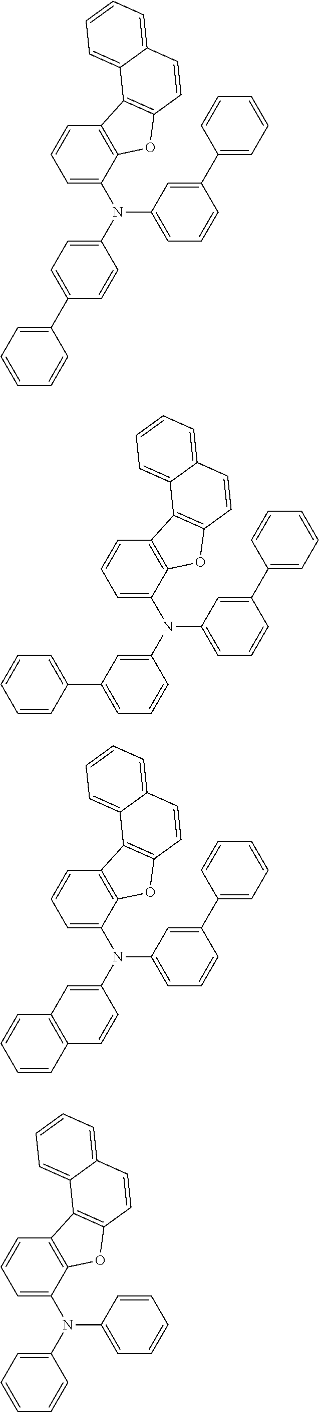

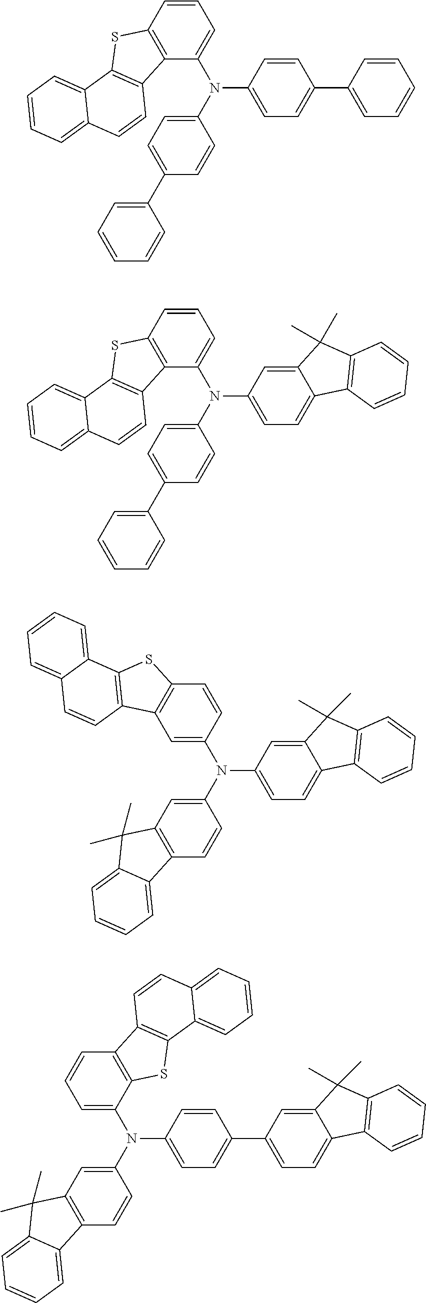 [SMILES: c1ccc(-c2ccc(N(c3ccc(-c4ccccc4)cc3)c3cccc4sc5c6ccccc6ccc5c34)cc2)cc1 ; CC1(C)c2ccccc2-c2ccc(N(c3ccc(-c4ccccc4)cc3)c3cccc4sc5c6ccccc6ccc5c34)cc21 ; CC1(C)c2ccccc2-c2ccc(N(c3ccc4c(c3)C(C)(C)c3ccccc3-4)c3ccc4sc5c6ccccc6ccc5c4c3)cc21 ; CC1(C)c2ccccc2-c2ccc(-c3ccc(N(c4ccc5c(c4)C(C)(C)c4ccccc4-5)c4cccc5c4sc4c6ccccc6ccc54)cc3)cc21]

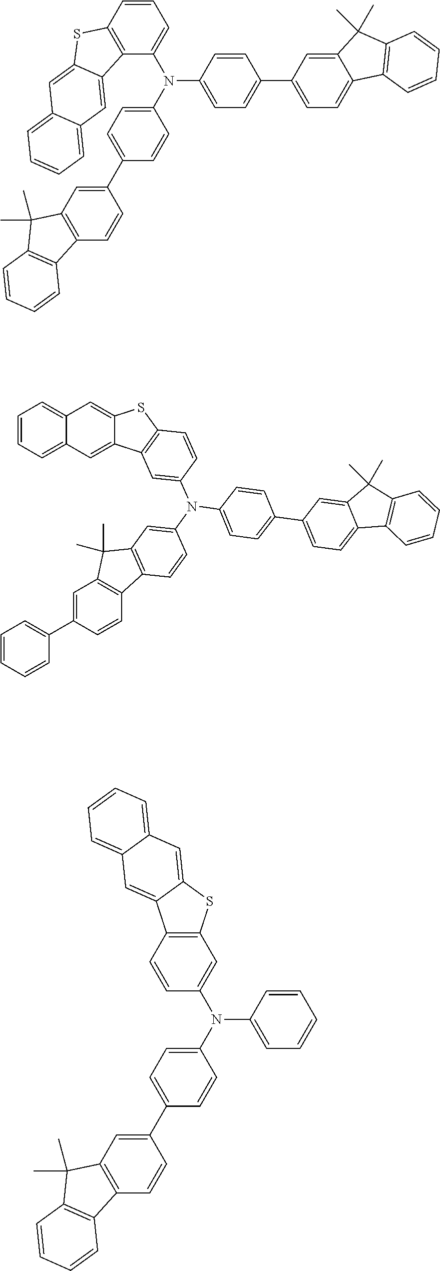 [SMILES: CC1(C)c2ccccc2-c2ccc(-c3ccc(N(c4ccc(-c5ccc6c(c5)C(C)(C)c5ccccc5-6)cc4)c4cccc5sc6cc7ccccc7cc6c45)cc3)cc21 ; CC1(C)c2ccccc2-c2ccc(-c3ccc(N(c4ccc5c(c4)C(C)(C)c4cc(-c6ccccc6)ccc4-5)c4ccc5sc6cc7ccccc7cc6c5c4)cc3)cc21 ; CC1(C)c2ccccc2-c2ccc(-c3ccc(N(c4ccccc4)c4ccc5c(c4)sc4cc6ccccc6cc45)cc3)cc21]

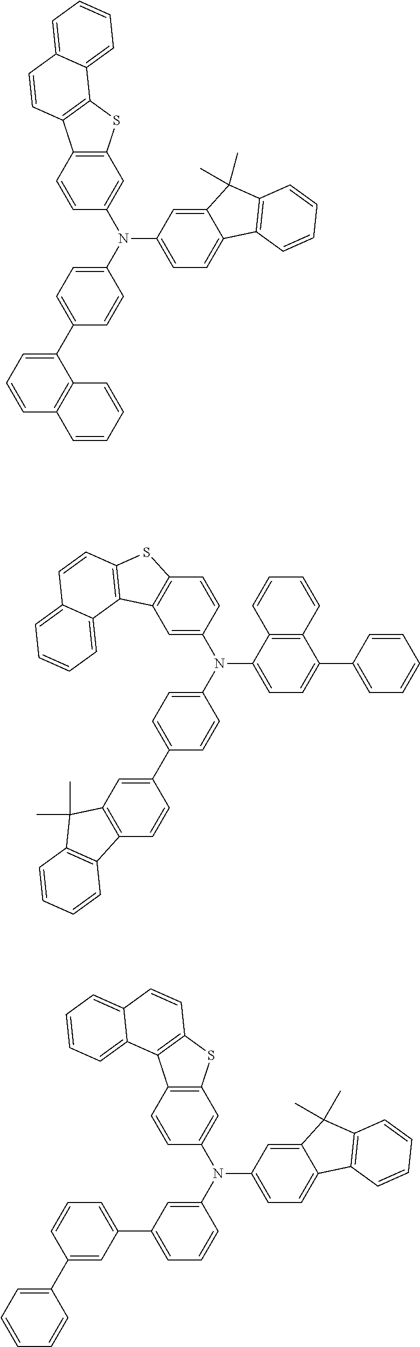 [SMILES: CC1(C)c2ccccc2-c2ccc(N(c3ccc(-c4cccc5ccccc45)cc3)c3ccc4c(c3)sc3c5ccccc5ccc43)cc21 ; CC1(C)c2ccccc2-c2ccc(-c3ccc(N(c4ccc5sc6ccc7ccccc7c6c5c4)c4ccc(-c5ccccc5)c5ccccc45)cc3)cc21 ; CC1(C)c2ccccc2-c2ccc(N(c3cccc(-c4cccc(-c5ccccc5)c4)c3)c3ccc4c(c3)sc3ccc5ccccc5c34)cc21]

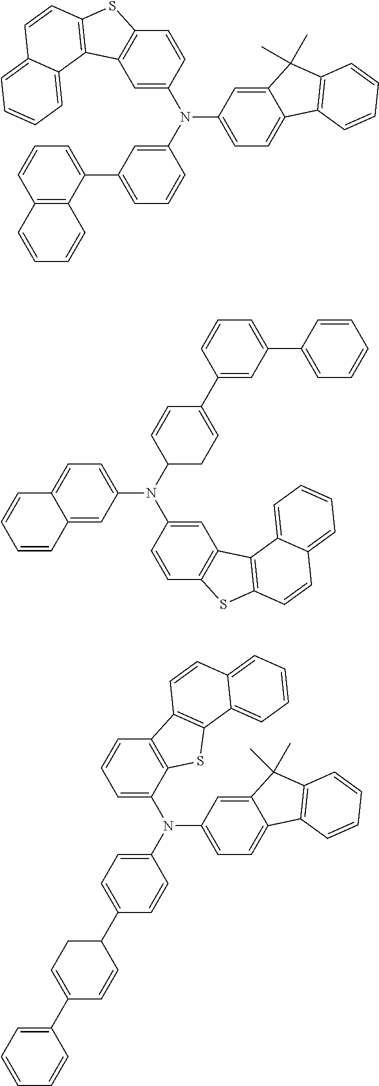 [SMILES: CC1(C)c2ccccc2-c2ccc(N(c3cccc(-c4cccc5ccccc45)c3)c3ccc4sc5ccc6ccccc6c5c4c3)cc21 ; C1=CC(N(c2ccc3ccccc3c2)c2ccc3sc4ccc5ccccc5c4c3c2)CC=C1c1cccc(-c2ccccc2)c1 ; CC1(C)c2ccccc2-c2ccc(N(c3ccc(C4C=CC(c5ccccc5)=CC4)cc3)c3cccc4c3sc3c5ccccc5ccc43)cc21]

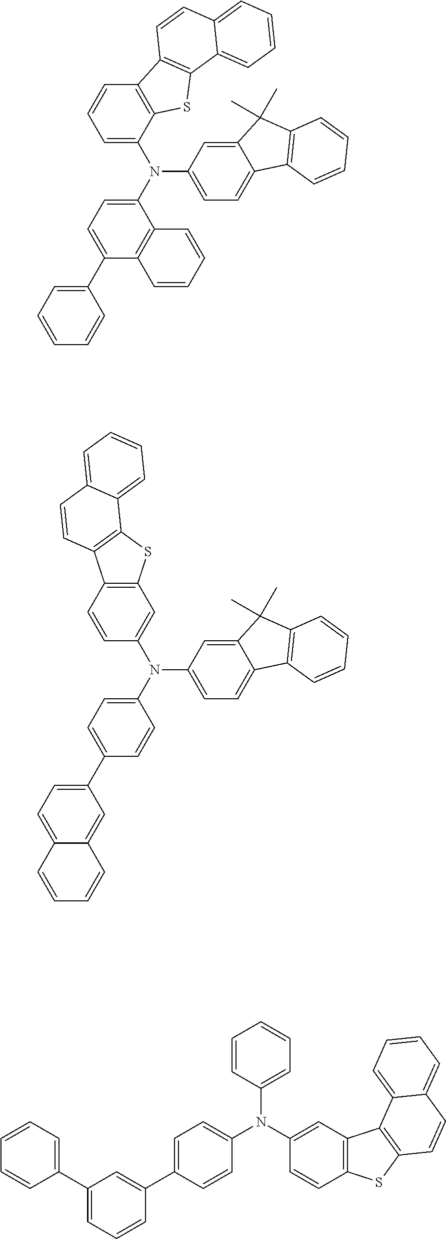 [SMILES: CC1(C)c2ccccc2-c2ccc(N(c3ccc(-c4ccccc4)c4ccccc34)c3cccc4c3sc3c5ccccc5ccc43)cc21 ; CC1(C)c2ccccc2-c2ccc(N(c3ccc(-c4ccc5ccccc5c4)cc3)c3ccc4c(c3)sc3c5ccccc5ccc43)cc21 ; c1ccc(-c2cccc(-c3ccc(N(c4ccccc4)c4ccc5sc6ccc7ccccc7c6c5c4)cc3)c2)cc1]

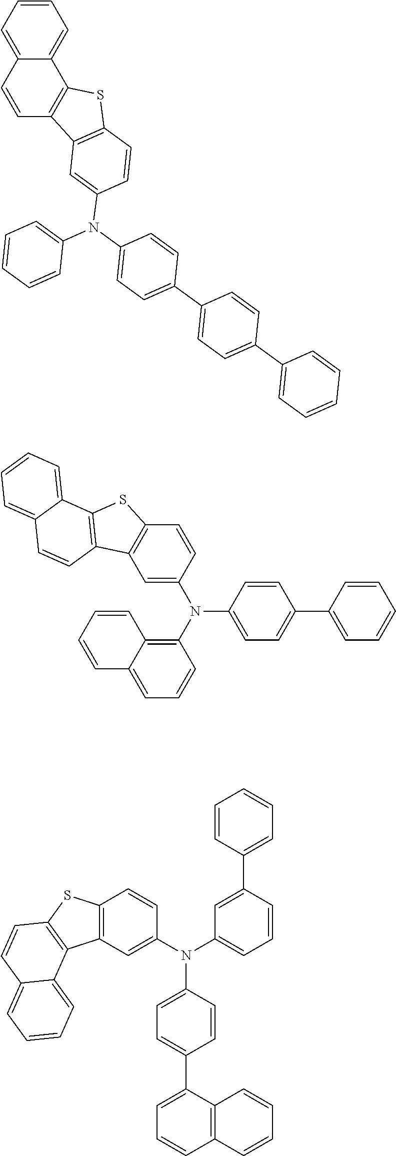 [SMILES: c1ccc(-c2ccc(-c3ccc(N(c4ccccc4)c4ccc5sc6c7ccccc7ccc6c5c4)cc3)cc2)cc1 ; c1ccc(-c2ccc(N(c3ccc4sc5c6ccccc6ccc5c4c3)c3cccc4ccccc34)cc2)cc1 ; c1ccc(-c2cccc(N(c3ccc(-c4cccc5ccccc45)cc3)c3ccc4sc5ccc6ccccc6c5c4c3)c2)cc1]

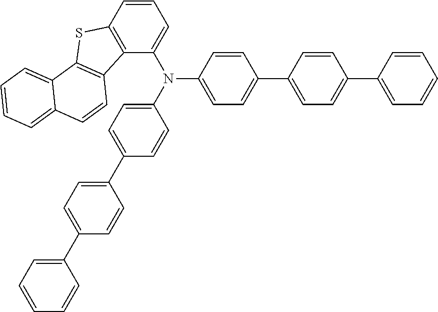 [SMILES: c1ccc(-c2ccc(-c3ccc(N(c4ccc(-c5ccc(-c6ccccc6)cc5)cc4)c4cccc5sc6c7ccccc7ccc6c45)cc3)cc2)cc1]

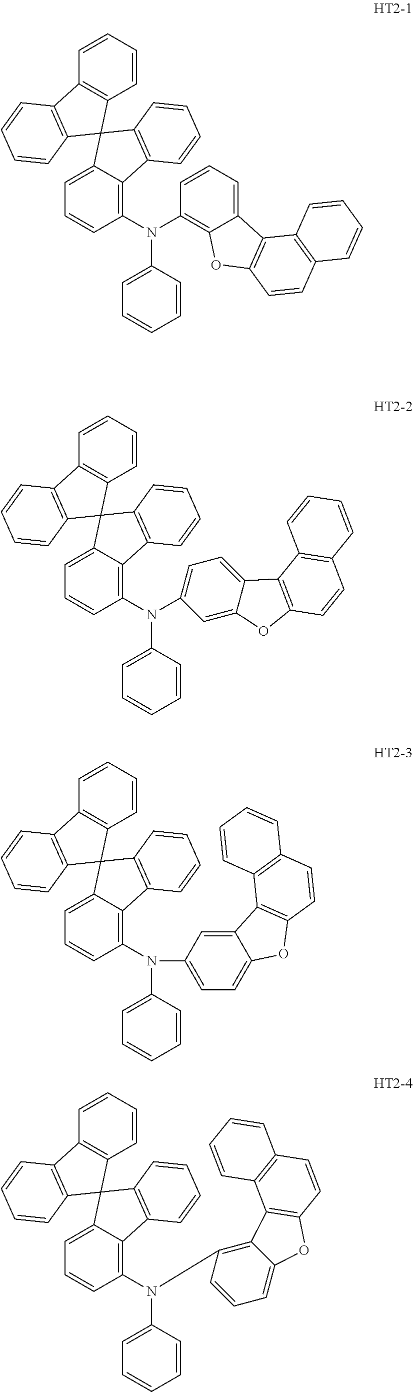 [SMILES: c1ccc(N(c2cccc3c2-c2ccccc2C32c3ccccc3-c3ccccc32)c2cccc3c2oc2ccc4ccccc4c23)cc1 ; c1ccc(N(c2ccc3c(c2)oc2ccc4ccccc4c23)c2cccc3c2-c2ccccc2C32c3ccccc3-c3ccccc32)cc1 ; c1ccc(N(c2ccc3oc4ccc5ccccc5c4c3c2)c2cccc3c2-c2ccccc2C32c3ccccc3-c3ccccc32)cc1 ; c1ccc(N(c2cccc3c2-c2ccccc2C32c3ccccc3-c3ccccc32)c2cccc3oc4ccc5ccccc5c4c23)cc1]

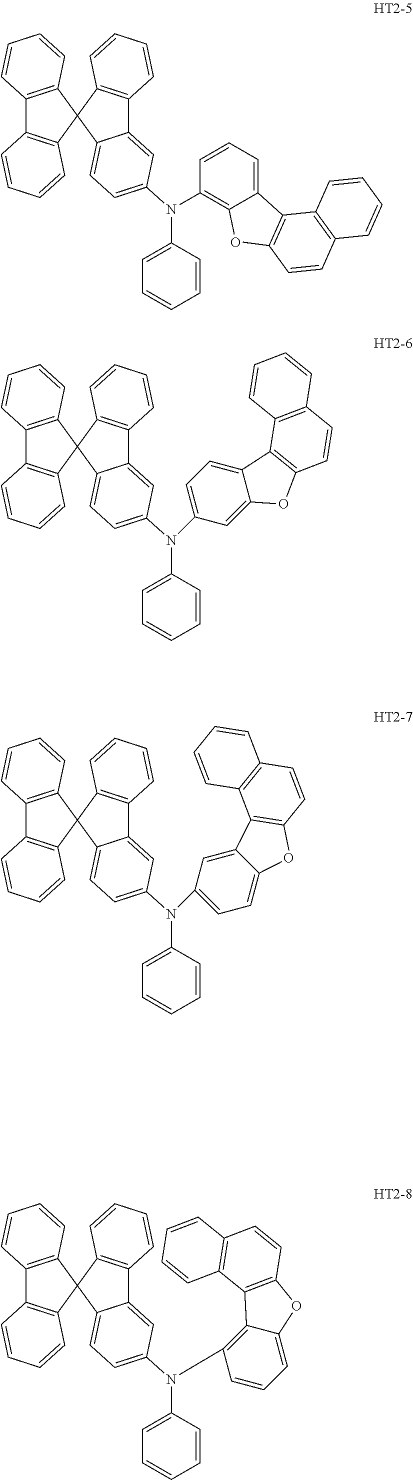 [SMILES: c1ccc(N(c2ccc3c(c2)-c2ccccc2C32c3ccccc3-c3ccccc32)c2cccc3c2oc2ccc4ccccc4c23)cc1 ; c1ccc(N(c2ccc3c(c2)-c2ccccc2C32c3ccccc3-c3ccccc32)c2ccc3c(c2)oc2ccc4ccccc4c23)cc1 ; c1ccc(N(c2ccc3c(c2)-c2ccccc2C32c3ccccc3-c3ccccc32)c2ccc3oc4ccc5ccccc5c4c3c2)cc1 ; c1ccc(N(c2ccc3c(c2)-c2ccccc2C32c3ccccc3-c3ccccc32)c2cccc3oc4ccc5ccccc5c4c23)cc1]

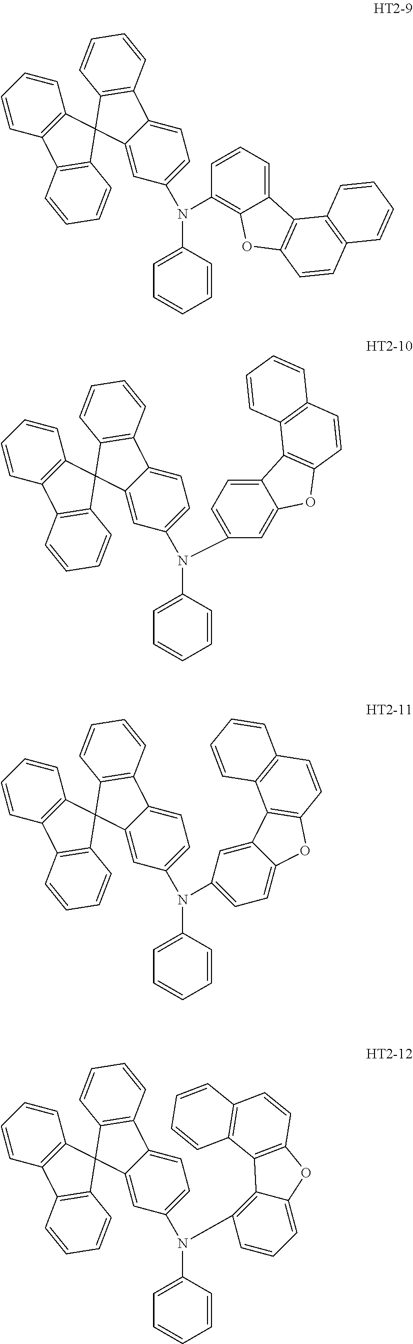

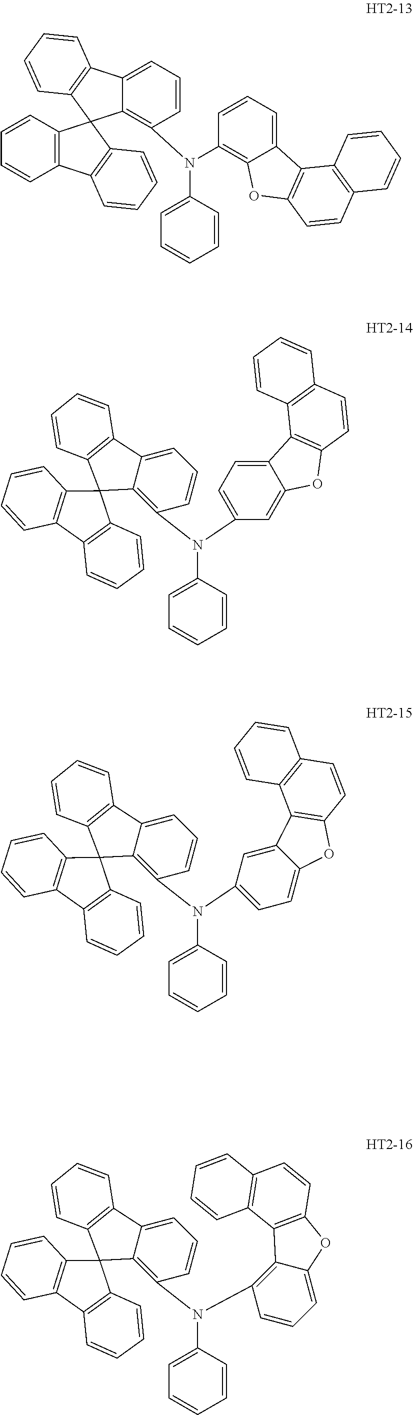 [SMILES: c1ccc(N(c2cccc3c2C2(c4ccccc4-c4ccccc42)c2ccccc2-3)c2cccc3c2oc2ccc4ccccc4c23)cc1 ; c1ccc(N(c2ccc3c(c2)oc2ccc4ccccc4c23)c2cccc3c2C2(c4ccccc4-c4ccccc42)c2ccccc2-3)cc1 ; c1ccc(N(c2ccc3oc4ccc5ccccc5c4c3c2)c2cccc3c2C2(c4ccccc4-c4ccccc42)c2ccccc2-3)cc1 ; c1ccc(N(c2cccc3c2C2(c4ccccc4-c4ccccc42)c2ccccc2-3)c2cccc3oc4ccc5ccccc5c4c23)cc1]

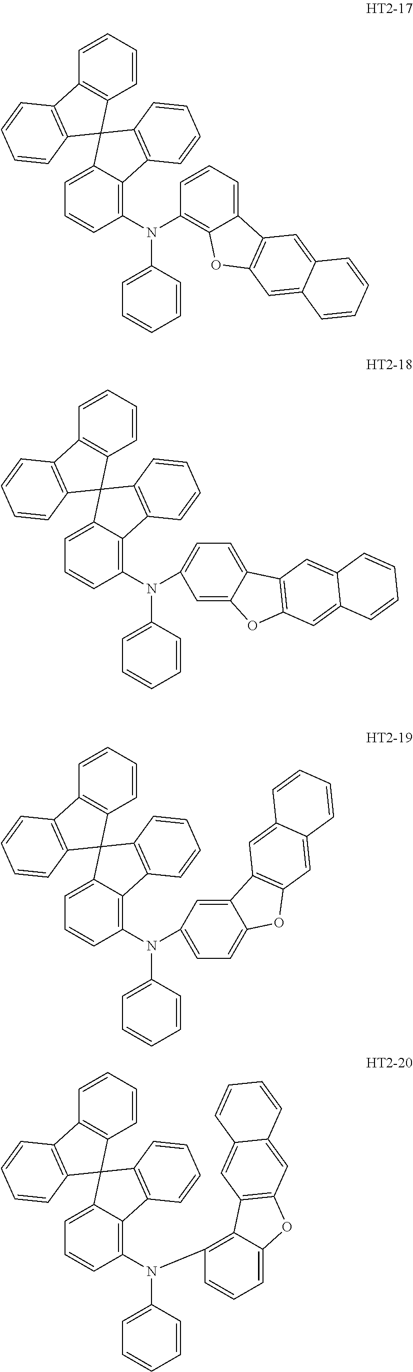

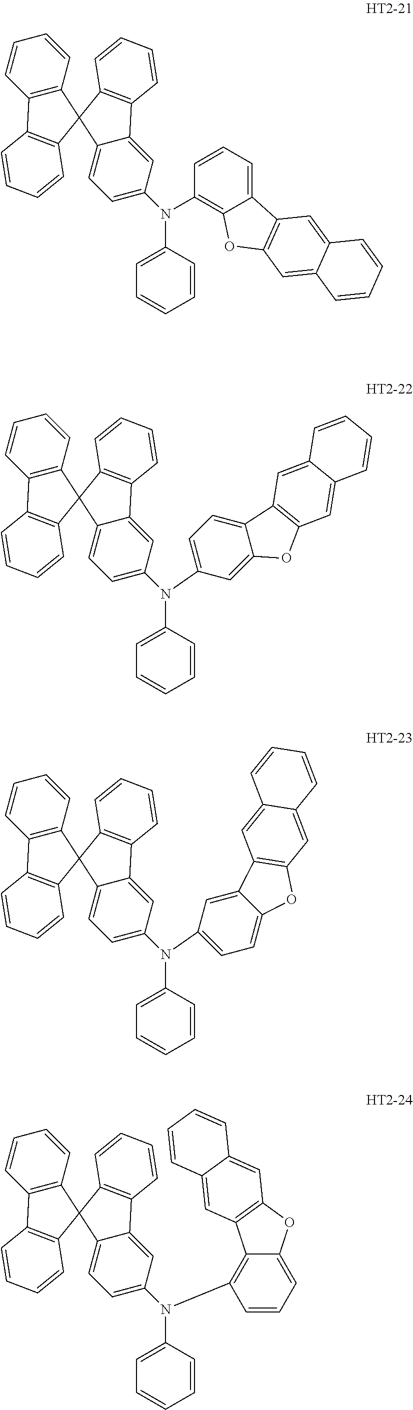 [SMILES: c1ccc(N(c2ccc3c(c2)-c2ccccc2C32c3ccccc3-c3ccccc32)c2cccc3c2oc2cc4ccccc4cc23)cc1 ; c1ccc(N(c2ccc3c(c2)-c2ccccc2C32c3ccccc3-c3ccccc32)c2ccc3c(c2)oc2cc4ccccc4cc23)cc1 ; c1ccc(N(c2ccc3c(c2)-c2ccccc2C32c3ccccc3-c3ccccc32)c2ccc3oc4cc5ccccc5cc4c3c2)cc1 ; c1ccc(N(c2ccc3c(c2)-c2ccccc2C32c3ccccc3-c3ccccc32)c2cccc3oc4cc5ccccc5cc4c23)cc1]

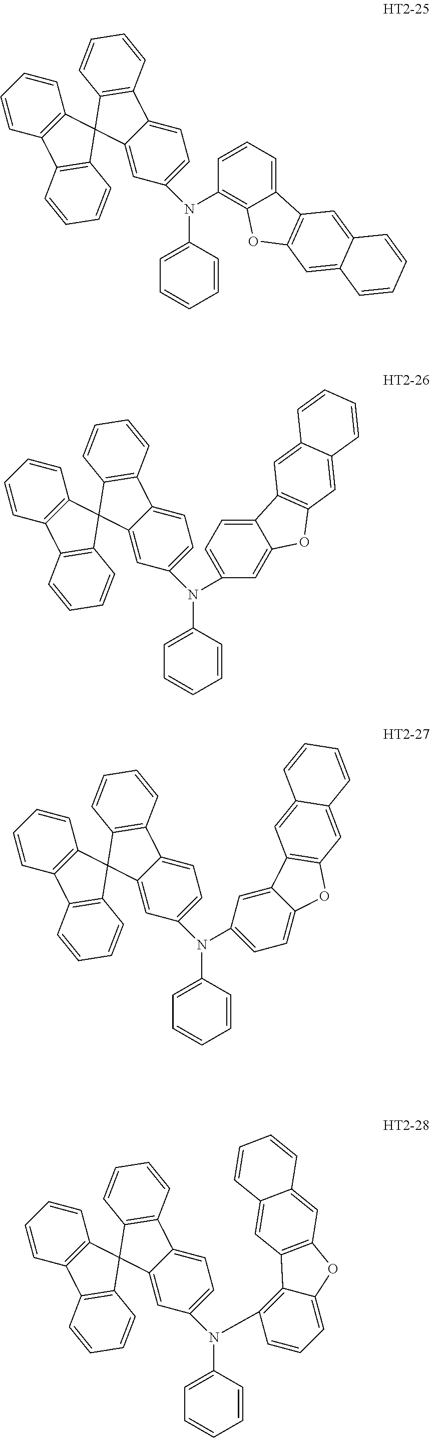 [SMILES: c1ccc(N(c2ccc3c(c2)C2(c4ccccc4-c4ccccc42)c2ccccc2-3)c2cccc3c2oc2cc4ccccc4cc23)cc1 ; c1ccc(N(c2ccc3c(c2)C2(c4ccccc4-c4ccccc42)c2ccccc2-3)c2ccc3c(c2)oc2cc4ccccc4cc23)cc1 ; c1ccc(N(c2ccc3c(c2)C2(c4ccccc4-c4ccccc42)c2ccccc2-3)c2ccc3oc4cc5ccccc5cc4c3c2)cc1 ; c1ccc(N(c2ccc3c(c2)C2(c4ccccc4-c4ccccc42)c2ccccc2-3)c2cccc3oc4cc5ccccc5cc4c23)cc1]

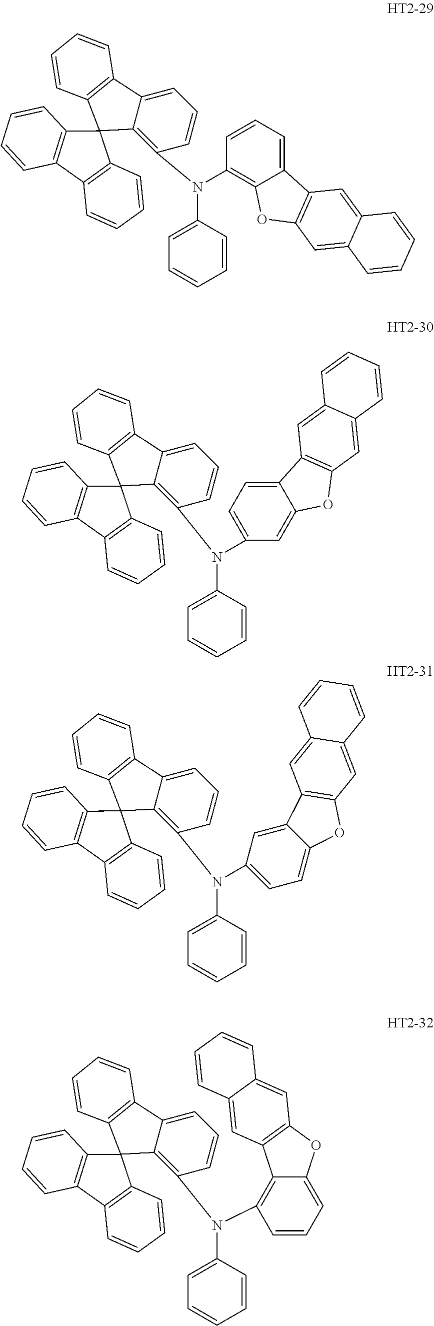 [SMILES: c1ccc(N(c2cccc3c2C2(c4ccccc4-c4ccccc42)c2ccccc2-3)c2cccc3c2oc2cc4ccccc4cc23)cc1 ; c1ccc(N(c2ccc3c(c2)oc2cc4ccccc4cc23)c2cccc3c2C2(c4ccccc4-c4ccccc42)c2ccccc2-3)cc1 ; c1ccc(N(c2ccc3oc4cc5ccccc5cc4c3c2)c2cccc3c2C2(c4ccccc4-c4ccccc42)c2ccccc2-3)cc1 ; c1ccc(N(c2cccc3c2C2(c4ccccc4-c4ccccc42)c2ccccc2-3)c2cccc3oc4cc5ccccc5cc4c23)cc1]

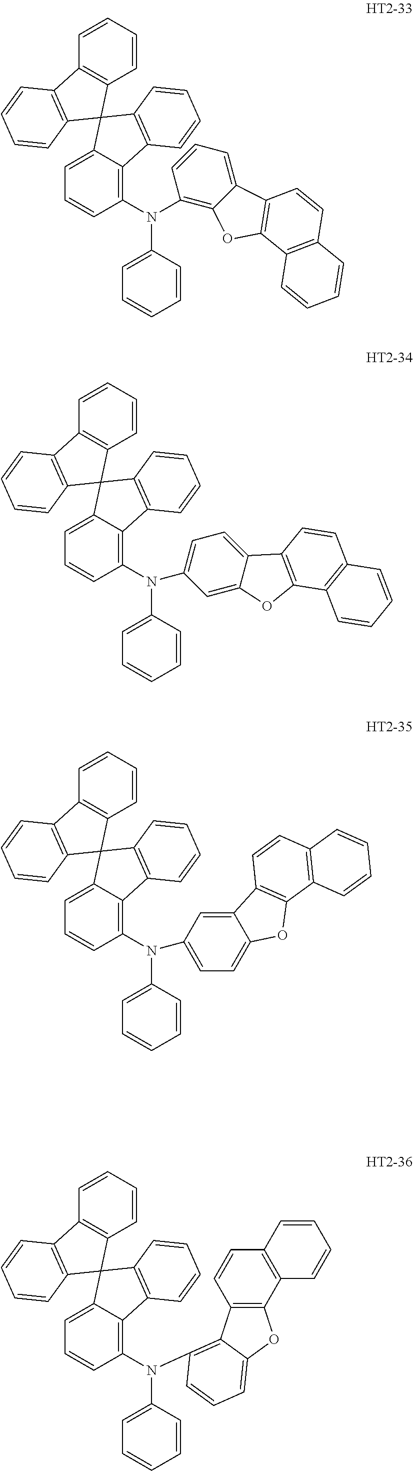 [SMILES: c1ccc(N(c2cccc3c2-c2ccccc2C32c3ccccc3-c3ccccc32)c2cccc3c2oc2c4ccccc4ccc32)cc1 ; c1ccc(N(c2ccc3c(c2)oc2c4ccccc4ccc32)c2cccc3c2-c2ccccc2C32c3ccccc3-c3ccccc32)cc1 ; c1ccc(N(c2ccc3oc4c5ccccc5ccc4c3c2)c2cccc3c2-c2ccccc2C32c3ccccc3-c3ccccc32)cc1 ; c1ccc(N(c2cccc3c2-c2ccccc2C32c3ccccc3-c3ccccc32)c2cccc3oc4c5ccccc5ccc4c23)cc1]

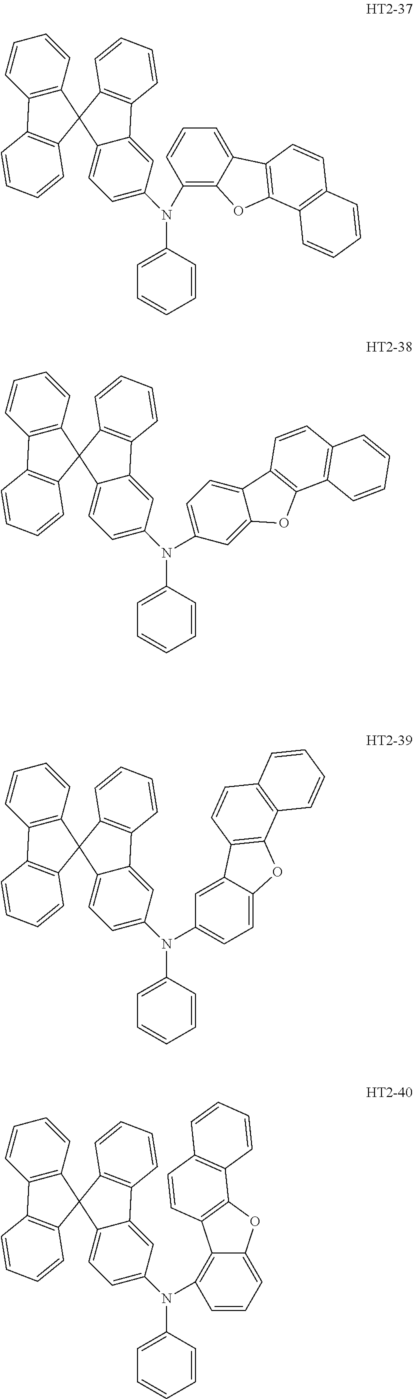 [SMILES: c1ccc(N(c2ccc3c(c2)-c2ccccc2C32c3ccccc3-c3ccccc32)c2cccc3c2oc2c4ccccc4ccc32)cc1 ; c1ccc(N(c2ccc3c(c2)-c2ccccc2C32c3ccccc3-c3ccccc32)c2ccc3c(c2)oc2c4ccccc4ccc32)cc1 ; c1ccc(N(c2ccc3c(c2)-c2ccccc2C32c3ccccc3-c3ccccc32)c2ccc3oc4c5ccccc5ccc4c3c2)cc1 ; c1ccc(N(c2ccc3c(c2)-c2ccccc2C32c3ccccc3-c3ccccc32)c2cccc3oc4c5ccccc5ccc4c23)cc1]

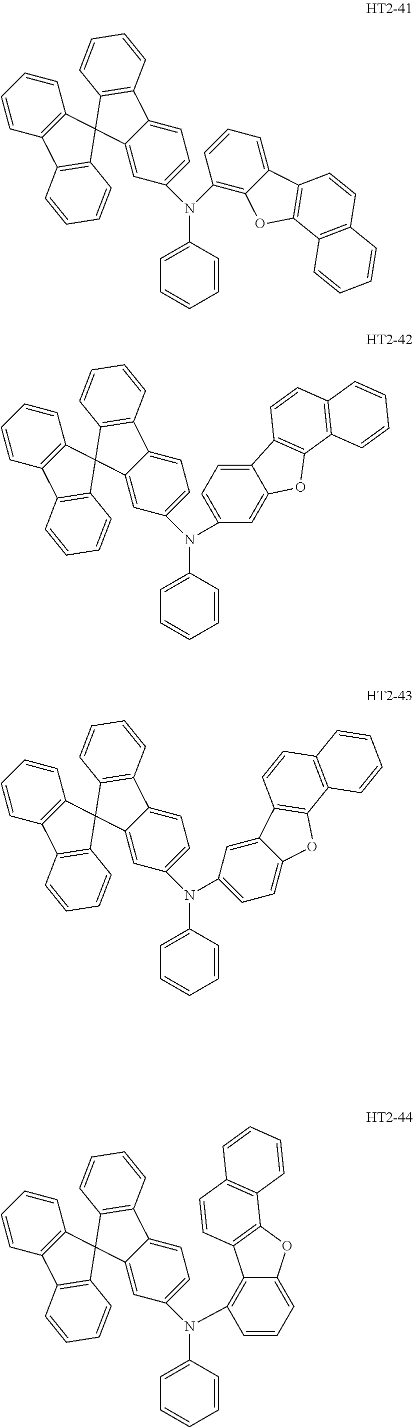 [SMILES: c1ccc(N(c2ccc3c(c2)C2(c4ccccc4-c4ccccc42)c2ccccc2-3)c2cccc3c2oc2c4ccccc4ccc32)cc1 ; c1ccc(N(c2ccc3c(c2)C2(c4ccccc4-c4ccccc42)c2ccccc2-3)c2ccc3c(c2)oc2c4ccccc4ccc32)cc1 ; c1ccc(N(c2ccc3c(c2)C2(c4ccccc4-c4ccccc42)c2ccccc2-3)c2ccc3oc4c5ccccc5ccc4c3c2)cc1 ; c1ccc(N(c2ccc3c(c2)C2(c4ccccc4-c4ccccc42)c2ccccc2-3)c2cccc3oc4c5ccccc5ccc4c23)cc1]

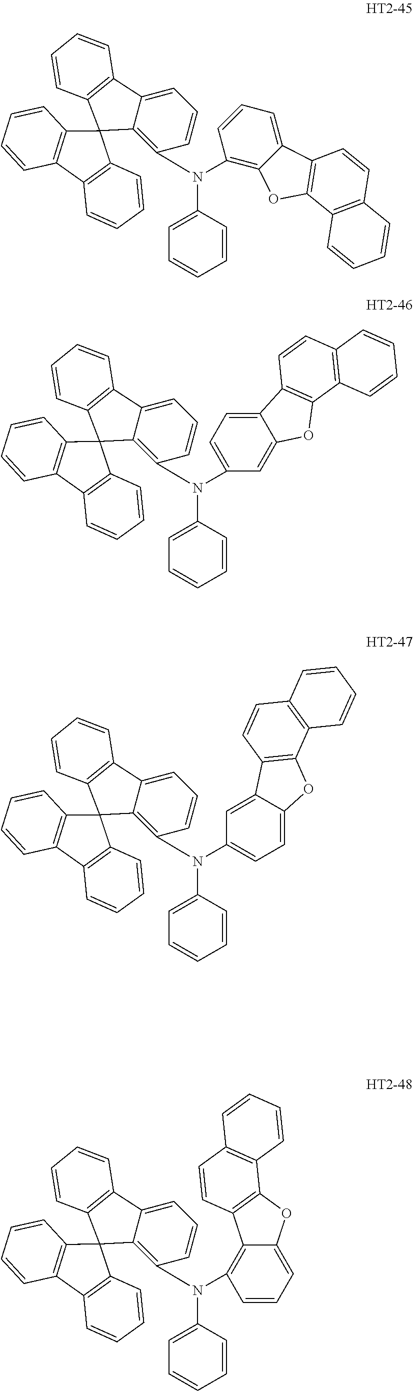 [SMILES: c1ccc(N(c2cccc3c2C2(c4ccccc4-c4ccccc42)c2ccccc2-3)c2cccc3c2oc2c4ccccc4ccc32)cc1 ; c1ccc(N(c2ccc3c(c2)oc2c4ccccc4ccc32)c2cccc3c2C2(c4ccccc4-c4ccccc42)c2ccccc2-3)cc1 ; c1ccc(N(c2ccc3oc4c5ccccc5ccc4c3c2)c2cccc3c2C2(c4ccccc4-c4ccccc42)c2ccccc2-3)cc1 ; c1ccc(N(c2cccc3c2C2(c4ccccc4-c4ccccc42)c2ccccc2-3)c2cccc3oc4c5ccccc5ccc4c23)cc1]

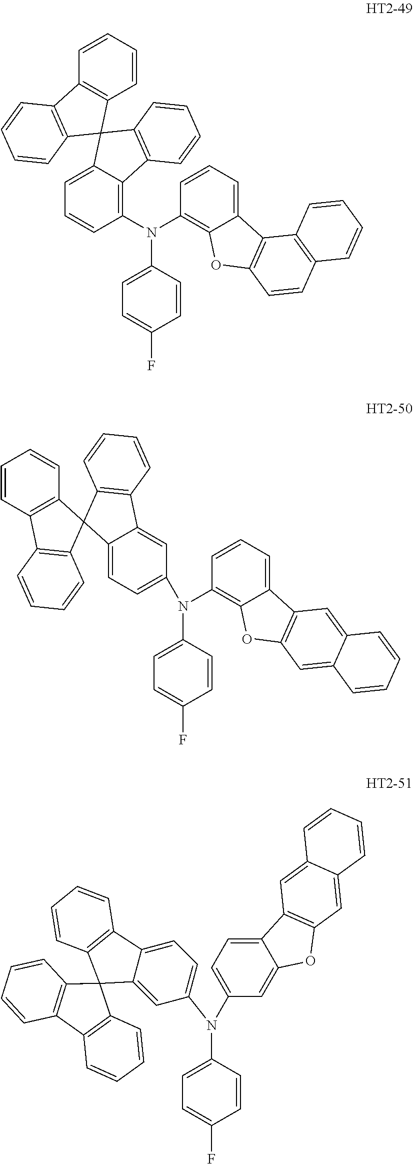 [SMILES: Fc1ccc(N(c2cccc3c2-c2ccccc2C32c3ccccc3-c3ccccc32)c2cccc3c2oc2ccc4ccccc4c23)cc1 ; Fc1ccc(N(c2ccc3c(c2)-c2ccccc2C32c3ccccc3-c3ccccc32)c2cccc3c2oc2cc4ccccc4cc23)cc1 ; Fc1ccc(N(c2ccc3c(c2)C2(c4ccccc4-c4ccccc42)c2ccccc2-3)c2ccc3c(c2)oc2cc4ccccc4cc23)cc1]

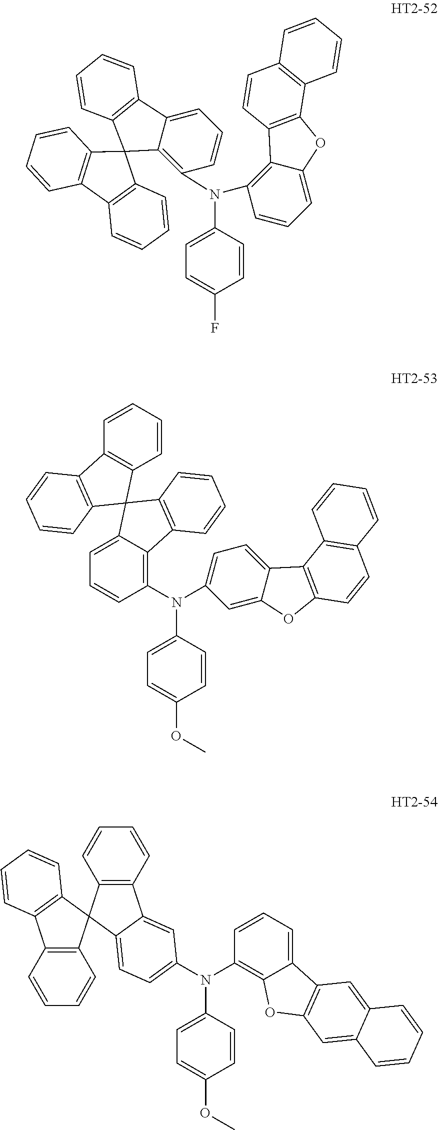 [SMILES: Fc1ccc(N(c2cccc3c2C2(c4ccccc4-c4ccccc42)c2ccccc2-3)c2cccc3oc4c5ccccc5ccc4c23)cc1 ; COc1ccc(N(c2ccc3c(c2)oc2ccc4ccccc4c23)c2cccc3c2-c2ccccc2C32c3ccccc3-c3ccccc32)cc1 ; COc1ccc(N(c2ccc3c(c2)-c2ccccc2C32c3ccccc3-c3ccccc32)c2cccc3c2oc2cc4ccccc4cc23)cc1]

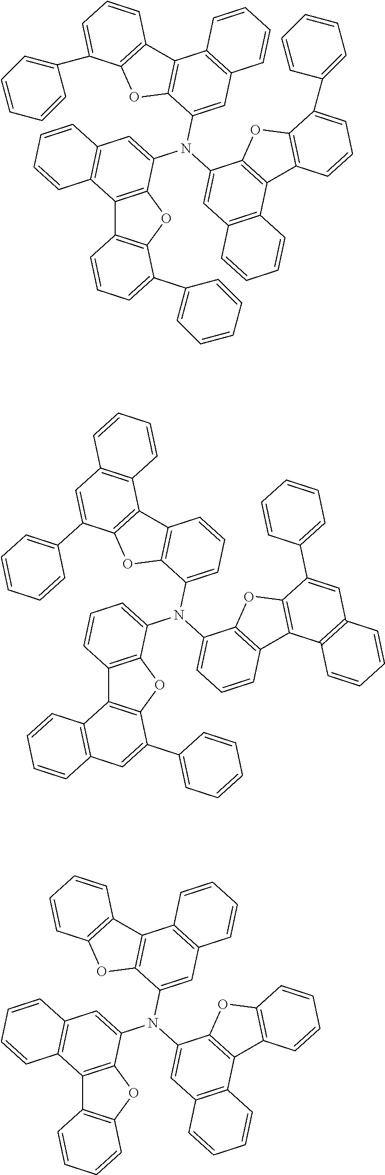 [SMILES: c1ccc(-c2cccc3c2oc2c(N(c4cc5ccccc5c5c4oc4c(-c6ccccc6)cccc45)c4cc5ccccc5c5c4oc4c(-c6ccccc6)cccc45)cc4ccccc4c23)cc1 ; c1ccc(-c2cc3ccccc3c3c2oc2c(N(c4cccc5c4oc4c(-c6ccccc6)cc6ccccc6c45)c4cccc5c4oc4c(-c6ccccc6)cc6ccccc6c45)cccc23)cc1 ; c1ccc2c(c1)cc(N(c1cc3ccccc3c3c1oc1ccccc13)c1cc3ccccc3c3c1oc1ccccc13)c1oc3ccccc3c12]

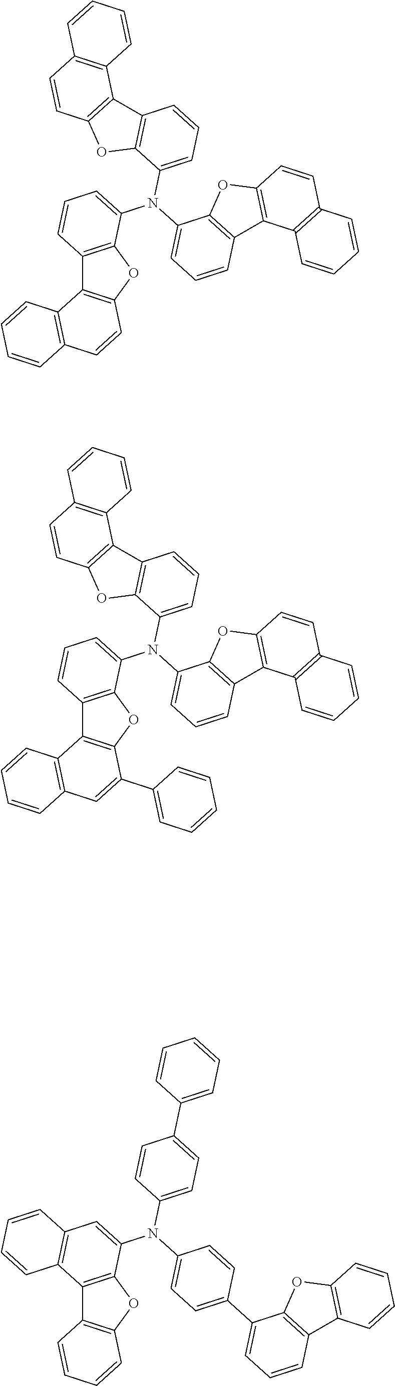 [SMILES: c1ccc2c(c1)ccc1oc3c(N(c4cccc5c4oc4ccc6ccccc6c45)c4cccc5c4oc4ccc6ccccc6c45)cccc3c12 ; c1ccc(-c2cc3ccccc3c3c2oc2c(N(c4cccc5c4oc4ccc6ccccc6c45)c4cccc5c4oc4ccc6ccccc6c45)cccc23)cc1 ; c1ccc(-c2ccc(N(c3ccc(-c4cccc5c4oc4ccccc45)cc3)c3cc4ccccc4c4c3oc3ccccc34)cc2)cc1]

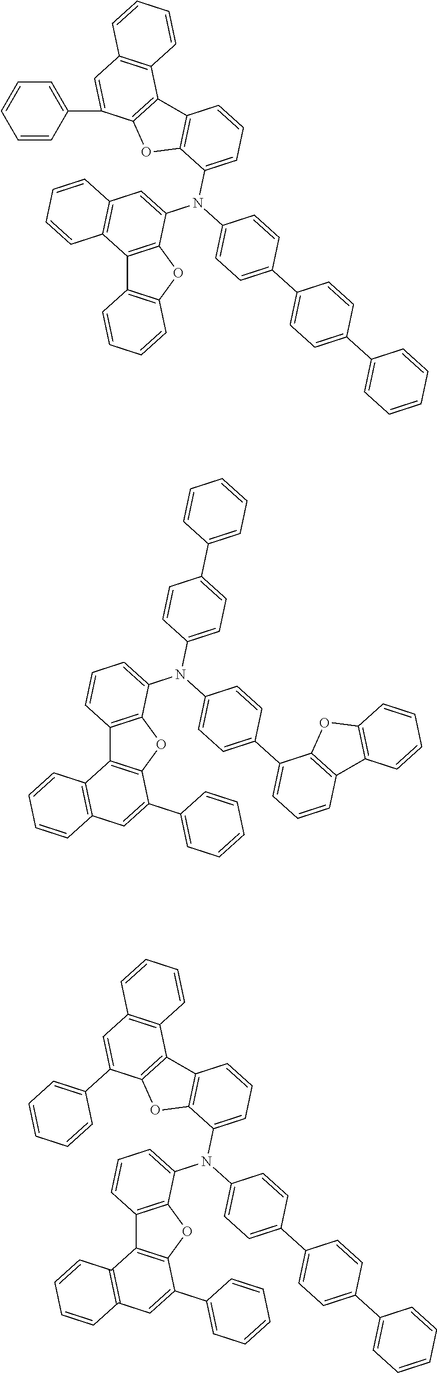 [SMILES: c1ccc(-c2ccc(-c3ccc(N(c4cccc5c4oc4c(-c6ccccc6)cc6ccccc6c45)c4cc5ccccc5c5c4oc4ccccc45)cc3)cc2)cc1 ; c1ccc(-c2ccc(N(c3ccc(-c4cccc5c4oc4ccccc45)cc3)c3cccc4c3oc3c(-c5ccccc5)cc5ccccc5c34)cc2)cc1 ; c1ccc(-c2ccc(-c3ccc(N(c4cccc5c4oc4c(-c6ccccc6)cc6ccccc6c45)c4cccc5c4oc4c(-c6ccccc6)cc6ccccc6c45)cc3)cc2)cc1]

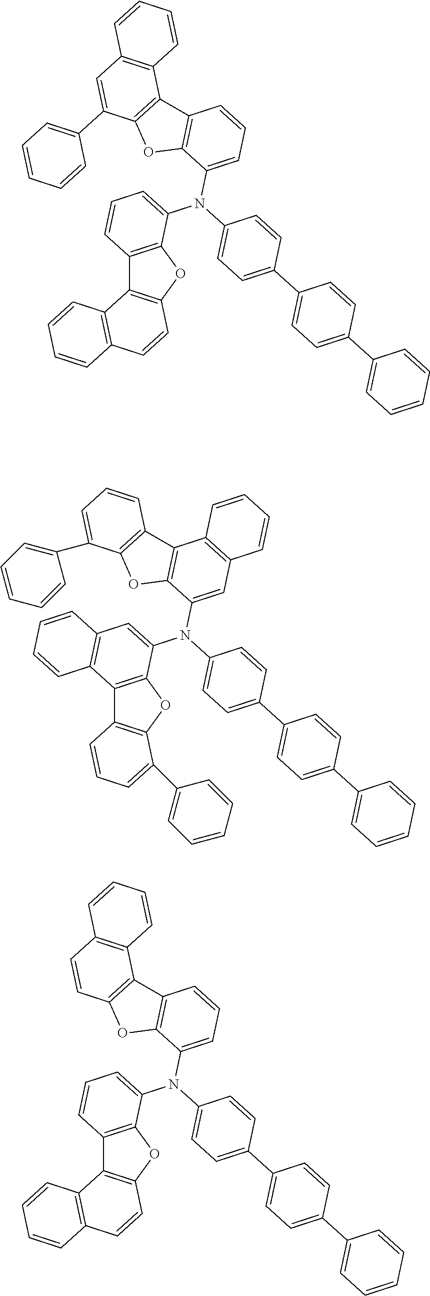 [SMILES: c1ccc(-c2ccc(-c3ccc(N(c4cccc5c4oc4ccc6ccccc6c45)c4cccc5c4oc4c(-c6ccccc6)cc6ccccc6c45)cc3)cc2)cc1 ; c1ccc(-c2ccc(-c3ccc(N(c4cc5ccccc5c5c4oc4c(-c6ccccc6)cccc45)c4cc5ccccc5c5c4oc4c(-c6ccccc6)cccc45)cc3)cc2)cc1 ; c1ccc(-c2ccc(-c3ccc(N(c4cccc5c4oc4ccc6ccccc6c45)c4cccc5c4oc4ccc6ccccc6c45)cc3)cc2)cc1]

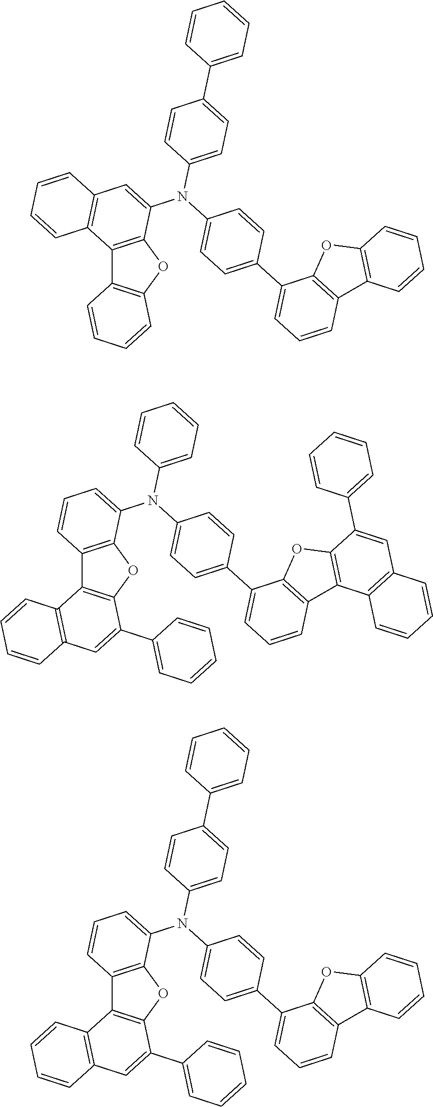 [SMILES: c1ccc(-c2ccc(N(c3ccc(-c4cccc5c4oc4ccccc45)cc3)c3cc4ccccc4c4c3oc3ccccc34)cc2)cc1 ; c1ccc(-c2cc3ccccc3c3c2oc2c(-c4ccc(N(c5ccccc5)c5cccc6c5oc5c(-c7ccccc7)cc7ccccc7c56)cc4)cccc23)cc1 ; c1ccc(-c2ccc(N(c3ccc(-c4cccc5c4oc4ccccc45)cc3)c3cccc4c3oc3c(-c5ccccc5)cc5ccccc5c34)cc2)cc1]

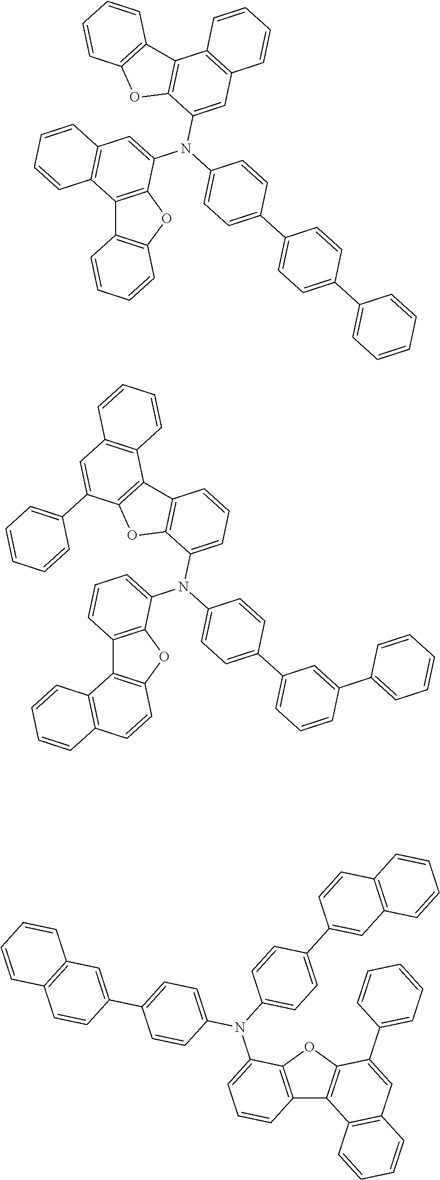 [SMILES: c1ccc(-c2ccc(-c3ccc(N(c4cc5ccccc5c5c4oc4ccccc45)c4cc5ccccc5c5c4oc4ccccc45)cc3)cc2)cc1 ; c1ccc(-c2cccc(-c3ccc(N(c4cccc5c4oc4ccc6ccccc6c45)c4cccc5c4oc4c(-c6ccccc6)cc6ccccc6c45)cc3)c2)cc1 ; c1ccc(-c2cc3ccccc3c3c2oc2c(N(c4ccc(-c5ccc6ccccc6c5)cc4)c4ccc(-c5ccc6ccccc6c5)cc4)cccc23)cc1]

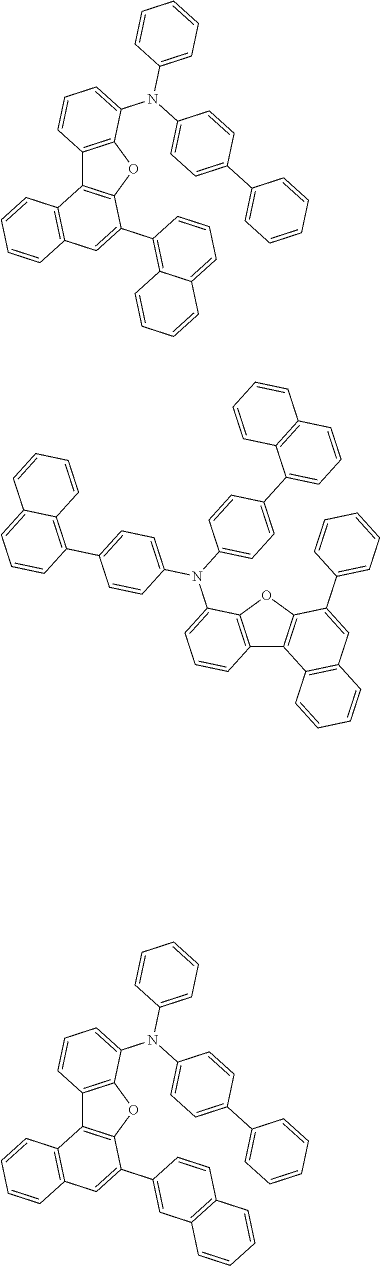 [SMILES: c1ccc(-c2ccc(N(c3ccccc3)c3cccc4c3oc3c(-c5cccc6ccccc56)cc5ccccc5c34)cc2)cc1 ; c1ccc(-c2cc3ccccc3c3c2oc2c(N(c4ccc(-c5cccc6ccccc56)cc4)c4ccc(-c5cccc6ccccc56)cc4)cccc23)cc1 ; c1ccc(-c2ccc(N(c3ccccc3)c3cccc4c3oc3c(-c5ccc6ccccc6c5)cc5ccccc5c34)cc2)cc1]

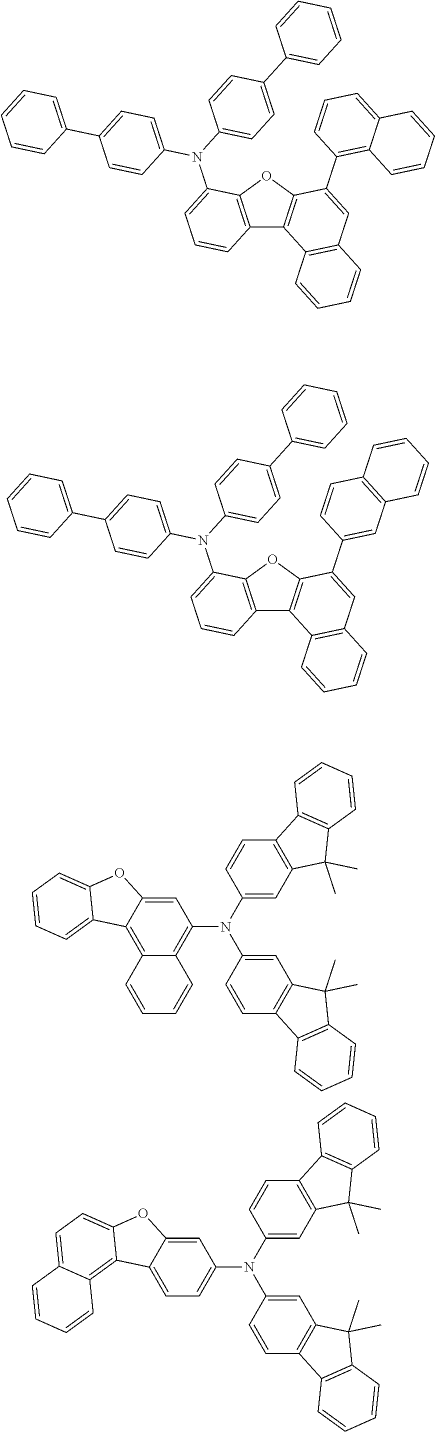

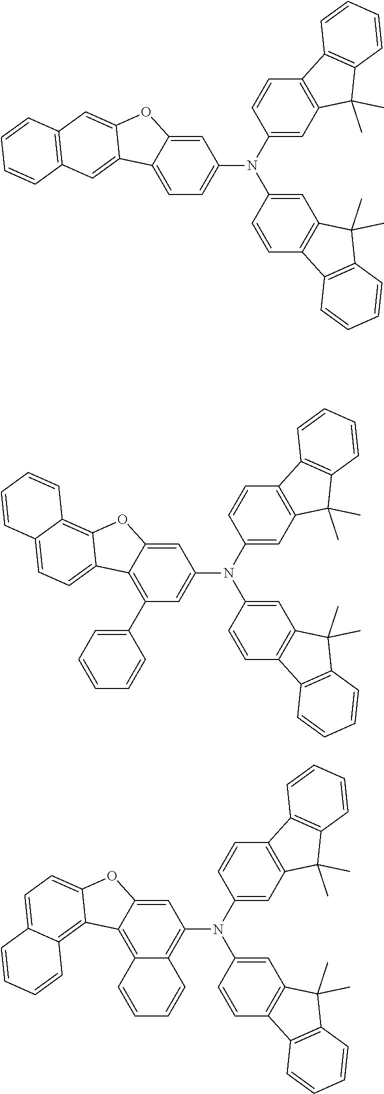

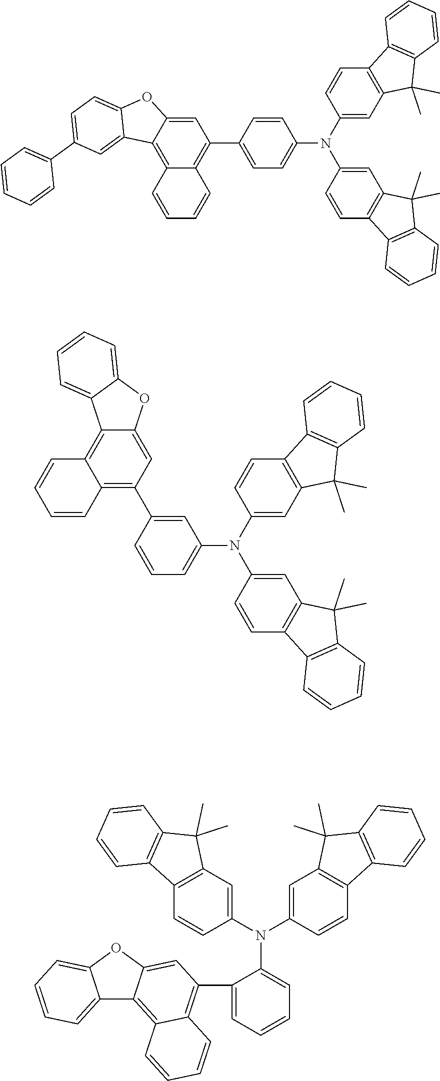 [SMILES: CC1(C)c2ccccc2-c2ccc(N(c3ccc(-c4cc5oc6ccc(-c7ccccc7)cc6c5c5ccccc45)cc3)c3ccc4c(c3)C(C)(C)c3ccccc3-4)cc21 ; CC1(C)c2ccccc2-c2ccc(N(c3cccc(-c4cc5oc6ccccc6c5c5ccccc45)c3)c3ccc4c(c3)C(C)(C)c3ccccc3-4)cc21 ; CC1(C)c2ccccc2-c2ccc(N(c3ccc4c(c3)C(C)(C)c3ccccc3-4)c3ccccc3-c3cc4oc5ccccc5c4c4ccccc34)cc21]

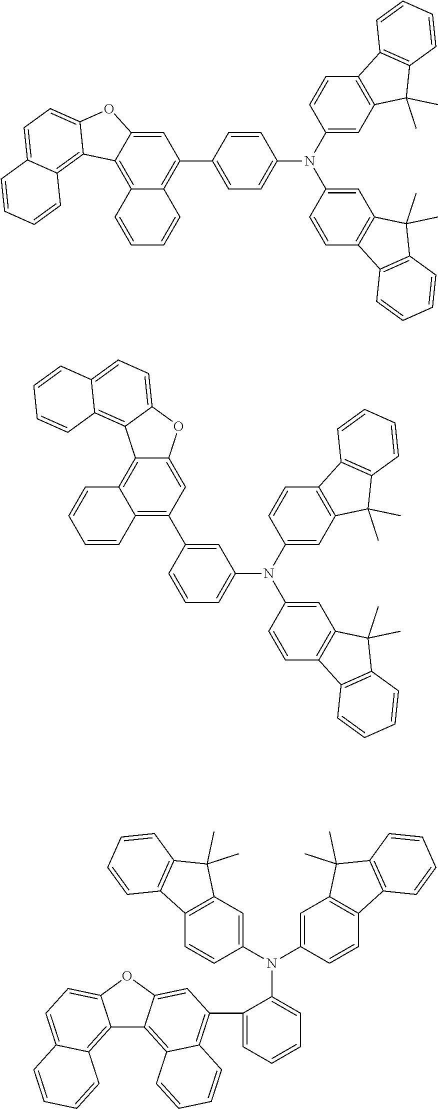 [SMILES: CC1(C)c2ccccc2-c2ccc(N(c3ccc(-c4cc5oc6ccc7ccccc7c6c5c5ccccc45)cc3)c3ccc4c(c3)C(C)(C)c3ccccc3-4)cc21 ; CC1(C)c2ccccc2-c2ccc(N(c3cccc(-c4cc5oc6ccc7ccccc7c6c5c5ccccc45)c3)c3ccc4c(c3)C(C)(C)c3ccccc3-4)cc21 ; CC1(C)c2ccccc2-c2ccc(N(c3ccc4c(c3)C(C)(C)c3ccccc3-4)c3ccccc3-c3cc4oc5ccc6ccccc6c5c4c4ccccc34)cc21]

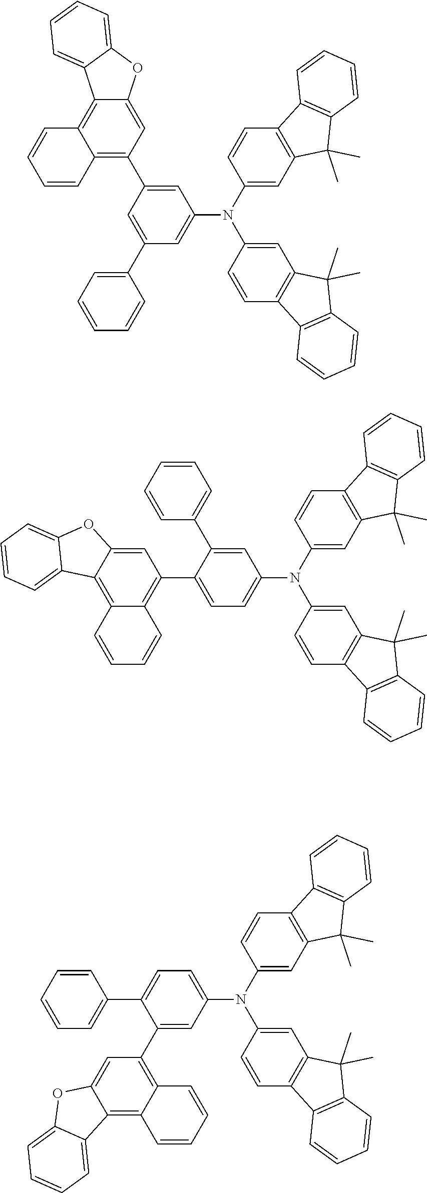 [SMILES: CC1(C)c2ccccc2-c2ccc(N(c3cc(-c4ccccc4)cc(-c4cc5oc6ccccc6c5c5ccccc45)c3)c3ccc4c(c3)C(C)(C)c3ccccc3-4)cc21 ; CC1(C)c2ccccc2-c2ccc(N(c3ccc(-c4cc5oc6ccccc6c5c5ccccc45)c(-c4ccccc4)c3)c3ccc4c(c3)C(C)(C)c3ccccc3-4)cc21 ; CC1(C)c2ccccc2-c2ccc(N(c3ccc(-c4ccccc4)c(-c4cc5oc6ccccc6c5c5ccccc45)c3)c3ccc4c(c3)C(C)(C)c3ccccc3-4)cc21]

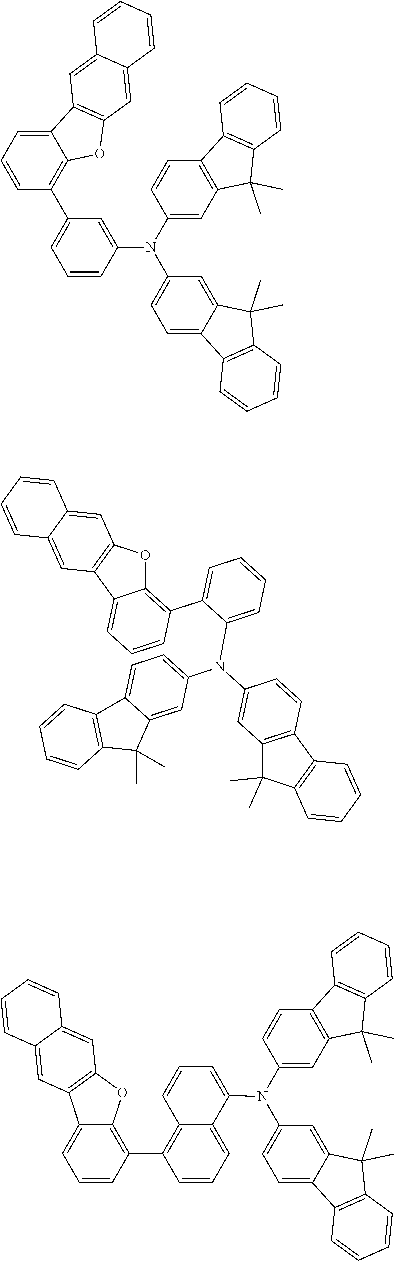 [SMILES: CC1(C)c2ccccc2-c2ccc(N(c3cccc(-c4cccc5c4oc4cc6ccccc6cc45)c3)c3ccc4c(c3)C(C)(C)c3ccccc3-4)cc21 ; CC1(C)c2ccccc2-c2ccc(N(c3ccc4c(c3)C(C)(C)c3ccccc3-4)c3ccccc3-c3cccc4c3oc3cc5ccccc5cc34)cc21 ; CC1(C)c2ccccc2-c2ccc(N(c3ccc4c(c3)C(C)(C)c3ccccc3-4)c3cccc4c(-c5cccc6c5oc5cc7ccccc7cc56)cccc34)cc21]

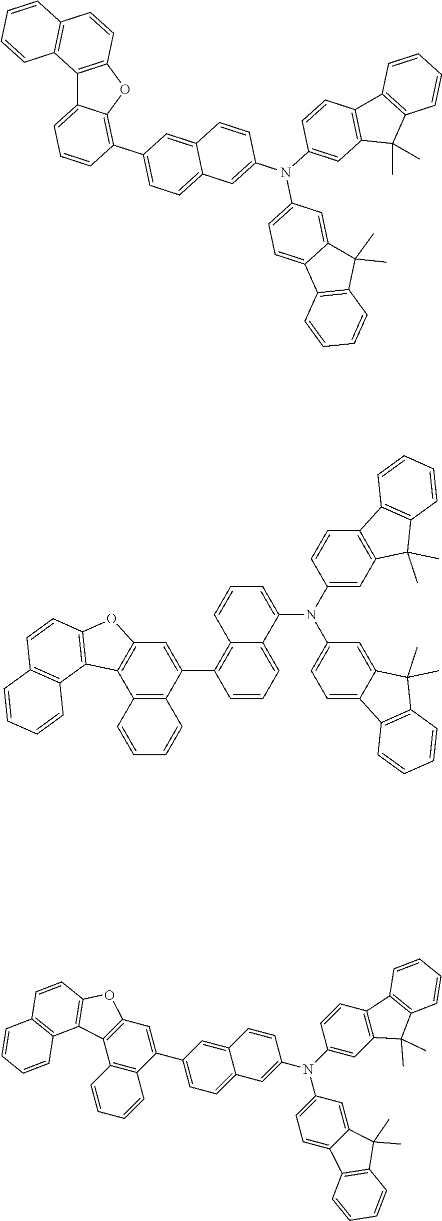 [SMILES: CC1(C)c2ccccc2-c2ccc(N(c3ccc4c(c3)C(C)(C)c3ccccc3-4)c3ccc4cc(-c5cccc6c5oc5ccc7ccccc7c56)ccc4c3)cc21 ; CC1(C)c2ccccc2-c2ccc(N(c3ccc4c(c3)C(C)(C)c3ccccc3-4)c3cccc4c(-c5cc6oc7ccc8ccccc8c7c6c6ccccc56)cccc34)cc21 ; CC1(C)c2ccccc2-c2ccc(N(c3ccc4c(c3)C(C)(C)c3ccccc3-4)c3ccc4cc(-c5cc6oc7ccc8ccccc8c7c6c6ccccc56)ccc4c3)cc21]

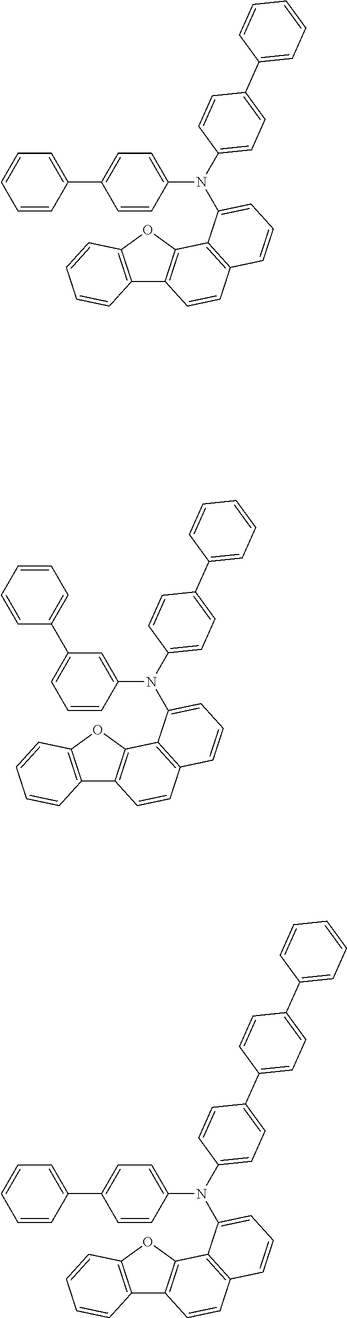 [SMILES: c1ccc(-c2ccc(N(c3ccc(-c4ccccc4)cc3)c3cccc4ccc5c6ccccc6oc5c34)cc2)cc1 ; c1ccc(-c2ccc(N(c3cccc(-c4ccccc4)c3)c3cccc4ccc5c6ccccc6oc5c34)cc2)cc1 ; c1ccc(-c2ccc(-c3ccc(N(c4ccc(-c5ccccc5)cc4)c4cccc5ccc6c7ccccc7oc6c45)cc3)cc2)cc1]

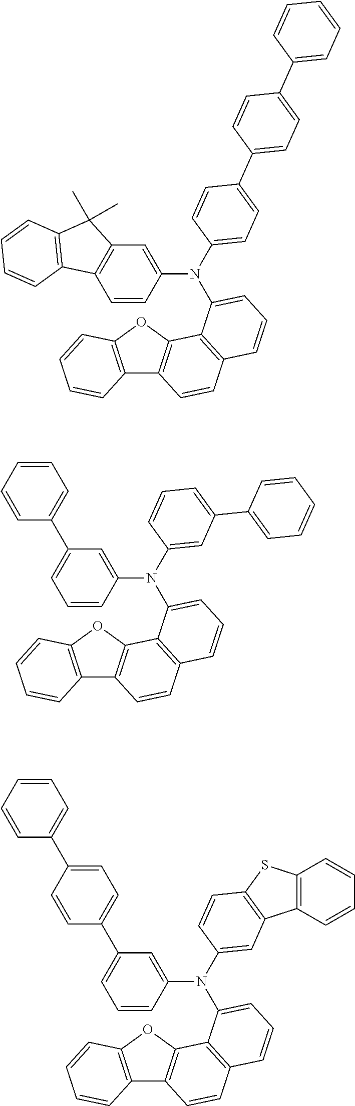 [SMILES: CC1(C)c2ccccc2-c2ccc(N(c3ccc(-c4ccc(-c5ccccc5)cc4)cc3)c3cccc4ccc5c6ccccc6oc5c34)cc21 ; c1ccc(-c2cccc(N(c3cccc(-c4ccccc4)c3)c3cccc4ccc5c6ccccc6oc5c34)c2)cc1 ; c1ccc(-c2ccc(-c3cccc(N(c4ccc5sc6ccccc6c5c4)c4cccc5ccc6c7ccccc7oc6c45)c3)cc2)cc1]

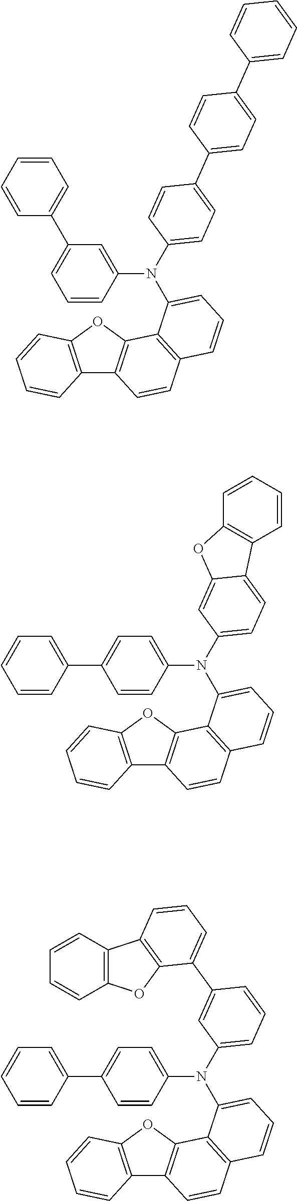 [SMILES: c1ccc(-c2ccc(-c3ccc(N(c4cccc(-c5ccccc5)c4)c4cccc5ccc6c7ccccc7oc6c45)cc3)cc2)cc1 ; c1ccc(-c2ccc(N(c3ccc4c(c3)oc3ccccc34)c3cccc4ccc5c6ccccc6oc5c34)cc2)cc1 ; c1ccc(-c2ccc(N(c3cccc(-c4cccc5c4oc4ccccc45)c3)c3cccc4ccc5c6ccccc6oc5c34)cc2)cc1]

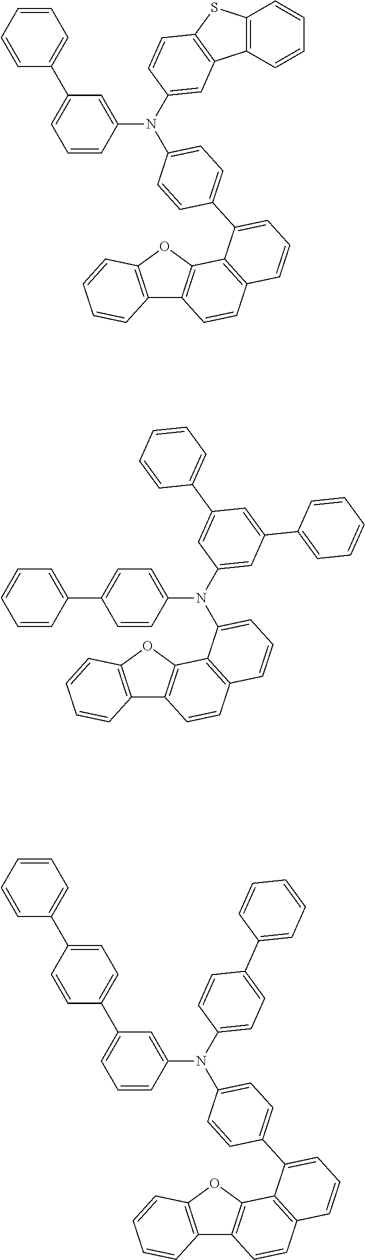 [SMILES: c1ccc(-c2cccc(N(c3ccc(-c4cccc5ccc6c7ccccc7oc6c45)cc3)c3ccc4sc5ccccc5c4c3)c2)cc1 ; c1ccc(-c2ccc(N(c3cc(-c4ccccc4)cc(-c4ccccc4)c3)c3cccc4ccc5c6ccccc6oc5c34)cc2)cc1 ; c1ccc(-c2ccc(-c3cccc(N(c4ccc(-c5ccccc5)cc4)c4ccc(-c5cccc6ccc7c8ccccc8oc7c56)cc4)c3)cc2)cc1]

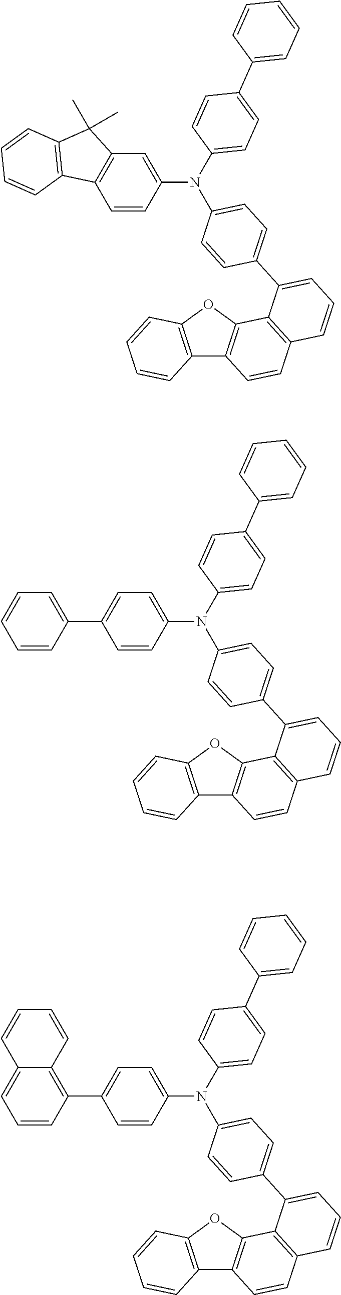 [SMILES: CC1(C)c2ccccc2-c2ccc(N(c3ccc(-c4ccccc4)cc3)c3ccc(-c4cccc5ccc6c7ccccc7oc6c45)cc3)cc21 ; c1ccc(-c2ccc(N(c3ccc(-c4ccccc4)cc3)c3ccc(-c4cccc5ccc6c7ccccc7oc6c45)cc3)cc2)cc1 ; c1ccc(-c2ccc(N(c3ccc(-c4cccc5ccccc45)cc3)c3ccc(-c4cccc5ccc6c7ccccc7oc6c45)cc3)cc2)cc1]

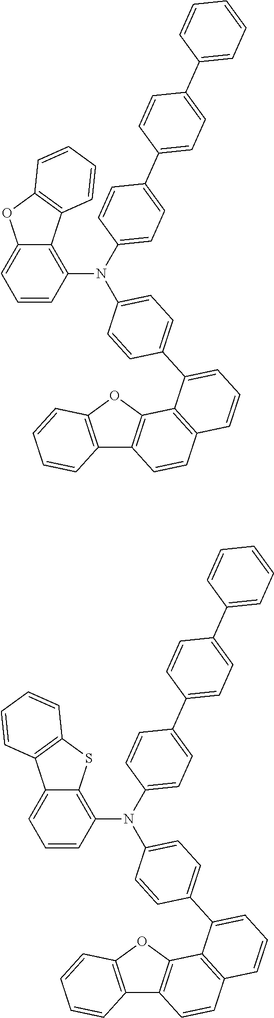 [SMILES: c1ccc(-c2ccc(-c3ccc(N(c4ccc(-c5cccc6ccc7c8ccccc8oc7c56)cc4)c4cccc5oc6ccccc6c45)cc3)cc2)cc1 ; c1ccc(-c2ccc(-c3ccc(N(c4ccc(-c5cccc6ccc7c8ccccc8oc7c56)cc4)c4cccc5c4sc4ccccc45)cc3)cc2)cc1]

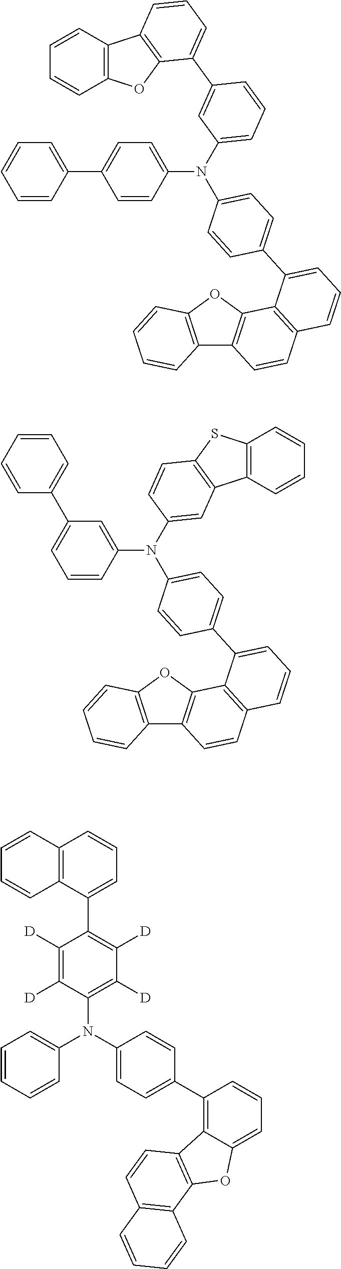 [SMILES: c1ccc(-c2ccc(N(c3ccc(-c4cccc5ccc6c7ccccc7oc6c45)cc3)c3cccc(-c4cccc5c4oc4ccccc45)c3)cc2)cc1 ; c1ccc(-c2cccc(N(c3ccc(-c4cccc5ccc6c7ccccc7oc6c45)cc3)c3ccc4sc5ccccc5c4c3)c2)cc1 ; [2H]c1c([2H])c(N(c2ccccc2)c2ccc(-c3cccc4oc5c6ccccc6ccc5c34)cc2)c([2H])c([2H])c1-c1cccc2ccccc12]

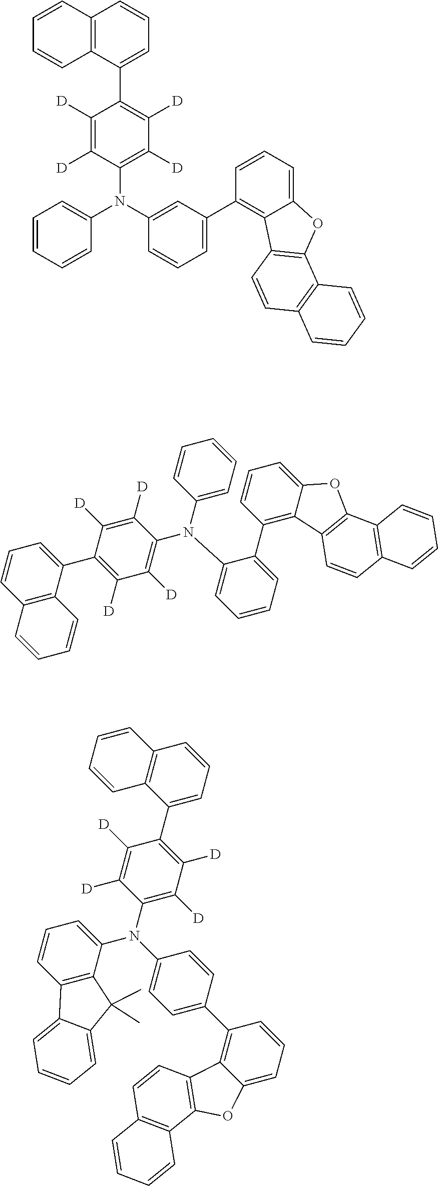 [SMILES: [2H]c1c([2H])c(N(c2ccccc2)c2cccc(-c3cccc4oc5c6ccccc6ccc5c34)c2)c([2H])c([2H])c1-c1cccc2ccccc12 ; [2H]c1c([2H])c(N(c2ccccc2)c2ccccc2-c2cccc3oc4c5ccccc5ccc4c23)c([2H])c([2H])c1-c1cccc2ccccc12 ; [2H]c1c([2H])c(N(c2ccc(-c3cccc4oc5c6ccccc6ccc5c34)cc2)c2cccc3c2C(C)(C)c2ccccc2-3)c([2H])c([2H])c1-c1cccc2ccccc12]

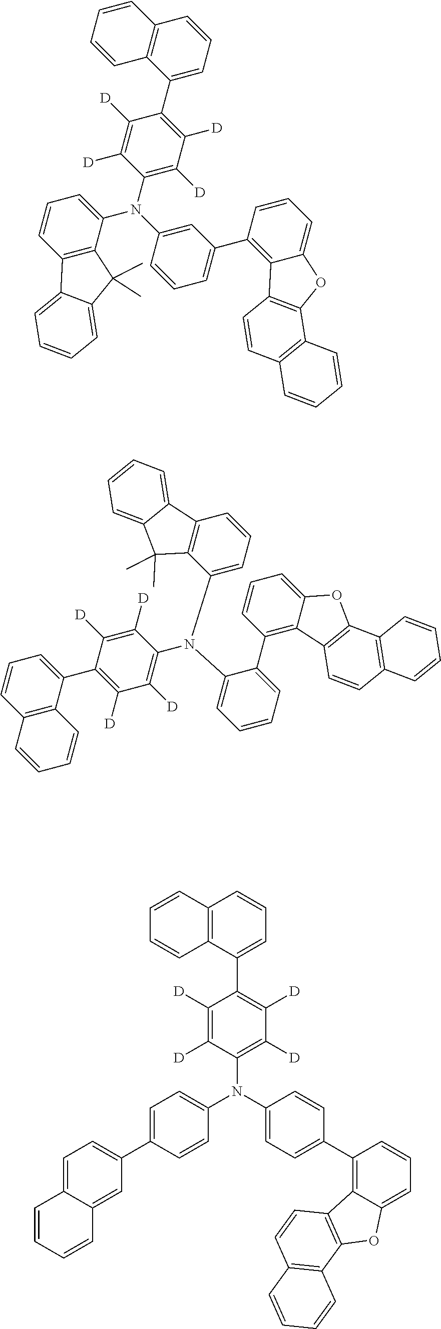 [SMILES: [2H]c1c([2H])c(N(c2cccc(-c3cccc4oc5c6ccccc6ccc5c34)c2)c2cccc3c2C(C)(C)c2ccccc2-3)c([2H])c([2H])c1-c1cccc2ccccc12 ; [2H]c1c([2H])c(N(c2ccccc2-c2cccc3oc4c5ccccc5ccc4c23)c2cccc3c2C(C)(C)c2ccccc2-3)c([2H])c([2H])c1-c1cccc2ccccc12 ; [2H]c1c([2H])c(N(c2ccc(-c3ccc4ccccc4c3)cc2)c2ccc(-c3cccc4oc5c6ccccc6ccc5c34)cc2)c([2H])c([2H])c1-c1cccc2ccccc12]

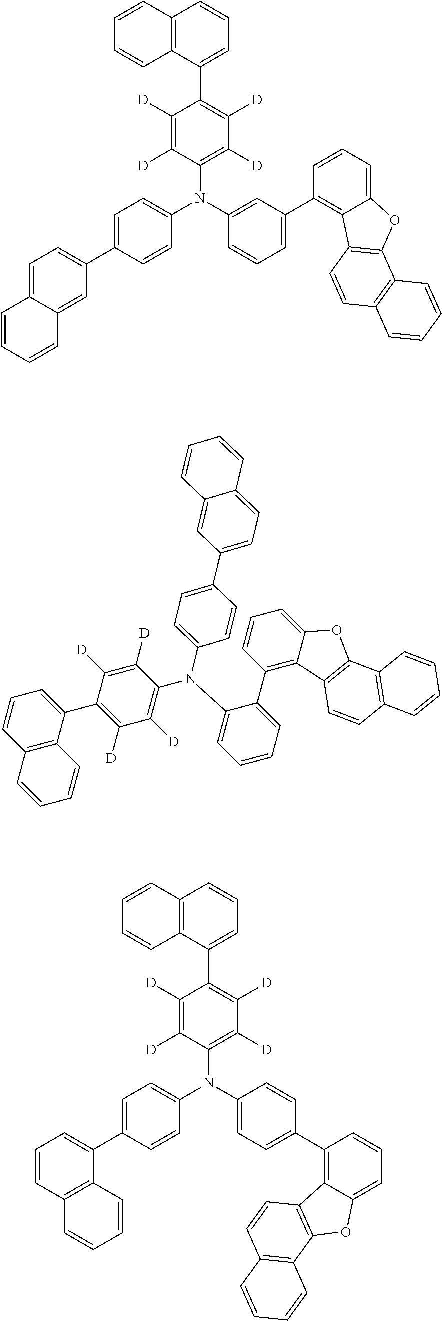 [SMILES: [2H]c1c([2H])c(N(c2ccc(-c3ccc4ccccc4c3)cc2)c2cccc(-c3cccc4oc5c6ccccc6ccc5c34)c2)c([2H])c([2H])c1-c1cccc2ccccc12 ; [2H]c1c([2H])c(N(c2ccc(-c3ccc4ccccc4c3)cc2)c2ccccc2-c2cccc3oc4c5ccccc5ccc4c23)c([2H])c([2H])c1-c1cccc2ccccc12 ; [2H]c1c([2H])c(N(c2ccc(-c3cccc4ccccc34)cc2)c2ccc(-c3cccc4oc5c6ccccc6ccc5c34)cc2)c([2H])c([2H])c1-c1cccc2ccccc12]

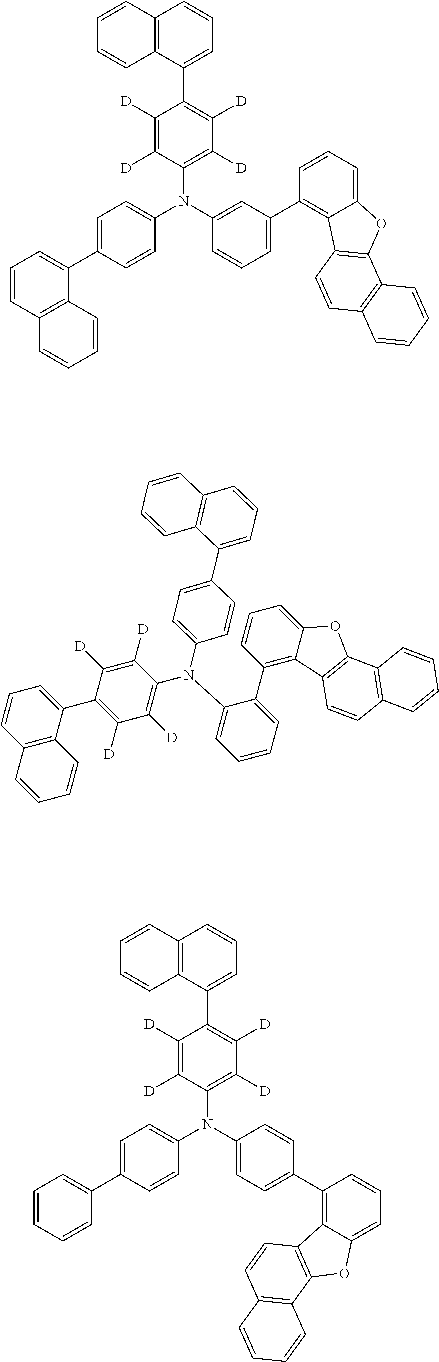 [SMILES: [2H]c1c([2H])c(N(c2ccc(-c3cccc4ccccc34)cc2)c2cccc(-c3cccc4oc5c6ccccc6ccc5c34)c2)c([2H])c([2H])c1-c1cccc2ccccc12 ; [2H]c1c([2H])c(N(c2ccc(-c3cccc4ccccc34)cc2)c2ccccc2-c2cccc3oc4c5ccccc5ccc4c23)c([2H])c([2H])c1-c1cccc2ccccc12 ; [2H]c1c([2H])c(N(c2ccc(-c3ccccc3)cc2)c2ccc(-c3cccc4oc5c6ccccc6ccc5c34)cc2)c([2H])c([2H])c1-c1cccc2ccccc12]

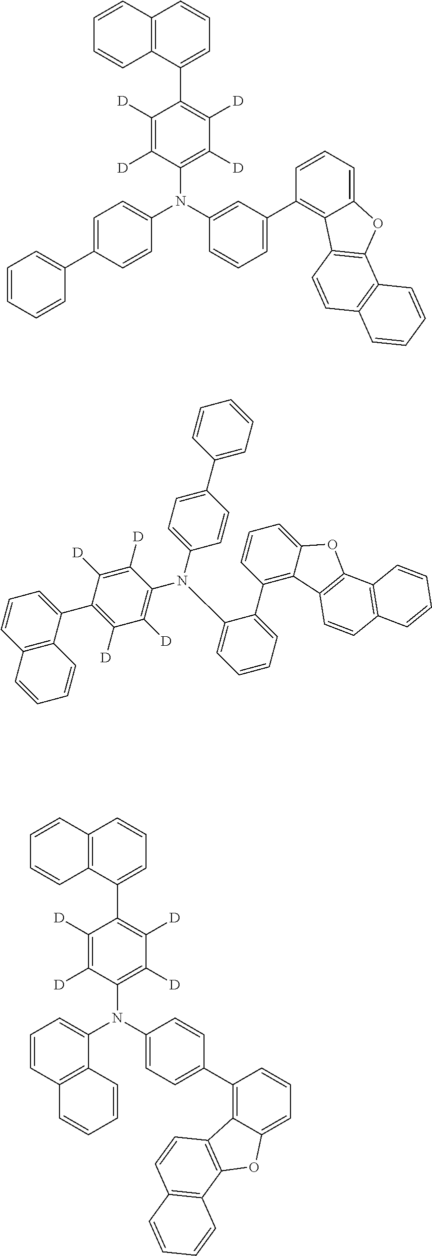 [SMILES: [2H]c1c([2H])c(N(c2ccc(-c3ccccc3)cc2)c2cccc(-c3cccc4oc5c6ccccc6ccc5c34)c2)c([2H])c([2H])c1-c1cccc2ccccc12 ; [2H]c1c([2H])c(N(c2ccc(-c3ccccc3)cc2)c2ccccc2-c2cccc3oc4c5ccccc5ccc4c23)c([2H])c([2H])c1-c1cccc2ccccc12 ; [2H]c1c([2H])c(N(c2ccc(-c3cccc4oc5c6ccccc6ccc5c34)cc2)c2cccc3ccccc23)c([2H])c([2H])c1-c1cccc2ccccc12]

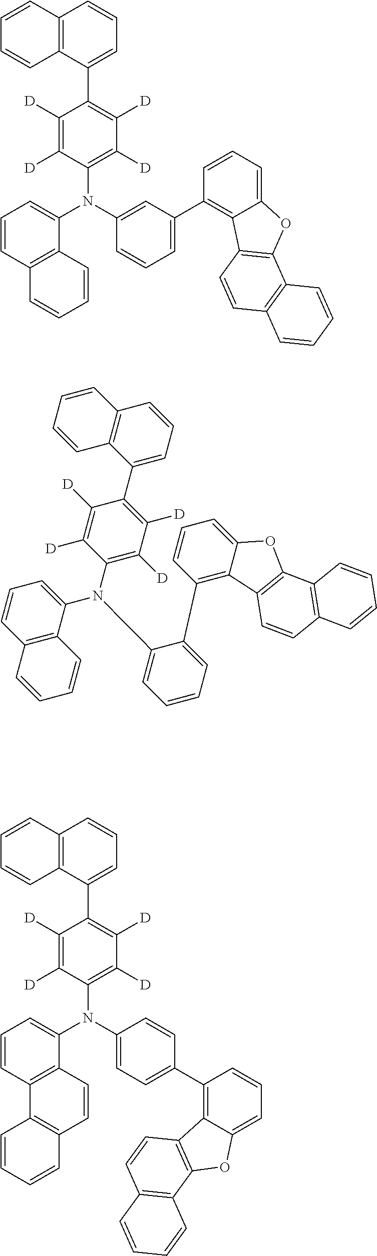 [SMILES: [2H]c1c([2H])c(N(c2cccc(-c3cccc4oc5c6ccccc6ccc5c34)c2)c2cccc3ccccc23)c([2H])c([2H])c1-c1cccc2ccccc12 ; [2H]c1c([2H])c(N(c2ccccc2-c2cccc3oc4c5ccccc5ccc4c23)c2cccc3ccccc23)c([2H])c([2H])c1-c1cccc2ccccc12 ; [2H]c1c([2H])c(N(c2ccc(-c3cccc4oc5c6ccccc6ccc5c34)cc2)c2cccc3c2ccc2ccccc23)c([2H])c([2H])c1-c1cccc2ccccc12]

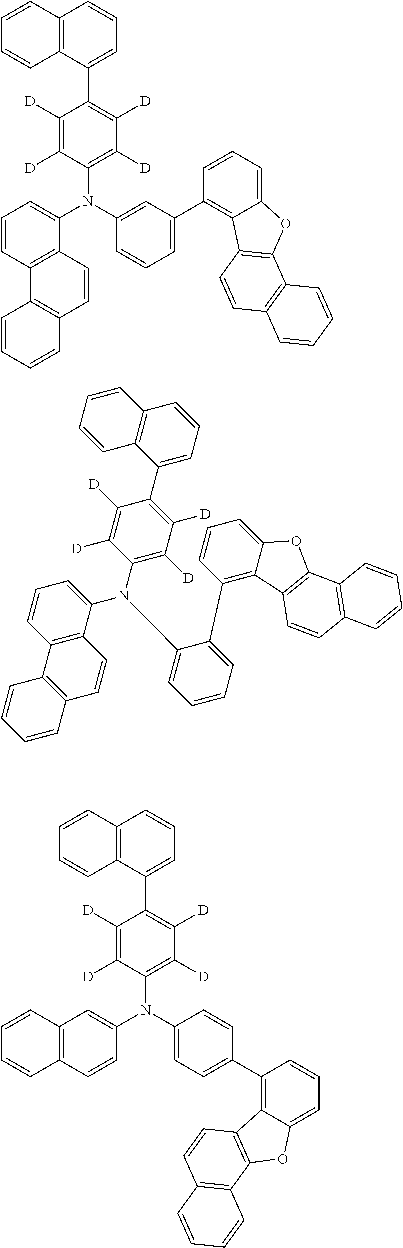 [SMILES: [2H]c1c([2H])c(N(c2cccc(-c3cccc4oc5c6ccccc6ccc5c34)c2)c2cccc3c2ccc2ccccc23)c([2H])c([2H])c1-c1cccc2ccccc12 ; [2H]c1c([2H])c(N(c2ccccc2-c2cccc3oc4c5ccccc5ccc4c23)c2cccc3c2ccc2ccccc23)c([2H])c([2H])c1-c1cccc2ccccc12 ; [2H]c1c([2H])c(N(c2ccc(-c3cccc4oc5c6ccccc6ccc5c34)cc2)c2ccc3ccccc3c2)c([2H])c([2H])c1-c1cccc2ccccc12]

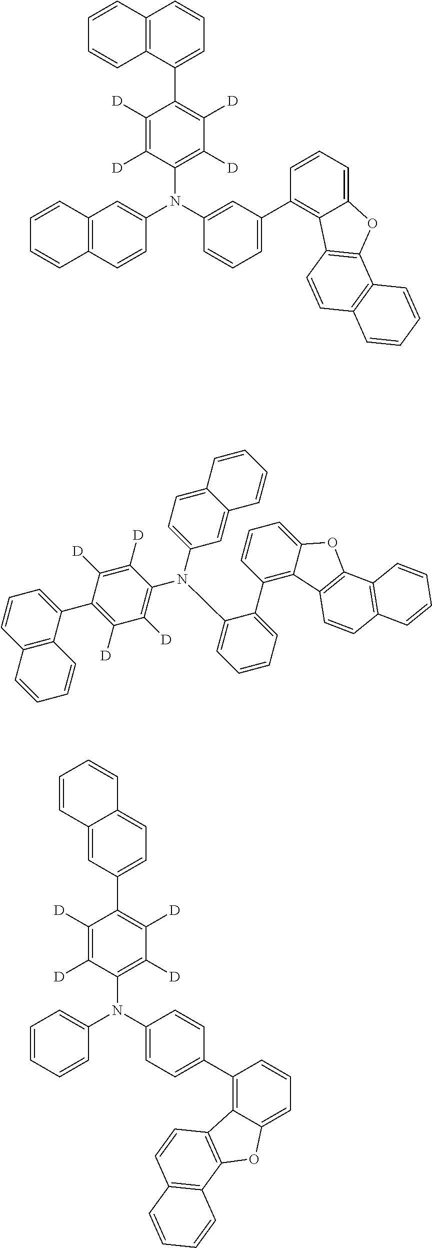 [SMILES: [2H]c1c([2H])c(N(c2cccc(-c3cccc4oc5c6ccccc6ccc5c34)c2)c2ccc3ccccc3c2)c([2H])c([2H])c1-c1cccc2ccccc12 ; [2H]c1c([2H])c(N(c2ccc3ccccc3c2)c2ccccc2-c2cccc3oc4c5ccccc5ccc4c23)c([2H])c([2H])c1-c1cccc2ccccc12 ; [2H]c1c([2H])c(N(c2ccccc2)c2ccc(-c3cccc4oc5c6ccccc6ccc5c34)cc2)c([2H])c([2H])c1-c1ccc2ccccc2c1]

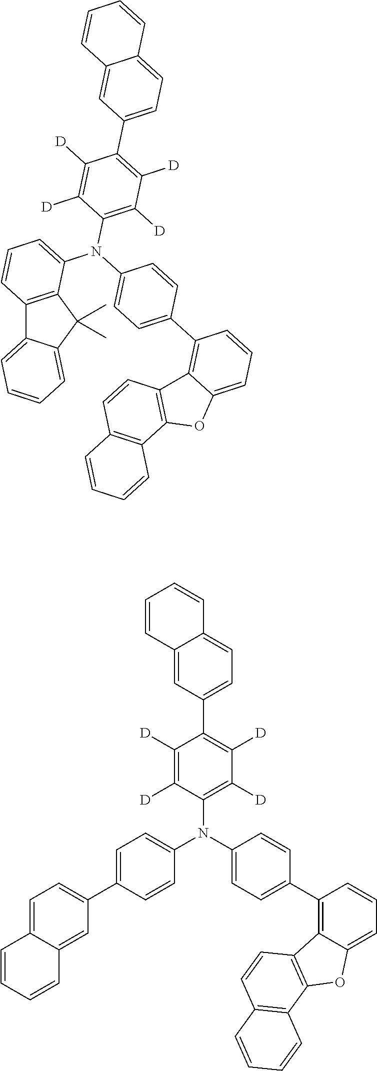 [SMILES: [2H]c1c([2H])c(N(c2ccc(-c3cccc4oc5c6ccccc6ccc5c34)cc2)c2cccc3c2C(C)(C)c2ccccc2-3)c([2H])c([2H])c1-c1ccc2ccccc2c1 ; [2H]c1c([2H])c(N(c2ccc(-c3ccc4ccccc4c3)cc2)c2ccc(-c3cccc4oc5c6ccccc6ccc5c34)cc2)c([2H])c([2H])c1-c1ccc2ccccc2c1]

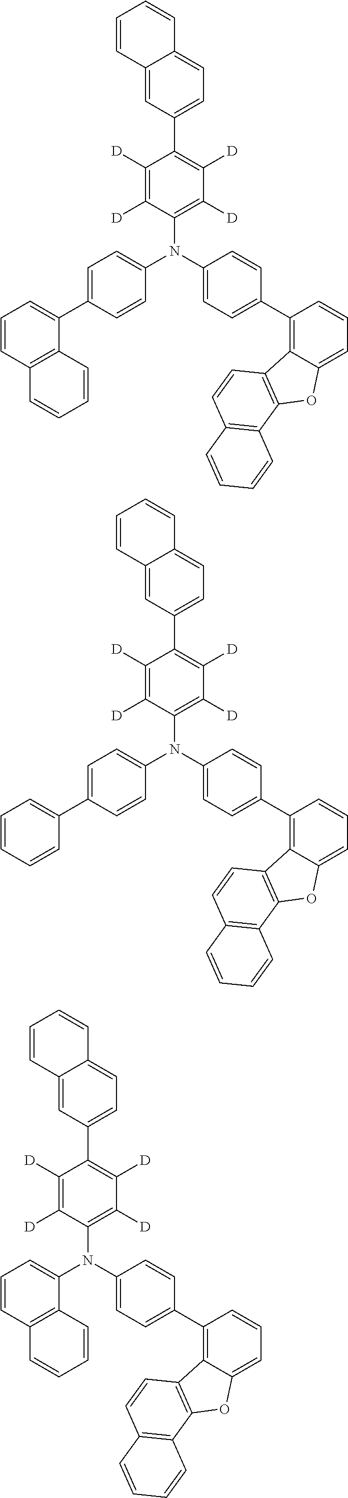 [SMILES: [2H]c1c([2H])c(N(c2ccc(-c3cccc4ccccc34)cc2)c2ccc(-c3cccc4oc5c6ccccc6ccc5c34)cc2)c([2H])c([2H])c1-c1ccc2ccccc2c1 ; [2H]c1c([2H])c(N(c2ccc(-c3ccccc3)cc2)c2ccc(-c3cccc4oc5c6ccccc6ccc5c34)cc2)c([2H])c([2H])c1-c1ccc2ccccc2c1 ; [2H]c1c([2H])c(N(c2ccc(-c3cccc4oc5c6ccccc6ccc5c34)cc2)c2cccc3ccccc23)c([2H])c([2H])c1-c1ccc2ccccc2c1]

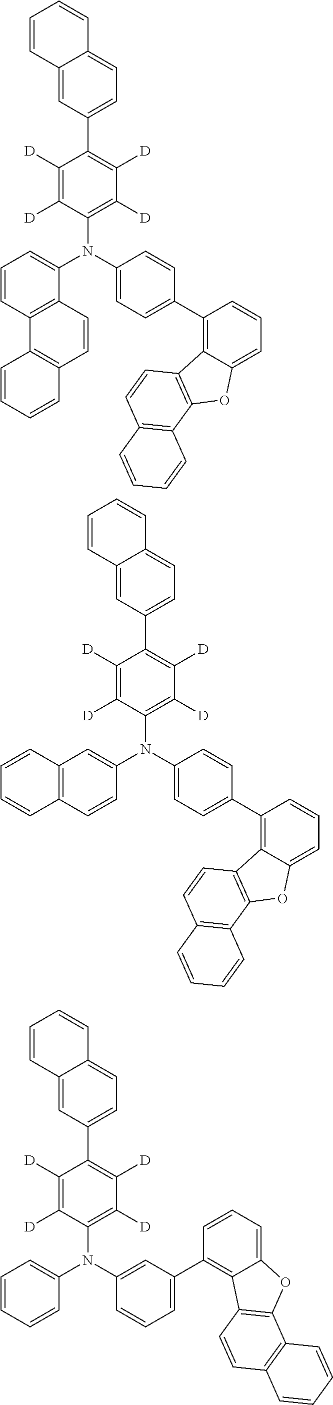

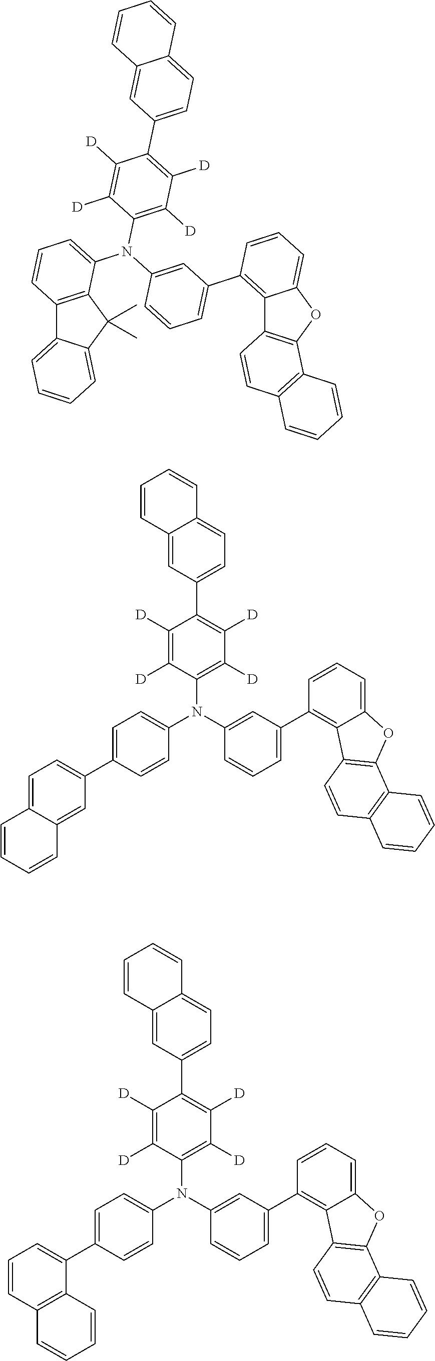 [SMILES: [2H]c1c([2H])c(N(c2cccc(-c3cccc4oc5c6ccccc6ccc5c34)c2)c2cccc3c2C(C)(C)c2ccccc2-3)c([2H])c([2H])c1-c1ccc2ccccc2c1 ; [2H]c1c([2H])c(N(c2ccc(-c3ccc4ccccc4c3)cc2)c2cccc(-c3cccc4oc5c6ccccc6ccc5c34)c2)c([2H])c([2H])c1-c1ccc2ccccc2c1 ; [2H]c1c([2H])c(N(c2ccc(-c3cccc4ccccc34)cc2)c2cccc(-c3cccc4oc5c6ccccc6ccc5c34)c2)c([2H])c([2H])c1-c1ccc2ccccc2c1]

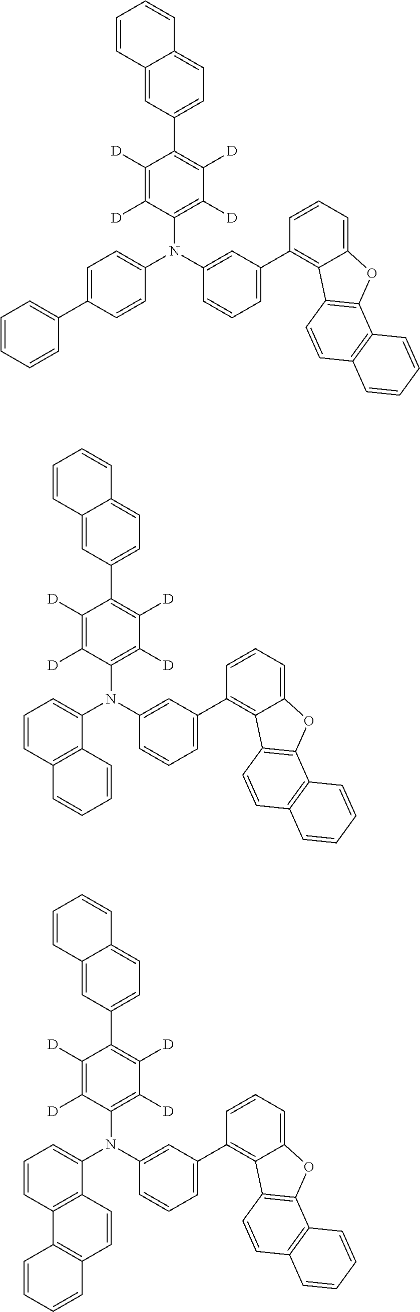 [SMILES: [2H]c1c([2H])c(N(c2ccc(-c3ccccc3)cc2)c2cccc(-c3cccc4oc5c6ccccc6ccc5c34)c2)c([2H])c([2H])c1-c1ccc2ccccc2c1 ; [2H]c1c([2H])c(N(c2cccc(-c3cccc4oc5c6ccccc6ccc5c34)c2)c2cccc3ccccc23)c([2H])c([2H])c1-c1ccc2ccccc2c1 ; [2H]c1c([2H])c(N(c2cccc(-c3cccc4oc5c6ccccc6ccc5c34)c2)c2cccc3c2ccc2ccccc23)c([2H])c([2H])c1-c1ccc2ccccc2c1]

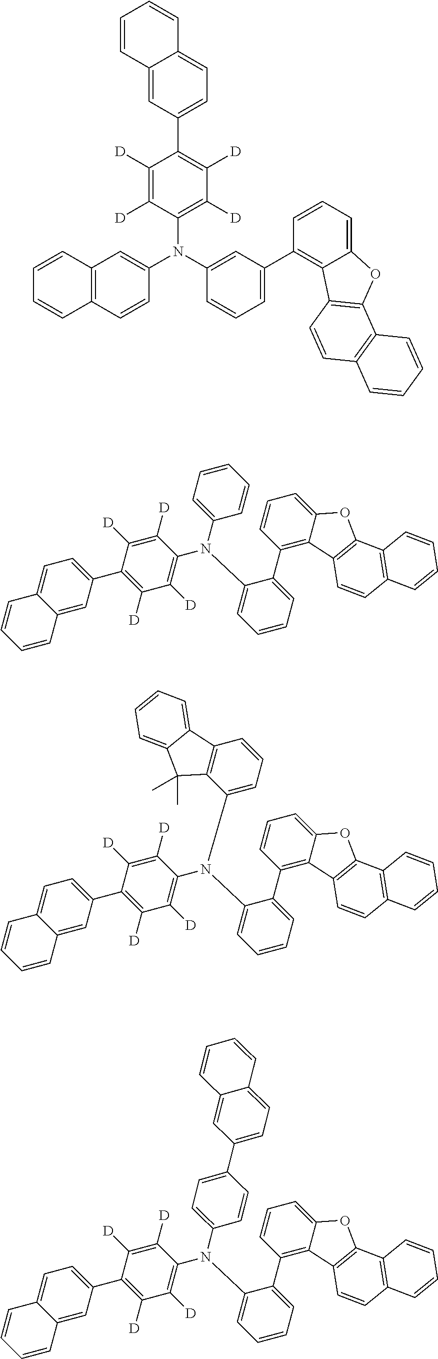 [SMILES: [2H]c1c([2H])c(N(c2cccc(-c3cccc4oc5c6ccccc6ccc5c34)c2)c2ccc3ccccc3c2)c([2H])c([2H])c1-c1ccc2ccccc2c1 ; [2H]c1c([2H])c(N(c2ccccc2)c2ccccc2-c2cccc3oc4c5ccccc5ccc4c23)c([2H])c([2H])c1-c1ccc2ccccc2c1 ; [2H]c1c([2H])c(N(c2ccccc2-c2cccc3oc4c5ccccc5ccc4c23)c2cccc3c2C(C)(C)c2ccccc2-3)c([2H])c([2H])c1-c1ccc2ccccc2c1 ; [2H]c1c([2H])c(N(c2ccc(-c3ccc4ccccc4c3)cc2)c2ccccc2-c2cccc3oc4c5ccccc5ccc4c23)c([2H])c([2H])c1-c1ccc2ccccc2c1]

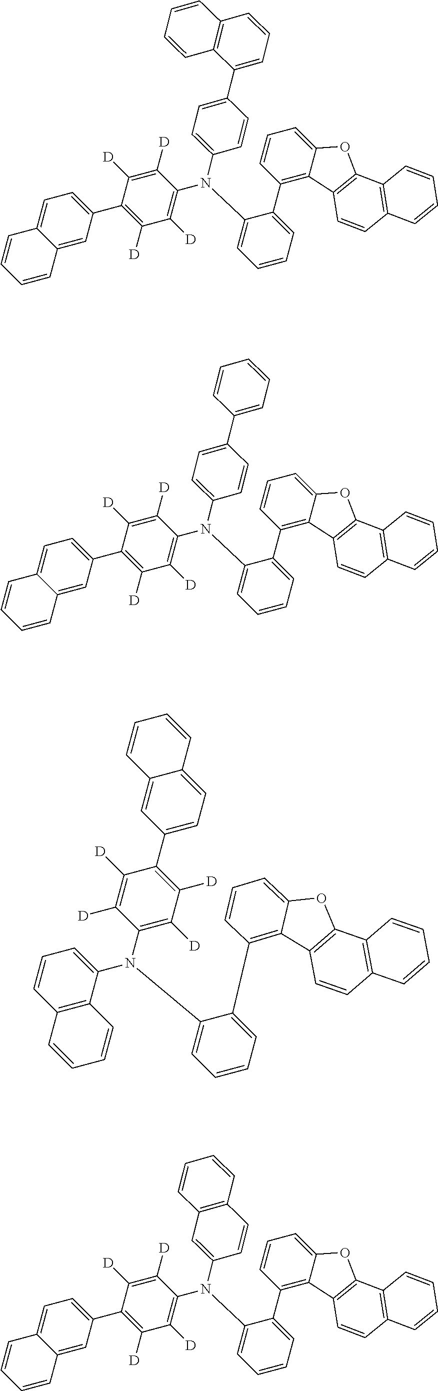 [SMILES: [2H]c1c([2H])c(N(c2ccc(-c3cccc4ccccc34)cc2)c2ccccc2-c2cccc3oc4c5ccccc5ccc4c23)c([2H])c([2H])c1-c1ccc2ccccc2c1 ; [2H]c1c([2H])c(N(c2ccc(-c3ccccc3)cc2)c2ccccc2-c2cccc3oc4c5ccccc5ccc4c23)c([2H])c([2H])c1-c1ccc2ccccc2c1 ; [2H]c1c([2H])c(N(c2ccccc2-c2cccc3oc4c5ccccc5ccc4c23)c2cccc3ccccc23)c([2H])c([2H])c1-c1ccc2ccccc2c1 ; [2H]c1c([2H])c(N(c2ccc3ccccc3c2)c2ccccc2-c2cccc3oc4c5ccccc5ccc4c23)c([2H])c([2H])c1-c1ccc2ccccc2c1]

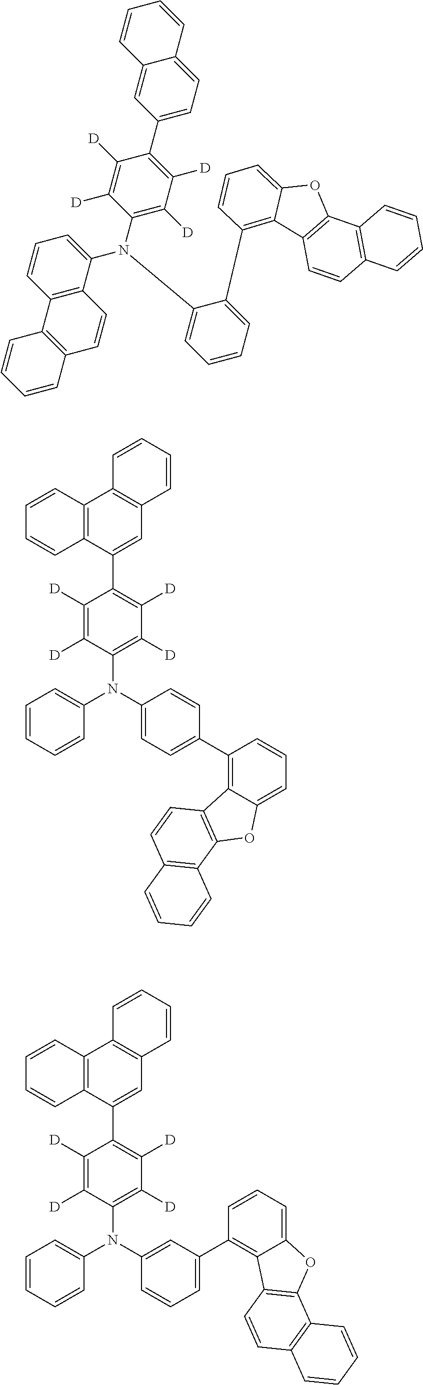 [SMILES: [2H]c1c([2H])c(N(c2ccccc2-c2cccc3oc4c5ccccc5ccc4c23)c2cccc3c2ccc2ccccc23)c([2H])c([2H])c1-c1ccc2ccccc2c1 ; [2H]c1c([2H])c(N(c2ccccc2)c2ccc(-c3cccc4oc5c6ccccc6ccc5c34)cc2)c([2H])c([2H])c1-c1cc2ccccc2c2ccccc12 ; [2H]c1c([2H])c(N(c2ccccc2)c2cccc(-c3cccc4oc5c6ccccc6ccc5c34)c2)c([2H])c([2H])c1-c1cc2ccccc2c2ccccc12]

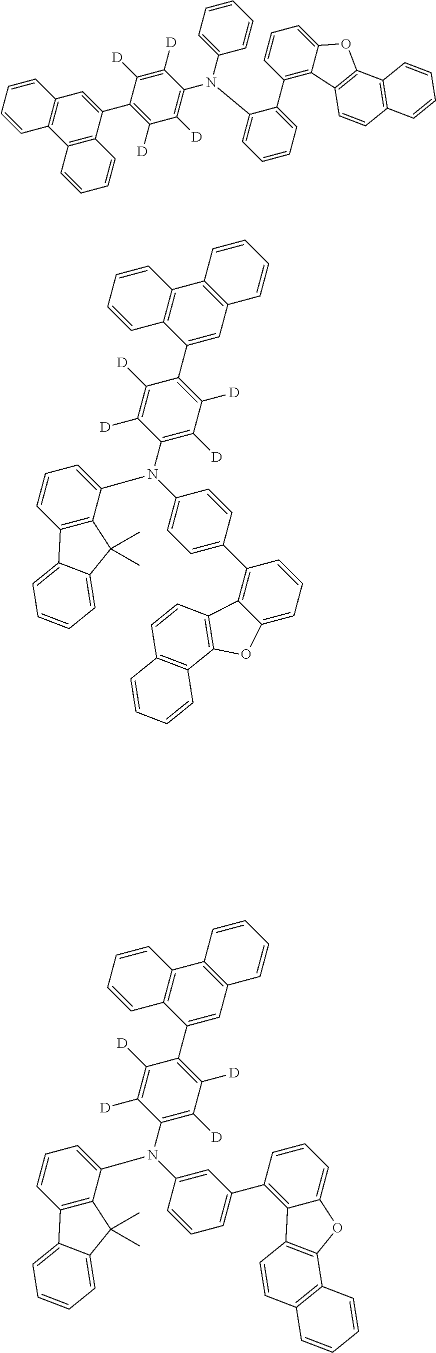 [SMILES: [2H]c1c([2H])c(N(c2ccccc2)c2ccccc2-c2cccc3oc4c5ccccc5ccc4c23)c([2H])c([2H])c1-c1cc2ccccc2c2ccccc12 ; [2H]c1c([2H])c(N(c2ccc(-c3cccc4oc5c6ccccc6ccc5c34)cc2)c2cccc3c2C(C)(C)c2ccccc2-3)c([2H])c([2H])c1-c1cc2ccccc2c2ccccc12 ; [2H]c1c([2H])c(N(c2cccc(-c3cccc4oc5c6ccccc6ccc5c34)c2)c2cccc3c2C(C)(C)c2ccccc2-3)c([2H])c([2H])c1-c1cc2ccccc2c2ccccc12]

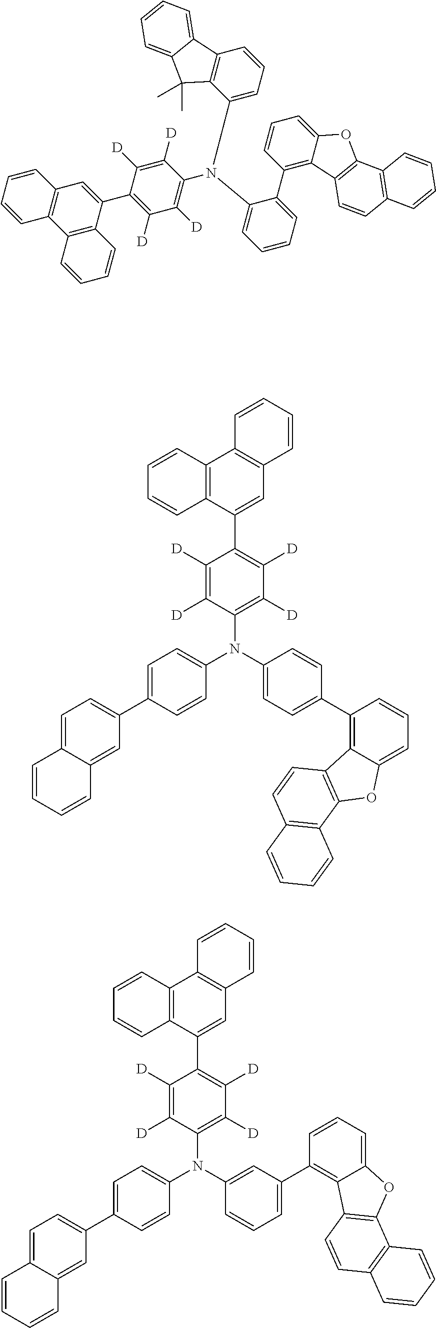 [SMILES: [2H]c1c([2H])c(N(c2ccccc2-c2cccc3oc4c5ccccc5ccc4c23)c2cccc3c2C(C)(C)c2ccccc2-3)c([2H])c([2H])c1-c1cc2ccccc2c2ccccc12 ; [2H]c1c([2H])c(N(c2ccc(-c3ccc4ccccc4c3)cc2)c2ccc(-c3cccc4oc5c6ccccc6ccc5c34)cc2)c([2H])c([2H])c1-c1cc2ccccc2c2ccccc12 ; [2H]c1c([2H])c(N(c2ccc(-c3ccc4ccccc4c3)cc2)c2cccc(-c3cccc4oc5c6ccccc6ccc5c34)c2)c([2H])c([2H])c1-c1cc2ccccc2c2ccccc12]

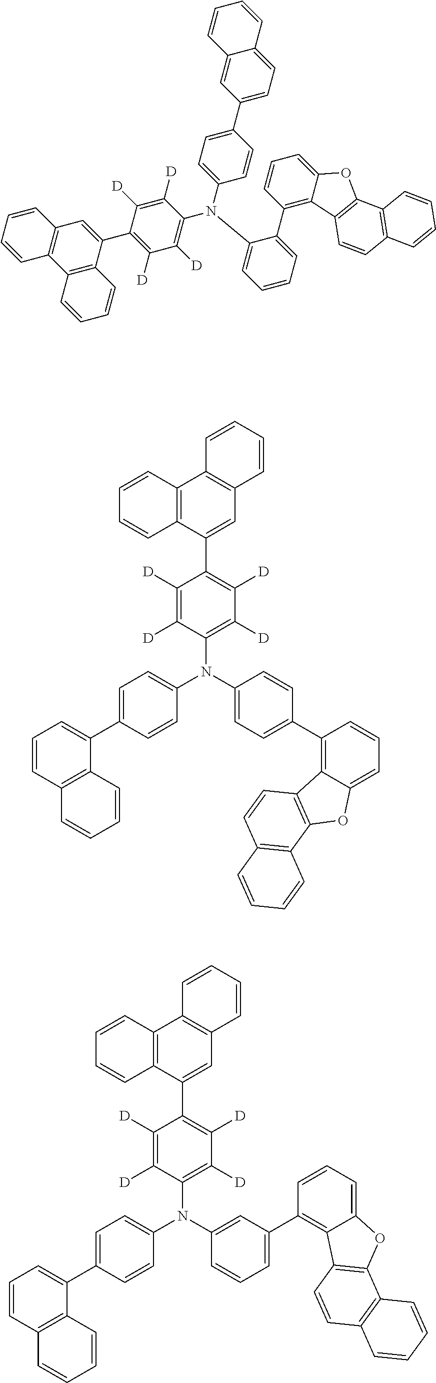 [SMILES: [2H]c1c([2H])c(N(c2ccc(-c3ccc4ccccc4c3)cc2)c2ccccc2-c2cccc3oc4c5ccccc5ccc4c23)c([2H])c([2H])c1-c1cc2ccccc2c2ccccc12 ; [2H]c1c([2H])c(N(c2ccc(-c3cccc4ccccc34)cc2)c2ccc(-c3cccc4oc5c6ccccc6ccc5c34)cc2)c([2H])c([2H])c1-c1cc2ccccc2c2ccccc12 ; [2H]c1c([2H])c(N(c2ccc(-c3cccc4ccccc34)cc2)c2cccc(-c3cccc4oc5c6ccccc6ccc5c34)c2)c([2H])c([2H])c1-c1cc2ccccc2c2ccccc12]

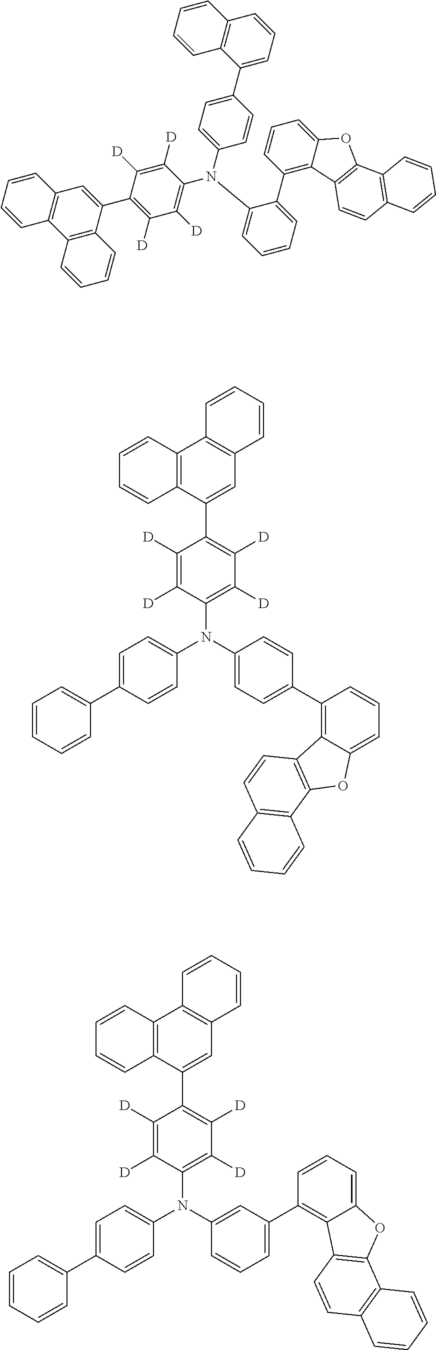 [SMILES: [2H]c1c([2H])c(N(c2ccc(-c3cccc4ccccc34)cc2)c2ccccc2-c2cccc3oc4c5ccccc5ccc4c23)c([2H])c([2H])c1-c1cc2ccccc2c2ccccc12 ; [2H]c1c([2H])c(N(c2ccc(-c3ccccc3)cc2)c2ccc(-c3cccc4oc5c6ccccc6ccc5c34)cc2)c([2H])c([2H])c1-c1cc2ccccc2c2ccccc12 ; [2H]c1c([2H])c(N(c2ccc(-c3ccccc3)cc2)c2cccc(-c3cccc4oc5c6ccccc6ccc5c34)c2)c([2H])c([2H])c1-c1cc2ccccc2c2ccccc12]

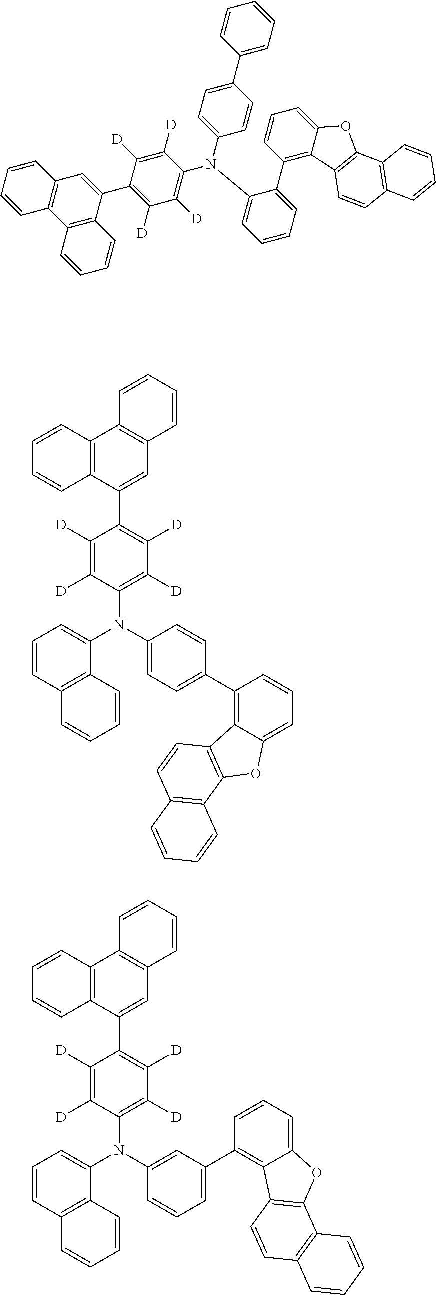

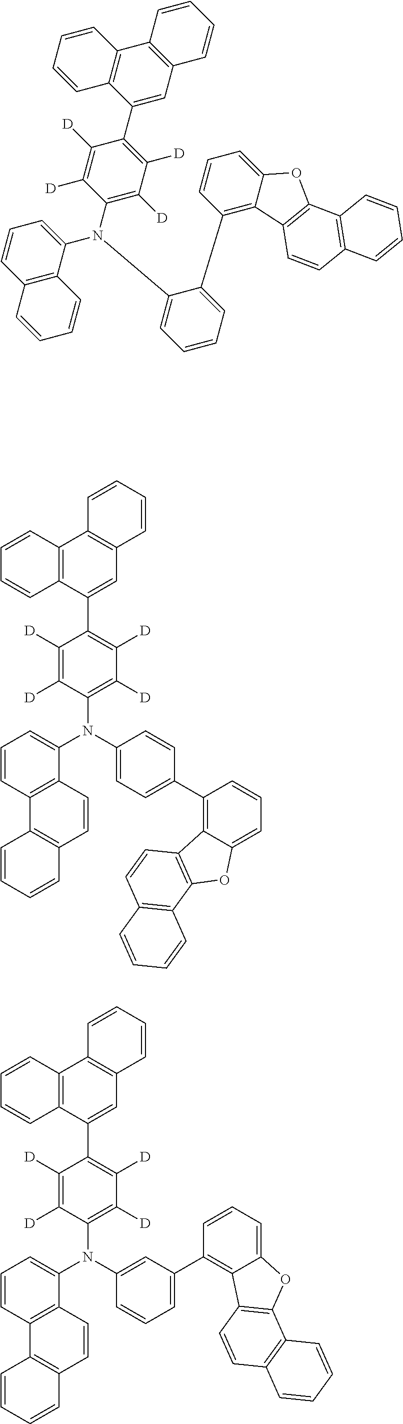

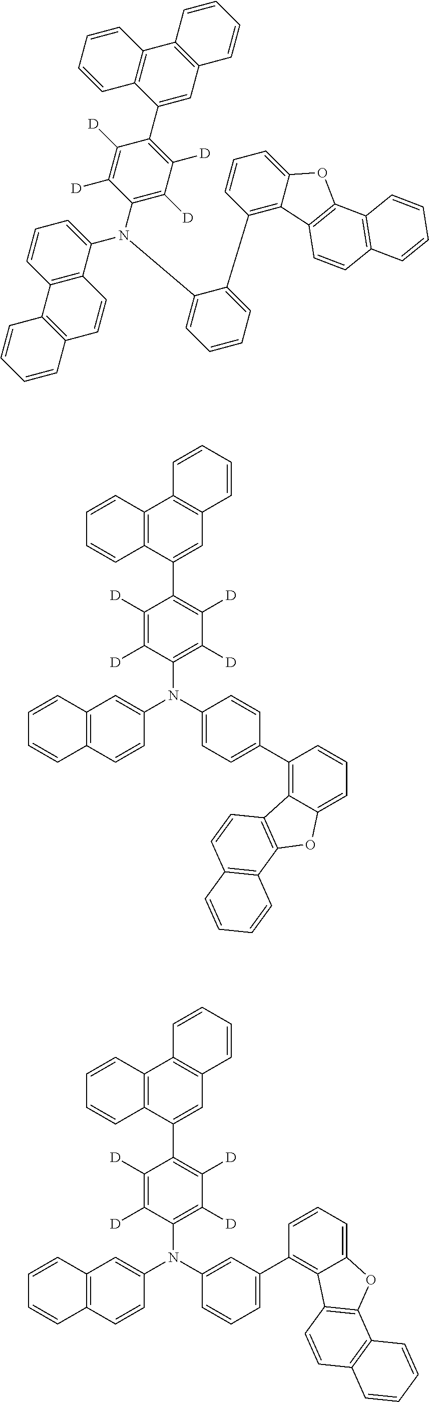 [SMILES: [2H]c1c([2H])c(N(c2ccccc2-c2cccc3oc4c5ccccc5ccc4c23)c2cccc3c2ccc2ccccc23)c([2H])c([2H])c1-c1cc2ccccc2c2ccccc12 ; [2H]c1c([2H])c(N(c2ccc(-c3cccc4oc5c6ccccc6ccc5c34)cc2)c2ccc3ccccc3c2)c([2H])c([2H])c1-c1cc2ccccc2c2ccccc12 ; [2H]c1c([2H])c(N(c2cccc(-c3cccc4oc5c6ccccc6ccc5c34)c2)c2ccc3ccccc3c2)c([2H])c([2H])c1-c1cc2ccccc2c2ccccc12]

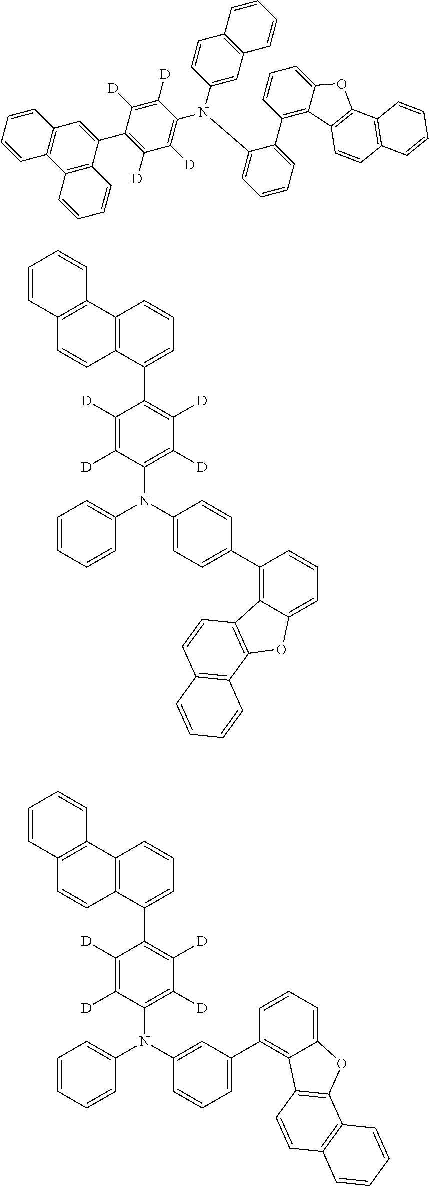

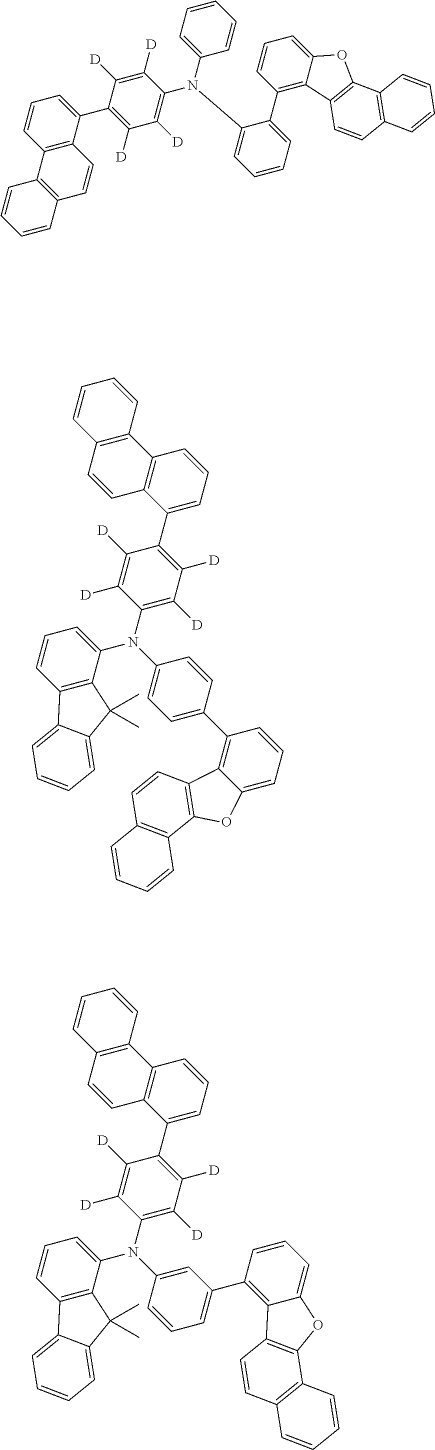 [SMILES: [2H]c1c([2H])c(N(c2ccccc2)c2ccccc2-c2cccc3oc4c5ccccc5ccc4c23)c([2H])c([2H])c1-c1cccc2c1ccc1ccccc12 ; [2H]c1c([2H])c(N(c2ccc(-c3cccc4oc5c6ccccc6ccc5c34)cc2)c2cccc3c2C(C)(C)c2ccccc2-3)c([2H])c([2H])c1-c1cccc2c1ccc1ccccc12 ; [2H]c1c([2H])c(N(c2cccc(-c3cccc4oc5c6ccccc6ccc5c34)c2)c2cccc3c2C(C)(C)c2ccccc2-3)c([2H])c([2H])c1-c1cccc2c1ccc1ccccc12]

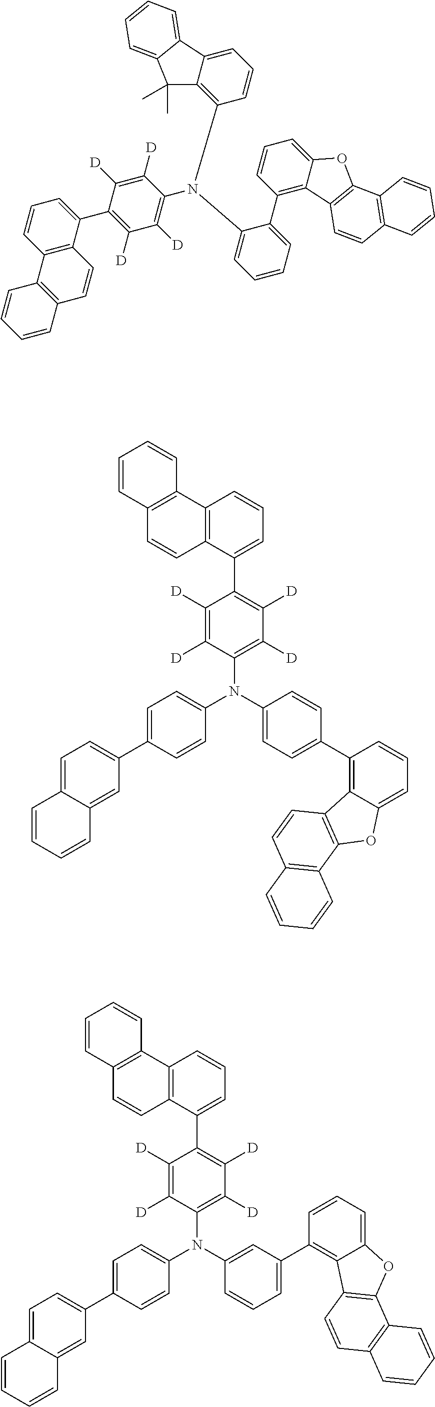 [SMILES: [2H]c1c([2H])c(N(c2ccccc2-c2cccc3oc4c5ccccc5ccc4c23)c2cccc3c2C(C)(C)c2ccccc2-3)c([2H])c([2H])c1-c1cccc2c1ccc1ccccc12 ; [2H]c1c([2H])c(N(c2ccc(-c3ccc4ccccc4c3)cc2)c2ccc(-c3cccc4oc5c6ccccc6ccc5c34)cc2)c([2H])c([2H])c1-c1cccc2c1ccc1ccccc12 ; [2H]c1c([2H])c(N(c2ccc(-c3ccc4ccccc4c3)cc2)c2cccc(-c3cccc4oc5c6ccccc6ccc5c34)c2)c([2H])c([2H])c1-c1cccc2c1ccc1ccccc12]

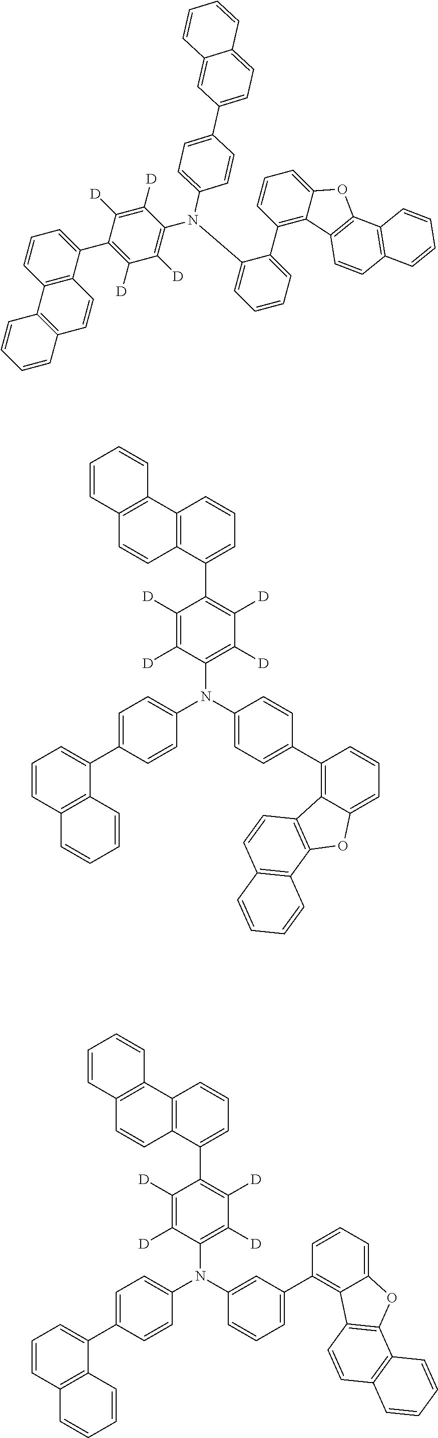 [SMILES: [2H]c1c([2H])c(N(c2ccc(-c3ccc4ccccc4c3)cc2)c2ccccc2-c2cccc3oc4c5ccccc5ccc4c23)c([2H])c([2H])c1-c1cccc2c1ccc1ccccc12 ; [2H]c1c([2H])c(N(c2ccc(-c3cccc4ccccc34)cc2)c2ccc(-c3cccc4oc5c6ccccc6ccc5c34)cc2)c([2H])c([2H])c1-c1cccc2c1ccc1ccccc12 ; [2H]c1c([2H])c(N(c2ccc(-c3cccc4ccccc34)cc2)c2cccc(-c3cccc4oc5c6ccccc6ccc5c34)c2)c([2H])c([2H])c1-c1cccc2c1ccc1ccccc12]

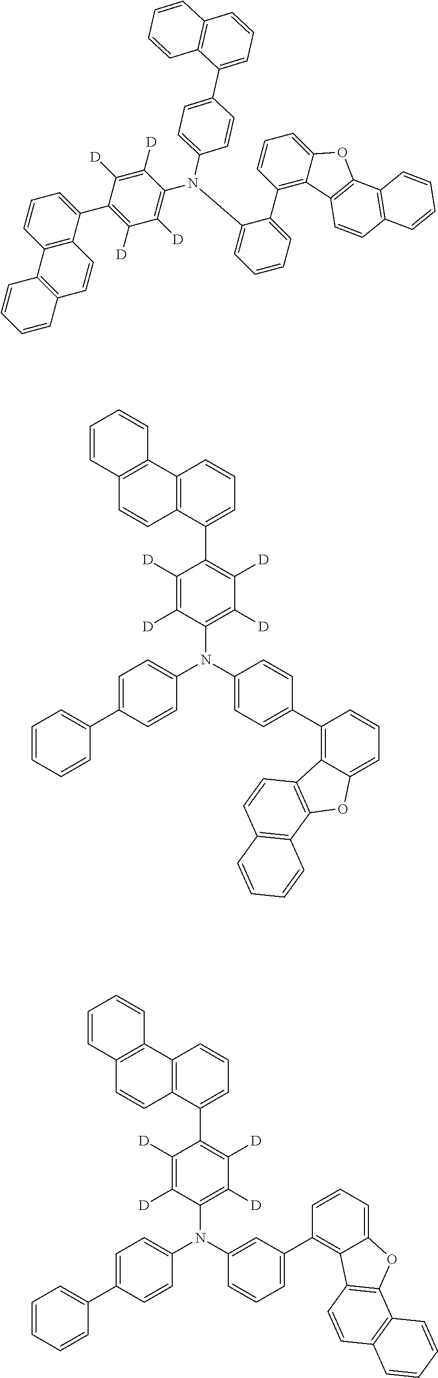 [SMILES: [2H]c1c([2H])c(N(c2ccc(-c3cccc4ccccc34)cc2)c2ccccc2-c2cccc3oc4c5ccccc5ccc4c23)c([2H])c([2H])c1-c1cccc2c1ccc1ccccc12 ; [2H]c1c([2H])c(N(c2ccc(-c3ccccc3)cc2)c2ccc(-c3cccc4oc5c6ccccc6ccc5c34)cc2)c([2H])c([2H])c1-c1cccc2c1ccc1ccccc12 ; [2H]c1c([2H])c(N(c2ccc(-c3ccccc3)cc2)c2cccc(-c3cccc4oc5c6ccccc6ccc5c34)c2)c([2H])c([2H])c1-c1cccc2c1ccc1ccccc12]

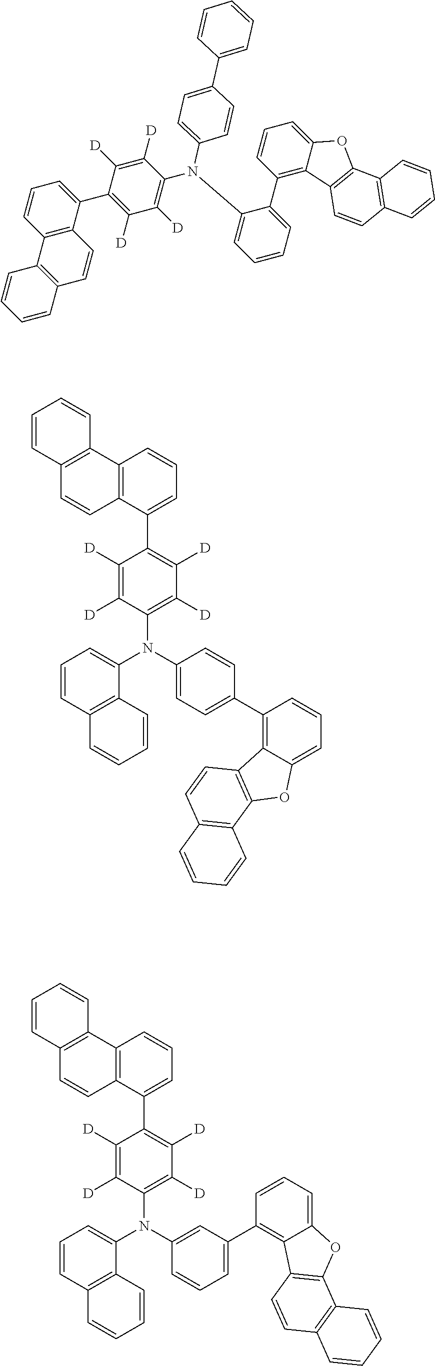 [SMILES: [2H]c1c([2H])c(N(c2ccc(-c3ccccc3)cc2)c2ccccc2-c2cccc3oc4c5ccccc5ccc4c23)c([2H])c([2H])c1-c1cccc2c1ccc1ccccc12 ; [2H]c1c([2H])c(N(c2ccc(-c3cccc4oc5c6ccccc6ccc5c34)cc2)c2cccc3ccccc23)c([2H])c([2H])c1-c1cccc2c1ccc1ccccc12 ; [2H]c1c([2H])c(N(c2cccc(-c3cccc4oc5c6ccccc6ccc5c34)c2)c2cccc3ccccc23)c([2H])c([2H])c1-c1cccc2c1ccc1ccccc12]

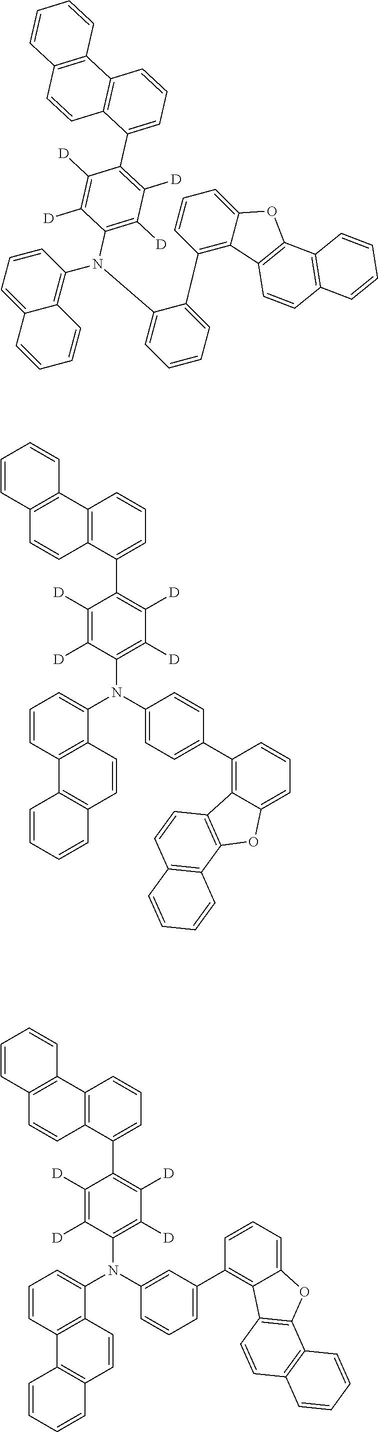 [SMILES: [2H]c1c([2H])c(N(c2ccccc2-c2cccc3oc4c5ccccc5ccc4c23)c2cccc3ccccc23)c([2H])c([2H])c1-c1cccc2c1ccc1ccccc12 ; [2H]c1c([2H])c(N(c2ccc(-c3cccc4oc5c6ccccc6ccc5c34)cc2)c2cccc3c2ccc2ccccc23)c([2H])c([2H])c1-c1cccc2c1ccc1ccccc12 ; [2H]c1c([2H])c(N(c2cccc(-c3cccc4oc5c6ccccc6ccc5c34)c2)c2cccc3c2ccc2ccccc23)c([2H])c([2H])c1-c1cccc2c1ccc1ccccc12]

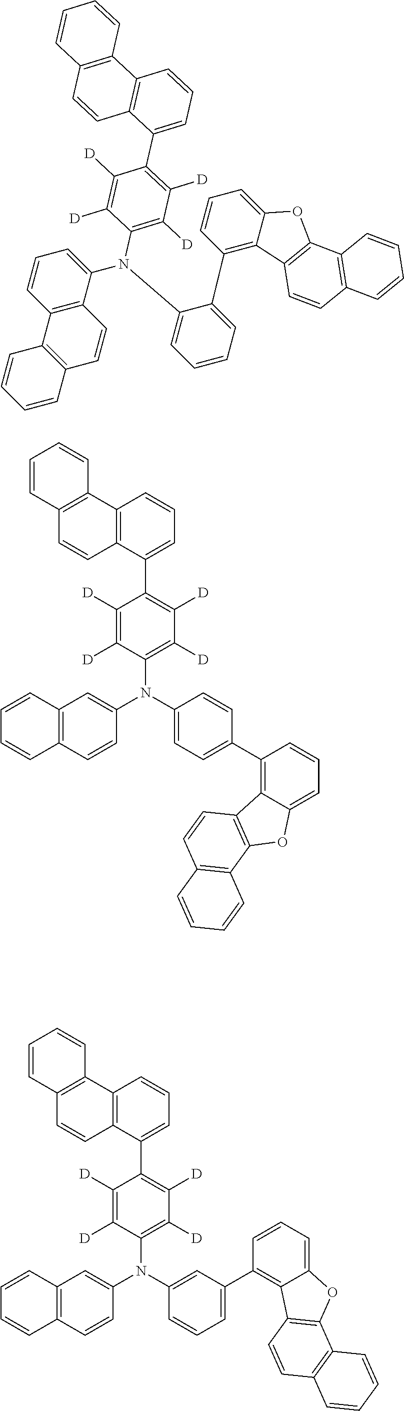

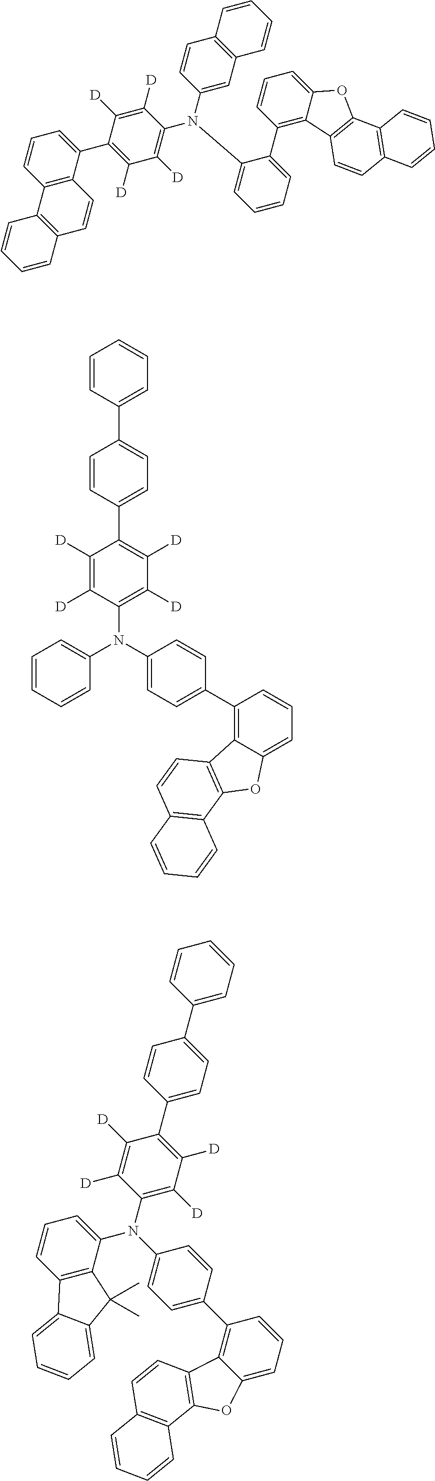 [SMILES: [2H]c1c([2H])c(N(c2ccc3ccccc3c2)c2ccccc2-c2cccc3oc4c5ccccc5ccc4c23)c([2H])c([2H])c1-c1cccc2c1ccc1ccccc12 ; [2H]c1c([2H])c(N(c2ccccc2)c2ccc(-c3cccc4oc5c6ccccc6ccc5c34)cc2)c([2H])c([2H])c1-c1ccc(-c2ccccc2)cc1 ; [2H]c1c([2H])c(N(c2ccc(-c3cccc4oc5c6ccccc6ccc5c34)cc2)c2cccc3c2C(C)(C)c2ccccc2-3)c([2H])c([2H])c1-c1ccc(-c2ccccc2)cc1]

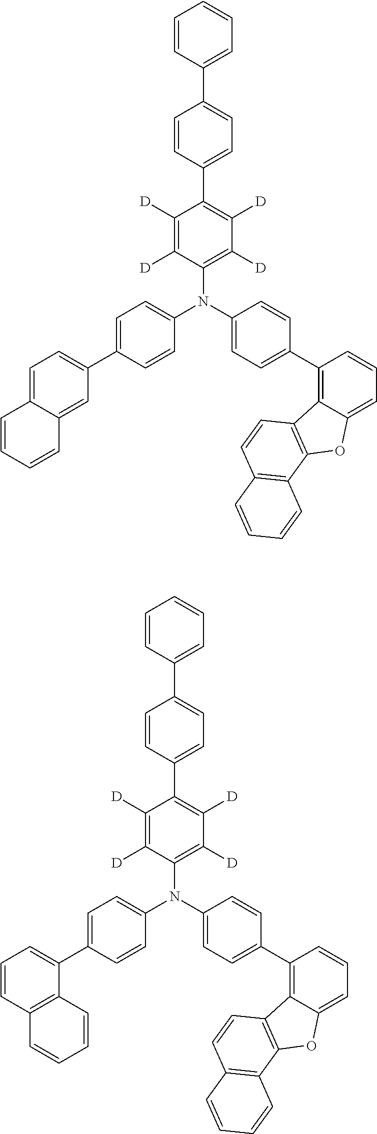 [SMILES: [2H]c1c([2H])c(N(c2ccc(-c3ccc4ccccc4c3)cc2)c2ccc(-c3cccc4oc5c6ccccc6ccc5c34)cc2)c([2H])c([2H])c1-c1ccc(-c2ccccc2)cc1 ; [2H]c1c([2H])c(N(c2ccc(-c3cccc4ccccc34)cc2)c2ccc(-c3cccc4oc5c6ccccc6ccc5c34)cc2)c([2H])c([2H])c1-c1ccc(-c2ccccc2)cc1]

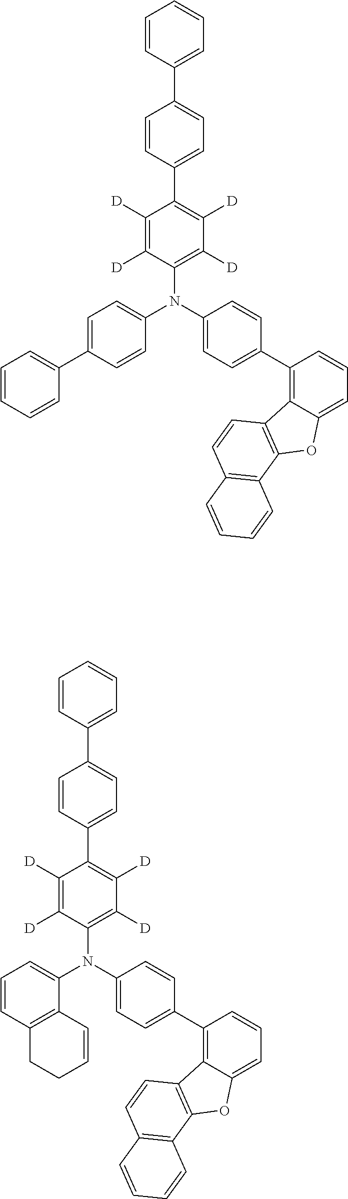 [SMILES: [2H]c1c([2H])c(N(c2ccc(-c3ccccc3)cc2)c2ccc(-c3cccc4oc5c6ccccc6ccc5c34)cc2)c([2H])c([2H])c1-c1ccc(-c2ccccc2)cc1 ; [2H]c1c([2H])c(N(c2ccc(-c3cccc4oc5c6ccccc6ccc5c34)cc2)c2cccc3c2C=CCC3)c([2H])c([2H])c1-c1ccc(-c2ccccc2)cc1]

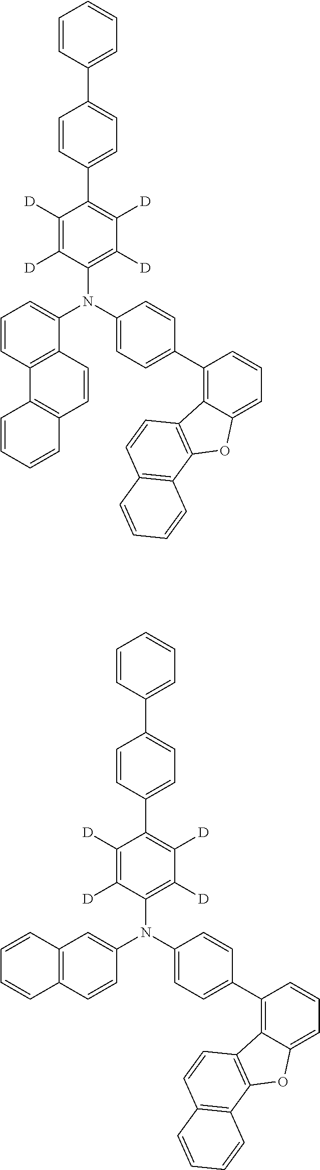 [SMILES: [2H]c1c([2H])c(N(c2ccc(-c3cccc4oc5c6ccccc6ccc5c34)cc2)c2cccc3c2ccc2ccccc23)c([2H])c([2H])c1-c1ccc(-c2ccccc2)cc1 ; [2H]c1c([2H])c(N(c2ccc(-c3cccc4oc5c6ccccc6ccc5c34)cc2)c2ccc3ccccc3c2)c([2H])c([2H])c1-c1ccc(-c2ccccc2)cc1]

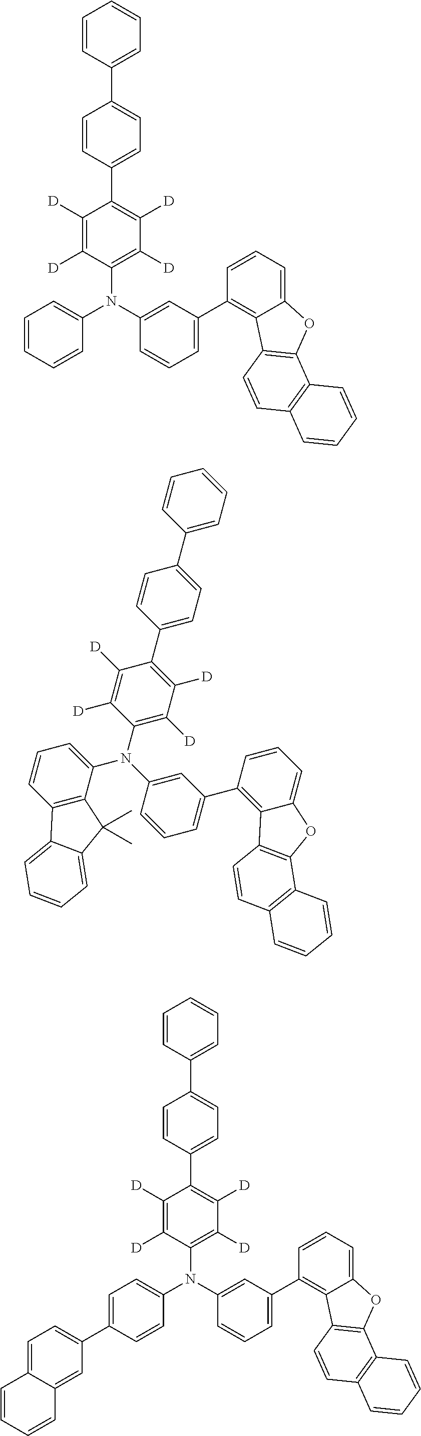 [SMILES: [2H]c1c([2H])c(N(c2ccccc2)c2cccc(-c3cccc4oc5c6ccccc6ccc5c34)c2)c([2H])c([2H])c1-c1ccc(-c2ccccc2)cc1 ; [2H]c1c([2H])c(N(c2cccc(-c3cccc4oc5c6ccccc6ccc5c34)c2)c2cccc3c2C(C)(C)c2ccccc2-3)c([2H])c([2H])c1-c1ccc(-c2ccccc2)cc1 ; [2H]c1c([2H])c(N(c2ccc(-c3ccc4ccccc4c3)cc2)c2cccc(-c3cccc4oc5c6ccccc6ccc5c34)c2)c([2H])c([2H])c1-c1ccc(-c2ccccc2)cc1]

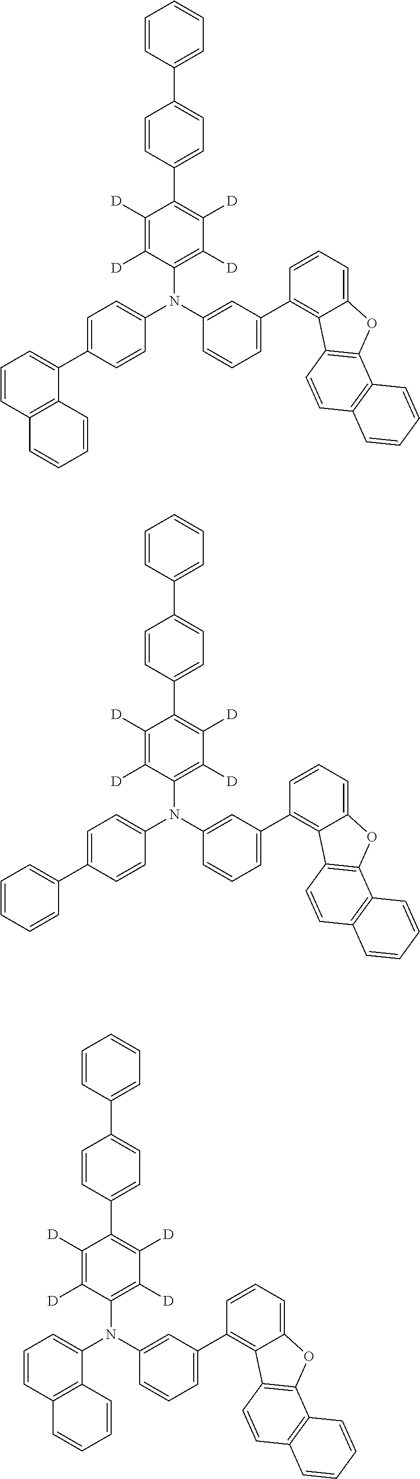 [SMILES: [2H]c1c([2H])c(N(c2ccc(-c3cccc4ccccc34)cc2)c2cccc(-c3cccc4oc5c6ccccc6ccc5c34)c2)c([2H])c([2H])c1-c1ccc(-c2ccccc2)cc1 ; [2H]c1c([2H])c(N(c2ccc(-c3ccccc3)cc2)c2cccc(-c3cccc4oc5c6ccccc6ccc5c34)c2)c([2H])c([2H])c1-c1ccc(-c2ccccc2)cc1 ; [2H]c1c([2H])c(N(c2cccc(-c3cccc4oc5c6ccccc6ccc5c34)c2)c2cccc3ccccc23)c([2H])c([2H])c1-c1ccc(-c2ccccc2)cc1]

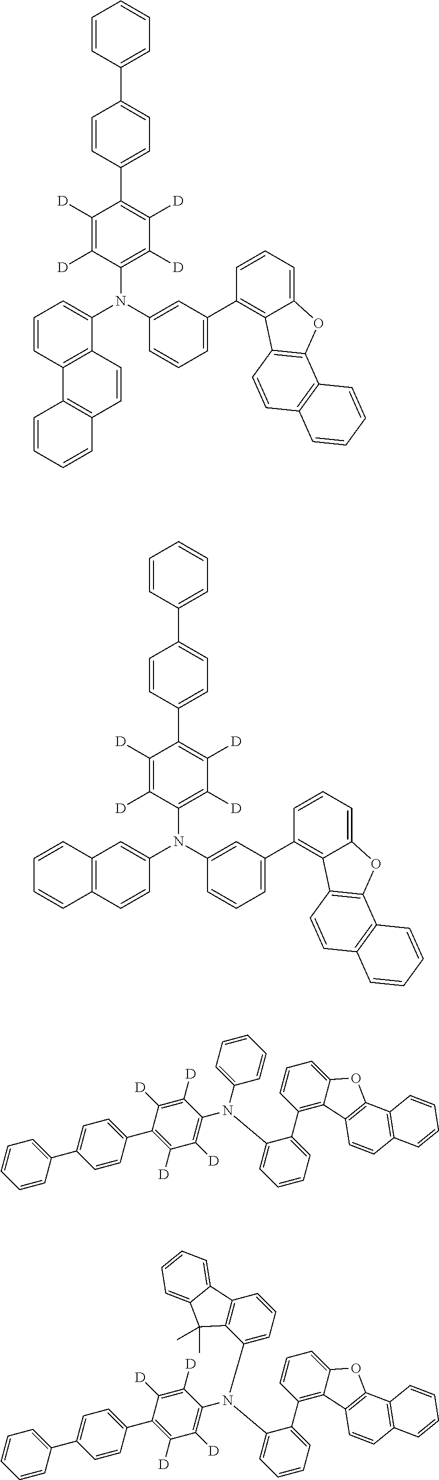 [SMILES: [2H]c1c([2H])c(N(c2cccc(-c3cccc4oc5c6ccccc6ccc5c34)c2)c2cccc3c2ccc2ccccc23)c([2H])c([2H])c1-c1ccc(-c2ccccc2)cc1 ; [2H]c1c([2H])c(N(c2cccc(-c3cccc4oc5c6ccccc6ccc5c34)c2)c2ccc3ccccc3c2)c([2H])c([2H])c1-c1ccc(-c2ccccc2)cc1 ; [2H]c1c([2H])c(N(c2ccccc2)c2ccccc2-c2cccc3oc4c5ccccc5ccc4c23)c([2H])c([2H])c1-c1ccc(-c2ccccc2)cc1 ; [2H]c1c([2H])c(N(c2ccccc2-c2cccc3oc4c5ccccc5ccc4c23)c2cccc3c2C(C)(C)c2ccccc2-3)c([2H])c([2H])c1-c1ccc(-c2ccccc2)cc1]

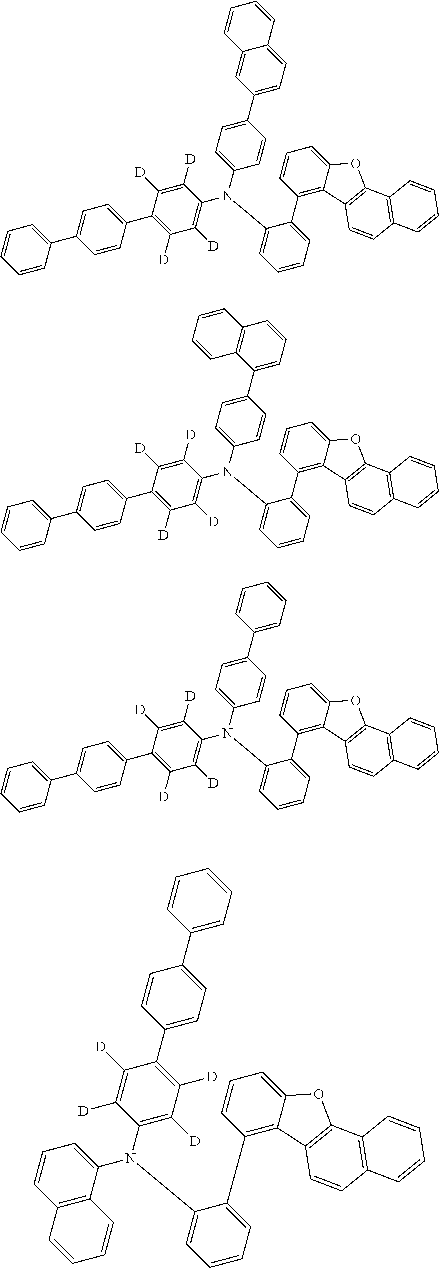

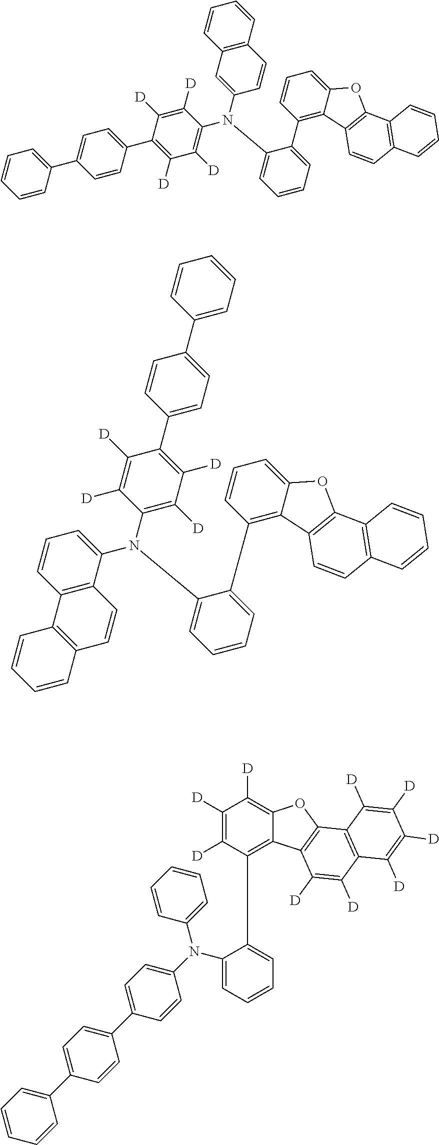 [SMILES: [2H]c1c([2H])c(N(c2ccc3ccccc3c2)c2ccccc2-c2cccc3oc4c5ccccc5ccc4c23)c([2H])c([2H])c1-c1ccc(-c2ccccc2)cc1 ; [2H]c1c([2H])c(N(c2ccccc2-c2cccc3oc4c5ccccc5ccc4c23)c2cccc3c2ccc2ccccc23)c([2H])c([2H])c1-c1ccc(-c2ccccc2)cc1 ; [2H]c1c([2H])c(-c2ccccc2N(c2ccccc2)c2ccc(-c3ccc(-c4ccccc4)cc3)cc2)c2c(oc3c4c([2H])c([2H])c([2H])c([2H])c4c([2H])c([2H])c32)c1[2H]]

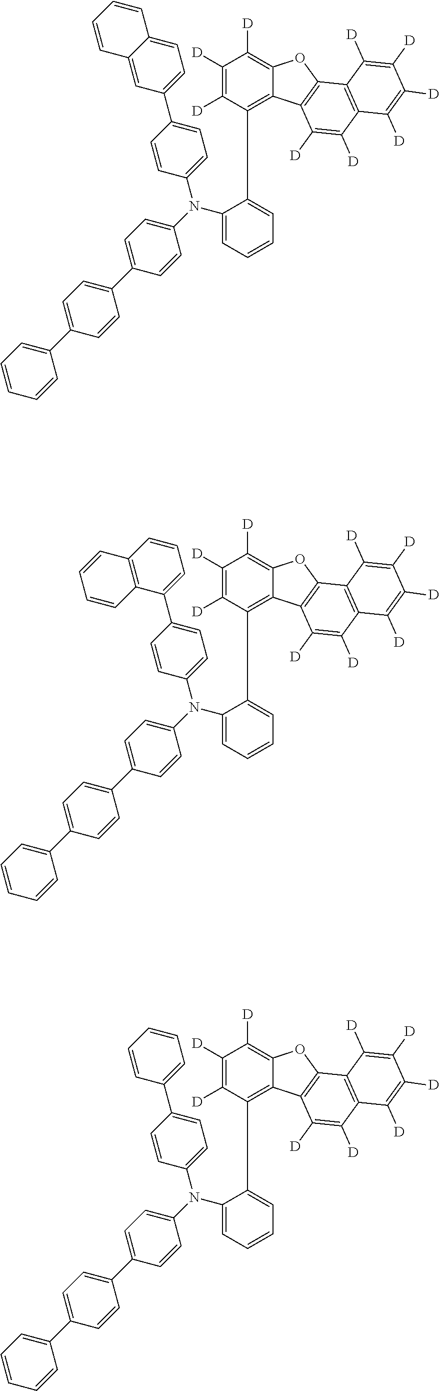 [SMILES: [2H]c1c([2H])c(-c2ccccc2N(c2ccc(-c3ccc(-c4ccccc4)cc3)cc2)c2ccc(-c3ccc4ccccc4c3)cc2)c2c(oc3c4c([2H])c([2H])c([2H])c([2H])c4c([2H])c([2H])c32)c1[2H] ; [2H]c1c([2H])c(-c2ccccc2N(c2ccc(-c3ccc(-c4ccccc4)cc3)cc2)c2ccc(-c3cccc4ccccc34)cc2)c2c(oc3c4c([2H])c([2H])c([2H])c([2H])c4c([2H])c([2H])c32)c1[2H] ; [2H]c1c([2H])c(-c2ccccc2N(c2ccc(-c3ccccc3)cc2)c2ccc(-c3ccc(-c4ccccc4)cc3)cc2)c2c(oc3c4c([2H])c([2H])c([2H])c([2H])c4c([2H])c([2H])c32)c1[2H]]

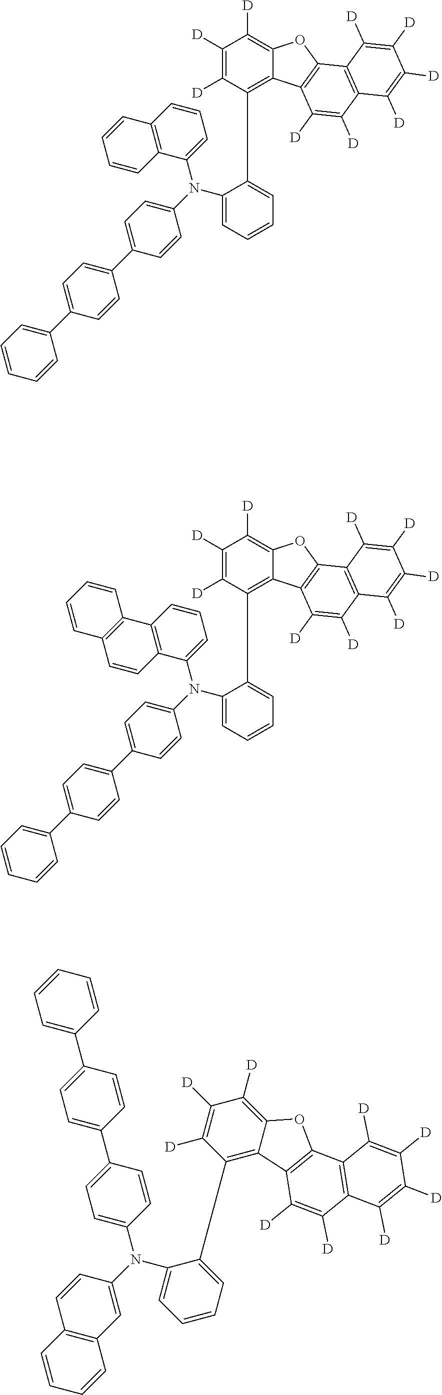 [SMILES: [2H]c1c([2H])c(-c2ccccc2N(c2ccc(-c3ccc(-c4ccccc4)cc3)cc2)c2cccc3ccccc23)c2c(oc3c4c([2H])c([2H])c([2H])c([2H])c4c([2H])c([2H])c32)c1[2H] ; [2H]c1c([2H])c(-c2ccccc2N(c2ccc(-c3ccc(-c4ccccc4)cc3)cc2)c2cccc3c2ccc2ccccc23)c2c(oc3c4c([2H])c([2H])c([2H])c([2H])c4c([2H])c([2H])c32)c1[2H] ; [2H]c1c([2H])c(-c2ccccc2N(c2ccc(-c3ccc(-c4ccccc4)cc3)cc2)c2ccc3ccccc3c2)c2c(oc3c4c([2H])c([2H])c([2H])c([2H])c4c([2H])c([2H])c32)c1[2H]]

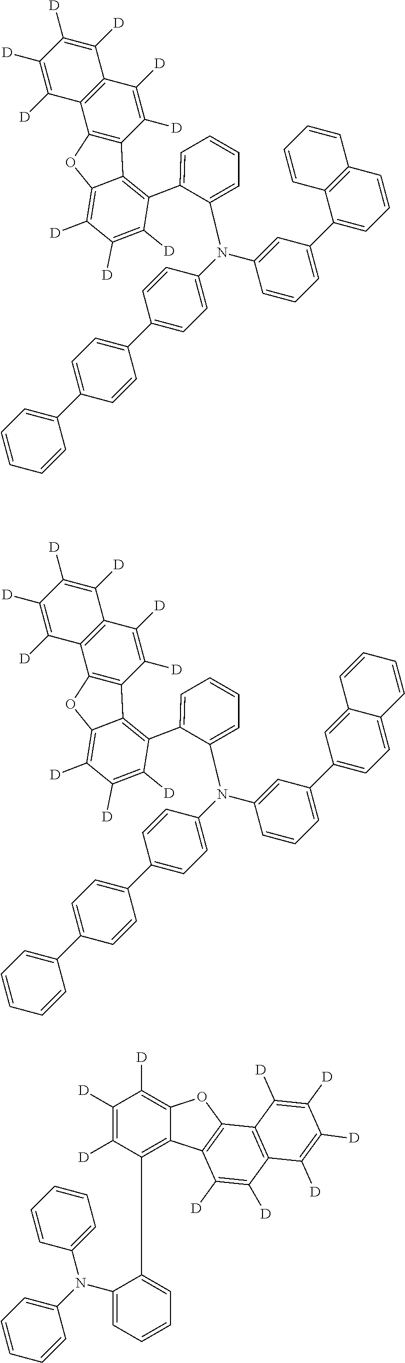 [SMILES: [2H]c1c([2H])c(-c2ccccc2N(c2ccc(-c3ccc(-c4ccccc4)cc3)cc2)c2cccc(-c3cccc4ccccc34)c2)c2c(oc3c4c([2H])c([2H])c([2H])c([2H])c4c([2H])c([2H])c32)c1[2H] ; [2H]c1c([2H])c(-c2ccccc2N(c2ccc(-c3ccc(-c4ccccc4)cc3)cc2)c2cccc(-c3ccc4ccccc4c3)c2)c2c(oc3c4c([2H])c([2H])c([2H])c([2H])c4c([2H])c([2H])c32)c1[2H] ; [2H]c1c([2H])c(-c2ccccc2N(c2ccccc2)c2ccccc2)c2c(oc3c4c([2H])c([2H])c([2H])c([2H])c4c([2H])c([2H])c32)c1[2H]]

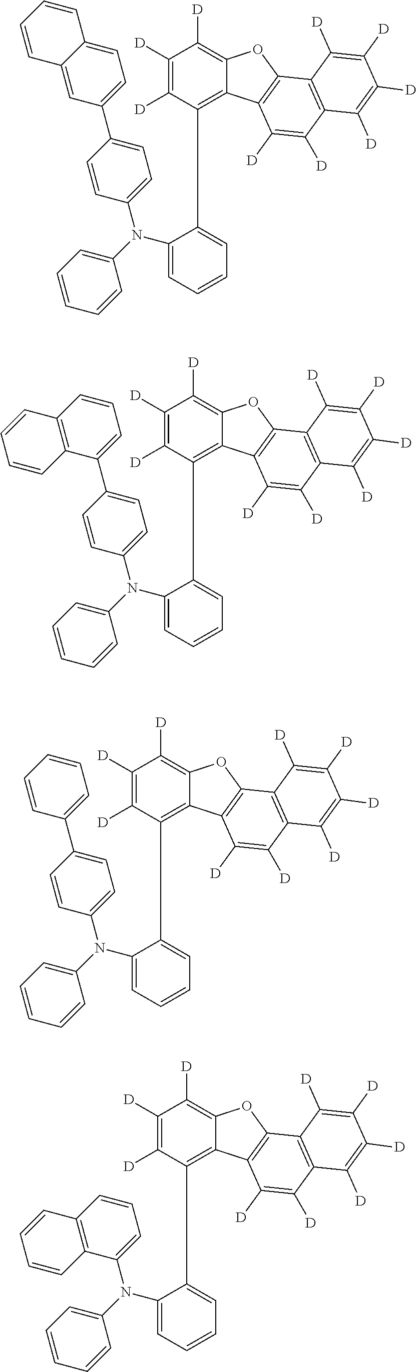 [SMILES: [2H]c1c([2H])c(-c2ccccc2N(c2ccccc2)c2ccc(-c3ccc4ccccc4c3)cc2)c2c(oc3c4c([2H])c([2H])c([2H])c([2H])c4c([2H])c([2H])c32)c1[2H] ; [2H]c1c([2H])c(-c2ccccc2N(c2ccccc2)c2ccc(-c3cccc4ccccc34)cc2)c2c(oc3c4c([2H])c([2H])c([2H])c([2H])c4c([2H])c([2H])c32)c1[2H] ; [2H]c1c([2H])c(-c2ccccc2N(c2ccccc2)c2ccc(-c3ccccc3)cc2)c2c(oc3c4c([2H])c([2H])c([2H])c([2H])c4c([2H])c([2H])c32)c1[2H] ; [2H]c1c([2H])c(-c2ccccc2N(c2ccccc2)c2cccc3ccccc23)c2c(oc3c4c([2H])c([2H])c([2H])c([2H])c4c([2H])c([2H])c32)c1[2H]]

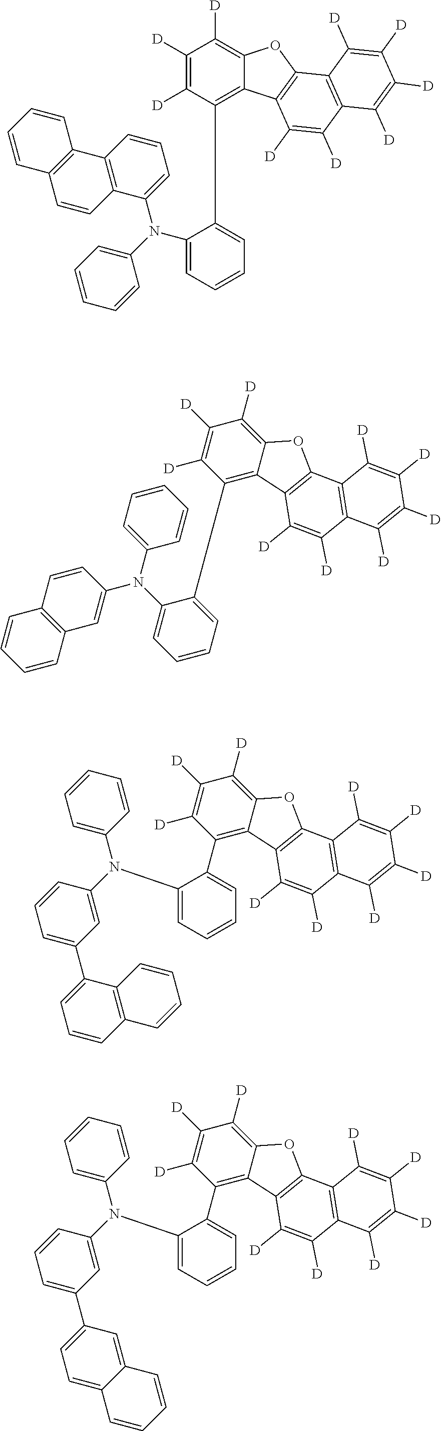 [SMILES: [2H]c1c([2H])c(-c2ccccc2N(c2ccccc2)c2cccc3c2ccc2ccccc23)c2c(oc3c4c([2H])c([2H])c([2H])c([2H])c4c([2H])c([2H])c32)c1[2H] ; [2H]c1c([2H])c(-c2ccccc2N(c2ccccc2)c2ccc3ccccc3c2)c2c(oc3c4c([2H])c([2H])c([2H])c([2H])c4c([2H])c([2H])c32)c1[2H] ; [2H]c1c([2H])c(-c2ccccc2N(c2ccccc2)c2cccc(-c3cccc4ccccc34)c2)c2c(oc3c4c([2H])c([2H])c([2H])c([2H])c4c([2H])c([2H])c32)c1[2H] ; [2H]c1c([2H])c(-c2ccccc2N(c2ccccc2)c2cccc(-c3ccc4ccccc4c3)c2)c2c(oc3c4c([2H])c([2H])c([2H])c([2H])c4c([2H])c([2H])c32)c1[2H]]

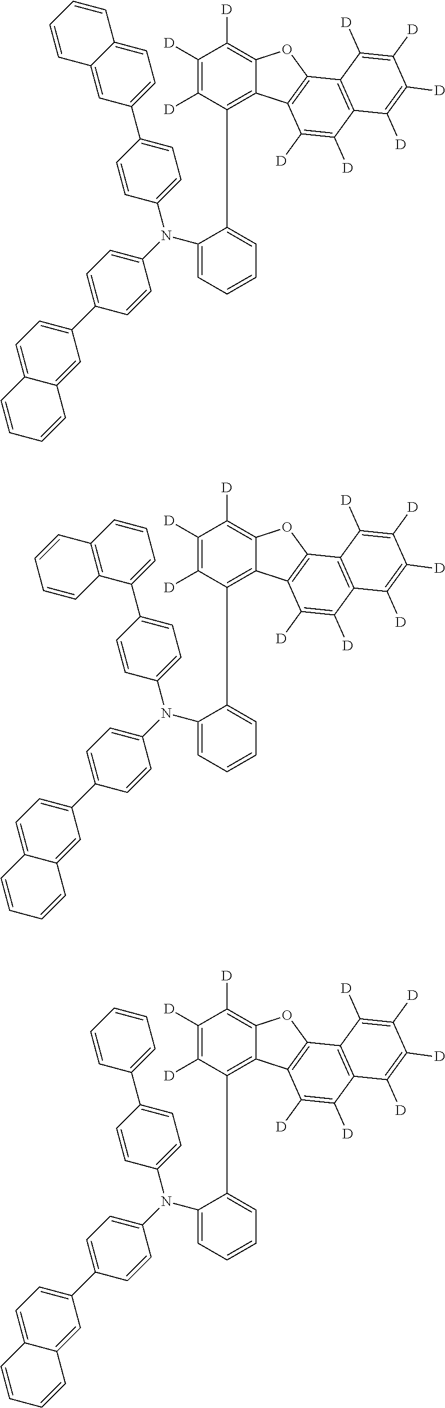 [SMILES: [2H]c1c([2H])c(-c2ccccc2N(c2ccc(-c3ccc4ccccc4c3)cc2)c2ccc(-c3ccc4ccccc4c3)cc2)c2c(oc3c4c([2H])c([2H])c([2H])c([2H])c4c([2H])c([2H])c32)c1[2H] ; [2H]c1c([2H])c(-c2ccccc2N(c2ccc(-c3ccc4ccccc4c3)cc2)c2ccc(-c3cccc4ccccc34)cc2)c2c(oc3c4c([2H])c([2H])c([2H])c([2H])c4c([2H])c([2H])c32)c1[2H] ; [2H]c1c([2H])c(-c2ccccc2N(c2ccc(-c3ccccc3)cc2)c2ccc(-c3ccc4ccccc4c3)cc2)c2c(oc3c4c([2H])c([2H])c([2H])c([2H])c4c([2H])c([2H])c32)c1[2H]]

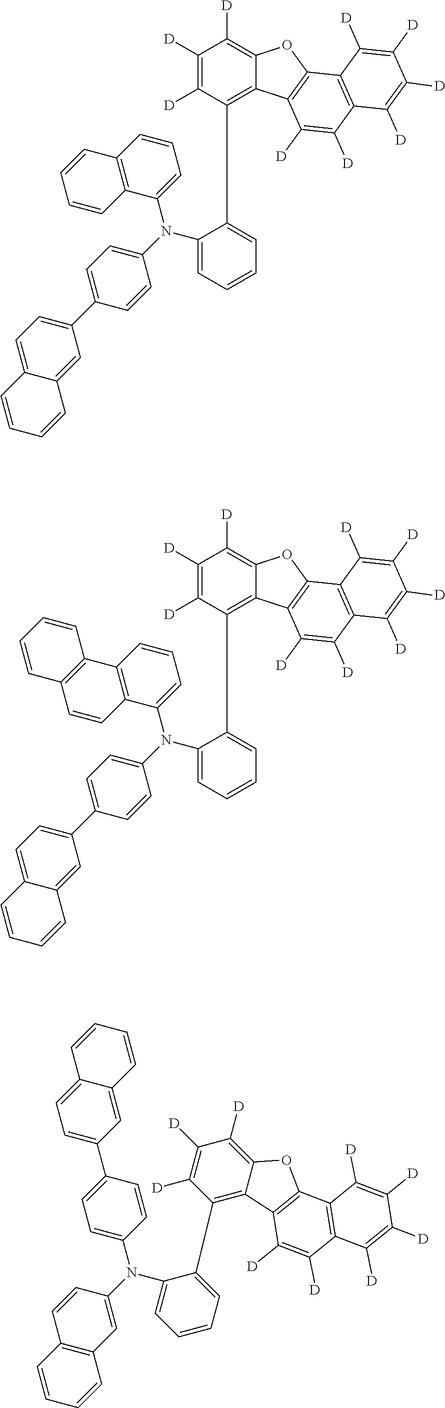 [SMILES: [2H]c1c([2H])c(-c2ccccc2N(c2ccc(-c3ccc4ccccc4c3)cc2)c2cccc3ccccc23)c2c(oc3c4c([2H])c([2H])c([2H])c([2H])c4c([2H])c([2H])c32)c1[2H] ; [2H]c1c([2H])c(-c2ccccc2N(c2ccc(-c3ccc4ccccc4c3)cc2)c2cccc3c2ccc2ccccc23)c2c(oc3c4c([2H])c([2H])c([2H])c([2H])c4c([2H])c([2H])c32)c1[2H] ; [2H]c1c([2H])c(-c2ccccc2N(c2ccc(-c3ccc4ccccc4c3)cc2)c2ccc3ccccc3c2)c2c(oc3c4c([2H])c([2H])c([2H])c([2H])c4c([2H])c([2H])c32)c1[2H]]

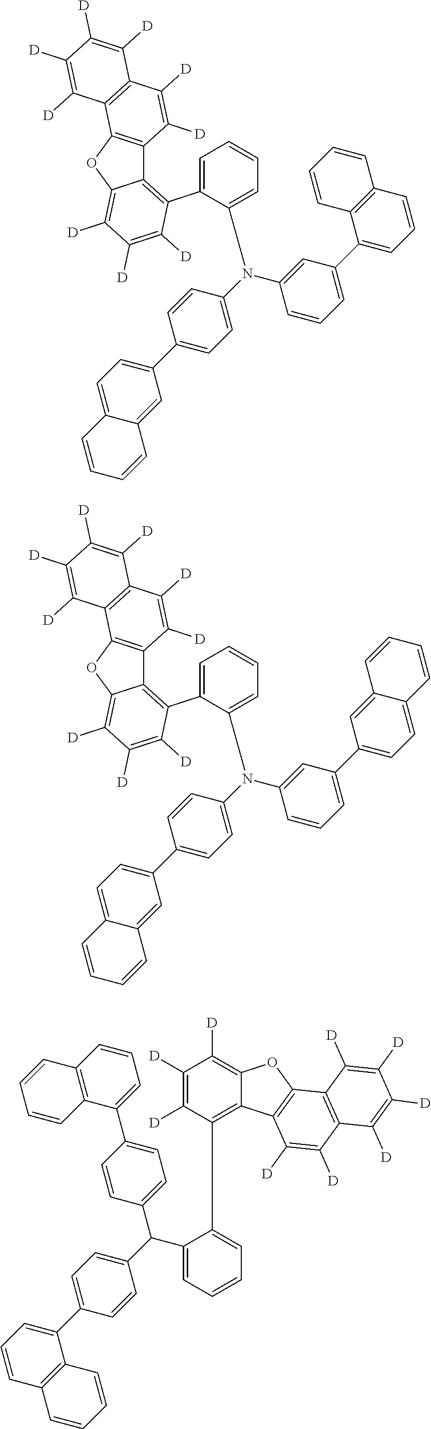

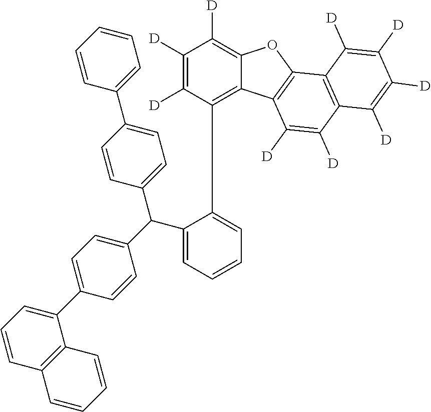 [SMILES: [2H]c1c([2H])c(-c2ccccc2C(c2ccc(-c3ccccc3)cc2)c2ccc(-c3cccc4ccccc34)cc2)c2c(oc3c4c([2H])c([2H])c([2H])c([2H])c4c([2H])c([2H])c32)c1[2H]]

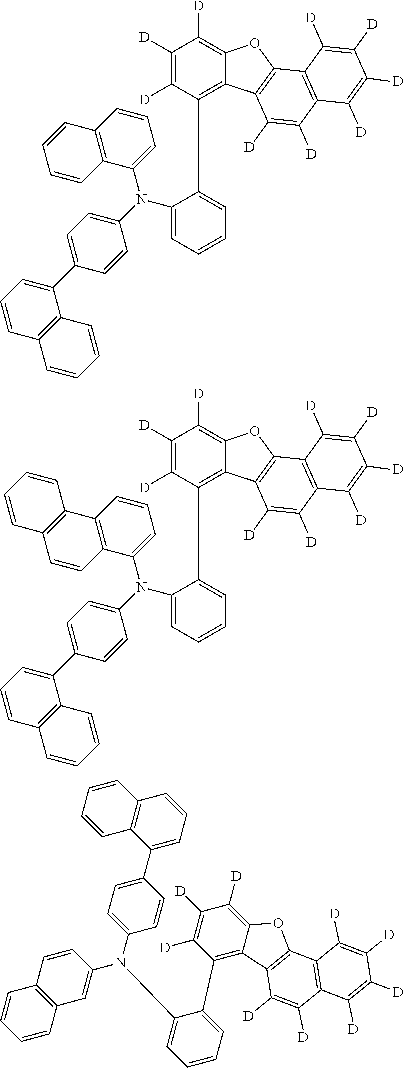

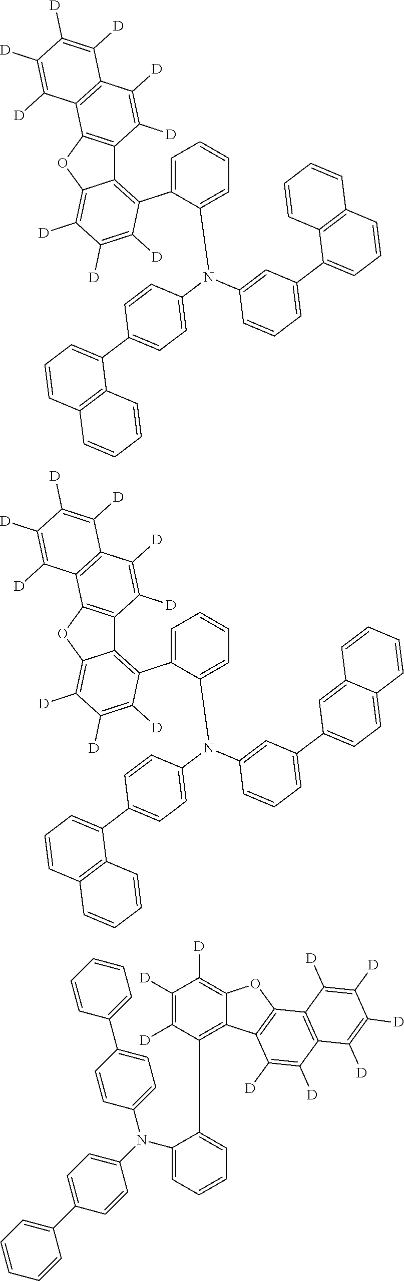

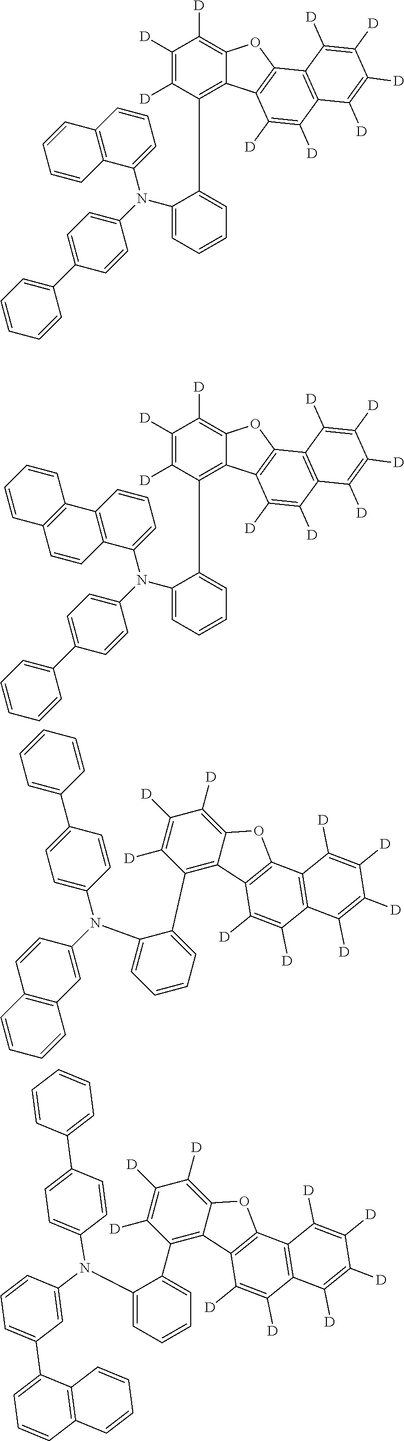

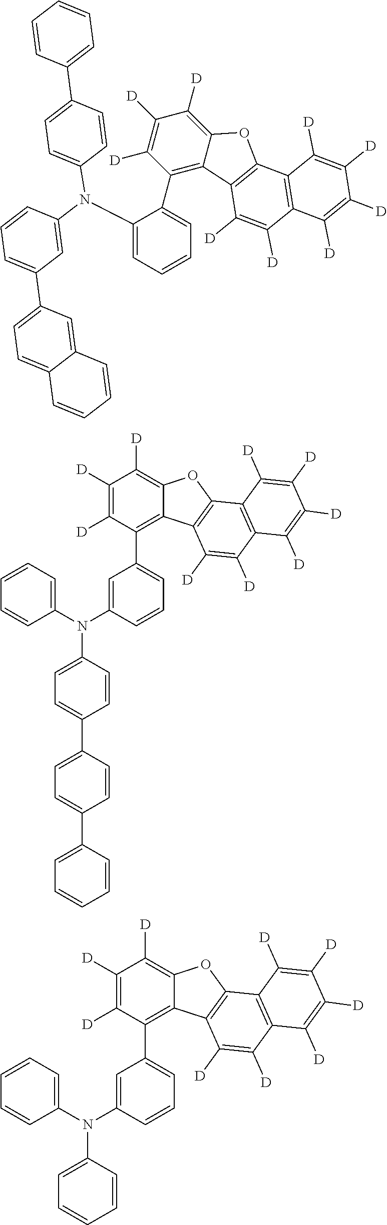 [SMILES: [2H]c1c([2H])c(-c2ccccc2N(c2ccc(-c3ccccc3)cc2)c2cccc(-c3ccc4ccccc4c3)c2)c2c(oc3c4c([2H])c([2H])c([2H])c([2H])c4c([2H])c([2H])c32)c1[2H] ; [2H]c1c([2H])c(-c2cccc(N(c3ccccc3)c3ccc(-c4ccc(-c5ccccc5)cc4)cc3)c2)c2c(oc3c4c([2H])c([2H])c([2H])c([2H])c4c([2H])c([2H])c32)c1[2H] ; [2H]c1c([2H])c(-c2cccc(N(c3ccccc3)c3ccccc3)c2)c2c(oc3c4c([2H])c([2H])c([2H])c([2H])c4c([2H])c([2H])c32)c1[2H]]

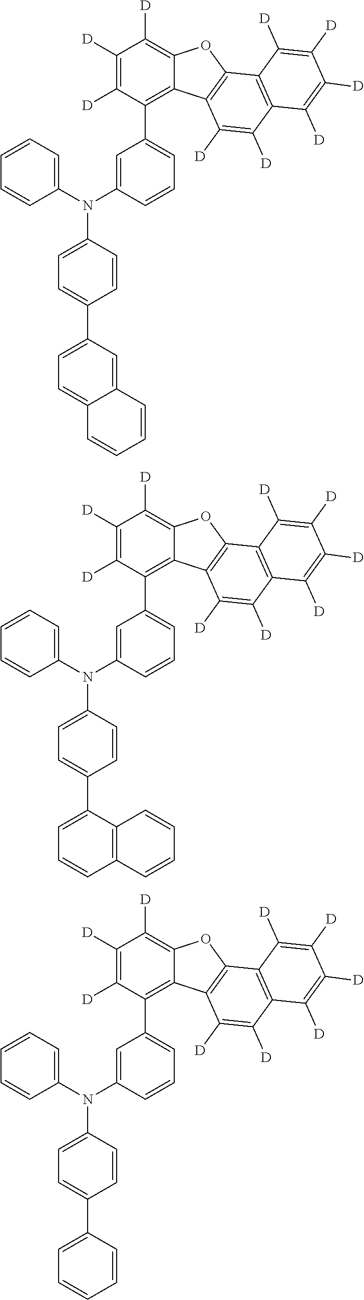

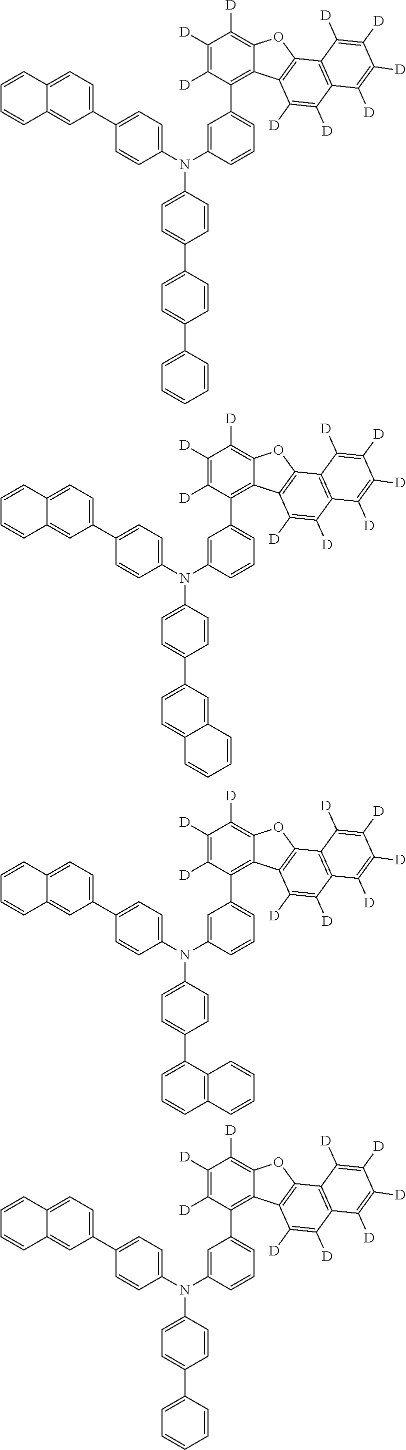

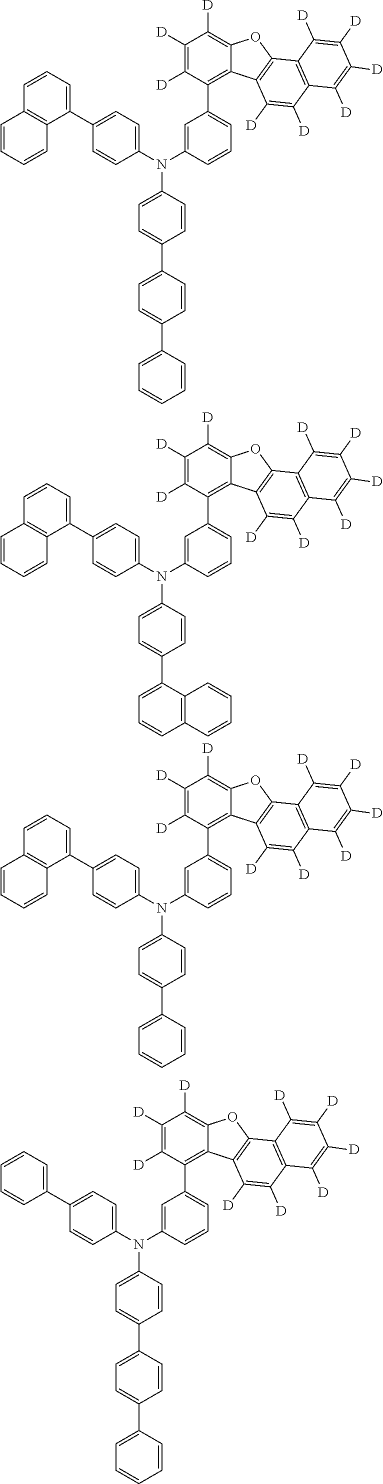

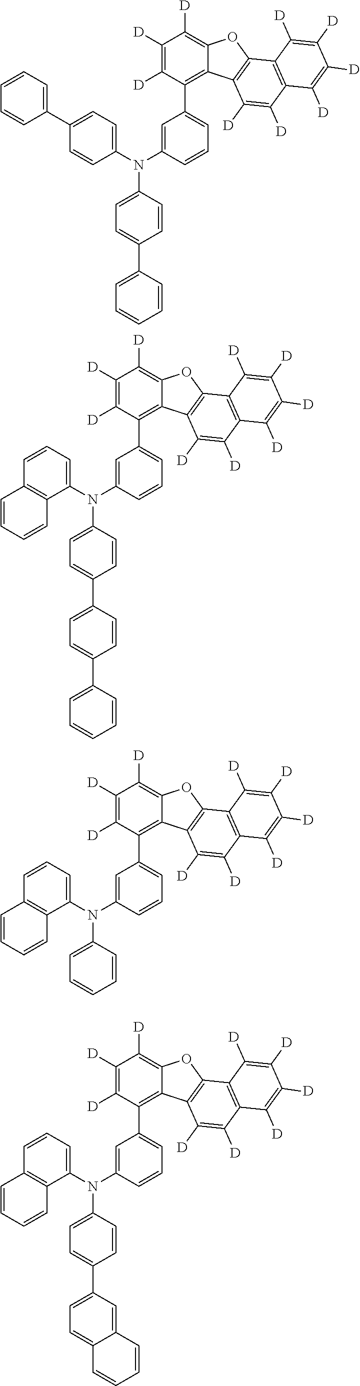

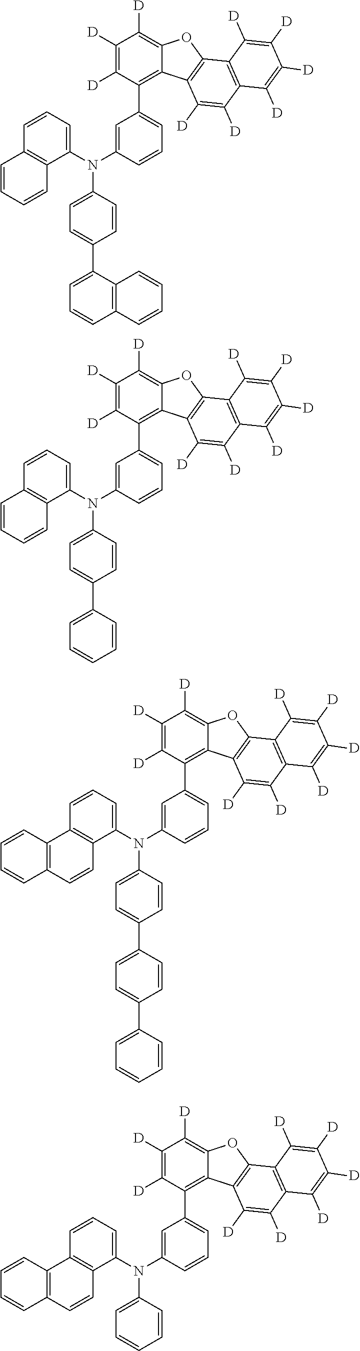

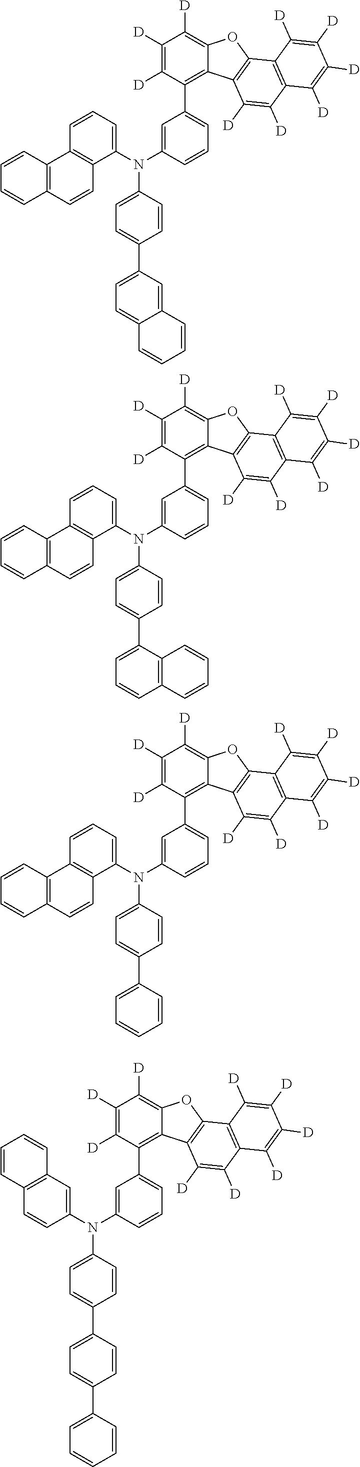

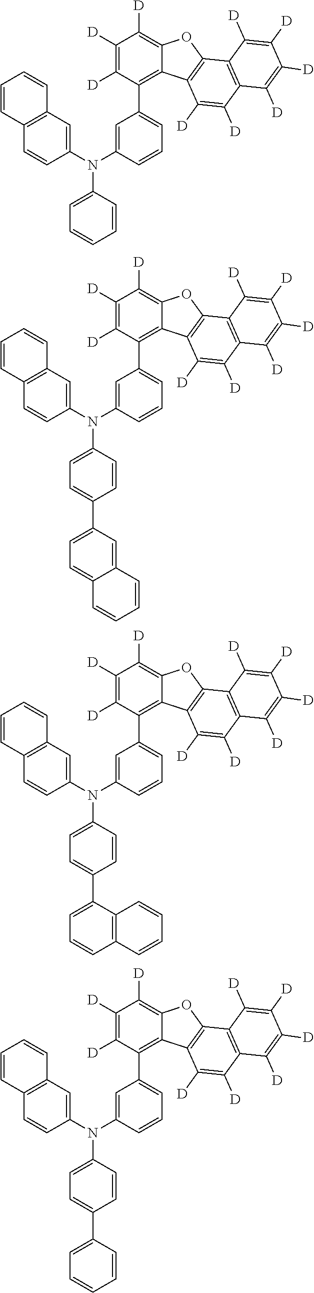

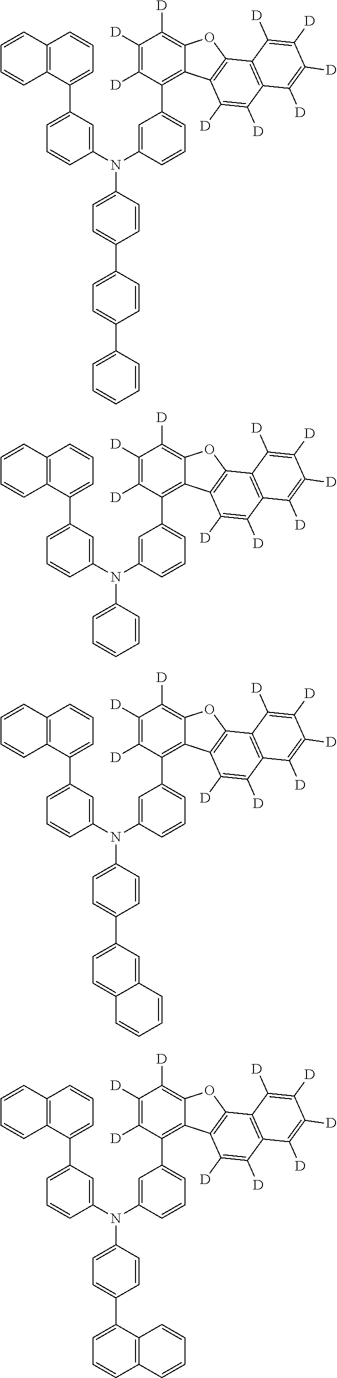

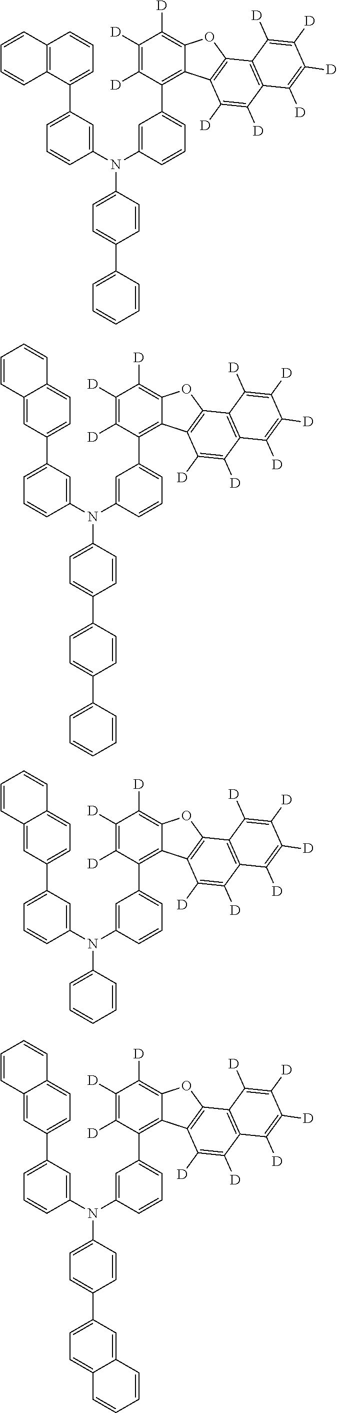

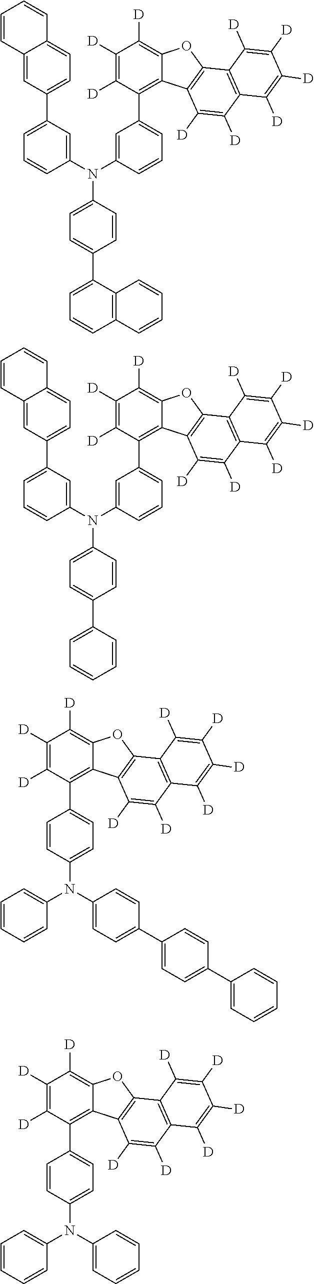

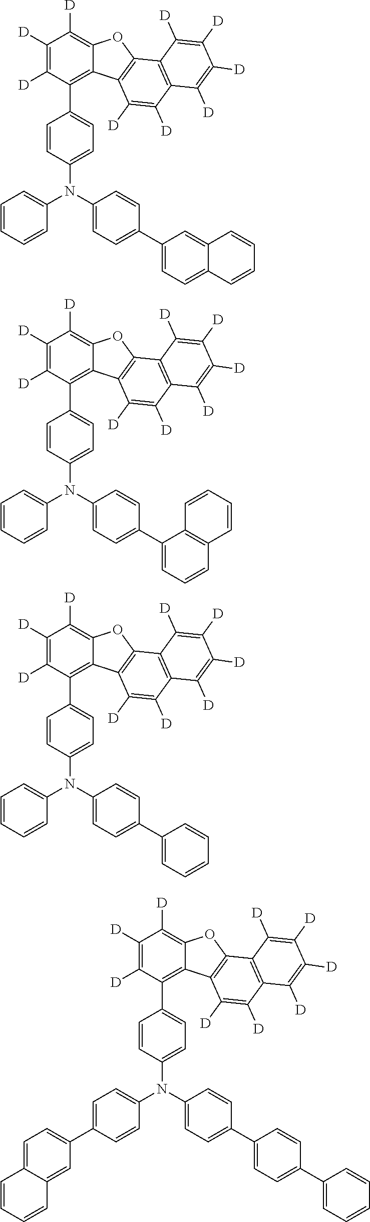

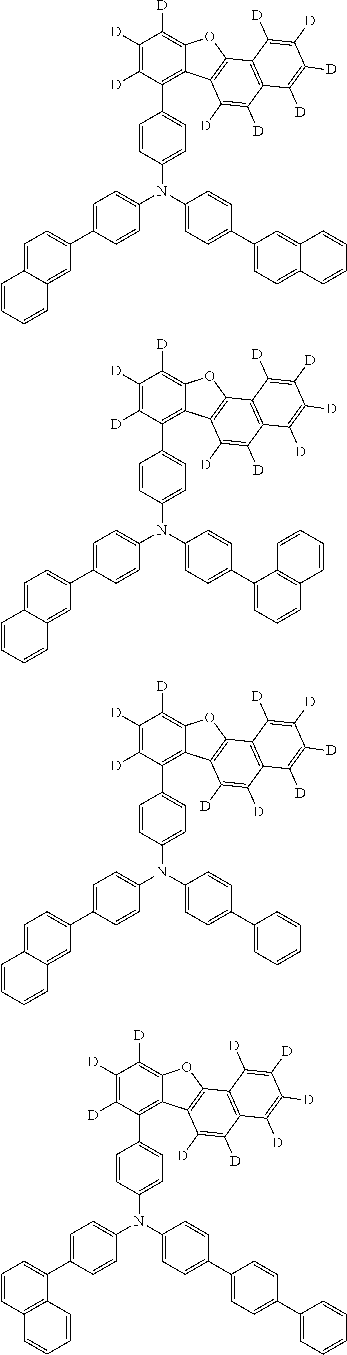

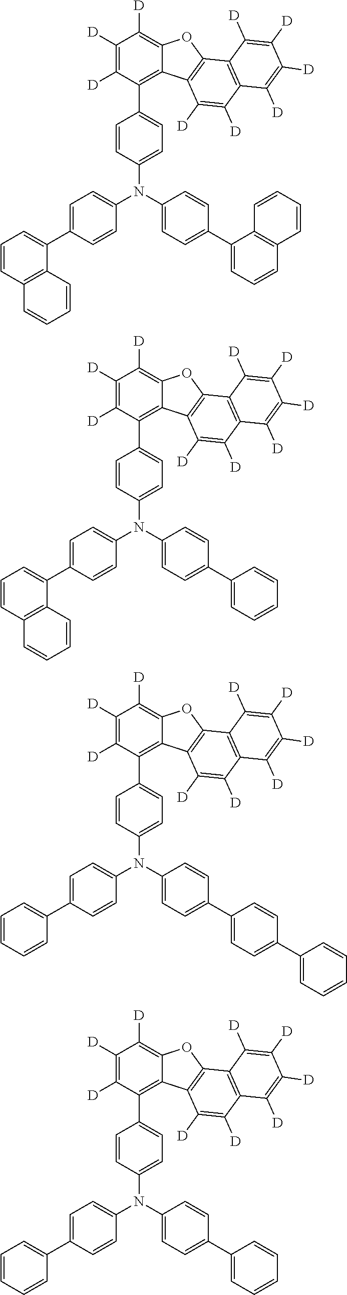

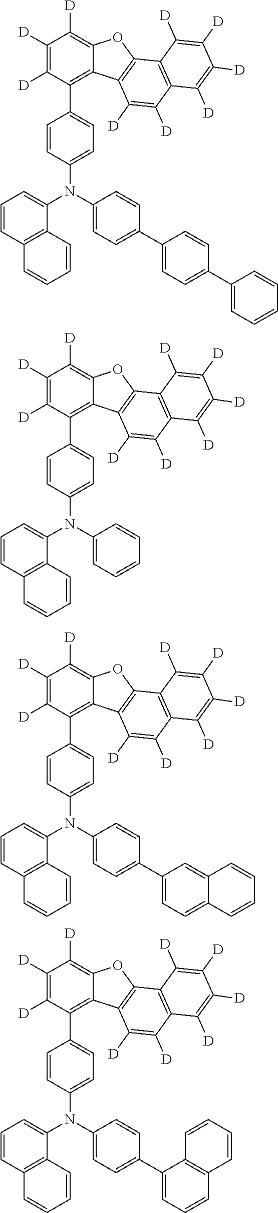

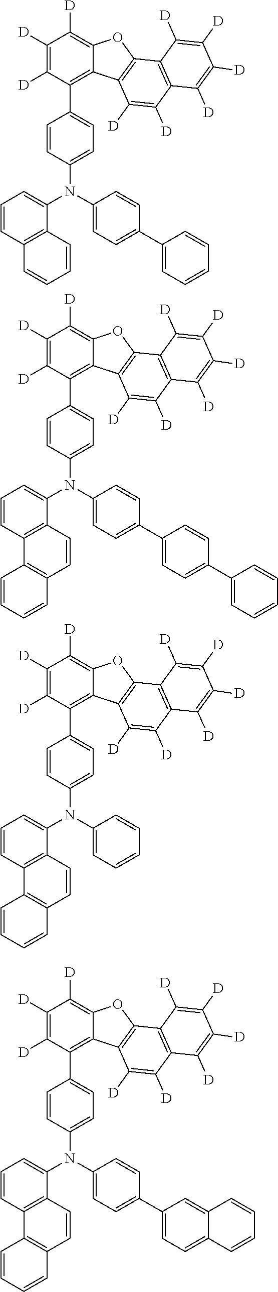

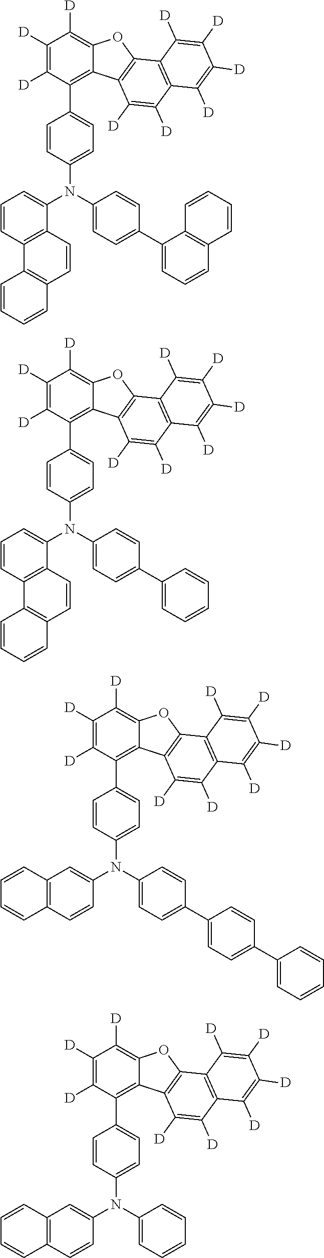

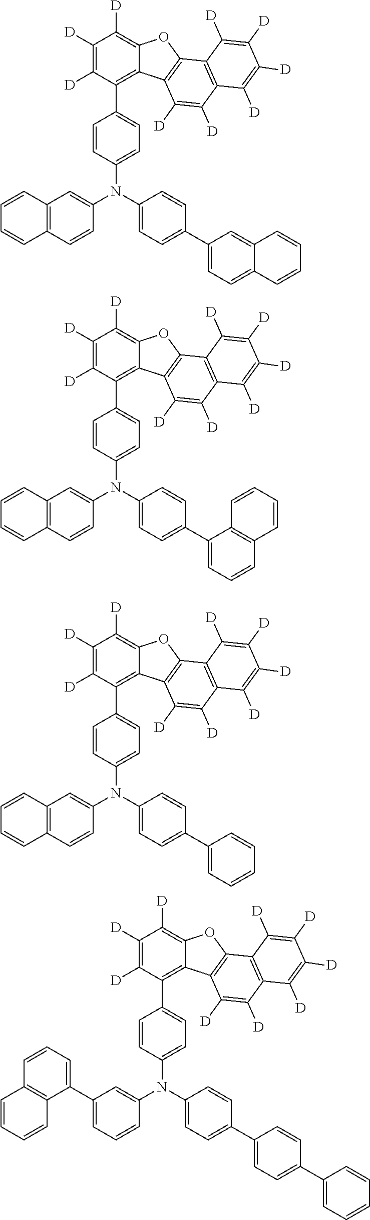

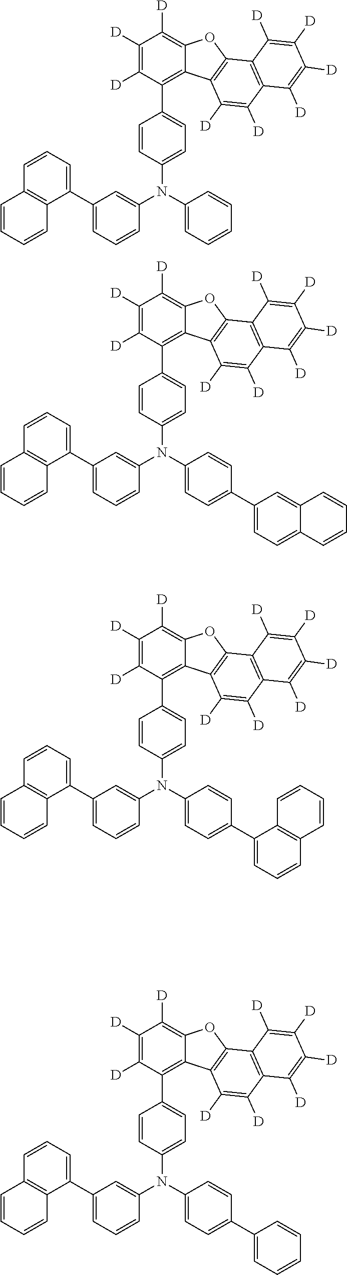

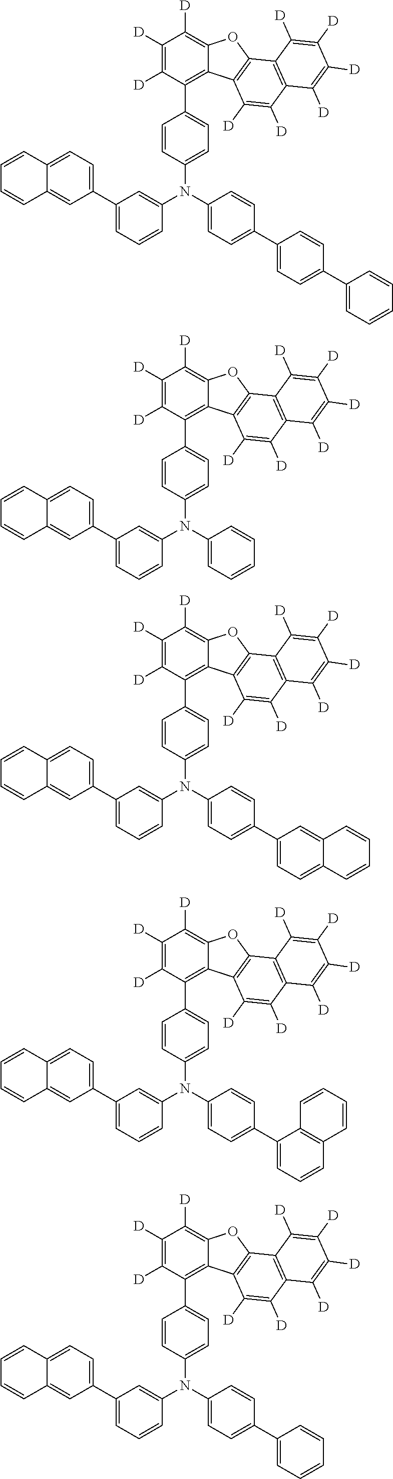

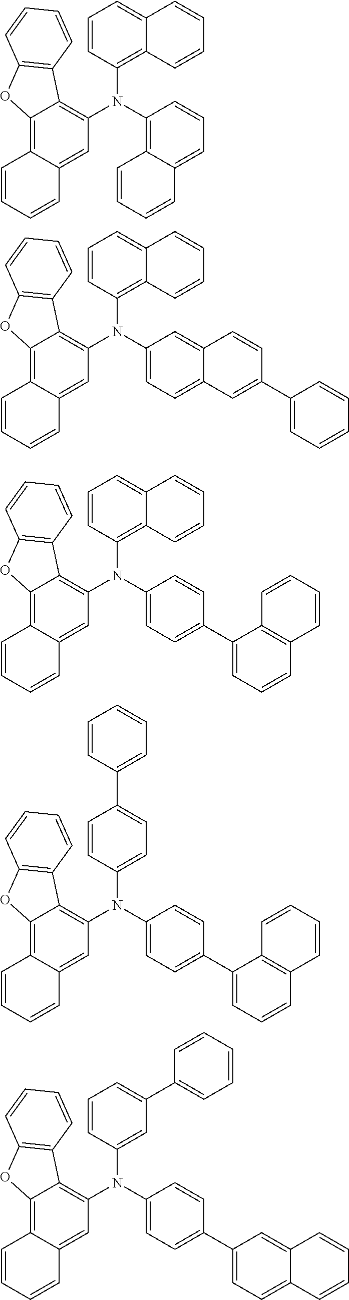

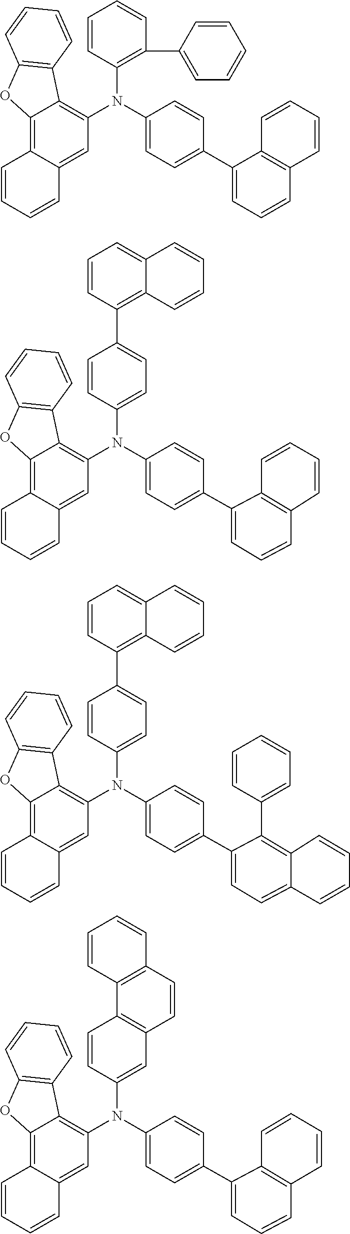 [SMILES: c1ccc(-c2ccccc2N(c2ccc(-c3cccc4ccccc34)cc2)c2cc3ccccc3c3oc4ccccc4c23)cc1 ; c1ccc2c(-c3ccc(N(c4ccc(-c5cccc6ccccc56)cc4)c4cc5ccccc5c5oc6ccccc6c45)cc3)cccc2c1 ; c1ccc(-c2c(-c3ccc(N(c4ccc(-c5cccc6ccccc56)cc4)c4cc5ccccc5c5oc6ccccc6c45)cc3)ccc3ccccc23)cc1 ; c1ccc2c(-c3ccc(N(c4ccc5c(ccc6ccccc65)c4)c4cc5ccccc5c5oc6ccccc6c45)cc3)cccc2c1]

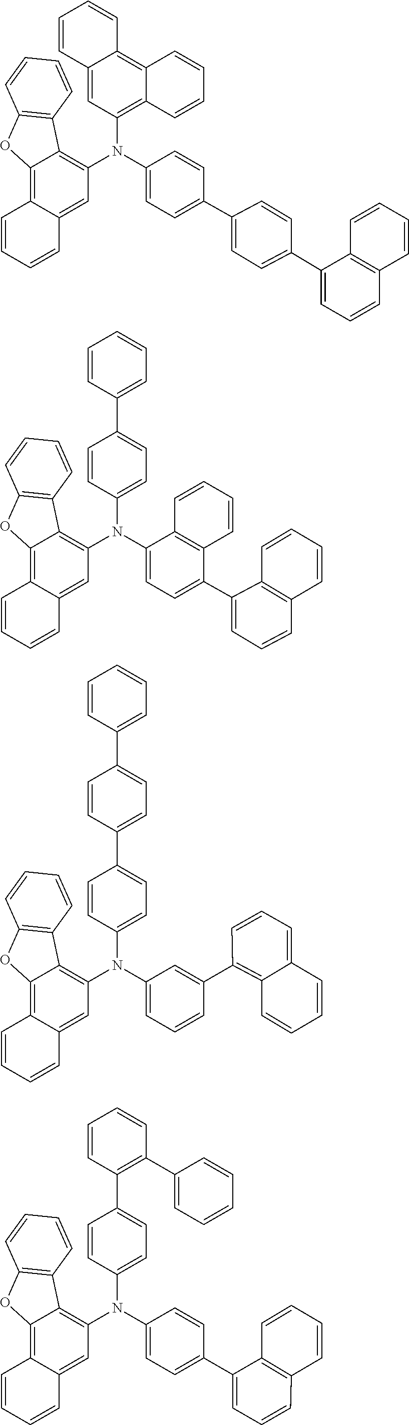 [SMILES: c1ccc2c(-c3ccc(-c4ccc(N(c5cc6ccccc6c6ccccc56)c5cc6ccccc6c6oc7ccccc7c56)cc4)cc3)cccc2c1 ; c1ccc(-c2ccc(N(c3ccc(-c4cccc5ccccc45)c4ccccc34)c3cc4ccccc4c4oc5ccccc5c34)cc2)cc1 ; c1ccc(-c2ccc(-c3ccc(N(c4cccc(-c5cccc6ccccc56)c4)c4cc5ccccc5c5oc6ccccc6c45)cc3)cc2)cc1 ; c1ccc(-c2ccccc2-c2ccc(N(c3ccc(-c4cccc5ccccc45)cc3)c3cc4ccccc4c4oc5ccccc5c34)cc2)cc1]

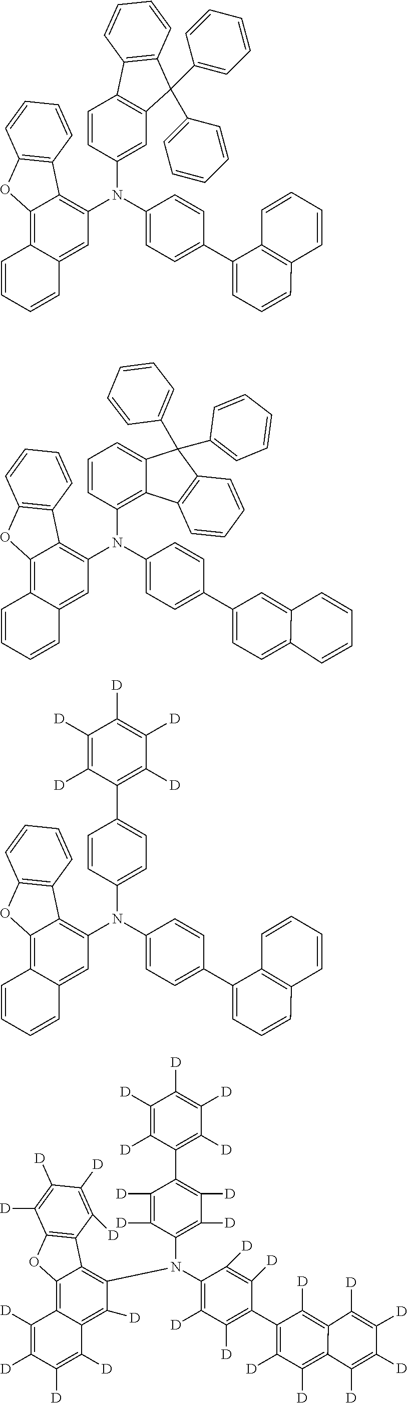

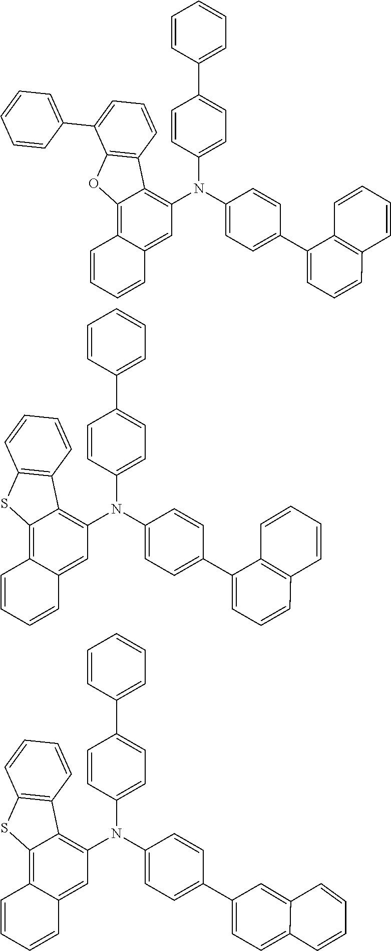

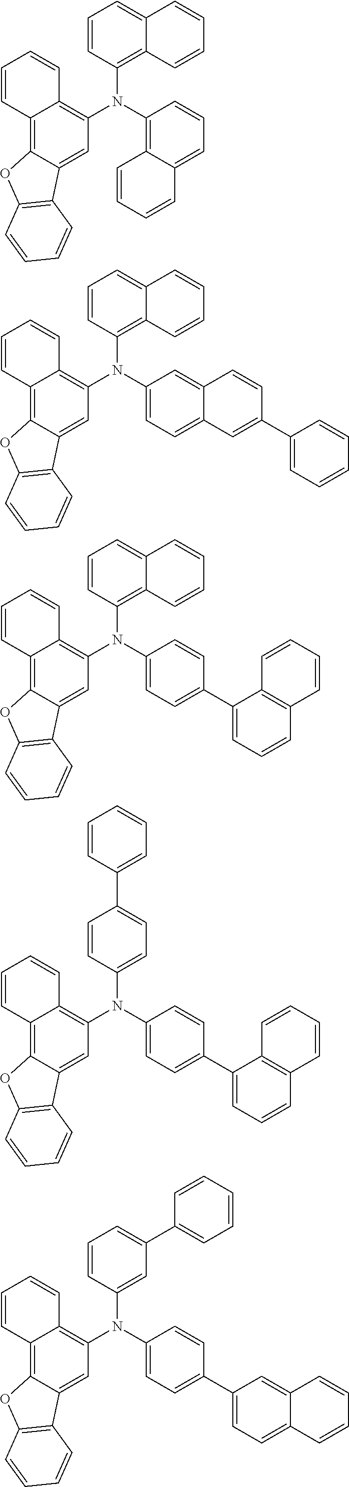

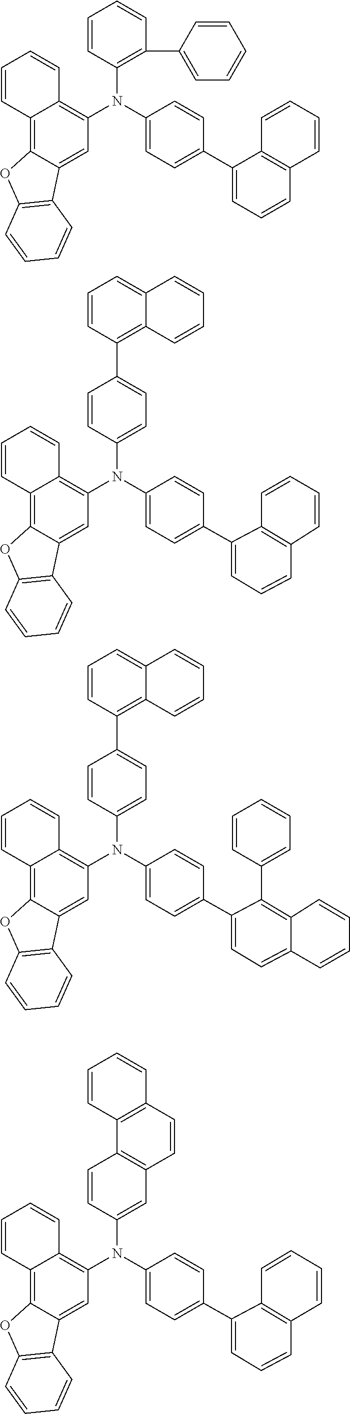

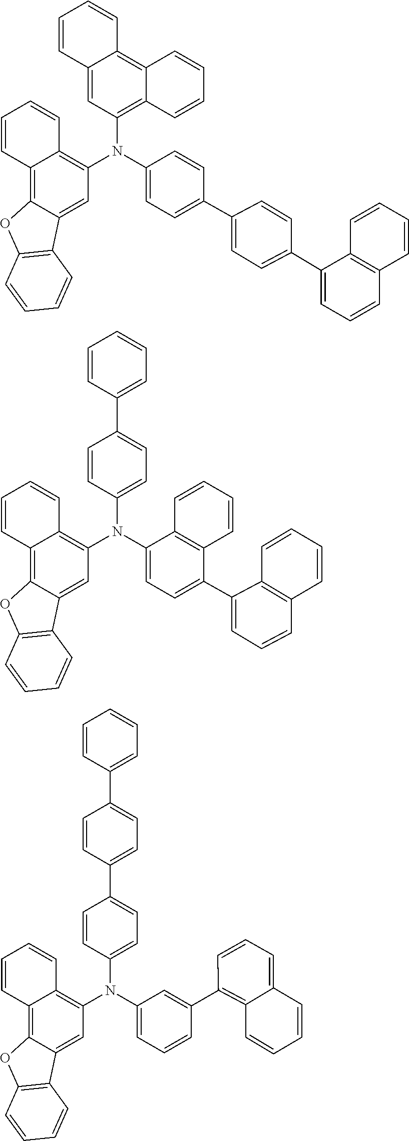

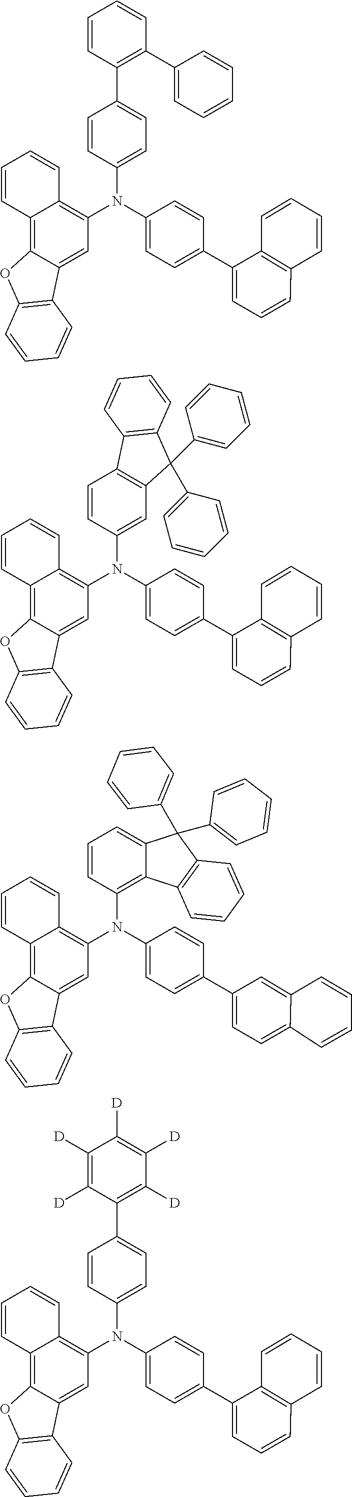 [SMILES: c1ccc(-c2ccccc2-c2ccc(N(c3ccc(-c4cccc5ccccc45)cc3)c3cc4c5ccccc5oc4c4ccccc34)cc2)cc1 ; c1ccc(C2(c3ccccc3)c3ccccc3-c3ccc(N(c4ccc(-c5cccc6ccccc56)cc4)c4cc5c6ccccc6oc5c5ccccc45)cc32)cc1 ; c1ccc(C2(c3ccccc3)c3ccccc3-c3c(N(c4ccc(-c5ccc6ccccc6c5)cc4)c4cc5c6ccccc6oc5c5ccccc45)cccc32)cc1 ; [2H]c1c([2H])c([2H])c(-c2ccc(N(c3ccc(-c4cccc5ccccc45)cc3)c3cc4c5ccccc5oc4c4ccccc34)cc2)c([2H])c1[2H]]

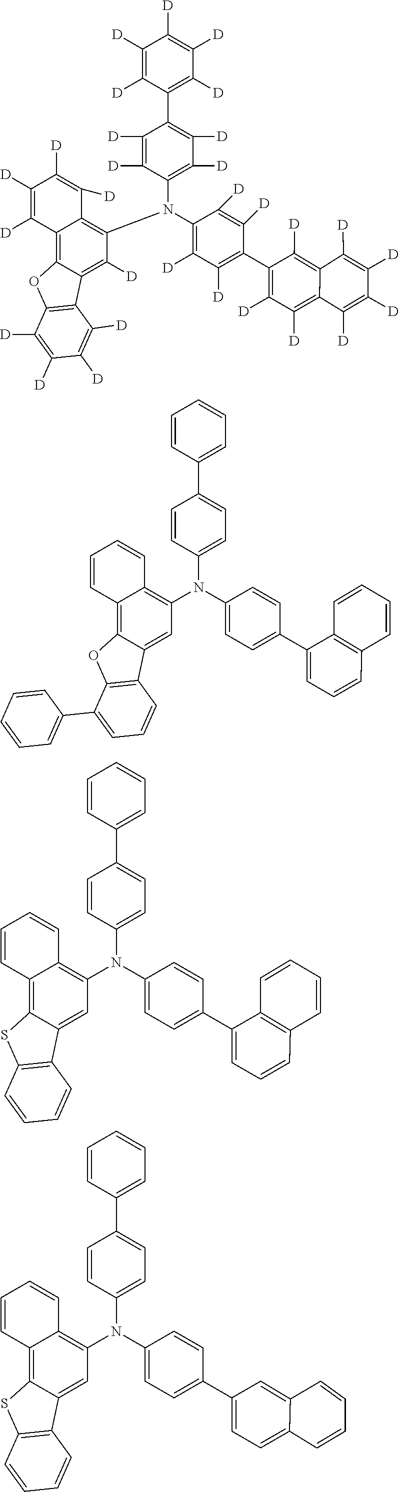

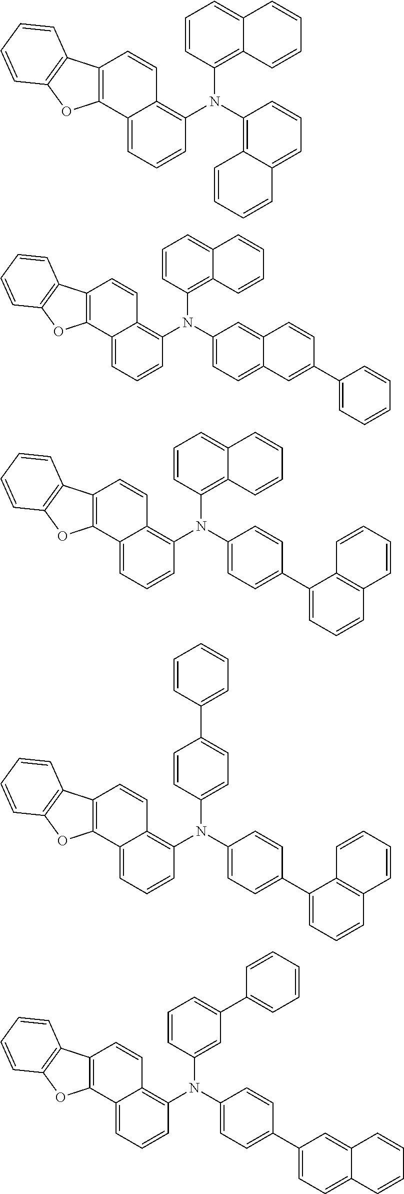

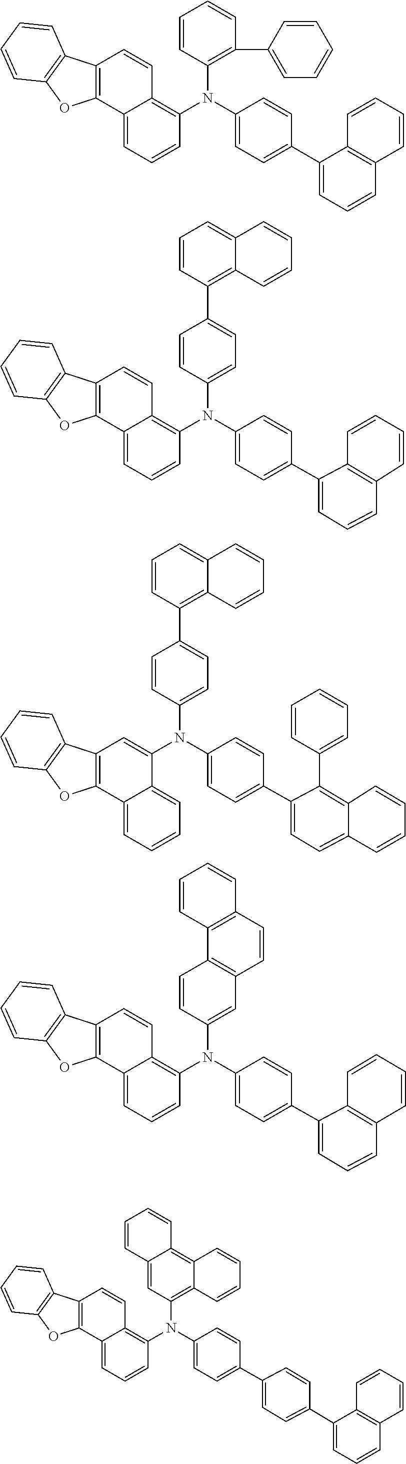

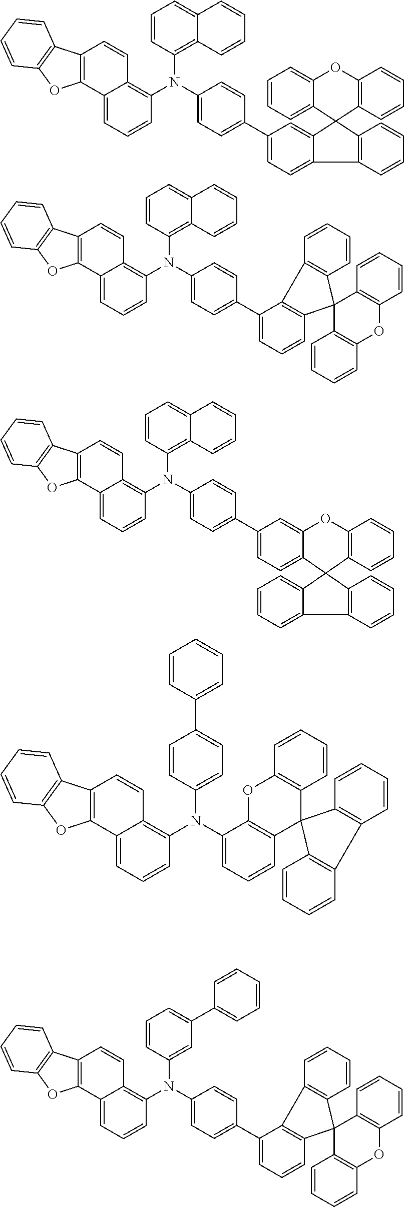 [SMILES: c1ccc2c(c1)Oc1ccccc1C21c2ccccc2-c2ccc(-c3ccc(N(c4cccc5ccccc45)c4cccc5c4ccc4c6ccccc6oc54)cc3)cc21 ; c1ccc2c(c1)Oc1ccccc1C21c2ccccc2-c2c(-c3ccc(N(c4cccc5ccccc45)c4cccc5c4ccc4c6ccccc6oc54)cc3)cccc21 ; c1ccc2c(c1)Oc1cc(-c3ccc(N(c4cccc5ccccc45)c4cccc5c4ccc4c6ccccc6oc54)cc3)ccc1C21c2ccccc2-c2ccccc21 ; c1ccc(-c2ccc(N(c3cccc4c3Oc3ccccc3C43c4ccccc4-c4ccccc43)c3cccc4c3ccc3c5ccccc5oc43)cc2)cc1 ; c1ccc(-c2cccc(N(c3ccc(-c4cccc5c4-c4ccccc4C54c5ccccc5Oc5ccccc54)cc3)c3cccc4c3ccc3c5ccccc5oc43)c2)cc1]

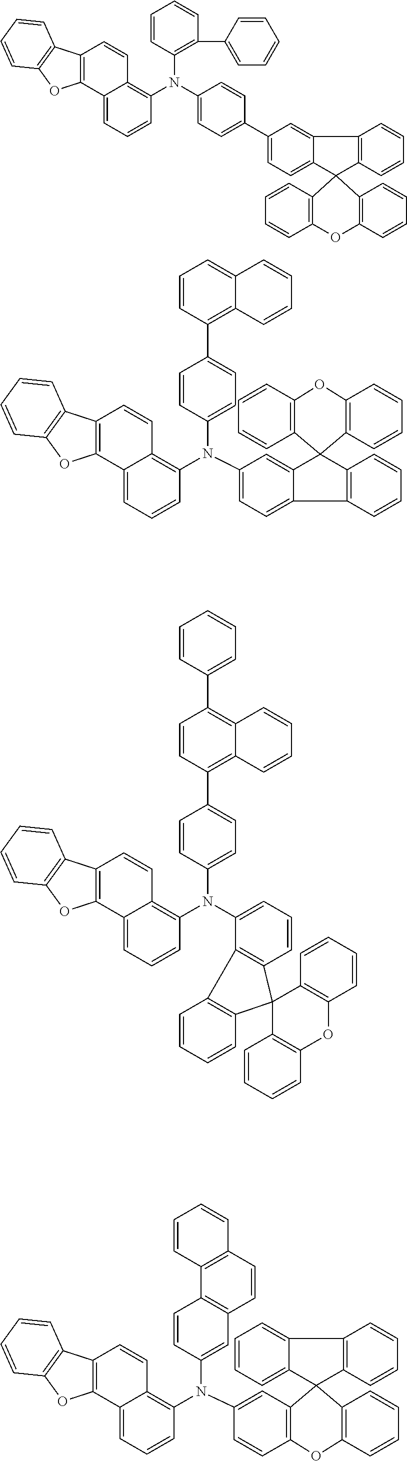

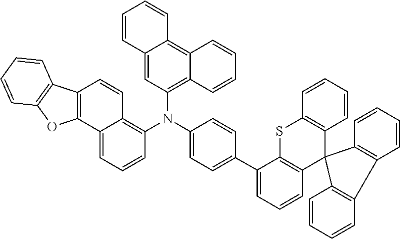 [SMILES: c1ccc2c(c1)Sc1c(-c3ccc(N(c4cc5ccccc5c5ccccc45)c4cccc5c4ccc4c6ccccc6oc54)cc3)cccc1C21c2ccccc2-c2ccccc21]

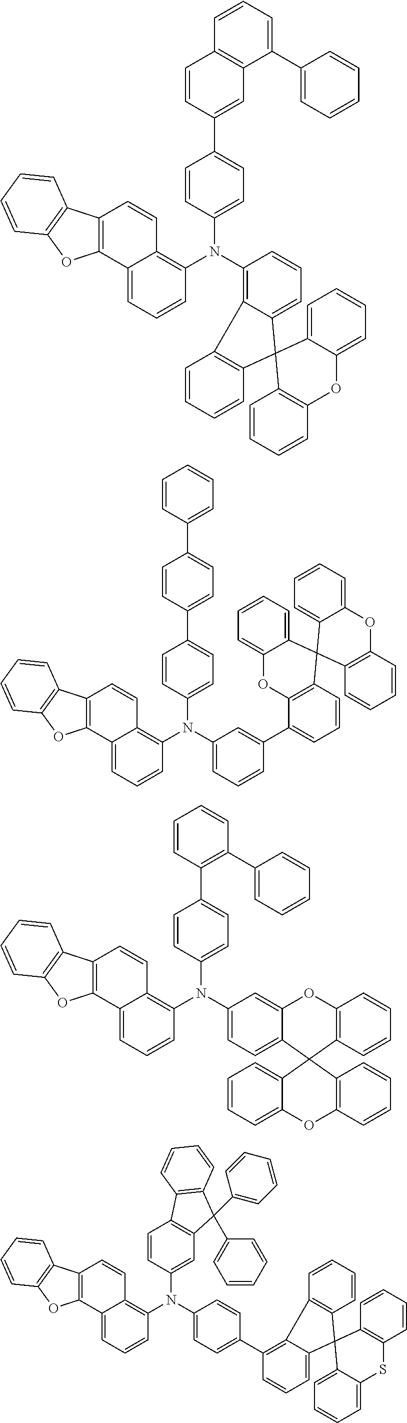

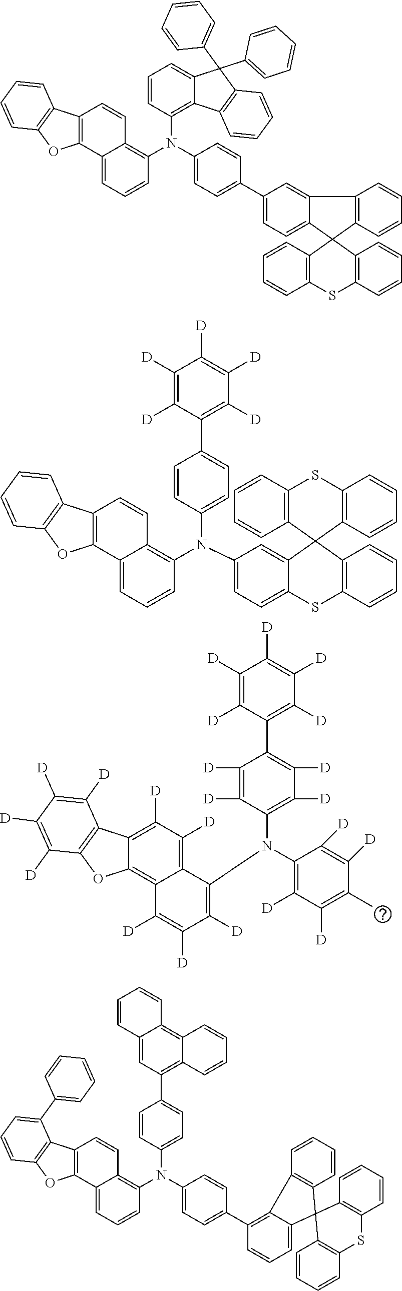

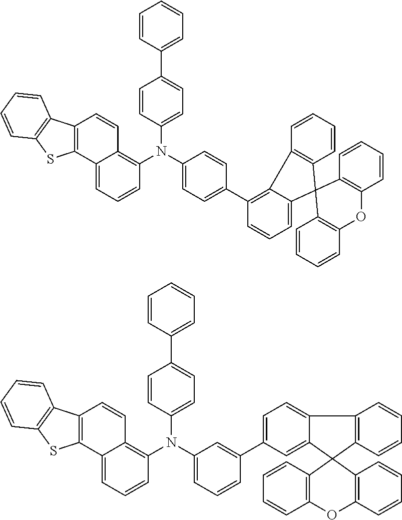 [SMILES: c1ccc(-c2ccc(N(c3ccc(-c4cccc5c4-c4ccccc4C54c5ccccc5Oc5ccccc54)cc3)c3cccc4c3ccc3c5ccccc5sc43)cc2)cc1 ; c1ccc(-c2ccc(N(c3cccc(-c4ccc5c(c4)C4(c6ccccc6Oc6ccccc64)c4ccccc4-5)c3)c3cccc4c3ccc3c5ccccc5sc43)cc2)cc1]

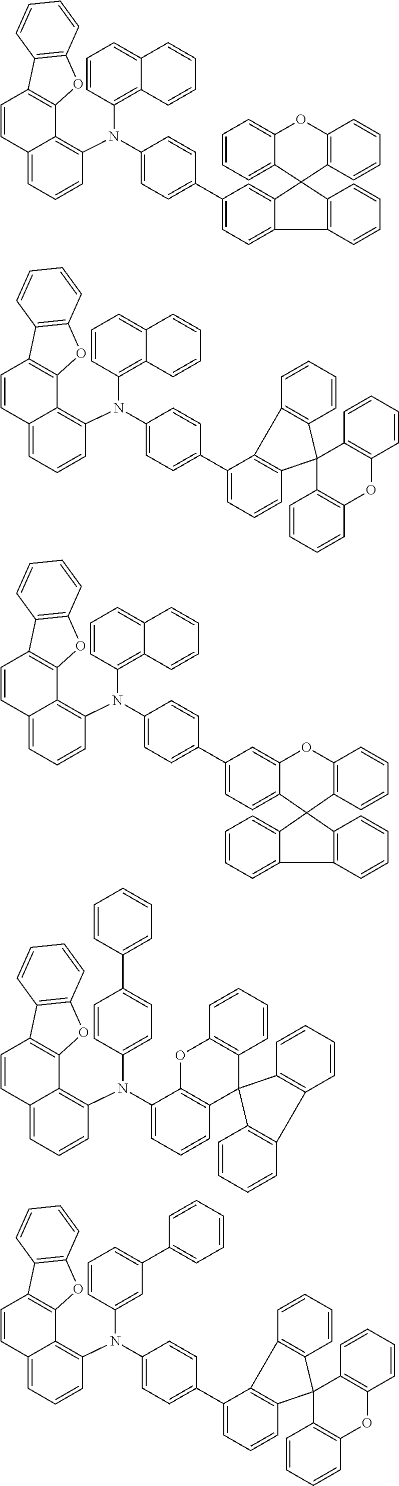

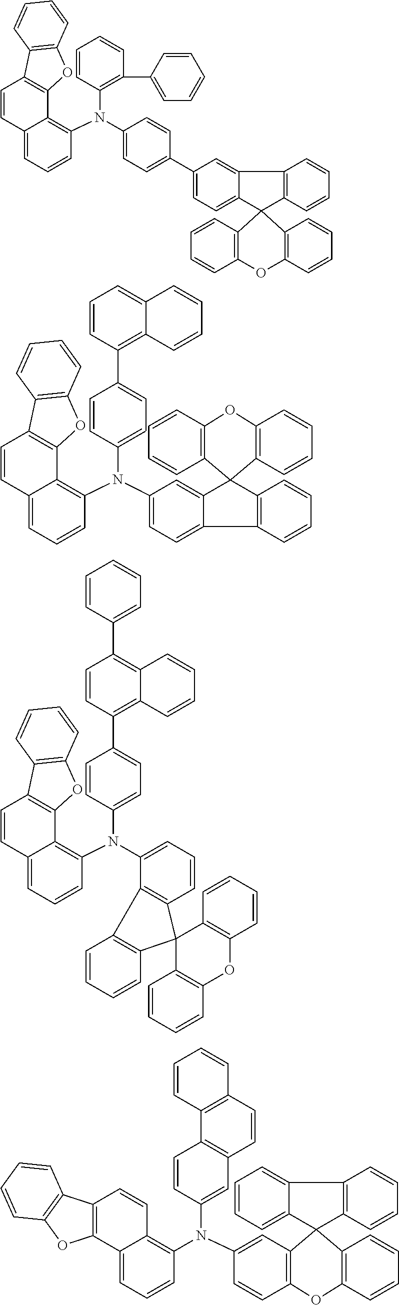

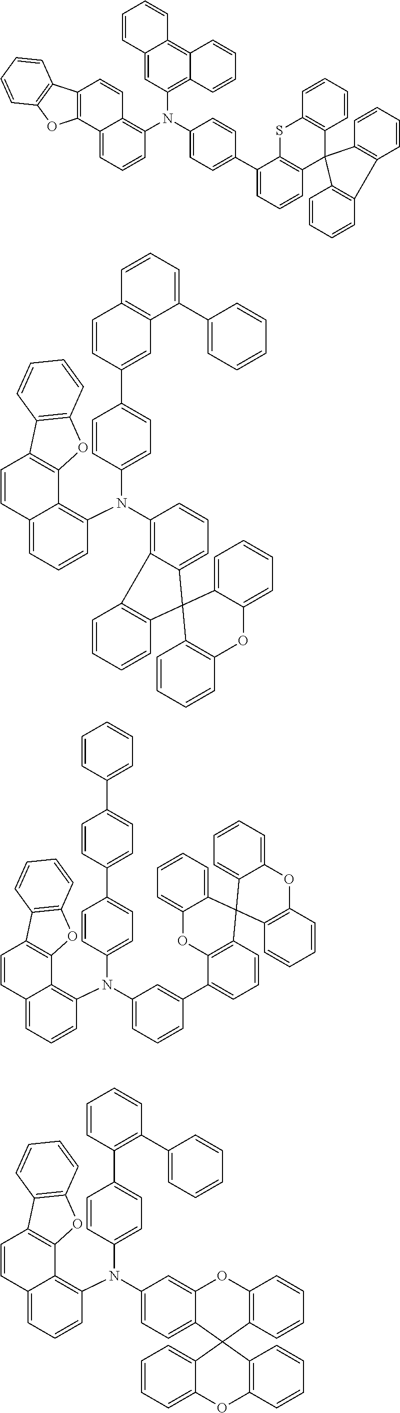 [SMILES: c1ccc2c(c1)Sc1c(-c3ccc(N(c4cc5ccccc5c5ccccc45)c4cccc5c4ccc4c6ccccc6oc54)cc3)cccc1C21c2ccccc2-c2ccccc21 ; c1ccc(-c2cccc3ccc(-c4ccc(N(c5cccc6c5-c5ccccc5C65c6ccccc6Oc6ccccc65)c5cccc6ccc7c8ccccc8oc7c56)cc4)cc23)cc1 ; c1ccc(-c2ccc(-c3ccc(N(c4cccc(-c5cccc6c5Oc5ccccc5C65c6ccccc6Oc6ccccc65)c4)c4cccc5ccc6c7ccccc7oc6c45)cc3)cc2)cc1 ; c1ccc(-c2ccccc2-c2ccc(N(c3ccc4c(c3)Oc3ccccc3C43c4ccccc4Oc4ccccc43)c3cccc4ccc5c6ccccc6oc5c34)cc2)cc1]

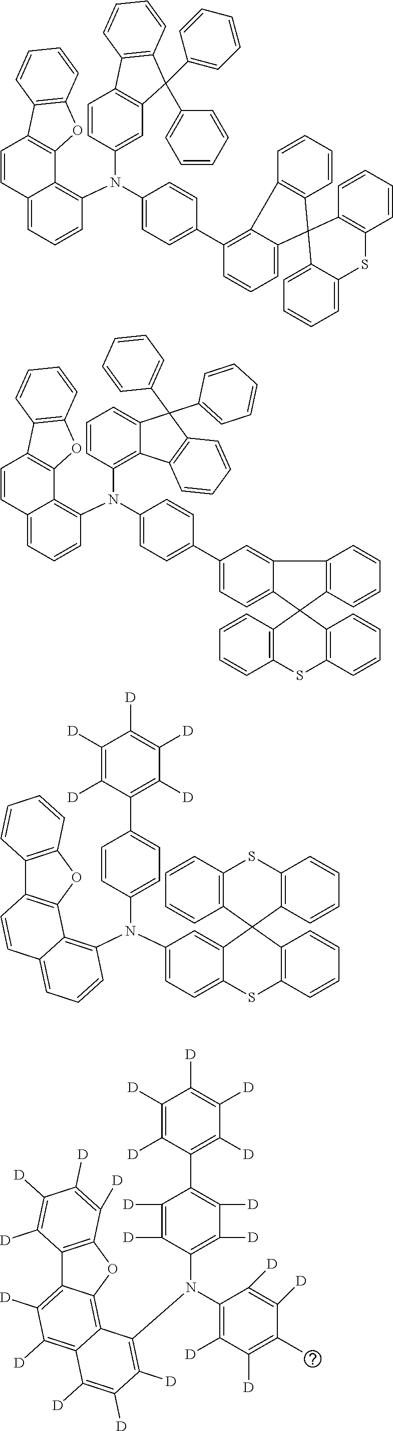

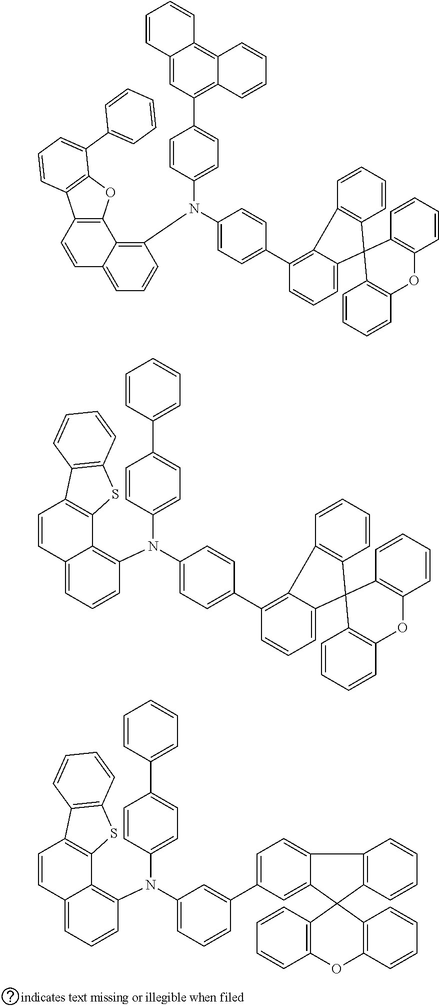 [SMILES: c1ccc(-c2cccc3c2oc2c3ccc3cccc(N(c4ccc(-c5cccc6c5-c5ccccc5C65c6ccccc6Oc6ccccc65)cc4)c4ccc(-c5cc6ccccc6c6ccccc56)cc4)c32)cc1 ; c1ccc(-c2ccc(N(c3ccc(-c4cccc5c4-c4ccccc4C54c5ccccc5Oc5ccccc54)cc3)c3cccc4ccc5c6ccccc6sc5c34)cc2)cc1 ; c1ccc(-c2ccc(N(c3cccc(-c4ccc5c(c4)C4(c6ccccc6Oc6ccccc64)c4ccccc4-5)c3)c3cccc4ccc5c6ccccc6sc5c34)cc2)cc1]

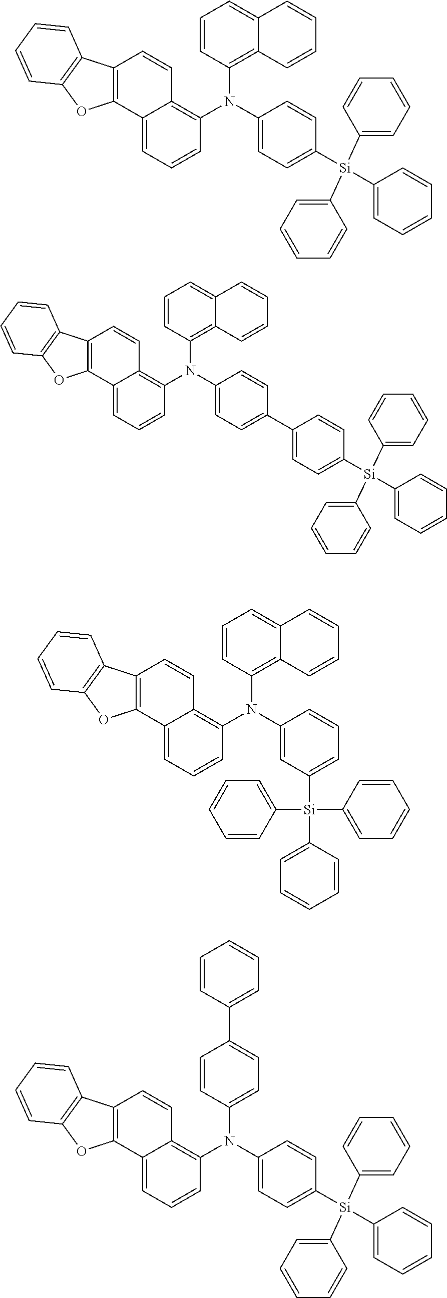 [SMILES: c1ccc([Si](c2ccccc2)(c2ccccc2)c2ccc(N(c3cccc4ccccc34)c3cccc4c3ccc3c5ccccc5oc43)cc2)cc1 ; c1ccc([Si](c2ccccc2)(c2ccccc2)c2ccc(-c3ccc(N(c4cccc5ccccc45)c4cccc5c4ccc4c6ccccc6oc54)cc3)cc2)cc1 ; c1ccc([Si](c2ccccc2)(c2ccccc2)c2cccc(N(c3cccc4ccccc34)c3cccc4c3ccc3c5ccccc5oc43)c2)cc1 ; c1ccc(-c2ccc(N(c3ccc([Si](c4ccccc4)(c4ccccc4)c4ccccc4)cc3)c3cccc4c3ccc3c5ccccc5oc43)cc2)cc1]

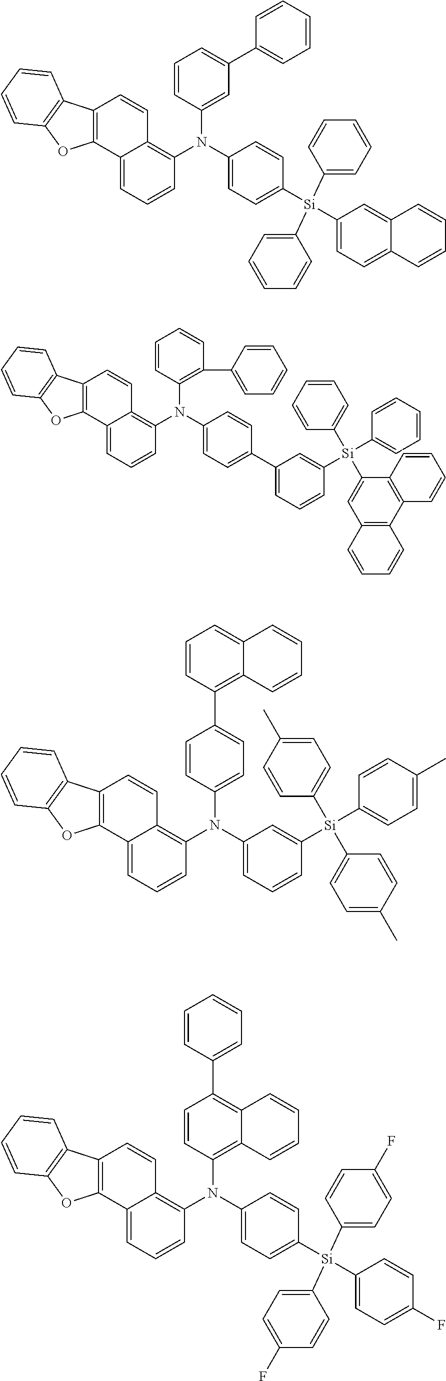 [SMILES: c1ccc(-c2cccc(N(c3ccc([Si](c4ccccc4)(c4ccccc4)c4ccc5ccccc5c4)cc3)c3cccc4c3ccc3c5ccccc5oc43)c2)cc1 ; c1ccc(-c2ccccc2N(c2ccc(-c3cccc([Si](c4ccccc4)(c4ccccc4)c4cc5ccccc5c5ccccc45)c3)cc2)c2cccc3c2ccc2c4ccccc4oc32)cc1 ; Cc1ccc([Si](c2ccc(C)cc2)(c2ccc(C)cc2)c2cccc(N(c3ccc(-c4cccc5ccccc45)cc3)c3cccc4c3ccc3c5ccccc5oc43)c2)cc1 ; Fc1ccc([Si](c2ccc(F)cc2)(c2ccc(F)cc2)c2ccc(N(c3ccc(-c4ccccc4)c4ccccc34)c3cccc4c3ccc3c5ccccc5oc43)cc2)cc1]

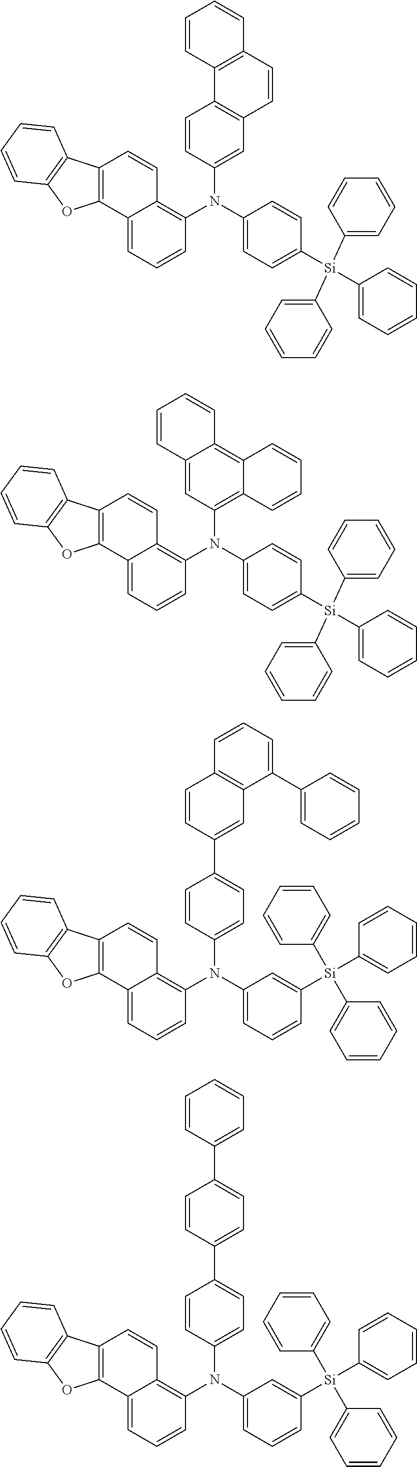

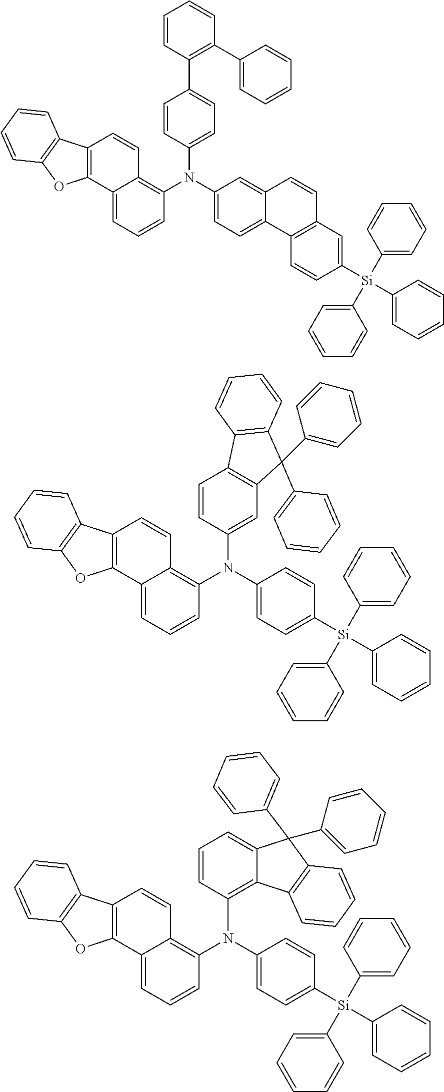

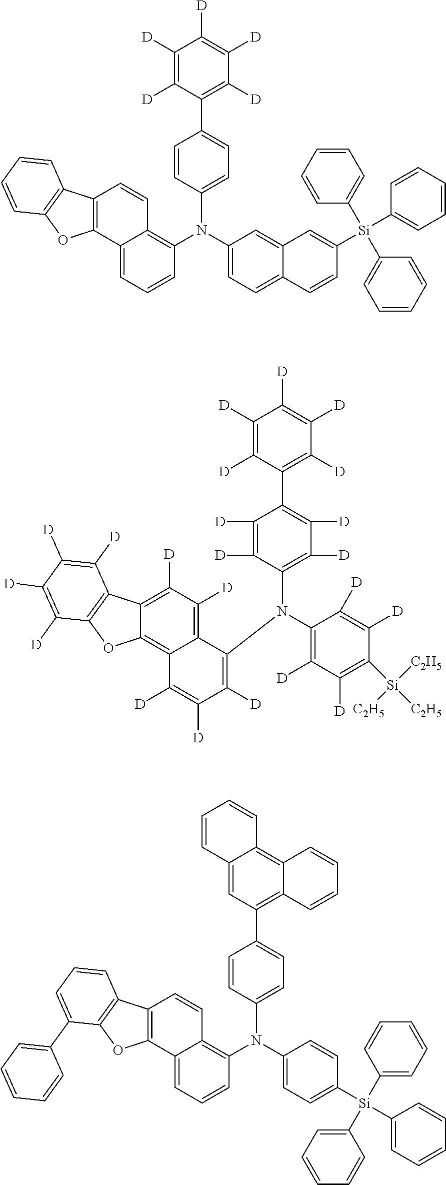 [SMILES: [2H]c1c([2H])c([2H])c(-c2ccc(N(c3ccc4ccc([Si](c5ccccc5)(c5ccccc5)c5ccccc5)cc4c3)c3cccc4c3ccc3c5ccccc5oc43)cc2)c([2H])c1[2H] ; [2H]c1c([2H])c([2H])c(-c2c([2H])c([2H])c(N(c3c([2H])c([2H])c([Si](CC)(CC)CC)c([2H])c3[2H])c3c([2H])c([2H])c([2H])c4c3c([2H])c([2H])c3c4oc4c([2H])c([2H])c([2H])c([2H])c43)c([2H])c2[2H])c([2H])c1[2H] ; c1ccc(-c2cccc3c2oc2c4cccc(N(c5ccc(-c6cc7ccccc7c7ccccc67)cc5)c5ccc([Si](c6ccccc6)(c6ccccc6)c6ccccc6)cc5)c4ccc32)cc1]

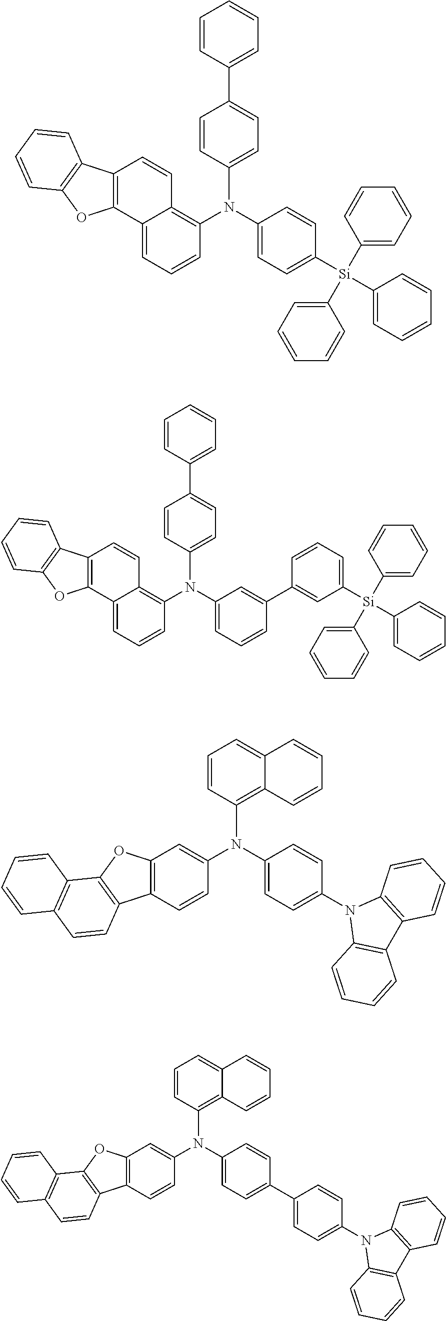 [SMILES: c1ccc(-c2ccc(N(c3ccc([Si](c4ccccc4)(c4ccccc4)c4ccccc4)cc3)c3cccc4c3ccc3c5ccccc5oc43)cc2)cc1 ; c1ccc(-c2ccc(N(c3cccc(-c4cccc([Si](c5ccccc5)(c5ccccc5)c5ccccc5)c4)c3)c3cccc4c3ccc3c5ccccc5oc43)cc2)cc1 ; c1ccc2c(N(c3ccc(-n4c5ccccc5c5ccccc54)cc3)c3ccc4c(c3)oc3c5ccccc5ccc43)cccc2c1 ; c1ccc2c(N(c3ccc(-c4ccc(-n5c6ccccc6c6ccccc65)cc4)cc3)c3ccc4c(c3)oc3c5ccccc5ccc43)cccc2c1]

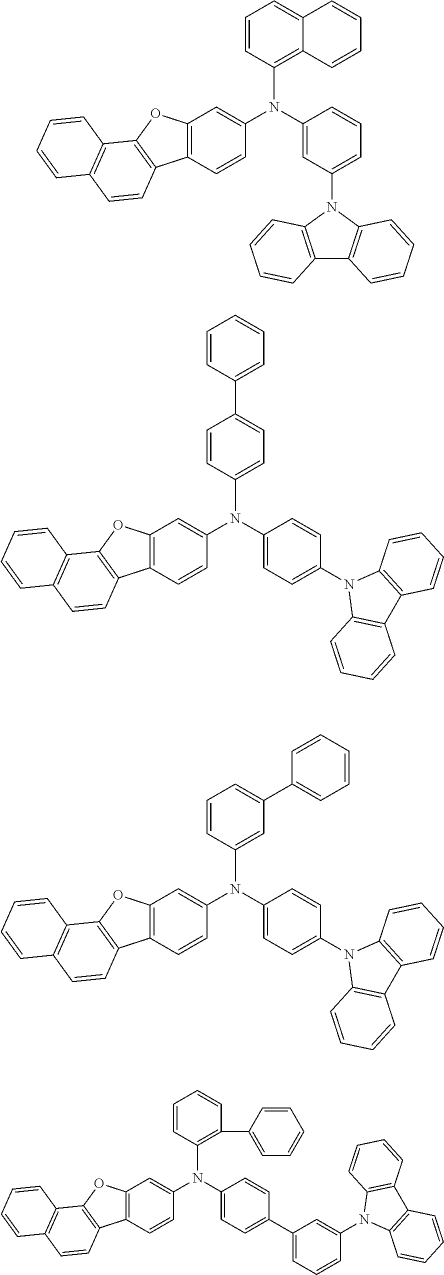 [SMILES: c1cc(N(c2ccc3c(c2)oc2c4ccccc4ccc32)c2cccc3ccccc23)cc(-n2c3ccccc3c3ccccc32)c1 ; c1ccc(-c2ccc(N(c3ccc(-n4c5ccccc5c5ccccc54)cc3)c3ccc4c(c3)oc3c5ccccc5ccc43)cc2)cc1 ; c1ccc(-c2cccc(N(c3ccc(-n4c5ccccc5c5ccccc54)cc3)c3ccc4c(c3)oc3c5ccccc5ccc43)c2)cc1 ; c1ccc(-c2ccccc2N(c2ccc(-c3cccc(-n4c5ccccc5c5ccccc54)c3)cc2)c2ccc3c(c2)oc2c4ccccc4ccc32)cc1]

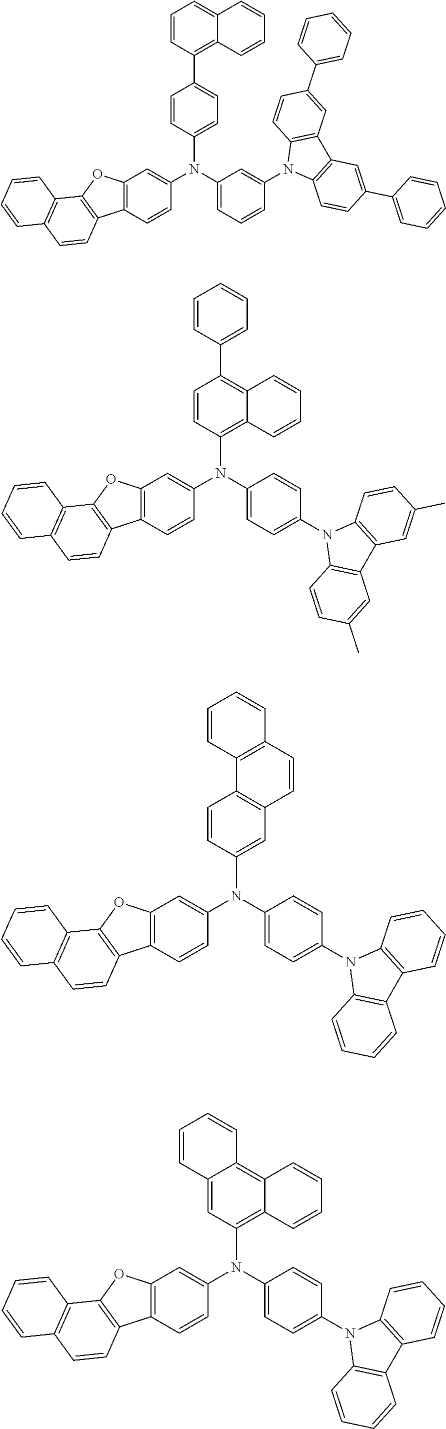 [SMILES: c1ccc(-c2ccc3c(c2)c2cc(-c4ccccc4)ccc2n3-c2cccc(N(c3ccc(-c4cccc5ccccc45)cc3)c3ccc4c(c3)oc3c5ccccc5ccc43)c2)cc1 ; Cc1ccc2c(c1)c1cc(C)ccc1n2-c1ccc(N(c2ccc3c(c2)oc2c4ccccc4ccc32)c2ccc(-c3ccccc3)c3ccccc23)cc1 ; c1ccc2c(c1)ccc1cc(N(c3ccc(-n4c5ccccc5c5ccccc54)cc3)c3ccc4c(c3)oc3c5ccccc5ccc43)ccc12 ; c1ccc2c(c1)cc(N(c1ccc(-n3c4ccccc4c4ccccc43)cc1)c1ccc3c(c1)oc1c4ccccc4ccc31)c1ccccc12]

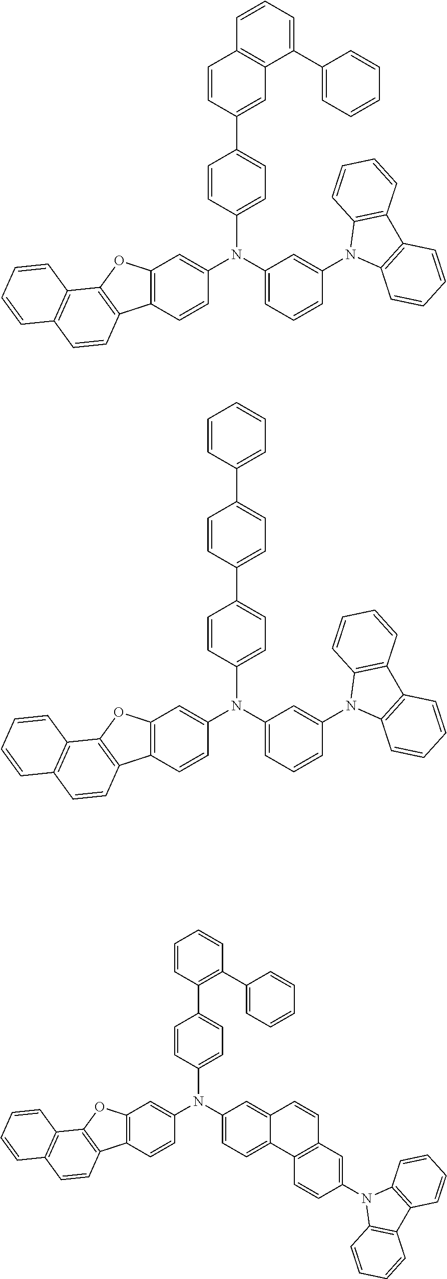 [SMILES: c1ccc(-c2cccc3ccc(-c4ccc(N(c5cccc(-n6c7ccccc7c7ccccc76)c5)c5ccc6c(c5)oc5c7ccccc7ccc65)cc4)cc23)cc1 ; c1ccc(-c2ccc(-c3ccc(N(c4cccc(-n5c6ccccc6c6ccccc65)c4)c4ccc5c(c4)oc4c6ccccc6ccc54)cc3)cc2)cc1 ; c1ccc(-c2ccccc2-c2ccc(N(c3ccc4c(ccc5cc(-n6c7ccccc7c7ccccc76)ccc54)c3)c3ccc4c(c3)oc3c5ccccc5ccc43)cc2)cc1]

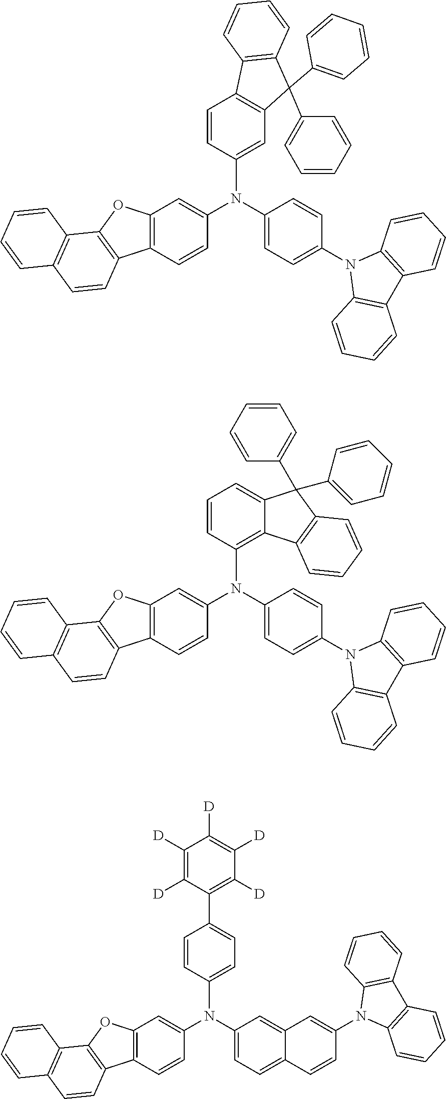 [SMILES: c1ccc(C2(c3ccccc3)c3ccccc3-c3ccc(N(c4ccc(-n5c6ccccc6c6ccccc65)cc4)c4ccc5c(c4)oc4c6ccccc6ccc54)cc32)cc1 ; c1ccc(C2(c3ccccc3)c3ccccc3-c3c(N(c4ccc(-n5c6ccccc6c6ccccc65)cc4)c4ccc5c(c4)oc4c6ccccc6ccc54)cccc32)cc1 ; [2H]c1c([2H])c([2H])c(-c2ccc(N(c3ccc4ccc(-n5c6ccccc6c6ccccc65)cc4c3)c3ccc4c(c3)oc3c5ccccc5ccc43)cc2)c([2H])c1[2H]]

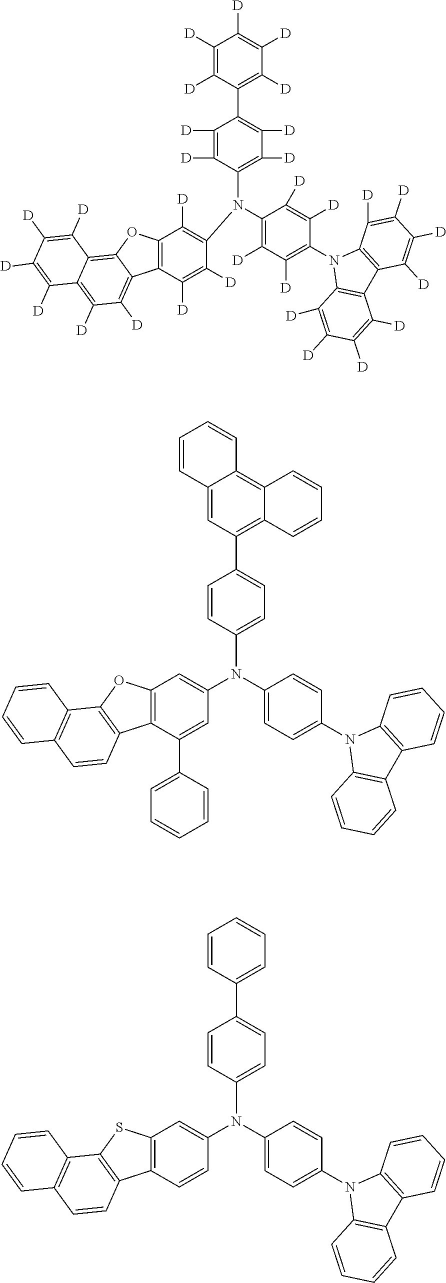 [SMILES: [2H]c1c([2H])c([2H])c(-c2c([2H])c([2H])c(N(c3c([2H])c([2H])c(-n4c5c([2H])c([2H])c([2H])c([2H])c5c5c([2H])c([2H])c([2H])c([2H])c54)c([2H])c3[2H])c3c([2H])c([2H])c4c(oc5c6c([2H])c([2H])c([2H])c([2H])c6c([2H])c([2H])c54)c3[2H])c([2H])c2[2H])c([2H])c1[2H] ; c1ccc(-c2cc(N(c3ccc(-c4cc5ccccc5c5ccccc45)cc3)c3ccc(-n4c5ccccc5c5ccccc54)cc3)cc3oc4c5ccccc5ccc4c23)cc1 ; c1ccc(-c2ccc(N(c3ccc(-n4c5ccccc5c5ccccc54)cc3)c3ccc4c(c3)sc3c5ccccc5ccc43)cc2)cc1]

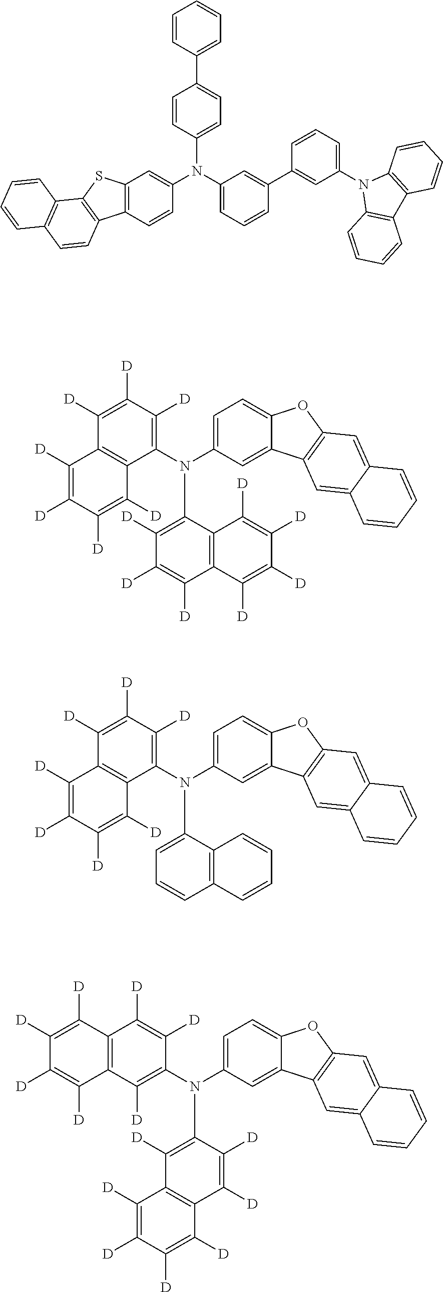 [SMILES: c1ccc(-c2ccc(N(c3cccc(-c4cccc(-n5c6ccccc6c6ccccc65)c4)c3)c3ccc4c(c3)sc3c5ccccc5ccc43)cc2)cc1 ; [2H]c1c([2H])c([2H])c2c(N(c3ccc4oc5cc6ccccc6cc5c4c3)c3c([2H])c([2H])c([2H])c4c([2H])c([2H])c([2H])c([2H])c34)c([2H])c([2H])c([2H])c2c1[2H] ; [2H]c1c([2H])c([2H])c2c(N(c3ccc4oc5cc6ccccc6cc5c4c3)c3cccc4ccccc34)c([2H])c([2H])c([2H])c2c1[2H] ; [2H]c1c([2H])c([2H])c2c([2H])c(N(c3ccc4oc5cc6ccccc6cc5c4c3)c3c([2H])c([2H])c4c([2H])c([2H])c([2H])c([2H])c4c3[2H])c([2H])c([2H])c2c1[2H]]

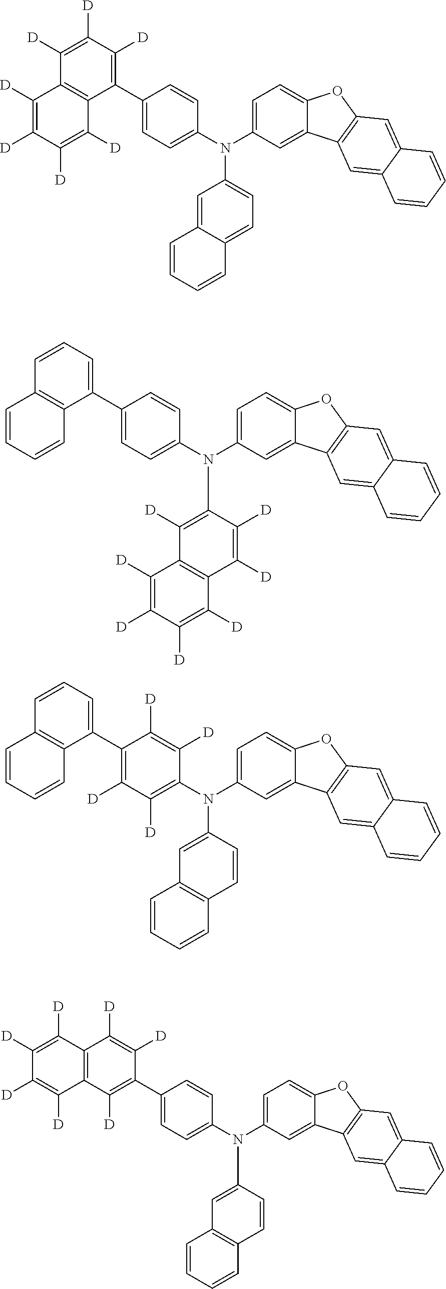 [SMILES: [2H]c1c([2H])c([2H])c2c(-c3ccc(N(c4ccc5ccccc5c4)c4ccc5oc6cc7ccccc7cc6c5c4)cc3)c([2H])c([2H])c([2H])c2c1[2H] ; [2H]c1c([2H])c([2H])c2c([2H])c(N(c3ccc(-c4cccc5ccccc45)cc3)c3ccc4oc5cc6ccccc6cc5c4c3)c([2H])c([2H])c2c1[2H] ; [2H]c1c([2H])c(N(c2ccc3ccccc3c2)c2ccc3oc4cc5ccccc5cc4c3c2)c([2H])c([2H])c1-c1cccc2ccccc12 ; [2H]c1c([2H])c([2H])c2c([2H])c(-c3ccc(N(c4ccc5ccccc5c4)c4ccc5oc6cc7ccccc7cc6c5c4)cc3)c([2H])c([2H])c2c1[2H]]

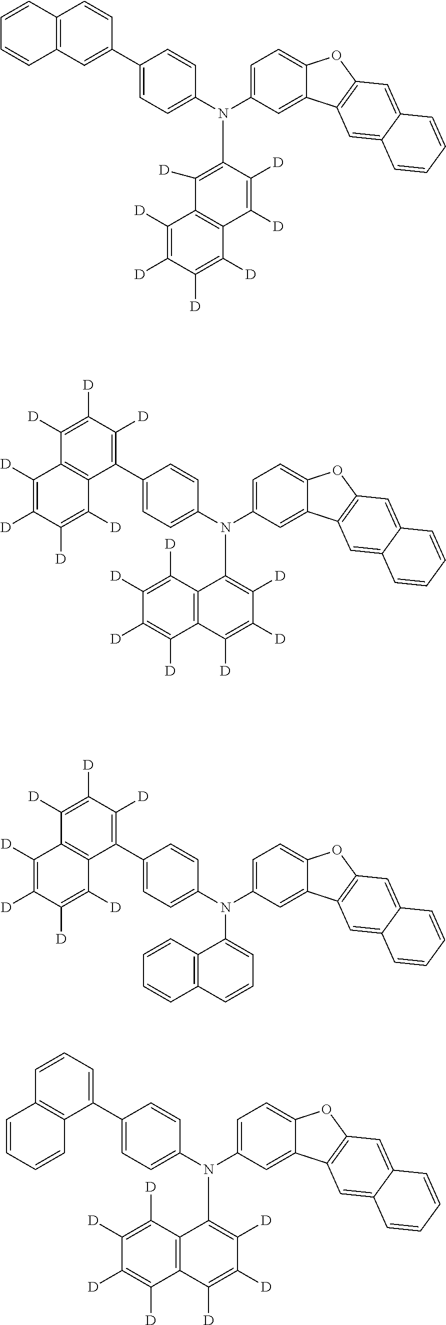 [SMILES: [2H]c1c([2H])c([2H])c2c([2H])c(N(c3ccc(-c4ccc5ccccc5c4)cc3)c3ccc4oc5cc6ccccc6cc5c4c3)c([2H])c([2H])c2c1[2H] ; [2H]c1c([2H])c([2H])c2c(-c3ccc(N(c4ccc5oc6cc7ccccc7cc6c5c4)c4c([2H])c([2H])c([2H])c5c([2H])c([2H])c([2H])c([2H])c45)cc3)c([2H])c([2H])c([2H])c2c1[2H] ; [2H]c1c([2H])c([2H])c2c(-c3ccc(N(c4ccc5oc6cc7ccccc7cc6c5c4)c4cccc5ccccc45)cc3)c([2H])c([2H])c([2H])c2c1[2H] ; [2H]c1c([2H])c([2H])c2c(N(c3ccc(-c4cccc5ccccc45)cc3)c3ccc4oc5cc6ccccc6cc5c4c3)c([2H])c([2H])c([2H])c2c1[2H]]

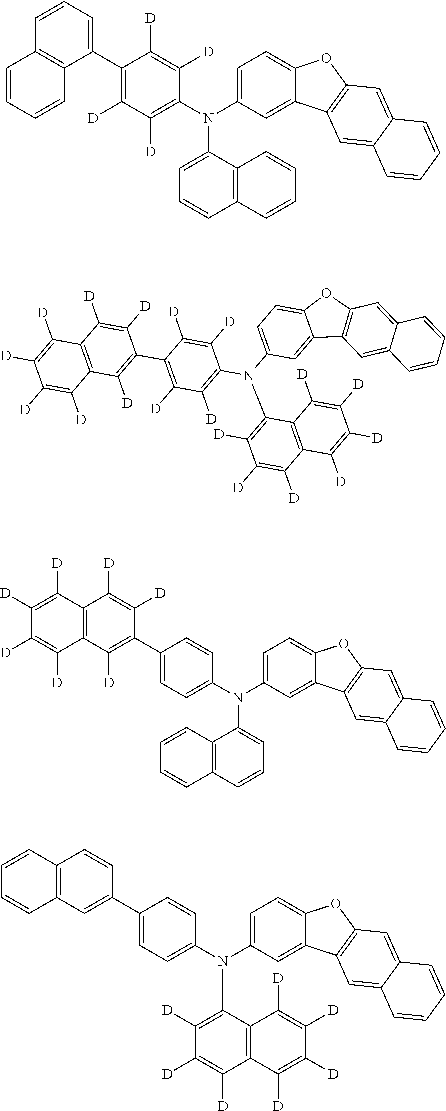 [SMILES: [2H]c1c([2H])c(N(c2ccc3oc4cc5ccccc5cc4c3c2)c2cccc3ccccc23)c([2H])c([2H])c1-c1cccc2ccccc12 ; [2H]c1c([2H])c(N(c2ccc3oc4cc5ccccc5cc4c3c2)c2c([2H])c([2H])c([2H])c3c([2H])c([2H])c([2H])c([2H])c23)c([2H])c([2H])c1-c1c([2H])c([2H])c2c([2H])c([2H])c([2H])c([2H])c2c1[2H] ; [2H]c1c([2H])c([2H])c2c([2H])c(-c3ccc(N(c4ccc5oc6cc7ccccc7cc6c5c4)c4cccc5ccccc45)cc3)c([2H])c([2H])c2c1[2H] ; [2H]c1c([2H])c([2H])c2c(N(c3ccc(-c4ccc5ccccc5c4)cc3)c3ccc4oc5cc6ccccc6cc5c4c3)c([2H])c([2H])c([2H])c2c1[2H]]

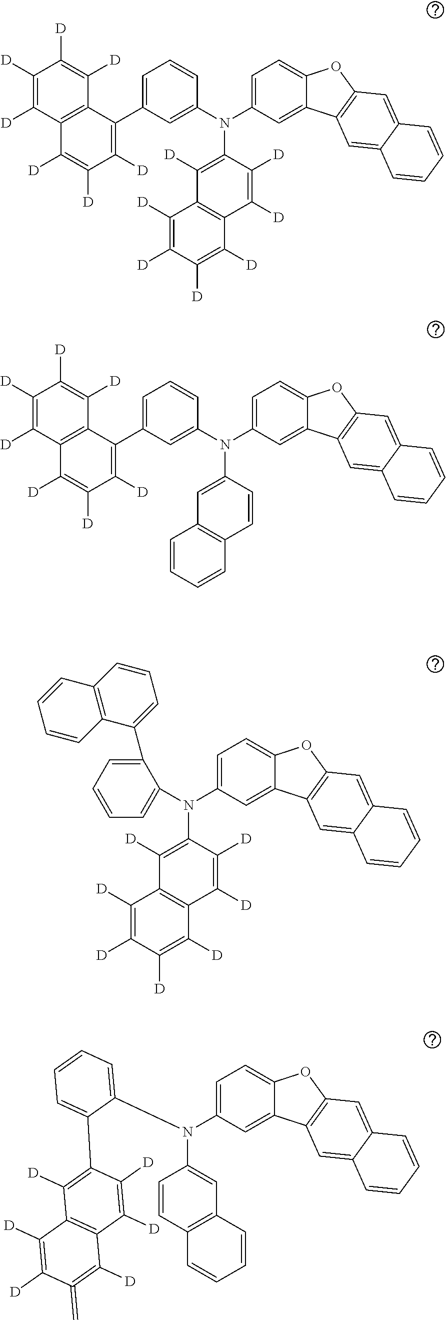

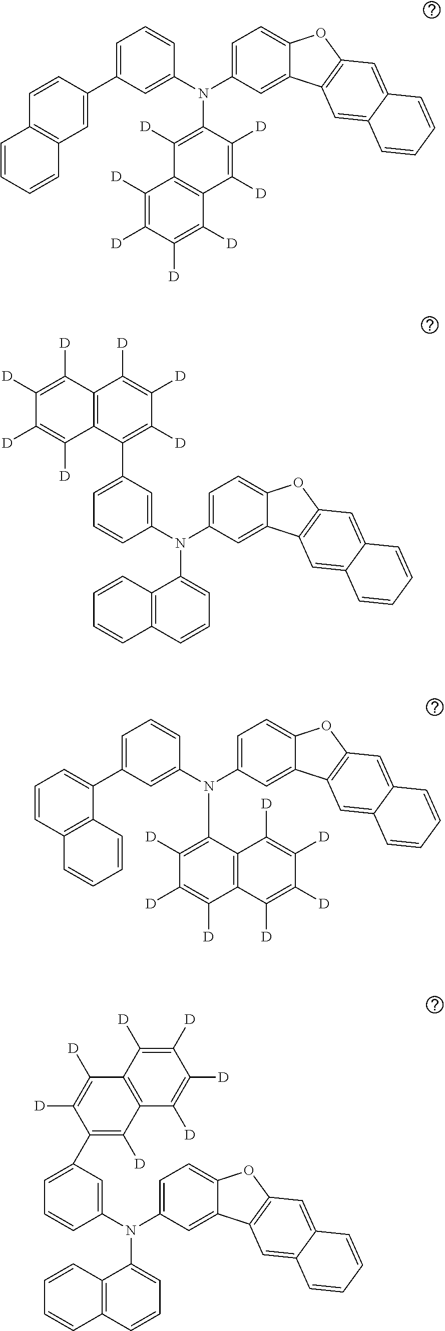 [SMILES: [2H]c1c([2H])c([2H])c2c([2H])c(N(c3cccc(-c4ccc5ccccc5c4)c3)c3ccc4oc5cc6ccccc6cc5c4c3)c([2H])c([2H])c2c1[2H] ; [2H]c1c([2H])c([2H])c2c(-c3cccc(N(c4ccc5oc6cc7ccccc7cc6c5c4)c4cccc5ccccc45)c3)c([2H])c([2H])c([2H])c2c1[2H] ; [2H]c1c([2H])c([2H])c2c(N(c3cccc(-c4cccc5ccccc45)c3)c3ccc4oc5cc6ccccc6cc5c4c3)c([2H])c([2H])c([2H])c2c1[2H] ; [2H]c1c([2H])c([2H])c2c([2H])c(-c3cccc(N(c4ccc5oc6cc7ccccc7cc6c5c4)c4cccc5ccccc45)c3)c([2H])c([2H])c2c1[2H]]

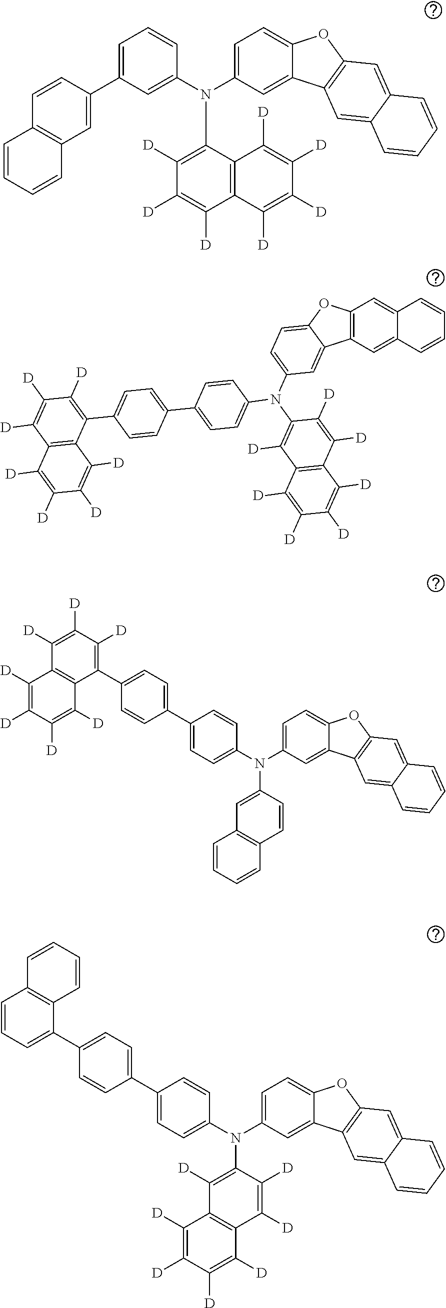

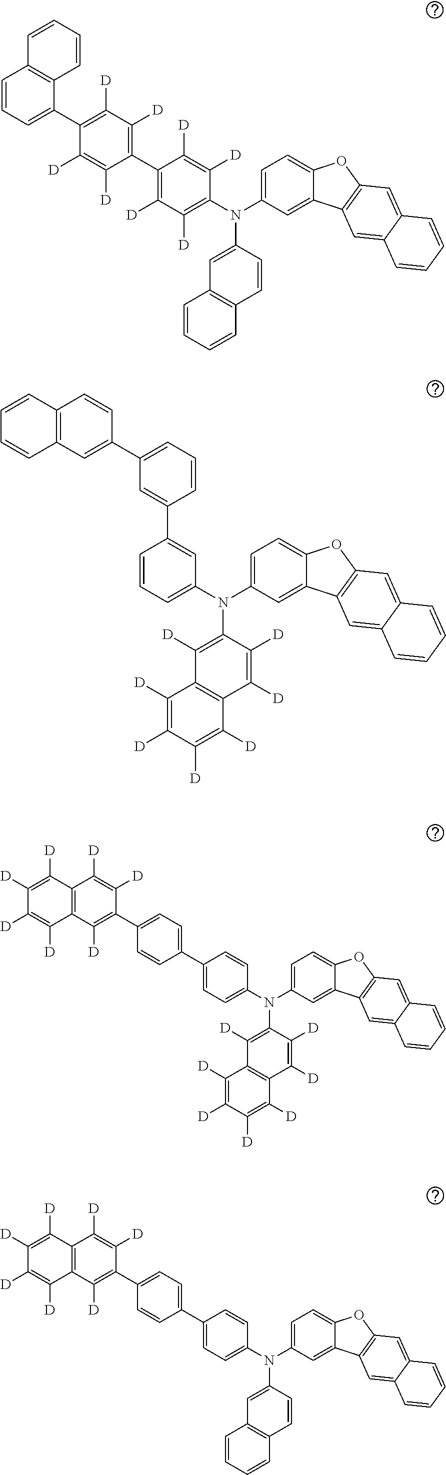

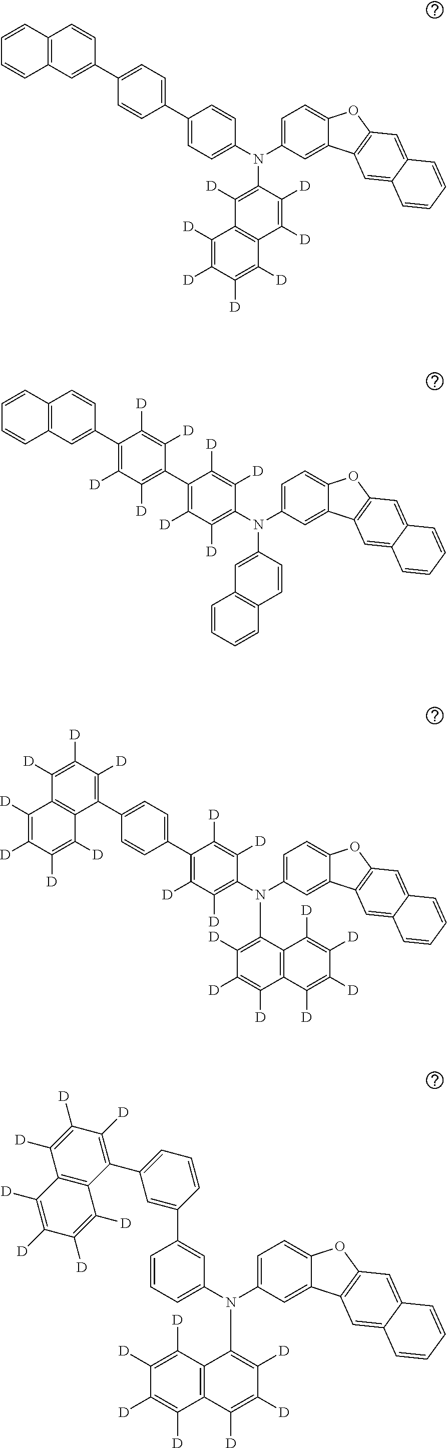

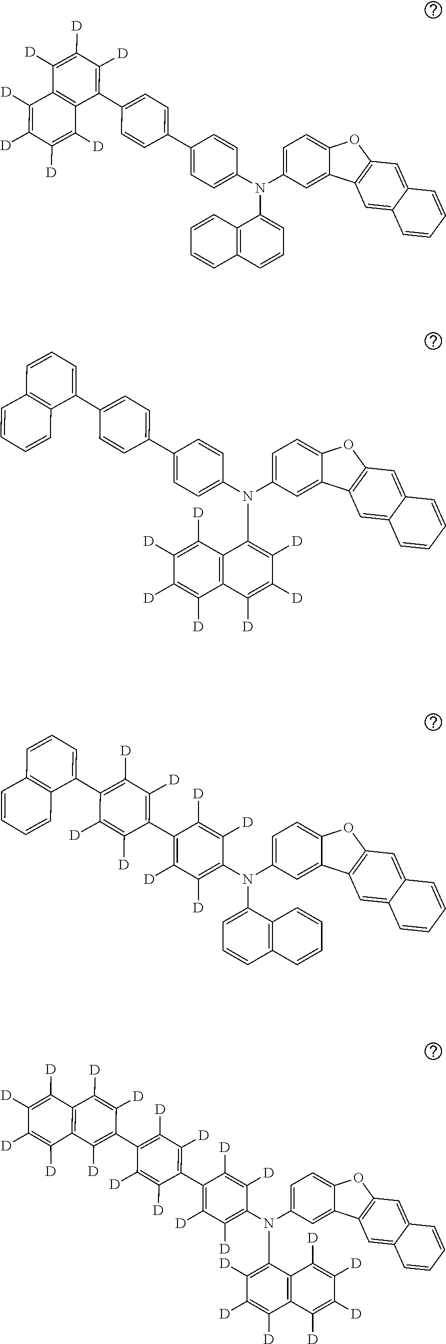

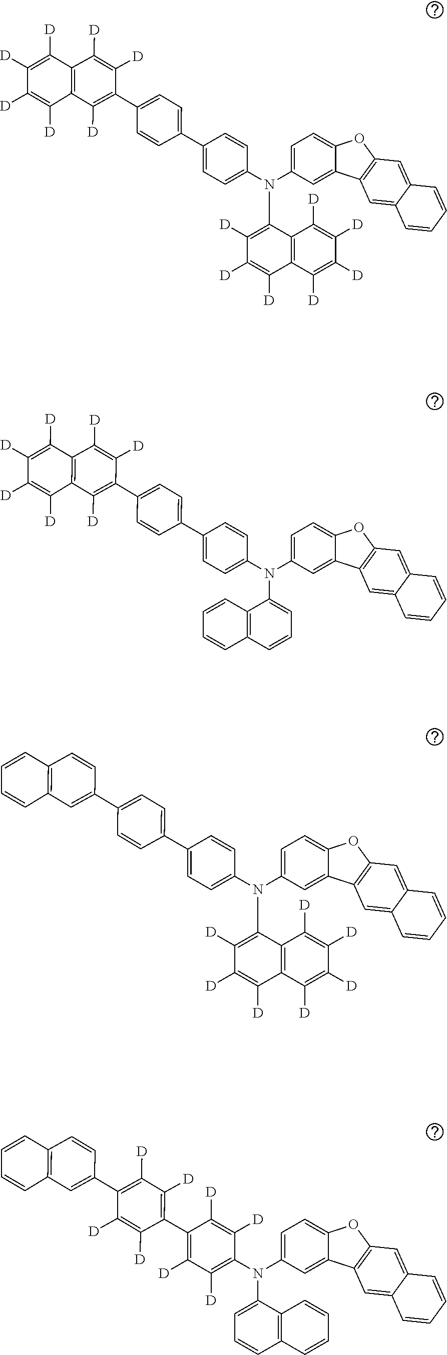

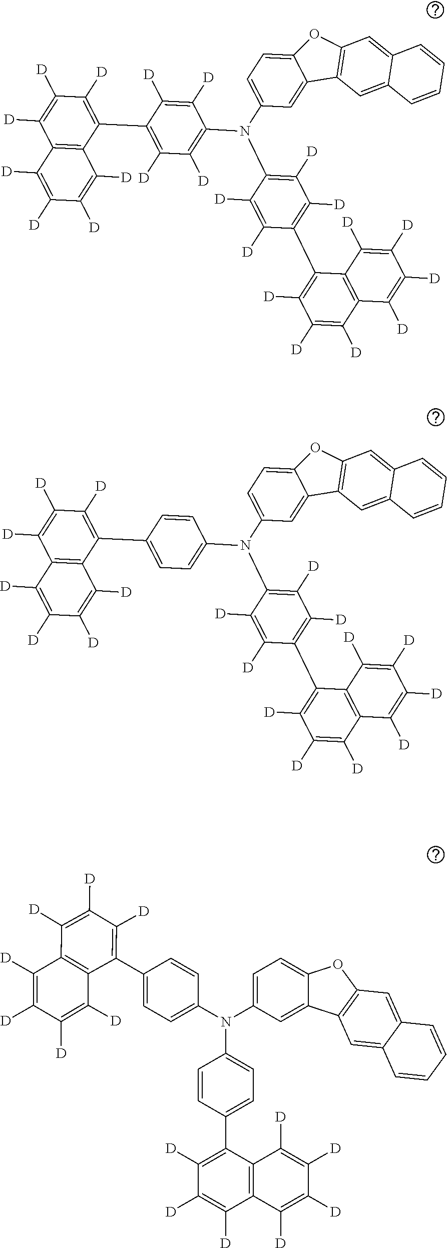

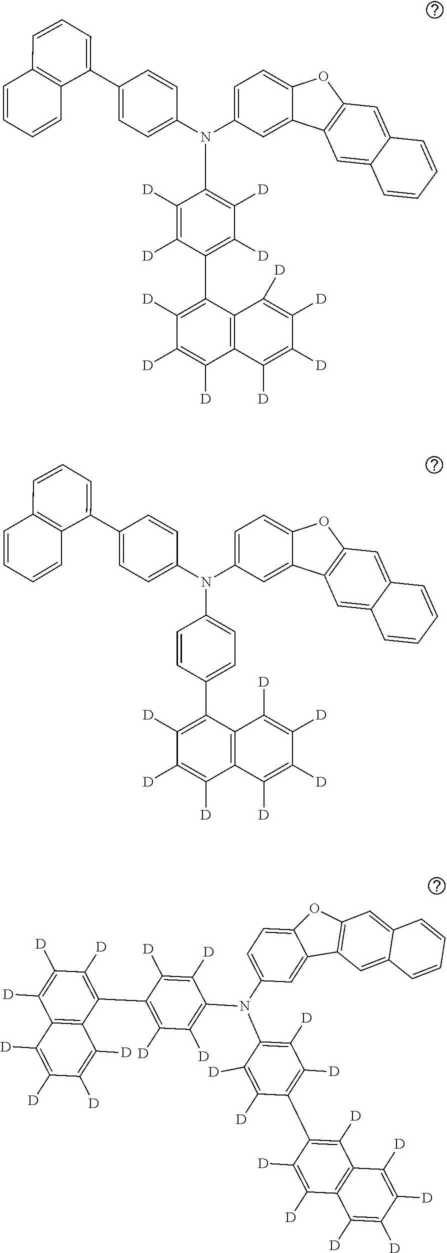 [SMILES: [2H]c1c([2H])c(N(c2ccc(-c3cccc4ccccc34)cc2)c2ccc3oc4cc5ccccc5cc4c3c2)c([2H])c([2H])c1-c1c([2H])c([2H])c([2H])c2c([2H])c([2H])c([2H])c([2H])c12 ; [2H]c1c([2H])c([2H])c2c(-c3ccc(N(c4ccc(-c5cccc6ccccc56)cc4)c4ccc5oc6cc7ccccc7cc6c5c4)cc3)c([2H])c([2H])c([2H])c2c1[2H] ; [2H]c1c([2H])c(N(c2ccc3oc4cc5ccccc5cc4c3c2)c2c([2H])c([2H])c(-c3c([2H])c([2H])c([2H])c4c([2H])c([2H])c([2H])c([2H])c34)c([2H])c2[2H])c([2H])c([2H])c1-c1c([2H])c([2H])c2c([2H])c([2H])c([2H])c([2H])c2c1[2H]]

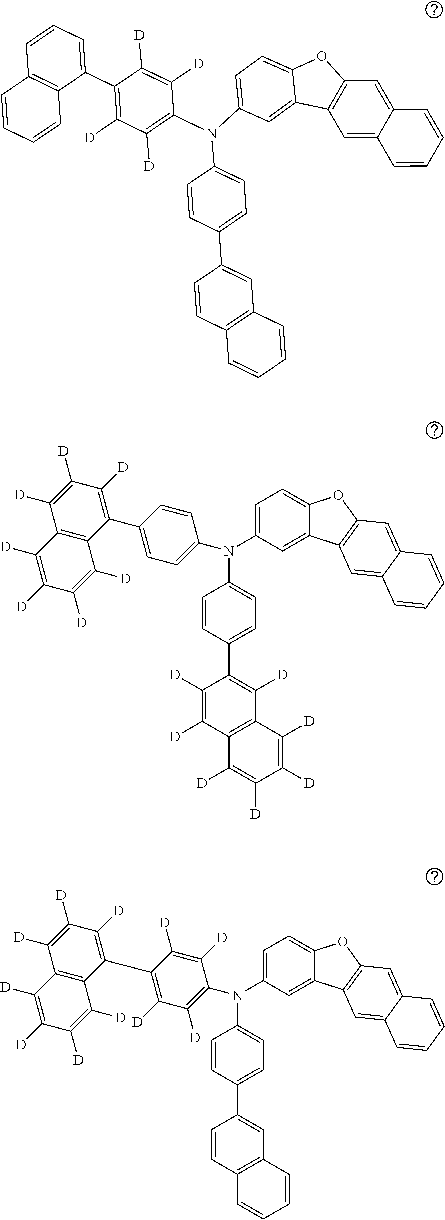 [SMILES: [2H]c1c([2H])c(N(c2ccc(-c3ccc4ccccc4c3)cc2)c2ccc3oc4cc5ccccc5cc4c3c2)c([2H])c([2H])c1-c1cccc2ccccc12 ; [2H]c1c([2H])c([2H])c2c([2H])c(-c3ccc(N(c4ccc(-c5c([2H])c([2H])c([2H])c6c([2H])c([2H])c([2H])c([2H])c56)cc4)c4ccc5oc6cc7ccccc7cc6c5c4)cc3)c([2H])c([2H])c2c1[2H] ; [2H]c1c([2H])c(N(c2ccc(-c3ccc4ccccc4c3)cc2)c2ccc3oc4cc5ccccc5cc4c3c2)c([2H])c([2H])c1-c1c([2H])c([2H])c([2H])c2c([2H])c([2H])c([2H])c([2H])c12]

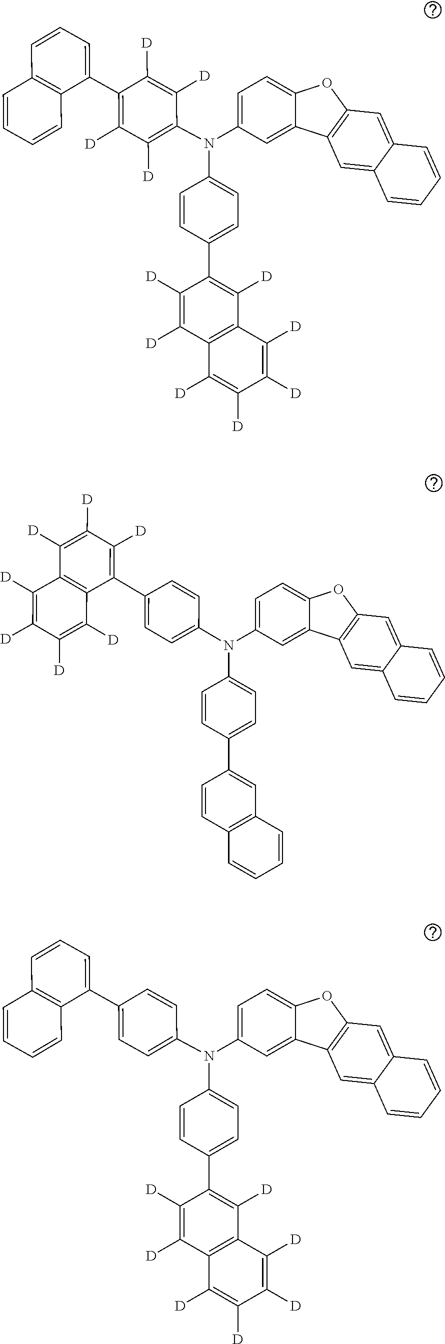 [SMILES: [2H]c1c([2H])c(N(c2ccc(-c3c([2H])c([2H])c4c([2H])c([2H])c([2H])c([2H])c4c3[2H])cc2)c2ccc3oc4cc5ccccc5cc4c3c2)c([2H])c([2H])c1-c1cccc2ccccc12 ; [2H]c1c([2H])c([2H])c2c(-c3ccc(N(c4ccc(-c5ccc6ccccc6c5)cc4)c4ccc5oc6cc7ccccc7cc6c5c4)cc3)c([2H])c([2H])c([2H])c2c1[2H] ; [2H]c1c([2H])c([2H])c2c([2H])c(-c3ccc(N(c4ccc(-c5cccc6ccccc56)cc4)c4ccc5oc6cc7ccccc7cc6c5c4)cc3)c([2H])c([2H])c2c1[2H]]

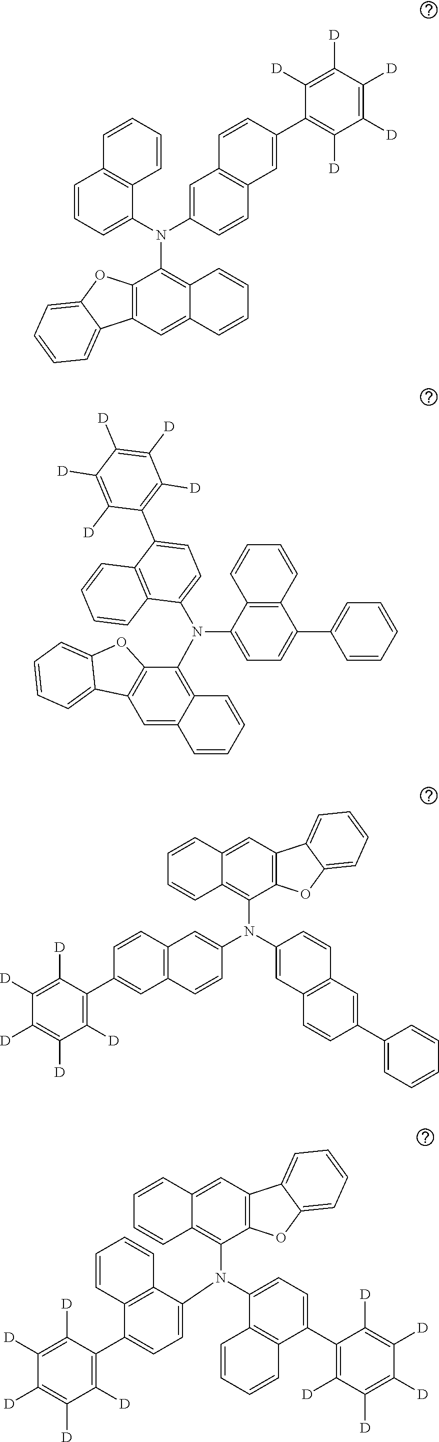 [SMILES: [2H]c1c([2H])c([2H])c(-c2ccc3cc(N(c4cccc5ccccc45)c4c5ccccc5cc5c4oc4ccccc45)ccc3c2)c([2H])c1[2H] ; [2H]c1c([2H])c([2H])c(-c2ccc(N(c3ccc(-c4ccccc4)c4ccccc34)c3c4ccccc4cc4c3oc3ccccc34)c3ccccc23)c([2H])c1[2H] ; [2H]c1c([2H])c([2H])c(-c2ccc3cc(N(c4ccc5cc(-c6ccccc6)ccc5c4)c4c5ccccc5cc5c4oc4ccccc45)ccc3c2)c([2H])c1[2H] ; [2H]c1c([2H])c([2H])c(-c2ccc(N(c3ccc(-c4c([2H])c([2H])c([2H])c([2H])c4[2H])c4ccccc34)c3c4ccccc4cc4c3oc3ccccc34)c3ccccc23)c([2H])c1[2H]]

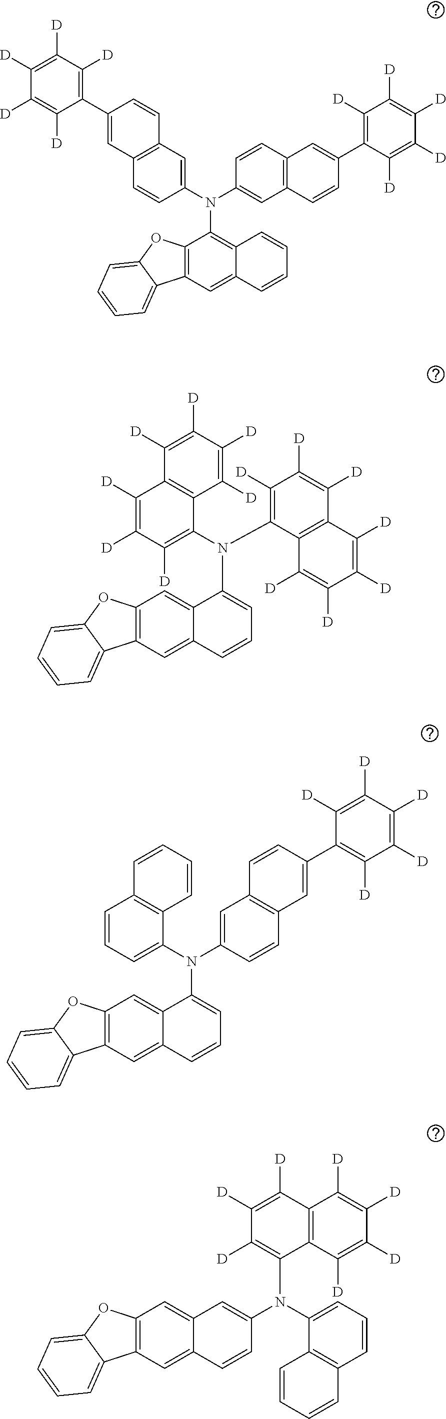 [SMILES: [2H]c1c([2H])c([2H])c(-c2ccc3cc(N(c4ccc5cc(-c6c([2H])c([2H])c([2H])c([2H])c6[2H])ccc5c4)c4c5ccccc5cc5c4oc4ccccc45)ccc3c2)c([2H])c1[2H] ; [2H]c1c([2H])c([2H])c2c(N(c3cccc4cc5c(cc34)oc3ccccc35)c3c([2H])c([2H])c([2H])c4c([2H])c([2H])c([2H])c([2H])c34)c([2H])c([2H])c([2H])c2c1[2H] ; [2H]c1c([2H])c([2H])c(-c2ccc3cc(N(c4cccc5ccccc45)c4cccc5cc6c(cc45)oc4ccccc46)ccc3c2)c([2H])c1[2H] ; [2H]c1c([2H])c([2H])c2c(N(c3ccc4cc5c(cc4c3)oc3ccccc35)c3cccc4ccccc34)c([2H])c([2H])c([2H])c2c1[2H]]

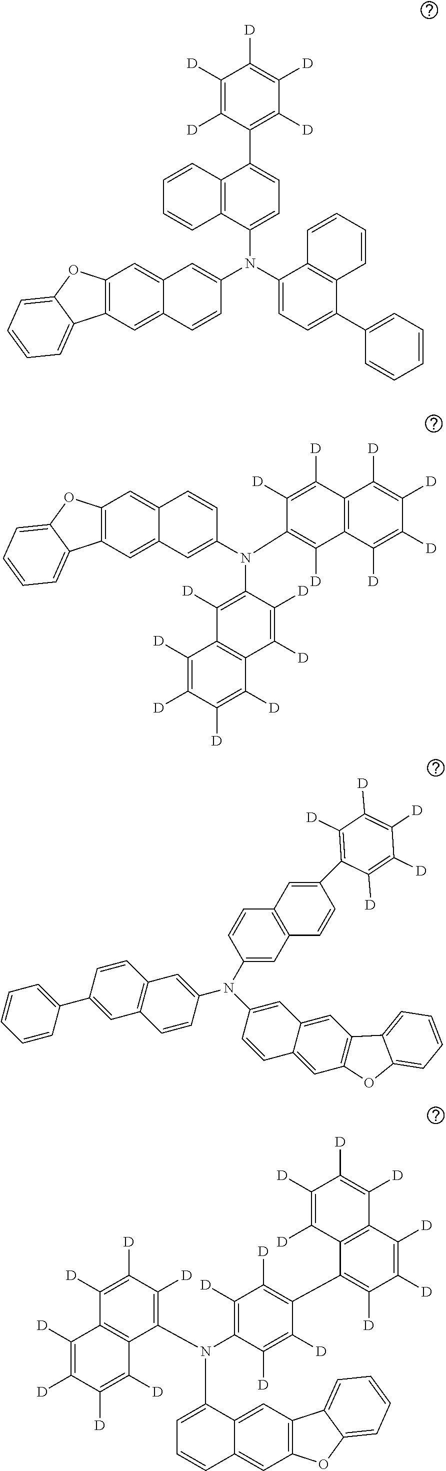

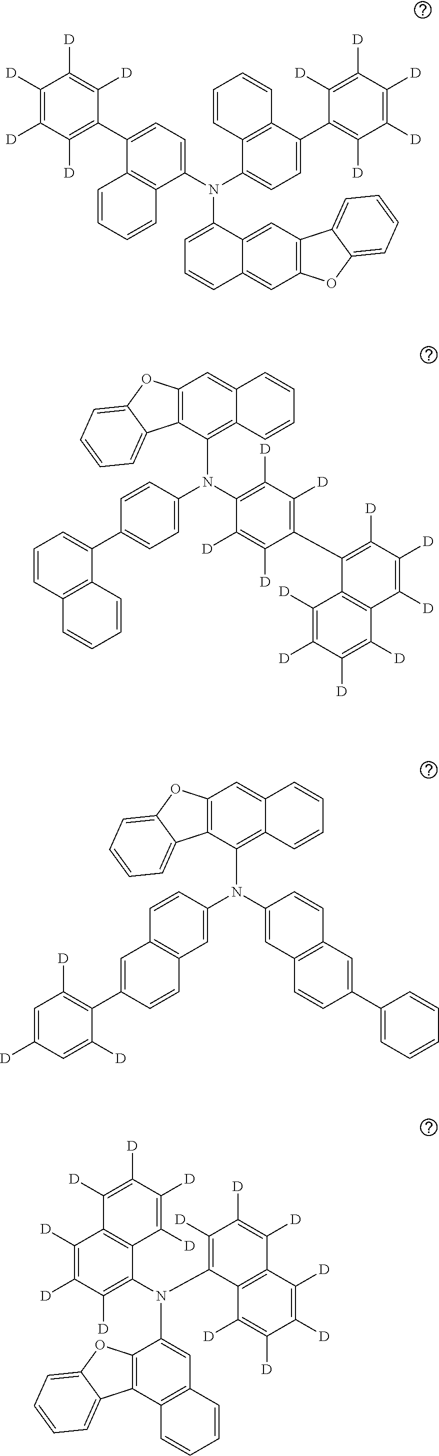

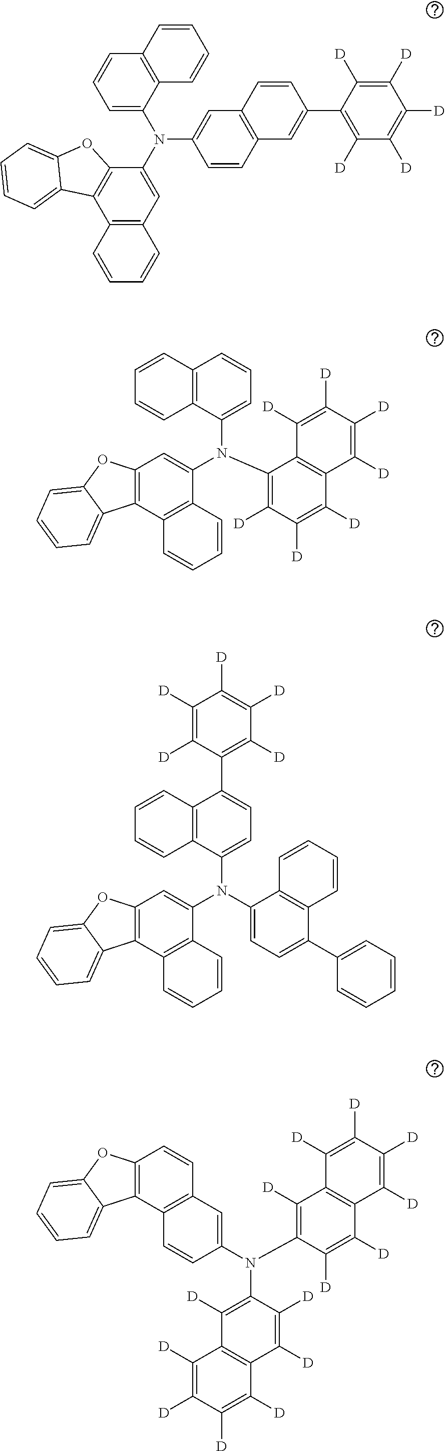 [SMILES: [2H]c1c([2H])c([2H])c(-c2ccc3cc(N(c4cccc5ccccc45)c4cc5ccccc5c5c4oc4ccccc45)ccc3c2)c([2H])c1[2H] ; [2H]c1c([2H])c([2H])c2c(N(c3cccc4ccccc34)c3cc4oc5ccccc5c4c4ccccc34)c([2H])c([2H])c([2H])c2c1[2H] ; [2H]c1c([2H])c([2H])c(-c2ccc(N(c3ccc(-c4ccccc4)c4ccccc34)c3cc4oc5ccccc5c4c4ccccc34)c3ccccc23)c([2H])c1[2H] ; [2H]c1c([2H])c([2H])c2c([2H])c(N(c3ccc4c(ccc5oc6ccccc6c54)c3)c3c([2H])c([2H])c4c([2H])c([2H])c([2H])c([2H])c4c3[2H])c([2H])c([2H])c2c1[2H]]

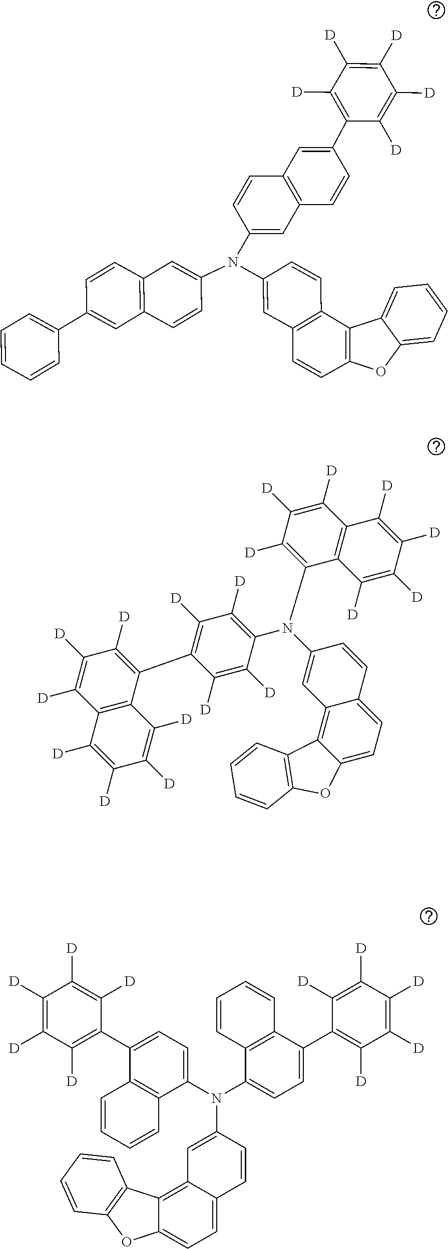 [SMILES: [2H]c1c([2H])c([2H])c(-c2ccc3cc(N(c4ccc5cc(-c6ccccc6)ccc5c4)c4ccc5c(ccc6oc7ccccc7c65)c4)ccc3c2)c([2H])c1[2H] ; [2H]c1c([2H])c(N(c2ccc3ccc4oc5ccccc5c4c3c2)c2c([2H])c([2H])c([2H])c3c([2H])c([2H])c([2H])c([2H])c23)c([2H])c([2H])c1-c1c([2H])c([2H])c([2H])c2c([2H])c([2H])c([2H])c([2H])c12 ; [2H]c1c([2H])c([2H])c(-c2ccc(N(c3ccc4ccc5oc6ccccc6c5c4c3)c3ccc(-c4c([2H])c([2H])c([2H])c([2H])c4[2H])c4ccccc34)c3ccccc23)c([2H])c1[2H]]

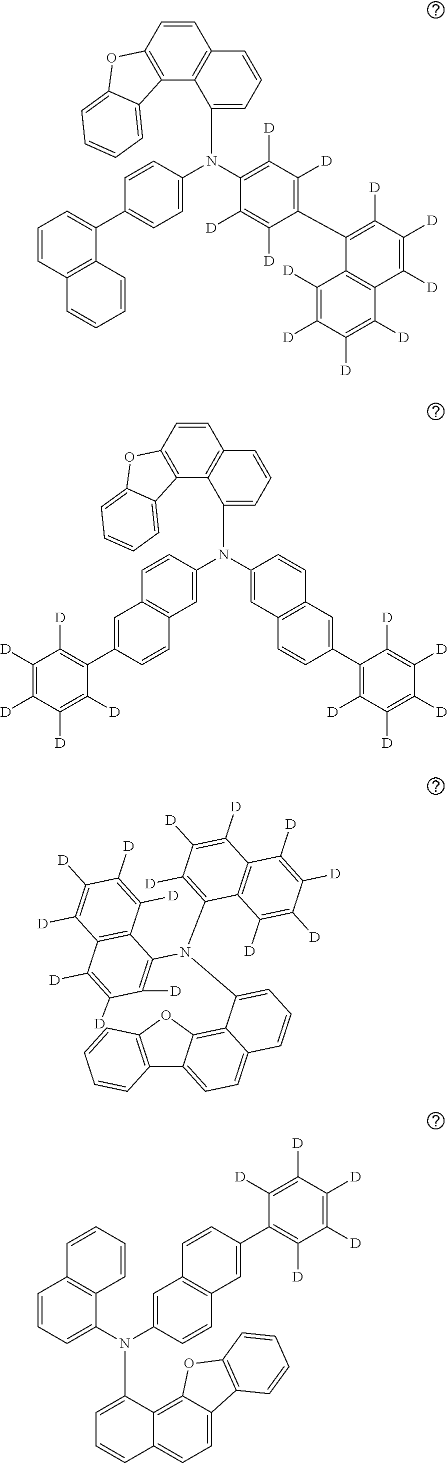

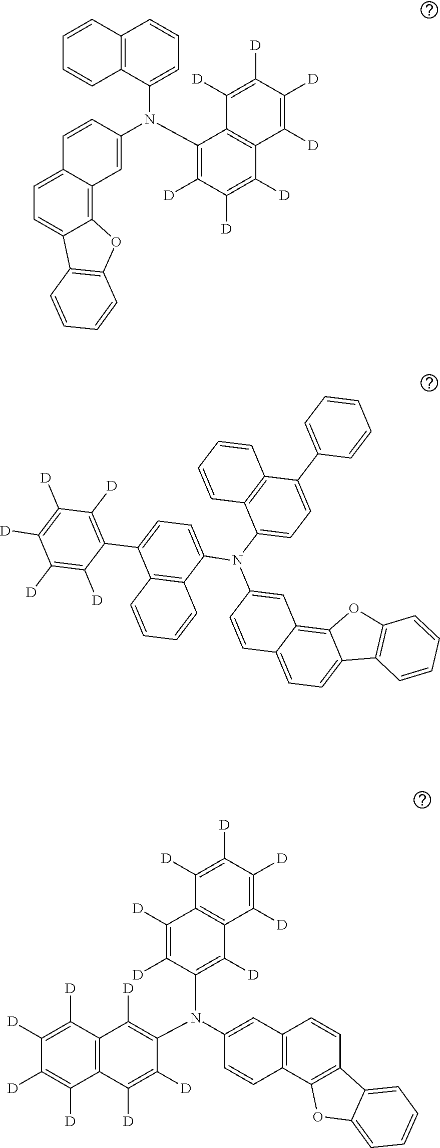 [SMILES: [2H]c1c([2H])c([2H])c2c(N(c3ccc4ccc5c6ccccc6oc5c4c3)c3cccc4ccccc34)c([2H])c([2H])c([2H])c2c1[2H] ; [2H]c1c([2H])c([2H])c(-c2ccc(N(c3ccc4ccc5c6ccccc6oc5c4c3)c3ccc(-c4ccccc4)c4ccccc34)c3ccccc23)c([2H])c1[2H] ; [2H]c1c([2H])c([2H])c2c([2H])c(N(c3ccc4c(ccc5c6ccccc6oc45)c3)c3c([2H])c([2H])c4c([2H])c([2H])c([2H])c([2H])c4c3[2H])c([2H])c([2H])c2c1[2H]]

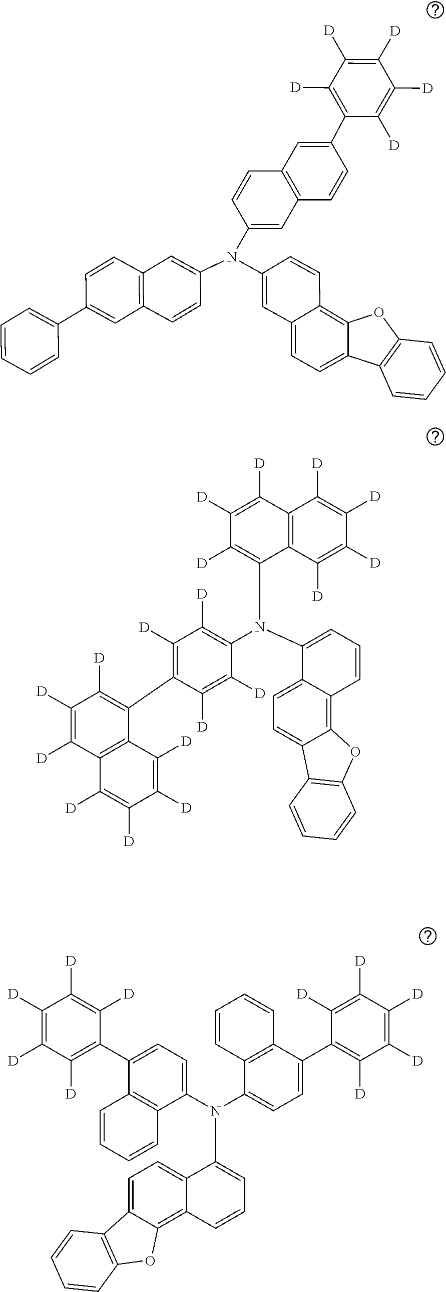 [SMILES: [2H]c1c([2H])c([2H])c(-c2ccc3cc(N(c4ccc5cc(-c6ccccc6)ccc5c4)c4ccc5c(ccc6c7ccccc7oc56)c4)ccc3c2)c([2H])c1[2H] ; [2H]c1c([2H])c(N(c2cccc3c2ccc2c4ccccc4oc32)c2c([2H])c([2H])c([2H])c3c([2H])c([2H])c([2H])c([2H])c23)c([2H])c([2H])c1-c1c([2H])c([2H])c([2H])c2c([2H])c([2H])c([2H])c([2H])c12 ; [2H]c1c([2H])c([2H])c(-c2ccc(N(c3ccc(-c4c([2H])c([2H])c([2H])c([2H])c4[2H])c4ccccc34)c3cccc4c3ccc3c5ccccc5oc43)c3ccccc23)c([2H])c1[2H]]

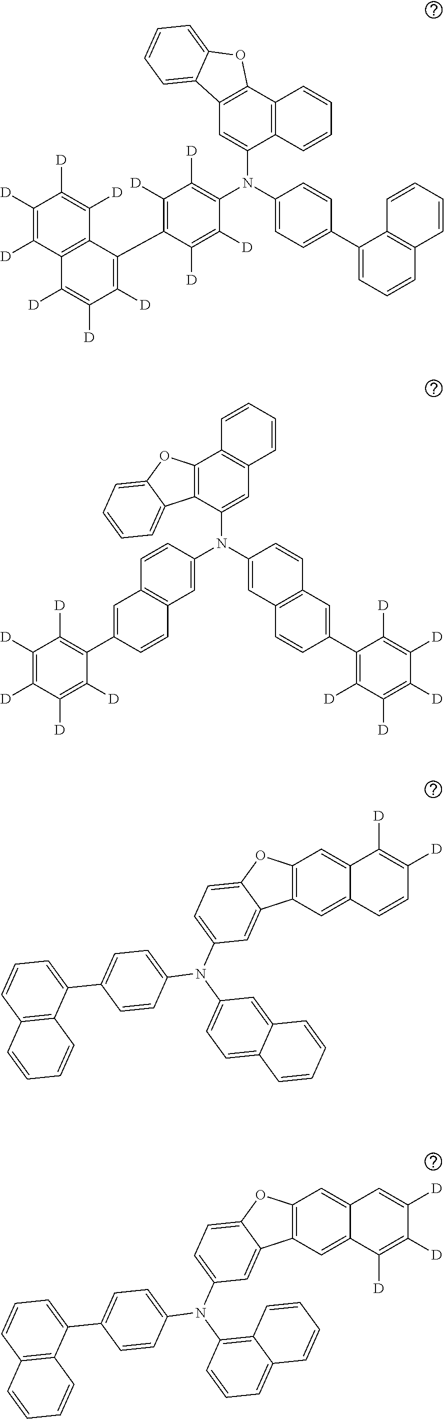 [SMILES: [2H]c1c([2H])c(N(c2ccc(-c3cccc4ccccc34)cc2)c2cc3c4ccccc4oc3c3ccccc23)c([2H])c([2H])c1-c1c([2H])c([2H])c([2H])c2c([2H])c([2H])c([2H])c([2H])c12 ; [2H]c1c([2H])c([2H])c(-c2ccc3cc(N(c4ccc5cc(-c6c([2H])c([2H])c([2H])c([2H])c6[2H])ccc5c4)c4cc5ccccc5c5oc6ccccc6c45)ccc3c2)c([2H])c1[2H] ; [2H]c1ccc2cc3c(cc2c1[2H])oc1ccc(N(c2ccc(-c4cccc5ccccc45)cc2)c2ccc4ccccc4c2)cc13 ; [2H]c1cc2cc3oc4ccc(N(c5ccc(-c6cccc7ccccc67)cc5)c5cccc6ccccc56)cc4c3cc2c([2H])c1[2H]]

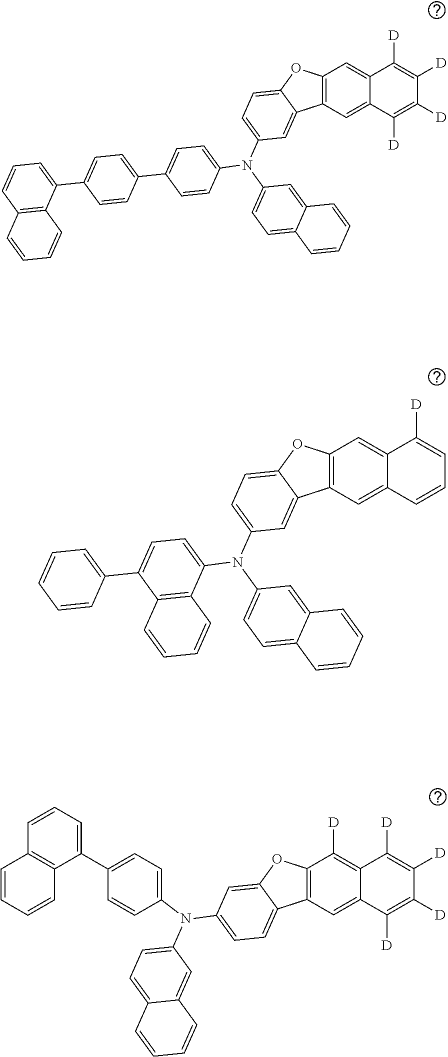 [SMILES: [2H]c1c([2H])c([2H])c2cc3c(cc2c1[2H])oc1ccc(N(c2ccc(-c4ccc(-c5cccc6ccccc56)cc4)cc2)c2ccc4ccccc4c2)cc13 ; [2H]c1cccc2cc3c(cc12)oc1ccc(N(c2ccc4ccccc4c2)c2ccc(-c4ccccc4)c4ccccc24)cc13 ; [2H]c1c([2H])c([2H])c2c([2H])c3oc4cc(N(c5ccc(-c6cccc7ccccc67)cc5)c5ccc6ccccc6c5)ccc4c3cc2c1[2H]]

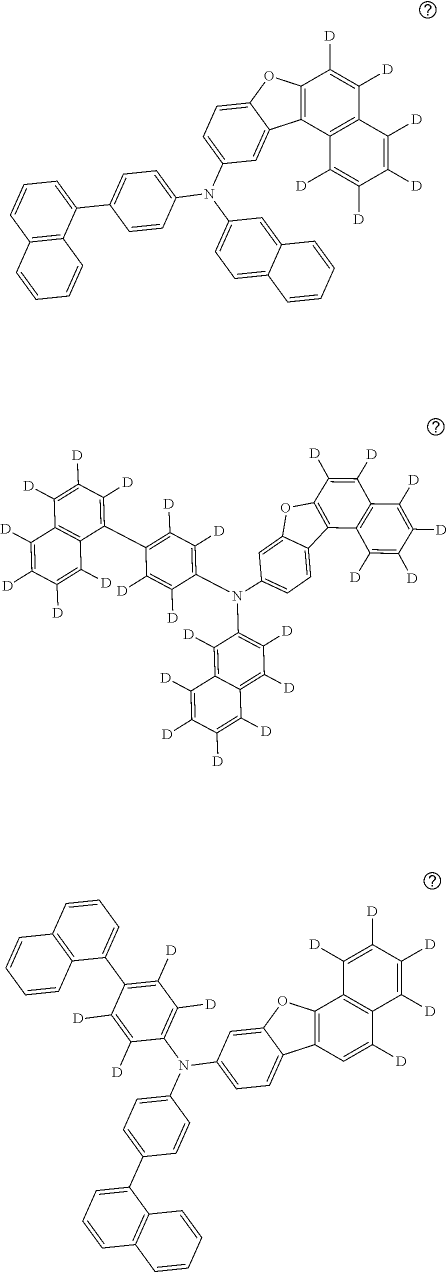 [SMILES: [2H]c1c([2H])c([2H])c2c(c1[2H])c([2H])c([2H])c1oc3ccc(N(c4ccc(-c5cccc6ccccc56)cc4)c4ccc5ccccc5c4)cc3c12 ; [2H]c1c([2H])c(N(c2ccc3c(c2)oc2c([2H])c([2H])c4c([2H])c([2H])c([2H])c([2H])c4c23)c2c([2H])c([2H])c3c([2H])c([2H])c([2H])c([2H])c3c2[2H])c([2H])c([2H])c1-c1c([2H])c([2H])c([2H])c2c([2H])c([2H])c([2H])c([2H])c12 ; [2H]c1c([2H])c(N(c2ccc(-c3cccc4ccccc34)cc2)c2ccc3c(c2)oc2c3cc([2H])c3c([2H])c([2H])c([2H])c([2H])c32)c([2H])c([2H])c1-c1cccc2ccccc12]

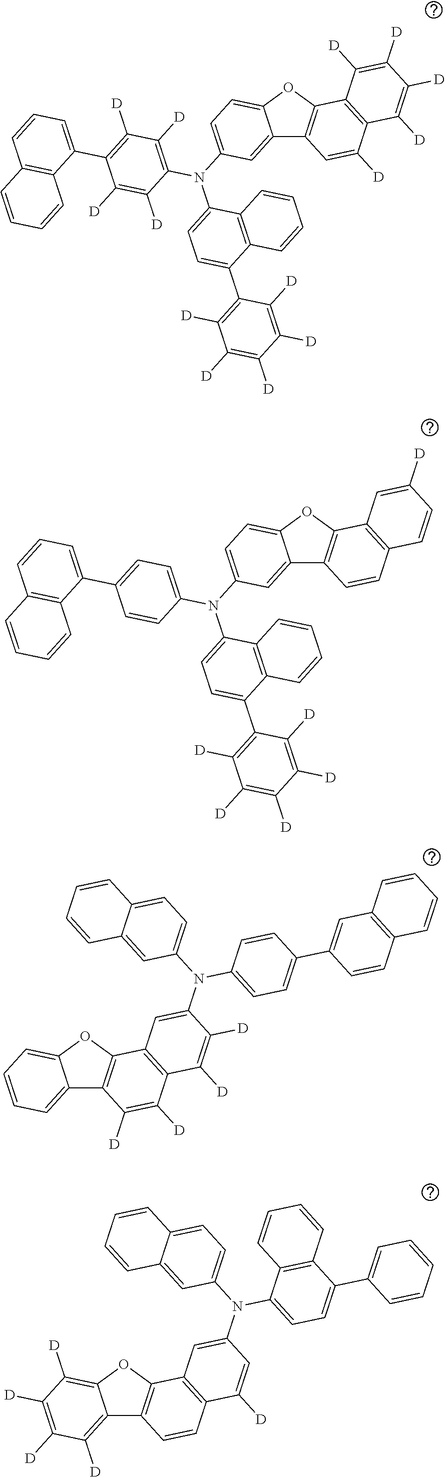 [SMILES: [2H]c1c([2H])c([2H])c(-c2ccc(N(c3ccc4oc5c(cc([2H])c6c([2H])c([2H])c([2H])c([2H])c65)c4c3)c3c([2H])c([2H])c(-c4cccc5ccccc45)c([2H])c3[2H])c3ccccc23)c([2H])c1[2H] ; [2H]c1ccc2ccc3c4cc(N(c5ccc(-c6cccc7ccccc67)cc5)c5ccc(-c6c([2H])c([2H])c([2H])c([2H])c6[2H])c6ccccc56)ccc4oc3c2c1 ; [2H]c1c(N(c2ccc(-c3ccc4ccccc4c3)cc2)c2ccc3ccccc3c2)cc2c(c1[2H])c([2H])c([2H])c1c3ccccc3oc21 ; [2H]c1c([2H])c([2H])c2c(oc3c4cc(N(c5ccc6ccccc6c5)c5ccc(-c6ccccc6)c6ccccc56)cc([2H])c4ccc32)c1[2H]]

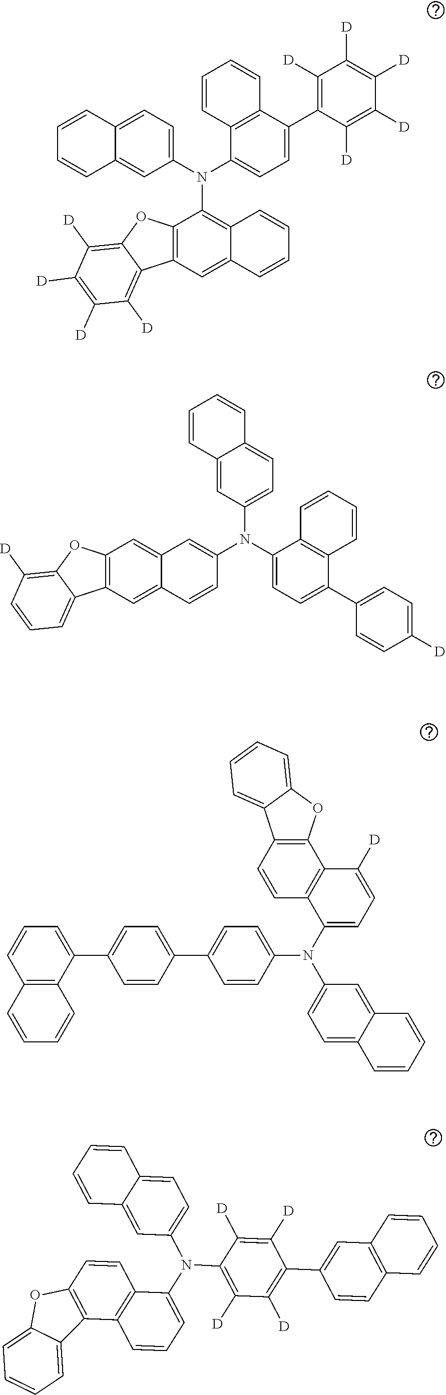 [SMILES: [2H]c1c([2H])c([2H])c(-c2ccc(N(c3ccc4ccccc4c3)c3c4ccccc4cc4c3oc3c([2H])c([2H])c([2H])c([2H])c34)c3ccccc23)c([2H])c1[2H] ; [2H]c1ccc(-c2ccc(N(c3ccc4ccccc4c3)c3ccc4cc5c(cc4c3)oc3c([2H])cccc35)c3ccccc23)cc1 ; [2H]c1ccc(N(c2ccc(-c3ccc(-c4cccc5ccccc45)cc3)cc2)c2ccc3ccccc3c2)c2ccc3c4ccccc4oc3c12 ; [2H]c1c([2H])c(N(c2ccc3ccccc3c2)c2cccc3c2ccc2oc4ccccc4c23)c([2H])c([2H])c1-c1ccc2ccccc2c1]

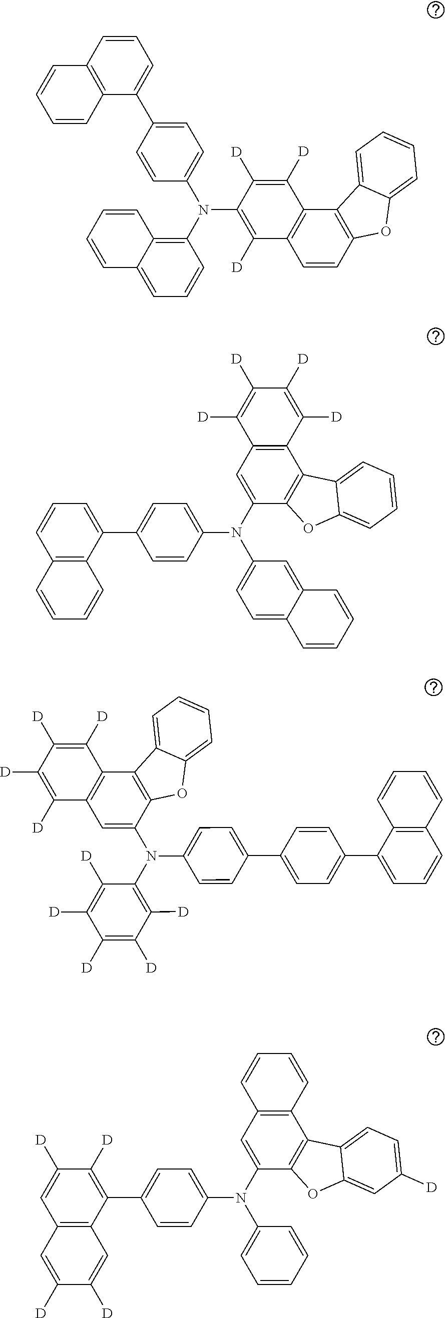 [SMILES: [2H]c1c(N(c2ccc(-c3cccc4ccccc34)cc2)c2cccc3ccccc23)c([2H])c2ccc3oc4ccccc4c3c2c1[2H] ; [2H]c1c([2H])c([2H])c2c(cc(N(c3ccc(-c4cccc5ccccc45)cc3)c3ccc4ccccc4c3)c3oc4ccccc4c32)c1[2H] ; [2H]c1c([2H])c([2H])c(N(c2ccc(-c3ccc(-c4cccc5ccccc45)cc3)cc2)c2cc3c([2H])c([2H])c([2H])c([2H])c3c3c2oc2ccccc23)c([2H])c1[2H] ; [2H]c1ccc2c(c1)oc1c(N(c3ccccc3)c3ccc(-c4c([2H])c([2H])cc5cc([2H])c([2H])cc45)cc3)cc3ccccc3c12]

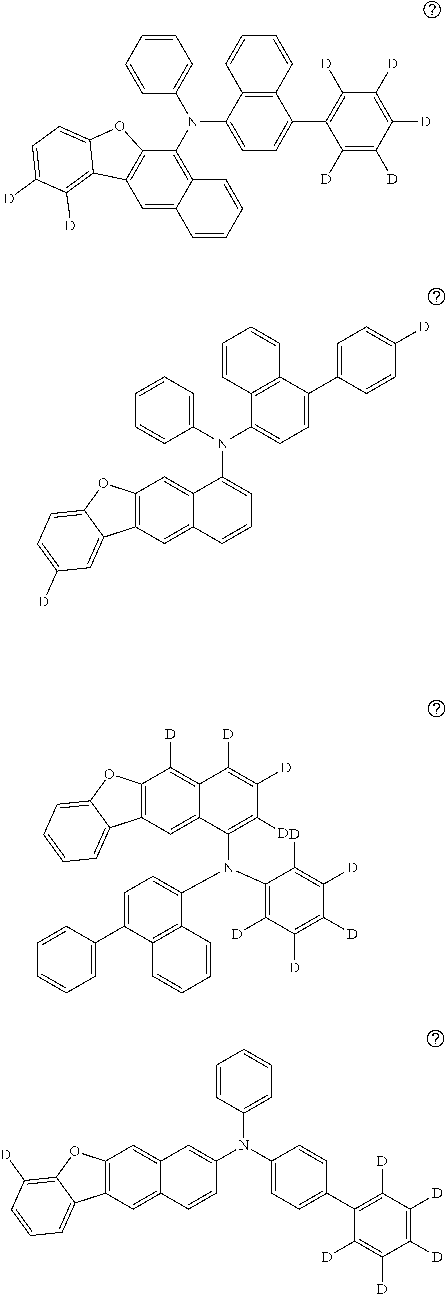 [SMILES: [2H]c1ccc2oc3c(N(c4ccccc4)c4ccc(-c5c([2H])c([2H])c([2H])c([2H])c5[2H])c5ccccc45)c4ccccc4cc3c2c1[2H] ; [2H]c1ccc(-c2ccc(N(c3ccccc3)c3cccc4cc5c(cc34)oc3ccc([2H])cc35)c3ccccc23)cc1 ; [2H]c1c([2H])c([2H])c(N(c2ccc(-c3ccccc3)c3ccccc23)c2c([2H])c([2H])c([2H])c3c([2H])c4oc5ccccc5c4cc23)c([2H])c1[2H] ; [2H]c1c([2H])c([2H])c(-c2ccc(N(c3ccccc3)c3ccc4cc5c(cc4c3)oc3c([2H])cccc35)cc2)c([2H])c1[2H]]

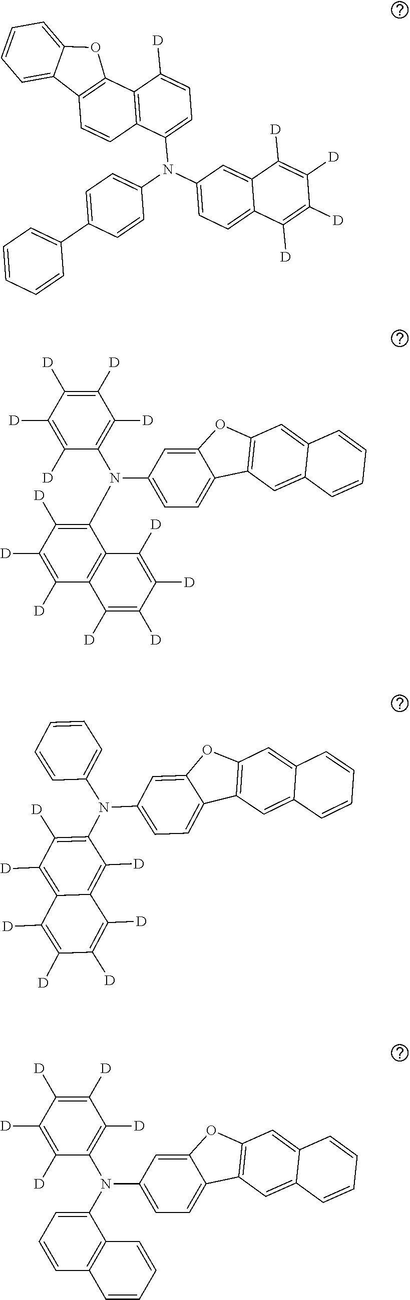 [SMILES: [2H]c1c([2H])c([2H])c2cc(N(c3ccc(-c4ccccc4)cc3)c3ccc([2H])c4c3ccc3c5ccccc5oc34)ccc2c1[2H] ; [2H]c1c([2H])c([2H])c(N(c2ccc3c(c2)oc2cc4ccccc4cc23)c2c([2H])c([2H])c([2H])c3c([2H])c([2H])c([2H])c([2H])c23)c([2H])c1[2H] ; [2H]c1c([2H])c([2H])c2c([2H])c(N(c3ccccc3)c3ccc4c(c3)oc3cc5ccccc5cc34)c([2H])c([2H])c2c1[2H] ; [2H]c1c([2H])c([2H])c(N(c2ccc3c(c2)oc2cc4ccccc4cc23)c2cccc3ccccc23)c([2H])c1[2H]]

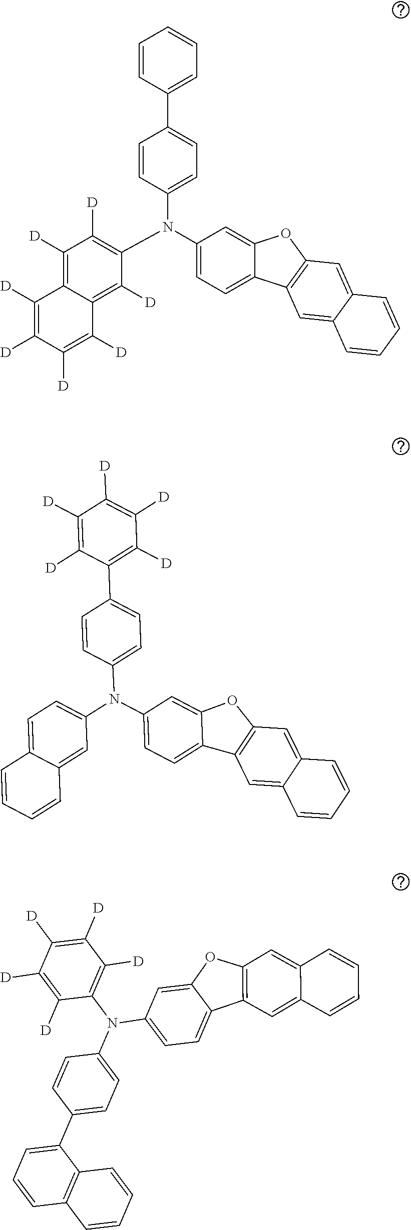 [SMILES: [2H]c1c([2H])c([2H])c2c([2H])c(N(c3ccc(-c4ccccc4)cc3)c3ccc4c(c3)oc3cc5ccccc5cc34)c([2H])c([2H])c2c1[2H] ; [2H]c1c([2H])c([2H])c(-c2ccc(N(c3ccc4ccccc4c3)c3ccc4c(c3)oc3cc5ccccc5cc34)cc2)c([2H])c1[2H] ; [2H]c1c([2H])c([2H])c(N(c2ccc(-c3cccc4ccccc34)cc2)c2ccc3c(c2)oc2cc4ccccc4cc23)c([2H])c1[2H]]

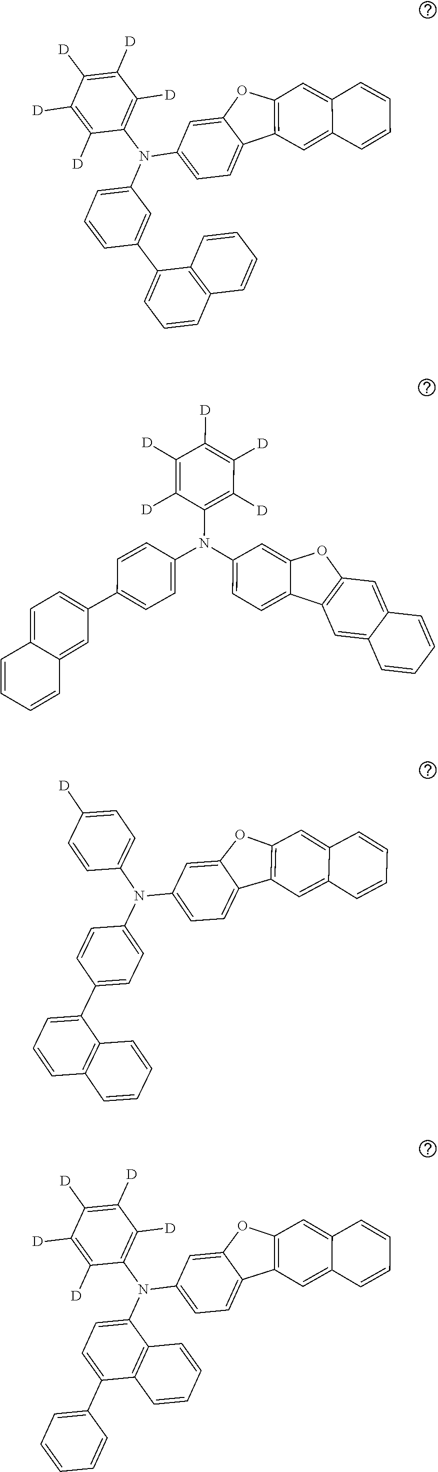 [SMILES: [2H]c1c([2H])c([2H])c(N(c2cccc(-c3cccc4ccccc34)c2)c2ccc3c(c2)oc2cc4ccccc4cc23)c([2H])c1[2H] ; [2H]c1c([2H])c([2H])c(N(c2ccc(-c3ccc4ccccc4c3)cc2)c2ccc3c(c2)oc2cc4ccccc4cc23)c([2H])c1[2H] ; [2H]c1ccc(N(c2ccc(-c3cccc4ccccc34)cc2)c2ccc3c(c2)oc2cc4ccccc4cc23)cc1 ; [2H]c1c([2H])c([2H])c(N(c2ccc3c(c2)oc2cc4ccccc4cc23)c2ccc(-c3ccccc3)c3ccccc23)c([2H])c1[2H]]

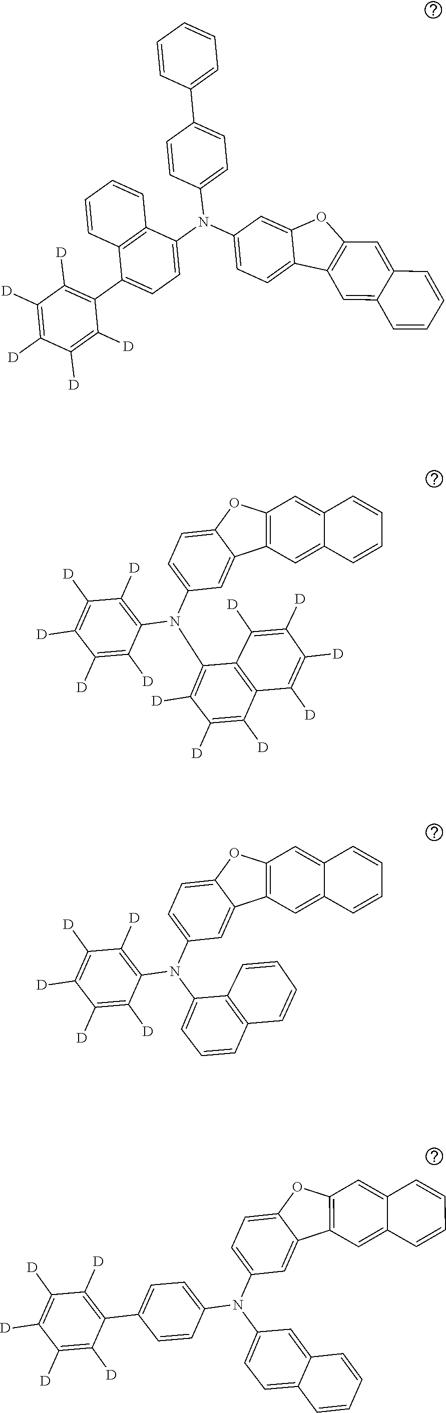 [SMILES: [2H]c1c([2H])c([2H])c(-c2ccc(N(c3ccc(-c4ccccc4)cc3)c3ccc4c(c3)oc3cc5ccccc5cc34)c3ccccc23)c([2H])c1[2H] ; [2H]c1c([2H])c([2H])c(N(c2ccc3oc4cc5ccccc5cc4c3c2)c2c([2H])c([2H])c([2H])c3c([2H])c([2H])c([2H])c([2H])c23)c([2H])c1[2H] ; [2H]c1c([2H])c([2H])c(N(c2ccc3oc4cc5ccccc5cc4c3c2)c2cccc3ccccc23)c([2H])c1[2H] ; [2H]c1c([2H])c([2H])c(-c2ccc(N(c3ccc4ccccc4c3)c3ccc4oc5cc6ccccc6cc5c4c3)cc2)c([2H])c1[2H]]

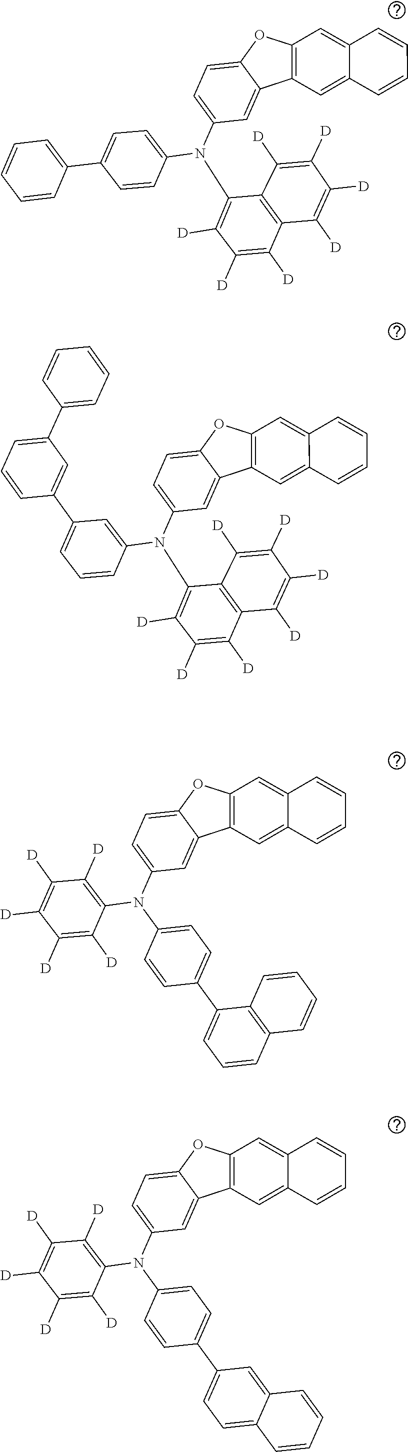 [SMILES: [2H]c1c([2H])c([2H])c2c(N(c3ccc(-c4ccccc4)cc3)c3ccc4oc5cc6ccccc6cc5c4c3)c([2H])c([2H])c([2H])c2c1[2H] ; [2H]c1c([2H])c([2H])c2c(N(c3cccc(-c4cccc(-c5ccccc5)c4)c3)c3ccc4oc5cc6ccccc6cc5c4c3)c([2H])c([2H])c([2H])c2c1[2H] ; [2H]c1c([2H])c([2H])c(N(c2ccc(-c3cccc4ccccc34)cc2)c2ccc3oc4cc5ccccc5cc4c3c2)c([2H])c1[2H] ; [2H]c1c([2H])c([2H])c(N(c2ccc(-c3ccc4ccccc4c3)cc2)c2ccc3oc4cc5ccccc5cc4c3c2)c([2H])c1[2H]]

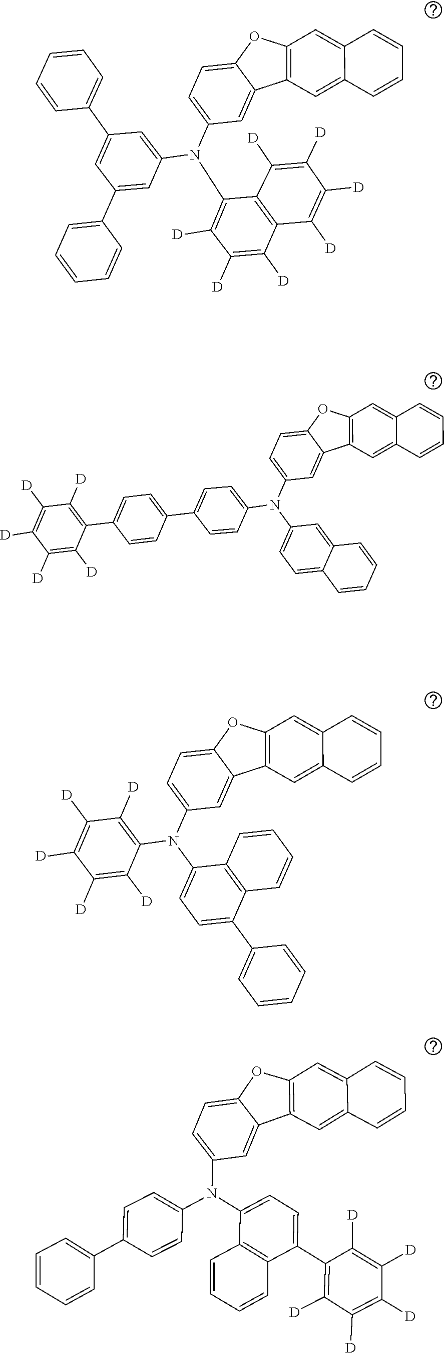 [SMILES: [2H]c1c([2H])c([2H])c2c(N(c3cc(-c4ccccc4)cc(-c4ccccc4)c3)c3ccc4oc5cc6ccccc6cc5c4c3)c([2H])c([2H])c([2H])c2c1[2H] ; [2H]c1c([2H])c([2H])c(-c2ccc(-c3ccc(N(c4ccc5ccccc5c4)c4ccc5oc6cc7ccccc7cc6c5c4)cc3)cc2)c([2H])c1[2H] ; [2H]c1c([2H])c([2H])c(N(c2ccc3oc4cc5ccccc5cc4c3c2)c2ccc(-c3ccccc3)c3ccccc23)c([2H])c1[2H] ; [2H]c1c([2H])c([2H])c(-c2ccc(N(c3ccc(-c4ccccc4)cc3)c3ccc4oc5cc6ccccc6cc5c4c3)c3ccccc23)c([2H])c1[2H]]

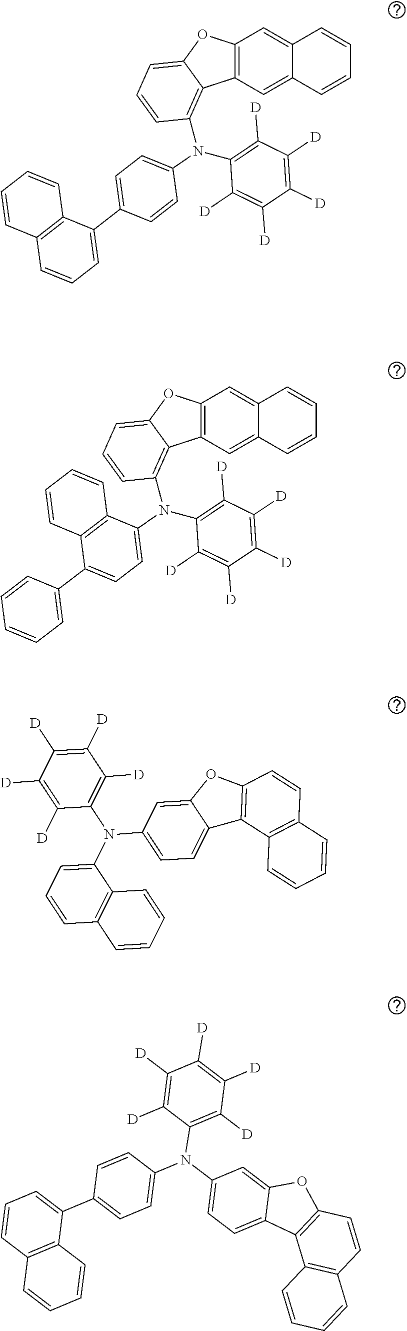 [SMILES: [2H]c1c([2H])c([2H])c(N(c2ccc(-c3cccc4ccccc34)cc2)c2cccc3oc4cc5ccccc5cc4c23)c([2H])c1[2H] ; [2H]c1c([2H])c([2H])c(N(c2ccc(-c3ccccc3)c3ccccc23)c2cccc3oc4cc5ccccc5cc4c23)c([2H])c1[2H] ; [2H]c1c([2H])c([2H])c(N(c2ccc3c(c2)oc2ccc4ccccc4c23)c2cccc3ccccc23)c([2H])c1[2H] ; [2H]c1c([2H])c([2H])c(N(c2ccc(-c3cccc4ccccc34)cc2)c2ccc3c(c2)oc2ccc4ccccc4c23)c([2H])c1[2H]]

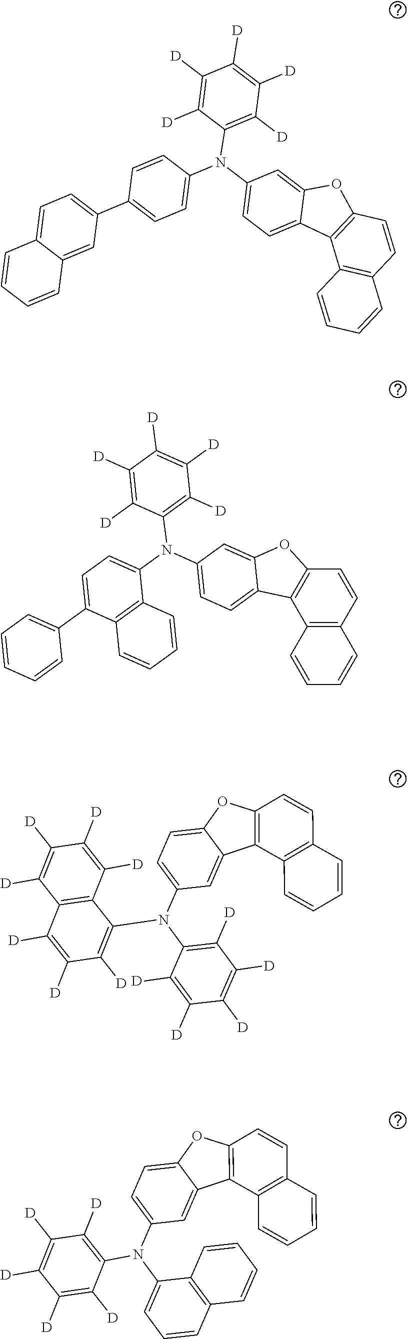 [SMILES: [2H]c1c([2H])c([2H])c(N(c2ccc(-c3ccc4ccccc4c3)cc2)c2ccc3c(c2)oc2ccc4ccccc4c23)c([2H])c1[2H] ; [2H]c1c([2H])c([2H])c(N(c2ccc3c(c2)oc2ccc4ccccc4c23)c2ccc(-c3ccccc3)c3ccccc23)c([2H])c1[2H] ; [2H]c1c([2H])c([2H])c(N(c2ccc3oc4ccc5ccccc5c4c3c2)c2c([2H])c([2H])c([2H])c3c([2H])c([2H])c([2H])c([2H])c23)c([2H])c1[2H] ; [2H]c1c([2H])c([2H])c(N(c2ccc3oc4ccc5ccccc5c4c3c2)c2cccc3ccccc23)c([2H])c1[2H]]

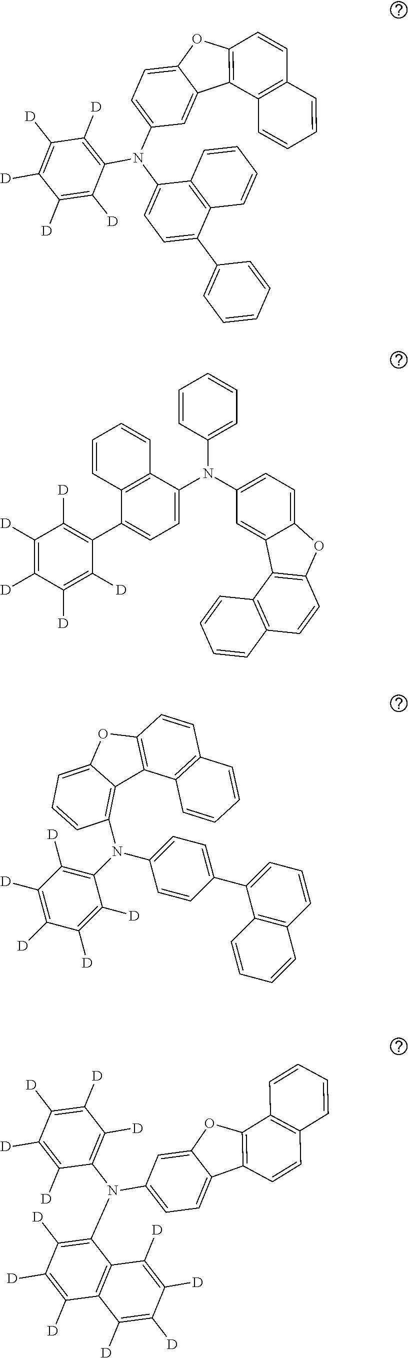 [SMILES: [2H]c1c([2H])c([2H])c(N(c2ccc3oc4ccc5ccccc5c4c3c2)c2ccc(-c3ccccc3)c3ccccc23)c([2H])c1[2H] ; [2H]c1c([2H])c([2H])c(-c2ccc(N(c3ccccc3)c3ccc4oc5ccc6ccccc6c5c4c3)c3ccccc23)c([2H])c1[2H] ; [2H]c1c([2H])c([2H])c(N(c2ccc(-c3cccc4ccccc34)cc2)c2cccc3oc4ccc5ccccc5c4c23)c([2H])c1[2H] ; [2H]c1c([2H])c([2H])c(N(c2ccc3c(c2)oc2c4ccccc4ccc32)c2c([2H])c([2H])c([2H])c3c([2H])c([2H])c([2H])c([2H])c23)c([2H])c1[2H]]

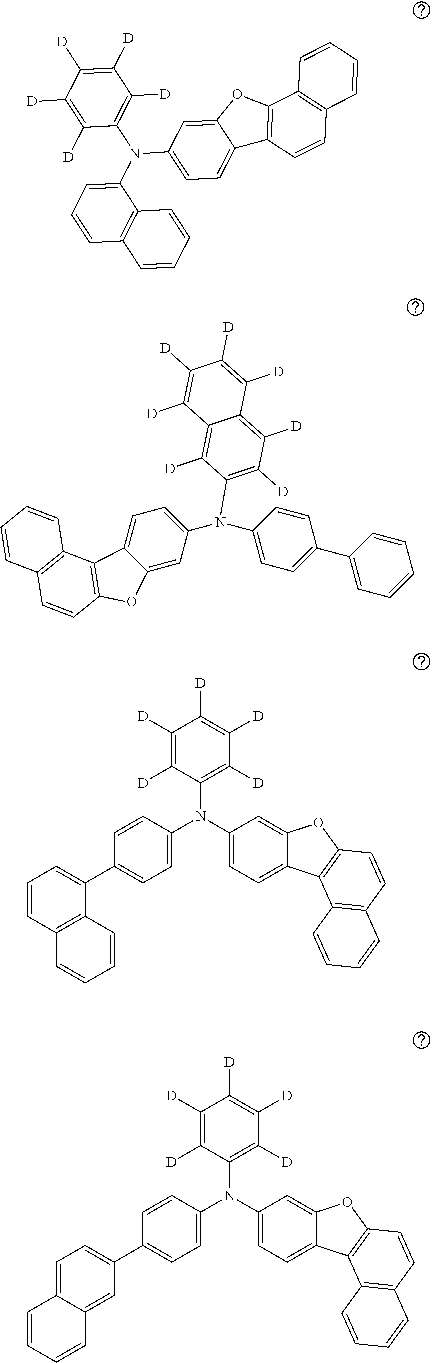 [SMILES: [2H]c1c([2H])c([2H])c(N(c2ccc3c(c2)oc2c4ccccc4ccc32)c2cccc3ccccc23)c([2H])c1[2H] ; [2H]c1c([2H])c([2H])c2c([2H])c(N(c3ccc(-c4ccccc4)cc3)c3ccc4c(c3)oc3ccc5ccccc5c34)c([2H])c([2H])c2c1[2H] ; [2H]c1c([2H])c([2H])c(N(c2ccc(-c3cccc4ccccc34)cc2)c2ccc3c(c2)oc2ccc4ccccc4c23)c([2H])c1[2H] ; [2H]c1c([2H])c([2H])c(N(c2ccc(-c3ccc4ccccc4c3)cc2)c2ccc3c(c2)oc2ccc4ccccc4c23)c([2H])c1[2H]]

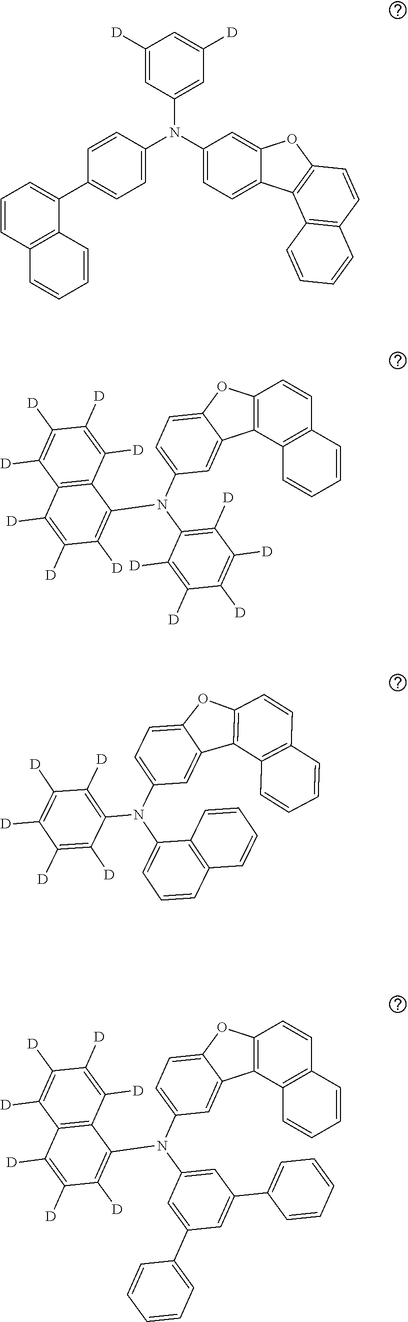 [SMILES: [2H]c1cc([2H])cc(N(c2ccc(-c3cccc4ccccc34)cc2)c2ccc3c(c2)oc2ccc4ccccc4c23)c1 ; [2H]c1c([2H])c([2H])c(N(c2ccc3oc4ccc5ccccc5c4c3c2)c2c([2H])c([2H])c([2H])c3c([2H])c([2H])c([2H])c([2H])c23)c([2H])c1[2H] ; [2H]c1c([2H])c([2H])c(N(c2ccc3oc4ccc5ccccc5c4c3c2)c2cccc3ccccc23)c([2H])c1[2H] ; [2H]c1c([2H])c([2H])c2c(N(c3cc(-c4ccccc4)cc(-c4ccccc4)c3)c3ccc4oc5ccc6ccccc6c5c4c3)c([2H])c([2H])c([2H])c2c1[2H]]

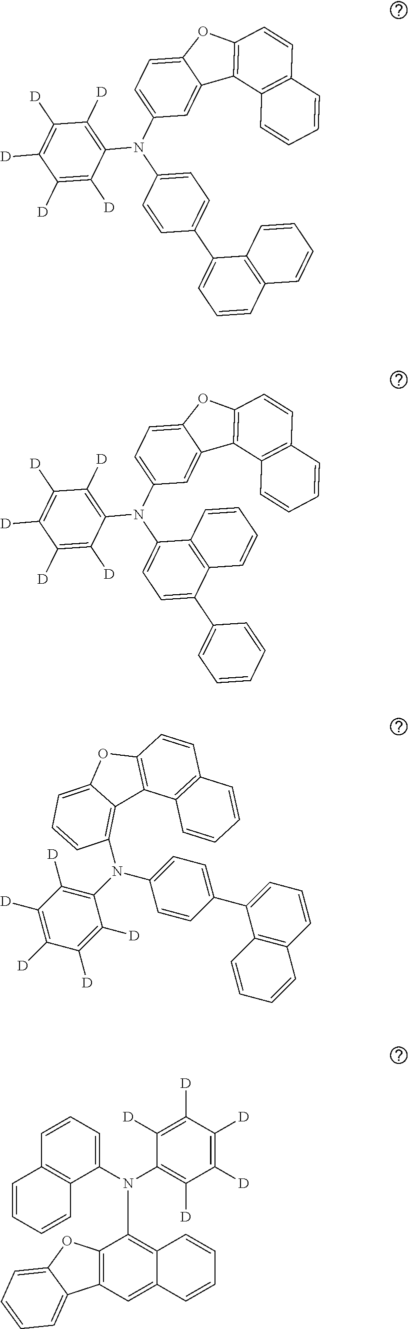 [SMILES: [2H]c1c([2H])c([2H])c(N(c2ccc(-c3cccc4ccccc34)cc2)c2ccc3oc4ccc5ccccc5c4c3c2)c([2H])c1[2H] ; [2H]c1c([2H])c([2H])c(N(c2ccc3oc4ccc5ccccc5c4c3c2)c2ccc(-c3ccccc3)c3ccccc23)c([2H])c1[2H] ; [2H]c1c([2H])c([2H])c(N(c2ccc(-c3cccc4ccccc34)cc2)c2cccc3oc4ccc5ccccc5c4c23)c([2H])c1[2H] ; [2H]c1c([2H])c([2H])c(N(c2cccc3ccccc23)c2c3ccccc3cc3c2oc2ccccc23)c([2H])c1[2H]]

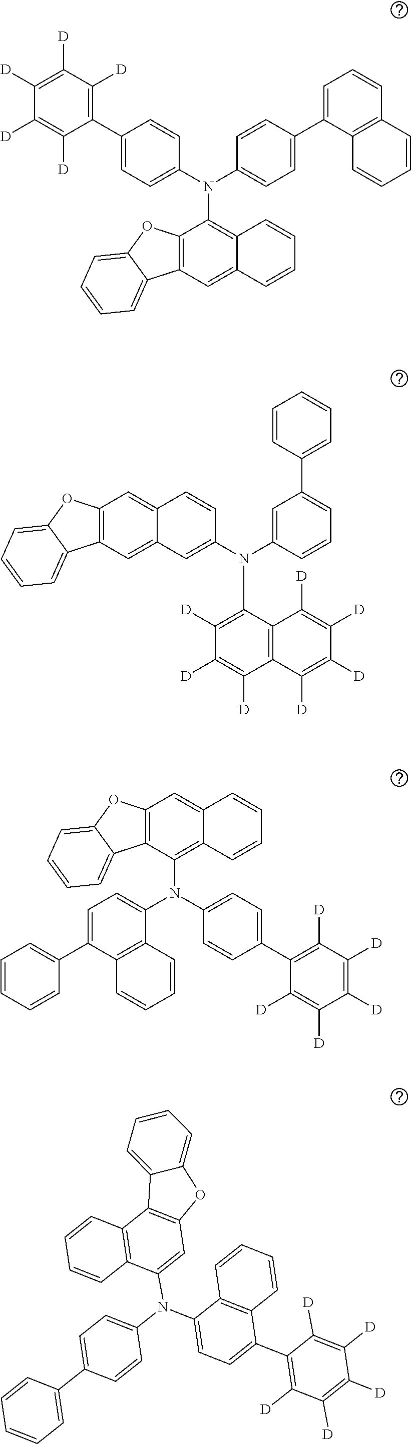 [SMILES: [2H]c1c([2H])c([2H])c(-c2ccc(N(c3ccc(-c4cccc5ccccc45)cc3)c3c4ccccc4cc4c3oc3ccccc34)cc2)c([2H])c1[2H] ; [2H]c1c([2H])c([2H])c2c(N(c3cccc(-c4ccccc4)c3)c3ccc4cc5oc6ccccc6c5cc4c3)c([2H])c([2H])c([2H])c2c1[2H] ; [2H]c1c([2H])c([2H])c(-c2ccc(N(c3ccc(-c4ccccc4)c4ccccc34)c3c4ccccc4cc4oc5ccccc5c34)cc2)c([2H])c1[2H] ; [2H]c1c([2H])c([2H])c(-c2ccc(N(c3ccc(-c4ccccc4)cc3)c3cc4oc5ccccc5c4c4ccccc34)c3ccccc23)c([2H])c1[2H]]

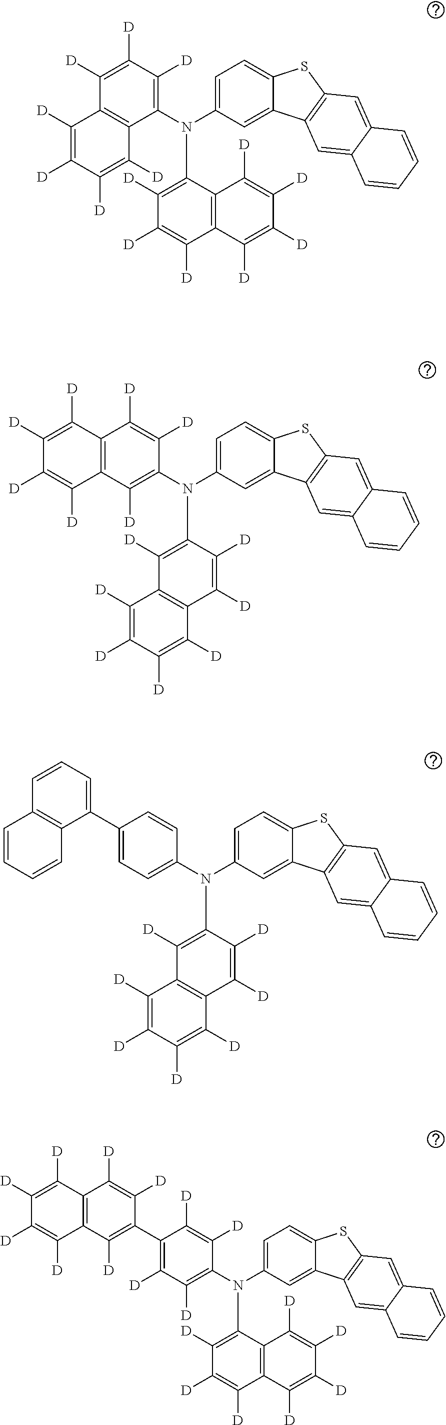

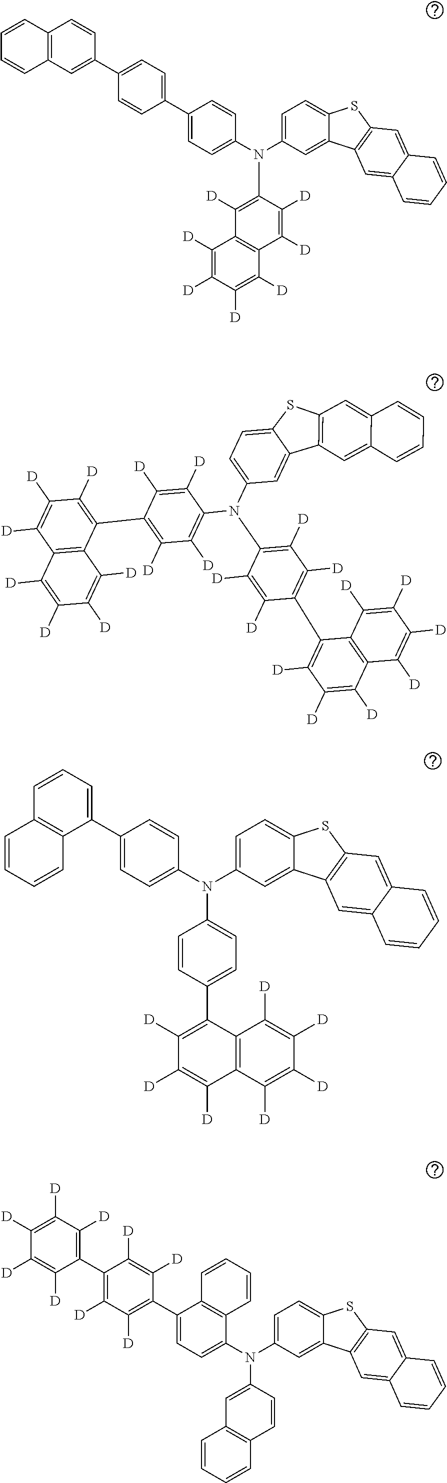

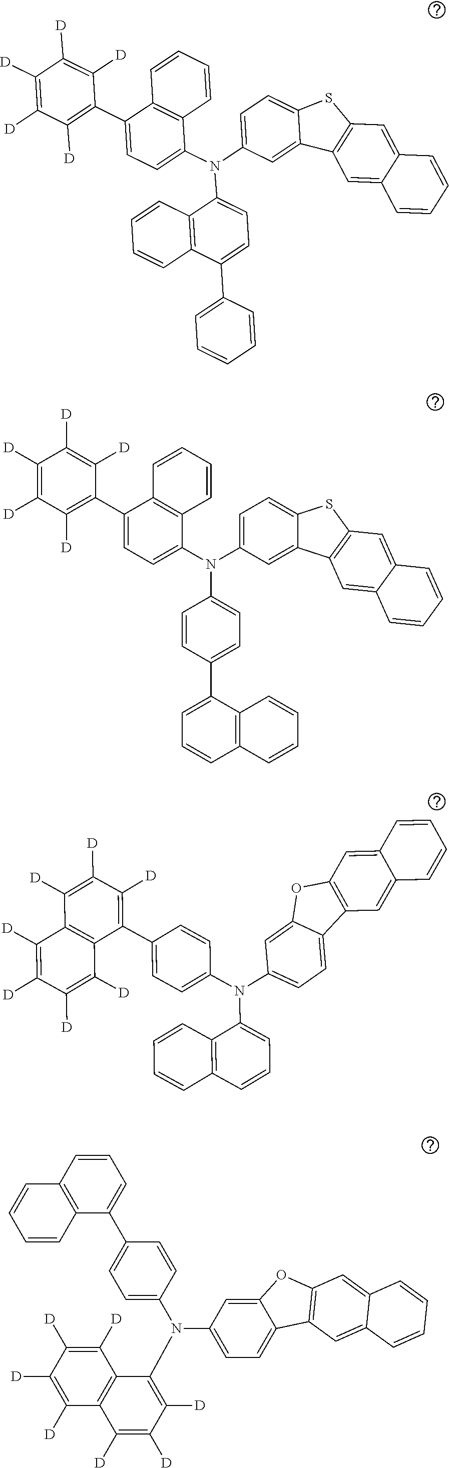 [SMILES: [2H]c1c([2H])c([2H])c(-c2ccc(N(c3ccc4sc5cc6ccccc6cc5c4c3)c3ccc(-c4ccccc4)c4ccccc34)c3ccccc23)c([2H])c1[2H] ; [2H]c1c([2H])c([2H])c(-c2ccc(N(c3ccc(-c4cccc5ccccc45)cc3)c3ccc4sc5cc6ccccc6cc5c4c3)c3ccccc23)c([2H])c1[2H] ; [2H]c1c([2H])c([2H])c2c(-c3ccc(N(c4ccc5c(c4)oc4cc6ccccc6cc45)c4cccc5ccccc45)cc3)c([2H])c([2H])c([2H])c2c1[2H] ; [2H]c1c([2H])c([2H])c2c(N(c3ccc(-c4cccc5ccccc45)cc3)c3ccc4c(c3)oc3cc5ccccc5cc34)c([2H])c([2H])c([2H])c2c1[2H]]

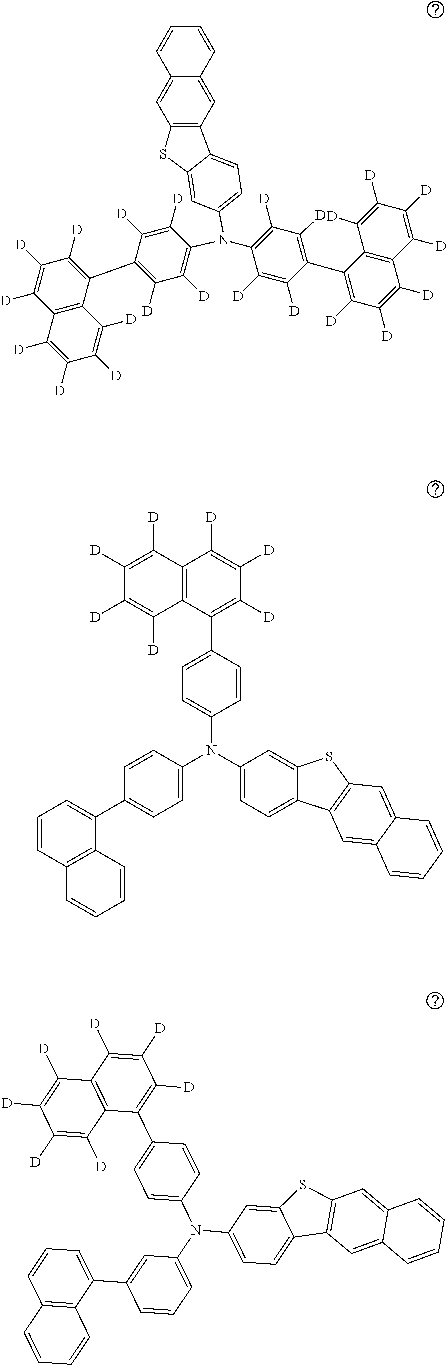 [SMILES: [2H]c1c([2H])c(N(c2ccc3c(c2)sc2cc4ccccc4cc23)c2c([2H])c([2H])c(-c3c([2H])c([2H])c([2H])c4c([2H])c([2H])c([2H])c([2H])c34)c([2H])c2[2H])c([2H])c([2H])c1-c1c([2H])c([2H])c([2H])c2c([2H])c([2H])c([2H])c([2H])c12 ; [2H]c1c([2H])c([2H])c2c(-c3ccc(N(c4ccc(-c5cccc6ccccc56)cc4)c4ccc5c(c4)sc4cc6ccccc6cc45)cc3)c([2H])c([2H])c([2H])c2c1[2H] ; [2H]c1c([2H])c([2H])c2c(-c3ccc(N(c4cccc(-c5cccc6ccccc56)c4)c4ccc5c(c4)sc4cc6ccccc6cc45)cc3)c([2H])c([2H])c([2H])c2c1[2H]]

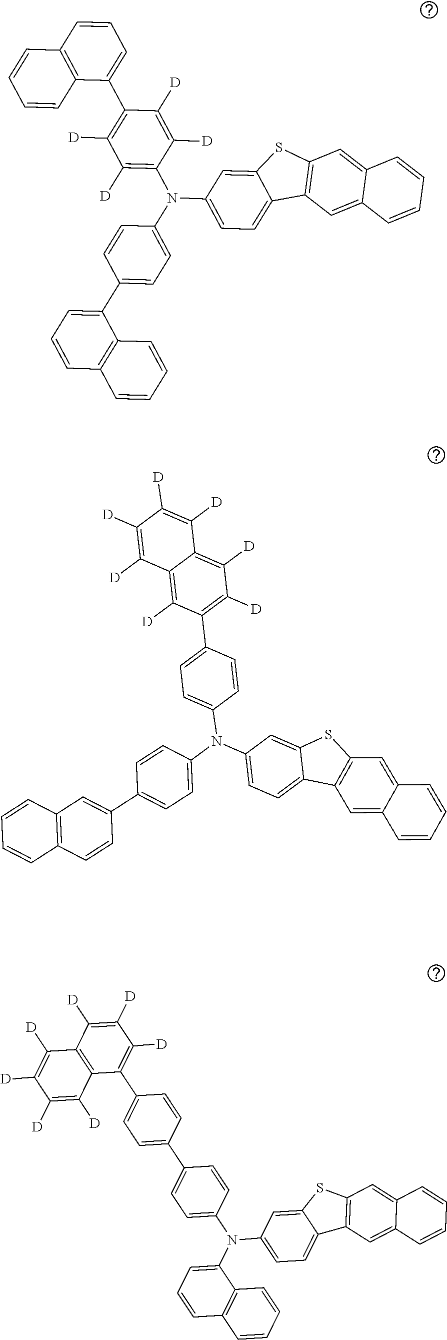 [SMILES: [2H]c1c([2H])c(N(c2ccc(-c3cccc4ccccc34)cc2)c2ccc3c(c2)sc2cc4ccccc4cc23)c([2H])c([2H])c1-c1cccc2ccccc12 ; [2H]c1c([2H])c([2H])c2c([2H])c(-c3ccc(N(c4ccc(-c5ccc6ccccc6c5)cc4)c4ccc5c(c4)sc4cc6ccccc6cc45)cc3)c([2H])c([2H])c2c1[2H] ; [2H]c1c([2H])c([2H])c2c(-c3ccc(-c4ccc(N(c5ccc6c(c5)sc5cc7ccccc7cc56)c5cccc6ccccc56)cc4)cc3)c([2H])c([2H])c([2H])c2c1[2H]]

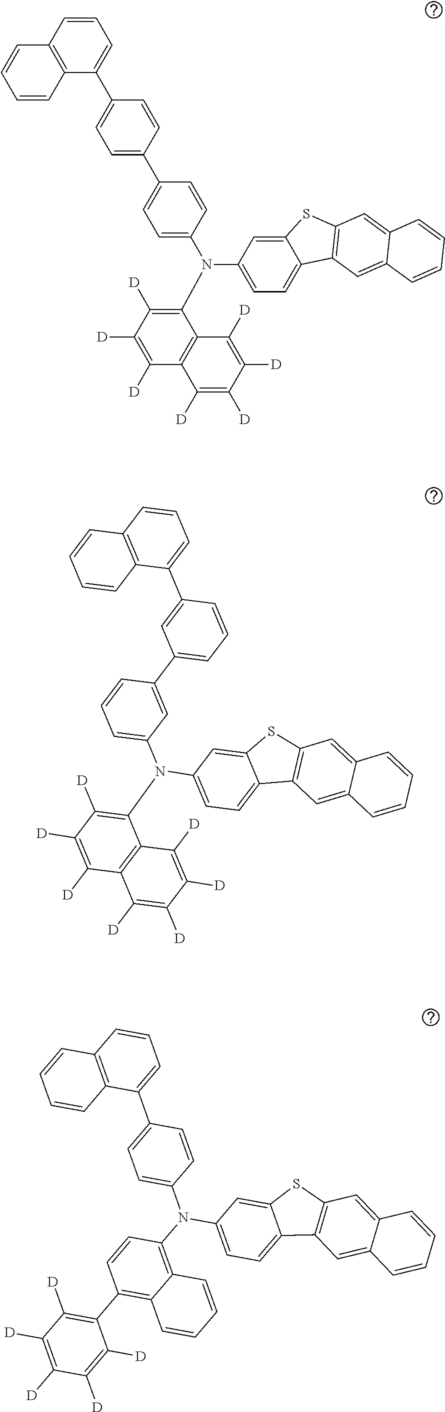 [SMILES: [2H]c1c([2H])c([2H])c2c(N(c3ccc(-c4ccc(-c5cccc6ccccc56)cc4)cc3)c3ccc4c(c3)sc3cc5ccccc5cc34)c([2H])c([2H])c([2H])c2c1[2H] ; [2H]c1c([2H])c([2H])c2c(N(c3cccc(-c4cccc(-c5cccc6ccccc56)c4)c3)c3ccc4c(c3)sc3cc5ccccc5cc34)c([2H])c([2H])c([2H])c2c1[2H] ; [2H]c1c([2H])c([2H])c(-c2ccc(N(c3ccc(-c4cccc5ccccc45)cc3)c3ccc4c(c3)sc3cc5ccccc5cc34)c3ccccc23)c([2H])c1[2H]]

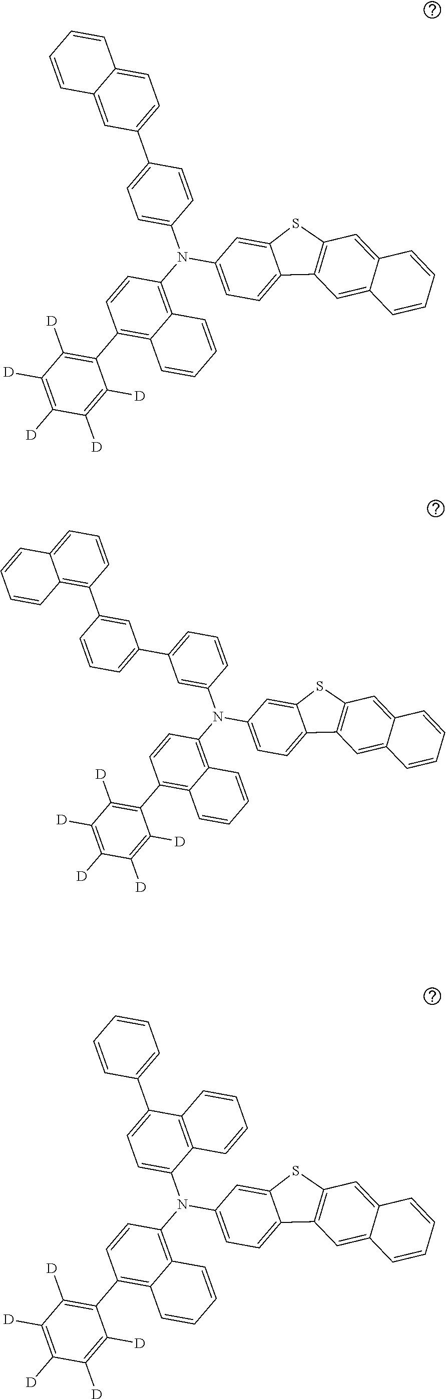 [SMILES: [2H]c1c([2H])c([2H])c(-c2ccc(N(c3ccc(-c4ccc5ccccc5c4)cc3)c3ccc4c(c3)sc3cc5ccccc5cc34)c3ccccc23)c([2H])c1[2H] ; [2H]c1c([2H])c([2H])c(-c2ccc(N(c3cccc(-c4cccc(-c5cccc6ccccc56)c4)c3)c3ccc4c(c3)sc3cc5ccccc5cc34)c3ccccc23)c([2H])c1[2H] ; [2H]c1c([2H])c([2H])c(-c2ccc(N(c3ccc4c(c3)sc3cc5ccccc5cc34)c3ccc(-c4ccccc4)c4ccccc34)c3ccccc23)c([2H])c1[2H]]

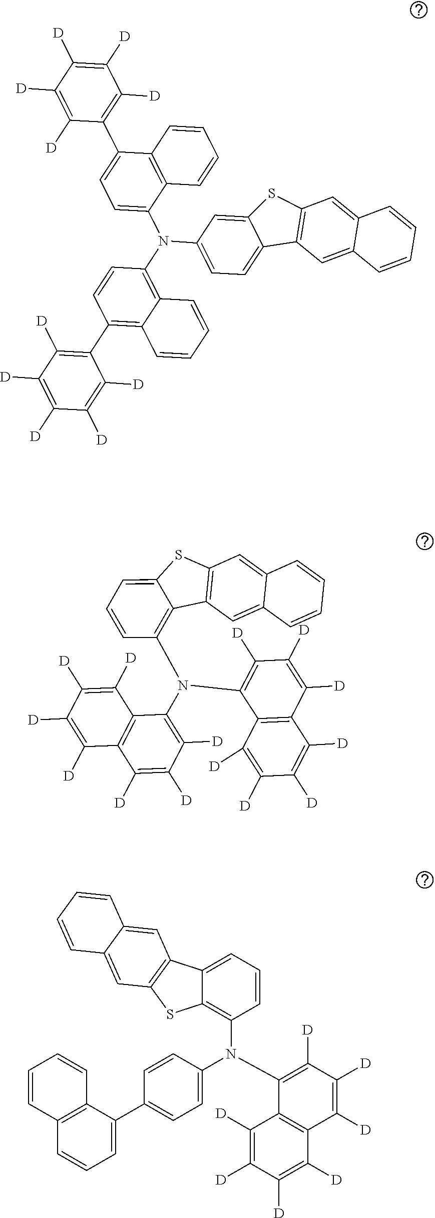 [SMILES: [2H]c1c([2H])c([2H])c(-c2ccc(N(c3ccc4c(c3)sc3cc5ccccc5cc34)c3ccc(-c4c([2H])c([2H])c([2H])c([2H])c4[2H])c4ccccc34)c3ccccc23)c([2H])c1[2H] ; [2H]c1c([2H])c([2H])c2c(N(c3c([2H])c([2H])c([2H])c4c([2H])c([2H])c([2H])c([2H])c34)c3cccc4sc5cc6ccccc6cc5c34)c([2H])c([2H])c([2H])c2c1[2H] ; [2H]c1c([2H])c([2H])c2c(N(c3ccc(-c4cccc5ccccc45)cc3)c3cccc4c3sc3cc5ccccc5cc34)c([2H])c([2H])c([2H])c2c1[2H]]

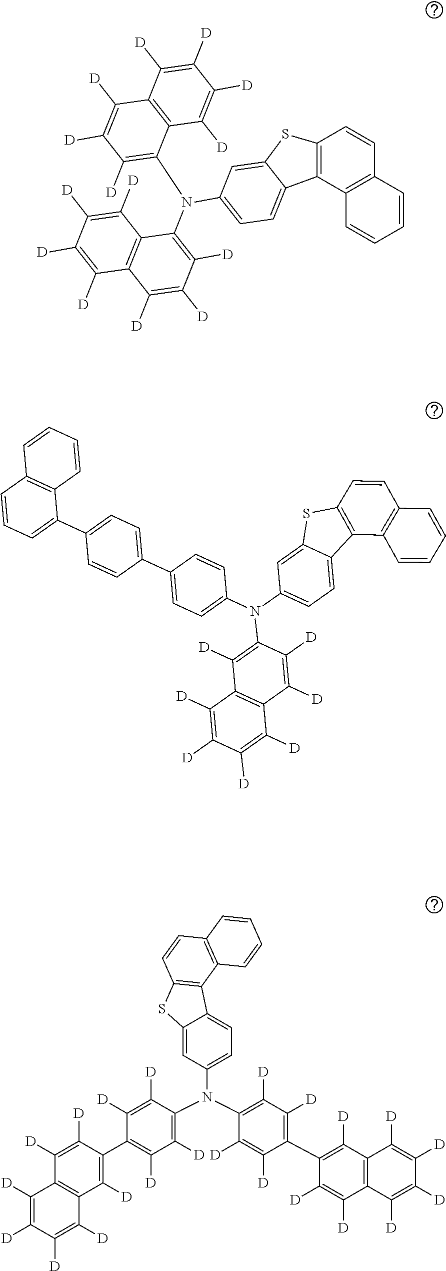 [SMILES: [2H]c1c([2H])c([2H])c2c(N(c3ccc4c(c3)sc3ccc5ccccc5c34)c3c([2H])c([2H])c([2H])c4c([2H])c([2H])c([2H])c([2H])c34)c([2H])c([2H])c([2H])c2c1[2H] ; [2H]c1c([2H])c([2H])c2c([2H])c(N(c3ccc(-c4ccc(-c5cccc6ccccc56)cc4)cc3)c3ccc4c(c3)sc3ccc5ccccc5c34)c([2H])c([2H])c2c1[2H] ; [2H]c1c([2H])c(N(c2ccc3c(c2)sc2ccc4ccccc4c23)c2c([2H])c([2H])c(-c3c([2H])c([2H])c4c([2H])c([2H])c([2H])c([2H])c4c3[2H])c([2H])c2[2H])c([2H])c([2H])c1-c1c([2H])c([2H])c2c([2H])c([2H])c([2H])c([2H])c2c1[2H]]

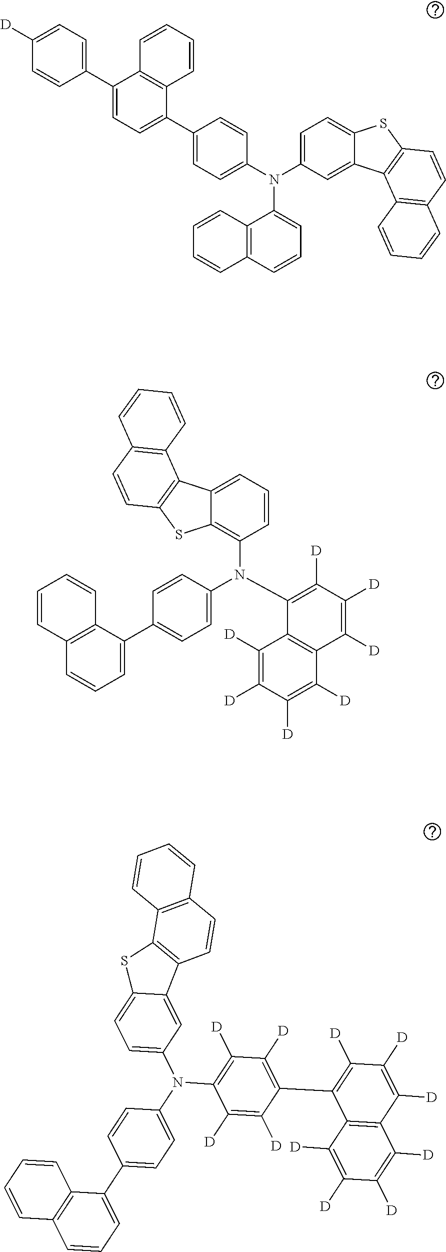 [SMILES: [2H]c1ccc(-c2ccc(-c3ccc(N(c4ccc5sc6ccc7ccccc7c6c5c4)c4cccc5ccccc45)cc3)c3ccccc23)cc1 ; [2H]c1c([2H])c([2H])c2c(N(c3ccc(-c4cccc5ccccc45)cc3)c3cccc4c3sc3ccc5ccccc5c34)c([2H])c([2H])c([2H])c2c1[2H] ; [2H]c1c([2H])c(N(c2ccc(-c3cccc4ccccc34)cc2)c2ccc3sc4c5ccccc5ccc4c3c2)c([2H])c([2H])c1-c1c([2H])c([2H])c([2H])c2c([2H])c([2H])c([2H])c([2H])c12]

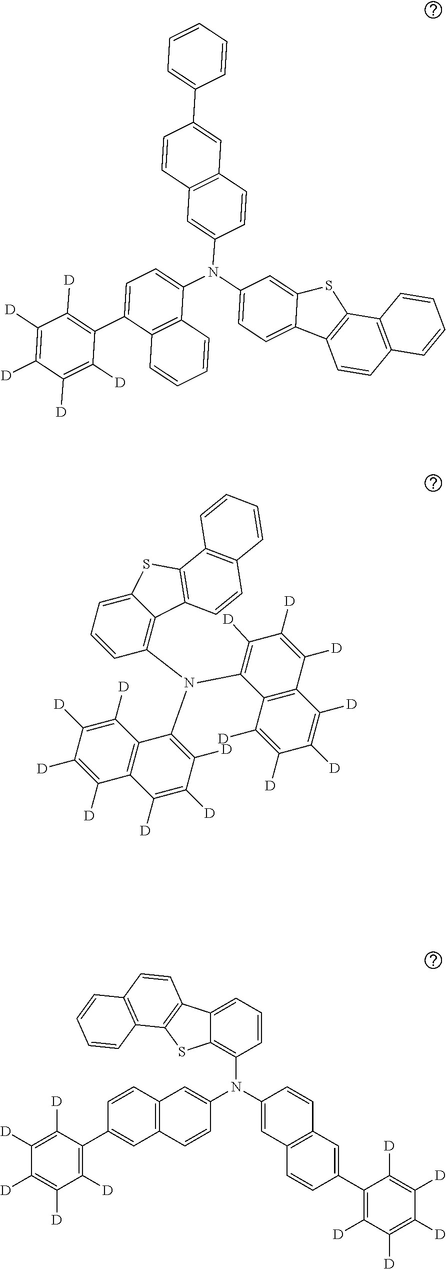 [SMILES: [2H]c1c([2H])c([2H])c(-c2ccc(N(c3ccc4cc(-c5ccccc5)ccc4c3)c3ccc4c(c3)sc3c5ccccc5ccc43)c3ccccc23)c([2H])c1[2H] ; [2H]c1c([2H])c([2H])c2c(N(c3c([2H])c([2H])c([2H])c4c([2H])c([2H])c([2H])c([2H])c34)c3cccc4sc5c6ccccc6ccc5c34)c([2H])c([2H])c([2H])c2c1[2H] ; [2H]c1c([2H])c([2H])c(-c2ccc3cc(N(c4ccc5cc(-c6c([2H])c([2H])c([2H])c([2H])c6[2H])ccc5c4)c4cccc5c4sc4c6ccccc6ccc54)ccc3c2)c([2H])c1[2H]]

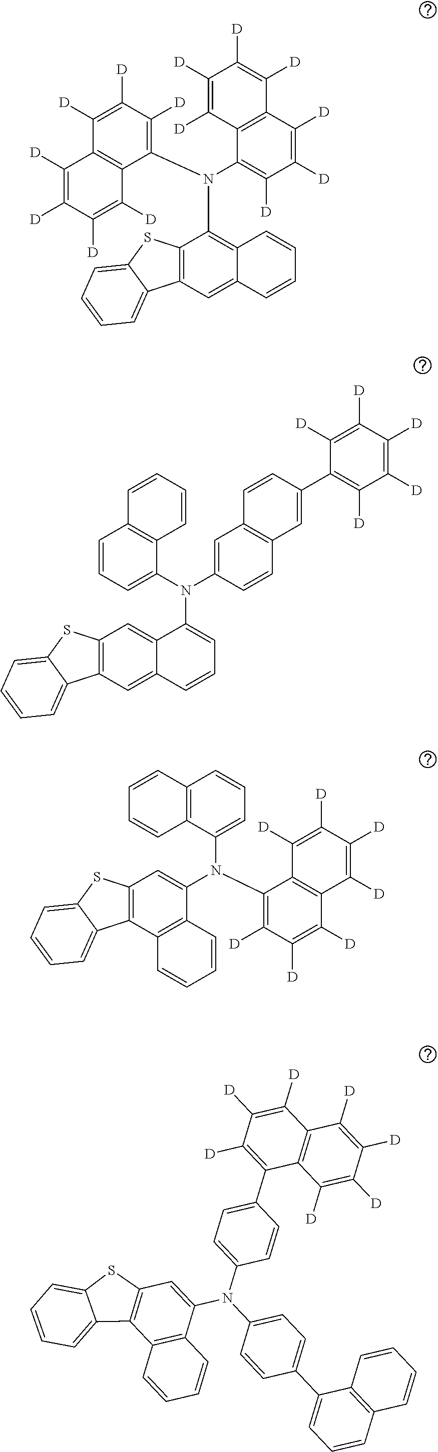 [SMILES: [2H]c1c([2H])c([2H])c2c(N(c3c4ccccc4cc4c3sc3ccccc34)c3c([2H])c([2H])c([2H])c4c([2H])c([2H])c([2H])c([2H])c34)c([2H])c([2H])c([2H])c2c1[2H] ; [2H]c1c([2H])c([2H])c(-c2ccc3cc(N(c4cccc5ccccc45)c4cccc5cc6c(cc45)sc4ccccc46)ccc3c2)c([2H])c1[2H] ; [2H]c1c([2H])c([2H])c2c(N(c3cccc4ccccc34)c3cc4sc5ccccc5c4c4ccccc34)c([2H])c([2H])c([2H])c2c1[2H] ; [2H]c1c([2H])c([2H])c2c(-c3ccc(N(c4ccc(-c5cccc6ccccc56)cc4)c4cc5sc6ccccc6c5c5ccccc45)cc3)c([2H])c([2H])c([2H])c2c1[2H]]

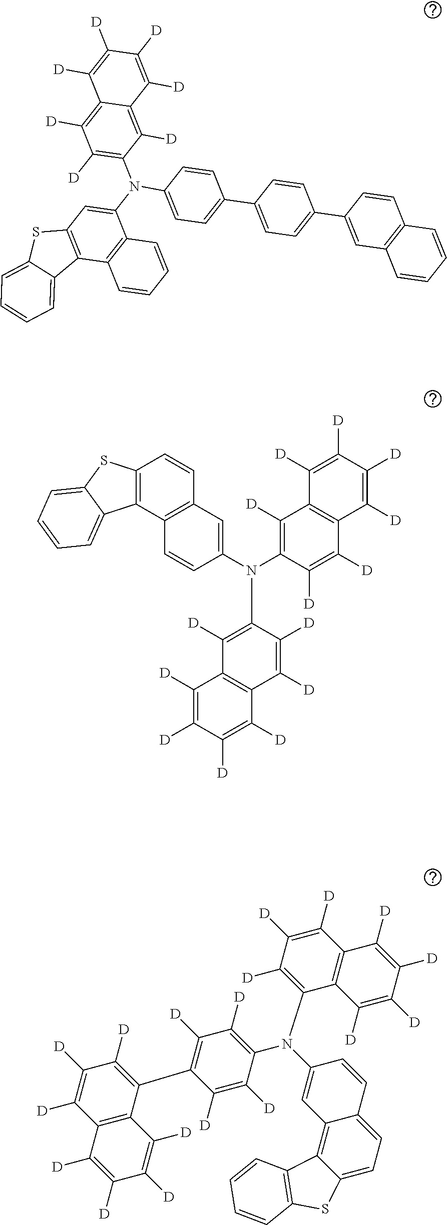 [SMILES: [2H]c1c([2H])c([2H])c2c([2H])c(N(c3ccc(-c4ccc(-c5ccc6ccccc6c5)cc4)cc3)c3cc4sc5ccccc5c4c4ccccc34)c([2H])c([2H])c2c1[2H] ; [2H]c1c([2H])c([2H])c2c([2H])c(N(c3ccc4c(ccc5sc6ccccc6c54)c3)c3c([2H])c([2H])c4c([2H])c([2H])c([2H])c([2H])c4c3[2H])c([2H])c([2H])c2c1[2H] ; [2H]c1c([2H])c(N(c2ccc3ccc4sc5ccccc5c4c3c2)c2c([2H])c([2H])c([2H])c3c([2H])c([2H])c([2H])c([2H])c23)c([2H])c([2H])c1-c1c([2H])c([2H])c([2H])c2c([2H])c([2H])c([2H])c([2H])c12]

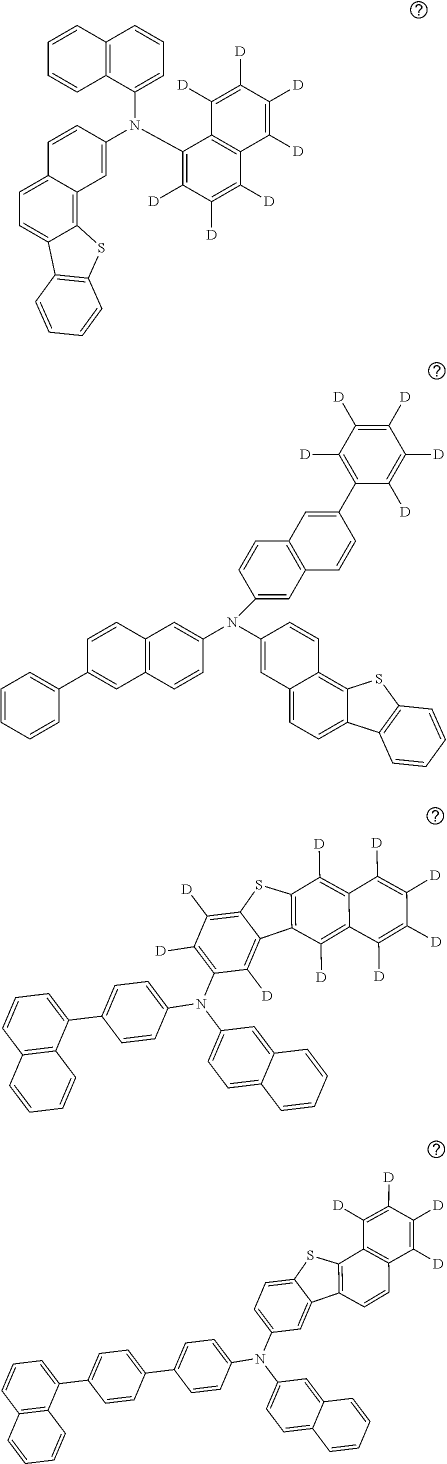 [SMILES: [2H]c1c([2H])c([2H])c2c(N(c3ccc4ccc5c6ccccc6sc5c4c3)c3cccc4ccccc34)c([2H])c([2H])c([2H])c2c1[2H] ; [2H]c1c([2H])c([2H])c(-c2ccc3cc(N(c4ccc5cc(-c6ccccc6)ccc5c4)c4ccc5c(ccc6c7ccccc7sc56)c4)ccc3c2)c([2H])c1[2H] ; [2H]c1c(N(c2ccc(-c3cccc4ccccc34)cc2)c2ccc3ccccc3c2)c([2H])c2c(sc3c([2H])c4c([2H])c([2H])c([2H])c([2H])c4c([2H])c32)c1[2H] ; [2H]c1c([2H])c([2H])c2c(ccc3c4cc(N(c5ccc(-c6ccc(-c7cccc8ccccc78)cc6)cc5)c5ccc6ccccc6c5)ccc4sc32)c1[2H]]

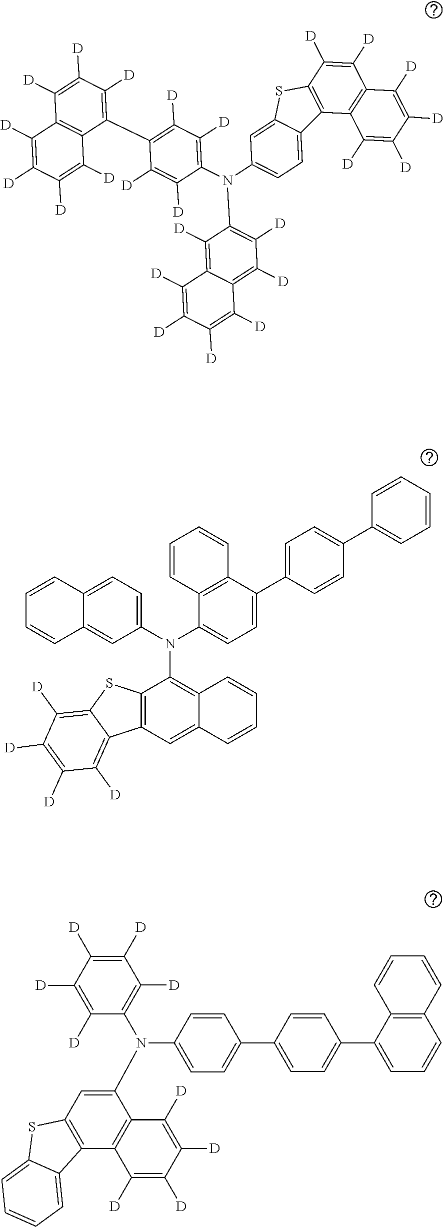 [SMILES: [2H]c1c([2H])c(N(c2ccc3c(c2)sc2c([2H])c([2H])c4c([2H])c([2H])c([2H])c([2H])c4c23)c2c([2H])c([2H])c3c([2H])c([2H])c([2H])c([2H])c3c2[2H])c([2H])c([2H])c1-c1c([2H])c([2H])c([2H])c2c([2H])c([2H])c([2H])c([2H])c12 ; [2H]c1c([2H])c([2H])c2c(sc3c(N(c4ccc5ccccc5c4)c4ccc(-c5ccc(-c6ccccc6)cc5)c5ccccc45)c4ccccc4cc32)c1[2H] ; [2H]c1c([2H])c([2H])c(N(c2ccc(-c3ccc(-c4cccc5ccccc45)cc3)cc2)c2cc3sc4ccccc4c3c3c([2H])c([2H])c([2H])c([2H])c23)c([2H])c1[2H]]

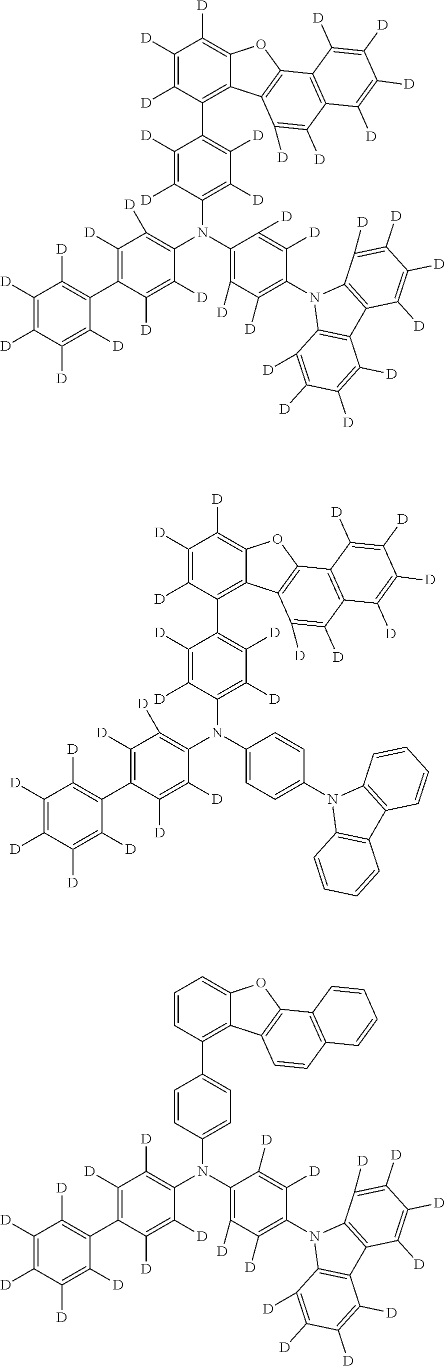

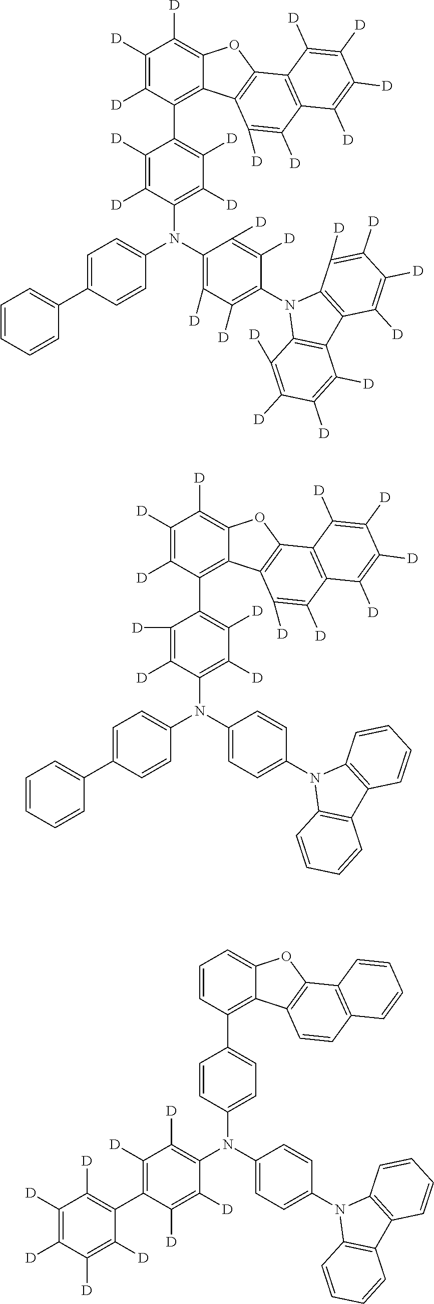

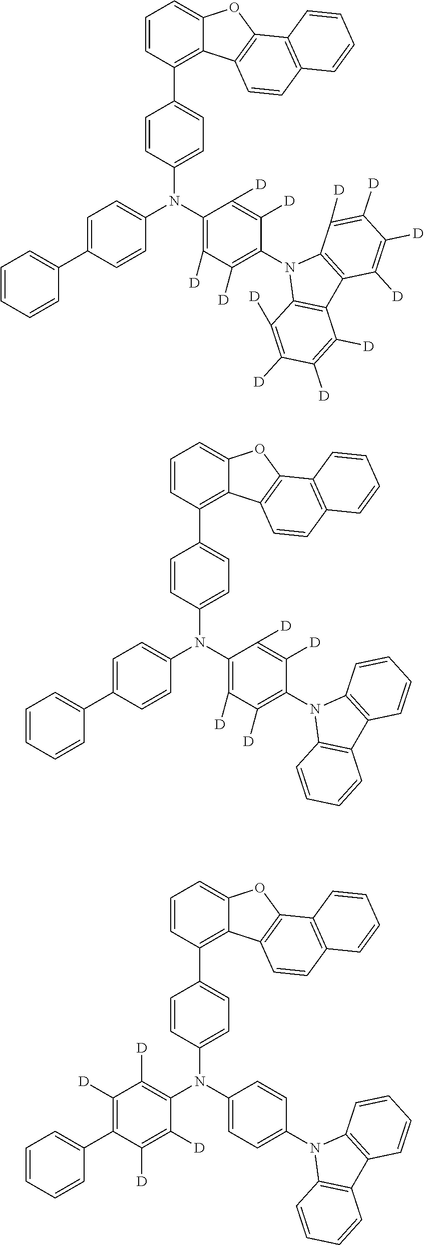 [SMILES: [2H]c1c([2H])c(-n2c3c([2H])c([2H])c([2H])c([2H])c3c3c([2H])c([2H])c([2H])c([2H])c32)c([2H])c([2H])c1N(c1ccc(-c2ccccc2)cc1)c1ccc(-c2cccc3oc4c5ccccc5ccc4c23)cc1 ; [2H]c1c([2H])c(-n2c3ccccc3c3ccccc32)c([2H])c([2H])c1N(c1ccc(-c2ccccc2)cc1)c1ccc(-c2cccc3oc4c5ccccc5ccc4c23)cc1 ; [2H]c1c([2H])c(N(c2ccc(-c3cccc4oc5c6ccccc6ccc5c34)cc2)c2ccc(-n3c4ccccc4c4ccccc43)cc2)c([2H])c([2H])c1-c1ccccc1]

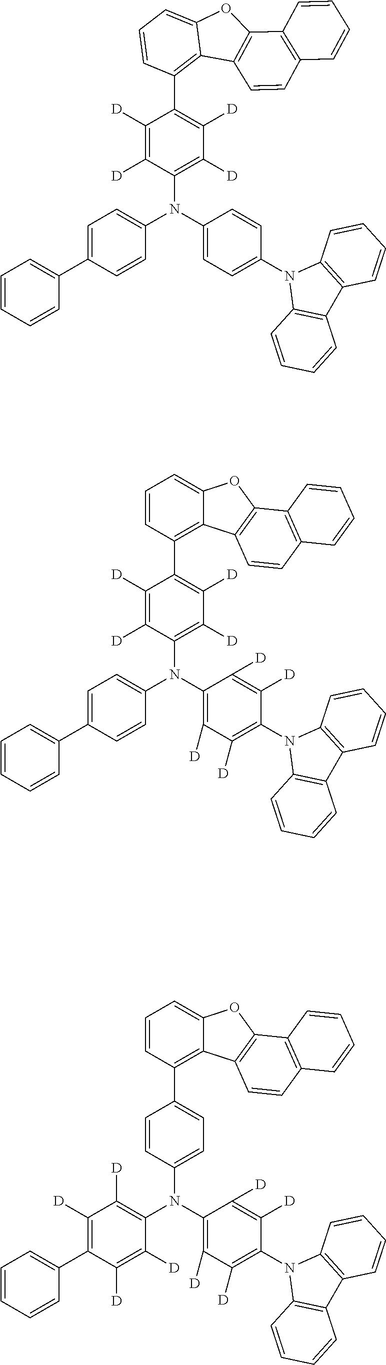 [SMILES: [2H]c1c([2H])c(N(c2ccc(-c3ccccc3)cc2)c2ccc(-n3c4ccccc4c4ccccc43)cc2)c([2H])c([2H])c1-c1cccc2oc3c4ccccc4ccc3c12 ; [2H]c1c([2H])c(N(c2ccc(-c3ccccc3)cc2)c2c([2H])c([2H])c(-n3c4ccccc4c4ccccc43)c([2H])c2[2H])c([2H])c([2H])c1-c1cccc2oc3c4ccccc4ccc3c12 ; [2H]c1c([2H])c(N(c2ccc(-c3cccc4oc5c6ccccc6ccc5c34)cc2)c2c([2H])c([2H])c(-n3c4ccccc4c4ccccc43)c([2H])c2[2H])c([2H])c([2H])c1-c1ccccc1]

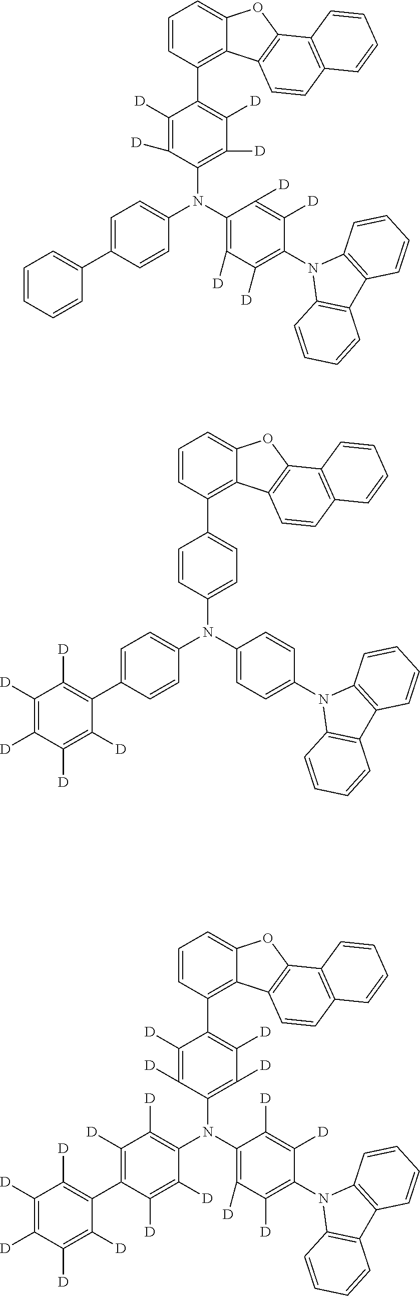 [SMILES: [2H]c1c([2H])c(N(c2ccc(-c3ccccc3)cc2)c2c([2H])c([2H])c(-n3c4ccccc4c4ccccc43)c([2H])c2[2H])c([2H])c([2H])c1-c1cccc2oc3c4ccccc4ccc3c12 ; [2H]c1c([2H])c([2H])c(-c2ccc(N(c3ccc(-c4cccc5oc6c7ccccc7ccc6c45)cc3)c3ccc(-n4c5ccccc5c5ccccc54)cc3)cc2)c([2H])c1[2H] ; [2H]c1c([2H])c([2H])c(-c2c([2H])c([2H])c(N(c3c([2H])c([2H])c(-c4cccc5oc6c7ccccc7ccc6c45)c([2H])c3[2H])c3c([2H])c([2H])c(-n4c5ccccc5c5ccccc54)c([2H])c3[2H])c([2H])c2[2H])c([2H])c1[2H]]

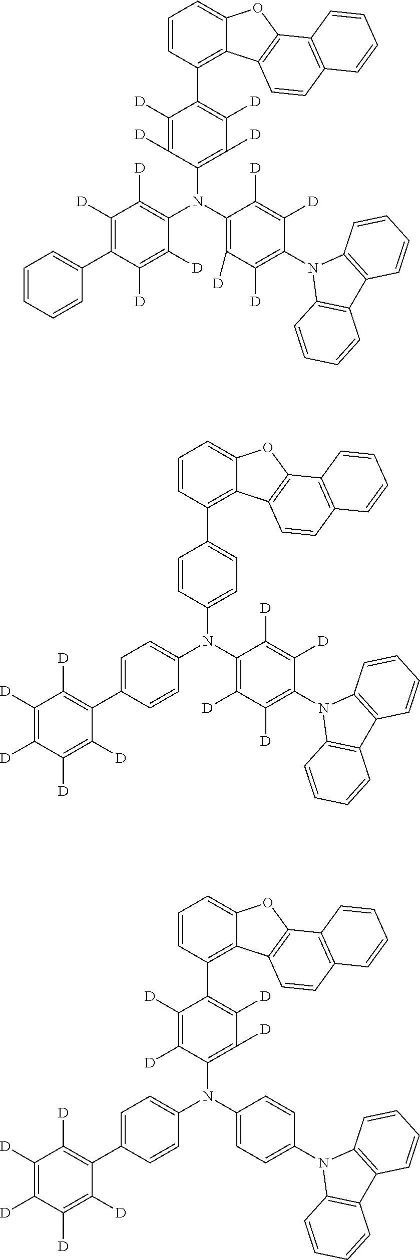 [SMILES: [2H]c1c([2H])c(N(c2c([2H])c([2H])c(-c3cccc4oc5c6ccccc6ccc5c34)c([2H])c2[2H])c2c([2H])c([2H])c(-n3c4ccccc4c4ccccc43)c([2H])c2[2H])c([2H])c([2H])c1-c1ccccc1 ; [2H]c1c([2H])c([2H])c(-c2ccc(N(c3ccc(-c4cccc5oc6c7ccccc7ccc6c45)cc3)c3c([2H])c([2H])c(-n4c5ccccc5c5ccccc54)c([2H])c3[2H])cc2)c([2H])c1[2H] ; [2H]c1c([2H])c([2H])c(-c2ccc(N(c3ccc(-n4c5ccccc5c5ccccc54)cc3)c3c([2H])c([2H])c(-c4cccc5oc6c7ccccc7ccc6c45)c([2H])c3[2H])cc2)c([2H])c1[2H]]

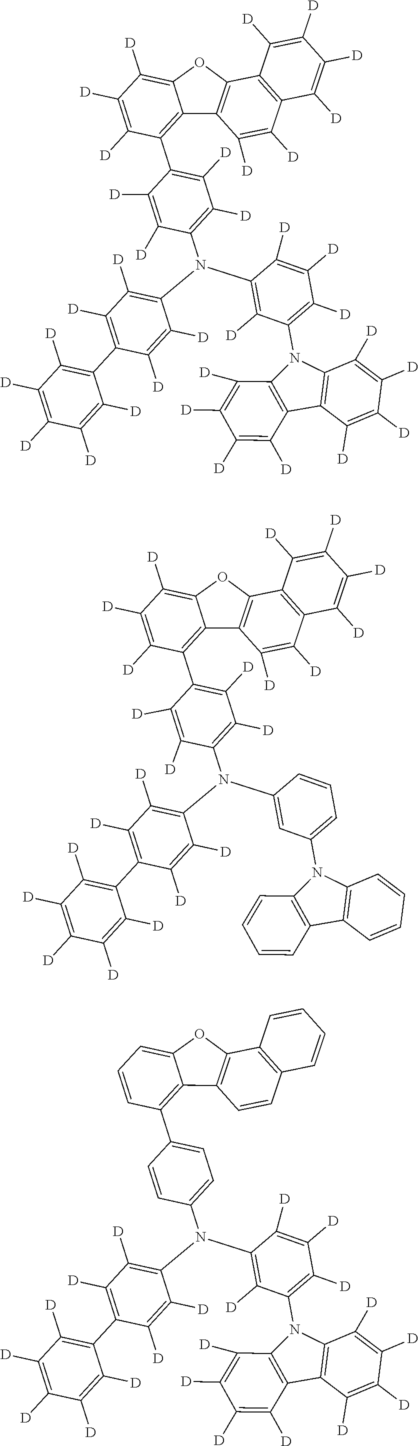

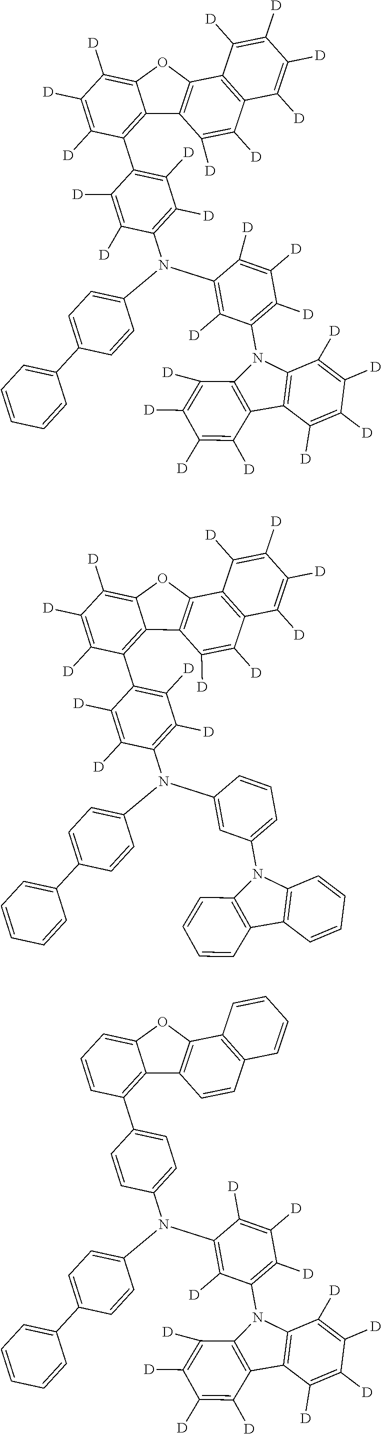

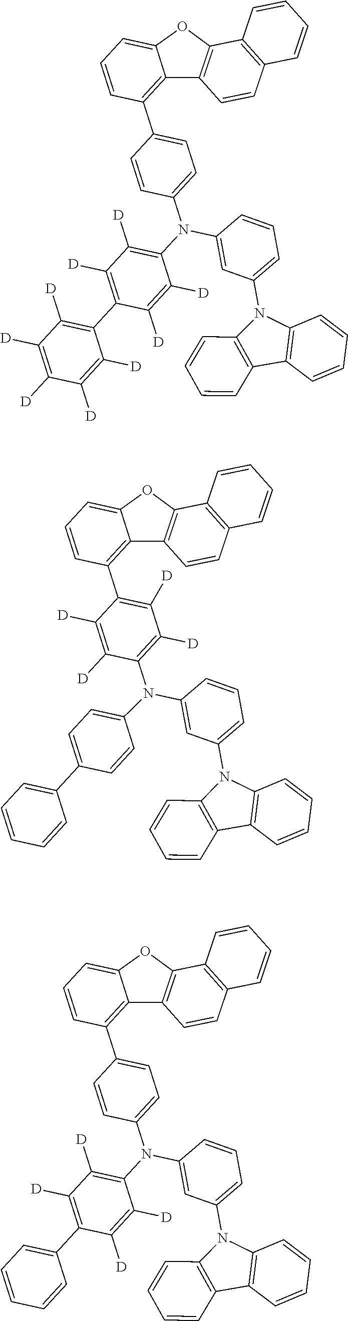 [SMILES: [2H]c1c([2H])c([2H])c(-c2c([2H])c([2H])c(N(c3ccc(-c4cccc5oc6c7ccccc7ccc6c45)cc3)c3cccc(-n4c5ccccc5c5ccccc54)c3)c([2H])c2[2H])c([2H])c1[2H] ; [2H]c1c([2H])c(N(c2ccc(-c3ccccc3)cc2)c2cccc(-n3c4ccccc4c4ccccc43)c2)c([2H])c([2H])c1-c1cccc2oc3c4ccccc4ccc3c12 ; [2H]c1c([2H])c(N(c2ccc(-c3cccc4oc5c6ccccc6ccc5c34)cc2)c2cccc(-n3c4ccccc4c4ccccc43)c2)c([2H])c([2H])c1-c1ccccc1]

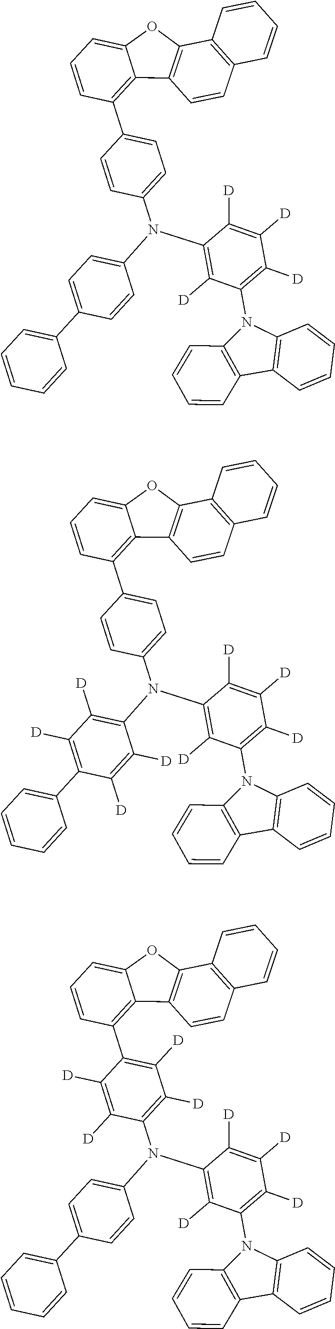 [SMILES: [2H]c1c([2H])c(N(c2ccc(-c3ccccc3)cc2)c2ccc(-c3cccc4oc5c6ccccc6ccc5c34)cc2)c([2H])c(-n2c3ccccc3c3ccccc32)c1[2H] ; [2H]c1c([2H])c(N(c2ccc(-c3cccc4oc5c6ccccc6ccc5c34)cc2)c2c([2H])c([2H])c(-c3ccccc3)c([2H])c2[2H])c([2H])c(-n2c3ccccc3c3ccccc32)c1[2H] ; [2H]c1c([2H])c(N(c2ccc(-c3ccccc3)cc2)c2c([2H])c([2H])c(-c3cccc4oc5c6ccccc6ccc5c34)c([2H])c2[2H])c([2H])c(-n2c3ccccc3c3ccccc32)c1[2H]]

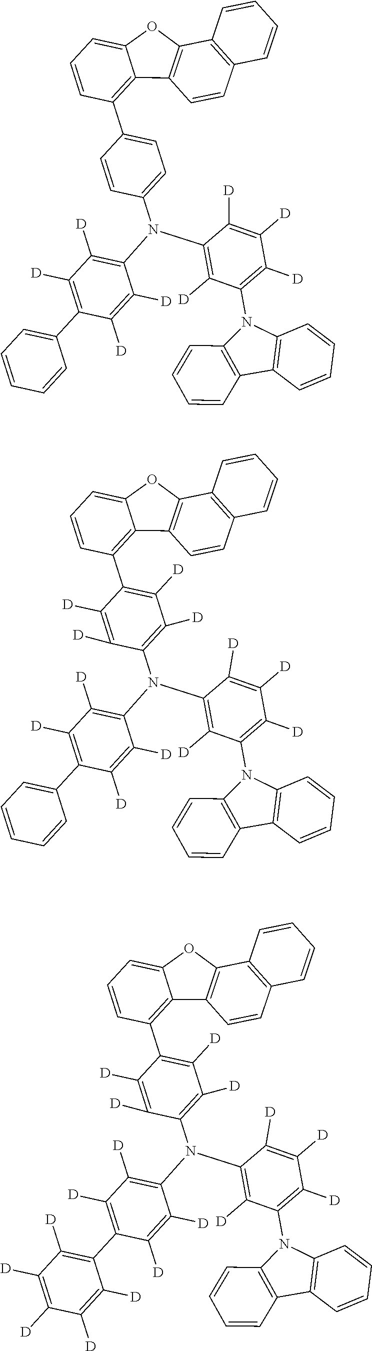 [SMILES: [2H]c1c([2H])c(N(c2ccc(-c3cccc4oc5c6ccccc6ccc5c34)cc2)c2c([2H])c([2H])c(-c3ccccc3)c([2H])c2[2H])c([2H])c(-n2c3ccccc3c3ccccc32)c1[2H] ; [2H]c1c([2H])c(N(c2c([2H])c([2H])c(-c3ccccc3)c([2H])c2[2H])c2c([2H])c([2H])c(-c3cccc4oc5c6ccccc6ccc5c34)c([2H])c2[2H])c([2H])c(-n2c3ccccc3c3ccccc32)c1[2H] ; [2H]c1c([2H])c([2H])c(-c2c([2H])c([2H])c(N(c3c([2H])c([2H])c(-c4cccc5oc6c7ccccc7ccc6c45)c([2H])c3[2H])c3c([2H])c([2H])c([2H])c(-n4c5ccccc5c5ccccc54)c3[2H])c([2H])c2[2H])c([2H])c1[2H]]

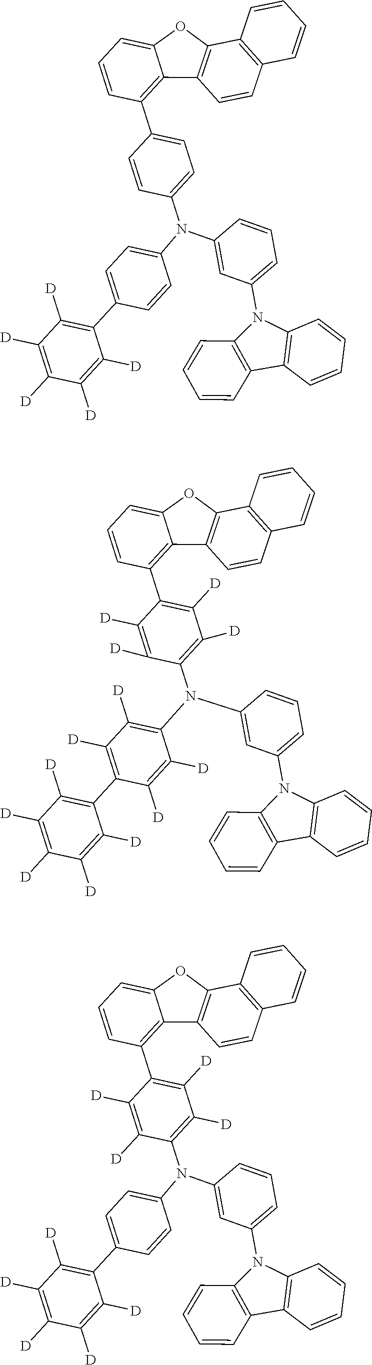 [SMILES: [2H]c1c([2H])c([2H])c(-c2ccc(N(c3ccc(-c4cccc5oc6c7ccccc7ccc6c45)cc3)c3cccc(-n4c5ccccc5c5ccccc54)c3)cc2)c([2H])c1[2H] ; [2H]c1c([2H])c([2H])c(-c2c([2H])c([2H])c(N(c3cccc(-n4c5ccccc5c5ccccc54)c3)c3c([2H])c([2H])c(-c4cccc5oc6c7ccccc7ccc6c45)c([2H])c3[2H])c([2H])c2[2H])c([2H])c1[2H] ; [2H]c1c([2H])c([2H])c(-c2ccc(N(c3cccc(-n4c5ccccc5c5ccccc54)c3)c3c([2H])c([2H])c(-c4cccc5oc6c7ccccc7ccc6c45)c([2H])c3[2H])cc2)c([2H])c1[2H]]

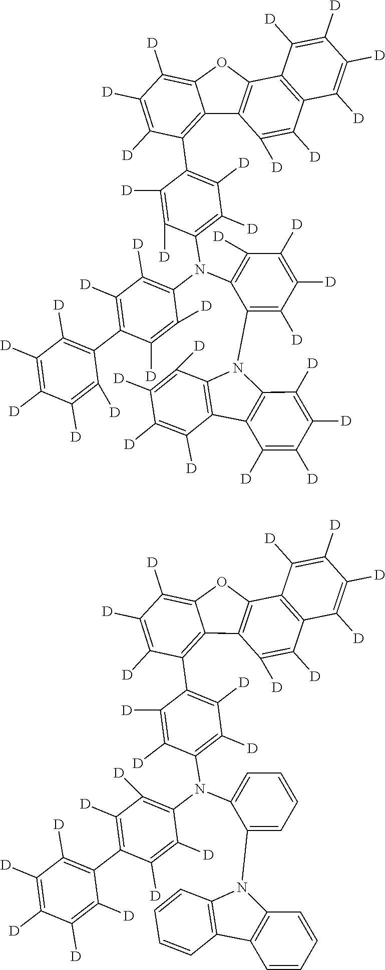 [SMILES: [2H]c1c([2H])c([2H])c(-c2c([2H])c([2H])c(N(c3c([2H])c([2H])c(-c4c([2H])c([2H])c([2H])c5oc6c7c([2H])c([2H])c([2H])c([2H])c7c([2H])c([2H])c6c45)c([2H])c3[2H])c3c([2H])c([2H])c([2H])c([2H])c3-n3c4c([2H])c([2H])c([2H])c([2H])c4c4c([2H])c([2H])c([2H])c([2H])c43)c([2H])c2[2H])c([2H])c1[2H] ; [2H]c1c([2H])c([2H])c(-c2c([2H])c([2H])c(N(c3ccccc3-n3c4ccccc4c4ccccc43)c3c([2H])c([2H])c(-c4c([2H])c([2H])c([2H])c5oc6c7c([2H])c([2H])c([2H])c([2H])c7c([2H])c([2H])c6c45)c([2H])c3[2H])c([2H])c2[2H])c([2H])c1[2H]]

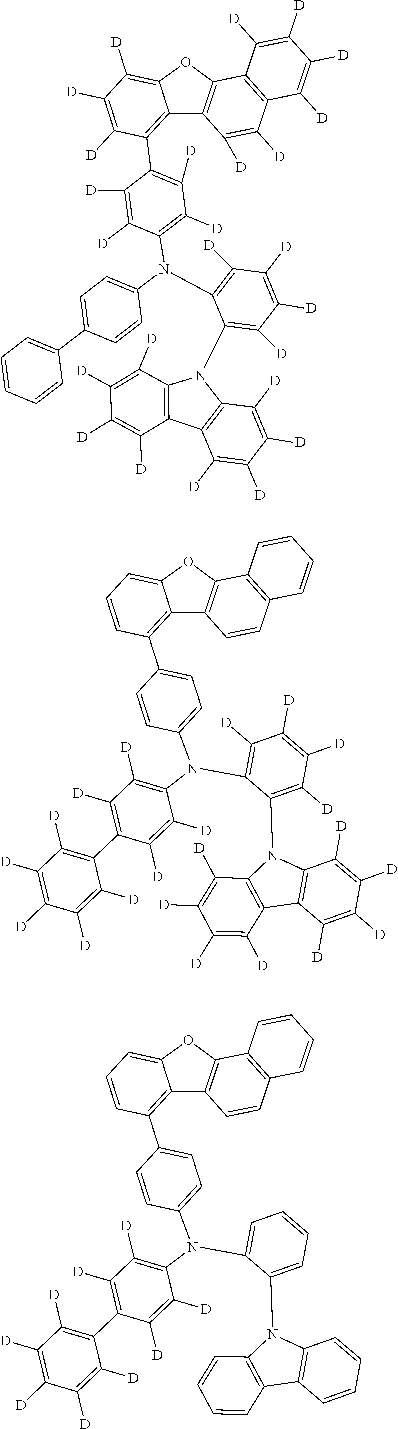

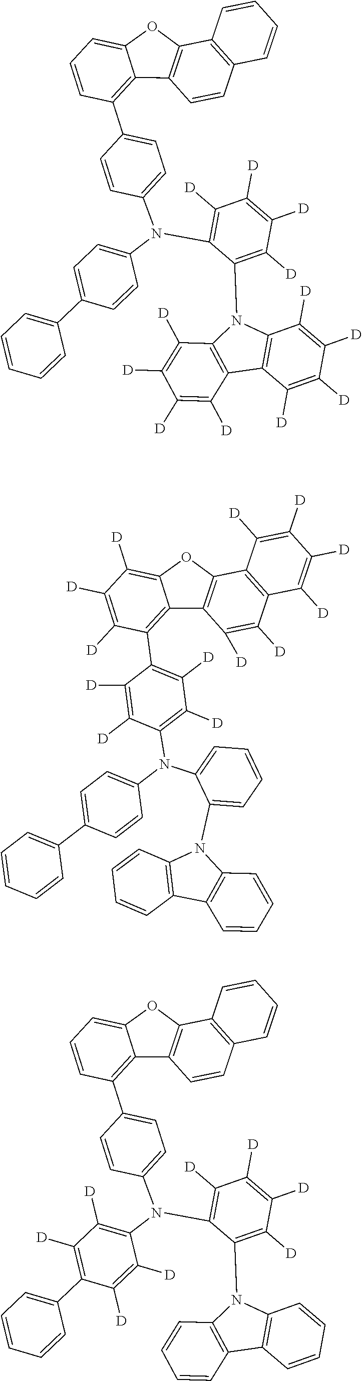 [SMILES: [2H]c1c([2H])c([2H])c(-n2c3c([2H])c([2H])c([2H])c([2H])c3c3c([2H])c([2H])c([2H])c([2H])c32)c(N(c2ccc(-c3ccccc3)cc2)c2ccc(-c3cccc4oc5c6ccccc6ccc5c34)cc2)c1[2H] ; [2H]c1c([2H])c(N(c2ccc(-c3ccccc3)cc2)c2ccccc2-n2c3ccccc3c3ccccc32)c([2H])c([2H])c1-c1c([2H])c([2H])c([2H])c2oc3c4c([2H])c([2H])c([2H])c([2H])c4c([2H])c([2H])c3c12 ; [2H]c1c([2H])c([2H])c(-n2c3ccccc3c3ccccc32)c(N(c2ccc(-c3cccc4oc5c6ccccc6ccc5c34)cc2)c2c([2H])c([2H])c(-c3ccccc3)c([2H])c2[2H])c1[2H]]

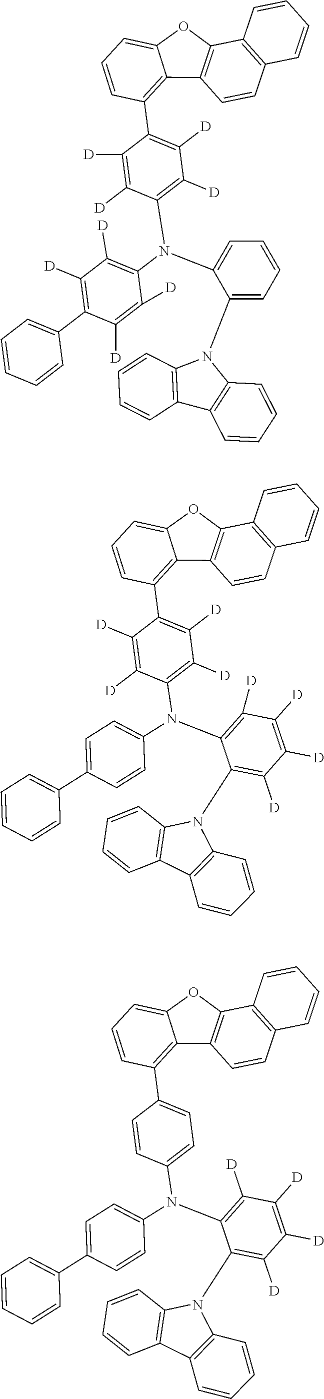 [SMILES: [2H]c1c([2H])c(N(c2ccccc2-n2c3ccccc3c3ccccc32)c2c([2H])c([2H])c(-c3cccc4oc5c6ccccc6ccc5c34)c([2H])c2[2H])c([2H])c([2H])c1-c1ccccc1 ; [2H]c1c([2H])c([2H])c(-n2c3ccccc3c3ccccc32)c(N(c2ccc(-c3ccccc3)cc2)c2c([2H])c([2H])c(-c3cccc4oc5c6ccccc6ccc5c34)c([2H])c2[2H])c1[2H] ; [2H]c1c([2H])c([2H])c(-n2c3ccccc3c3ccccc32)c(N(c2ccc(-c3ccccc3)cc2)c2ccc(-c3cccc4oc5c6ccccc6ccc5c34)cc2)c1[2H]]

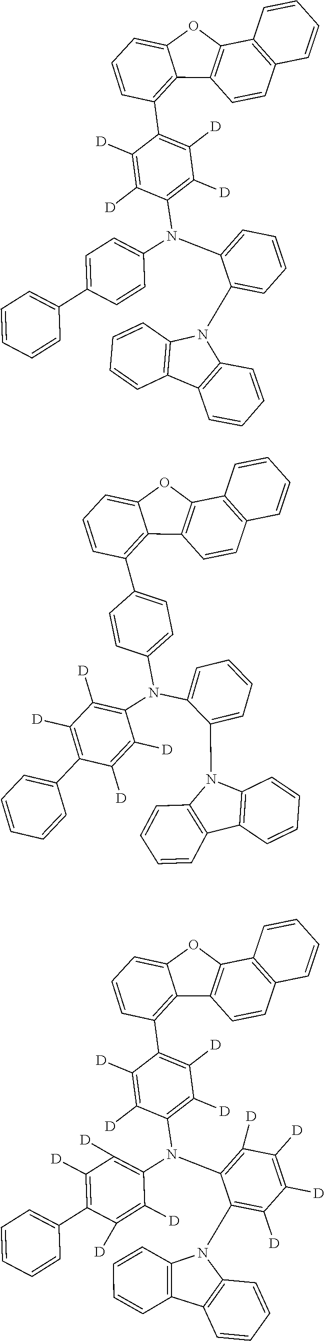

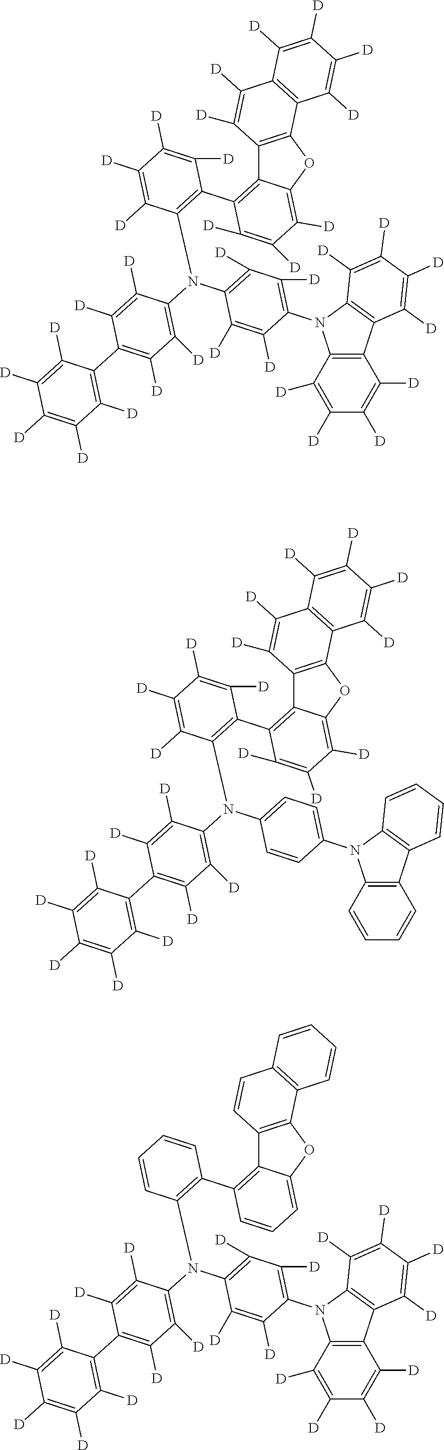

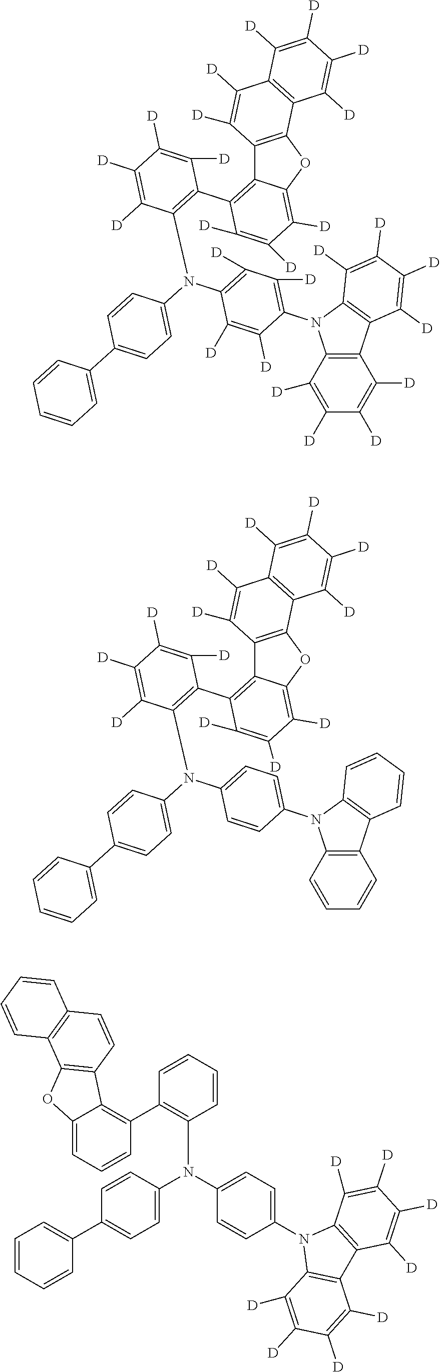

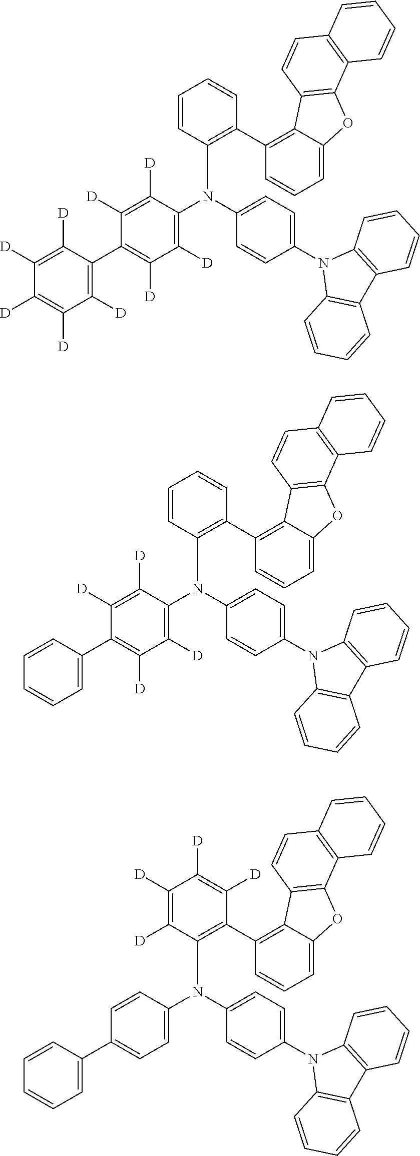

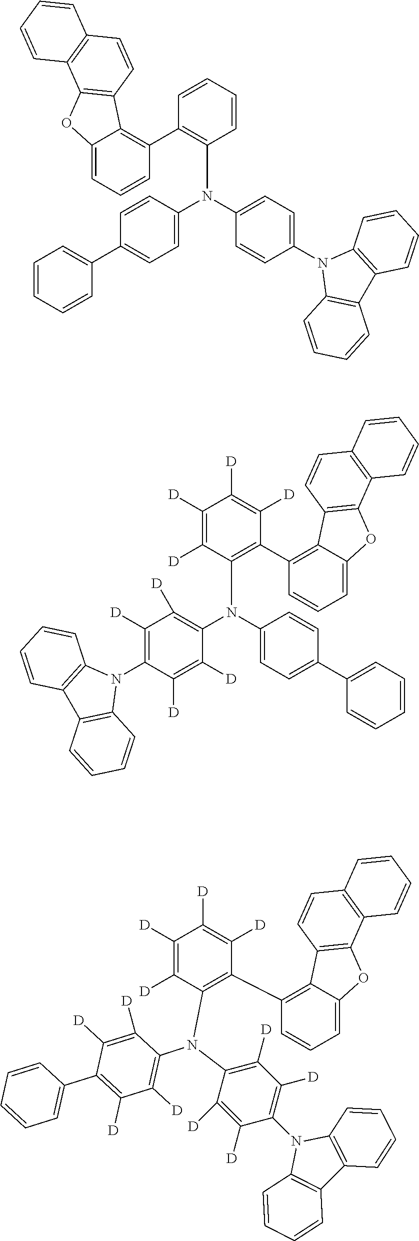 [SMILES: c1ccc(-c2ccc(N(c3ccc(-n4c5ccccc5c5ccccc54)cc3)c3ccccc3-c3cccc4oc5c6ccccc6ccc5c34)cc2)cc1 ; [2H]c1c([2H])c([2H])c(N(c2ccc(-c3ccccc3)cc2)c2c([2H])c([2H])c(-n3c4ccccc4c4ccccc43)c([2H])c2[2H])c(-c2cccc3oc4c5ccccc5ccc4c23)c1[2H] ; [2H]c1c([2H])c([2H])c(N(c2c([2H])c([2H])c(-c3ccccc3)c([2H])c2[2H])c2c([2H])c([2H])c(-n3c4ccccc4c4ccccc43)c([2H])c2[2H])c(-c2cccc3oc4c5ccccc5ccc4c23)c1[2H]]

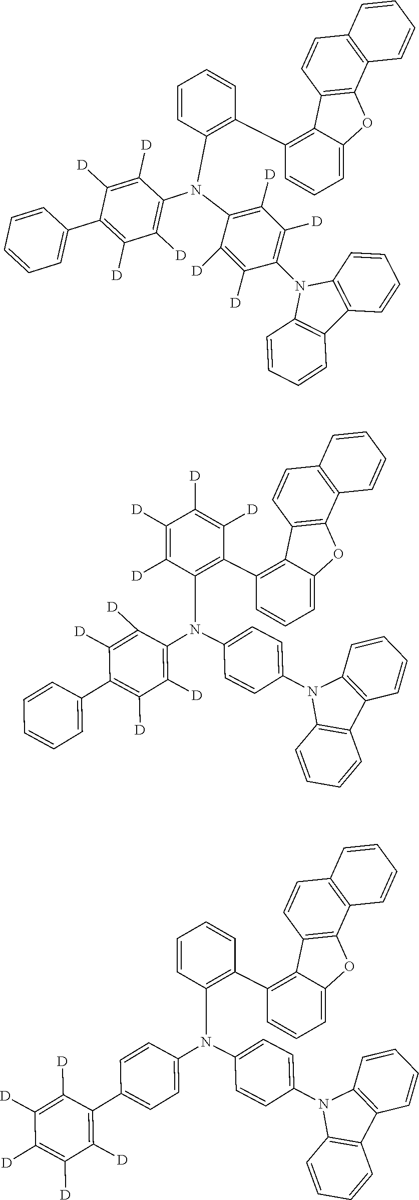 [SMILES: [2H]c1c([2H])c(N(c2ccccc2-c2cccc3oc4c5ccccc5ccc4c23)c2c([2H])c([2H])c(-n3c4ccccc4c4ccccc43)c([2H])c2[2H])c([2H])c([2H])c1-c1ccccc1 ; [2H]c1c([2H])c([2H])c(N(c2ccc(-n3c4ccccc4c4ccccc43)cc2)c2c([2H])c([2H])c(-c3ccccc3)c([2H])c2[2H])c(-c2cccc3oc4c5ccccc5ccc4c23)c1[2H] ; [2H]c1c([2H])c([2H])c(-c2ccc(N(c3ccc(-n4c5ccccc5c5ccccc54)cc3)c3ccccc3-c3cccc4oc5c6ccccc6ccc5c34)cc2)c([2H])c1[2H]]

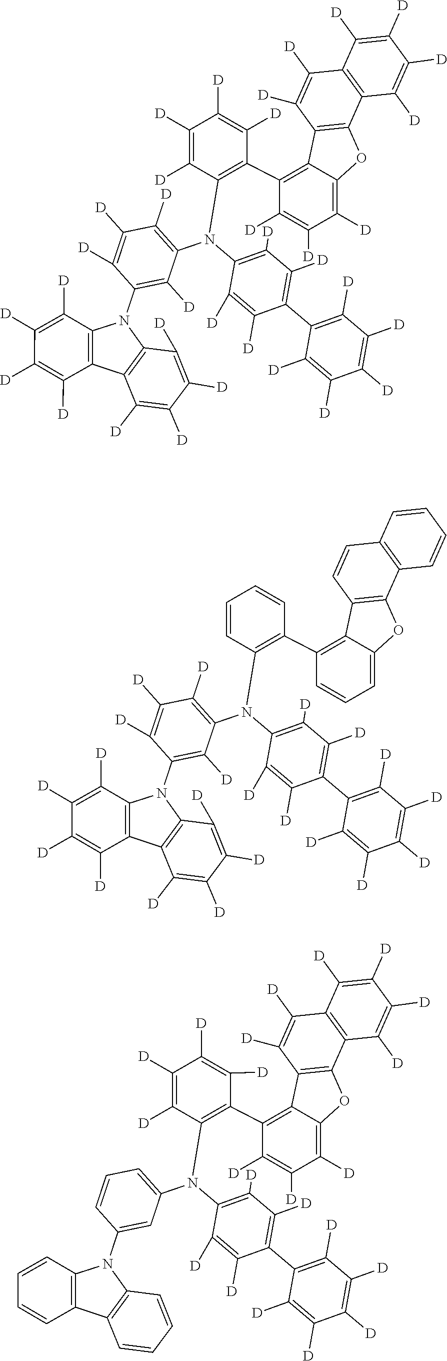

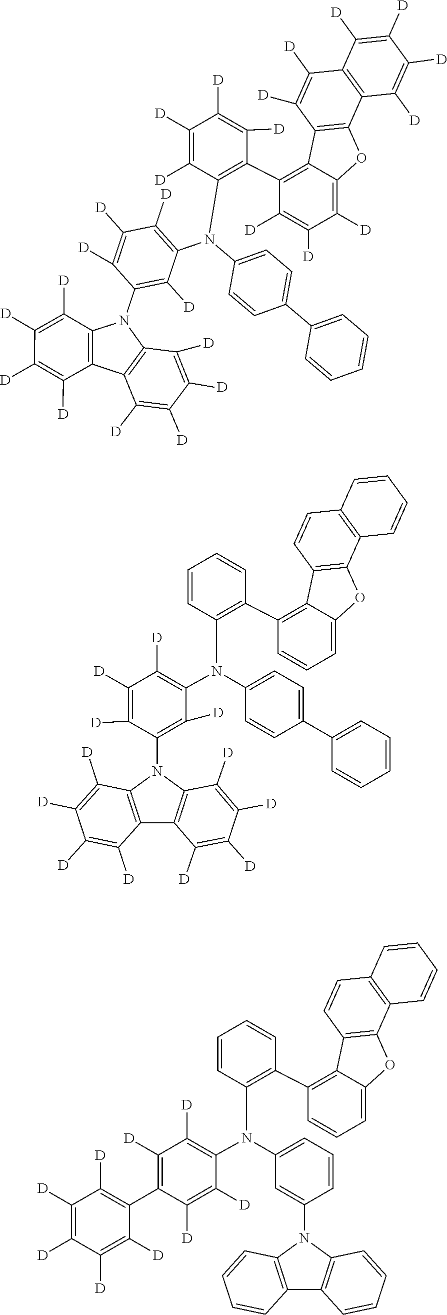

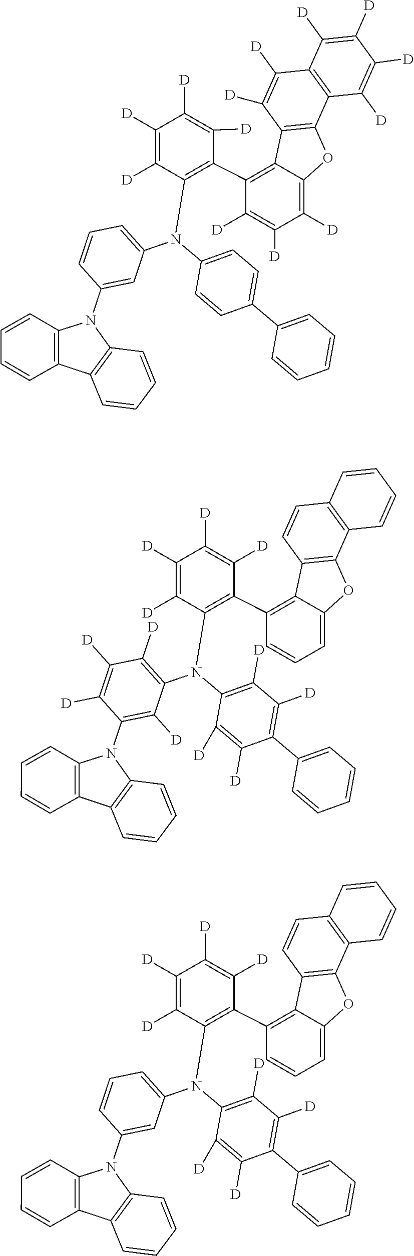 [SMILES: [2H]c1c([2H])c([2H])c(N(c2ccc(-c3ccccc3)cc2)c2cccc(-n3c4ccccc4c4ccccc43)c2)c(-c2c([2H])c([2H])c([2H])c3oc4c5c([2H])c([2H])c([2H])c([2H])c5c([2H])c([2H])c4c23)c1[2H] ; [2H]c1c([2H])c([2H])c(N(c2c([2H])c([2H])c(-c3ccccc3)c([2H])c2[2H])c2c([2H])c([2H])c([2H])c(-n3c4ccccc4c4ccccc43)c2[2H])c(-c2cccc3oc4c5ccccc5ccc4c23)c1[2H] ; [2H]c1c([2H])c([2H])c(N(c2cccc(-n3c4ccccc4c4ccccc43)c2)c2c([2H])c([2H])c(-c3ccccc3)c([2H])c2[2H])c(-c2cccc3oc4c5ccccc5ccc4c23)c1[2H]]

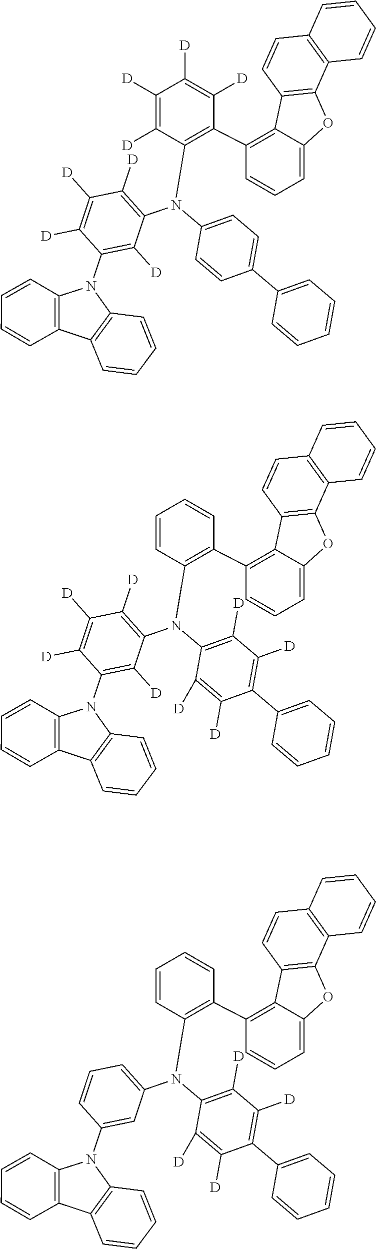 [SMILES: [2H]c1c([2H])c([2H])c(N(c2ccc(-c3ccccc3)cc2)c2c([2H])c([2H])c([2H])c(-n3c4ccccc4c4ccccc43)c2[2H])c(-c2cccc3oc4c5ccccc5ccc4c23)c1[2H] ; [2H]c1c([2H])c(N(c2ccccc2-c2cccc3oc4c5ccccc5ccc4c23)c2c([2H])c([2H])c(-c3ccccc3)c([2H])c2[2H])c([2H])c(-n2c3ccccc3c3ccccc32)c1[2H] ; [2H]c1c([2H])c(N(c2cccc(-n3c4ccccc4c4ccccc43)c2)c2ccccc2-c2cccc3oc4c5ccccc5ccc4c23)c([2H])c([2H])c1-c1ccccc1]

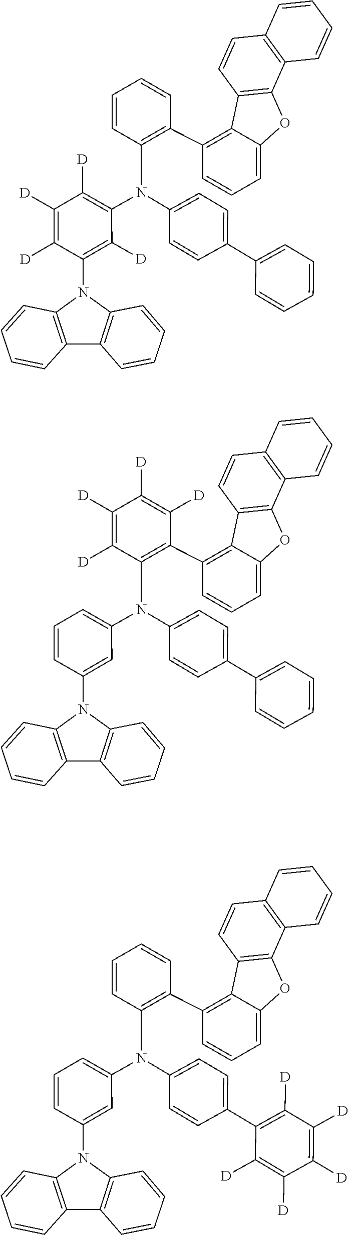 [SMILES: [2H]c1c([2H])c(N(c2ccc(-c3ccccc3)cc2)c2ccccc2-c2cccc3oc4c5ccccc5ccc4c23)c([2H])c(-n2c3ccccc3c3ccccc32)c1[2H] ; [2H]c1c([2H])c([2H])c(N(c2ccc(-c3ccccc3)cc2)c2cccc(-n3c4ccccc4c4ccccc43)c2)c(-c2cccc3oc4c5ccccc5ccc4c23)c1[2H] ; [2H]c1c([2H])c([2H])c(-c2ccc(N(c3cccc(-n4c5ccccc5c5ccccc54)c3)c3ccccc3-c3cccc4oc5c6ccccc6ccc5c34)cc2)c([2H])c1[2H]]

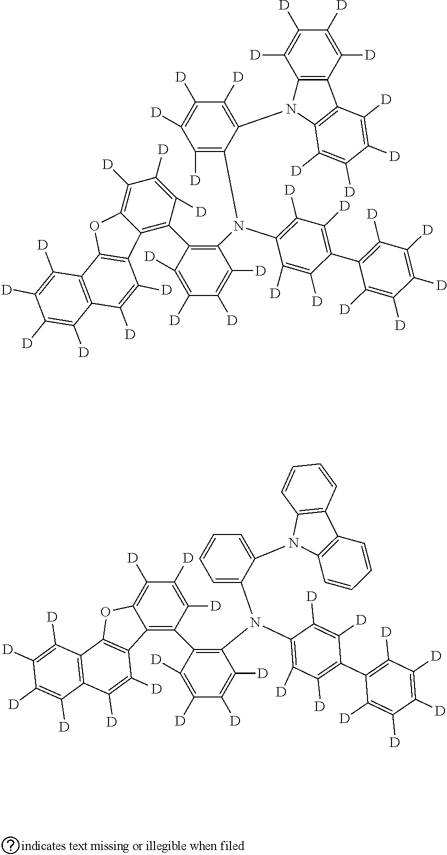 [SMILES: [2H]c1c([2H])c([2H])c(-c2c([2H])c([2H])c(N(c3c([2H])c([2H])c([2H])c([2H])c3-c3c([2H])c([2H])c([2H])c4oc5c6c([2H])c([2H])c([2H])c([2H])c6c([2H])c([2H])c5c34)c3c([2H])c([2H])c([2H])c([2H])c3-n3c4c([2H])c([2H])c([2H])c([2H])c4c4c([2H])c([2H])c([2H])c([2H])c43)c([2H])c2[2H])c([2H])c1[2H] ; [2H]c1c([2H])c([2H])c(-c2c([2H])c([2H])c(N(c3ccccc3-n3c4ccccc4c4ccccc43)c3c([2H])c([2H])c([2H])c([2H])c3-c3c([2H])c([2H])c([2H])c4oc5c6c([2H])c([2H])c([2H])c([2H])c6c([2H])c([2H])c5c34)c([2H])c2[2H])c([2H])c1[2H]]

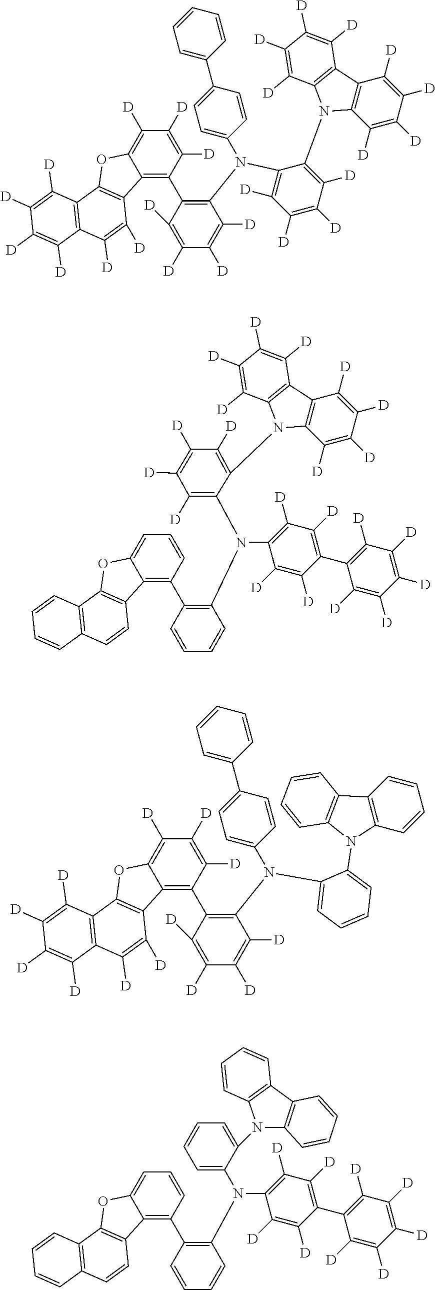

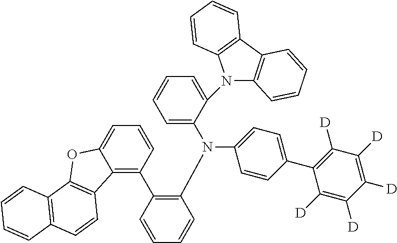 [SMILES: [2H]c1c([2H])c([2H])c(-c2ccc(N(c3ccccc3-c3cccc4oc5c6ccccc6ccc5c34)c3ccccc3-n3c4ccccc4c4ccccc43)cc2)c([2H])c1[2H]]

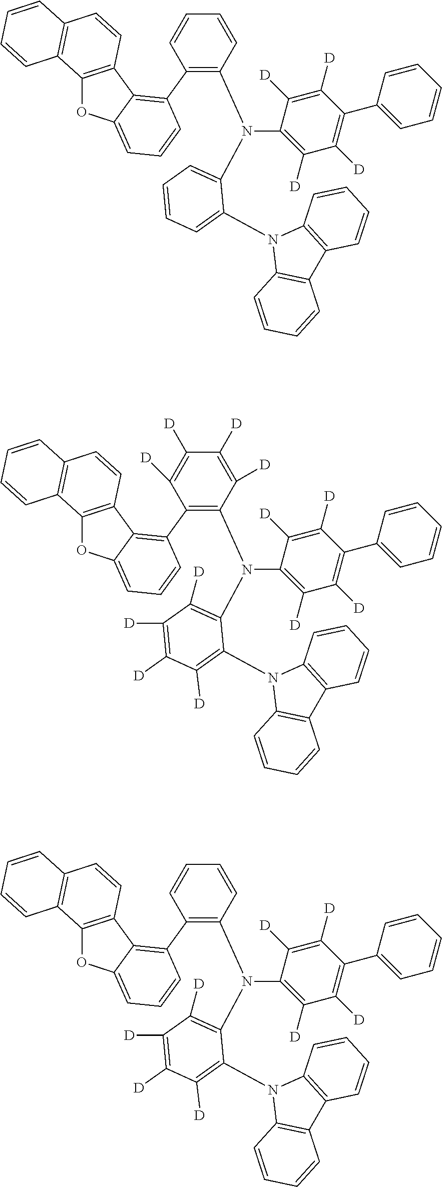 [SMILES: [2H]c1c([2H])c(N(c2ccccc2-c2cccc3oc4c5ccccc5ccc4c23)c2ccccc2-n2c3ccccc3c3ccccc32)c([2H])c([2H])c1-c1ccccc1 ; [2H]c1c([2H])c([2H])c(N(c2c([2H])c([2H])c(-c3ccccc3)c([2H])c2[2H])c2c([2H])c([2H])c([2H])c([2H])c2-n2c3ccccc3c3ccccc32)c(-c2cccc3oc4c5ccccc5ccc4c23)c1[2H] ; [2H]c1c([2H])c([2H])c(-n2c3ccccc3c3ccccc32)c(N(c2ccccc2-c2cccc3oc4c5ccccc5ccc4c23)c2c([2H])c([2H])c(-c3ccccc3)c([2H])c2[2H])c1[2H]]

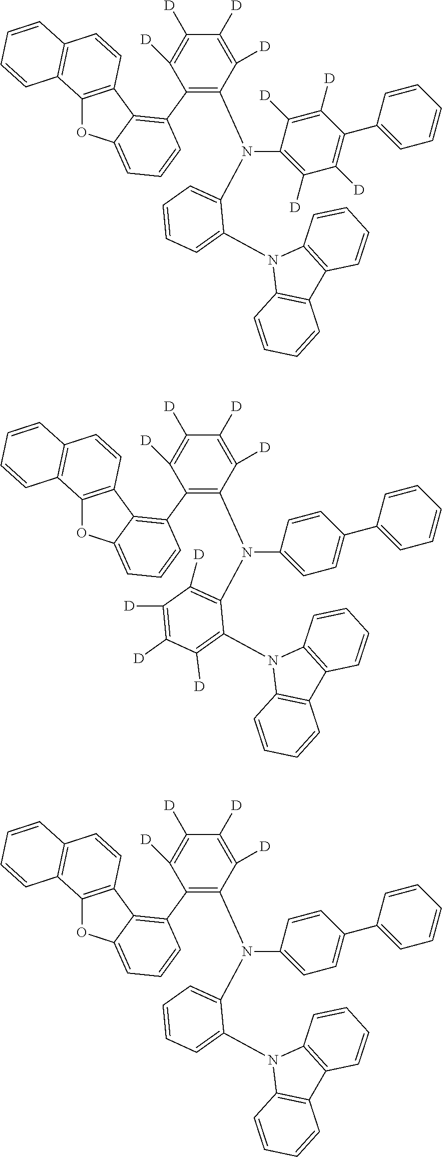 [SMILES: [2H]c1c([2H])c([2H])c(N(c2ccccc2-n2c3ccccc3c3ccccc32)c2c([2H])c([2H])c(-c3ccccc3)c([2H])c2[2H])c(-c2cccc3oc4c5ccccc5ccc4c23)c1[2H] ; [2H]c1c([2H])c([2H])c(N(c2ccc(-c3ccccc3)cc2)c2c([2H])c([2H])c([2H])c([2H])c2-n2c3ccccc3c3ccccc32)c(-c2cccc3oc4c5ccccc5ccc4c23)c1[2H] ; [2H]c1c([2H])c([2H])c(N(c2ccc(-c3ccccc3)cc2)c2ccccc2-n2c3ccccc3c3ccccc32)c(-c2cccc3oc4c5ccccc5ccc4c23)c1[2H]]

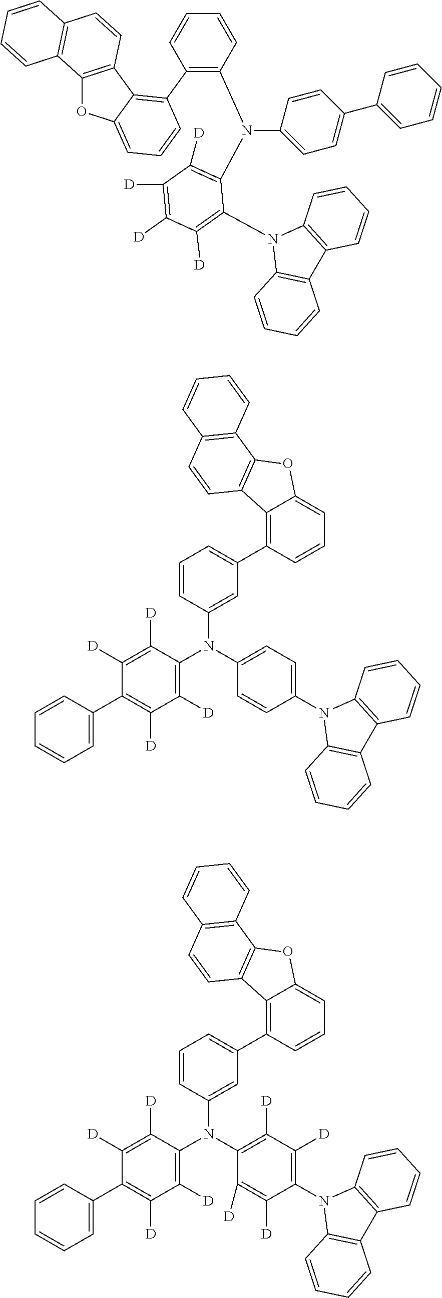 [SMILES: [2H]c1c([2H])c([2H])c(-n2c3ccccc3c3ccccc32)c(N(c2ccc(-c3ccccc3)cc2)c2ccccc2-c2cccc3oc4c5ccccc5ccc4c23)c1[2H] ; [2H]c1c([2H])c(N(c2ccc(-n3c4ccccc4c4ccccc43)cc2)c2cccc(-c3cccc4oc5c6ccccc6ccc5c34)c2)c([2H])c([2H])c1-c1ccccc1 ; [2H]c1c([2H])c(N(c2cccc(-c3cccc4oc5c6ccccc6ccc5c34)c2)c2c([2H])c([2H])c(-n3c4ccccc4c4ccccc43)c([2H])c2[2H])c([2H])c([2H])c1-c1ccccc1]

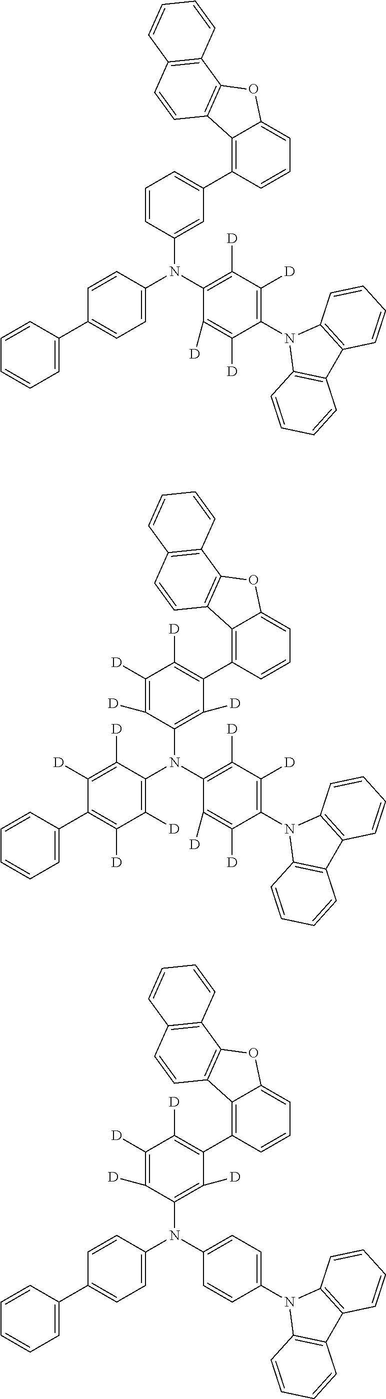 [SMILES: [2H]c1c([2H])c(-n2c3ccccc3c3ccccc32)c([2H])c([2H])c1N(c1ccc(-c2ccccc2)cc1)c1cccc(-c2cccc3oc4c5ccccc5ccc4c23)c1 ; [2H]c1c([2H])c(-c2cccc3oc4c5ccccc5ccc4c23)c([2H])c(N(c2c([2H])c([2H])c(-c3ccccc3)c([2H])c2[2H])c2c([2H])c([2H])c(-n3c4ccccc4c4ccccc43)c([2H])c2[2H])c1[2H] ; [2H]c1c([2H])c(-c2cccc3oc4c5ccccc5ccc4c23)c([2H])c(N(c2ccc(-c3ccccc3)cc2)c2ccc(-n3c4ccccc4c4ccccc43)cc2)c1[2H]]

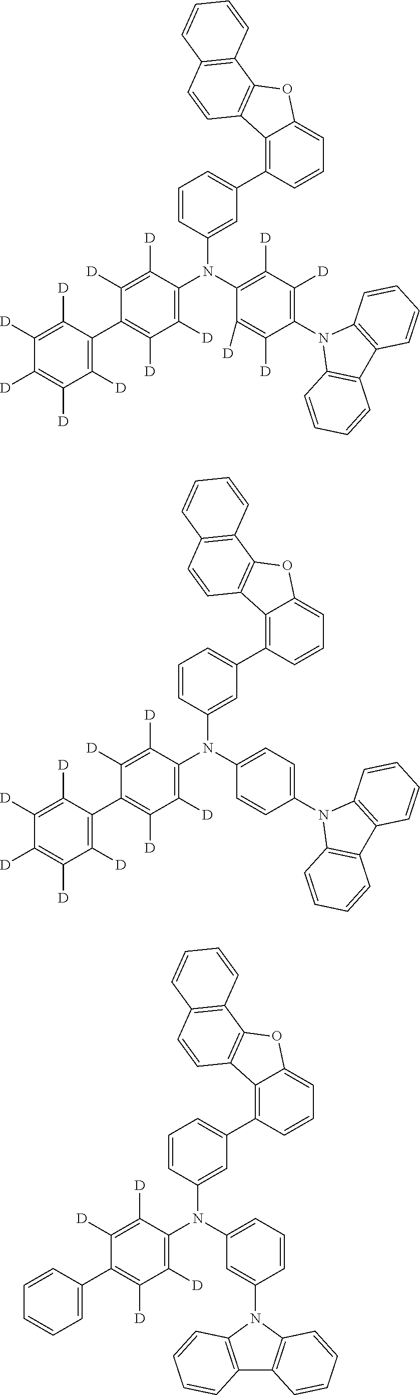 [SMILES: [2H]c1c([2H])c([2H])c(-c2c([2H])c([2H])c(N(c3cccc(-c4cccc5oc6c7ccccc7ccc6c45)c3)c3c([2H])c([2H])c(-n4c5ccccc5c5ccccc54)c([2H])c3[2H])c([2H])c2[2H])c([2H])c1[2H] ; [2H]c1c([2H])c([2H])c(-c2c([2H])c([2H])c(N(c3ccc(-n4c5ccccc5c5ccccc54)cc3)c3cccc(-c4cccc5oc6c7ccccc7ccc6c45)c3)c([2H])c2[2H])c([2H])c1[2H] ; [2H]c1c([2H])c(N(c2cccc(-c3cccc4oc5c6ccccc6ccc5c34)c2)c2cccc(-n3c4ccccc4c4ccccc43)c2)c([2H])c([2H])c1-c1ccccc1]

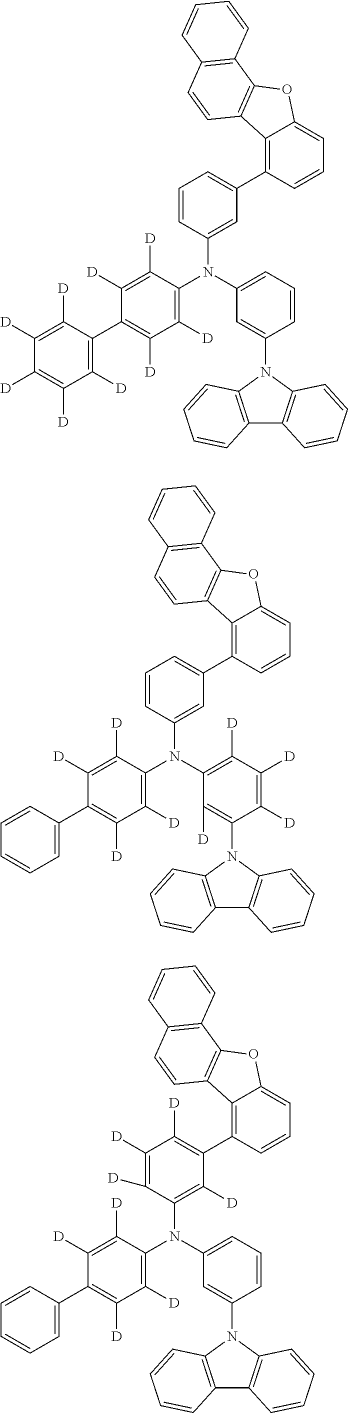

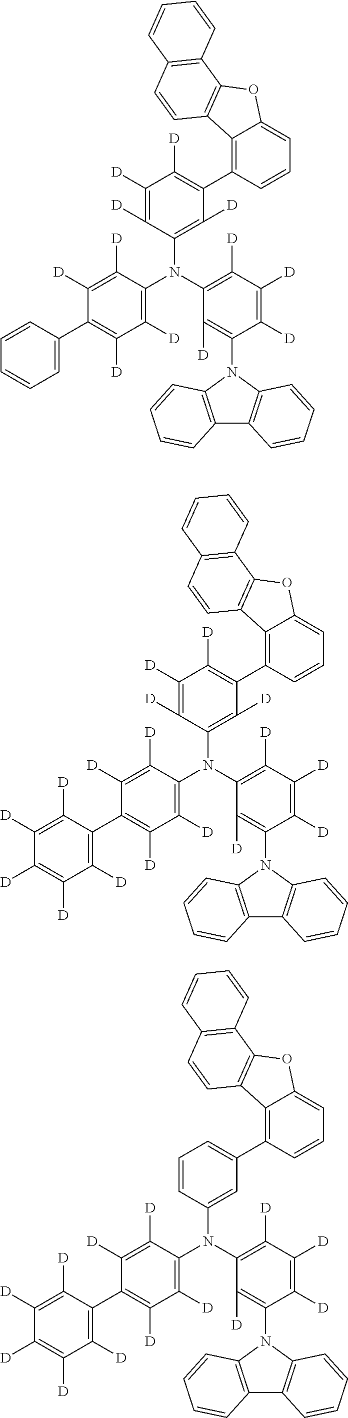

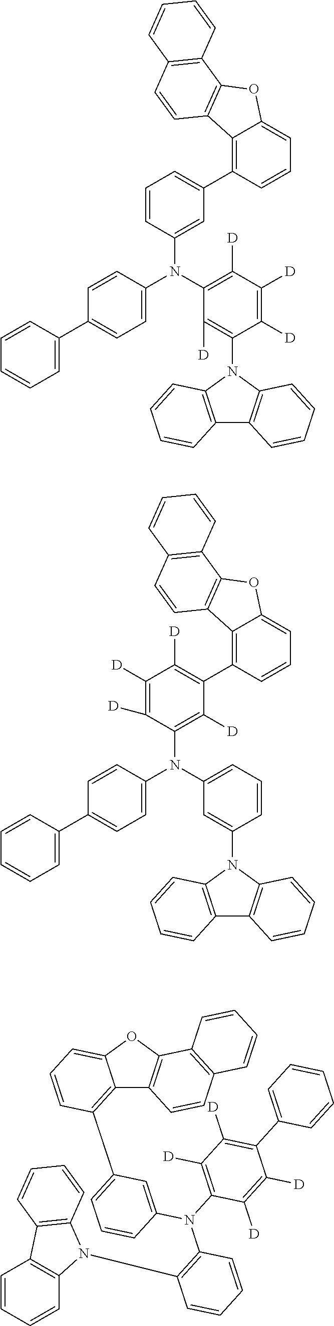 [SMILES: [2H]c1c([2H])c(N(c2ccc(-c3ccccc3)cc2)c2cccc(-c3cccc4oc5c6ccccc6ccc5c34)c2)c([2H])c(-n2c3ccccc3c3ccccc32)c1[2H] ; [2H]c1c([2H])c(-c2cccc3oc4c5ccccc5ccc4c23)c([2H])c(N(c2ccc(-c3ccccc3)cc2)c2cccc(-n3c4ccccc4c4ccccc43)c2)c1[2H] ; [2H]c1c([2H])c(N(c2cccc(-c3cccc4oc5c6ccccc6ccc5c34)c2)c2ccccc2-n2c3ccccc3c3ccccc32)c([2H])c([2H])c1-c1ccccc1]

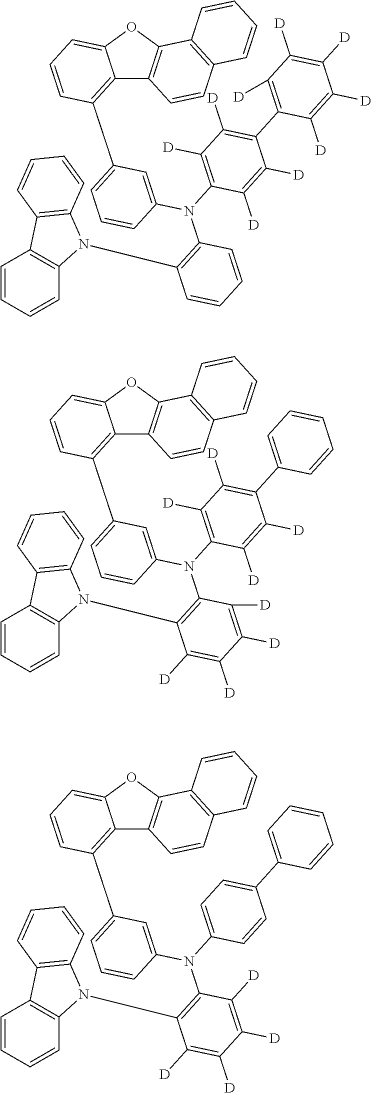 [SMILES: [2H]c1c([2H])c([2H])c(-c2c([2H])c([2H])c(N(c3cccc(-c4cccc5oc6c7ccccc7ccc6c45)c3)c3ccccc3-n3c4ccccc4c4ccccc43)c([2H])c2[2H])c([2H])c1[2H] ; [2H]c1c([2H])c([2H])c(-n2c3ccccc3c3ccccc32)c(N(c2cccc(-c3cccc4oc5c6ccccc6ccc5c34)c2)c2c([2H])c([2H])c(-c3ccccc3)c([2H])c2[2H])c1[2H] ; [2H]c1c([2H])c([2H])c(-n2c3ccccc3c3ccccc32)c(N(c2ccc(-c3ccccc3)cc2)c2cccc(-c3cccc4oc5c6ccccc6ccc5c34)c2)c1[2H]]

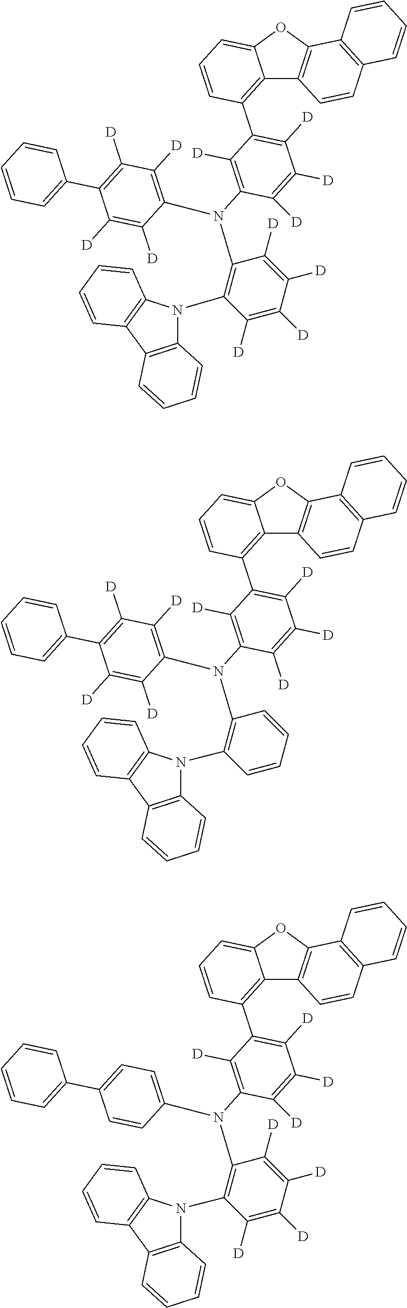 [SMILES: [2H]c1c([2H])c(-c2cccc3oc4c5ccccc5ccc4c23)c([2H])c(N(c2c([2H])c([2H])c(-c3ccccc3)c([2H])c2[2H])c2c([2H])c([2H])c([2H])c([2H])c2-n2c3ccccc3c3ccccc32)c1[2H] ; [2H]c1c([2H])c(-c2cccc3oc4c5ccccc5ccc4c23)c([2H])c(N(c2ccccc2-n2c3ccccc3c3ccccc32)c2c([2H])c([2H])c(-c3ccccc3)c([2H])c2[2H])c1[2H] ; [2H]c1c([2H])c(-c2cccc3oc4c5ccccc5ccc4c23)c([2H])c(N(c2ccc(-c3ccccc3)cc2)c2c([2H])c([2H])c([2H])c([2H])c2-n2c3ccccc3c3ccccc32)c1[2H]]

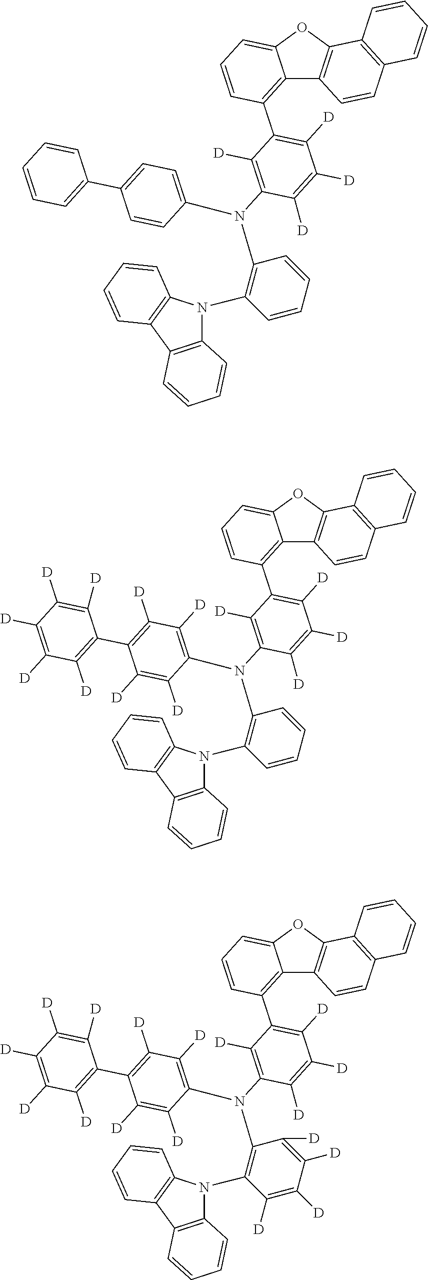 [SMILES: [2H]c1c([2H])c(-c2cccc3oc4c5ccccc5ccc4c23)c([2H])c(N(c2ccc(-c3ccccc3)cc2)c2ccccc2-n2c3ccccc3c3ccccc32)c1[2H] ; [2H]c1c([2H])c([2H])c(-c2c([2H])c([2H])c(N(c3ccccc3-n3c4ccccc4c4ccccc43)c3c([2H])c([2H])c([2H])c(-c4cccc5oc6c7ccccc7ccc6c45)c3[2H])c([2H])c2[2H])c([2H])c1[2H] ; [2H]c1c([2H])c([2H])c(-c2c([2H])c([2H])c(N(c3c([2H])c([2H])c([2H])c(-c4cccc5oc6c7ccccc7ccc6c45)c3[2H])c3c([2H])c([2H])c([2H])c([2H])c3-n3c4ccccc4c4ccccc43)c([2H])c2[2H])c([2H])c1[2H]]

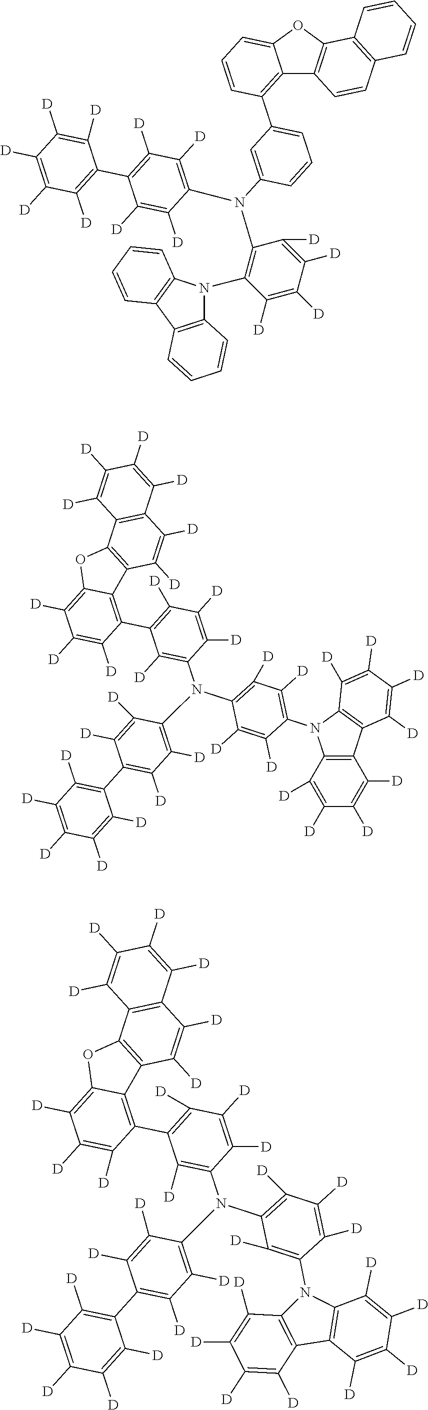

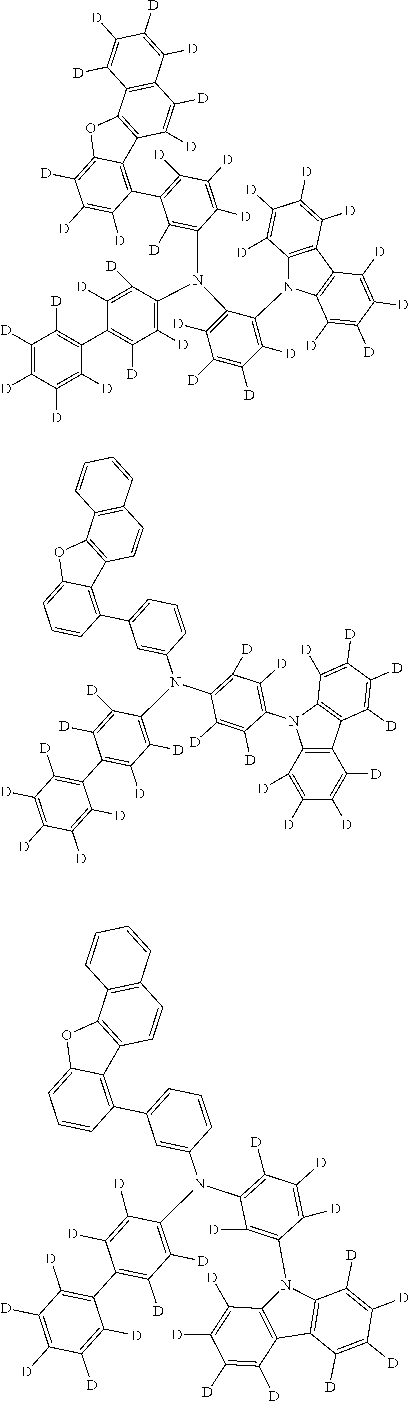

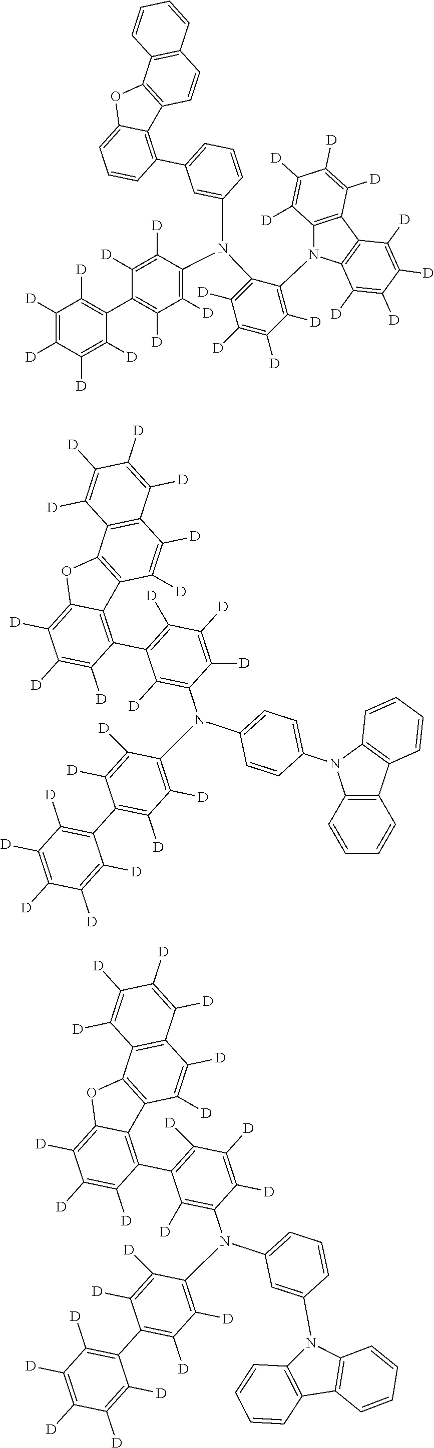

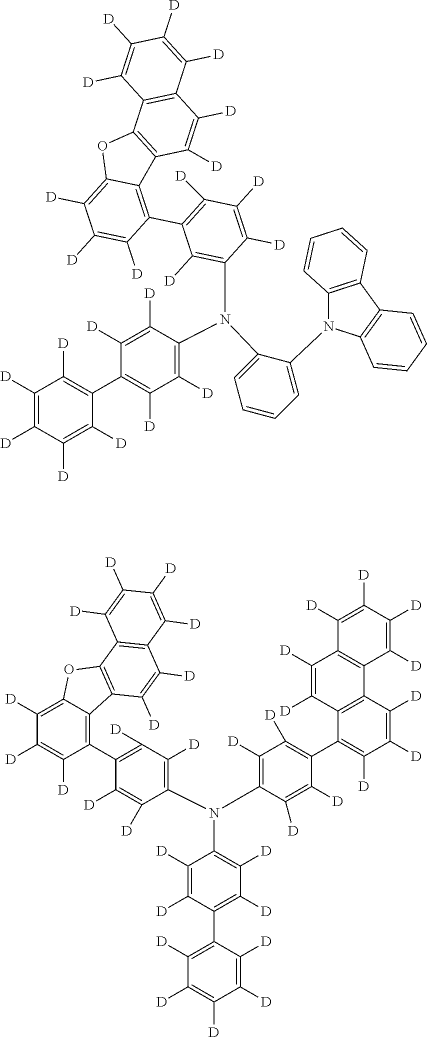

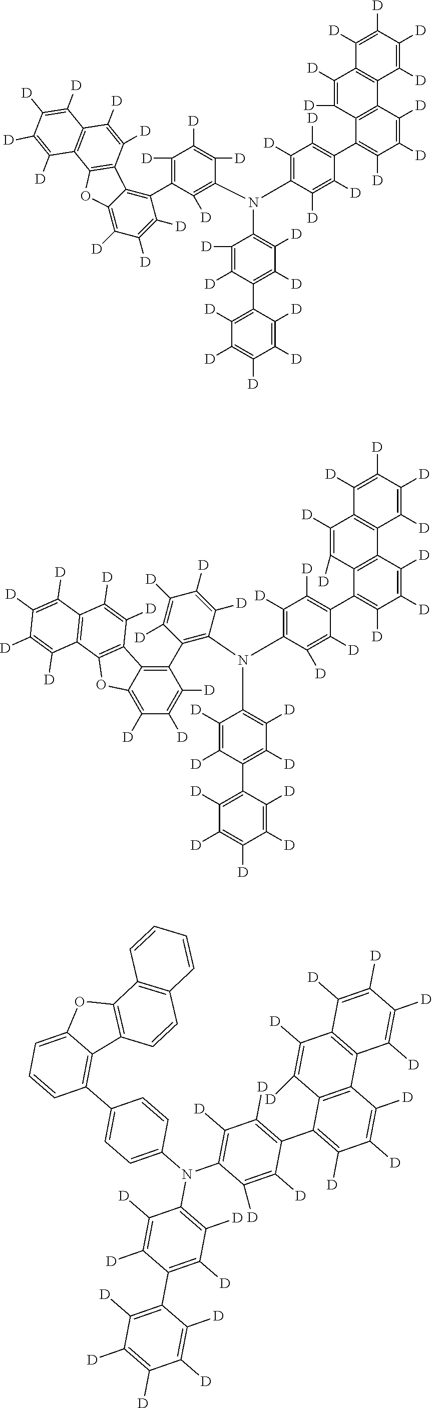

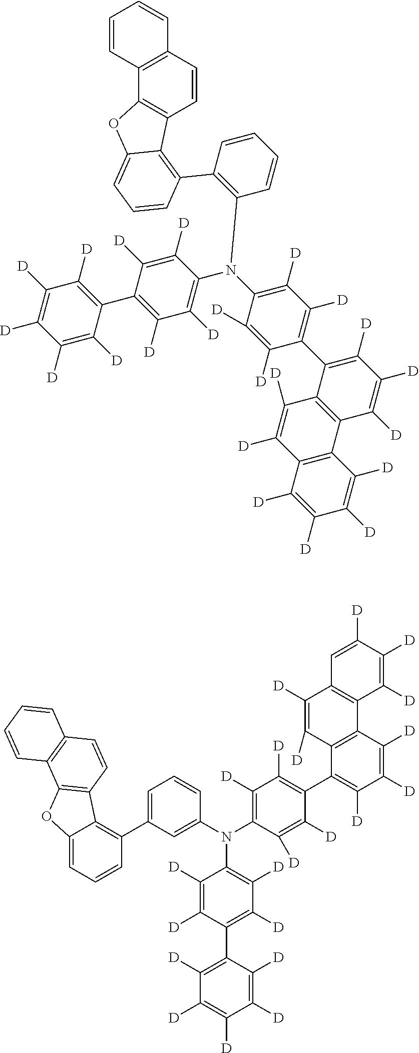 [SMILES: [2H]c1c([2H])c([2H])c(-c2c([2H])c([2H])c(N(c3ccccc3-c3cccc4oc5c6ccccc6ccc5c34)c3c([2H])c([2H])c(-c4c([2H])c([2H])c([2H])c5c4c([2H])c([2H])c4c([2H])c([2H])c([2H])c([2H])c45)c([2H])c3[2H])c([2H])c2[2H])c([2H])c1[2H] ; [2H]c1cc2c([2H])c([2H])c3c(-c4c([2H])c([2H])c(N(c5cccc(-c6cccc7oc8c9ccccc9ccc8c67)c5)c5c([2H])c([2H])c(-c6c([2H])c([2H])c([2H])c([2H])c6[2H])c([2H])c5[2H])c([2H])c4[2H])c([2H])c([2H])c([2H])c3c2c([2H])c1[2H]]

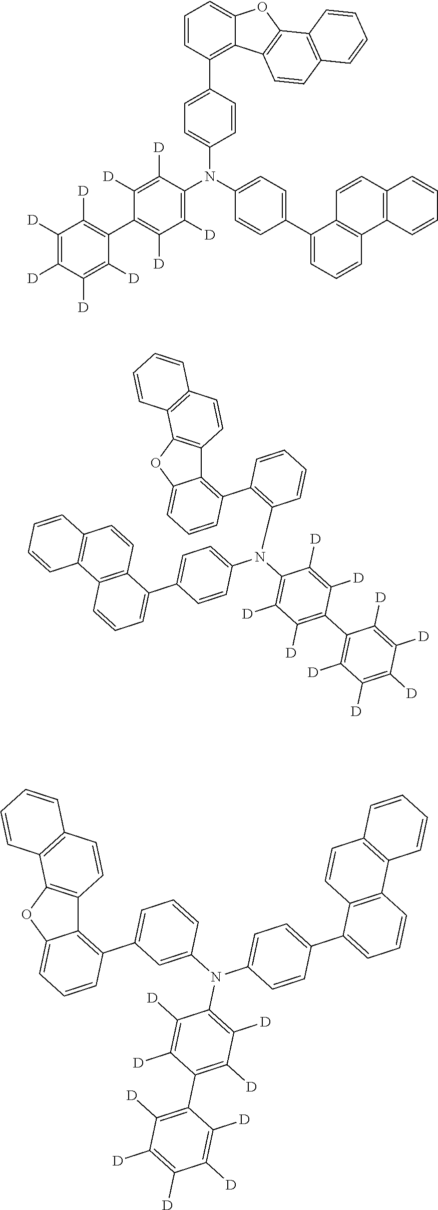 [SMILES: [2H]c1c([2H])c([2H])c(-c2c([2H])c([2H])c(N(c3ccc(-c4cccc5c4ccc4ccccc45)cc3)c3ccc(-c4cccc5oc6c7ccccc7ccc6c45)cc3)c([2H])c2[2H])c([2H])c1[2H] ; [2H]c1c([2H])c([2H])c(-c2c([2H])c([2H])c(N(c3ccc(-c4cccc5c4ccc4ccccc45)cc3)c3ccccc3-c3cccc4oc5c6ccccc6ccc5c34)c([2H])c2[2H])c([2H])c1[2H] ; [2H]c1c([2H])c([2H])c(-c2c([2H])c([2H])c(N(c3ccc(-c4cccc5c4ccc4ccccc45)cc3)c3cccc(-c4cccc5oc6c7ccccc7ccc6c45)c3)c([2H])c2[2H])c([2H])c1[2H]]

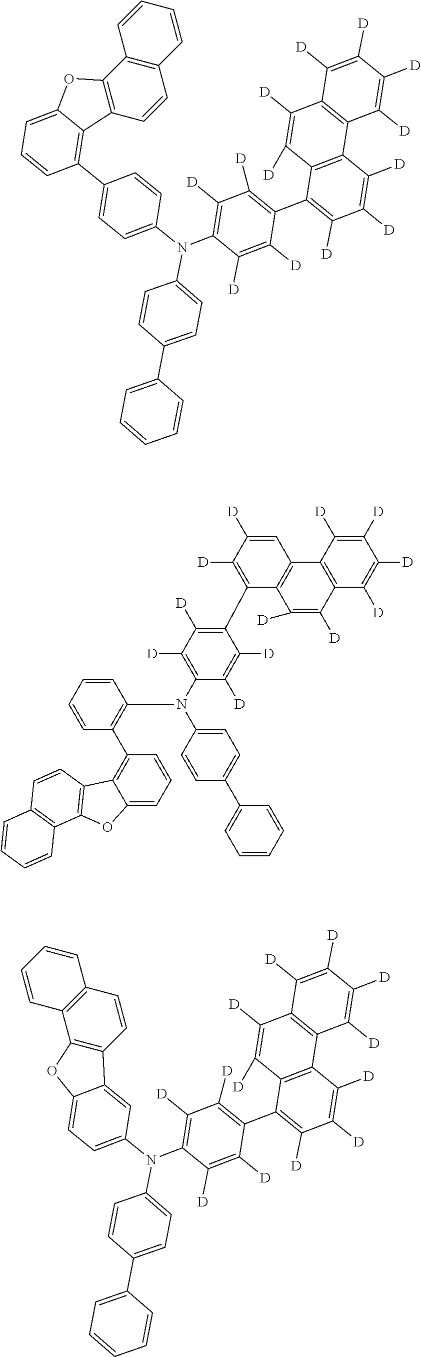 [SMILES: [2H]c1c([2H])c(N(c2ccc(-c3ccccc3)cc2)c2ccc(-c3cccc4oc5c6ccccc6ccc5c34)cc2)c([2H])c([2H])c1-c1c([2H])c([2H])c([2H])c2c1c([2H])c([2H])c1c([2H])c([2H])c([2H])c([2H])c12 ; [2H]c1cc2c(c([2H])c([2H])c3c([2H])c([2H])c([2H])c([2H])c32)c(-c2c([2H])c([2H])c(N(c3ccc(-c4ccccc4)cc3)c3ccccc3-c3cccc4oc5c6ccccc6ccc5c34)c([2H])c2[2H])c1[2H] ; [2H]c1c([2H])c(N(c2ccc(-c3ccccc3)cc2)c2ccc3oc4c5ccccc5ccc4c3c2)c([2H])c([2H])c1-c1c([2H])c([2H])c([2H])c2c1c([2H])c([2H])c1c([2H])c([2H])c([2H])c([2H])c12]

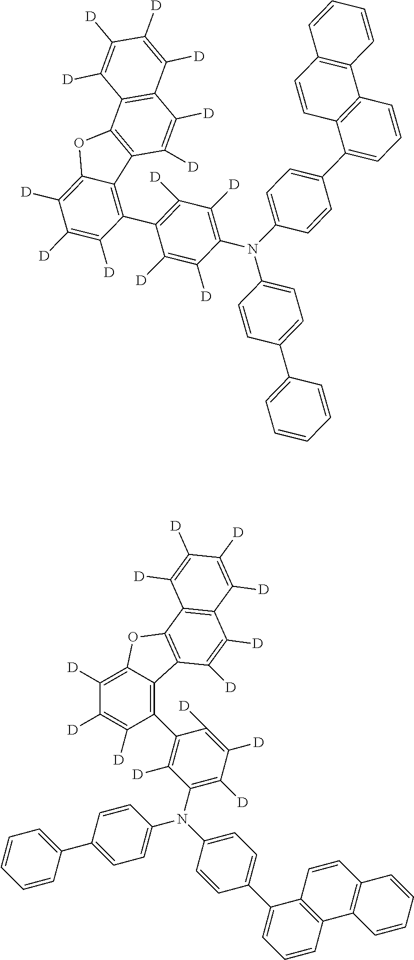 [SMILES: [2H]c1c([2H])c(N(c2ccc(-c3ccccc3)cc2)c2ccc(-c3cccc4c3ccc3ccccc34)cc2)c([2H])c([2H])c1-c1c([2H])c([2H])c([2H])c2oc3c4c([2H])c([2H])c([2H])c([2H])c4c([2H])c([2H])c3c12 ; [2H]c1c([2H])c(-c2c([2H])c([2H])c([2H])c3oc4c5c([2H])c([2H])c([2H])c([2H])c5c([2H])c([2H])c4c23)c([2H])c(N(c2ccc(-c3ccccc3)cc2)c2ccc(-c3cccc4c3ccc3ccccc34)cc2)c1[2H]]

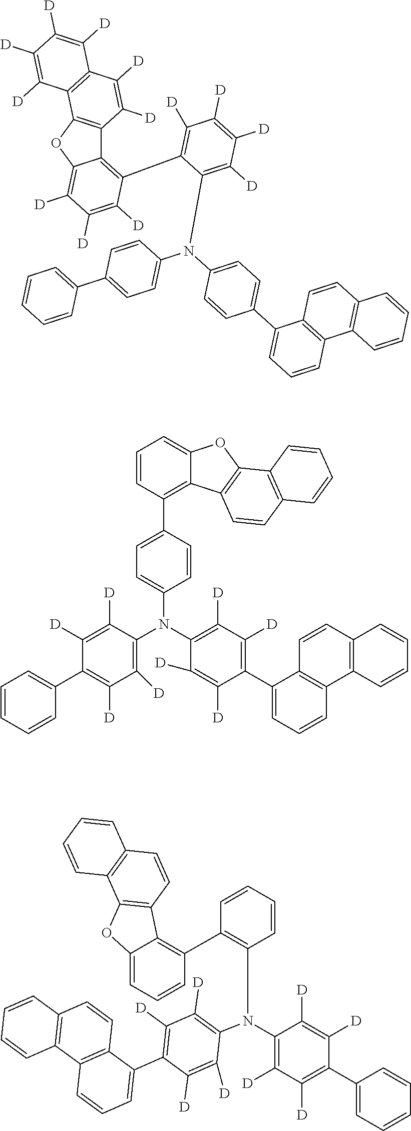 [SMILES: [2H]c1c([2H])c([2H])c(N(c2ccc(-c3ccccc3)cc2)c2ccc(-c3cccc4c3ccc3ccccc34)cc2)c(-c2c([2H])c([2H])c([2H])c3oc4c5c([2H])c([2H])c([2H])c([2H])c5c([2H])c([2H])c4c23)c1[2H] ; [2H]c1c([2H])c(N(c2ccc(-c3cccc4oc5c6ccccc6ccc5c34)cc2)c2c([2H])c([2H])c(-c3cccc4c3ccc3ccccc34)c([2H])c2[2H])c([2H])c([2H])c1-c1ccccc1 ; [2H]c1c([2H])c(N(c2ccccc2-c2cccc3oc4c5ccccc5ccc4c23)c2c([2H])c([2H])c(-c3cccc4c3ccc3ccccc34)c([2H])c2[2H])c([2H])c([2H])c1-c1ccccc1]

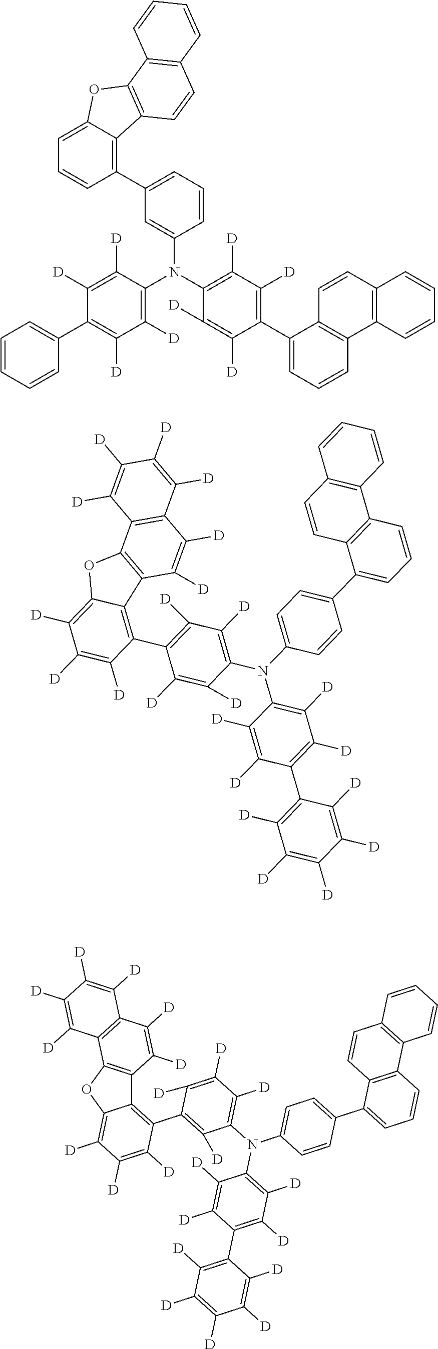

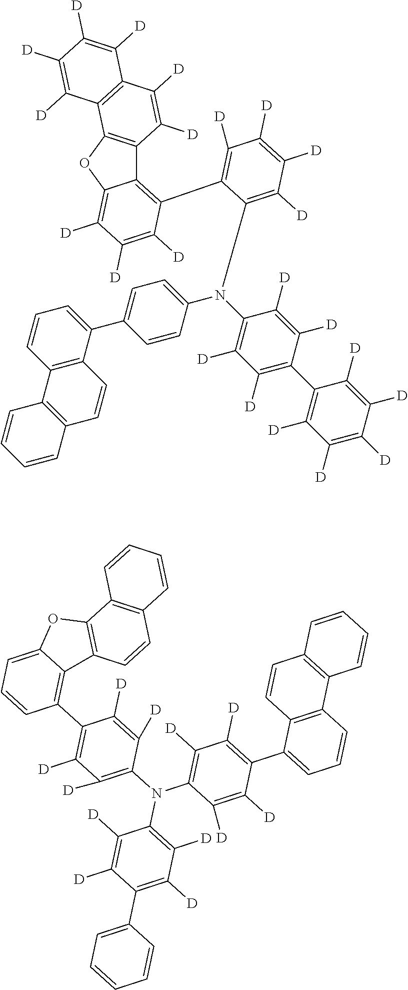 [SMILES: [2H]c1c([2H])c([2H])c(-c2c([2H])c([2H])c(N(c3ccc(-c4cccc5c4ccc4ccccc45)cc3)c3c([2H])c([2H])c([2H])c([2H])c3-c3c([2H])c([2H])c([2H])c4oc5c6c([2H])c([2H])c([2H])c([2H])c6c([2H])c([2H])c5c34)c([2H])c2[2H])c([2H])c1[2H] ; [2H]c1c([2H])c(N(c2c([2H])c([2H])c(-c3cccc4c3ccc3ccccc34)c([2H])c2[2H])c2c([2H])c([2H])c(-c3cccc4oc5c6ccccc6ccc5c34)c([2H])c2[2H])c([2H])c([2H])c1-c1ccccc1]

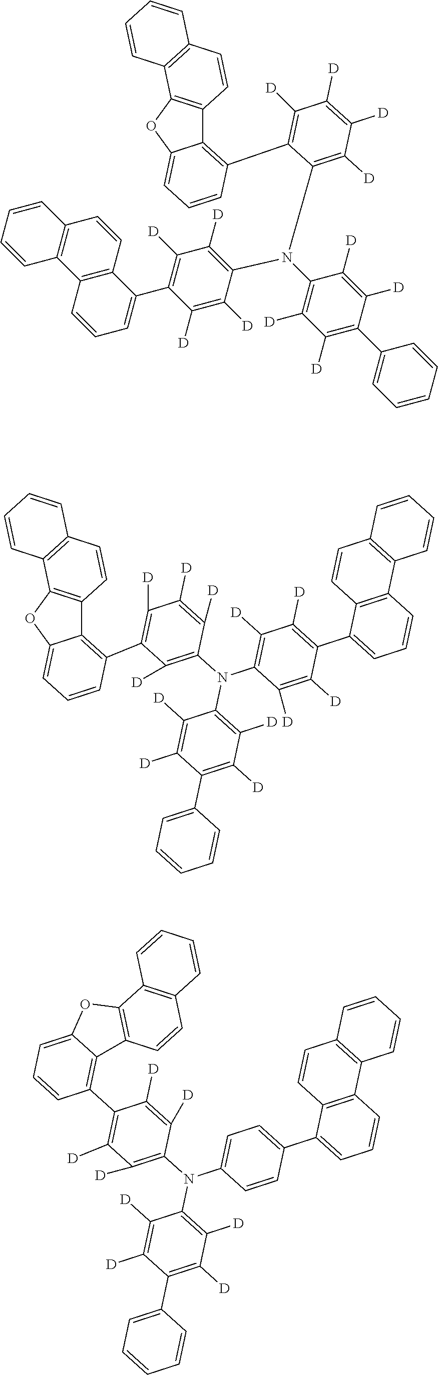 [SMILES: [2H]c1c([2H])c([2H])c(N(c2c([2H])c([2H])c(-c3ccccc3)c([2H])c2[2H])c2c([2H])c([2H])c(-c3cccc4c3ccc3ccccc34)c([2H])c2[2H])c(-c2cccc3oc4c5ccccc5ccc4c23)c1[2H] ; [2H]c1c([2H])c(-c2cccc3oc4c5ccccc5ccc4c23)c([2H])c(N(c2c([2H])c([2H])c(-c3ccccc3)c([2H])c2[2H])c2c([2H])c([2H])c(-c3cccc4c3ccc3ccccc34)c([2H])c2[2H])c1[2H] ; [2H]c1c([2H])c(N(c2ccc(-c3cccc4c3ccc3ccccc34)cc2)c2c([2H])c([2H])c(-c3cccc4oc5c6ccccc6ccc5c34)c([2H])c2[2H])c([2H])c([2H])c1-c1ccccc1]

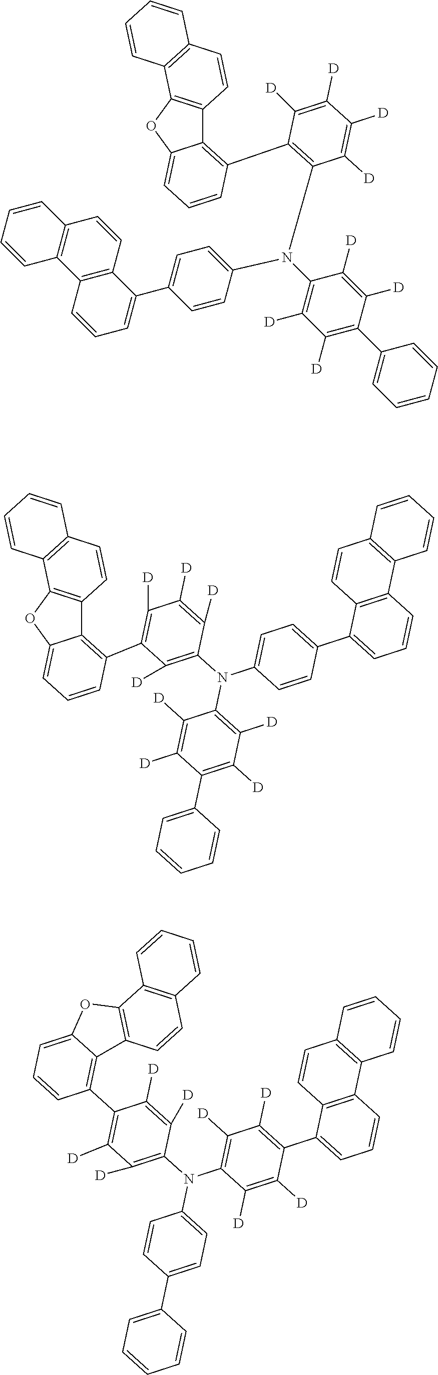 [SMILES: [2H]c1c([2H])c([2H])c(N(c2ccc(-c3cccc4c3ccc3ccccc34)cc2)c2c([2H])c([2H])c(-c3ccccc3)c([2H])c2[2H])c(-c2cccc3oc4c5ccccc5ccc4c23)c1[2H] ; [2H]c1c([2H])c(-c2cccc3oc4c5ccccc5ccc4c23)c([2H])c(N(c2ccc(-c3cccc4c3ccc3ccccc34)cc2)c2c([2H])c([2H])c(-c3ccccc3)c([2H])c2[2H])c1[2H] ; [2H]c1c([2H])c(N(c2ccc(-c3ccccc3)cc2)c2c([2H])c([2H])c(-c3cccc4oc5c6ccccc6ccc5c34)c([2H])c2[2H])c([2H])c([2H])c1-c1cccc2c1ccc1ccccc12]

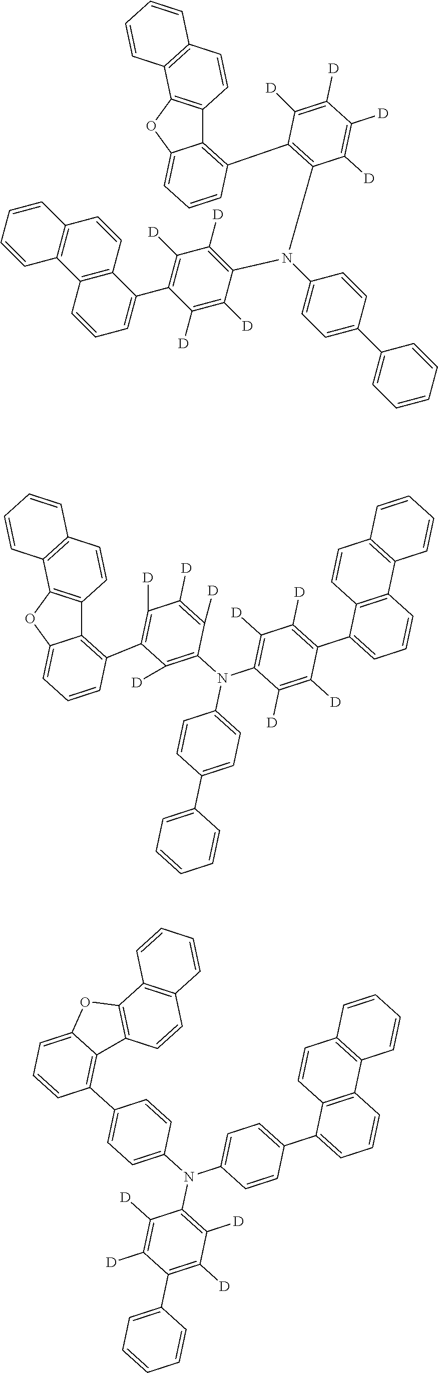 [SMILES: [2H]c1c([2H])c([2H])c(N(c2ccc(-c3ccccc3)cc2)c2c([2H])c([2H])c(-c3cccc4c3ccc3ccccc34)c([2H])c2[2H])c(-c2cccc3oc4c5ccccc5ccc4c23)c1[2H] ; [2H]c1c([2H])c(-c2cccc3oc4c5ccccc5ccc4c23)c([2H])c(N(c2ccc(-c3ccccc3)cc2)c2c([2H])c([2H])c(-c3cccc4c3ccc3ccccc34)c([2H])c2[2H])c1[2H] ; [2H]c1c([2H])c(N(c2ccc(-c3cccc4c3ccc3ccccc34)cc2)c2ccc(-c3cccc4oc5c6ccccc6ccc5c34)cc2)c([2H])c([2H])c1-c1ccccc1]

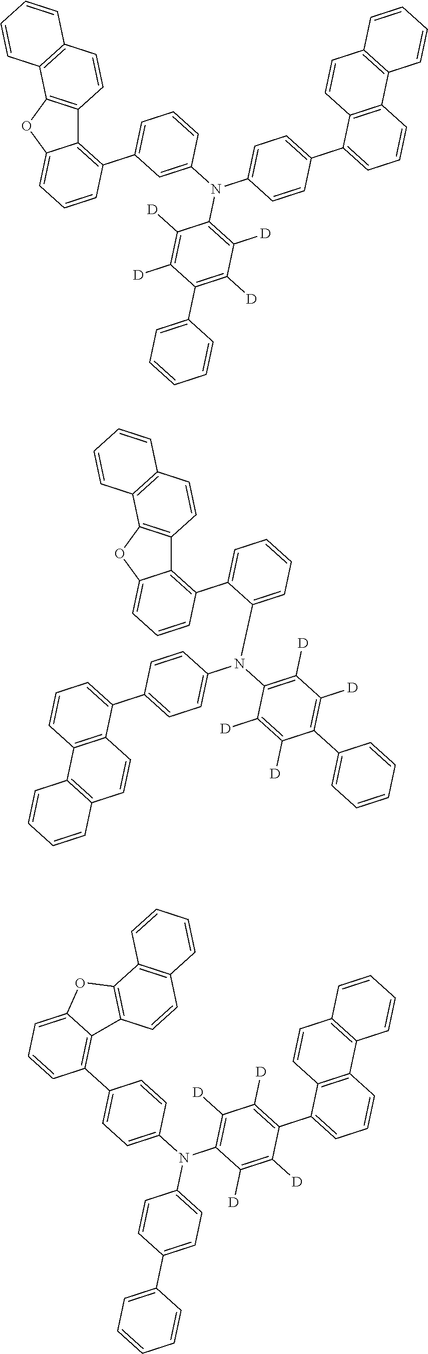 [SMILES: [2H]c1c([2H])c(N(c2ccc(-c3cccc4c3ccc3ccccc34)cc2)c2cccc(-c3cccc4oc5c6ccccc6ccc5c34)c2)c([2H])c([2H])c1-c1ccccc1 ; [2H]c1c([2H])c(N(c2ccc(-c3cccc4c3ccc3ccccc34)cc2)c2ccccc2-c2cccc3oc4c5ccccc5ccc4c23)c([2H])c([2H])c1-c1ccccc1 ; [2H]c1c([2H])c(N(c2ccc(-c3ccccc3)cc2)c2ccc(-c3cccc4oc5c6ccccc6ccc5c34)cc2)c([2H])c([2H])c1-c1cccc2c1ccc1ccccc12]

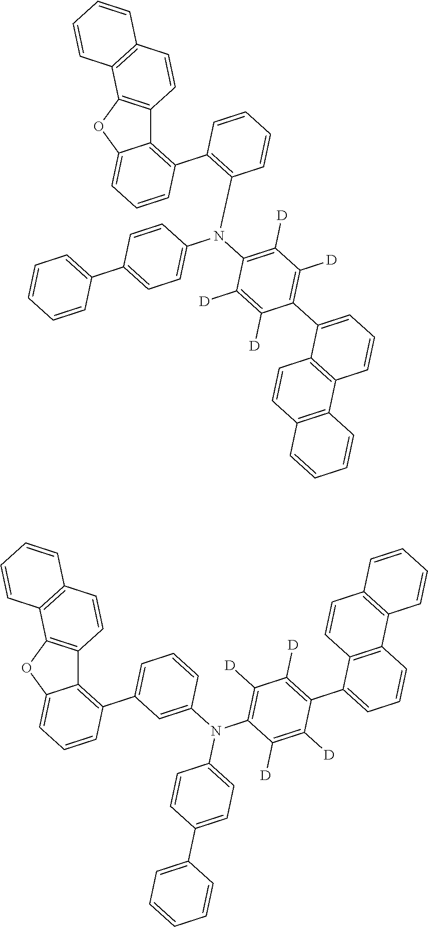 [SMILES: [2H]c1c([2H])c(N(c2ccc(-c3ccccc3)cc2)c2ccccc2-c2cccc3oc4c5ccccc5ccc4c23)c([2H])c([2H])c1-c1cccc2c1ccc1ccccc12 ; [2H]c1c([2H])c(N(c2ccc(-c3ccccc3)cc2)c2cccc(-c3cccc4oc5c6ccccc6ccc5c34)c2)c([2H])c([2H])c1-c1cccc2c1ccc1ccccc12]

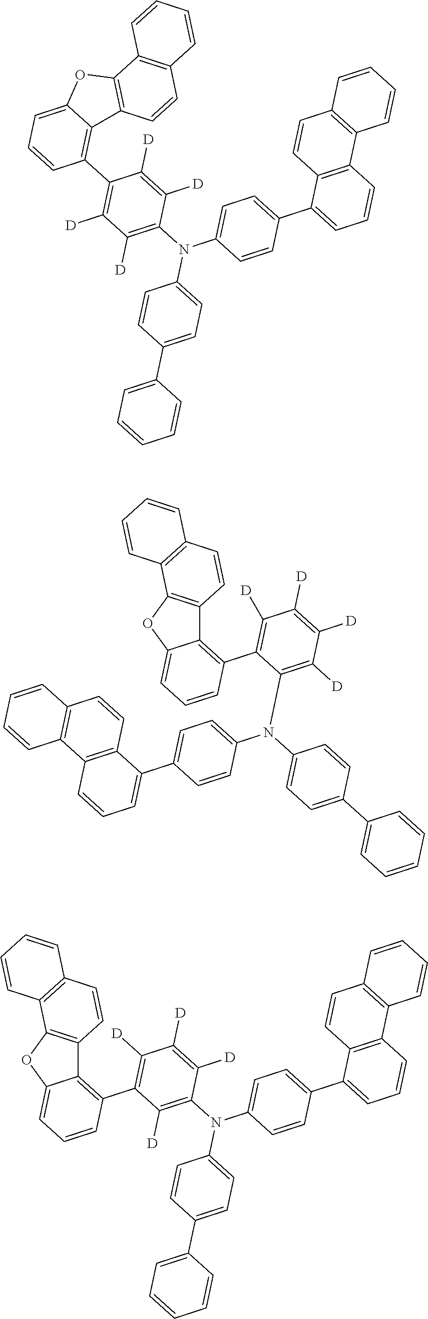 [SMILES: [2H]c1c([2H])c(N(c2ccc(-c3ccccc3)cc2)c2ccc(-c3cccc4c3ccc3ccccc34)cc2)c([2H])c([2H])c1-c1cccc2oc3c4ccccc4ccc3c12 ; [2H]c1c([2H])c([2H])c(N(c2ccc(-c3ccccc3)cc2)c2ccc(-c3cccc4c3ccc3ccccc34)cc2)c(-c2cccc3oc4c5ccccc5ccc4c23)c1[2H] ; [2H]c1c([2H])c(-c2cccc3oc4c5ccccc5ccc4c23)c([2H])c(N(c2ccc(-c3ccccc3)cc2)c2ccc(-c3cccc4c3ccc3ccccc34)cc2)c1[2H]]

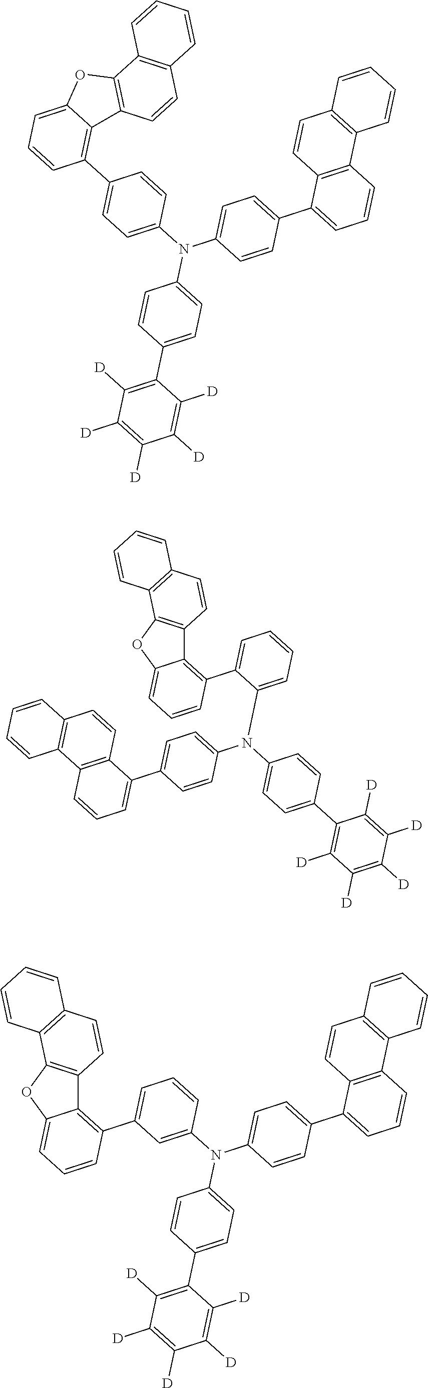 [SMILES: [2H]c1c([2H])c([2H])c(-c2ccc(N(c3ccc(-c4cccc5c4ccc4ccccc45)cc3)c3ccc(-c4cccc5oc6c7ccccc7ccc6c45)cc3)cc2)c([2H])c1[2H] ; [2H]c1c([2H])c([2H])c(-c2ccc(N(c3ccc(-c4cccc5c4ccc4ccccc45)cc3)c3ccccc3-c3cccc4oc5c6ccccc6ccc5c34)cc2)c([2H])c1[2H] ; [2H]c1c([2H])c([2H])c(-c2ccc(N(c3ccc(-c4cccc5c4ccc4ccccc45)cc3)c3cccc(-c4cccc5oc6c7ccccc7ccc6c45)c3)cc2)c([2H])c1[2H]]

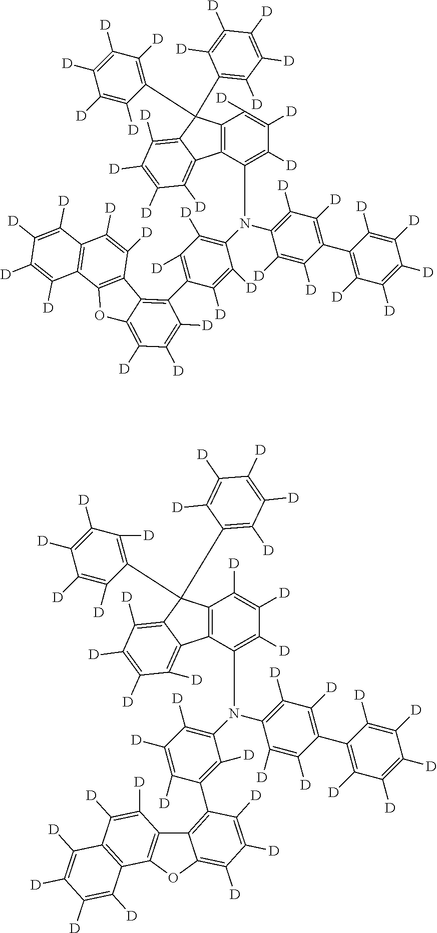

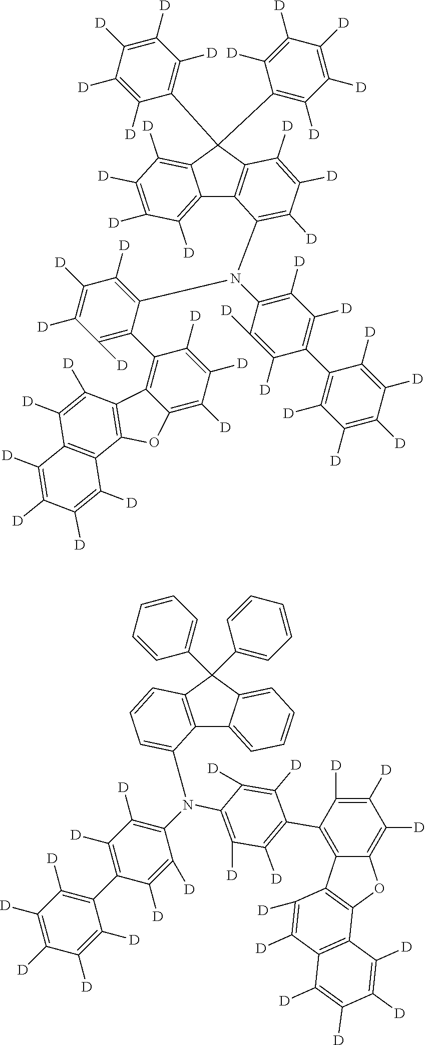

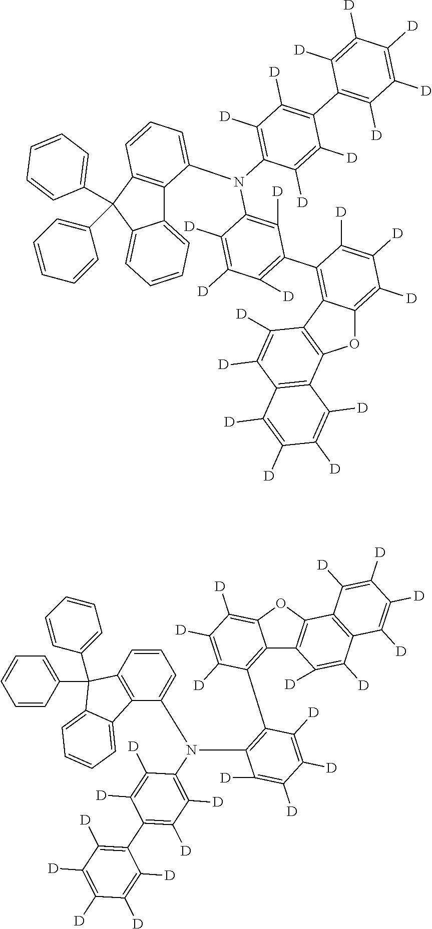 [SMILES: [2H]c1c([2H])c([2H])c(-c2c([2H])c([2H])c(N(c3cccc4c3-c3ccccc3C4(c3ccccc3)c3ccccc3)c3c([2H])c([2H])c([2H])c(-c4c([2H])c([2H])c([2H])c5oc6c7c([2H])c([2H])c([2H])c([2H])c7c([2H])c([2H])c6c45)c3[2H])c([2H])c2[2H])c([2H])c1[2H] ; [2H]c1c([2H])c([2H])c(-c2c([2H])c([2H])c(N(c3cccc4c3-c3ccccc3C4(c3ccccc3)c3ccccc3)c3c([2H])c([2H])c([2H])c([2H])c3-c3c([2H])c([2H])c([2H])c4oc5c6c([2H])c([2H])c([2H])c([2H])c6c([2H])c([2H])c5c34)c([2H])c2[2H])c([2H])c1[2H]]

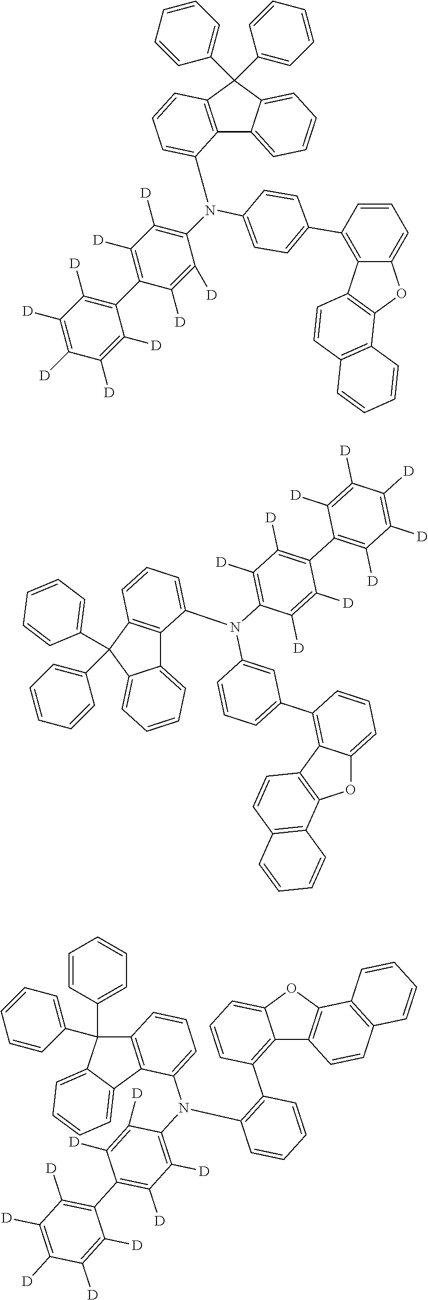

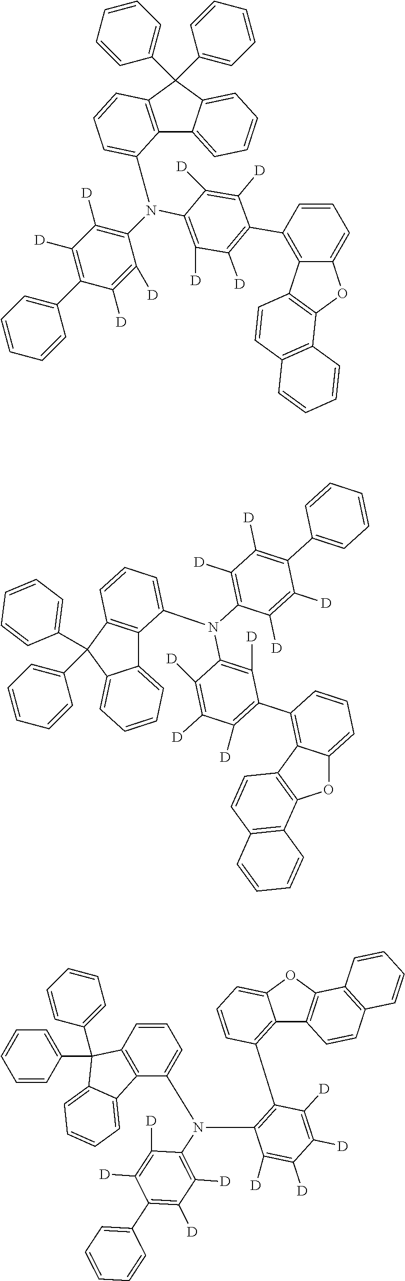 [SMILES: [2H]c1c([2H])c(N(c2cccc3c2-c2ccccc2C3(c2ccccc2)c2ccccc2)c2c([2H])c([2H])c(-c3cccc4oc5c6ccccc6ccc5c34)c([2H])c2[2H])c([2H])c([2H])c1-c1ccccc1 ; [2H]c1c([2H])c(-c2cccc3oc4c5ccccc5ccc4c23)c([2H])c(N(c2cccc3c2-c2ccccc2C3(c2ccccc2)c2ccccc2)c2c([2H])c([2H])c(-c3ccccc3)c([2H])c2[2H])c1[2H] ; [2H]c1c([2H])c([2H])c(N(c2cccc3c2-c2ccccc2C3(c2ccccc2)c2ccccc2)c2c([2H])c([2H])c(-c3ccccc3)c([2H])c2[2H])c(-c2cccc3oc4c5ccccc5ccc4c23)c1[2H]]

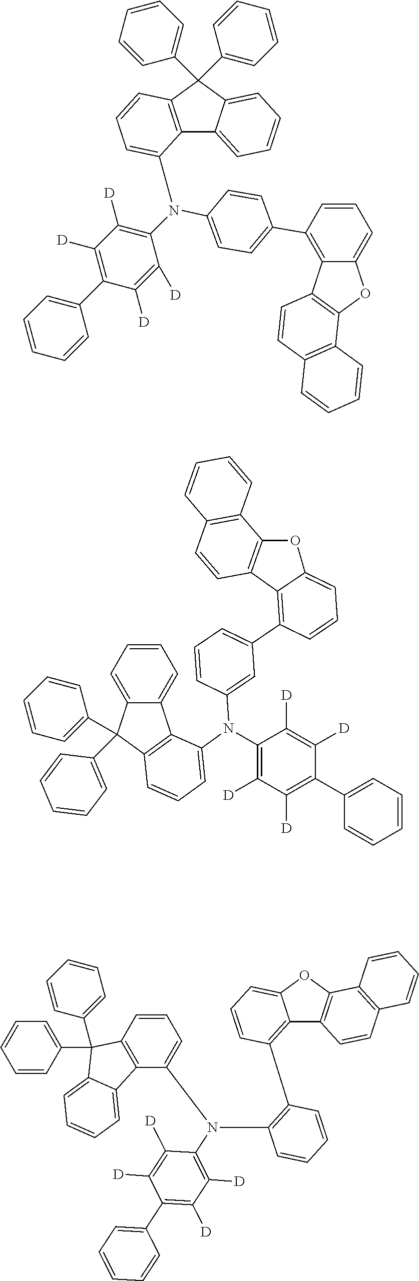 [SMILES: [2H]c1c([2H])c(N(c2ccc(-c3cccc4oc5c6ccccc6ccc5c34)cc2)c2cccc3c2-c2ccccc2C3(c2ccccc2)c2ccccc2)c([2H])c([2H])c1-c1ccccc1 ; [2H]c1c([2H])c(N(c2cccc(-c3cccc4oc5c6ccccc6ccc5c34)c2)c2cccc3c2-c2ccccc2C3(c2ccccc2)c2ccccc2)c([2H])c([2H])c1-c1ccccc1 ; [2H]c1c([2H])c(N(c2ccccc2-c2cccc3oc4c5ccccc5ccc4c23)c2cccc3c2-c2ccccc2C3(c2ccccc2)c2ccccc2)c([2H])c([2H])c1-c1ccccc1]

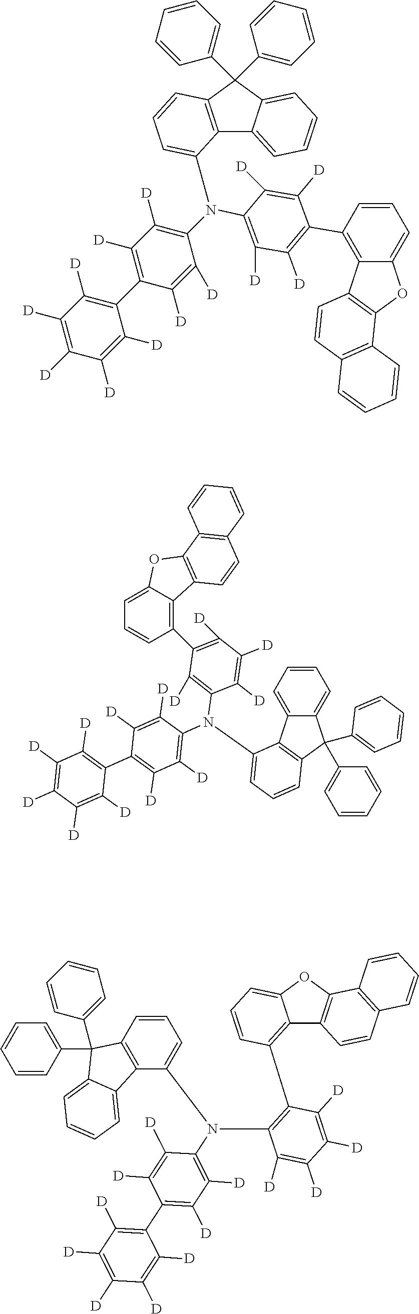

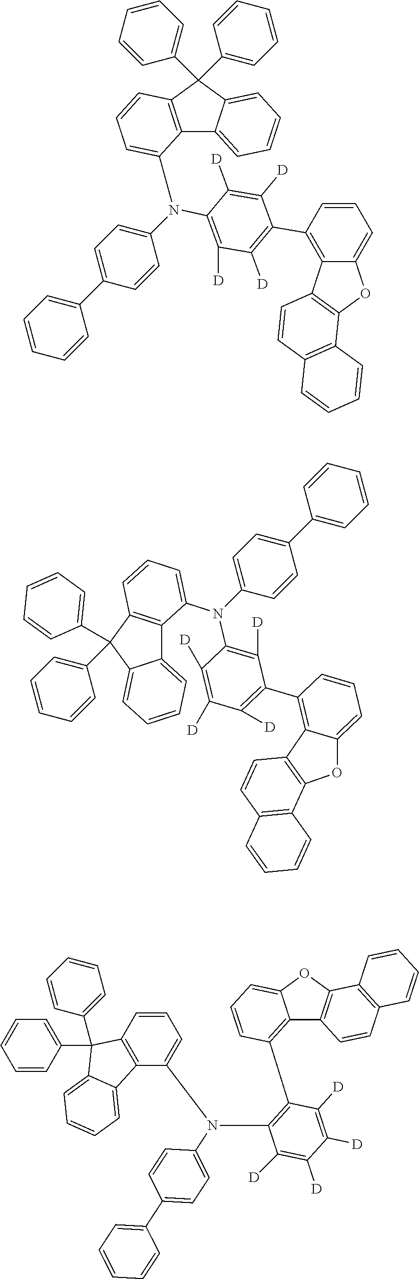 [SMILES: [2H]c1c([2H])c(N(c2ccc(-c3ccccc3)cc2)c2cccc3c2-c2ccccc2C3(c2ccccc2)c2ccccc2)c([2H])c([2H])c1-c1cccc2oc3c4ccccc4ccc3c12 ; [2H]c1c([2H])c(-c2cccc3oc4c5ccccc5ccc4c23)c([2H])c(N(c2ccc(-c3ccccc3)cc2)c2cccc3c2-c2ccccc2C3(c2ccccc2)c2ccccc2)c1[2H] ; [2H]c1c([2H])c([2H])c(N(c2ccc(-c3ccccc3)cc2)c2cccc3c2-c2ccccc2C3(c2ccccc2)c2ccccc2)c(-c2cccc3oc4c5ccccc5ccc4c23)c1[2H]]

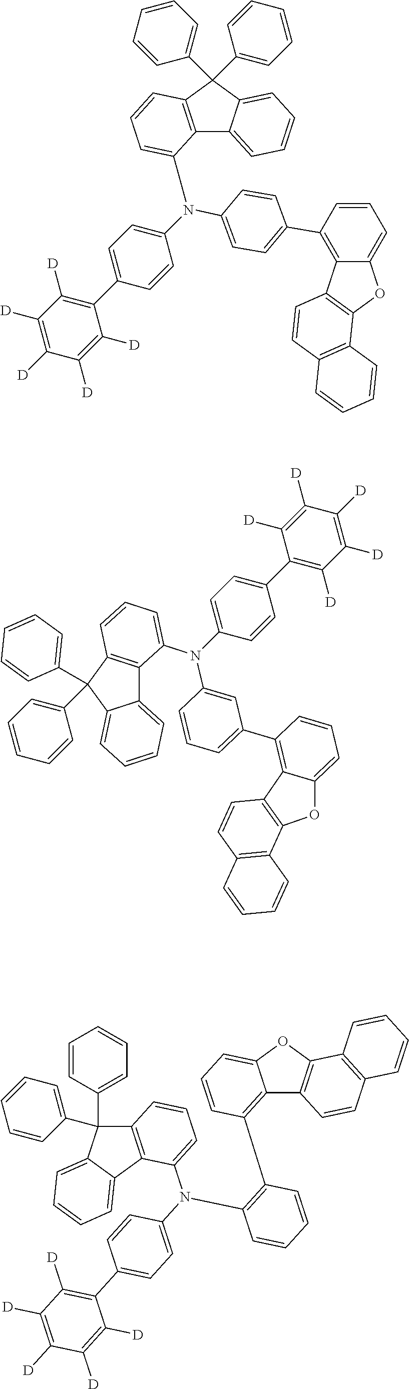 [SMILES: [2H]c1c([2H])c([2H])c(-c2ccc(N(c3ccc(-c4cccc5oc6c7ccccc7ccc6c45)cc3)c3cccc4c3-c3ccccc3C4(c3ccccc3)c3ccccc3)cc2)c([2H])c1[2H] ; [2H]c1c([2H])c([2H])c(-c2ccc(N(c3cccc(-c4cccc5oc6c7ccccc7ccc6c45)c3)c3cccc4c3-c3ccccc3C4(c3ccccc3)c3ccccc3)cc2)c([2H])c1[2H] ; [2H]c1c([2H])c([2H])c(-c2ccc(N(c3ccccc3-c3cccc4oc5c6ccccc6ccc5c34)c3cccc4c3-c3ccccc3C4(c3ccccc3)c3ccccc3)cc2)c([2H])c1[2H]]

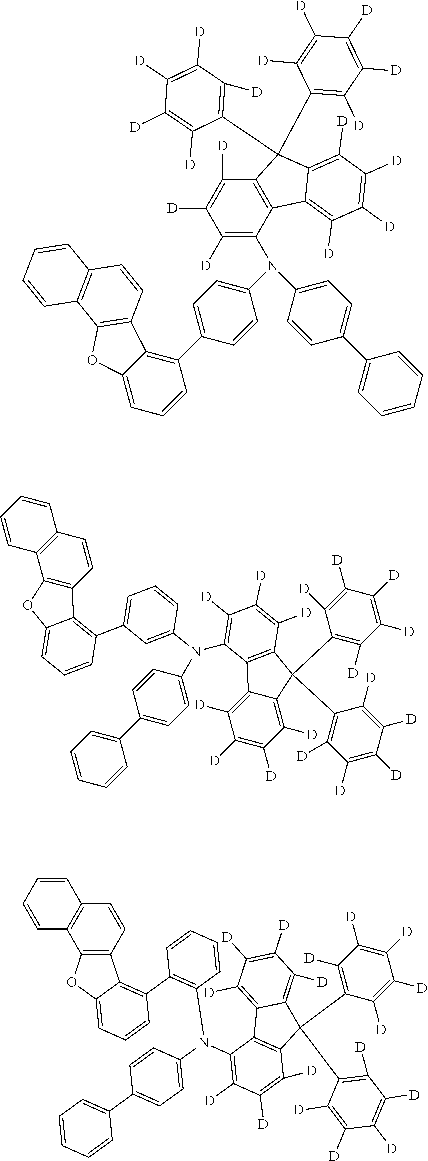

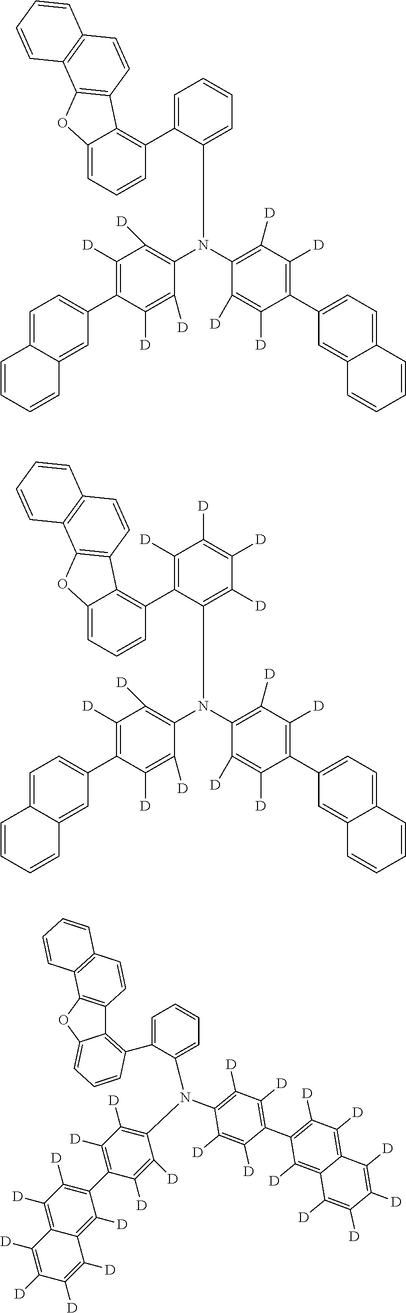

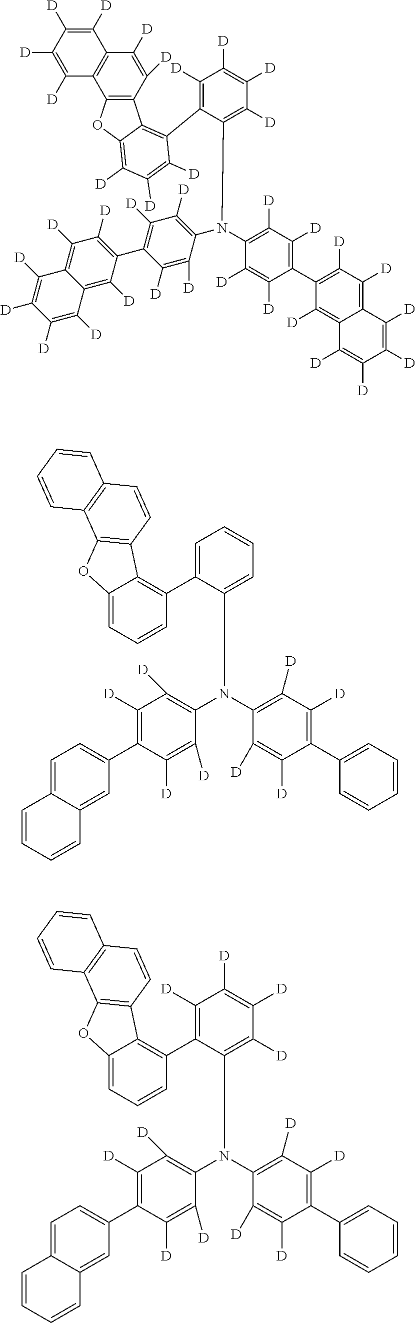

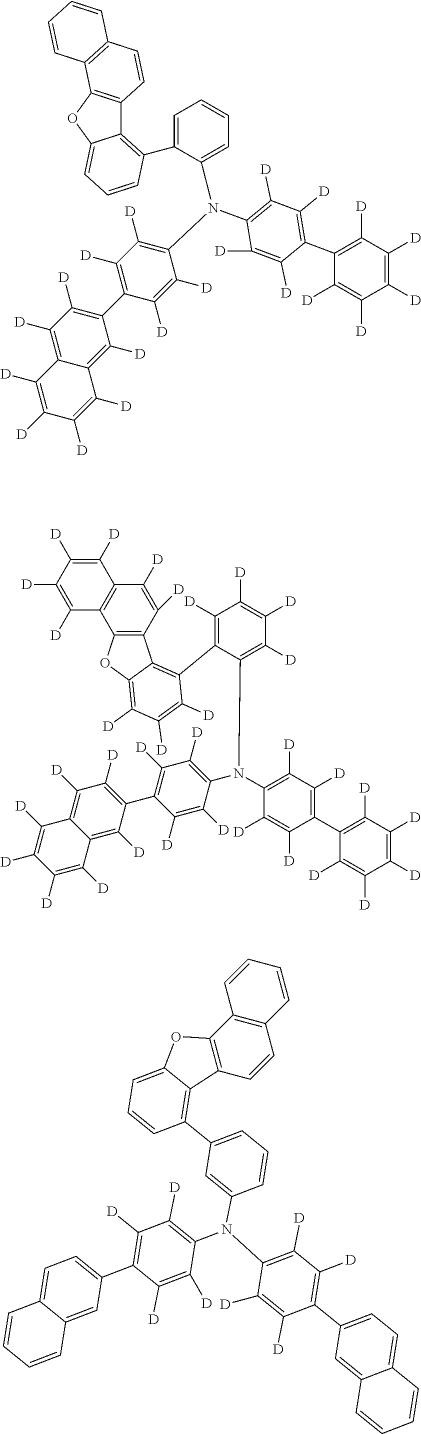

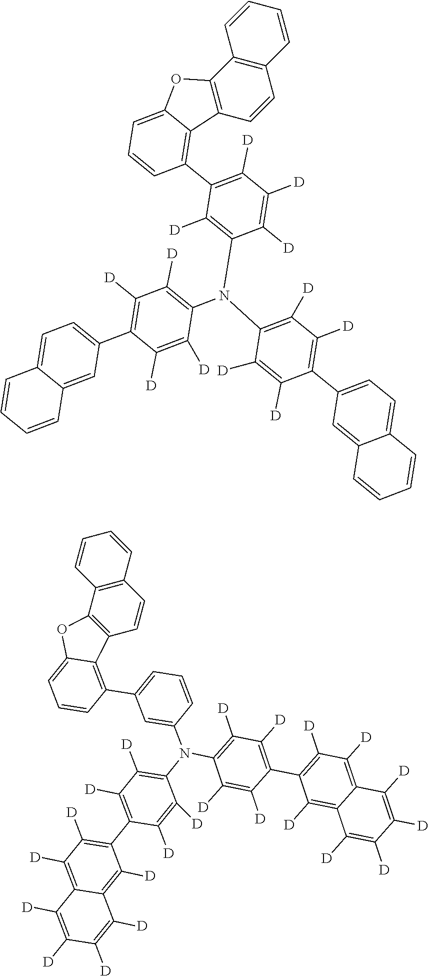 [SMILES: [2H]c1c([2H])c(-c2cccc3oc4c5ccccc5ccc4c23)c([2H])c(N(c2c([2H])c([2H])c(-c3ccc4ccccc4c3)c([2H])c2[2H])c2c([2H])c([2H])c(-c3ccc4ccccc4c3)c([2H])c2[2H])c1[2H] ; [2H]c1c([2H])c(N(c2cccc(-c3cccc4oc5c6ccccc6ccc5c34)c2)c2c([2H])c([2H])c(-c3c([2H])c([2H])c4c([2H])c([2H])c([2H])c([2H])c4c3[2H])c([2H])c2[2H])c([2H])c([2H])c1-c1c([2H])c([2H])c2c([2H])c([2H])c([2H])c([2H])c2c1[2H]]

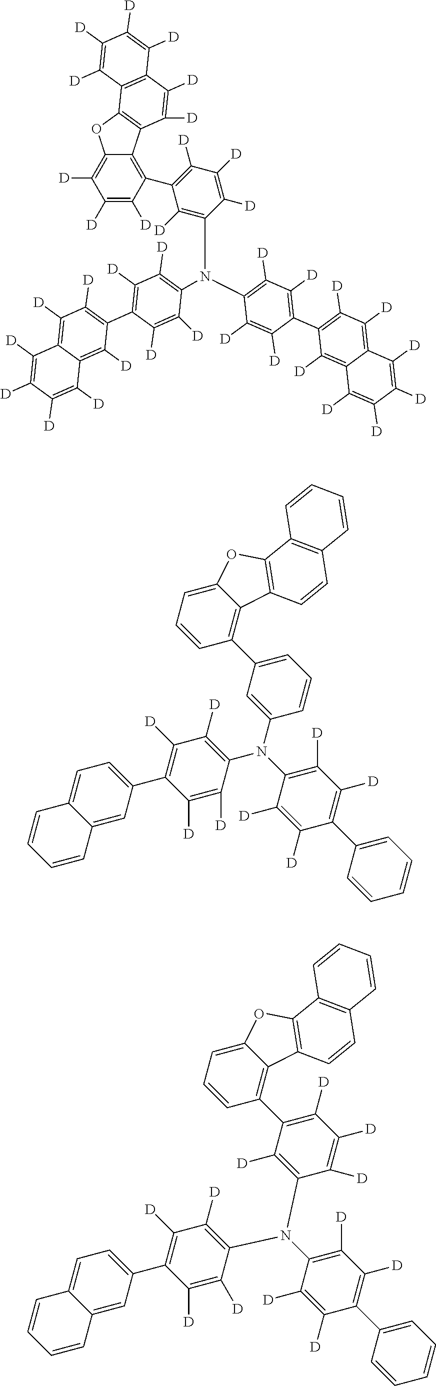

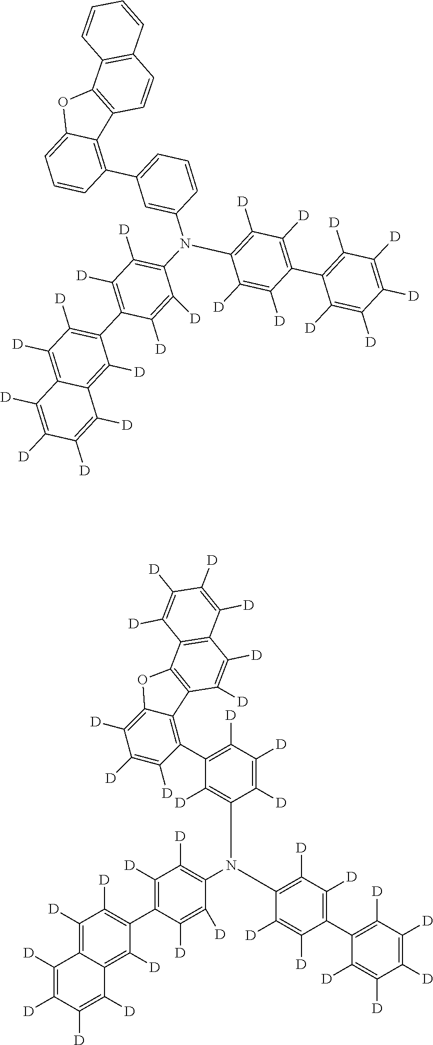 [SMILES: [2H]c1c([2H])c([2H])c(-c2c([2H])c([2H])c(N(c3cccc(-c4cccc5oc6c7ccccc7ccc6c45)c3)c3c([2H])c([2H])c(-c4c([2H])c([2H])c5c([2H])c([2H])c([2H])c([2H])c5c4[2H])c([2H])c3[2H])c([2H])c2[2H])c([2H])c1[2H] ; [2H]c1c([2H])c([2H])c(-c2c([2H])c([2H])c(N(c3c([2H])c([2H])c(-c4c([2H])c([2H])c5c([2H])c([2H])c([2H])c([2H])c5c4[2H])c([2H])c3[2H])c3c([2H])c([2H])c([2H])c(-c4c([2H])c([2H])c([2H])c5oc6c7c([2H])c([2H])c([2H])c([2H])c7c([2H])c([2H])c6c45)c3[2H])c([2H])c2[2H])c([2H])c1[2H]]

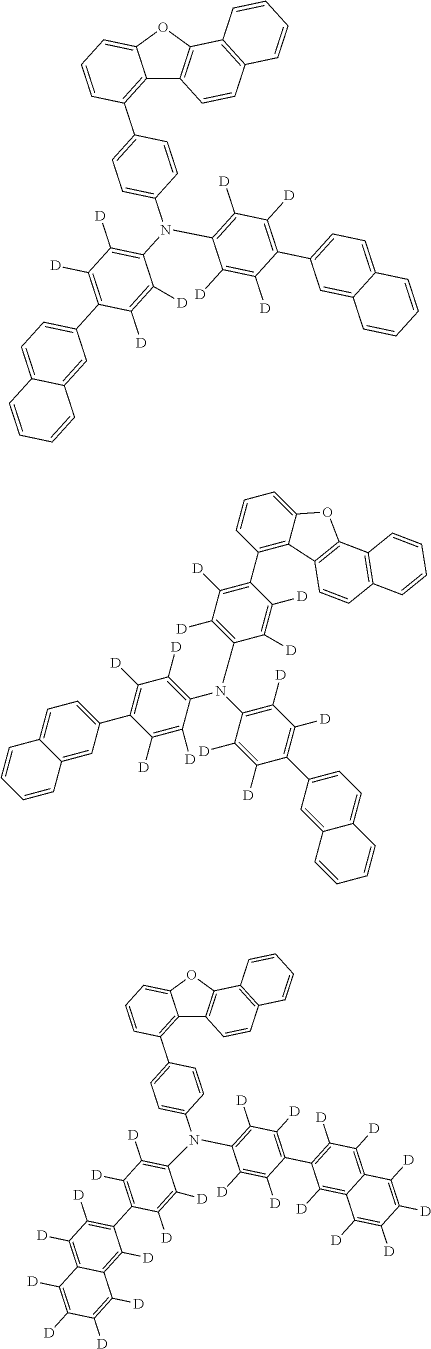

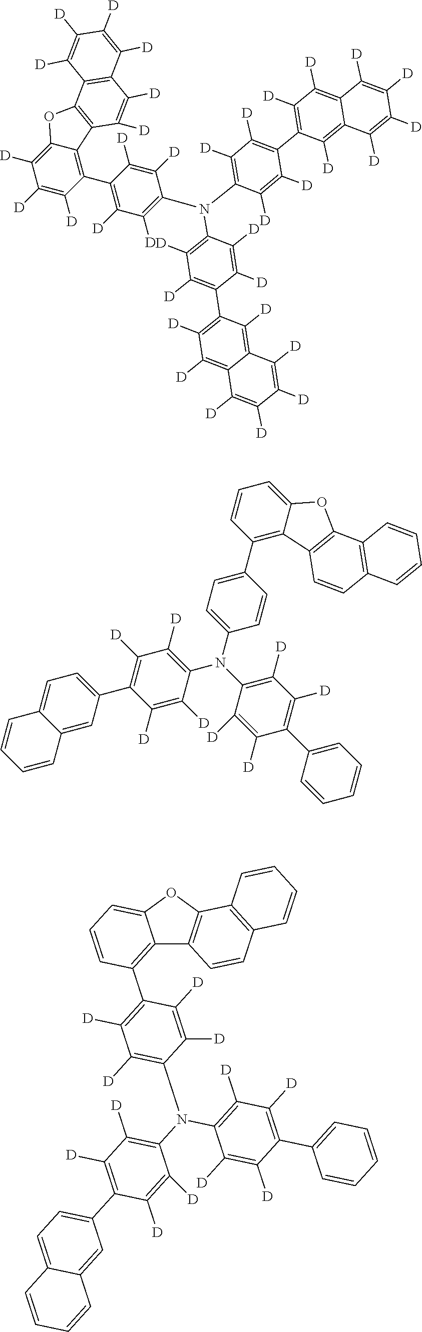

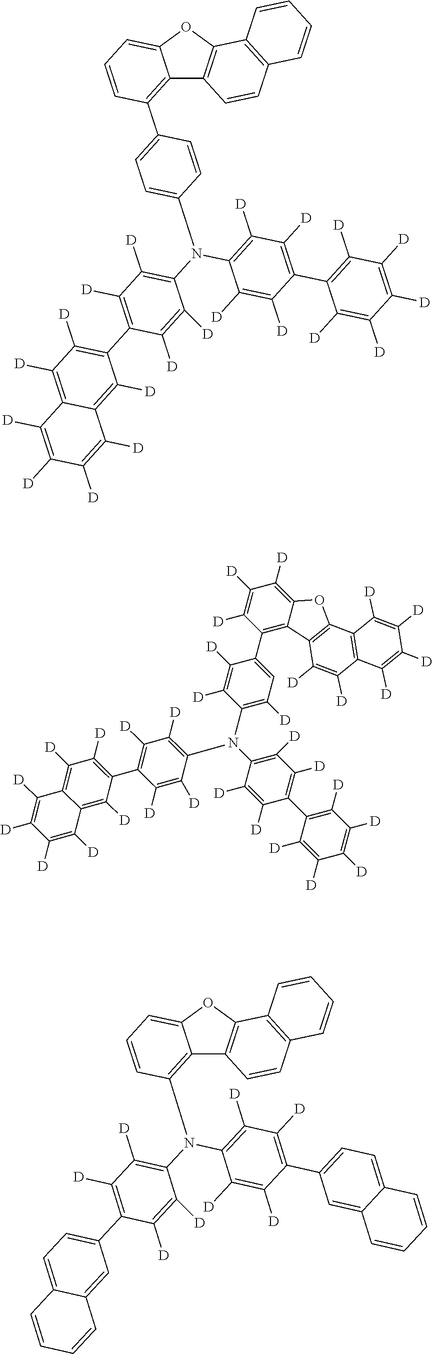

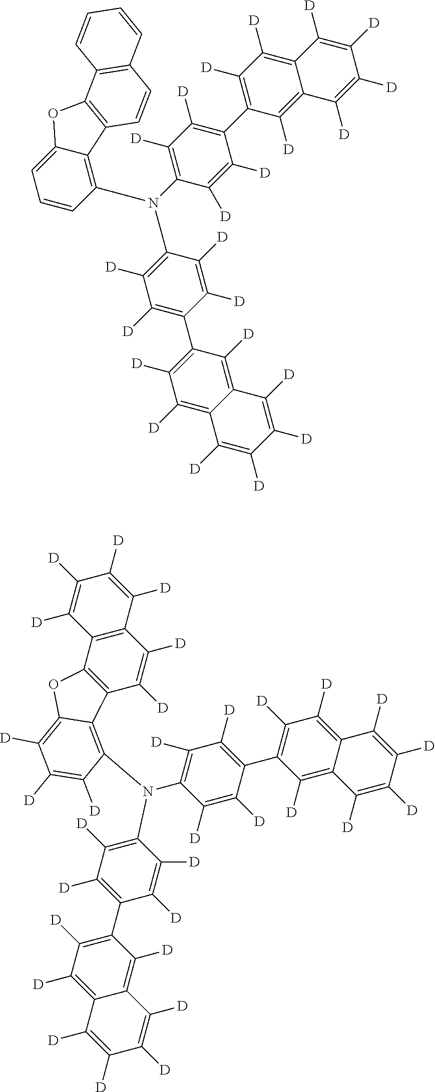 [SMILES: [2H]c1c([2H])c(N(c2c([2H])c([2H])c(-c3c([2H])c([2H])c4c([2H])c([2H])c([2H])c([2H])c4c3[2H])c([2H])c2[2H])c2cccc3oc4c5ccccc5ccc4c23)c([2H])c([2H])c1-c1c([2H])c([2H])c2c([2H])c([2H])c([2H])c([2H])c2c1[2H] ; [2H]c1c([2H])c(N(c2c([2H])c([2H])c(-c3c([2H])c([2H])c4c([2H])c([2H])c([2H])c([2H])c4c3[2H])c([2H])c2[2H])c2c([2H])c([2H])c([2H])c3oc4c5c([2H])c([2H])c([2H])c([2H])c5c([2H])c([2H])c4c23)c([2H])c([2H])c1-c1c([2H])c([2H])c2c([2H])c([2H])c([2H])c([2H])c2c1[2H]]

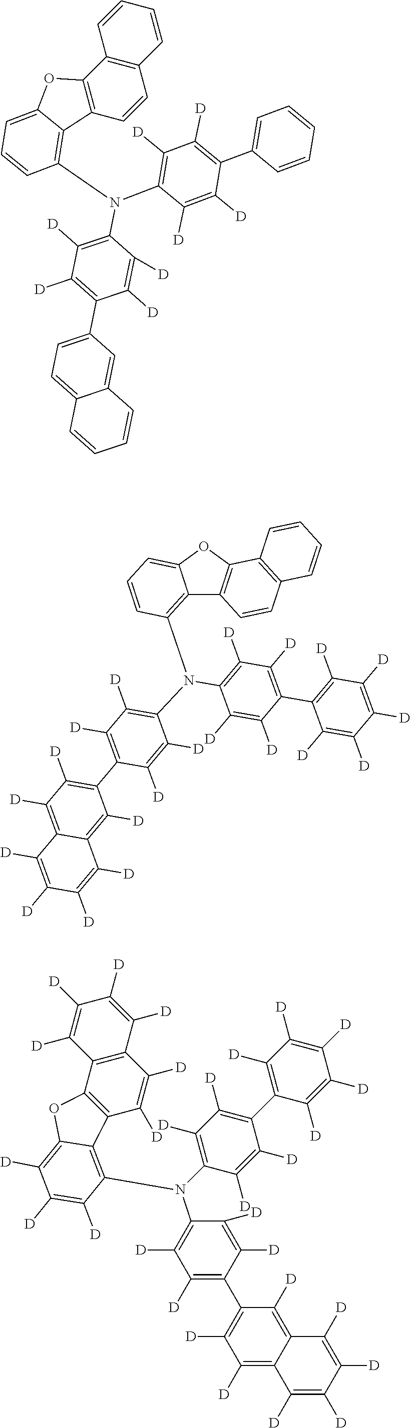

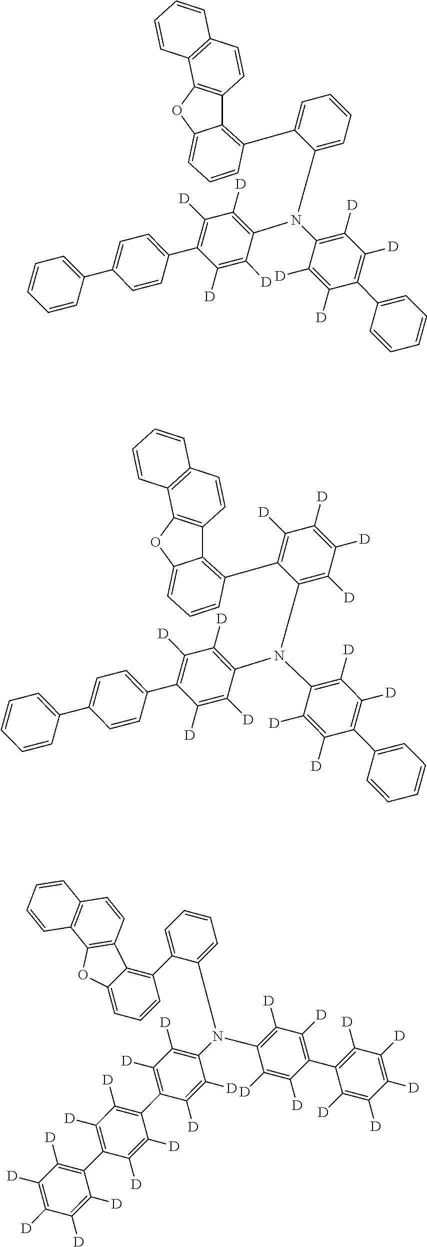 [SMILES: [2H]c1c([2H])c(N(c2ccccc2-c2cccc3oc4c5ccccc5ccc4c23)c2c([2H])c([2H])c(-c3ccc(-c4ccccc4)cc3)c([2H])c2[2H])c([2H])c([2H])c1-c1ccccc1 ; [2H]c1c([2H])c([2H])c(N(c2c([2H])c([2H])c(-c3ccccc3)c([2H])c2[2H])c2c([2H])c([2H])c(-c3ccc(-c4ccccc4)cc3)c([2H])c2[2H])c(-c2cccc3oc4c5ccccc5ccc4c23)c1[2H] ; [2H]c1c([2H])c([2H])c(-c2c([2H])c([2H])c(-c3c([2H])c([2H])c(N(c4ccccc4-c4cccc5oc6c7ccccc7ccc6c45)c4c([2H])c([2H])c(-c5c([2H])c([2H])c([2H])c([2H])c5[2H])c([2H])c4[2H])c([2H])c3[2H])c([2H])c2[2H])c([2H])c1[2H]]

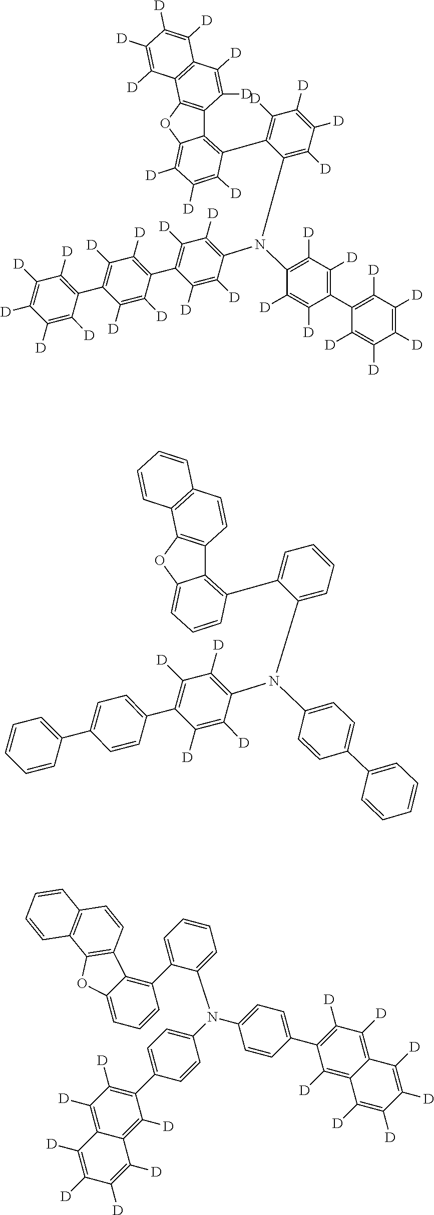

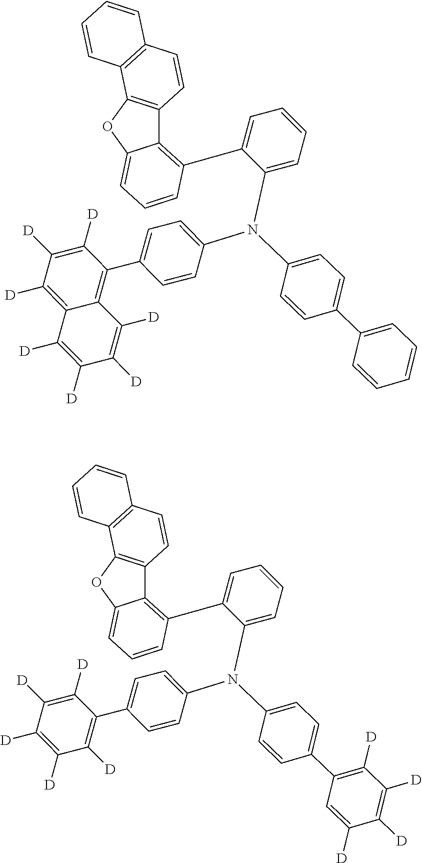 [SMILES: [2H]c1c([2H])c([2H])c2c(-c3ccc(N(c4ccc(-c5ccccc5)cc4)c4ccccc4-c4cccc5oc6c7ccccc7ccc6c45)cc3)c([2H])c([2H])c([2H])c2c1[2H] ; [2H]c1cc(-c2ccc(N(c3ccc(-c4c([2H])c([2H])c([2H])c([2H])c4[2H])cc3)c3ccccc3-c3cccc4oc5c6ccccc6ccc5c34)cc2)c([2H])c([2H])c1[2H]]

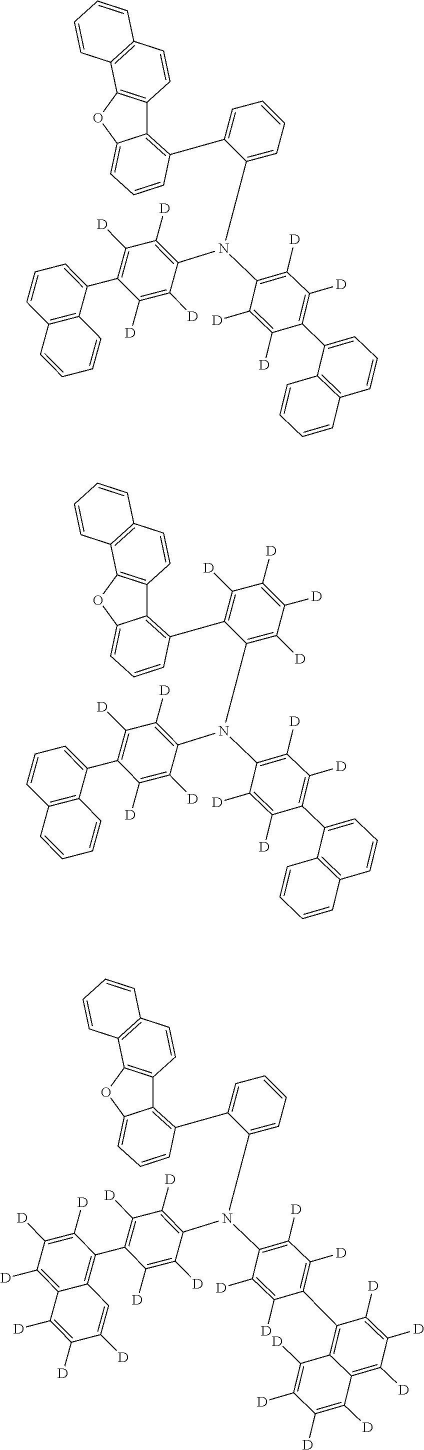 [SMILES: [2H]c1c([2H])c(N(c2ccccc2-c2cccc3oc4c5ccccc5ccc4c23)c2c([2H])c([2H])c(-c3cccc4ccccc34)c([2H])c2[2H])c([2H])c([2H])c1-c1cccc2ccccc12 ; [2H]c1c([2H])c([2H])c(N(c2c([2H])c([2H])c(-c3cccc4ccccc34)c([2H])c2[2H])c2c([2H])c([2H])c(-c3cccc4ccccc34)c([2H])c2[2H])c(-c2cccc3oc4c5ccccc5ccc4c23)c1[2H] ; [2H]c1cc2c(-c3c([2H])c([2H])c(N(c4ccccc4-c4cccc5oc6c7ccccc7ccc6c45)c4c([2H])c([2H])c(-c5c([2H])c([2H])c([2H])c6c([2H])c([2H])c([2H])c([2H])c56)c([2H])c4[2H])c([2H])c3[2H])c([2H])c([2H])c([2H])c2c([2H])c1[2H]]

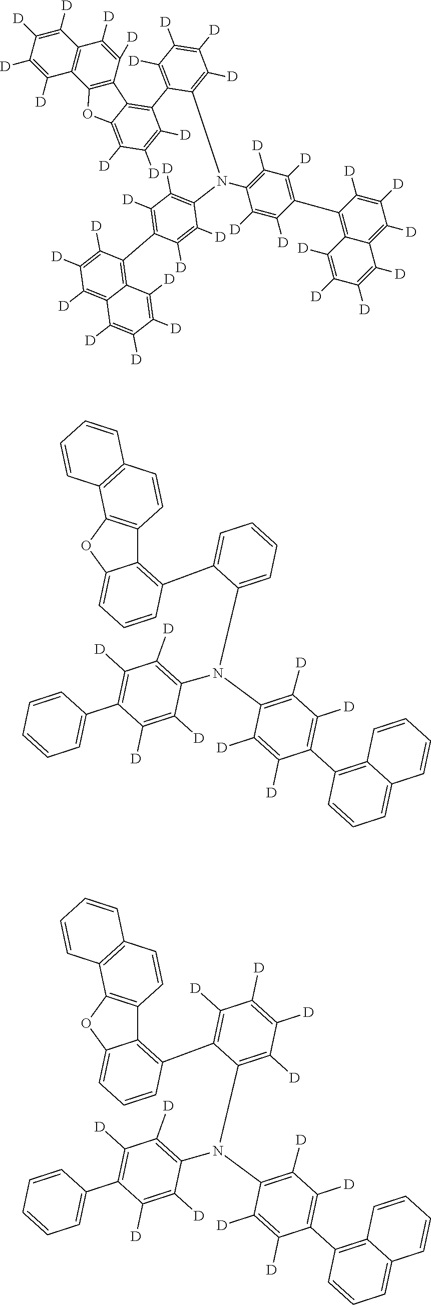

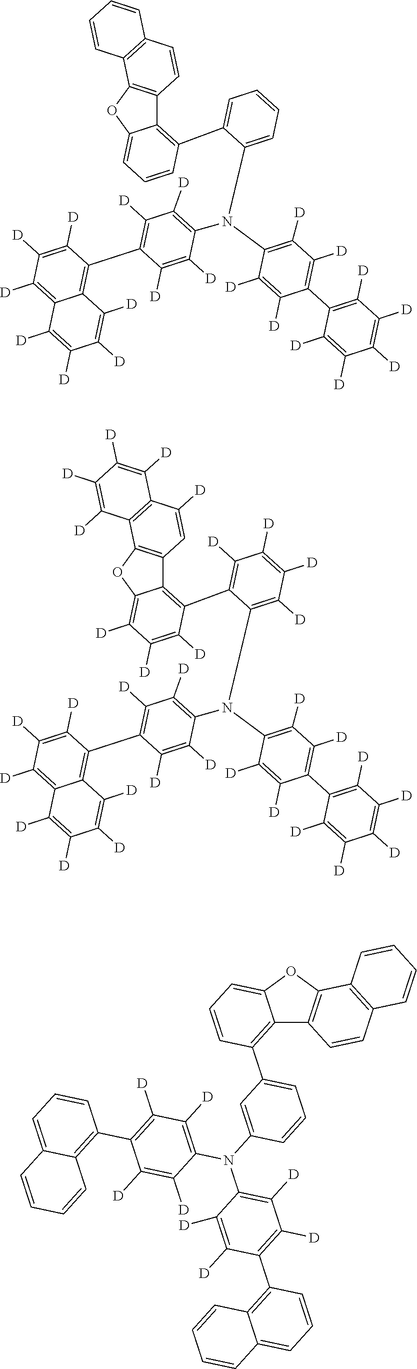

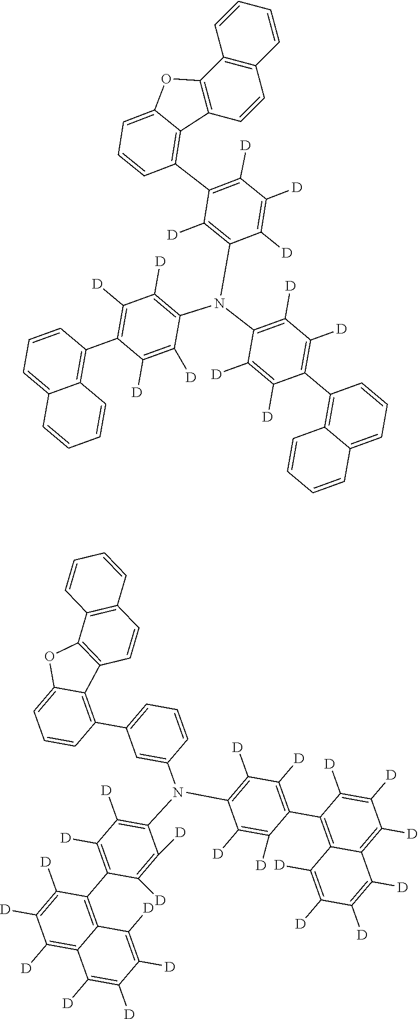 [SMILES: [2H]c1c([2H])c(-c2cccc3oc4c5ccccc5ccc4c23)c([2H])c(N(c2c([2H])c([2H])c(-c3cccc4ccccc34)c([2H])c2[2H])c2c([2H])c([2H])c(-c3cccc4ccccc34)c([2H])c2[2H])c1[2H] ; [2H]c1c([2H])c(N(c2cccc(-c3cccc4oc5c6ccccc6ccc5c34)c2)c2c([2H])c([2H])c(-c3c([2H])c([2H])c([2H])c4c([2H])c([2H])c([2H])c([2H])c34)c([2H])c2[2H])c([2H])c([2H])c1-c1c([2H])c([2H])c([2H])c2c([2H])c([2H])c([2H])c([2H])c12]

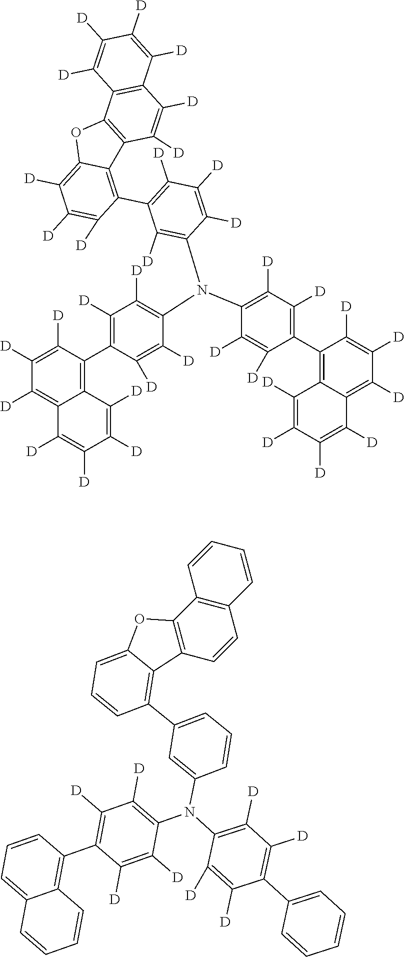 [SMILES: [2H]c1c([2H])c(-c2c([2H])c([2H])c([2H])c3oc4c5c([2H])c([2H])c([2H])c([2H])c5c([2H])c([2H])c4c23)c([2H])c(N(c2c([2H])c([2H])c(-c3c([2H])c([2H])c([2H])c4c([2H])c([2H])c([2H])c([2H])c34)c([2H])c2[2H])c2c([2H])c([2H])c(-c3c([2H])c([2H])c([2H])c4c([2H])c([2H])c([2H])c([2H])c34)c([2H])c2[2H])c1[2H] ; [2H]c1c([2H])c(N(c2cccc(-c3cccc4oc5c6ccccc6ccc5c34)c2)c2c([2H])c([2H])c(-c3cccc4ccccc34)c([2H])c2[2H])c([2H])c([2H])c1-c1ccccc1]

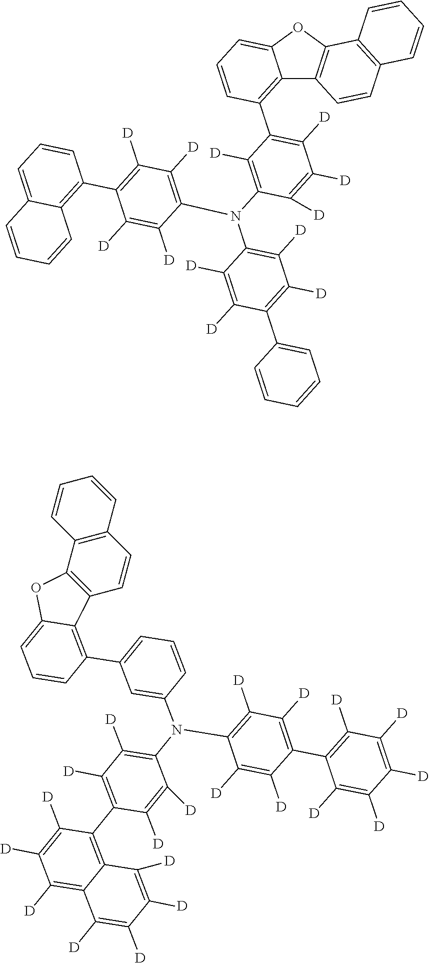 [SMILES: [2H]c1c([2H])c(-c2cccc3oc4c5ccccc5ccc4c23)c([2H])c(N(c2c([2H])c([2H])c(-c3ccccc3)c([2H])c2[2H])c2c([2H])c([2H])c(-c3cccc4ccccc34)c([2H])c2[2H])c1[2H] ; [2H]c1c([2H])c([2H])c(-c2c([2H])c([2H])c(N(c3cccc(-c4cccc5oc6c7ccccc7ccc6c45)c3)c3c([2H])c([2H])c(-c4c([2H])c([2H])c([2H])c5c([2H])c([2H])c([2H])c([2H])c45)c([2H])c3[2H])c([2H])c2[2H])c([2H])c1[2H]]

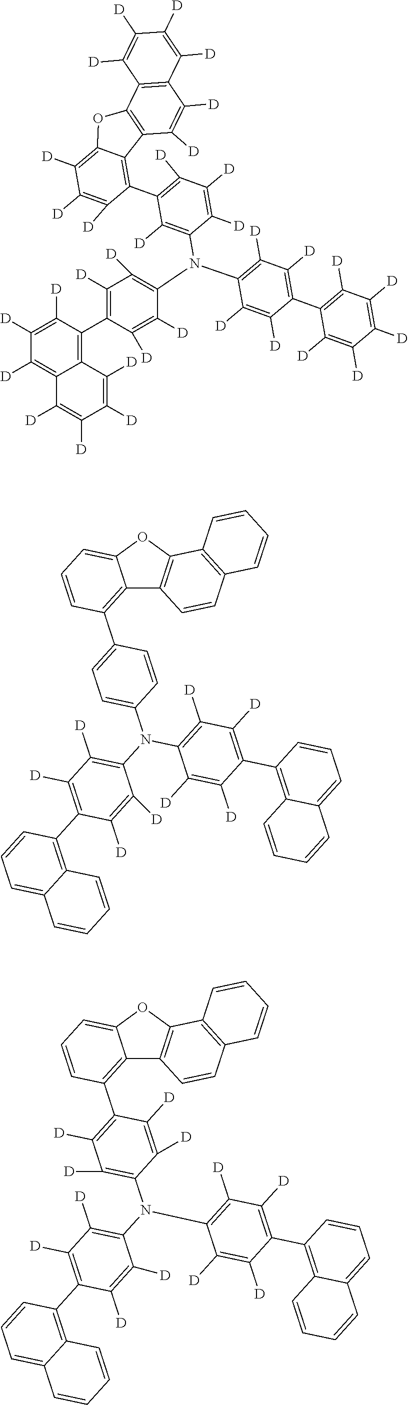

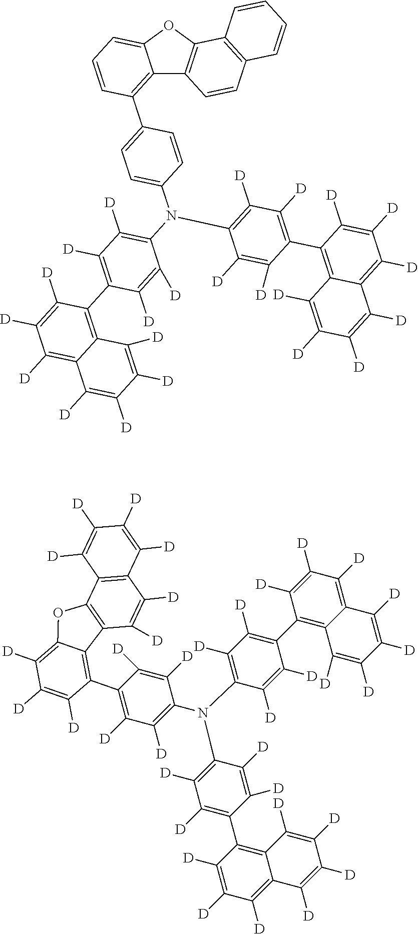

### Hole Injecting Layer

In an exemplary arrangement of the organic EL device of the exemplary embodiment, the hole injecting layer is provided between the anode and the emitting zone.

In an exemplary arrangement of the organic EL device of the exemplary embodiment, the anode is in direct contact with the hole injecting layer.

In an exemplary arrangement of the organic EL device of the exemplary embodiment, the hole injecting layer is in direct contact with the hole transporting layer.

In an exemplary arrangement of the organic EL device of the exemplary embodiment, a compound usable for the hole transporting layer (hole transporting zone material) is also usable for the hole injecting layer. In this case, the hole injecting layer preferably contains a hole transporting zone material and an acceptor material.

### Acceptor Material

The acceptor material contains at least one of a first cyclic structure represented by a formula (P11) below or a second cyclic structure represented by a formula (P12) below.

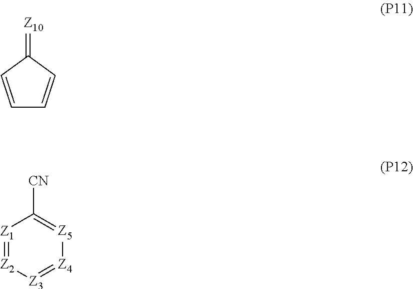

The first cyclic structure represented by the formula (P11) is fused to at least one cyclic structure of a substituted or unsubstituted aromatic hydrocarbon ring having 6 to 50 ring carbon atoms or a substituted or unsubstituted heterocycle having to 50 ring atoms in a molecule of the acceptor material, and
a structure represented by ═X₁₀ is represented by a formula (P11a), (P11 b), (P11c), (P11 d), (P11e), (P11f), (P11g), (P11 h), (P11 i), (P11j), (P11k), or (P11m) below.

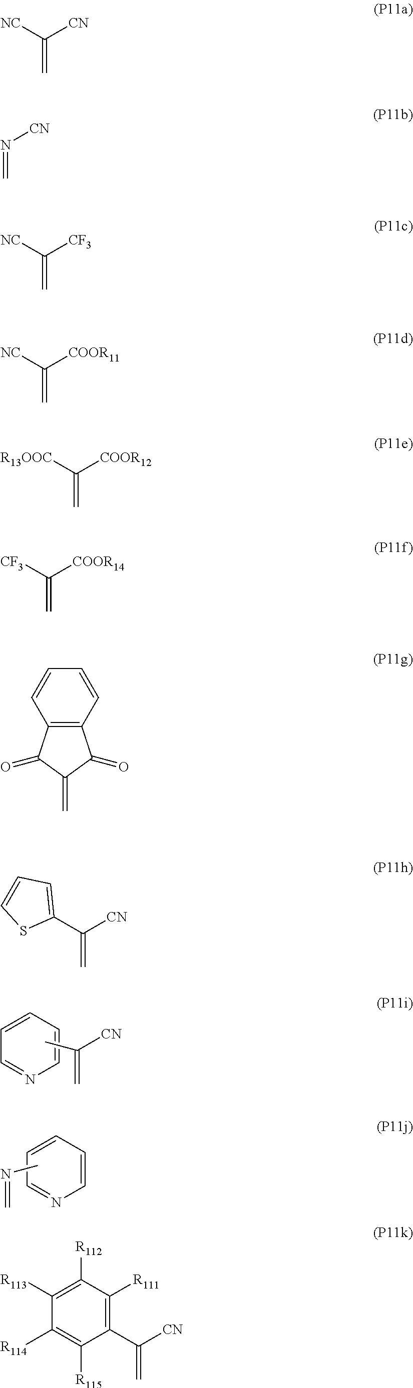

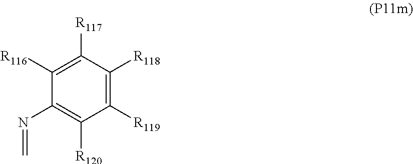

In the formula (P11a), (P11b), (P11c), (P11d), (P11e), (P11f), (P11g), (P11h), (P1 Ii), (P11j), (P11 k), or (P11 m), R₁₁ to R₁₄ and R₁₁₁ to R₁₂₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the formula (P12):
X₁ to X₅ are each independently a nitrogen atom, a carbon atom bonded to R₁₅, or a carbon atom bonded to another atom in the molecule of the acceptor material;
at least one of X₁ to X₅ is a carbon atom bonded to another atom in the molecule of the acceptor material;
R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the acceptor material, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device of the exemplary embodiment, the acceptor material has at least one cyano group.

In an exemplary arrangement of the organic EL device of the exemplary embodiment, the hole injecting layer contains the hole transporting zone material, the acceptor material and the hole transporting zone material are mutually different, and the content of the acceptor material in the hole injecting layer is less than 50 mass %.

In an exemplary arrangement of the organic EL device of the exemplary embodiment, the content of the acceptor material in the hole injecting layer is 10 mass % or less or 5 mass % or less.

In an exemplary arrangement of the organic EL device of the exemplary embodiment, the content of the acceptor material in the hole injecting layer is 1 mass % or more or 3 mass % or less.

In an exemplary arrangement of the organic EL device of the exemplary embodiment, the hole transporting zone material is preferably a compound selected from the group consisting of compounds usable for the hole transporting layer described later.

In an exemplary arrangement of the organic EL device of the exemplary embodiment, when the hole injecting layer contains the acceptor material and the hole transporting zone material, the content of the hole transporting zone material in the hole injecting layer is preferably 40 mass % or more, more preferably 45 mass % or more, and still more preferably 50 mass % or more. The content of the hole transporting zone material in the hole injecting layer is preferably 99.5 mass % or less. The total of the contents of the acceptor material and the hole transporting zone material in the hole injecting layer is 100 mass % or less.

An ester group herein is at least one group selected from the group consisting of an alkyl ester group and an aryl ester group.

An alkyl ester group herein is represented, for instance, by —C(═O)OR^{E}. R^{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R^{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂.

A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms.

R^{C} is exemplified by a substituted or unsubstituted alkyl group having 1 to 50 carbon atoms (preferably 1 to 6 carbon atoms).

In the acceptor material, also preferably, the groups specified to be “substituted or unsubstituted” are each an “unsubstituted” group.

### Specific Examples of Acceptor Material

Specific examples of the acceptor material include the following compounds. However, the invention is not limited to the specific examples of the acceptor material.

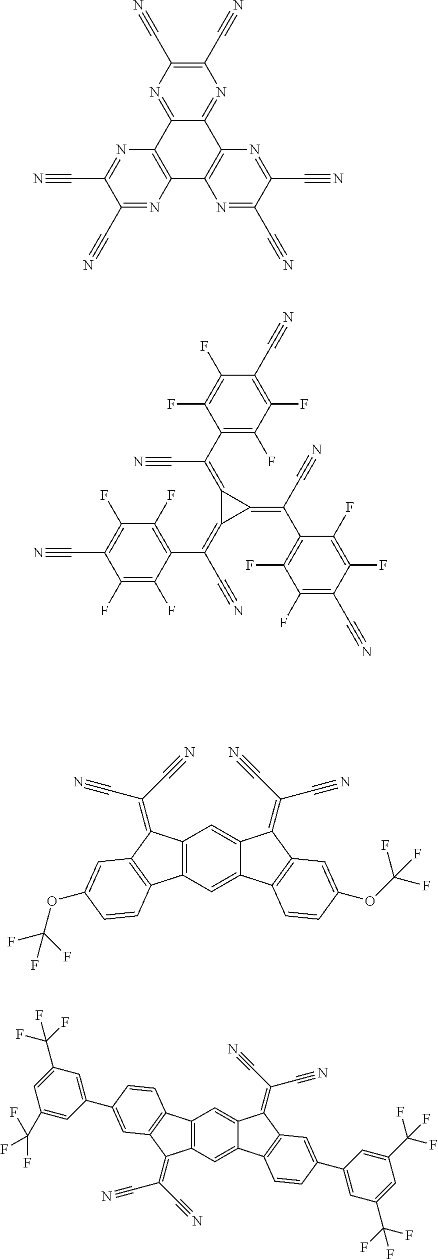 [SMILES: N#Cc1nc2c3nc(C#N)c(C#N)nc3c3nc(C#N)c(C#N)nc3c2nc1C#N ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

### Hole Transporting Layer

In an exemplary arrangement of the organic EL device of the exemplary embodiment, the hole transporting layer is provided between the anode and the emitting zone.

In an exemplary arrangement of the organic EL device of the exemplary embodiment, the hole transporting zone may include one hole transporting layer or two or more hole transporting layers.

In an exemplary arrangement of the organic EL device of the exemplary embodiment, the hole transporting layer contains a hole transporting zone material.

In an exemplary arrangement of the organic EL device of the exemplary embodiment, the hole transporting zone material is a monoamine compound having one substituted or unsubstituted amino group in a molecule, or a diamine compound having two substituted or unsubstituted amino groups in a molecule.

In an exemplary arrangement of the organic EL device of the exemplary embodiment, the hole transporting zone material is a monoamine compound having one substituted or unsubstituted amino group in a molecule.

In an exemplary arrangement of the organic EL device of the exemplary embodiment, the hole transporting zone material may be the third compound represented by the formula (EB1) or at least one compound selected from the group consisting of a compound represented by a formula (C1) below and a compound represented by a formula (C2) below.

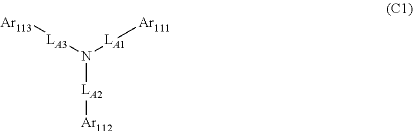

In the formula (C1):
L_{A1}, L_{A2}, and L_{A3} are each independently a single bond, a substituted or unsubstituted arylene group having 6 to 50 ring carbon atoms, or a substituted or unsubstituted divalent heterocyclic group having 5 to 50 ring atoms;
Ar₁₁₁, Ar₁₁₂, and Ar₁₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3}); R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

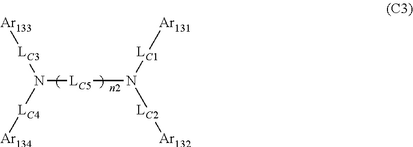

In the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₂₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3}); R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

In an exemplary composition of the exemplary embodiment, a first amino group represented by a formula (C3-1) below and a second amino group represented by a formula (C3-2) below in the compound represented by the formula (C3) are an identical group.

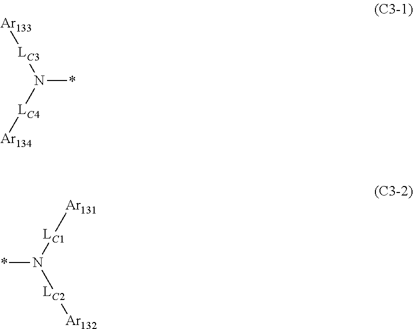

In the formulae (C3-1) and (C3-2), * each represent a bonding position to L_{C5}.

In an exemplary arrangement of the organic EL device of the exemplary embodiment, the first amino group represented by the formula (C3-1) and the second amino group represented by the formula (C3-2) may be mutually different.

### Specific Examples of Hole Transporting Zone Material

Specific examples of the hole transporting zone material include the following compounds. However, the invention is not limited to the specific examples of the hole transporting zone material.

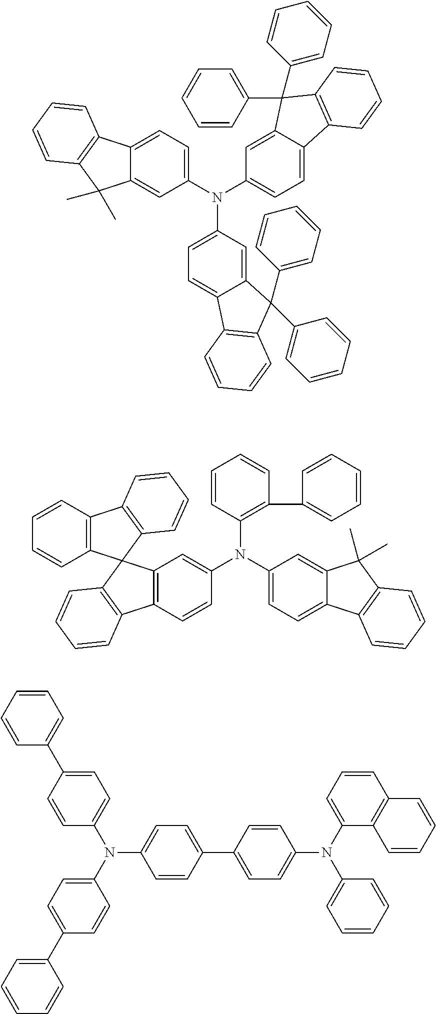 [SMILES: CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(N(c3ccc(-c4ccccc4)cc3)c3ccc(-c4ccc(N(c5ccccc5)c5cccc6ccccc56)cc4)cc3)cc2)cc1]

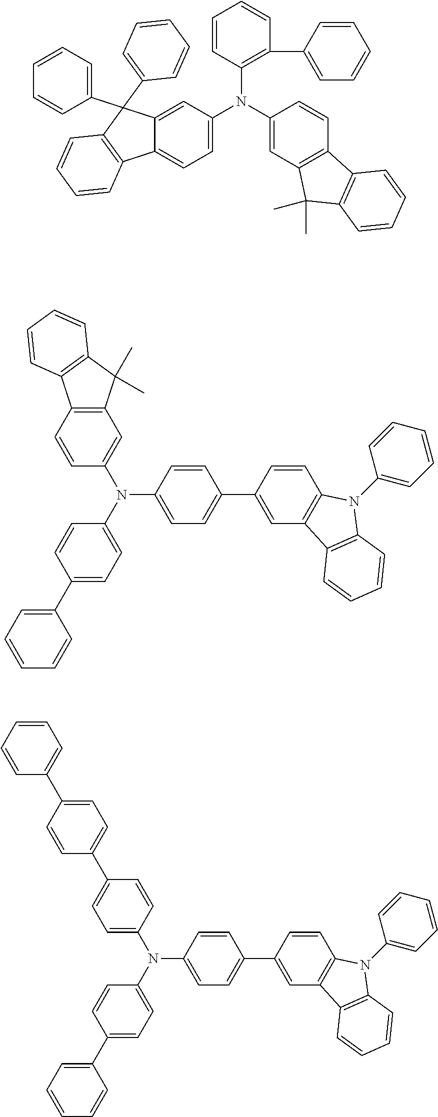 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

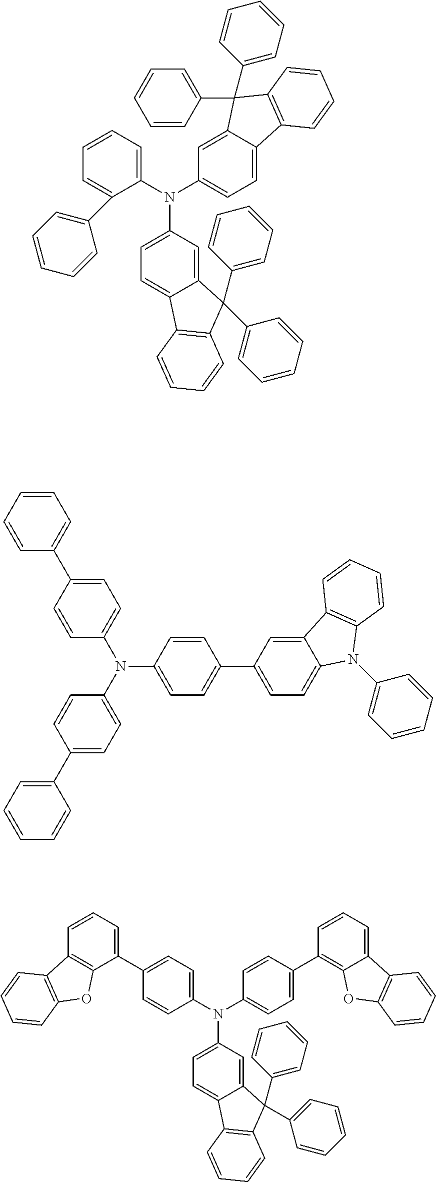 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1]

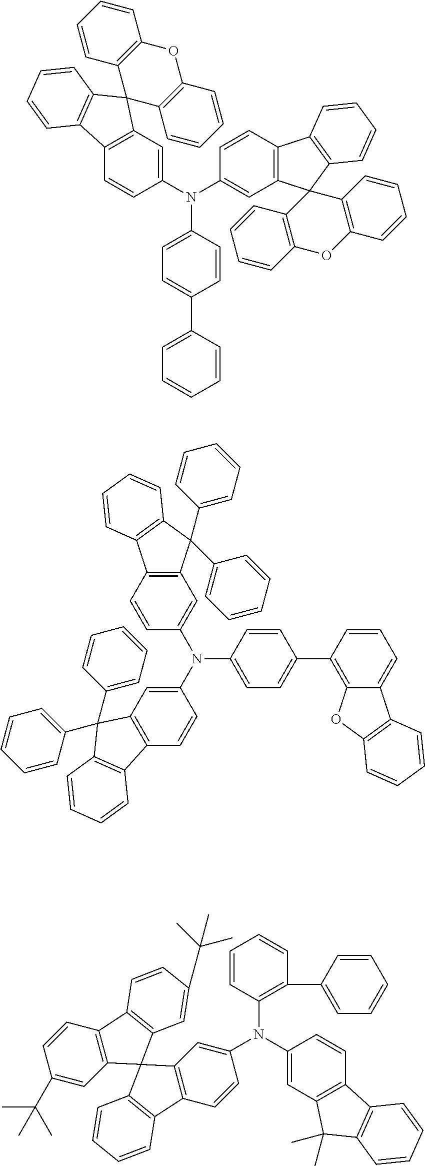 [SMILES: c1ccc(-c2ccc(N(c3ccc4c(c3)C3(c5ccccc5Oc5ccccc53)c3ccccc3-4)c3ccc4c(c3)C3(c5ccccc5Oc5ccccc53)c3ccccc3-4)cc2)cc1 ; c1ccc(C2(c3ccccc3)c3ccccc3-c3ccc(N(c4ccc(-c5cccc6c5oc5ccccc56)cc4)c4ccc5c(c4)C(c4ccccc4)(c4ccccc4)c4ccccc4-5)cc32)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

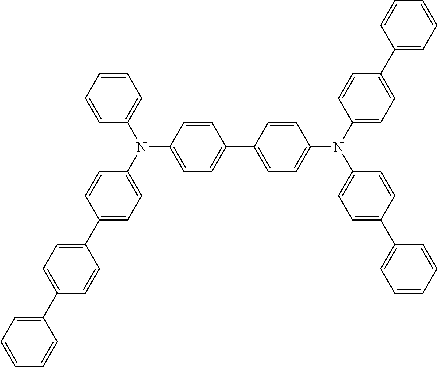 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

### Electron Blocking Layer

Preferably, the electron blocking layer permits transport of holes and blocks electrons from reaching a layer provided closer to the anode (e.g., the hole transporting layer) beyond the electron blocking layer.

In an exemplary arrangement of the organic EL device of the exemplary embodiment, the electron blocking layer contains the third compound represented by the formula (EB1).

In addition to the third compound represented by the formula (EB1), examples of the compound contained in the electron blocking layer of the organic EL device of the exemplary embodiment include a well-known compound used for the electron blocking layer, which may be at least one compound selected from the group consisting of an aromatic amine compound and a carbazole derivative. The compound contained in the electron blocking layer may be a monoamine compound having one substituted or unsubstituted amino group in a molecule. Further, the compound contained in the electron blocking layer may have, in a molecule, a substituted or unsubstituted carbazolyl group and one substituted or unsubstituted amino group.

In order to prevent excitation energy from leaking out from the emitting layer toward neighboring layer(s), the electron blocking layer may block excitons generated in the emitting layer from being transferred to a layer(s) closer to the anode (e.g., the hole transporting layer and the hole injecting layer) beyond the electron blocking layer.

### Emitting Zone

The emitting zone of the organic EL device of the exemplary embodiment is provided between the hole transporting zone and the cathode.

The emitting zone of the organic EL device of the exemplary embodiment includes at least one emitting layer, a first host material, a second host material, and an emitting compound being contained in a single emitting layer included in the at least one emitting layer.

In an exemplary arrangement of the organic EL device of the exemplary embodiment, the emitting layer is preferably in direct contact with the organic layer that contains the third compound represented by the formula (EB1).

In an exemplary arrangement of the organic EL device of the exemplary embodiment, the emitting zone includes a single emitting layer that contains the first host material, the second host material, and the emitting compound.

In an exemplary arrangement of the organic EL device of the exemplary embodiment, the emitting layer contains no metal complex. In an exemplary arrangement of the organic EL device of the exemplary embodiment, the emitting layer contains no boron-containing complex.

In an exemplary arrangement of the organic EL device of the exemplary embodiment, the emitting layer contains no phosphorescent material (dopant material).

In an exemplary arrangement of the organic EL device of the exemplary embodiment, the emitting layer does not contain a heavy metal complex and a phosphorescent rare earth metal complex. Examples of the heavy metal complex herein include iridium complex, osmium complex, and platinum complex.

In an exemplary arrangement of the organic EL device of the exemplary embodiment, the film thickness of the emitting layer is in a range from 5 nm to 30 nm.

In an exemplary arrangement of the organic EL device of the exemplary embodiment, the film thickness of the emitting layer is in a range from 10 nm to 25 nm.

### First Host Material and Second Host Material

In the organic EL device of the exemplary embodiment, the first host material and the second host material are each independently a compound represented by a formula (1) below. The first host material and the second host material are mutually different compounds.

### Compound Represented by Formula (1)

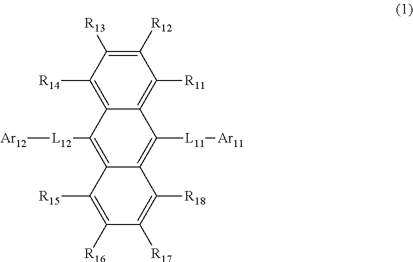

In the formula (1):
R₁₁ to R₁₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₁ and L₁₂ are each independently a single bond, a substituted or unsubstituted arylene group having 6 to 50 ring carbon atoms, or a substituted or unsubstituted divalent heterocyclic group having 5 to 50 ring atoms;
Ar₁₁ and Ar₁₂ are each independently a substituted or unsubstituted aryl group having 6 to 50 ring carbon atoms, or a substituted or unsubstituted heterocyclic group having 5 to 50 ring atoms.

In the first host material and the second host material, R₉₀₁, R₉₀₂, R₉₀₃, R₉₀₄, R₉₀₅, R₉₀₆, R₉₀₇, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device of the exemplary embodiment, the first host material is a compound represented by a formula (11) below and the second host material is a compound represented by a formula (12) below.

### Compound Represented by Formula (11)

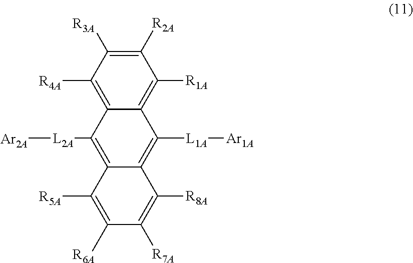

In the formula (11):
R_{1A} to R_{8A} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (11A) below; and
when two or more groups represented by the formula (11A) are present, the two or more groups represented by the formula (11A) are mutually the same or different.

*-L_{3A}-Ar_{3A} (11A)
L_{1A} and L_{2A} in the formula (11) and LA in the formula (11A) are each independently a single bond, a substituted or unsubstituted arylene group having 6 to 50 ring carbon atoms, or a substituted or unsubstituted divalent heterocyclic group having 5 to 50 ring atoms;
Ar_{1A} and Ar_{2A} in the formula (11) and Ar_{3A} in the formula (11A) are each independently a substituted or unsubstituted aryl group having 6 to 50 ring carbon atoms, or a substituted or unsubstituted heterocyclic group having 5 to 50 ring atoms; and
* in the formula (11A) represents a bonding position to an anthracene ring represented by the formula (11).

In an exemplary arrangement of the organic EL device of the exemplary embodiment, the compound represented by the formula (11) is a compound represented by a formula (111) below.

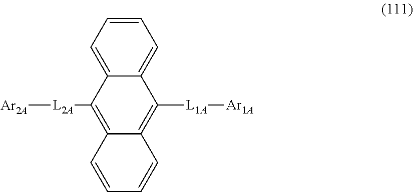

In the formula (111), L_{1A}, L_{2A}, Ar_{1A}, and Ar_{2A} respectively represent the same as those defined in the formula (11).

In an exemplary arrangement of the organic EL device of the exemplary embodiment, the compound represented by the formula (11) is a compound represented by a formula (112) below.

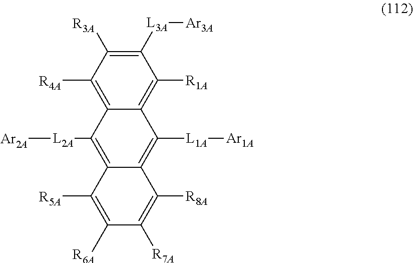

In the formula (112), R_{1A}, R_{3A} to R_{8A}, L_{1A}, L_{2A}, L_{3A}, Ar_{1A}, Ar_{2A}, and Ar_{3A} respectively represent the same as those defined in the formula (11) or (11 A).

In an exemplary arrangement of the organic EL device of the exemplary embodiment, the compound represented by the formula (11) is a compound represented by a formula (113), (114), or (115) below.

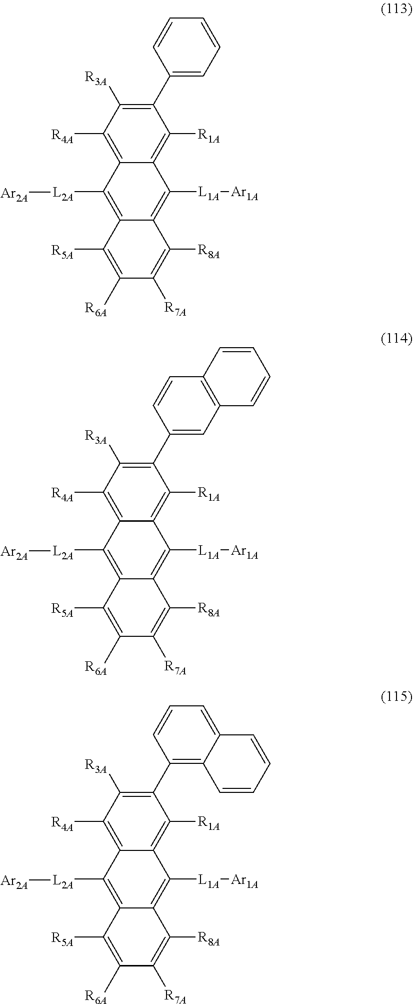

In the formulae (113), (114), and (115), R_{1A}, R_{3A} to R_{8A}, L_{1A}, L_{2A}, Ar_{1A}, and Ar_{2A} respectively represent the same as those defined in the formula (11).

In an exemplary arrangement of the organic EL device of the exemplary embodiment, the compound represented by the formula (11) is a compound represented by a formula (116) below.

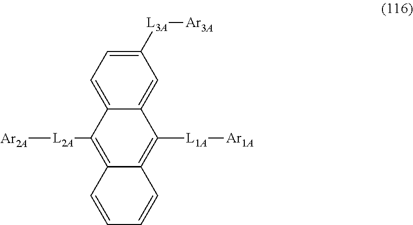

In the formula (116), L_{1A}, L_{2A}, L_{3A}, Ar_{1A}, Ar_{2A}, and Ar_{3A} respectively represent the same as those defined in the formula (11) or (11A).

In an exemplary arrangement of the organic EL device of the exemplary embodiment, the compound represented by the formula (11) is a compound represented by a formula (116A), (116B), or (116C) below.

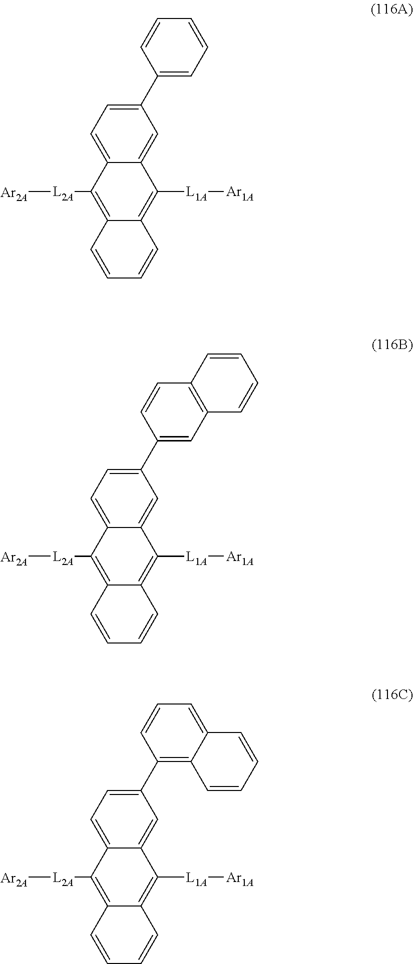

In the formulae (116A), (116B), and (116C), L_{1A}, L_{2A}, Ar_{1A}, and Ar_{2A} respectively represent the same as those defined in the formula (11).

In an exemplary arrangement of the organic EL device of the exemplary embodiment, L_{1A}, L_{2A}, and L_{3A} are each independently a single bond or a substituted or unsubstituted arylene group having 6 to 14 ring carbon atoms.

In an exemplary arrangement of the organic EL device of the exemplary embodiment, L_{1A}, L_{2A}, and L_{3A} are each independently a single bond, a substituted or unsubstituted phenylene group, or a substituted or unsubstituted naphthylene group.

In an exemplary arrangement of the organic EL device of the exemplary embodiment, Ar_{1A}, Ar_{2A}, and Ar_{3A} are each independently a substituted or unsubstituted aryl group having 6 to 50 ring carbon atoms.

In an exemplary arrangement of the organic EL device of the exemplary embodiment, Ar_{1A}, Ar_{2A}, and Ar_{3A} are each independently a group represented by a formula (11a), (11 b), (11c), or (11d) below.

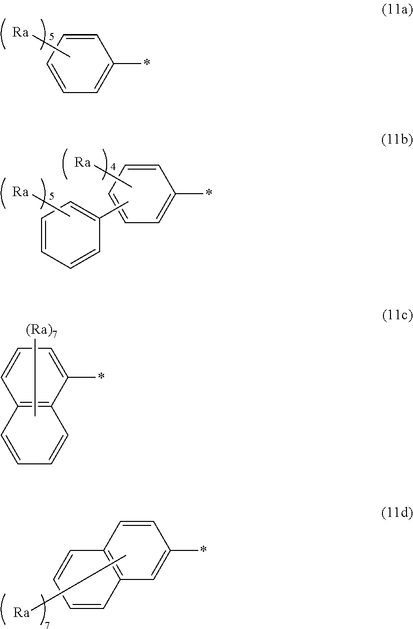

In the formulae (11a), (11 b), (11c), and (11d):
at least one combination of adjacent two or more of a plurality of Ra are mutually bonded to form a substituted or unsubstituted monocyclic ring, mutually bonded to form a substituted or unsubstituted fused ring, or not mutually bonded;
Ra forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of Ra are mutually the same or different; and
* is a single bond with L_{1A}, L_{2A}, or L_{3A}.

In an exemplary arrangement of the organic EL device of the exemplary embodiment, the compound represented by the formula (11) contains no hetero atom in a molecule.

In an exemplary arrangement of the organic EL device of the exemplary embodiment, the compound represented by the formula (11) is a hydrocarbon compound that contains only carbon atom(s) and hydrogen atom(s) in a molecule.

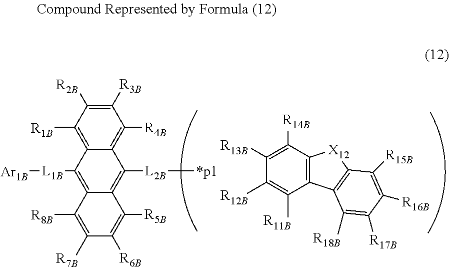

In the formula (12):
R_{1B} to R_{8B} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X₁₂ is an oxygen atom or a sulfur atom;
one of R_{11B} to R_{18B} is a single bond with *p1;
at least one combination of adjacent two or more of R_{11B} to R_{18B} not being the single bond with *p1 are mutually bonded to form a substituted or unsubstituted monocyclic ring, mutually bonded to form a substituted or unsubstituted fused ring, or not mutually bonded;
R_{11B} to R_{18B} not being the single bond with *p1, not forming the substituted or unsubstituted monocyclic ring, and not forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
L_{1B} and L_{2B} are each independently a single bond, a substituted or unsubstituted arylene group having 6 to 30 ring carbon atoms, or a substituted or unsubstituted divalent heterocyclic group having 5 to 30 ring atoms; and
Ar_{1B} is a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, the compound represented by the formula (12) is a compound represented by a formula (121), (122), (123), or (124) below.

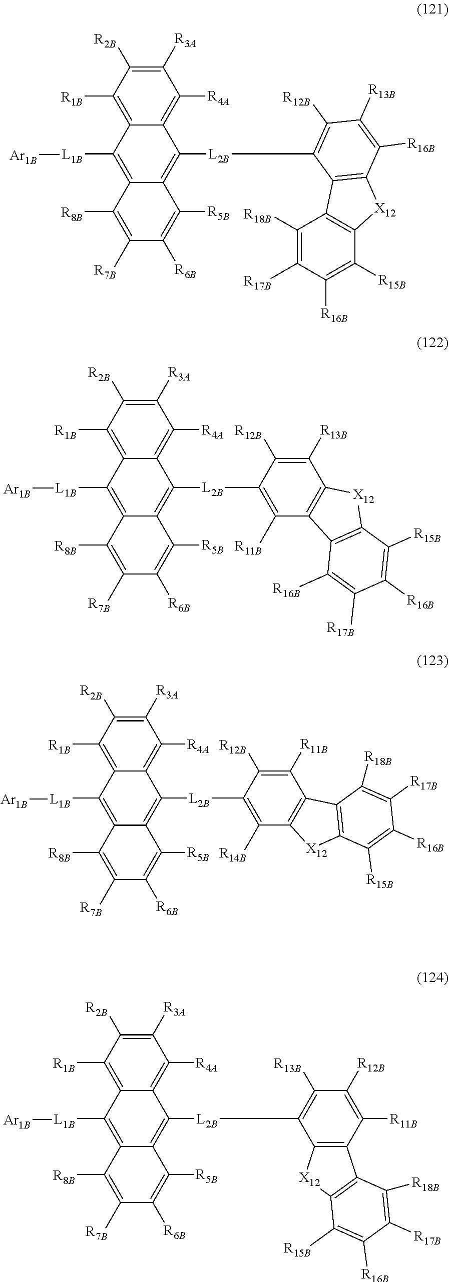

In the formulae (121) to (124), R_{1B} to R_{8B}, R_{11B} to R_{14B}, L_{1B}, L_{2B}, Ar_{1B}, and X₁₂ respectively represent the same as those defined in the formula (12).

In an exemplary arrangement of the organic EL device of the exemplary embodiment, at least one combination of adjacent two or more of R_{11B} to R_{18B} not being the single bond with *p1 are mutually bonded to form a substituted or unsubstituted monocyclic ring, or mutually bonded to form a substituted or unsubstituted fused ring.

In an exemplary arrangement of the organic EL device of the exemplary embodiment, none of combinations of adjacent two or more of R_{11B} to R_{14B} not being the single bond with *p1 are bonded to each other, and at least one combination of adjacent two or more of R_{15B} to R_{18B} not being the single bond with *p1 are mutually bonded to form a substituted or unsubstituted monocyclic ring, or mutually bonded to form a substituted or unsubstituted fused ring.

In an exemplary arrangement of the organic EL device of the exemplary embodiment, none of combinations of adjacent two or more of R_{11B} to R_{18B} not being the single bond with *p1 are bonded to each other.

In an exemplary arrangement of the organic EL device of the exemplary embodiment, L_{1B} and L_{2B} are each independently a single bond or a substituted or unsubstituted arylene group having 6 to 14 ring carbon atoms.

In an exemplary arrangement of the organic EL device of the exemplary embodiment, L_{1B} and L_{2B} are each independently a single bond a substituted or unsubstituted phenylene group, or a substituted or unsubstituted naphthylene group.

In an exemplary arrangement of the organic EL device of the exemplary embodiment, Ar_{1B} is a substituted or unsubstituted aryl group having 6 to 50 ring carbon atoms.

In an exemplary arrangement of the organic EL device of the exemplary embodiment, Ar_{1B} is a group represented by a formula (12a), (12b), (12c), or (12d) below.

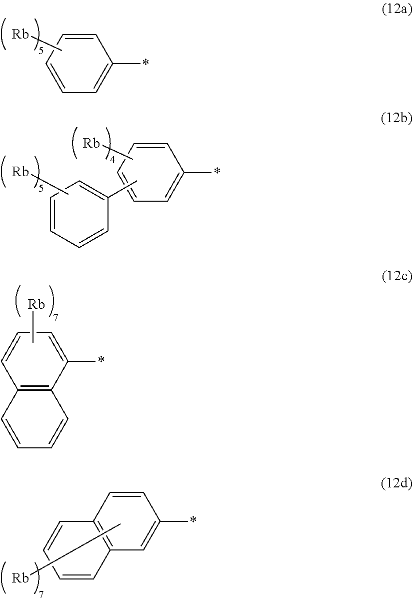

In the formulae (12a), (12b), (12c), and (12d):
at least one combination of adjacent two or more of a plurality of Rb are mutually bonded to form a substituted or unsubstituted monocyclic ring, mutually bonded to form a substituted or unsubstituted fused ring, or not mutually bonded;
Rb forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of Rb are mutually the same or different; and
* is a single bond with L_{1B}.

In an exemplary arrangement of the organic EL device of the exemplary embodiment, X₁₂ is an oxygen atom.

In an exemplary arrangement of the organic EL device of the exemplary embodiment, the compound represented by the formula (12) is a compound represented by a formula (125), (126), (127), (128), or (129) below.

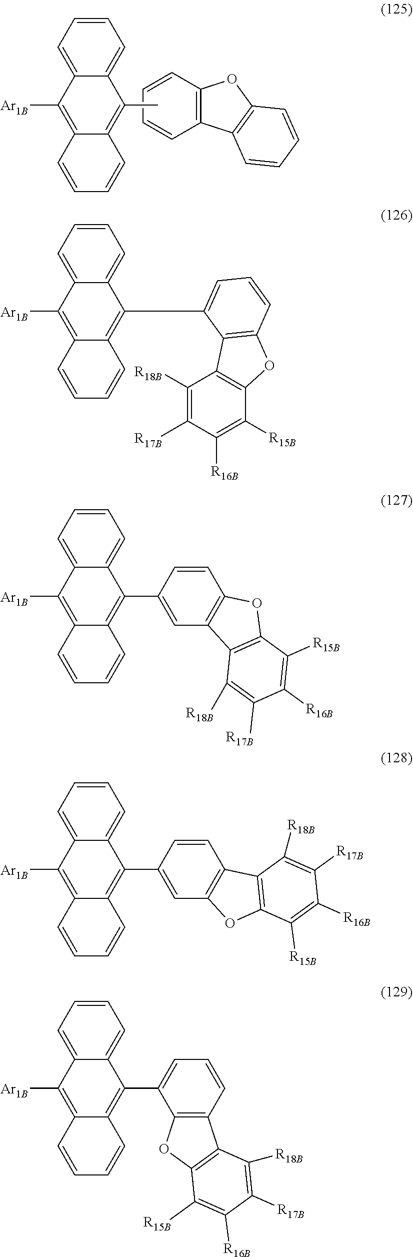

In the formulae (125) to (129), R_{15B} to R_{18B} and Ar_{1B} respectively represent the same as those defined in the formula (12).

In the compounds according to the first and second host materials in an exemplary arrangement of the organic EL device of the exemplary embodiment, also preferably, the groups specified to be “substituted or unsubstituted” are each an “unsubstituted” group.

In an exemplary arrangement of the organic EL device of the exemplary embodiment, the emitting layer containing the first host material, the second host material, and the emitting compound may contain, for instance, the first host material and the second host material in total, at 50 mass % or more, 60 mass % or more, 70 mass % or more, 80 mass % or more, 90 mass % or more, or 95 mass % or more with respect to the total mass of said emitting layer.

In an exemplary arrangement of the organic EL device of the exemplary embodiment, the content ratio (mass ratio) of the first host material and the second host material in the emitting layer may be 1:99 to 99:1, 10:90 to 90:10, 20:80 to 80:20, 40:60 to 60:40, or 45:55 to 55:45,

### Manufacturing Method of First Host Material and Second Host Material

The first host material and the second host material according to the exemplary embodiment can be manufactured based on a known method or through a known alternative reaction using a known material(s) tailored for the target compound in accordance with the known method.

### Specific Examples of First Host Material and Second Host Material

Specific examples of the first host material and the second host material according to the exemplary embodiment include compounds below. However, the invention is not limited to the specific examples.

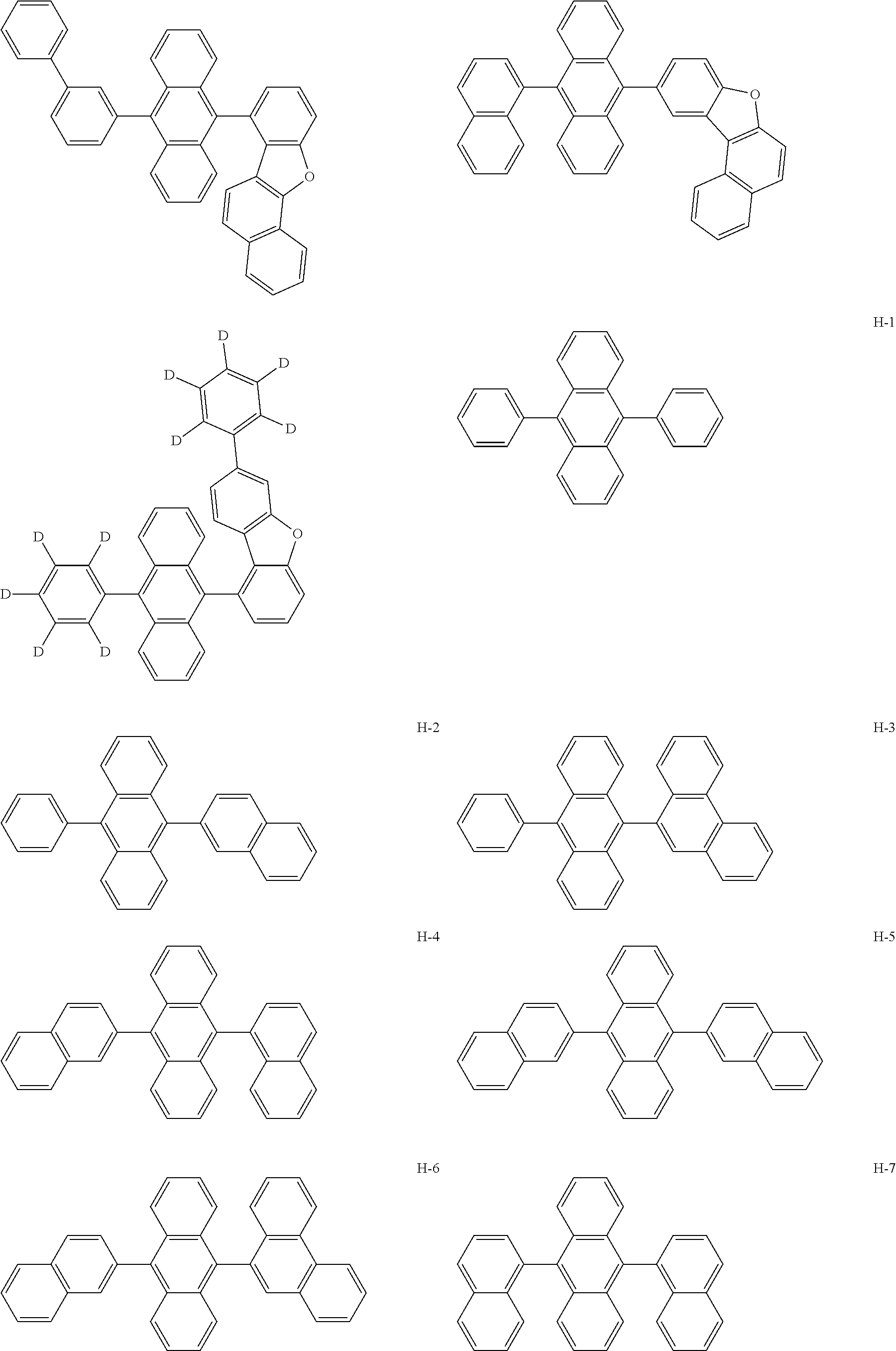

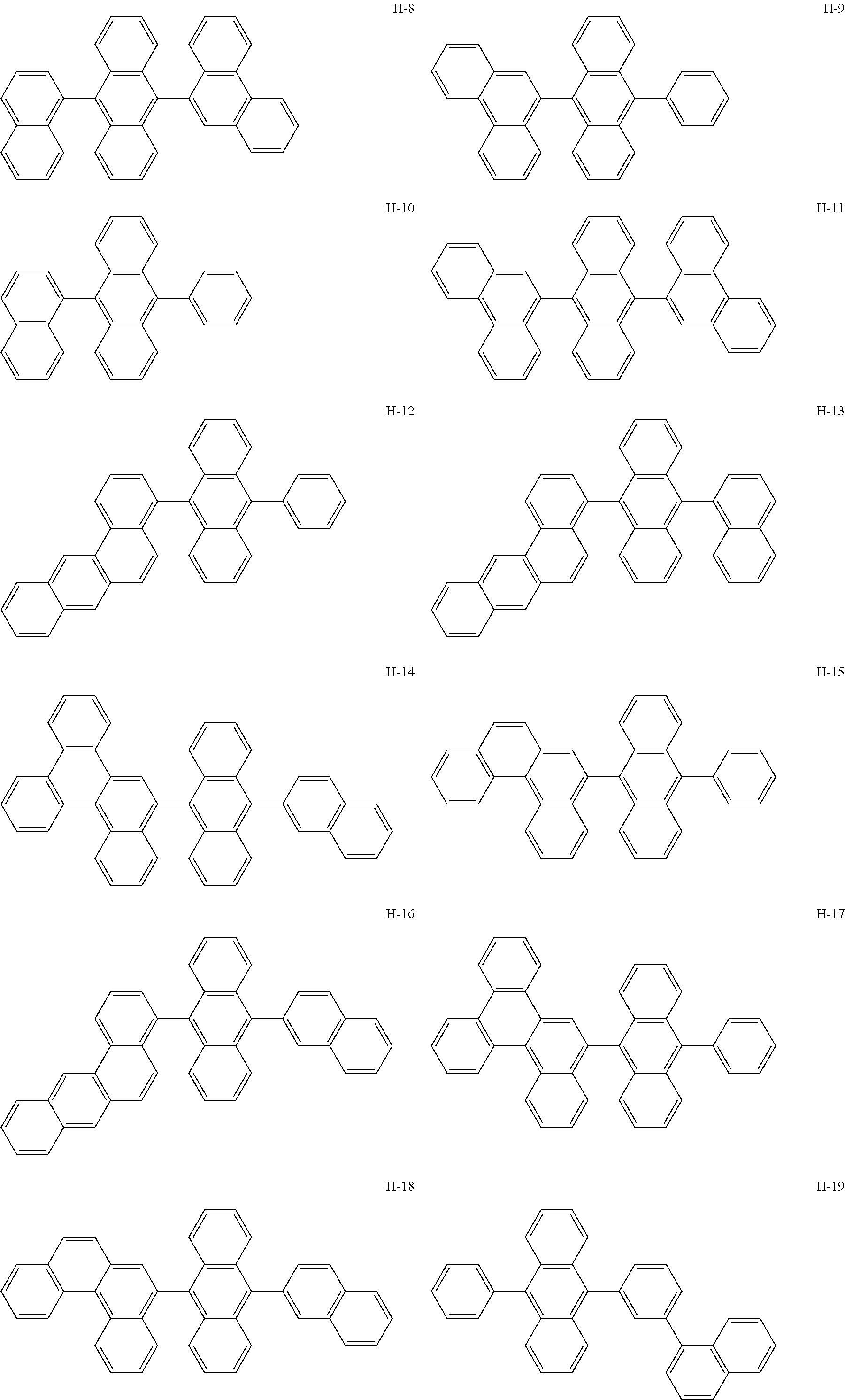

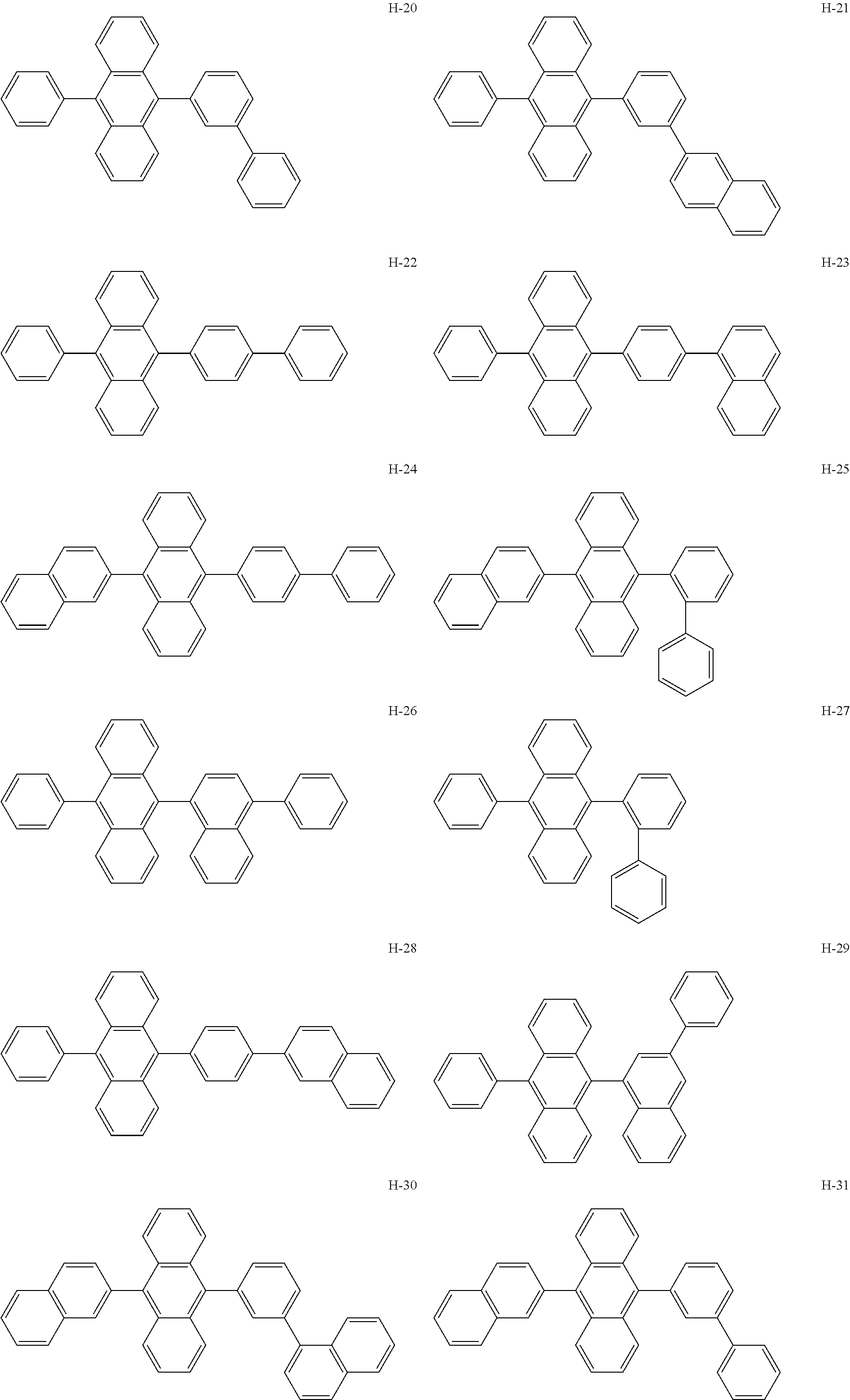

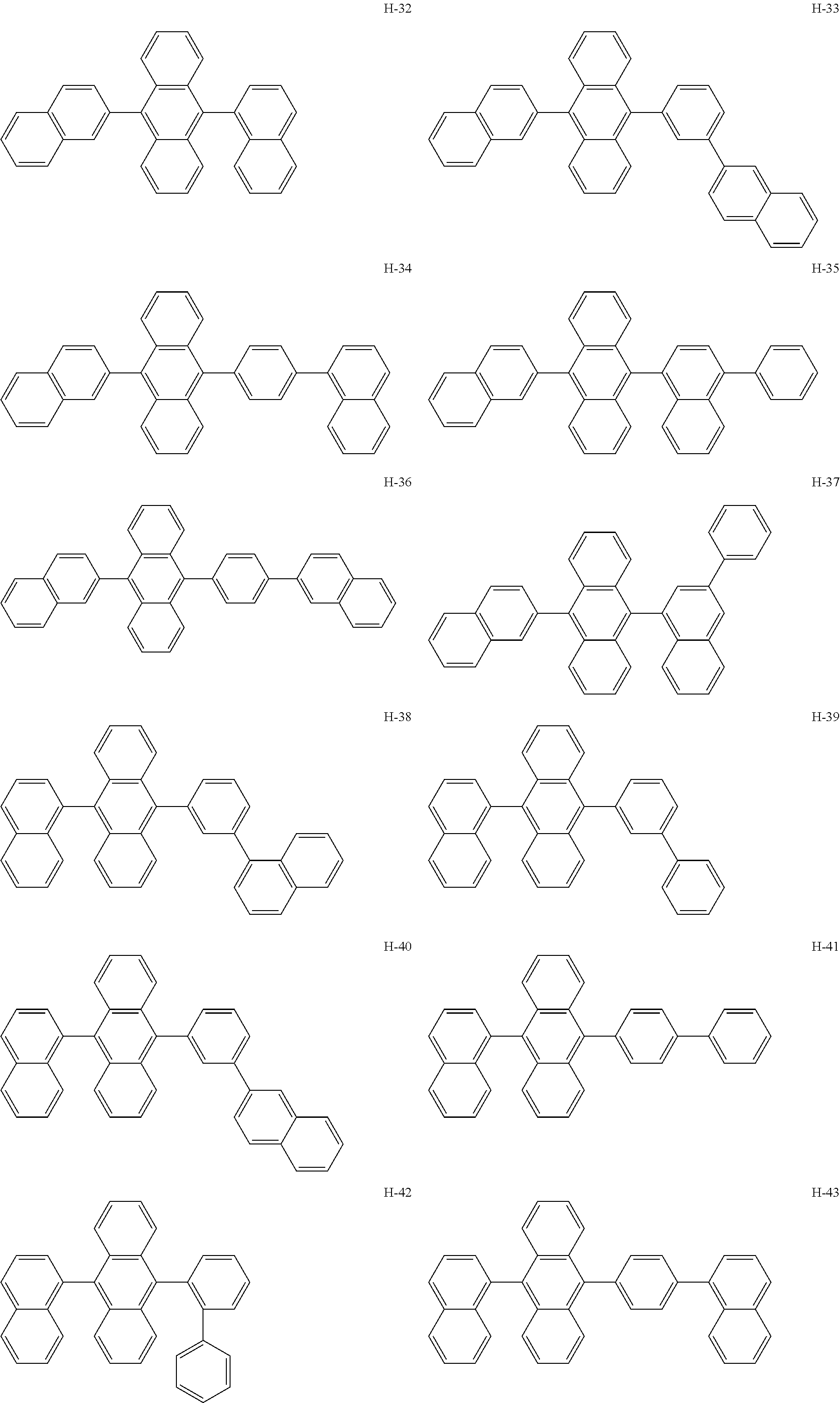

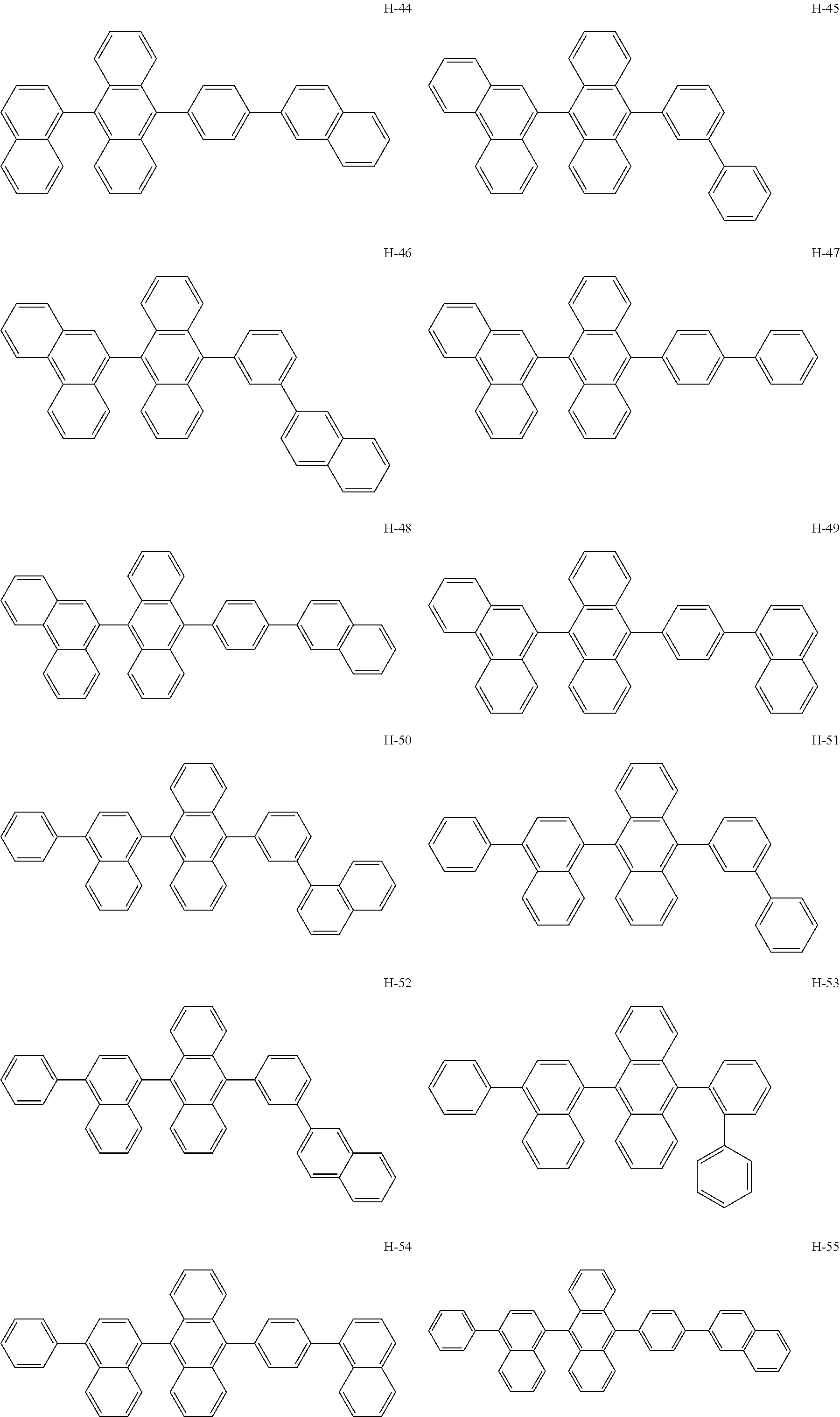

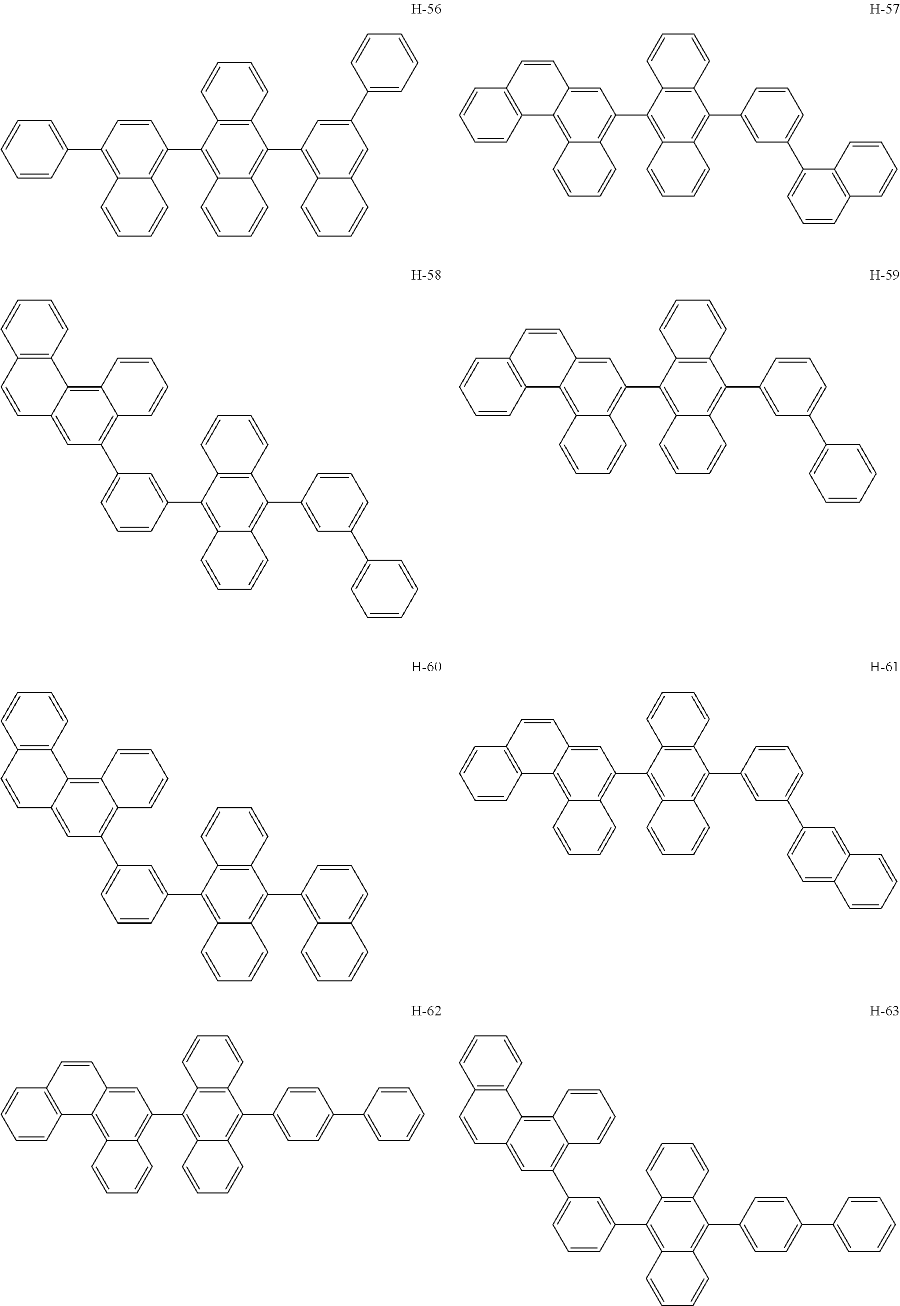

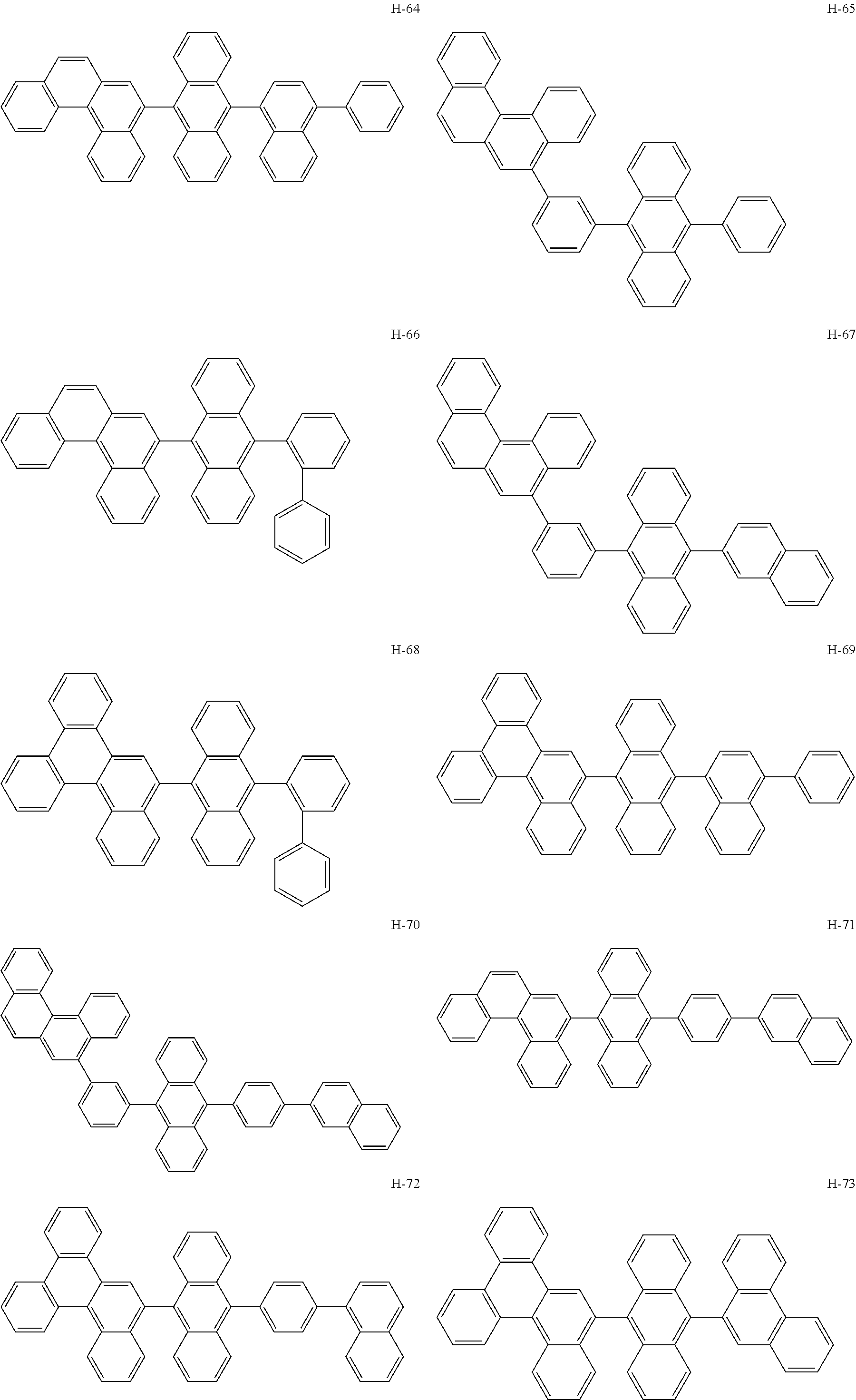

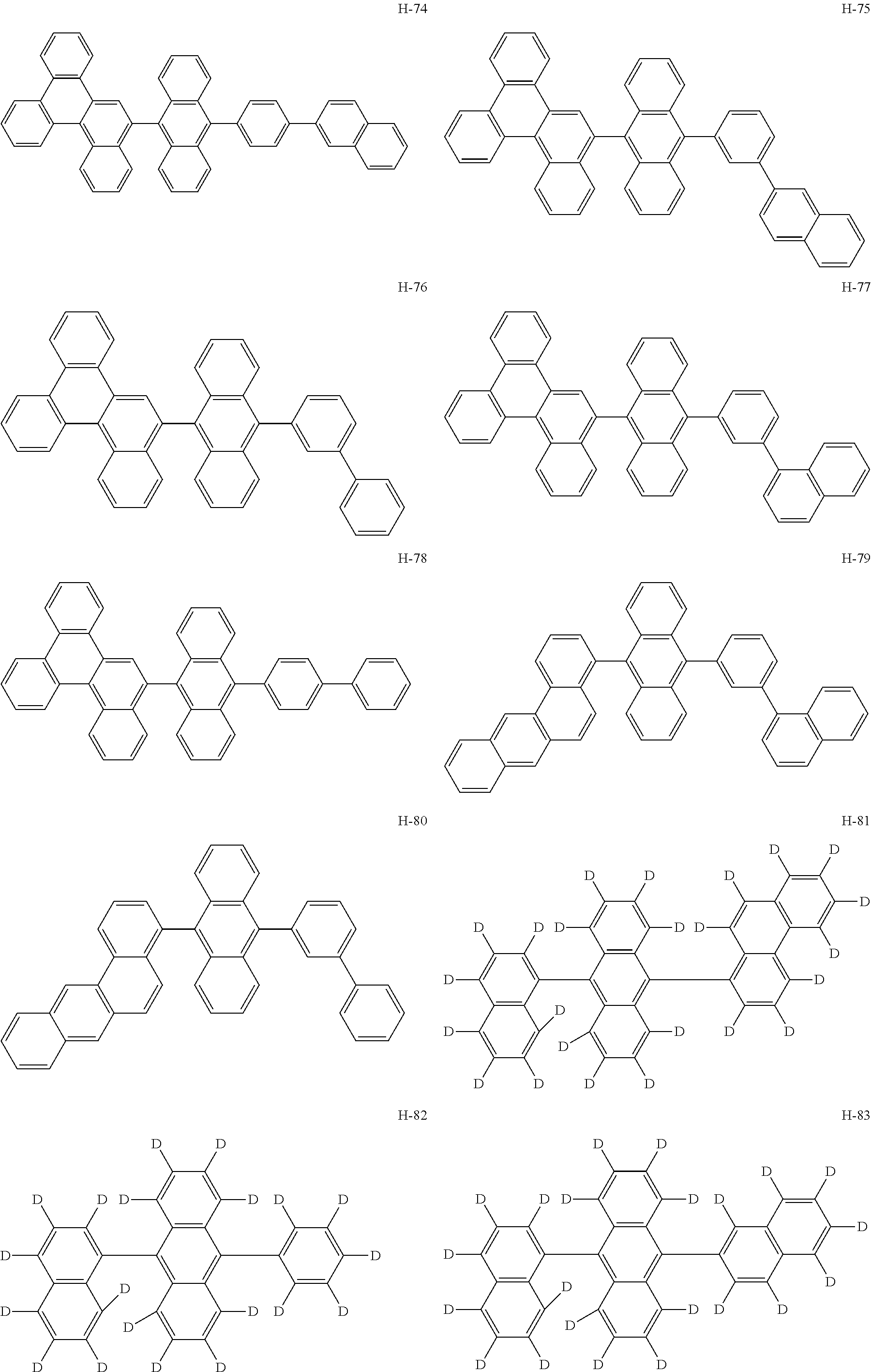

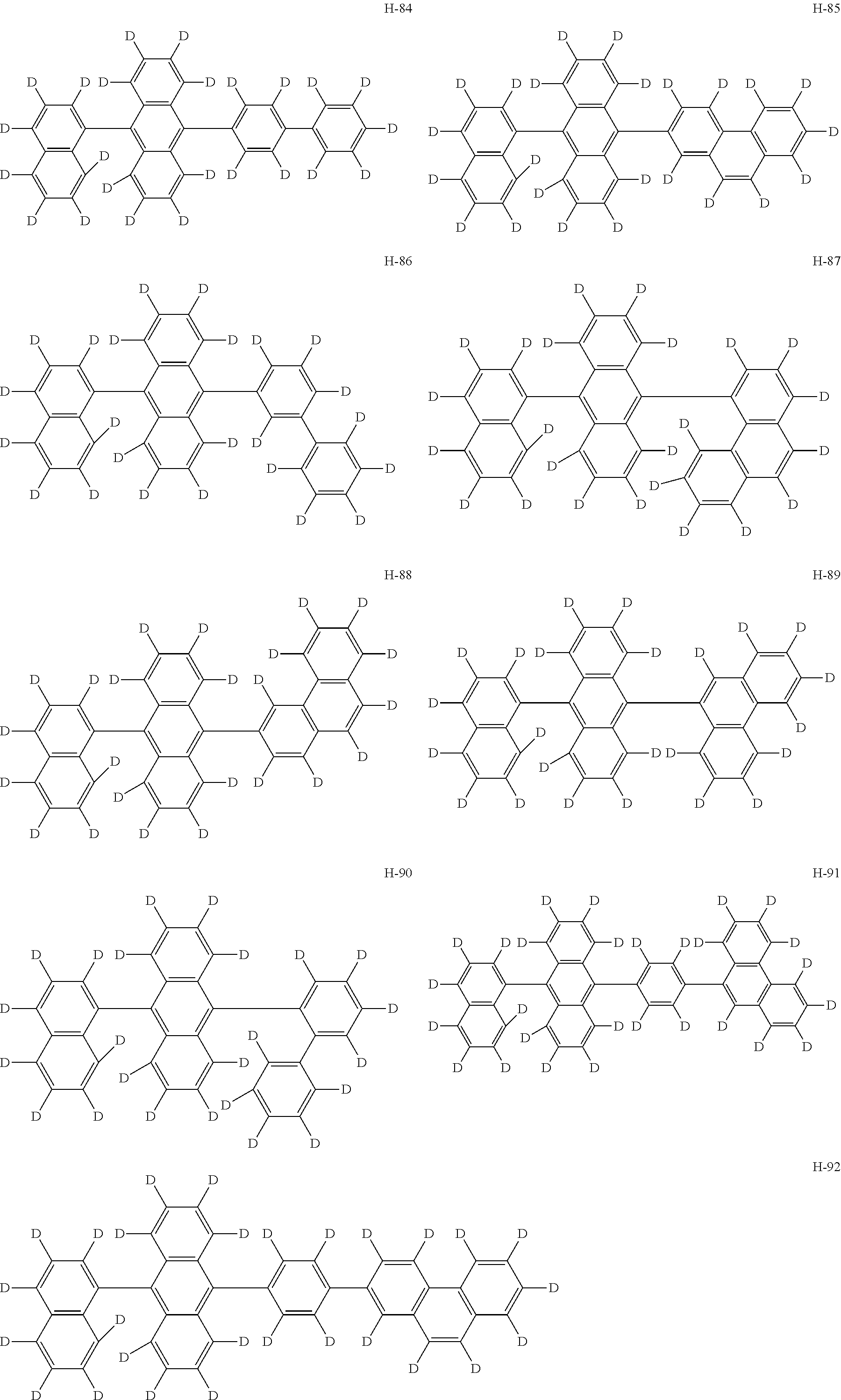

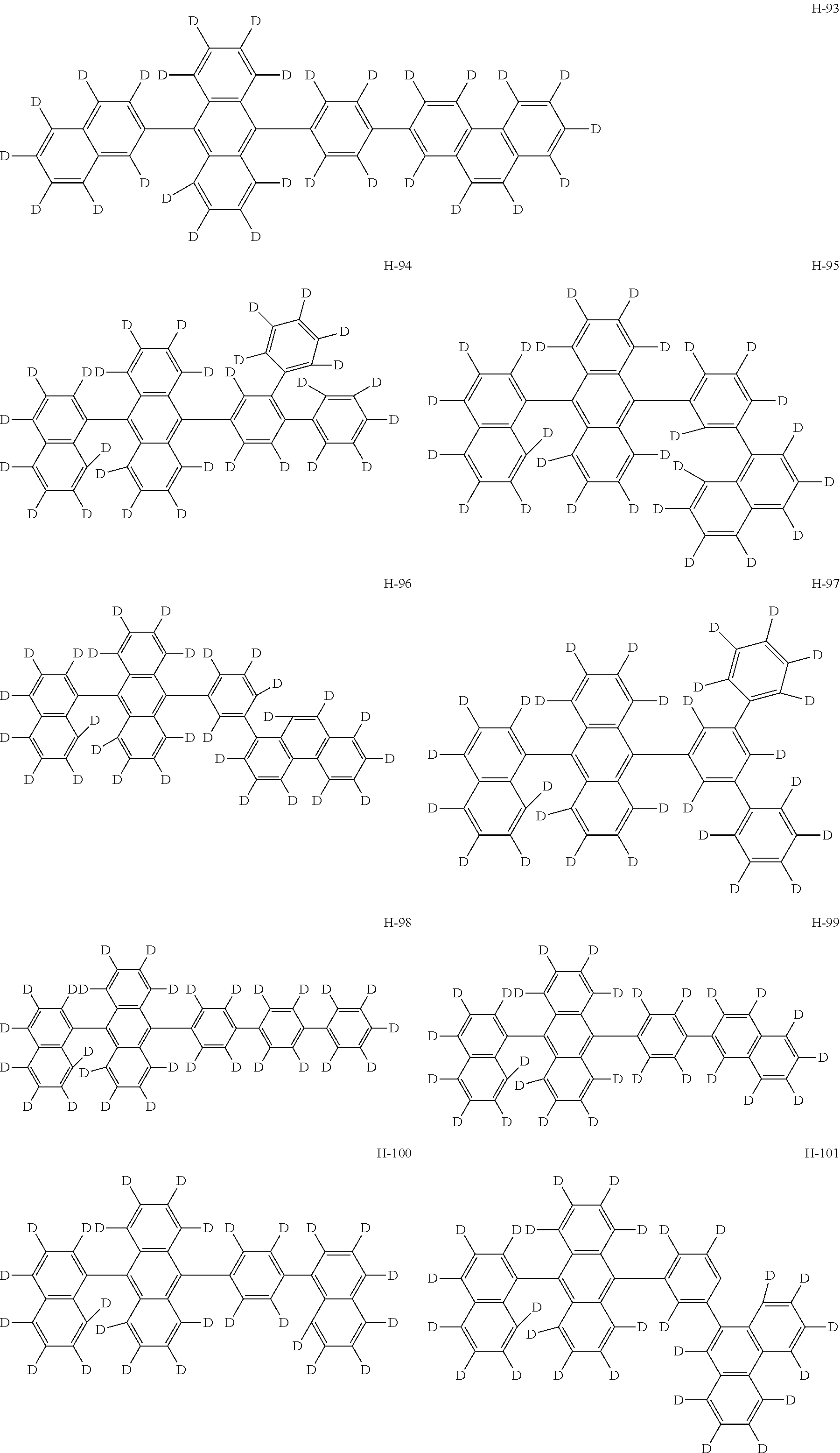

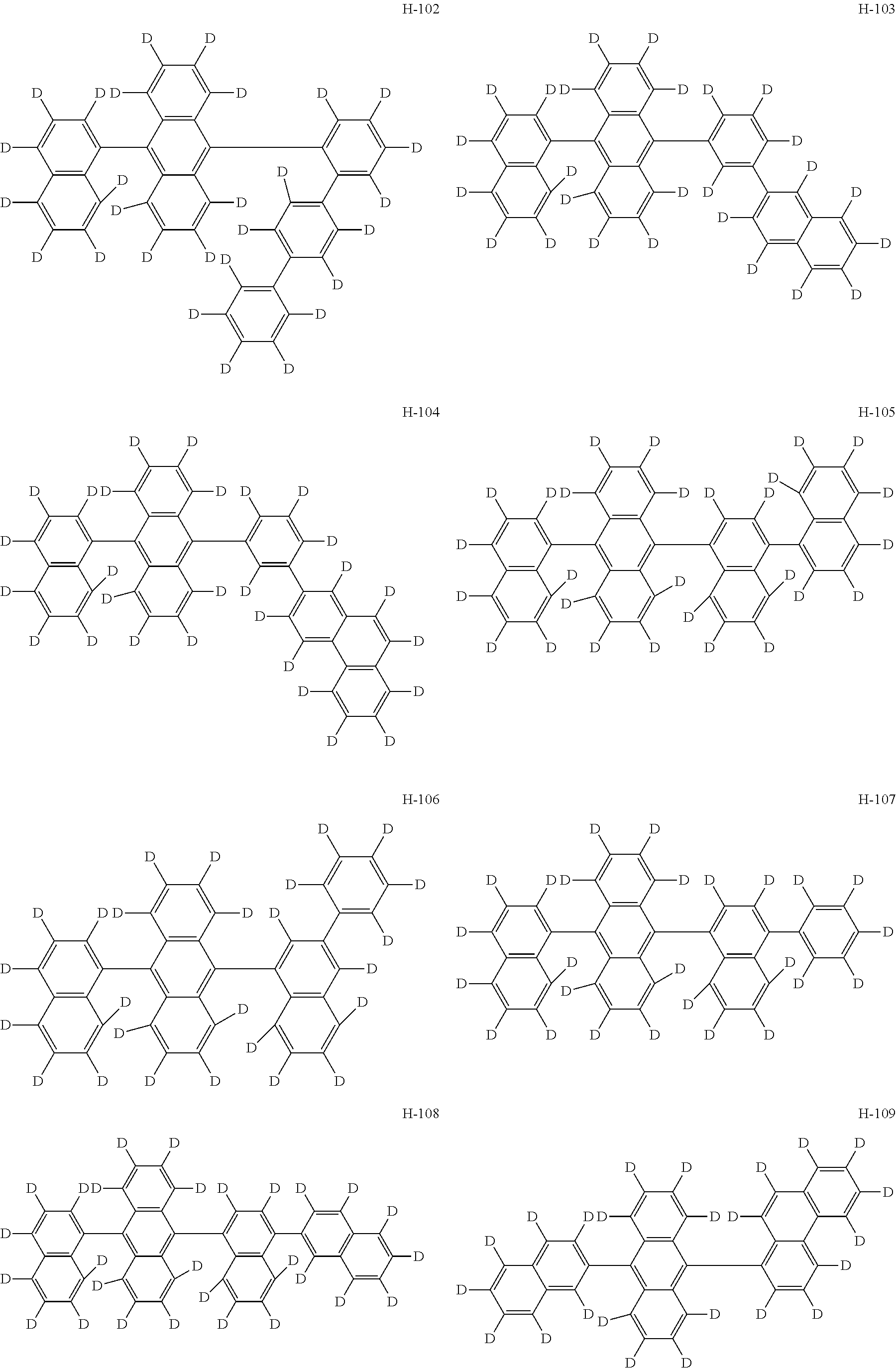

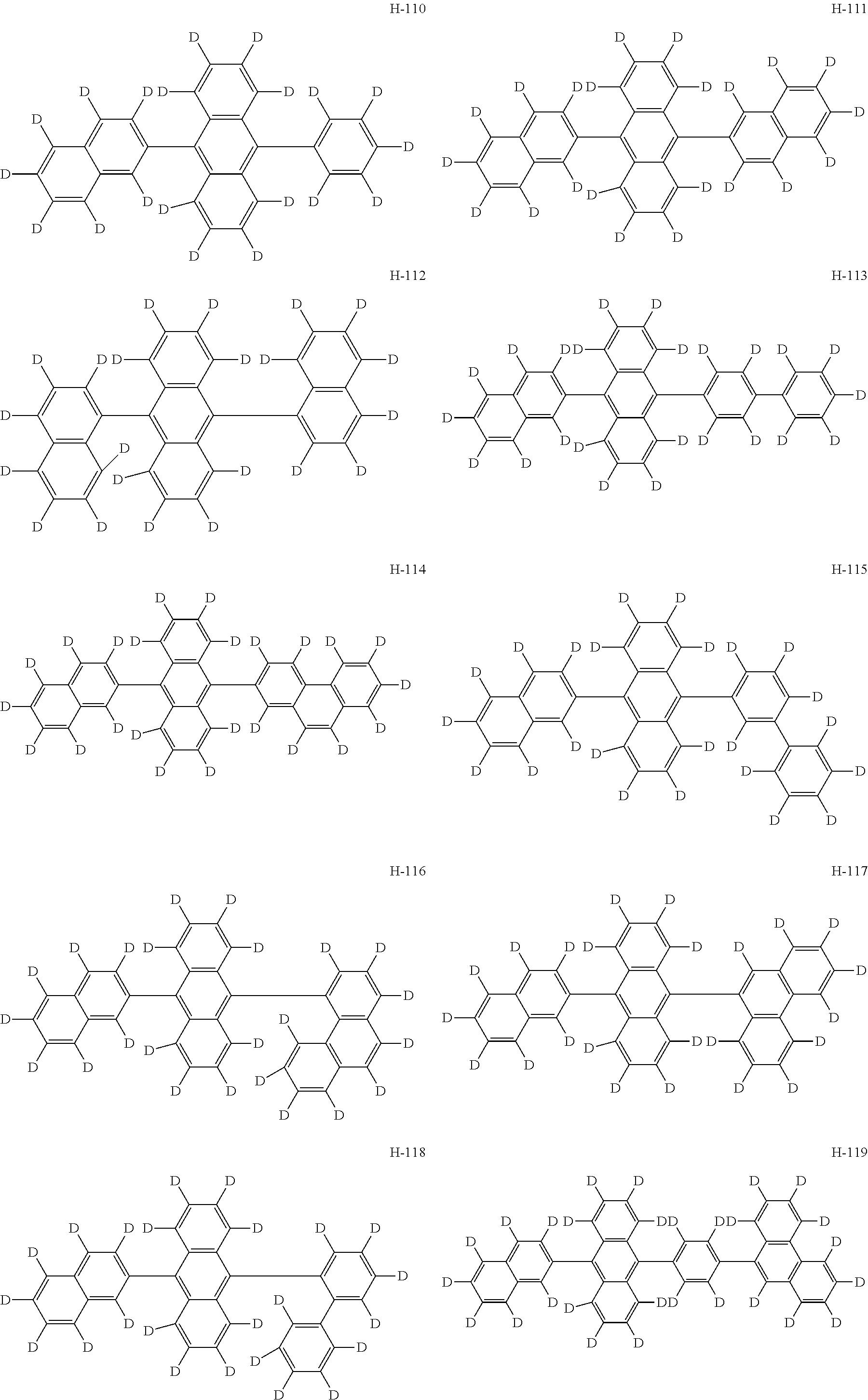

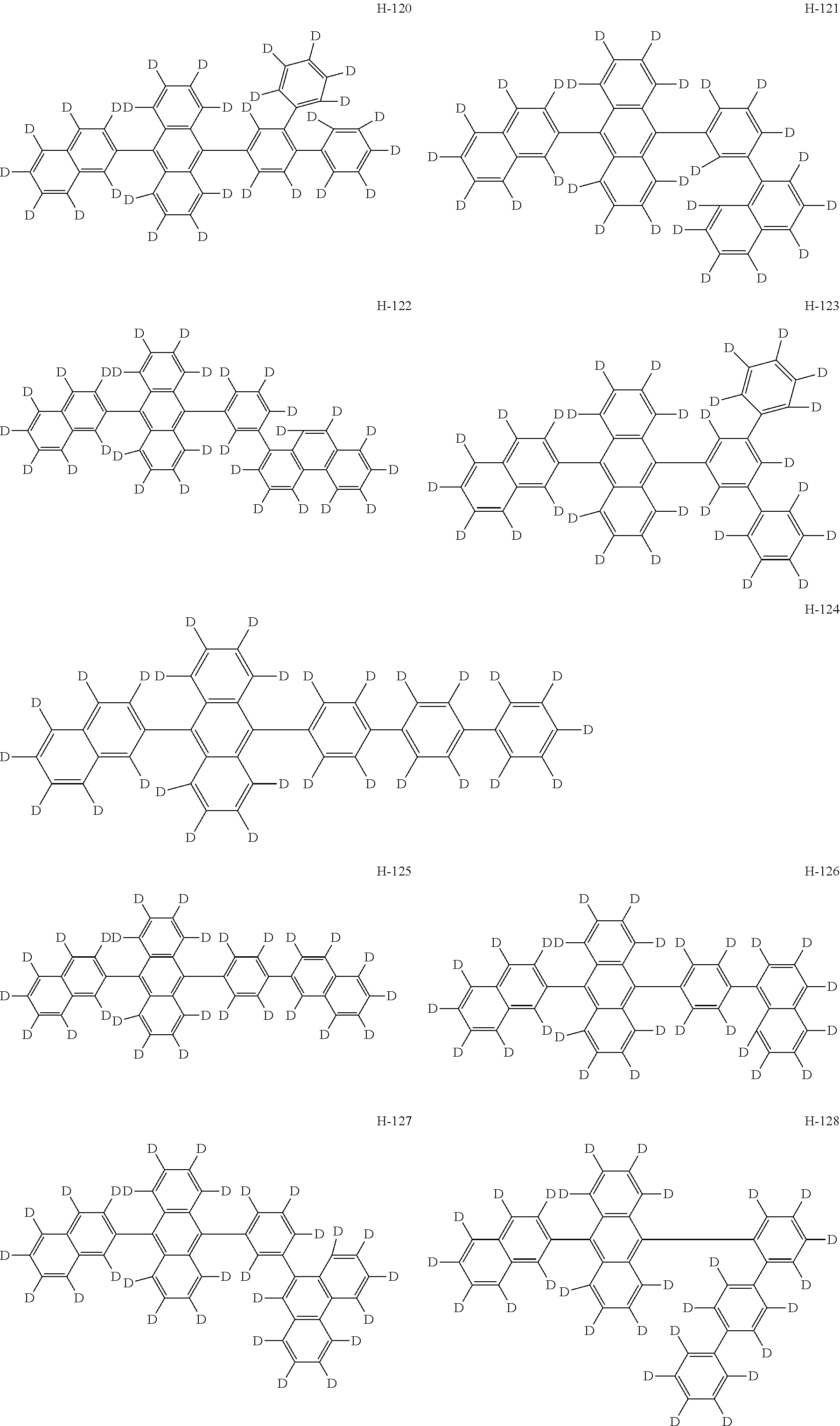

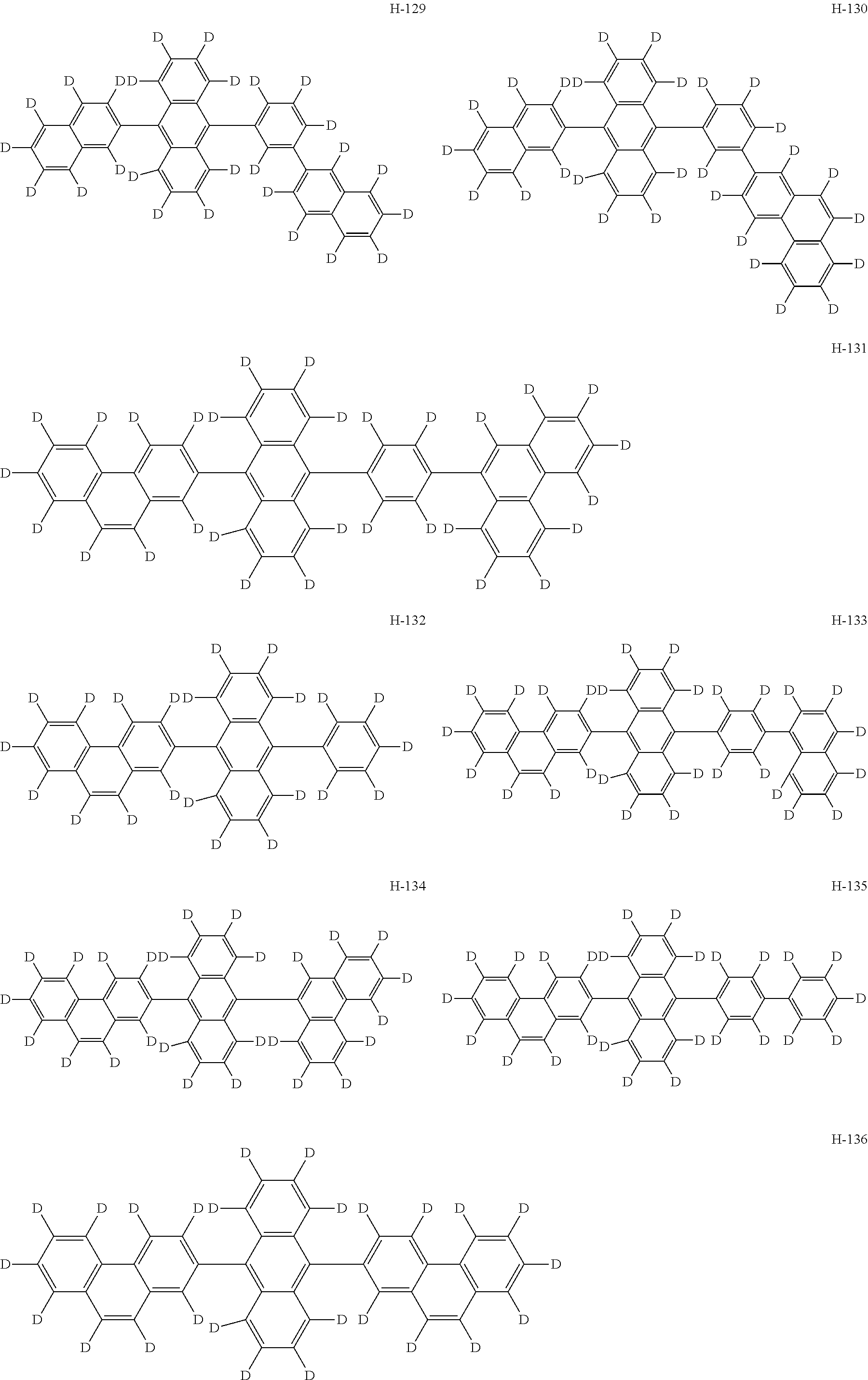

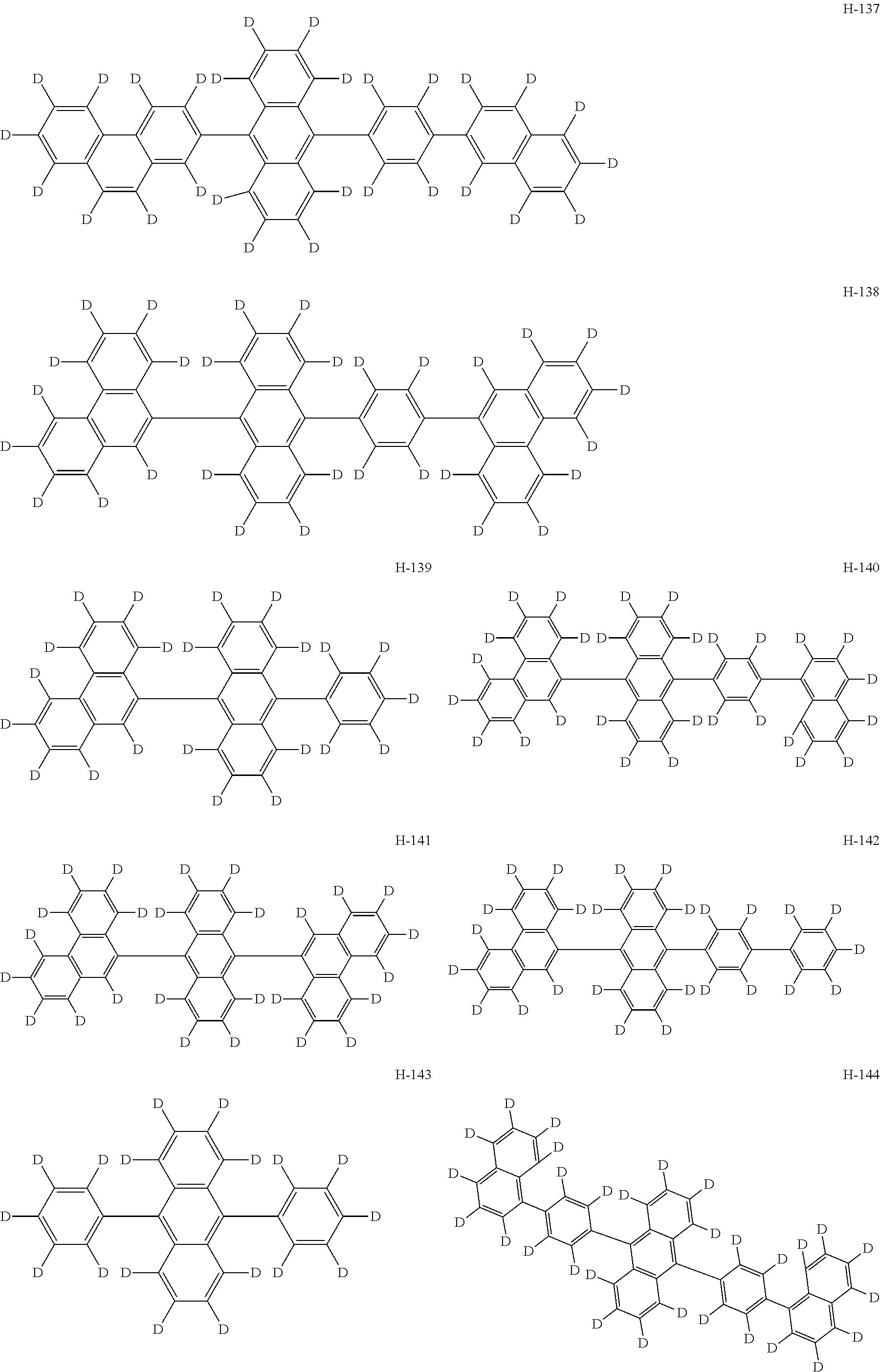

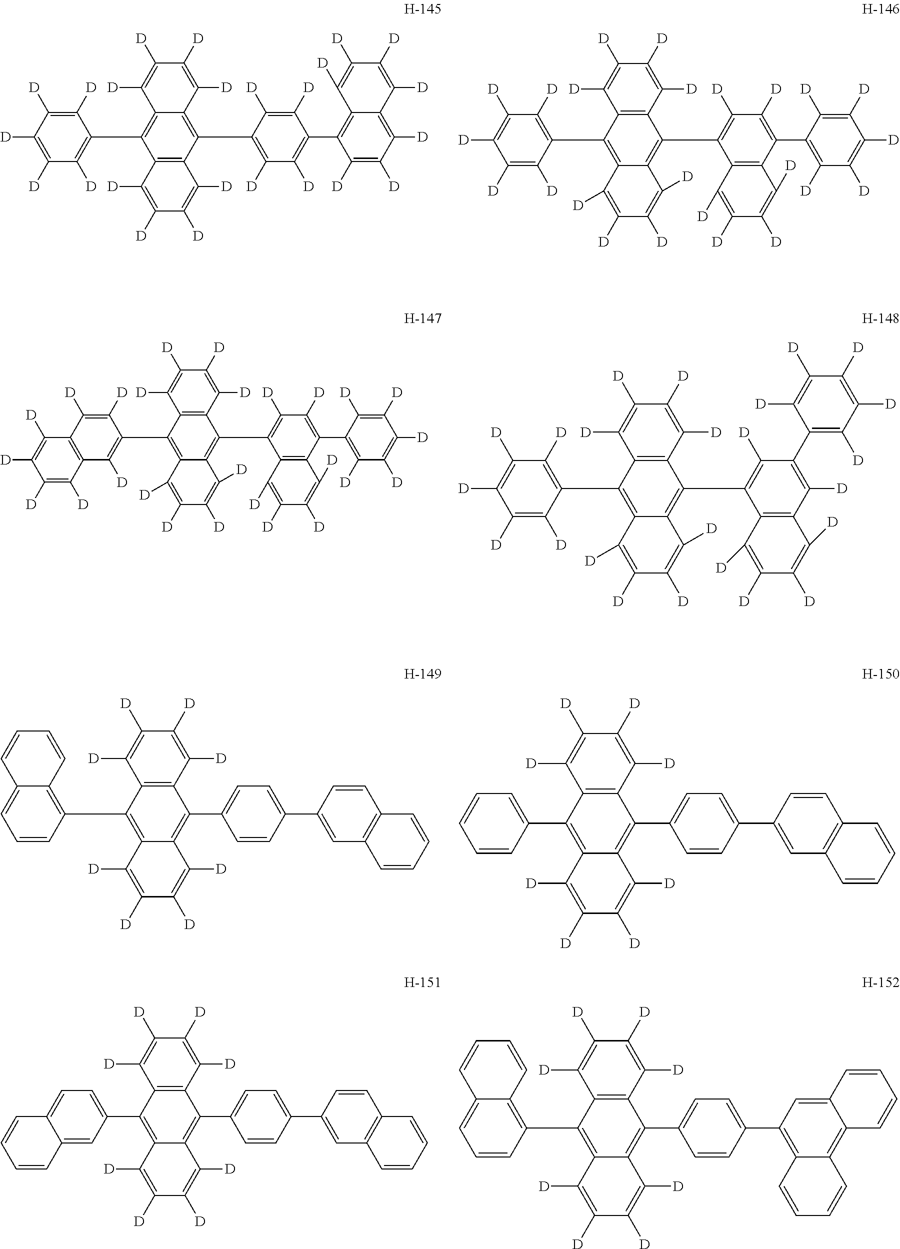

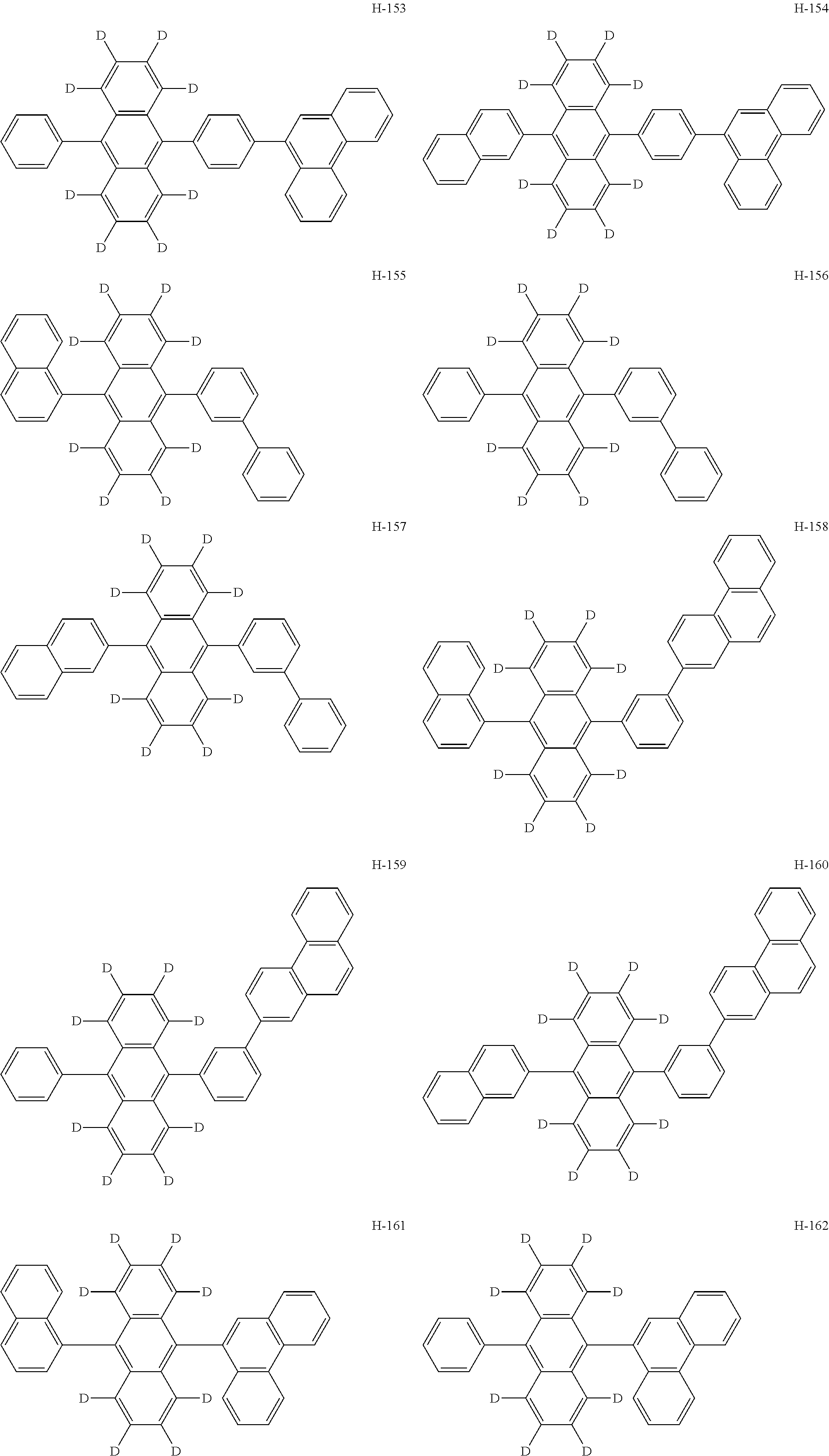

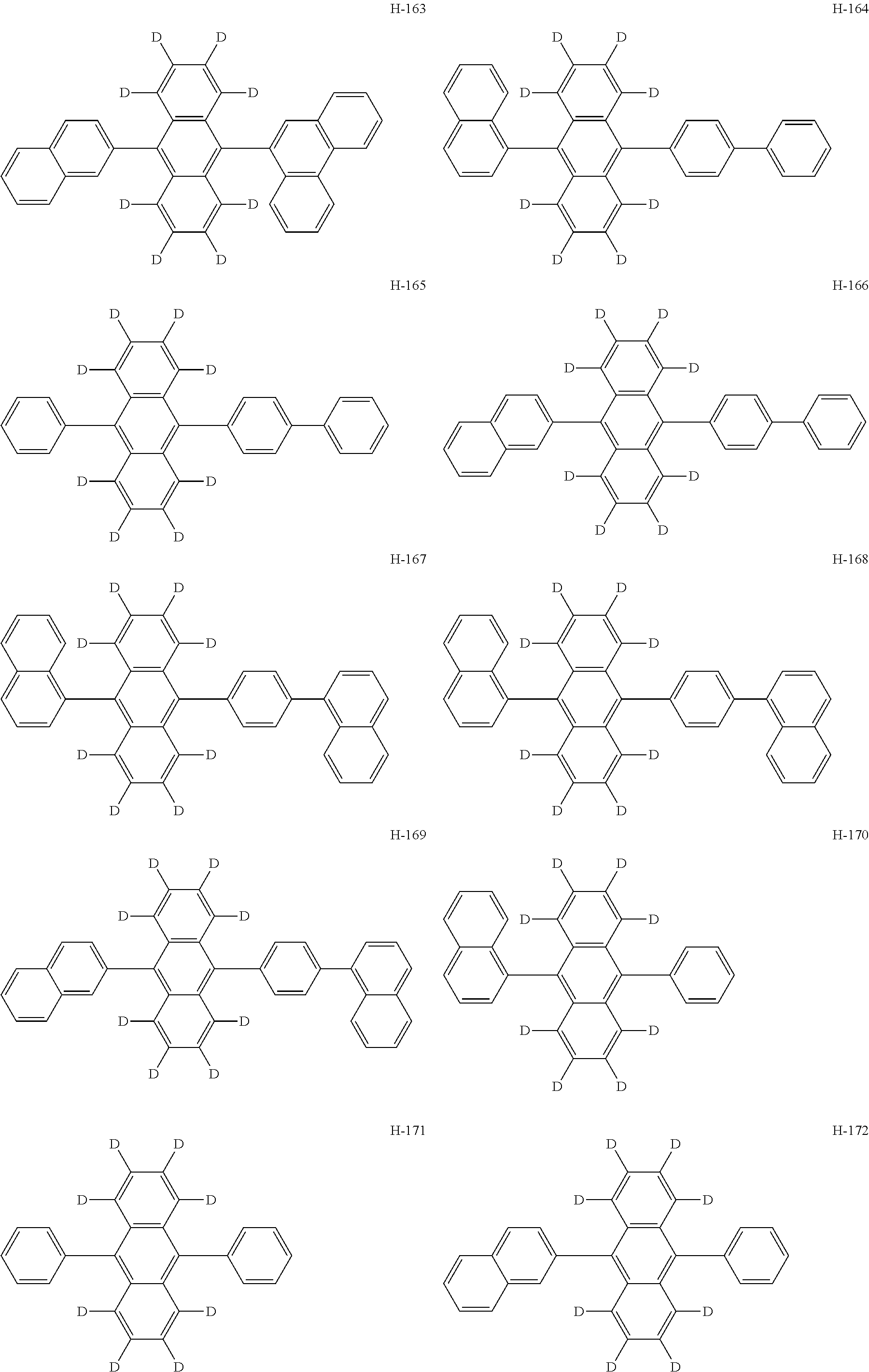

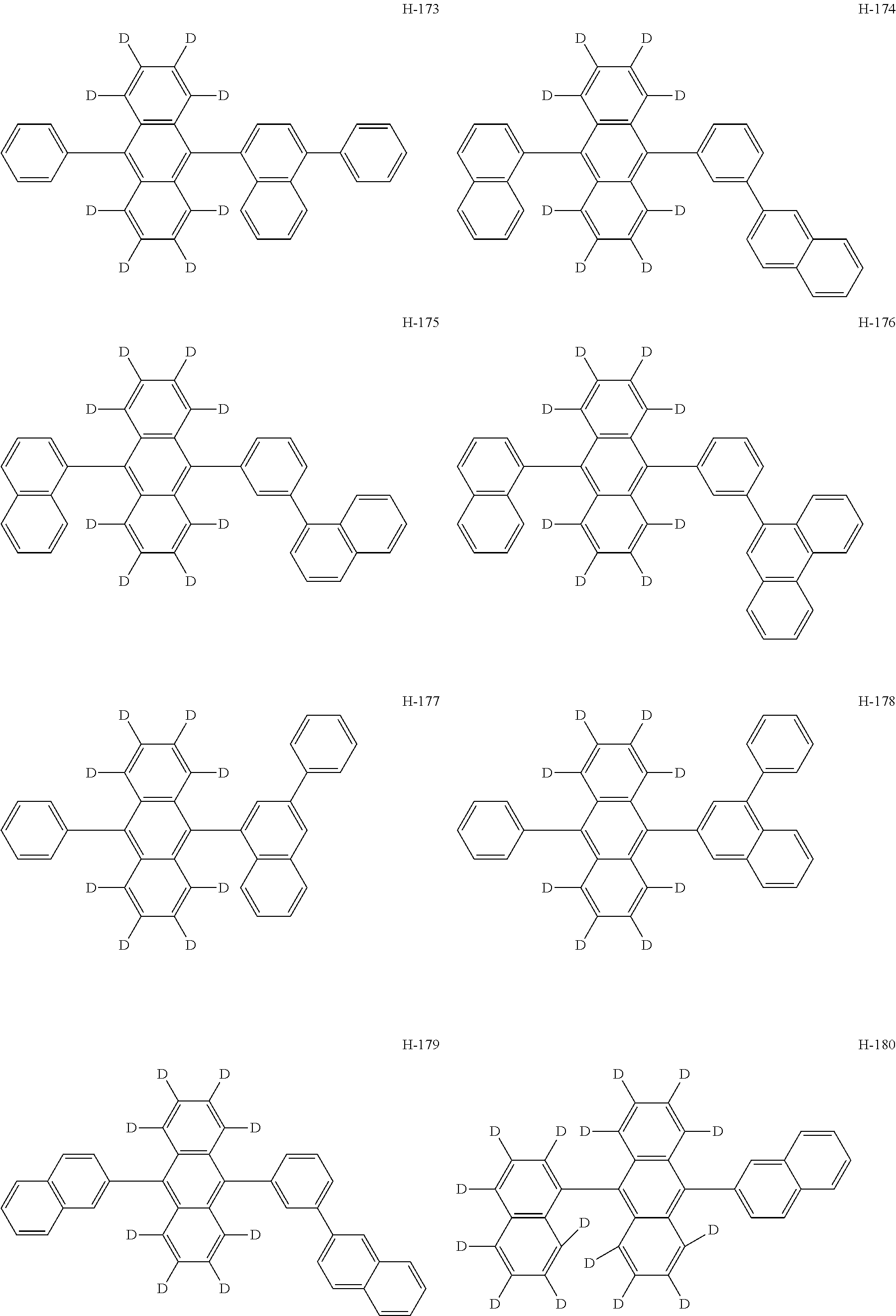

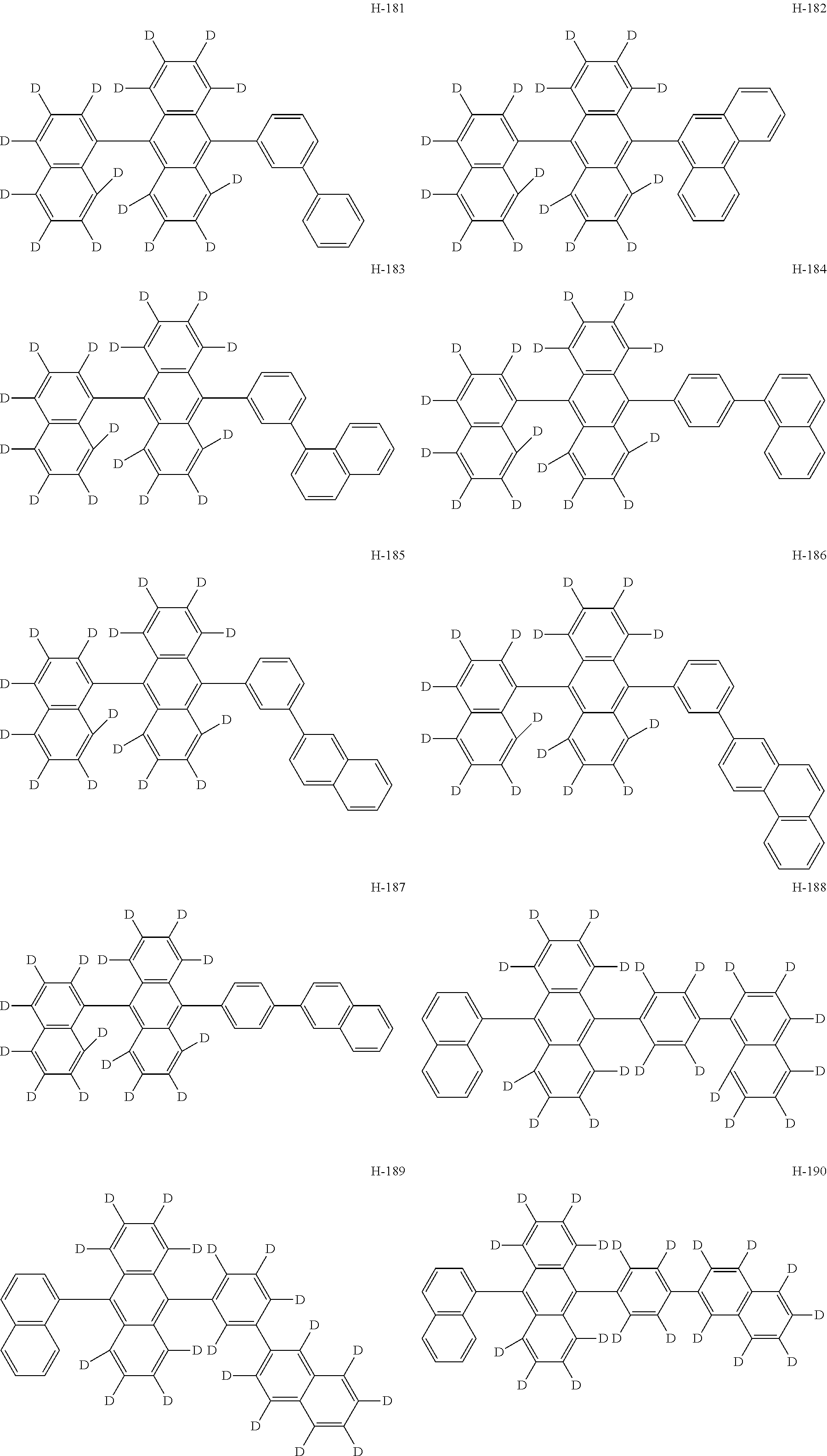

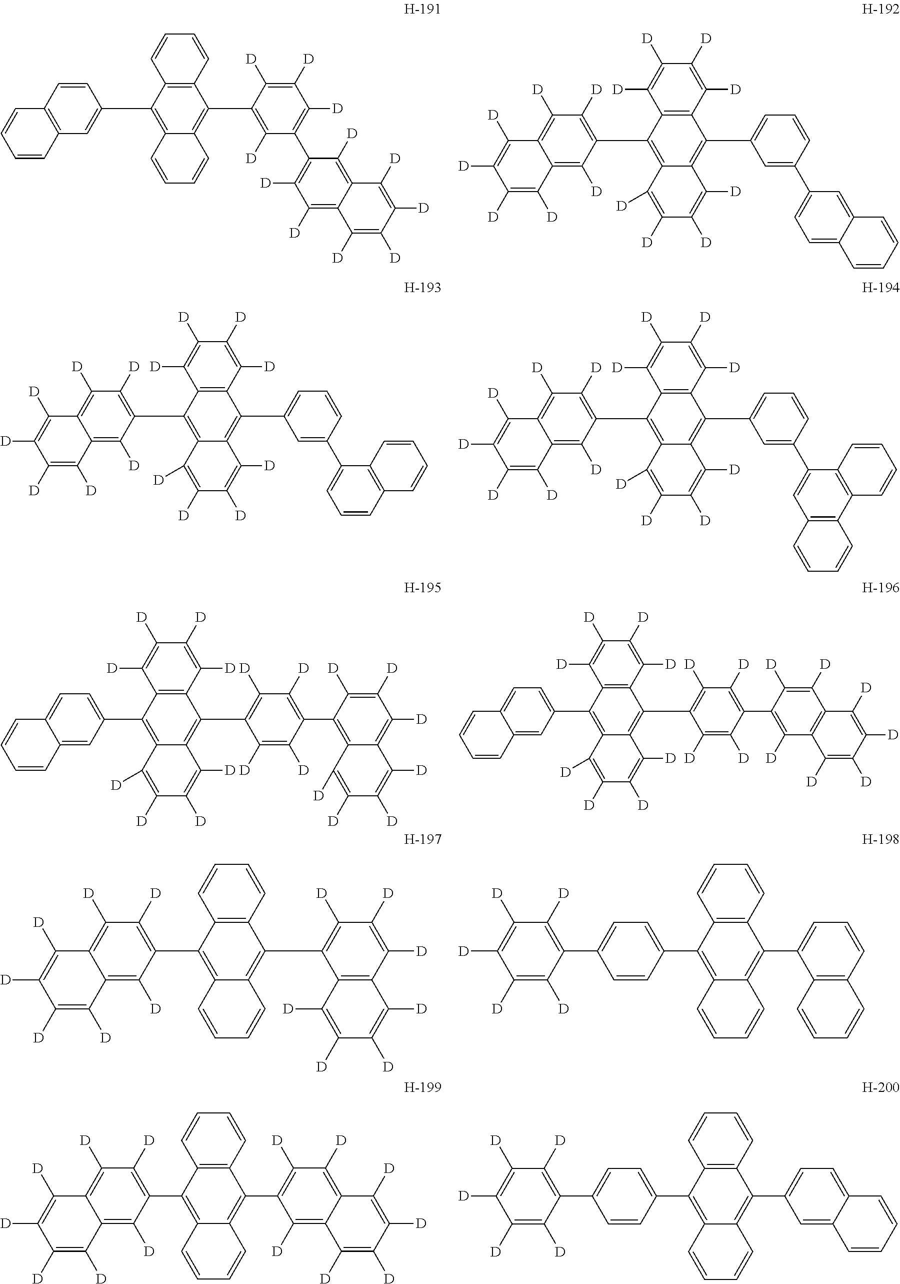

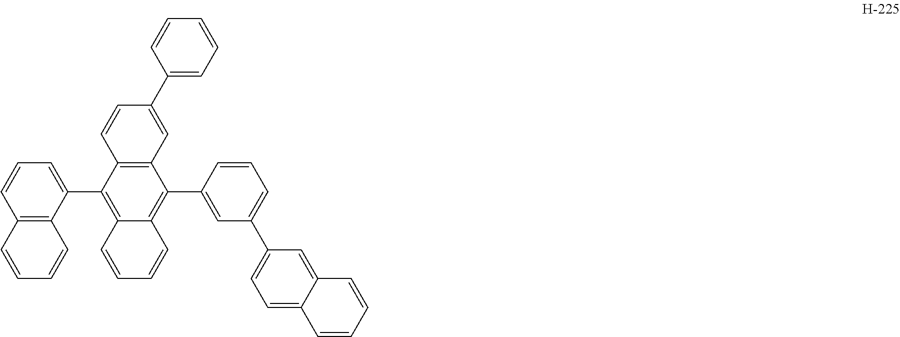 [SMILES: c1ccc(-c2ccc3c(-c4cccc5ccccc45)c4ccccc4c(-c4cccc(-c5ccc6ccccc6c5)c4)c3c2)cc1]

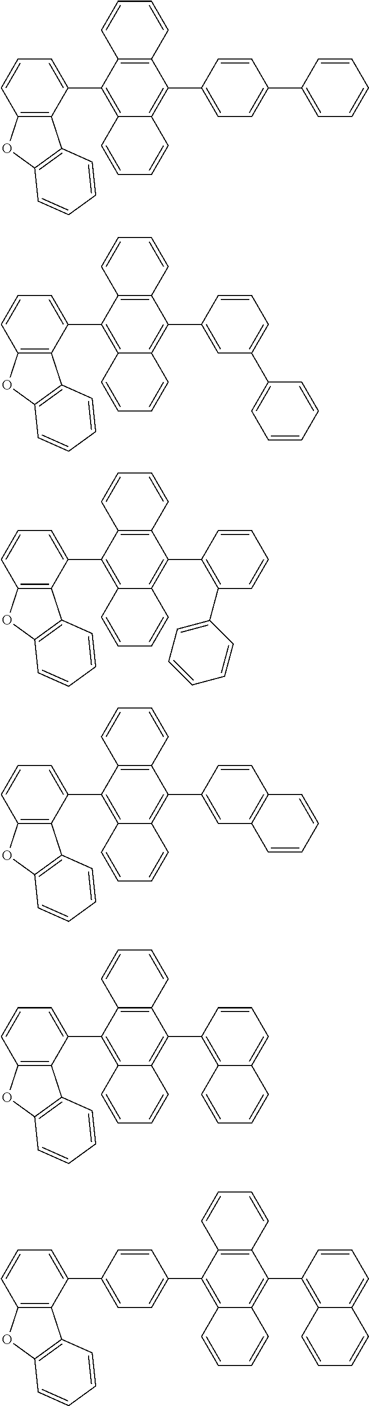 [SMILES: c1ccc(-c2ccc(-c3c4ccccc4c(-c4cccc5oc6ccccc6c45)c4ccccc34)cc2)cc1 ; c1ccc(-c2cccc(-c3c4ccccc4c(-c4cccc5oc6ccccc6c45)c4ccccc34)c2)cc1 ; c1ccc(-c2ccccc2-c2c3ccccc3c(-c3cccc4oc5ccccc5c34)c3ccccc23)cc1 ; c1ccc2cc(-c3c4ccccc4c(-c4cccc5oc6ccccc6c45)c4ccccc34)ccc2c1 ; c1ccc2c(-c3c4ccccc4c(-c4cccc5oc6ccccc6c45)c4ccccc34)cccc2c1 ; c1ccc2c(-c3c4ccccc4c(-c4ccc(-c5cccc6oc7ccccc7c56)cc4)c4ccccc34)cccc2c1]

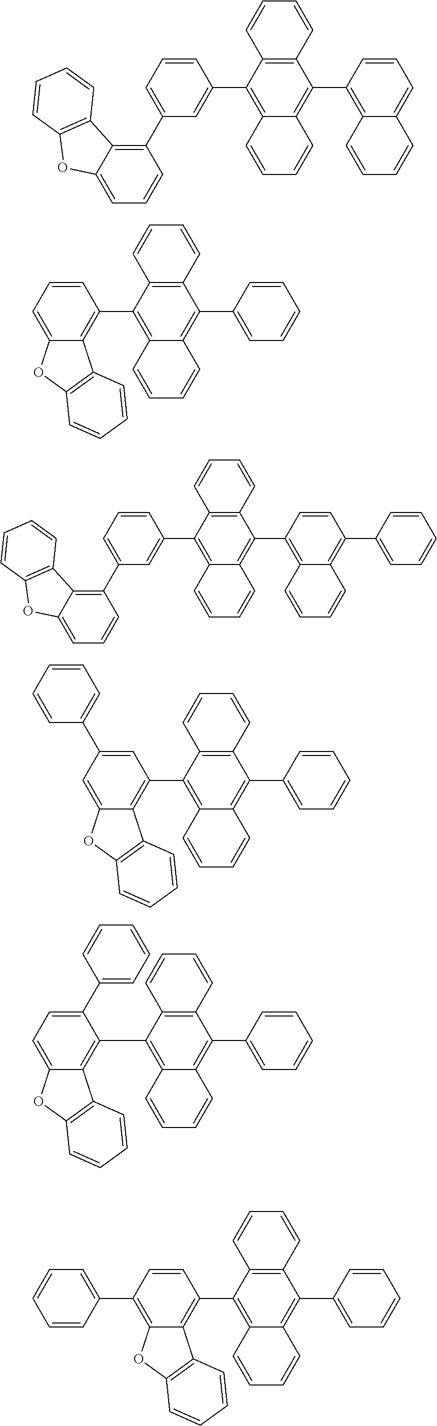

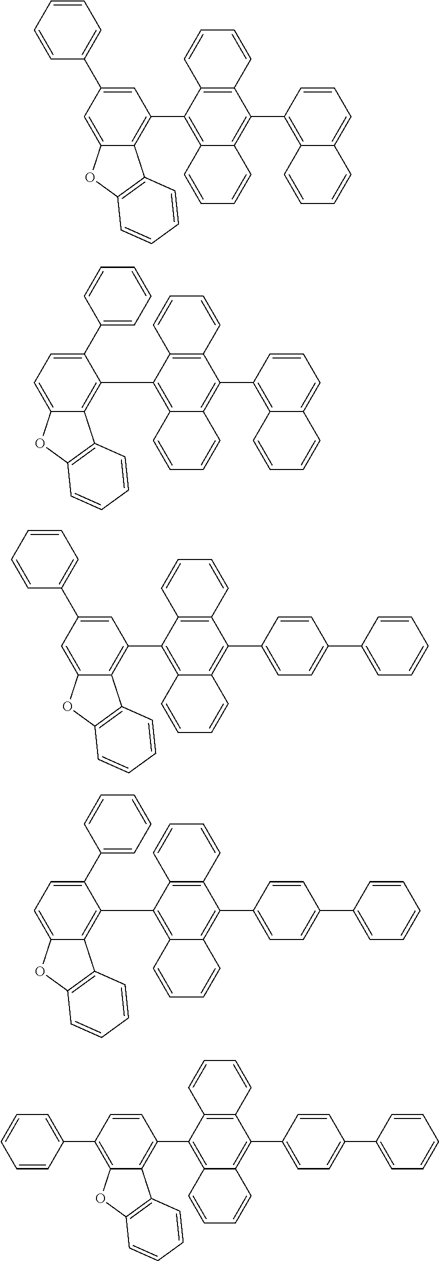

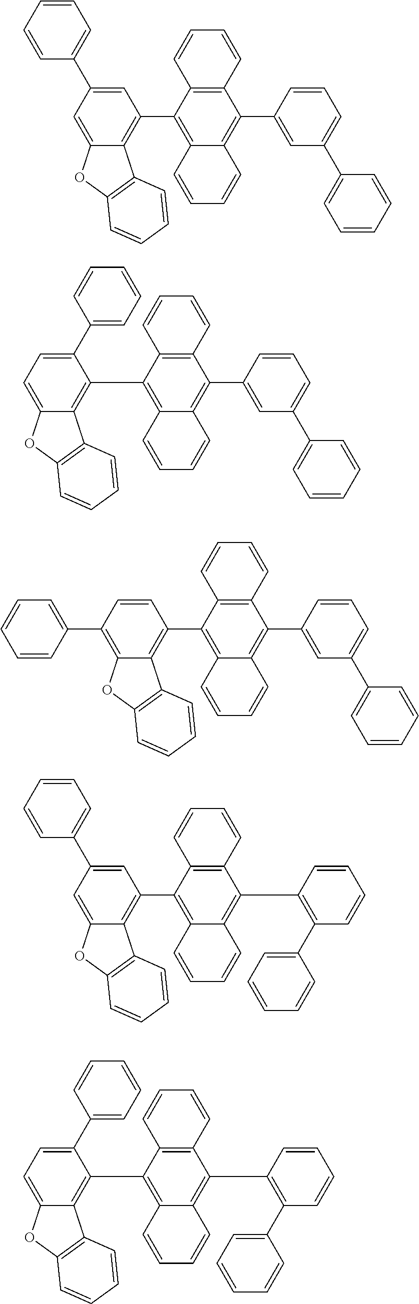

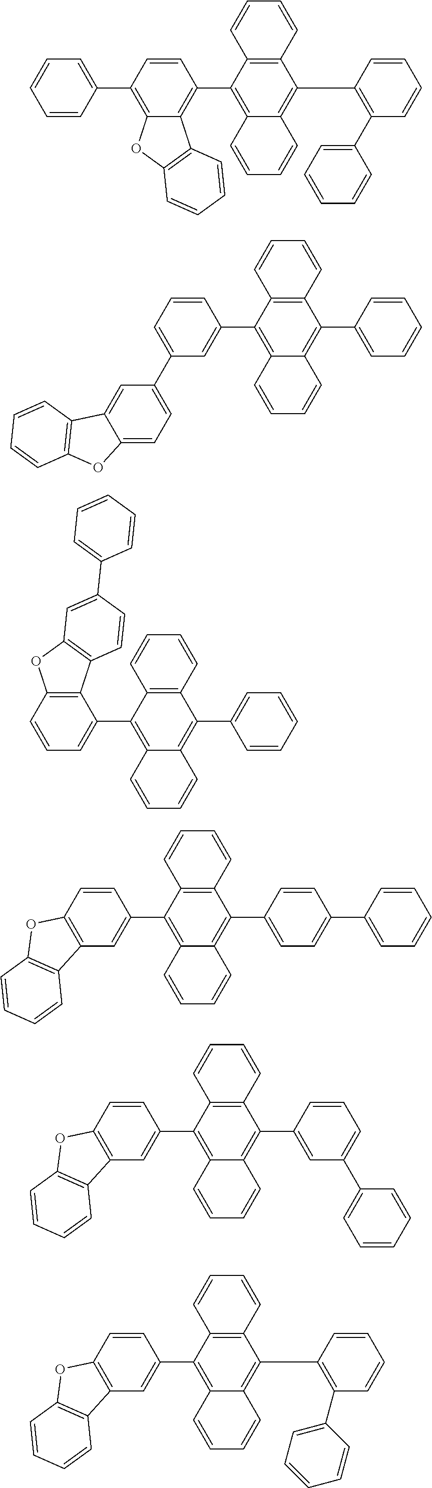

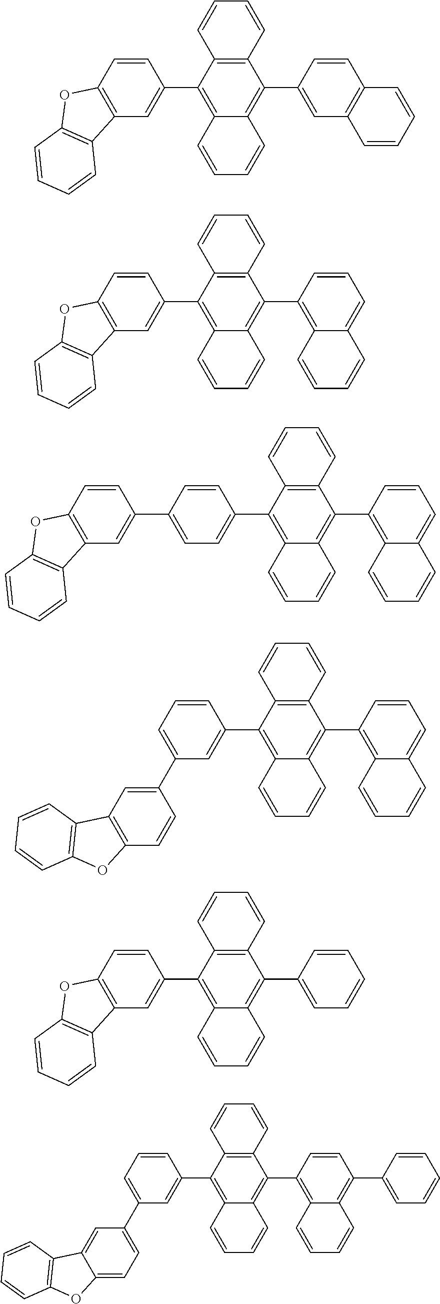

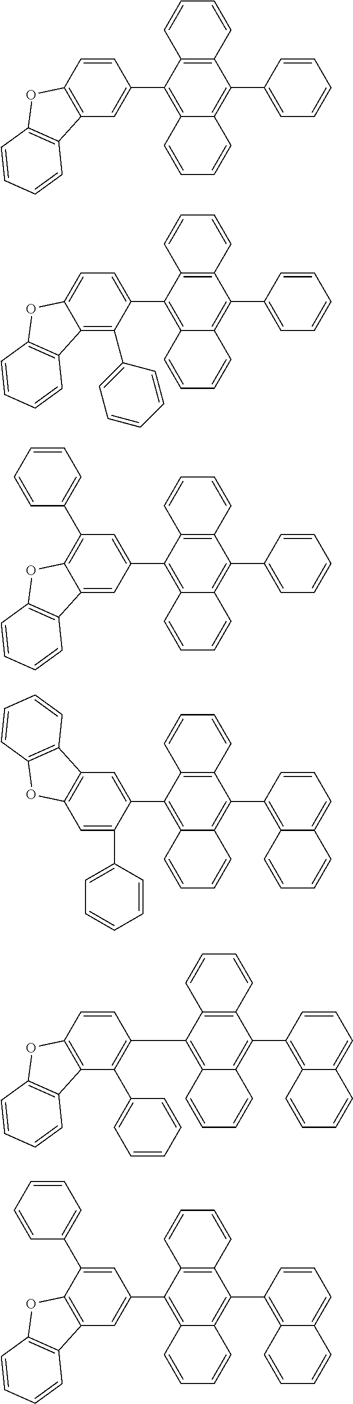

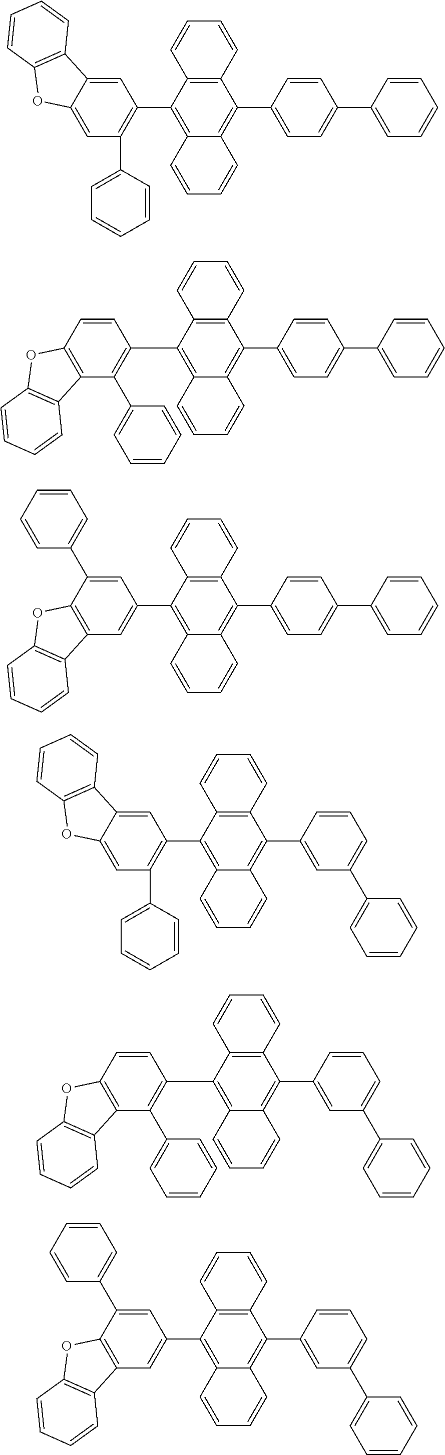

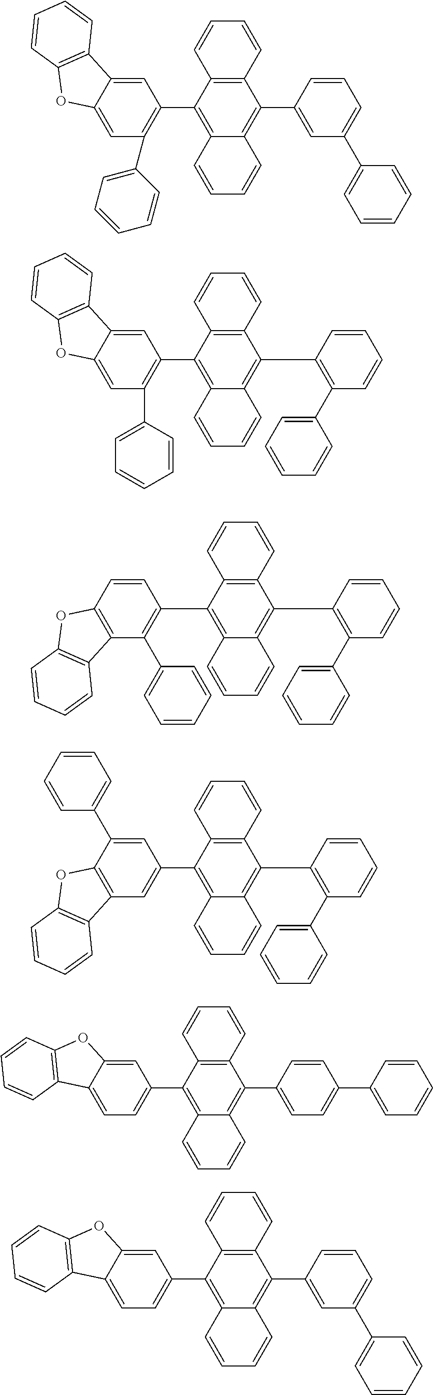

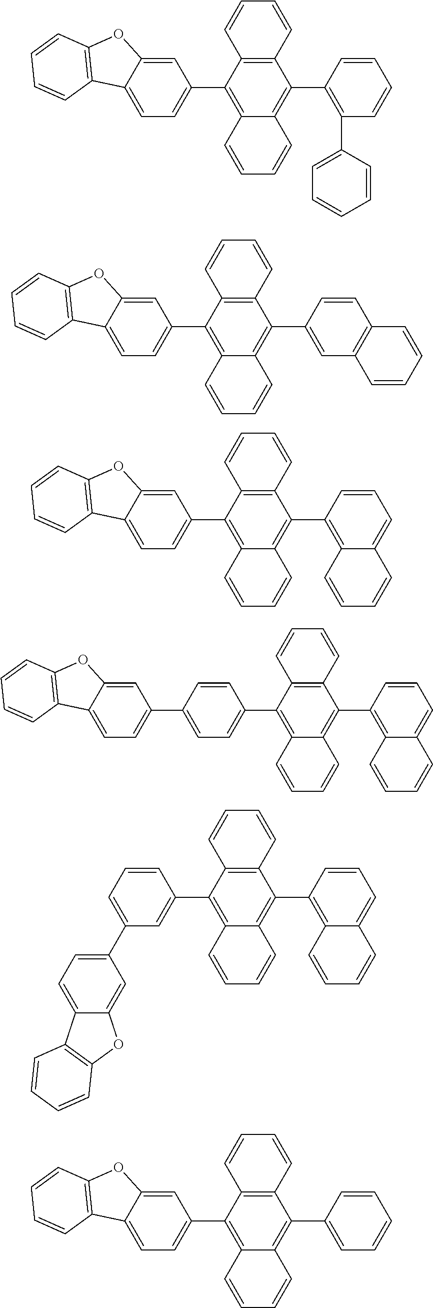

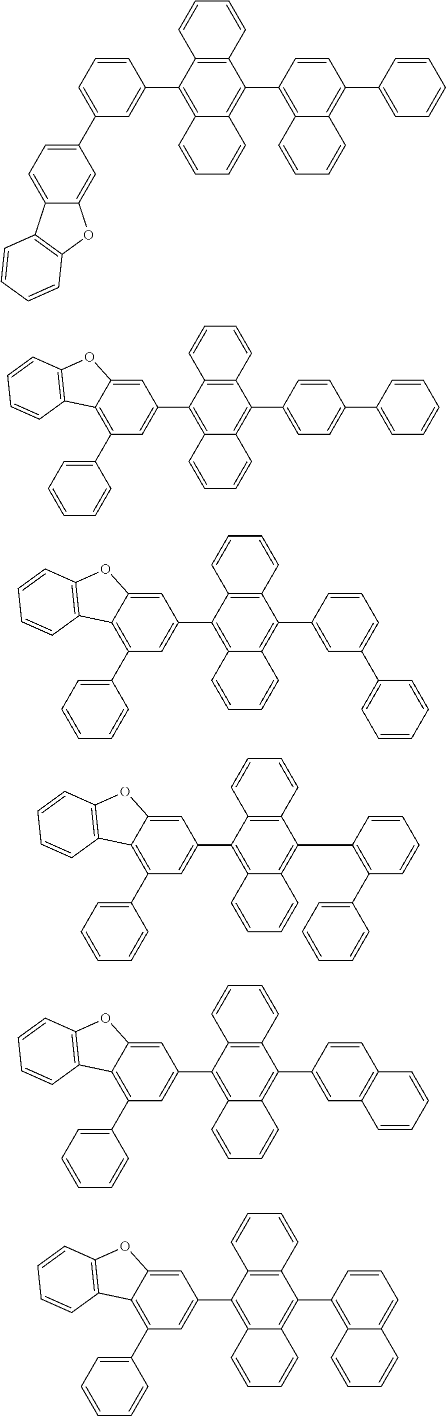 [SMILES: c1ccc(-c2ccc(-c3c4ccccc4c(-c4cccc(-c5ccc6c(c5)oc5ccccc56)c4)c4ccccc34)c3ccccc23)cc1 ; c1ccc(-c2ccc(-c3c4ccccc4c(-c4cc(-c5ccccc5)c5c(c4)oc4ccccc45)c4ccccc34)cc2)cc1 ; c1ccc(-c2cccc(-c3c4ccccc4c(-c4cc(-c5ccccc5)c5c(c4)oc4ccccc45)c4ccccc34)c2)cc1 ; c1ccc(-c2ccccc2-c2c3ccccc3c(-c3cc(-c4ccccc4)c4c(c3)oc3ccccc34)c3ccccc23)cc1 ; c1ccc(-c2cc(-c3c4ccccc4c(-c4ccc5ccccc5c4)c4ccccc34)cc3oc4ccccc4c23)cc1 ; c1ccc(-c2cc(-c3c4ccccc4c(-c4cccc5ccccc45)c4ccccc34)cc3oc4ccccc4c23)cc1]

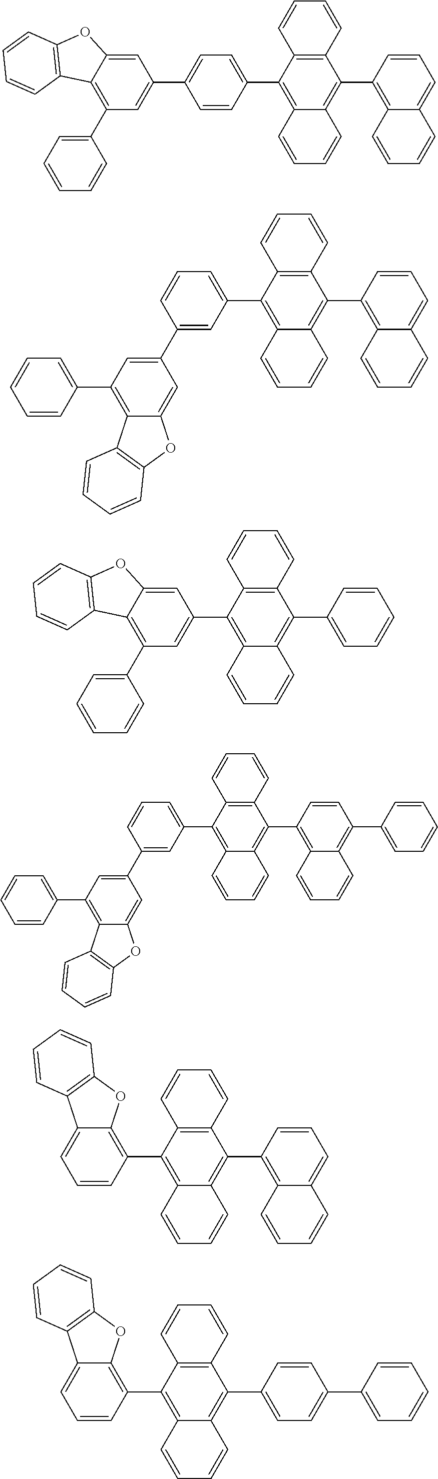

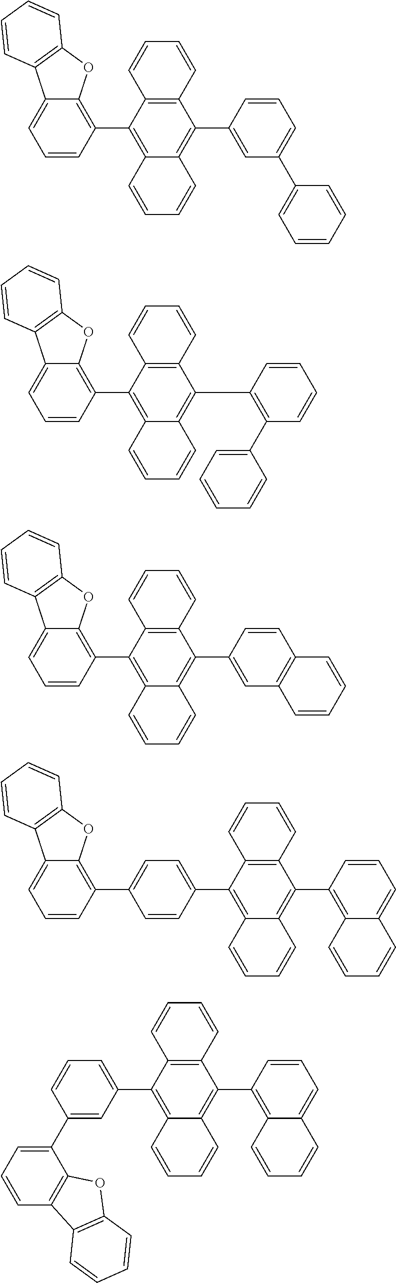 [SMILES: c1ccc(-c2cccc(-c3c4ccccc4c(-c4cccc5c4oc4ccccc45)c4ccccc34)c2)cc1 ; c1ccc(-c2ccccc2-c2c3ccccc3c(-c3cccc4c3oc3ccccc34)c3ccccc23)cc1 ; c1ccc2cc(-c3c4ccccc4c(-c4cccc5c4oc4ccccc45)c4ccccc34)ccc2c1 ; c1ccc2c(-c3c4ccccc4c(-c4ccc(-c5cccc6c5oc5ccccc56)cc4)c4ccccc34)cccc2c1 ; c1cc(-c2c3ccccc3c(-c3cccc4ccccc34)c3ccccc23)cc(-c2cccc3c2oc2ccccc23)c1]

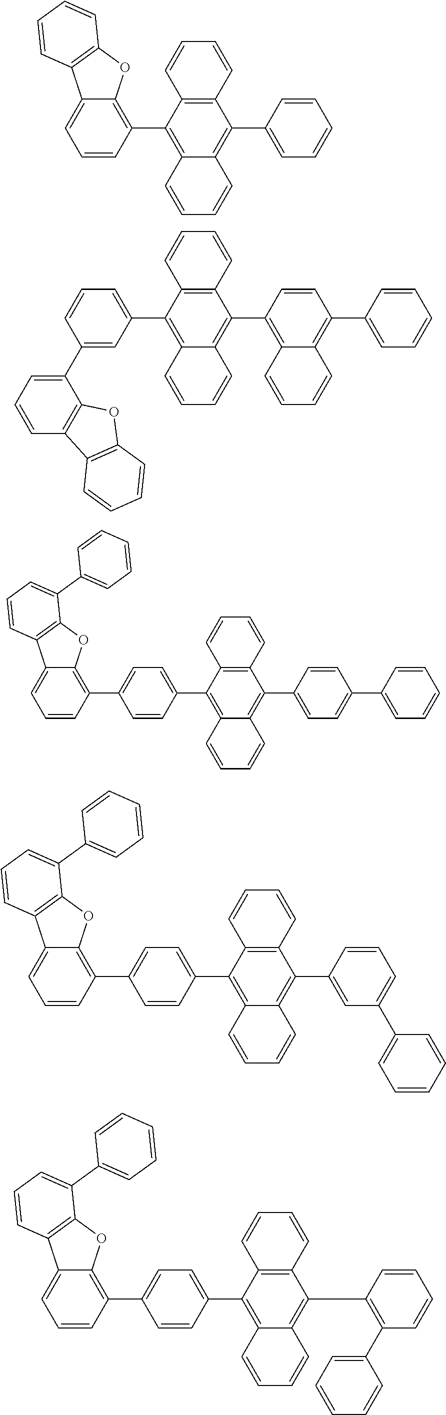

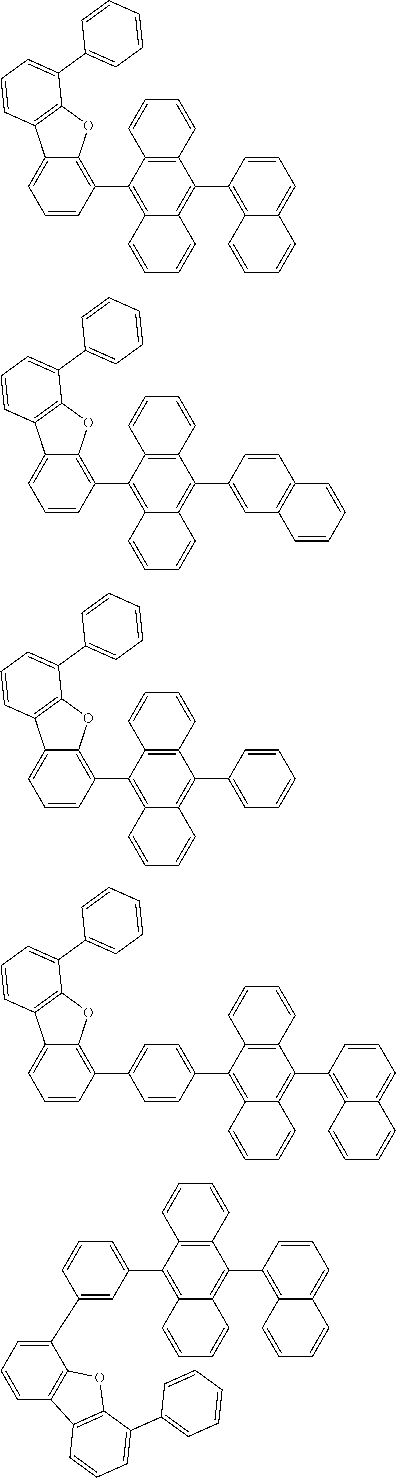

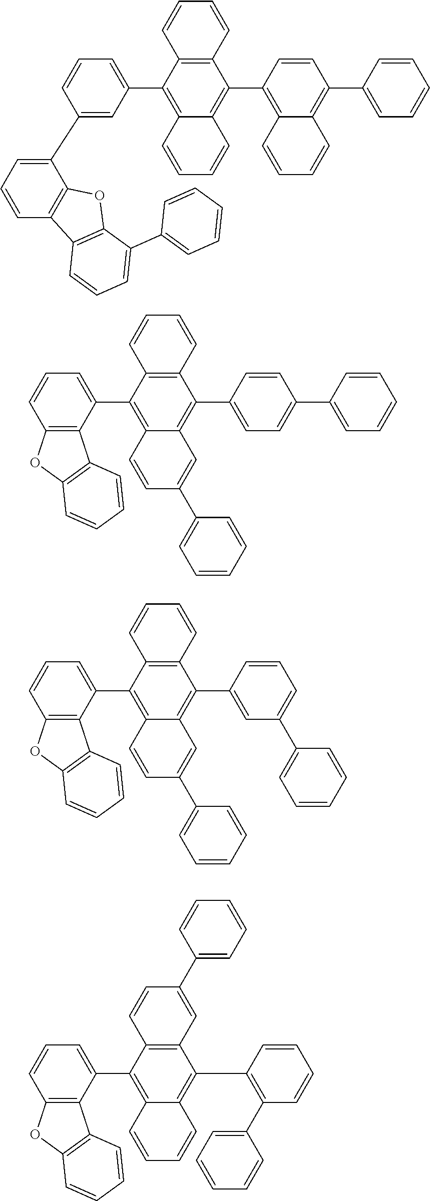

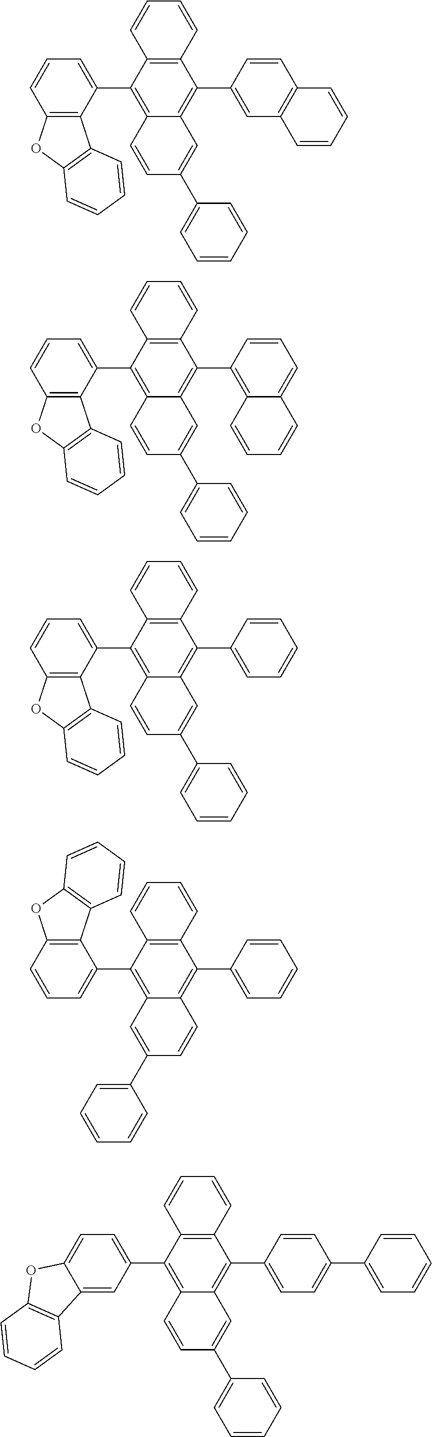

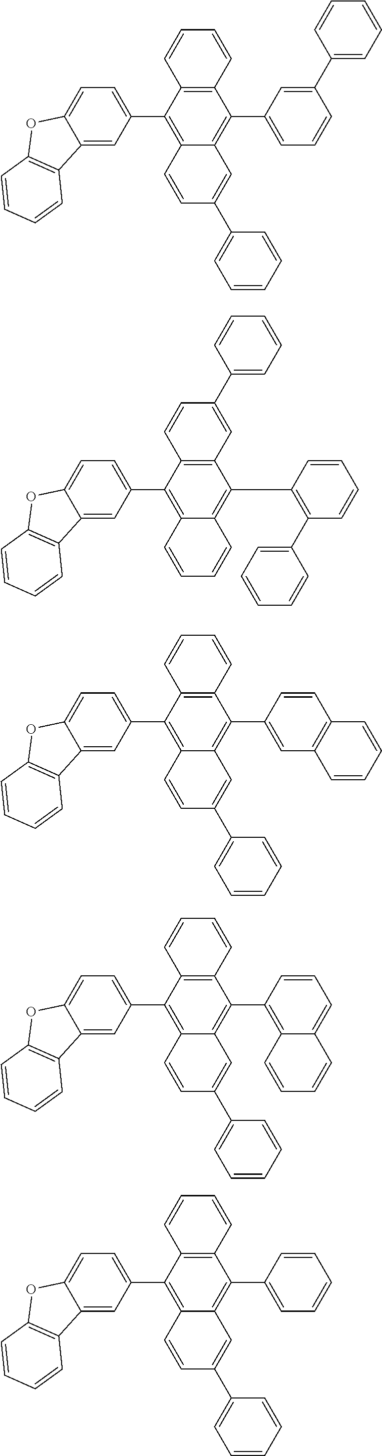

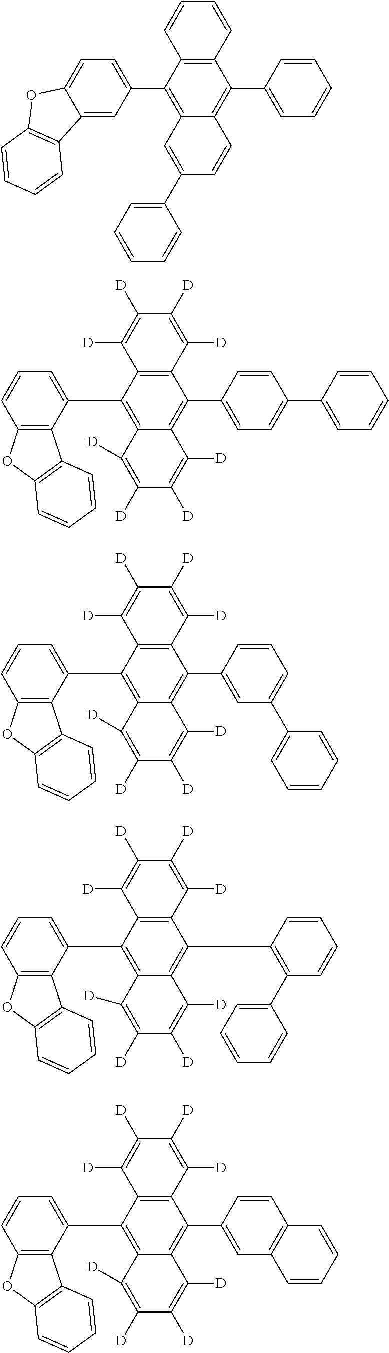

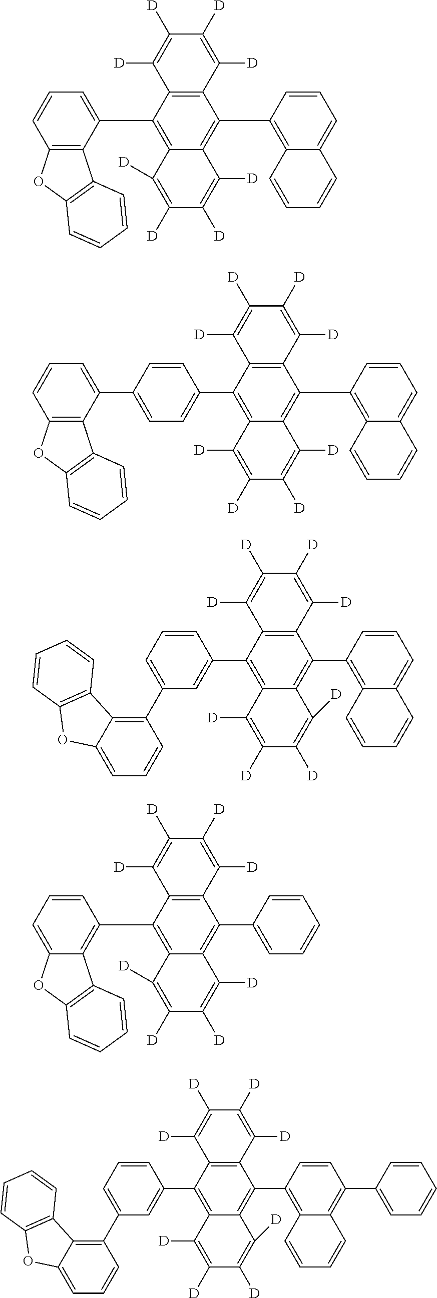

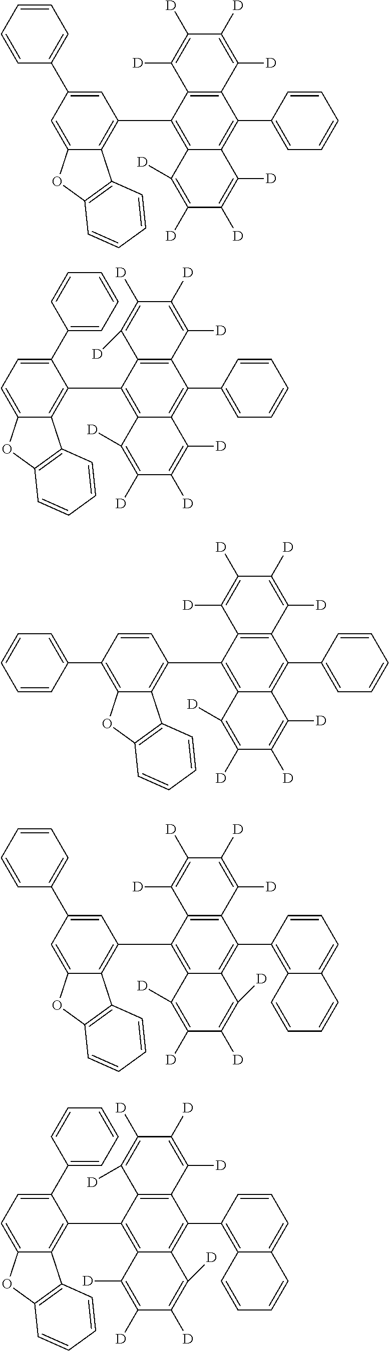

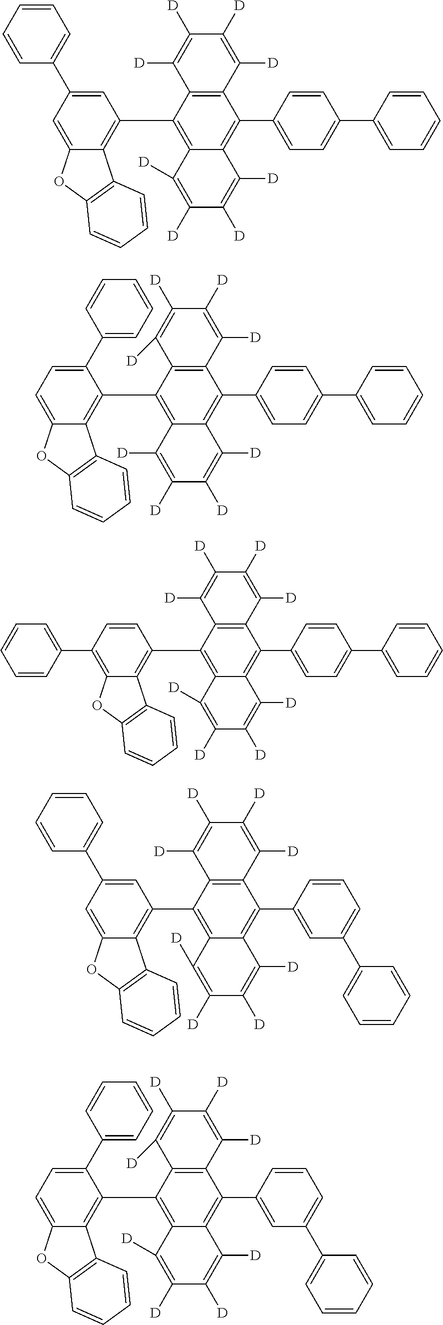

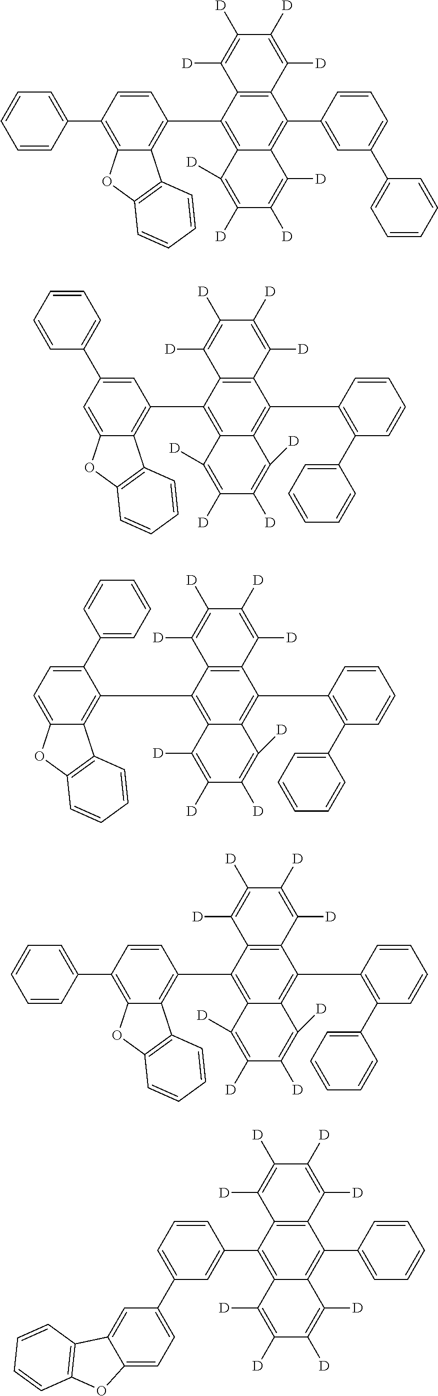

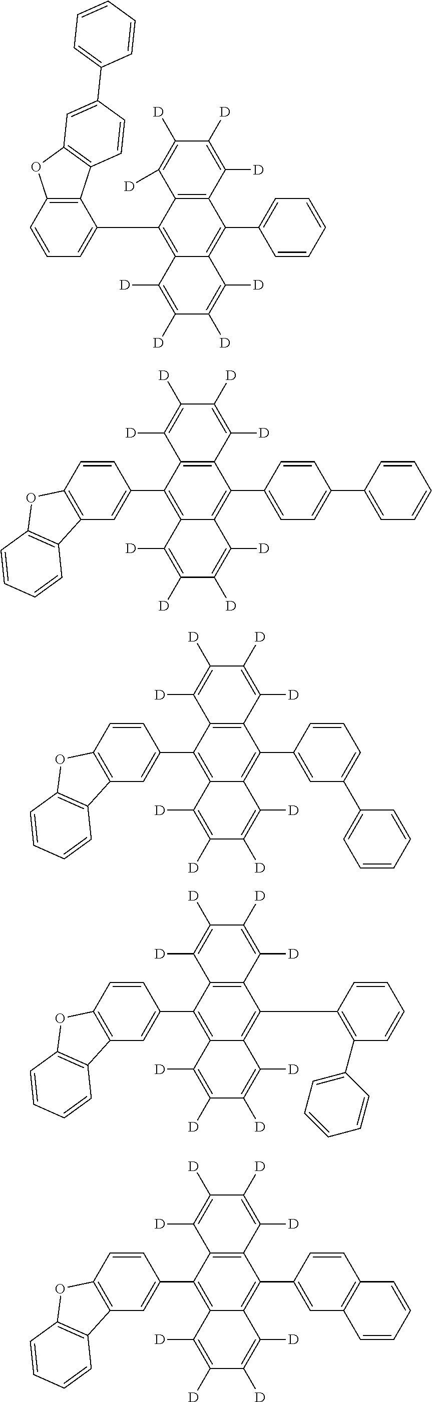

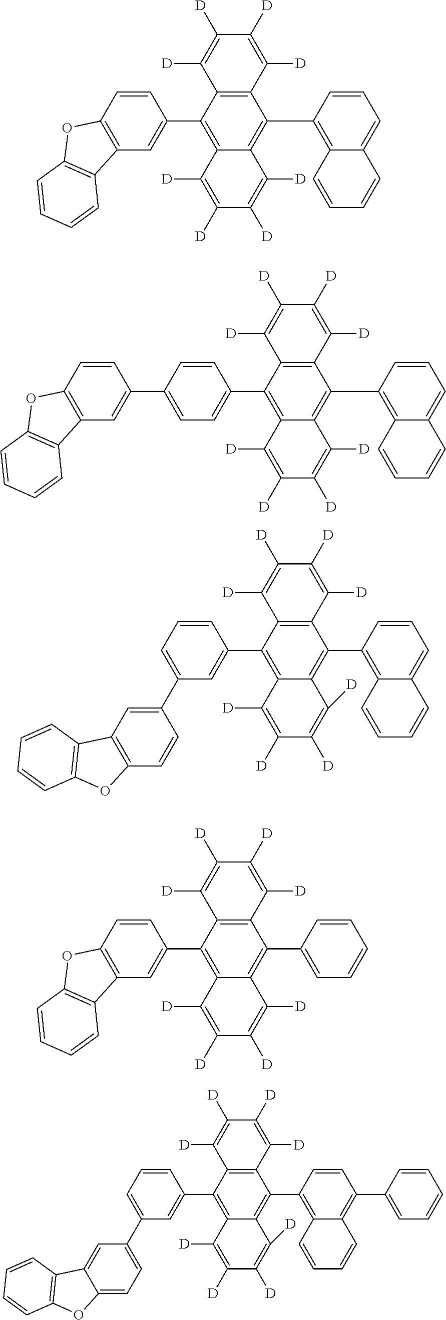

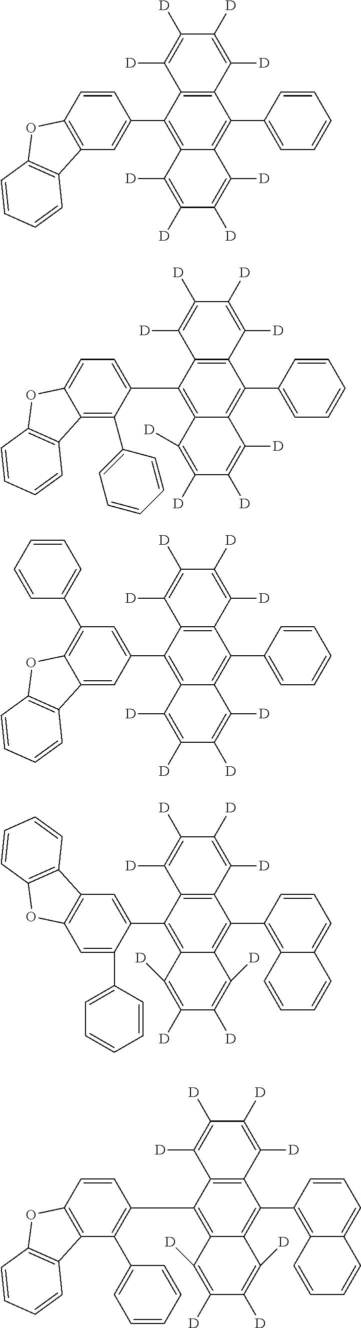

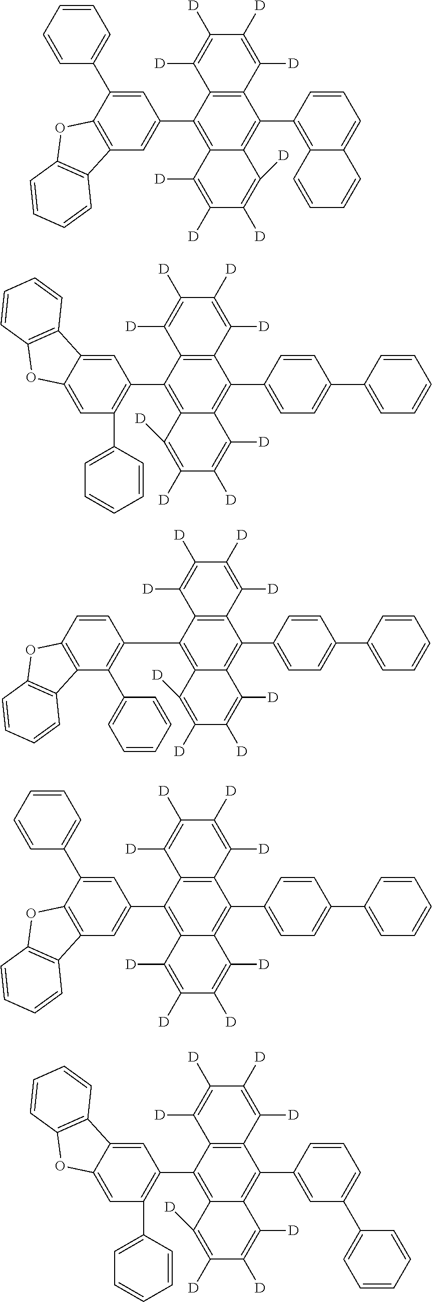

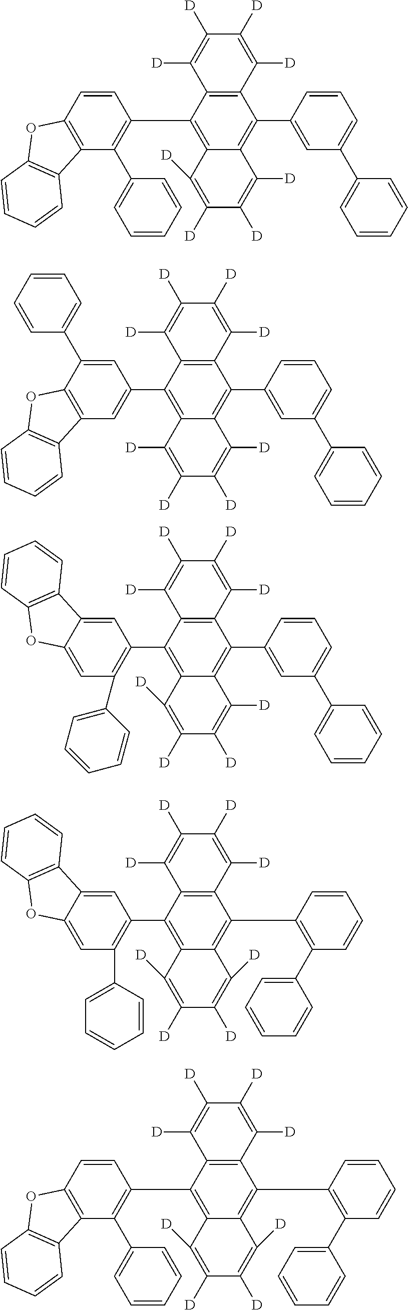

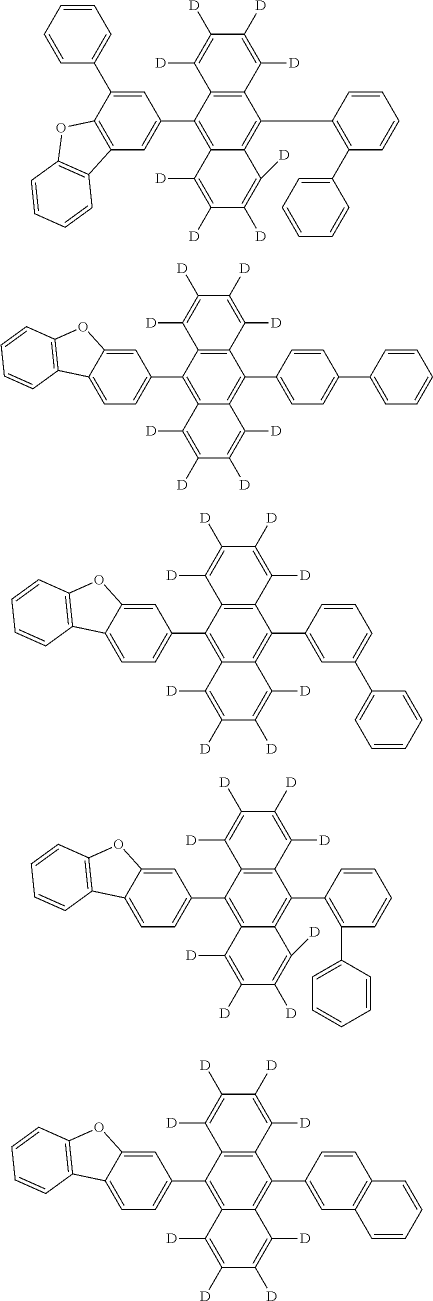

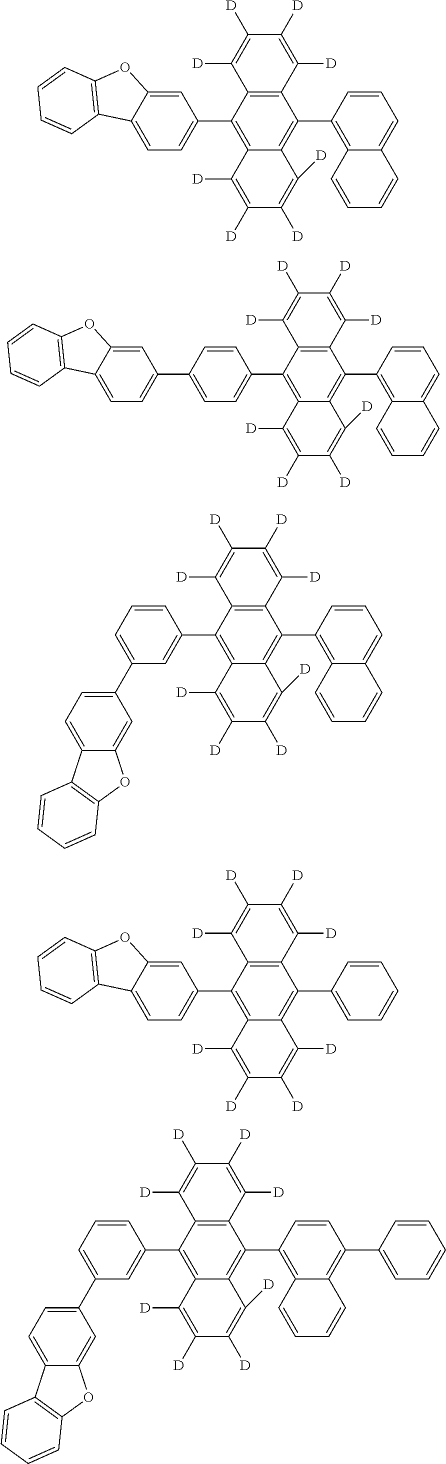

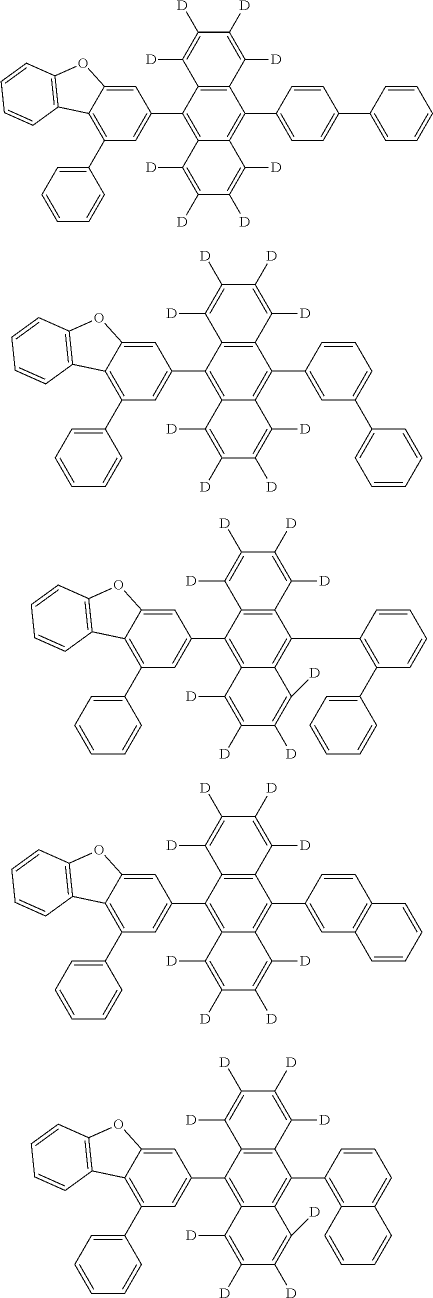

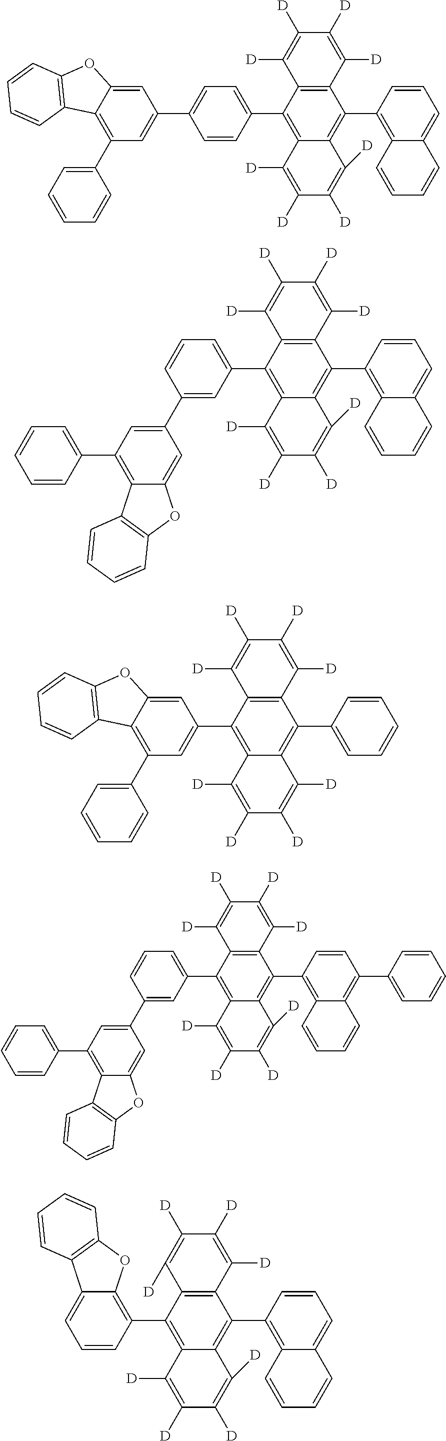

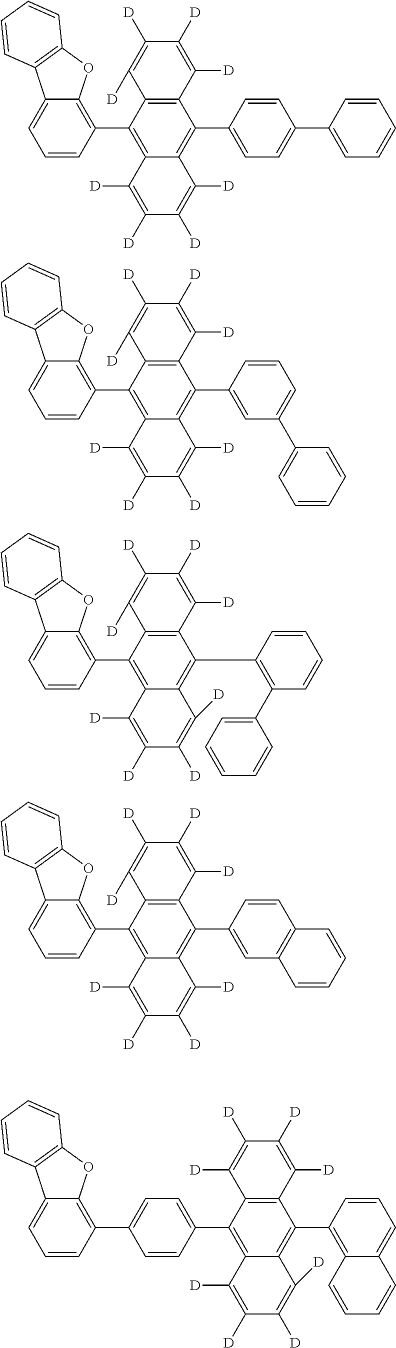

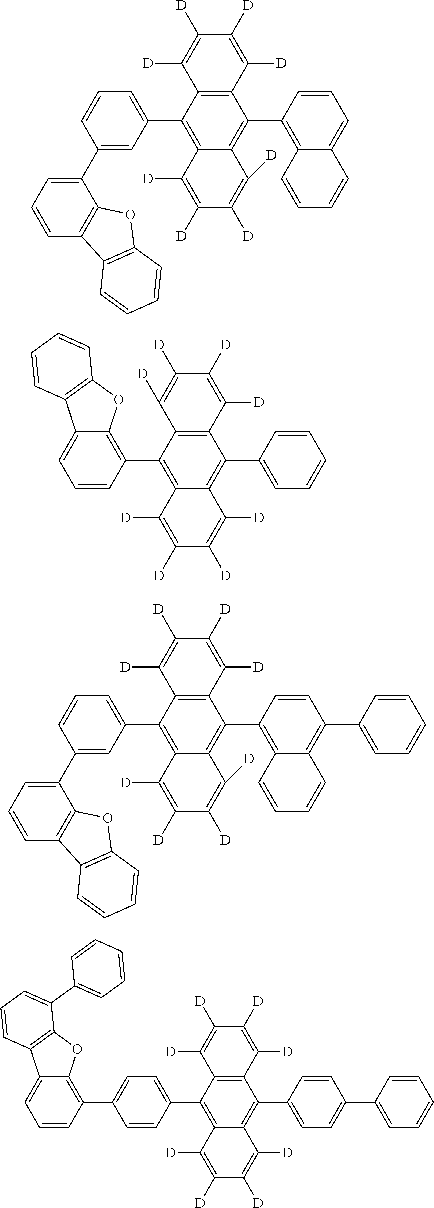

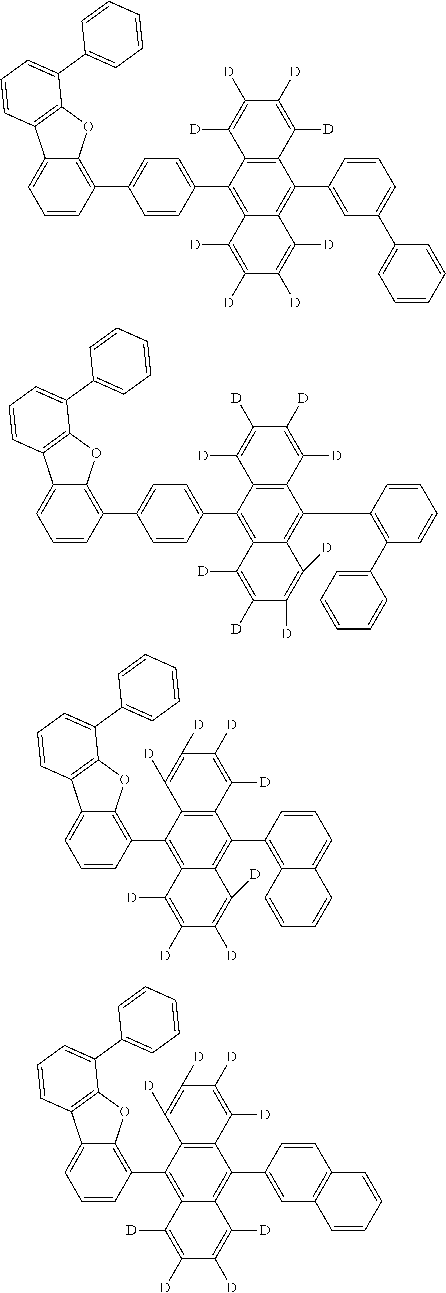

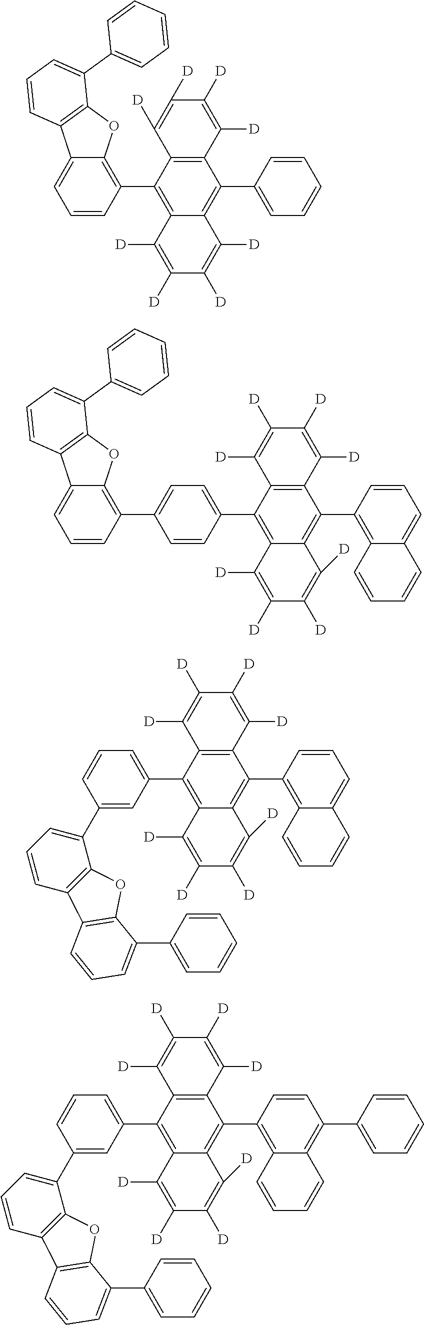

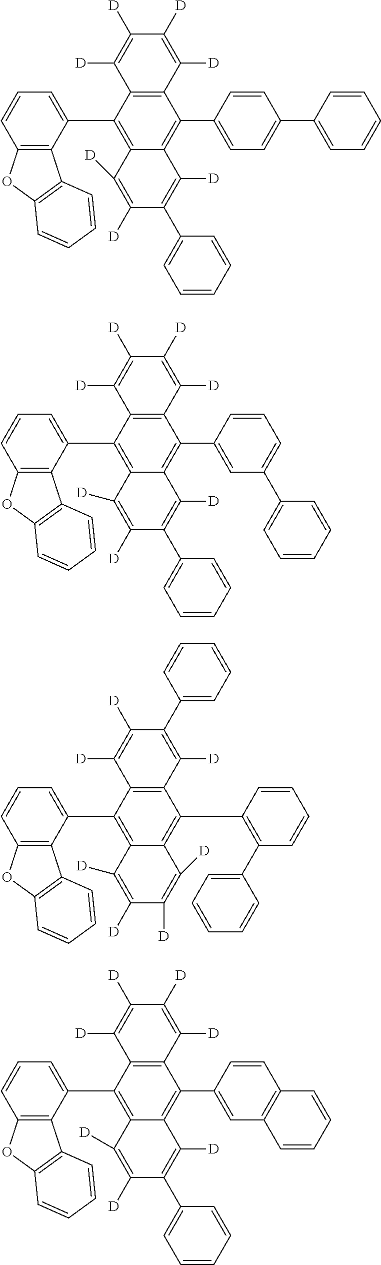

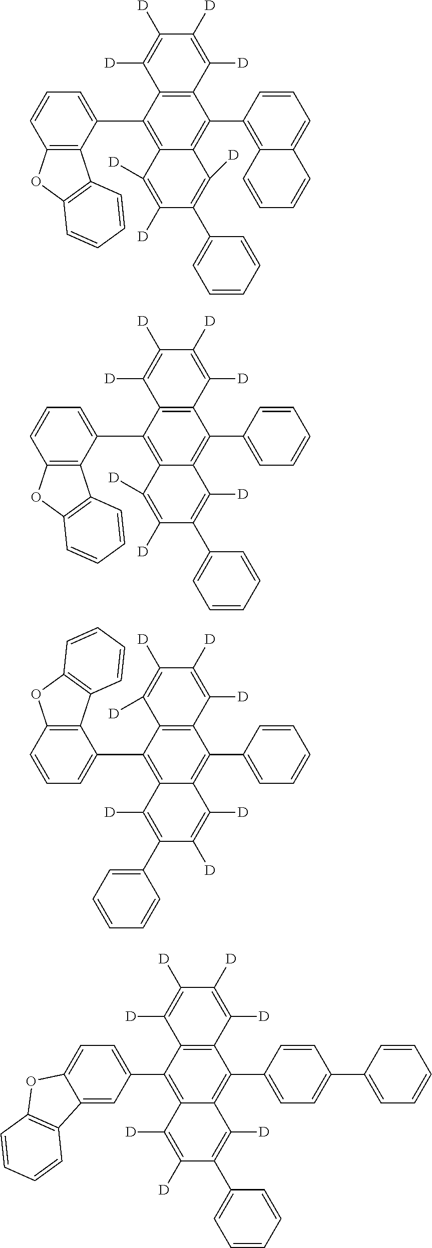

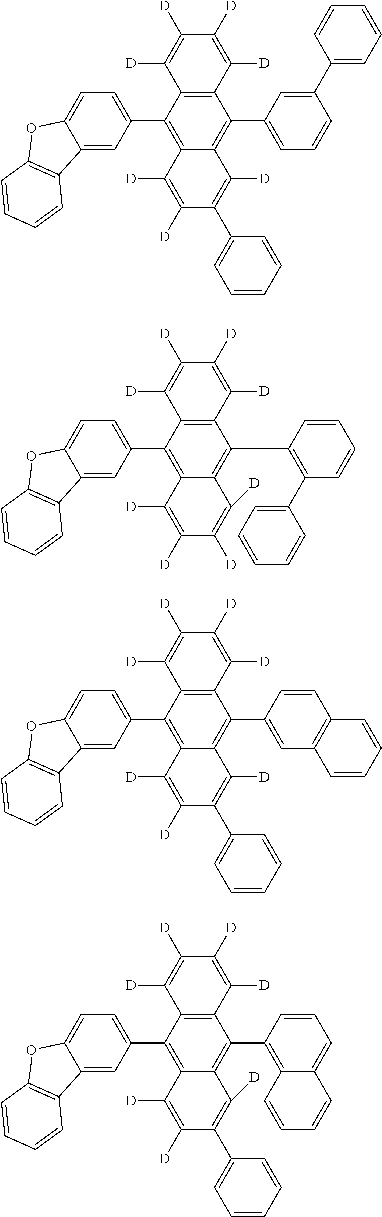

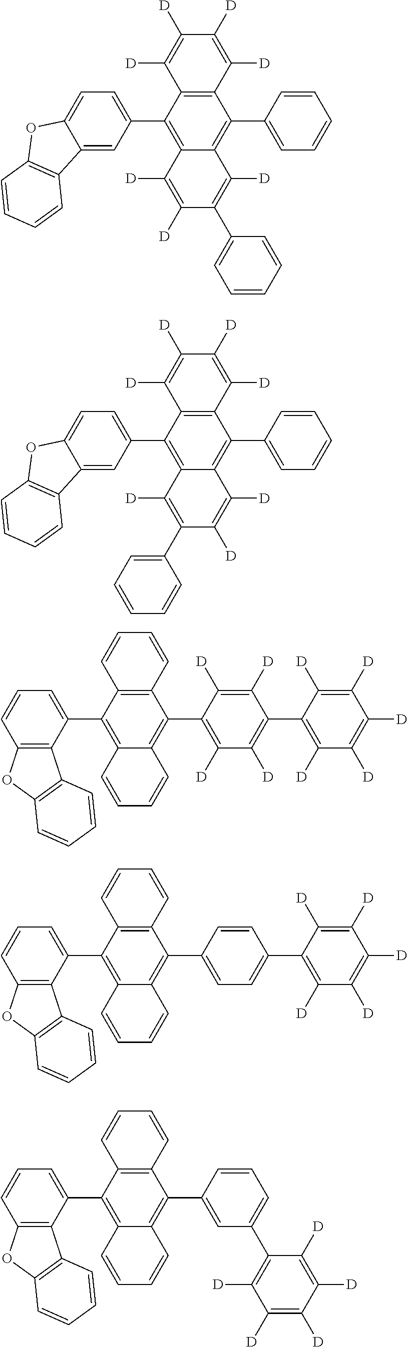

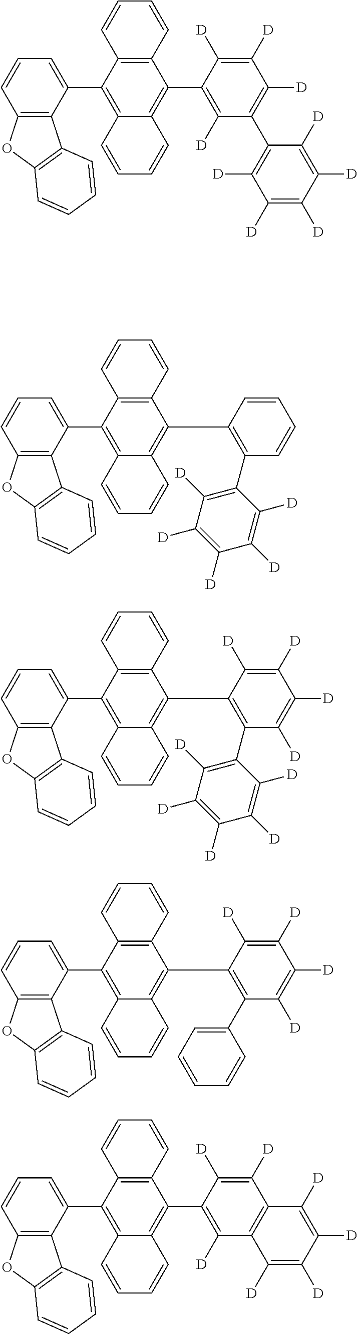

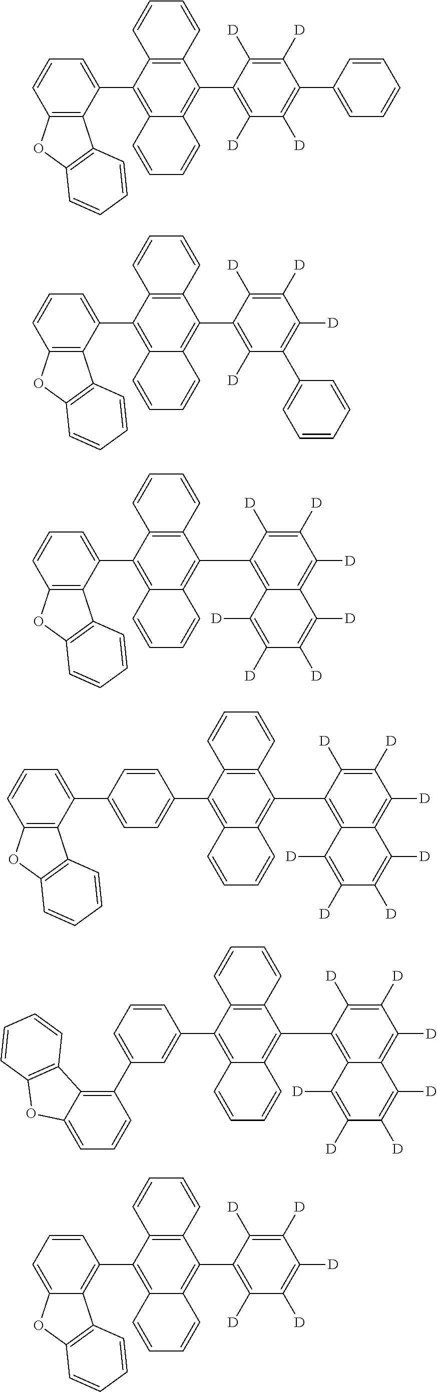

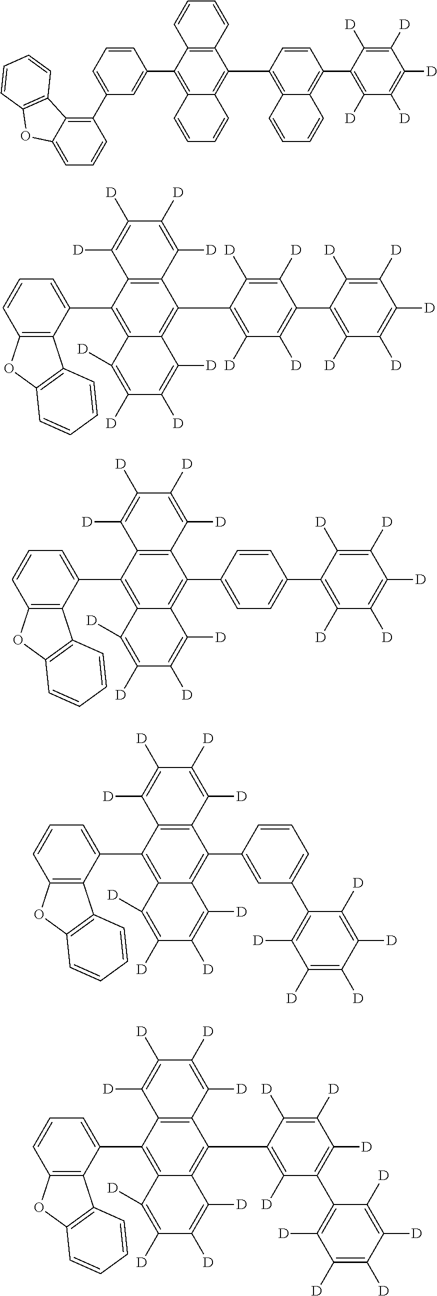

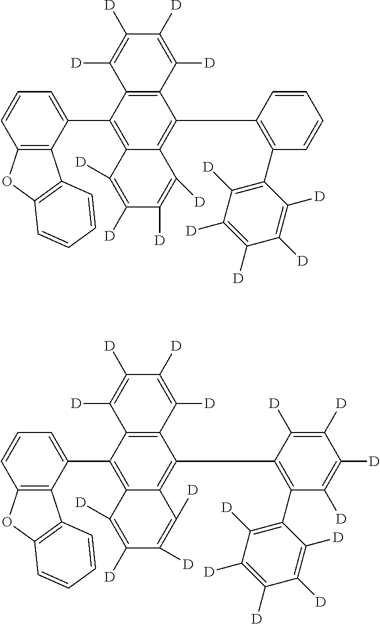 [SMILES: [2H]c1c([2H])c([2H])c(-c2ccccc2-c2c3c([2H])c([2H])c([2H])c([2H])c3c(-c3cccc4oc5ccccc5c34)c3c([2H])c([2H])c([2H])c([2H])c23)c([2H])c1[2H] ; [2H]c1c([2H])c([2H])c(-c2c([2H])c([2H])c([2H])c([2H])c2-c2c3c([2H])c([2H])c([2H])c([2H])c3c(-c3cccc4oc5ccccc5c34)c3c([2H])c([2H])c([2H])c([2H])c23)c([2H])c1[2H]]

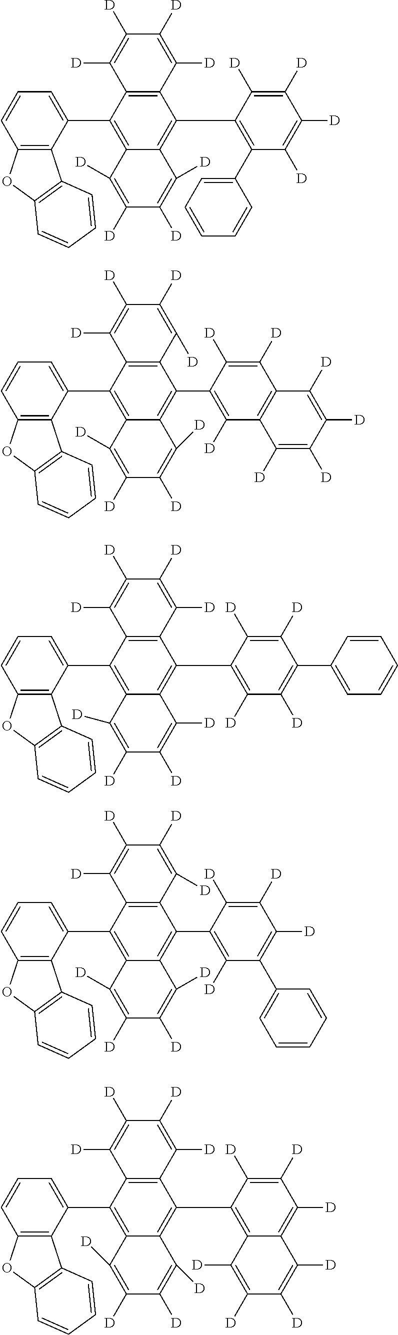

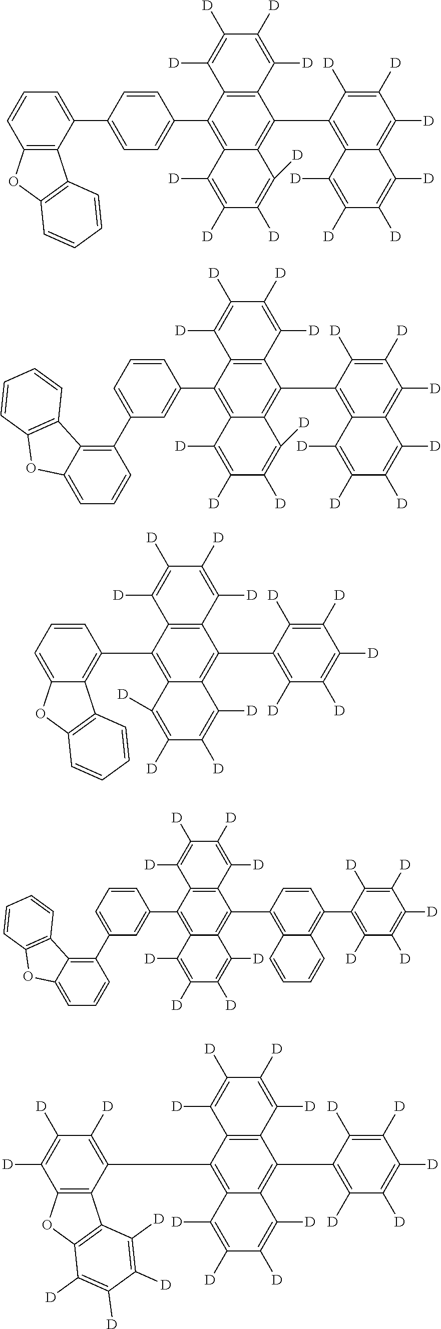

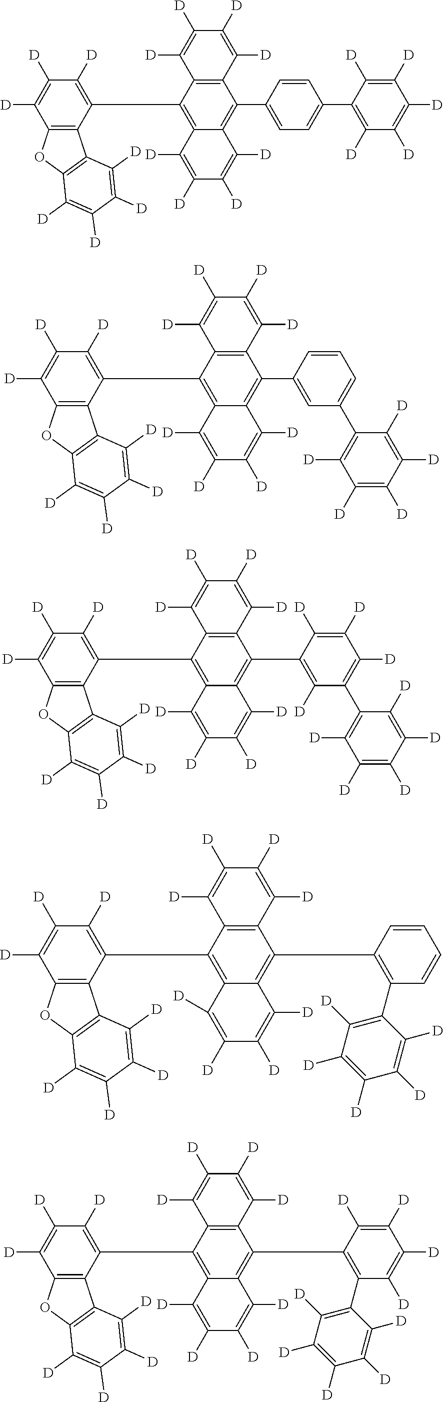

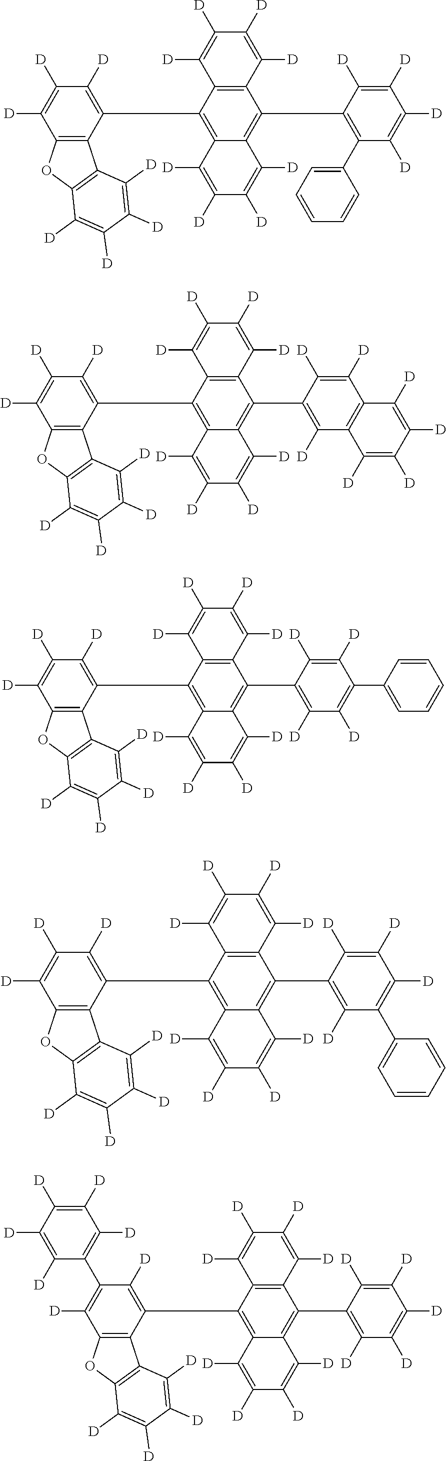

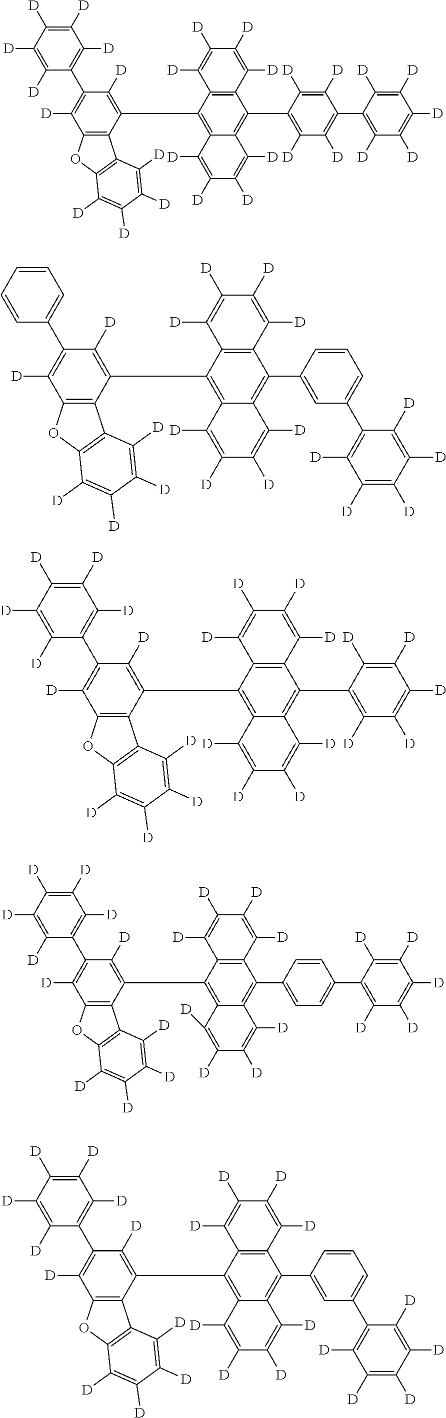

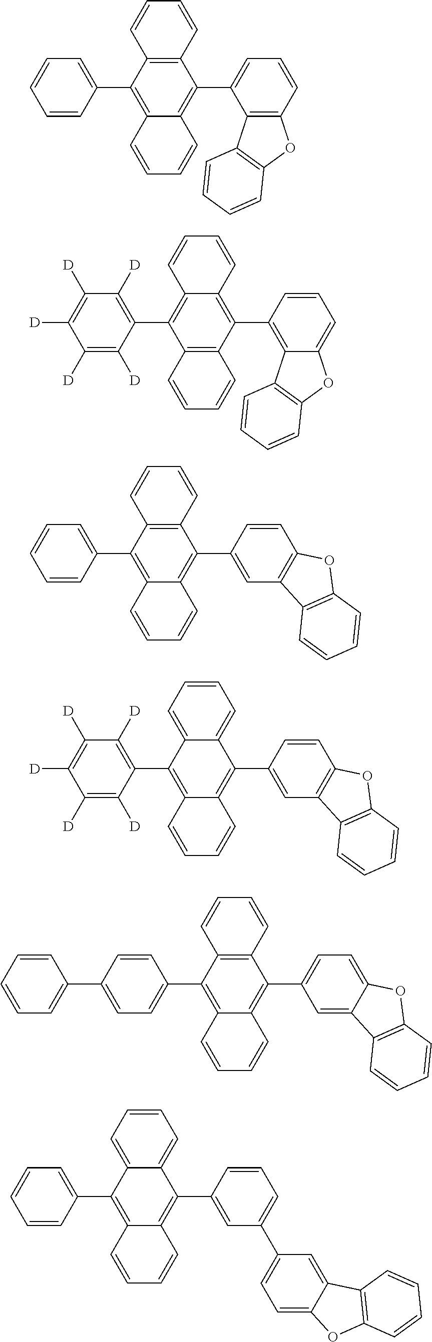

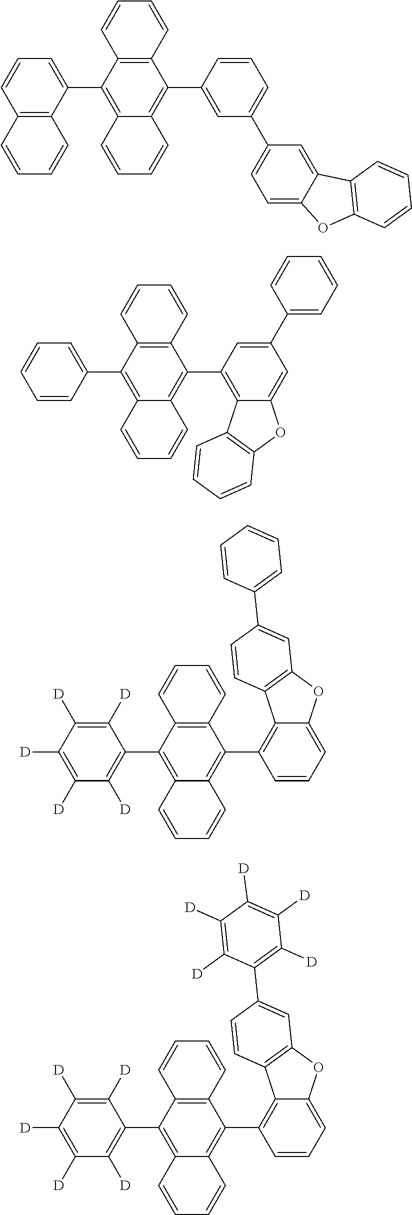

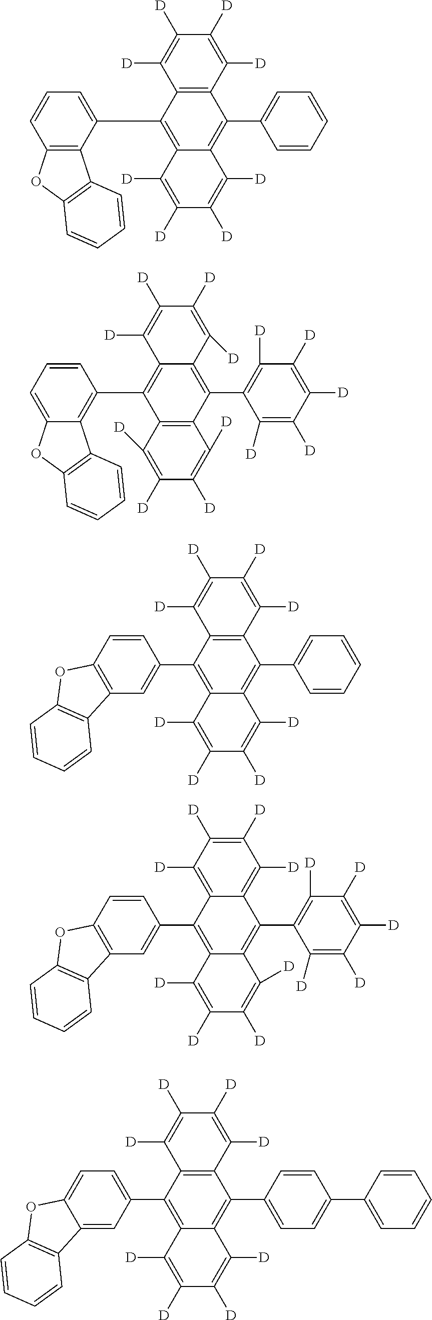

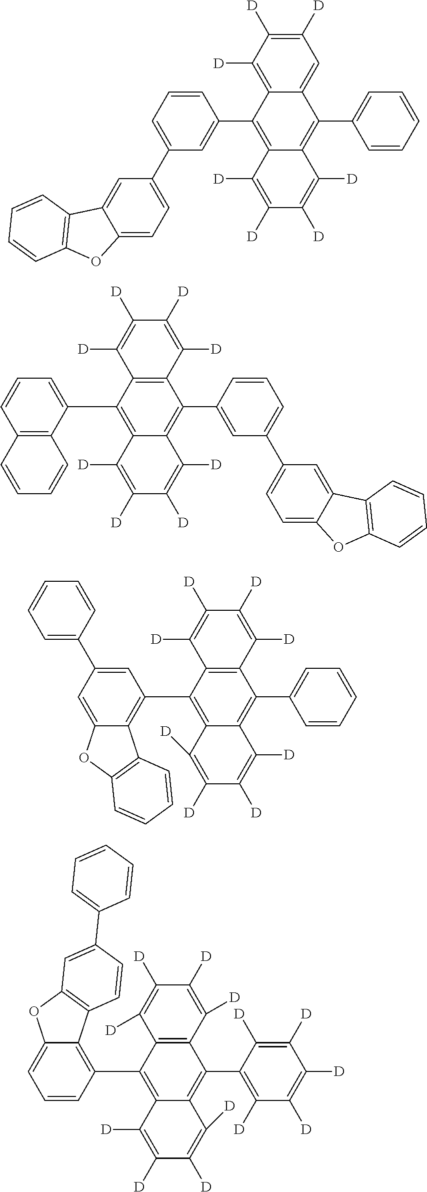

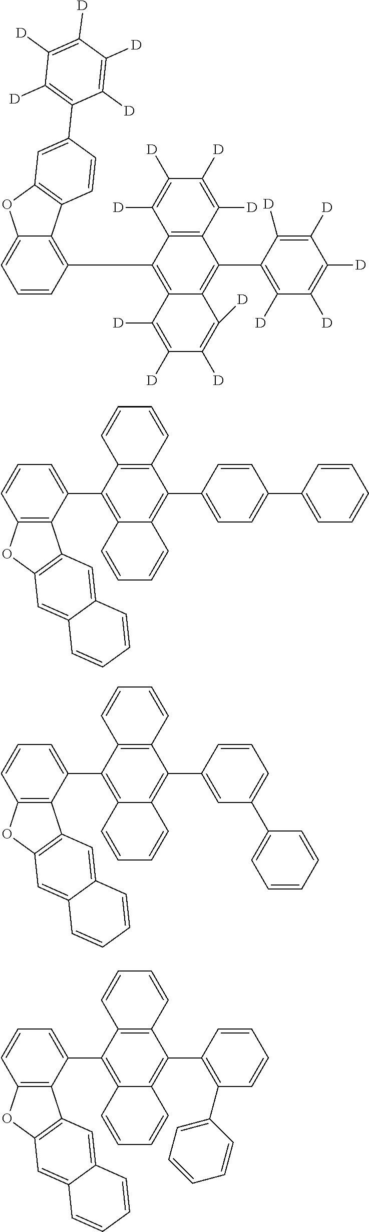

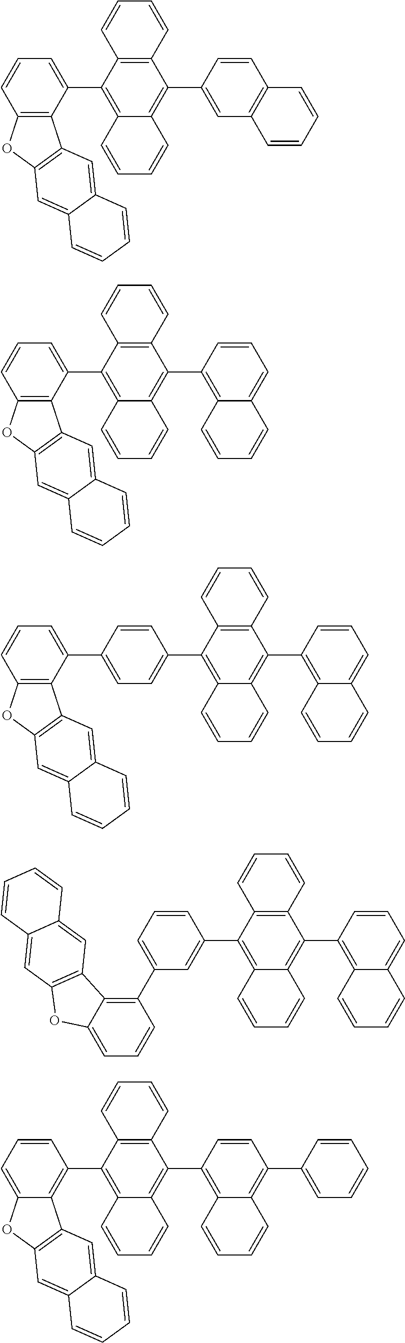

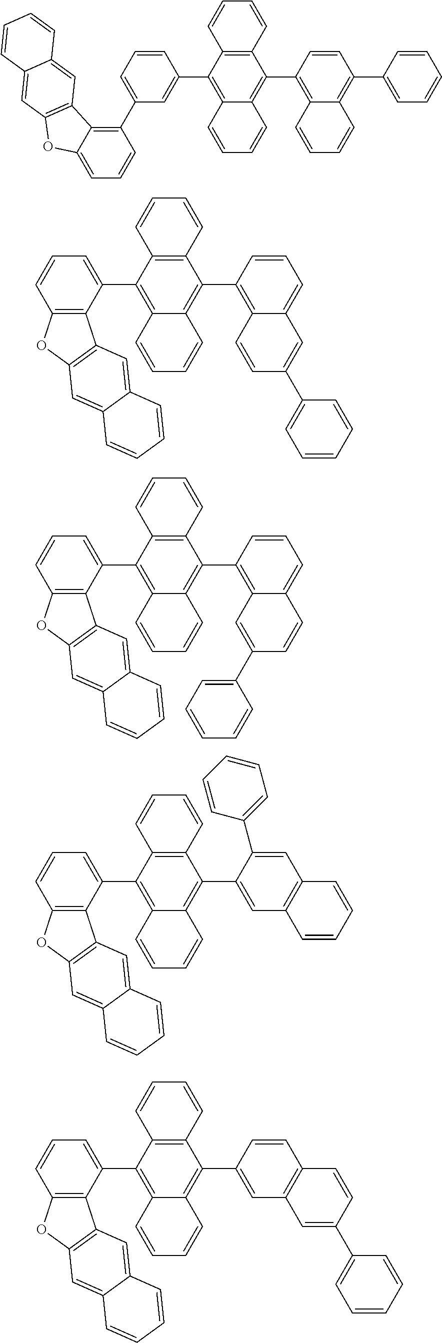

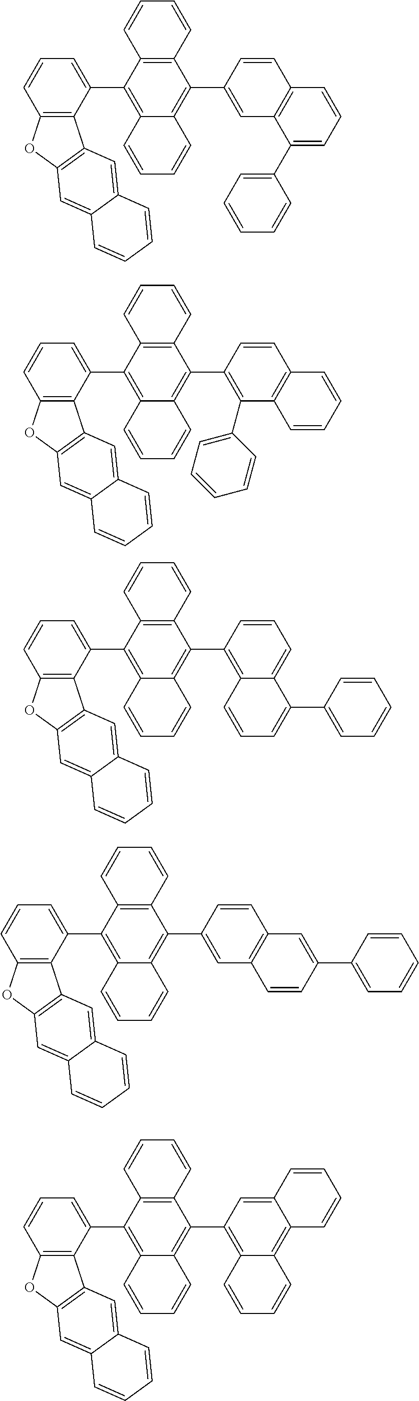

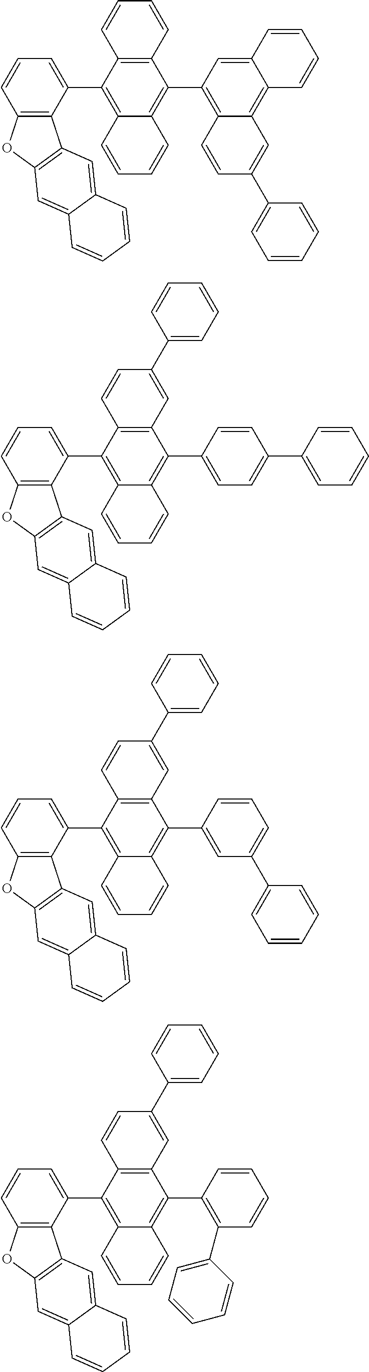 [SMILES: c1ccc(-c2ccc3c(-c4c5ccccc5c(-c5cccc6oc7cc8ccccc8cc7c56)c5ccccc45)cc4ccccc4c3c2)cc1 ; c1ccc(-c2ccc(-c3c4ccccc4c(-c4cccc5oc6cc7ccccc7cc6c45)c4ccc(-c5ccccc5)cc34)cc2)cc1 ; c1ccc(-c2cccc(-c3c4ccccc4c(-c4cccc5oc6cc7ccccc7cc6c45)c4ccc(-c5ccccc5)cc34)c2)cc1 ; c1ccc(-c2ccc3c(-c4cccc5oc6cc7ccccc7cc6c45)c4ccccc4c(-c4ccccc4-c4ccccc4)c3c2)cc1]

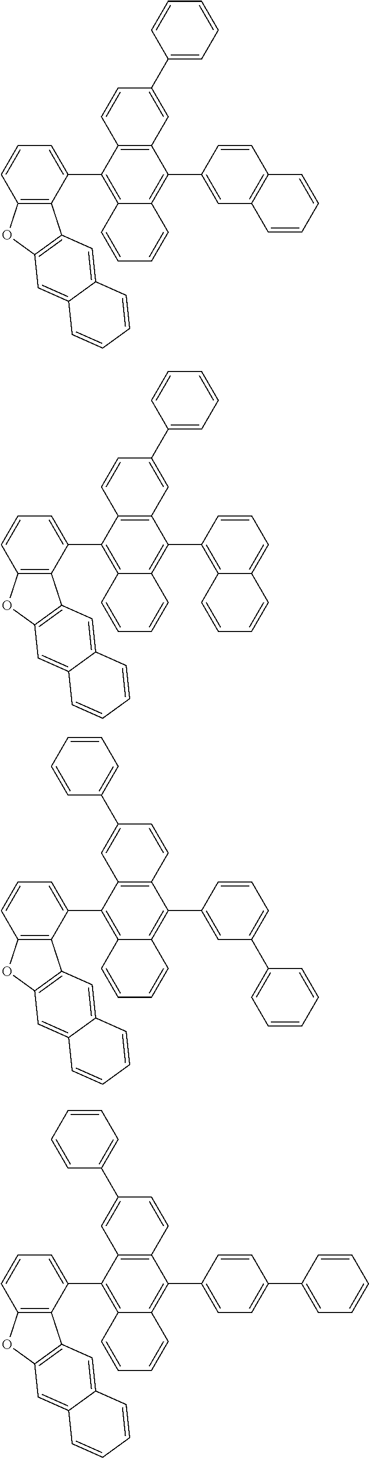

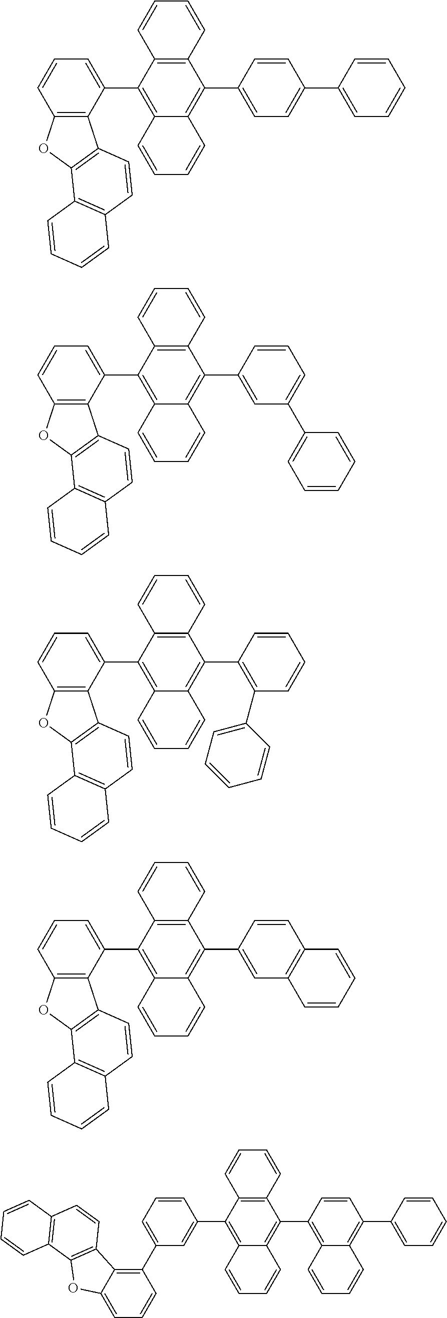 [SMILES: c1ccc(-c2ccc(-c3c4ccccc4c(-c4cccc5oc6c7ccccc7ccc6c45)c4ccccc34)cc2)cc1 ; c1ccc(-c2cccc(-c3c4ccccc4c(-c4cccc5oc6c7ccccc7ccc6c45)c4ccccc34)c2)cc1 ; c1ccc(-c2ccccc2-c2c3ccccc3c(-c3cccc4oc5c6ccccc6ccc5c34)c3ccccc23)cc1 ; c1ccc2cc(-c3c4ccccc4c(-c4cccc5oc6c7ccccc7ccc6c45)c4ccccc34)ccc2c1 ; c1ccc(-c2ccc(-c3c4ccccc4c(-c4cccc(-c5cccc6oc7c8ccccc8ccc7c56)c4)c4ccccc34)c3ccccc23)cc1]

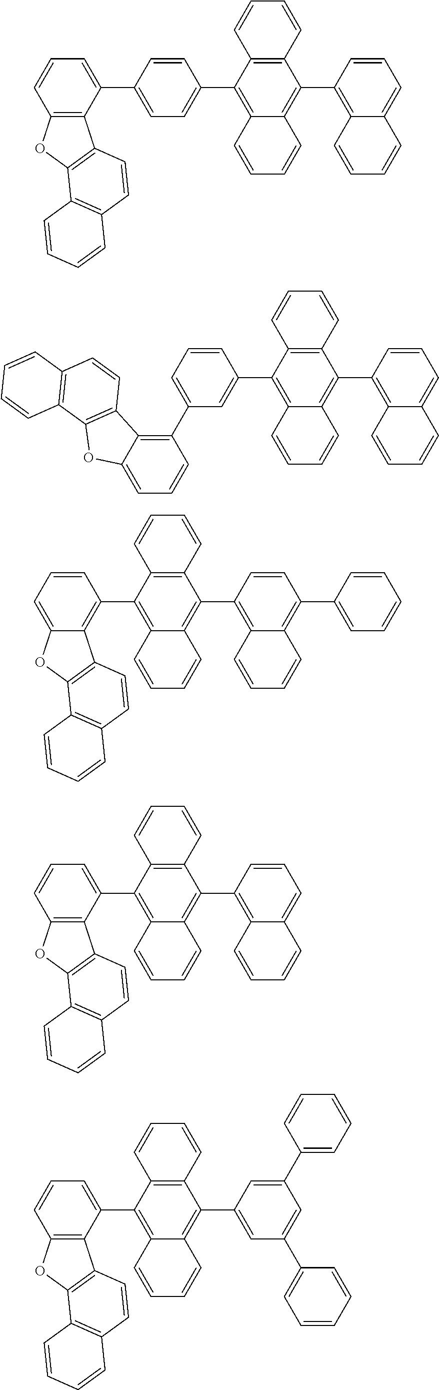

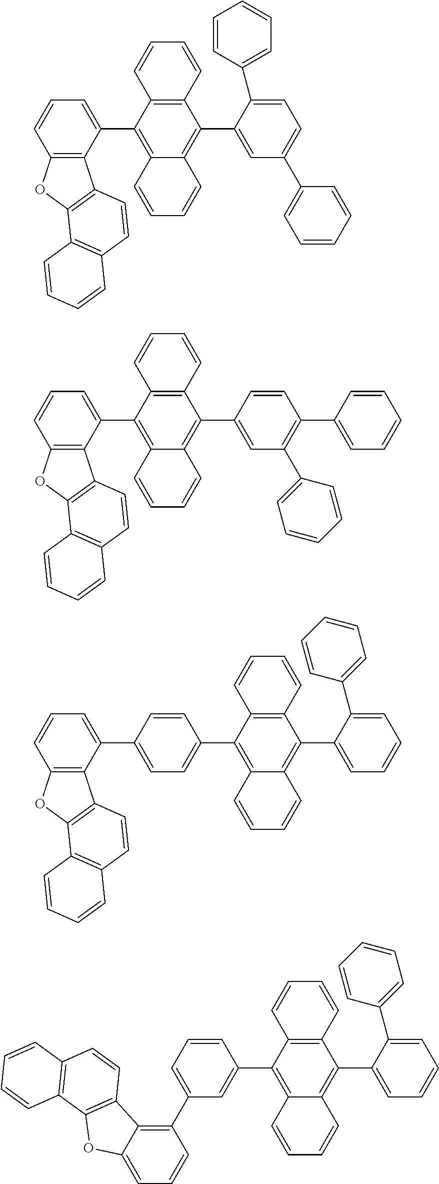 [SMILES: c1ccc(-c2ccc(-c3ccccc3)c(-c3c4ccccc4c(-c4cccc5oc6c7ccccc7ccc6c45)c4ccccc34)c2)cc1 ; c1ccc(-c2ccc(-c3c4ccccc4c(-c4cccc5oc6c7ccccc7ccc6c45)c4ccccc34)cc2-c2ccccc2)cc1 ; c1ccc(-c2ccccc2-c2c3ccccc3c(-c3ccc(-c4cccc5oc6c7ccccc7ccc6c45)cc3)c3ccccc23)cc1 ; c1ccc(-c2ccccc2-c2c3ccccc3c(-c3cccc(-c4cccc5oc6c7ccccc7ccc6c45)c3)c3ccccc23)cc1]

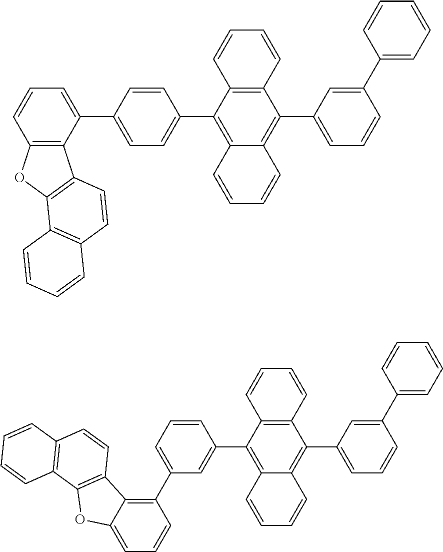 [SMILES: c1ccc(-c2cccc(-c3c4ccccc4c(-c4ccc(-c5cccc6oc7c8ccccc8ccc7c56)cc4)c4ccccc34)c2)cc1 ; c1ccc(-c2cccc(-c3c4ccccc4c(-c4cccc(-c5cccc6oc7c8ccccc8ccc7c56)c4)c4ccccc34)c2)cc1]

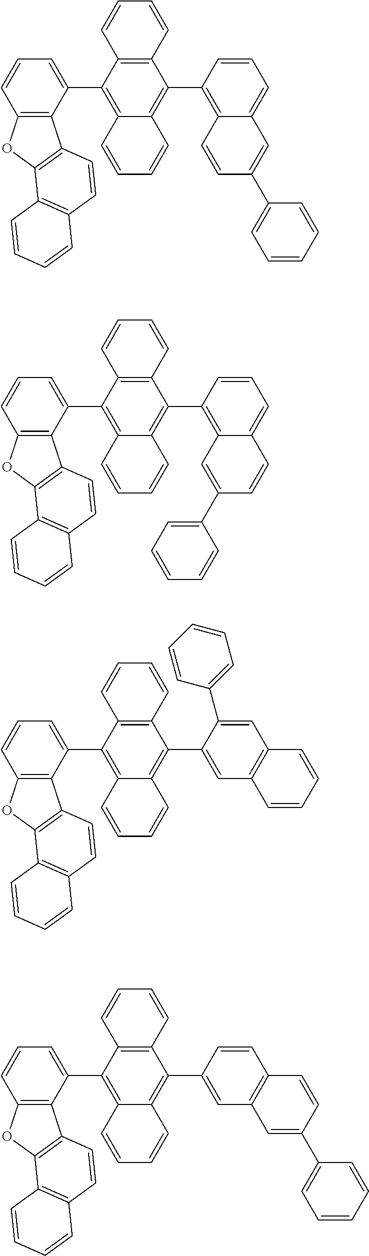

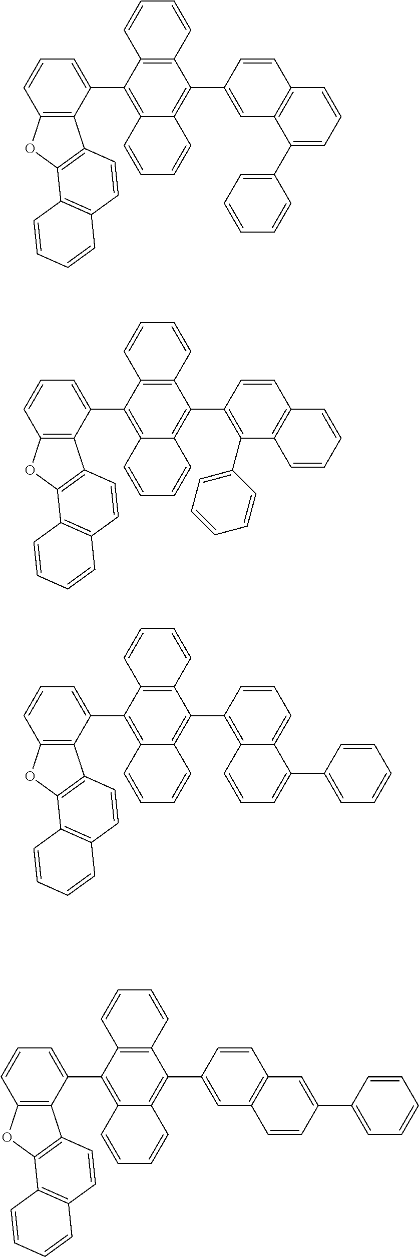 [SMILES: c1ccc(-c2cccc3ccc(-c4c5ccccc5c(-c5cccc6oc7c8ccccc8ccc7c56)c5ccccc45)cc23)cc1 ; c1ccc(-c2c(-c3c4ccccc4c(-c4cccc5oc6c7ccccc7ccc6c45)c4ccccc34)ccc3ccccc23)cc1 ; c1ccc(-c2cccc3c(-c4c5ccccc5c(-c5cccc6oc7c8ccccc8ccc7c56)c5ccccc45)cccc23)cc1 ; c1ccc(-c2ccc3cc(-c4c5ccccc5c(-c5cccc6oc7c8ccccc8ccc7c56)c5ccccc45)ccc3c2)cc1]

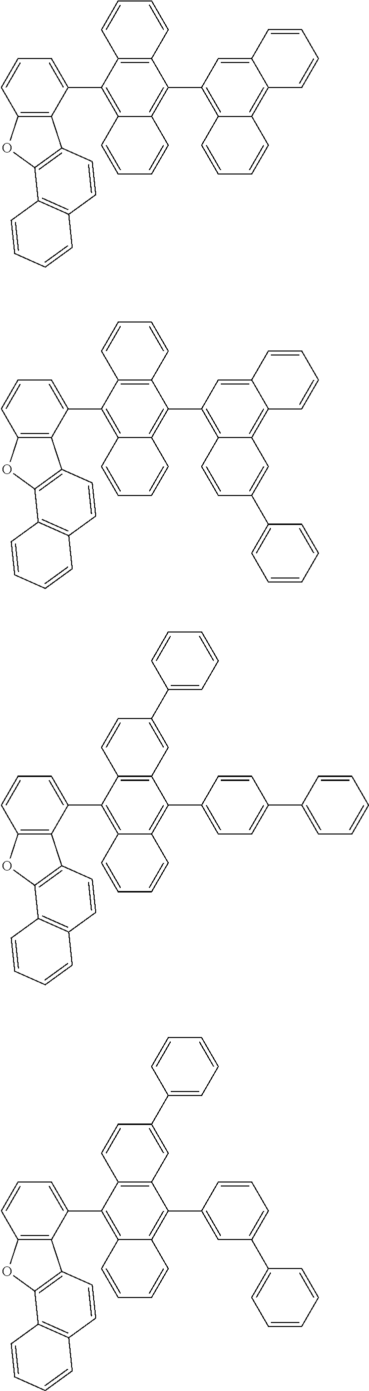 [SMILES: c1ccc2c(c1)cc(-c1c3ccccc3c(-c3cccc4oc5c6ccccc6ccc5c34)c3ccccc13)c1ccccc12 ; c1ccc(-c2ccc3c(-c4c5ccccc5c(-c5cccc6oc7c8ccccc8ccc7c56)c5ccccc45)cc4ccccc4c3c2)cc1 ; c1ccc(-c2ccc(-c3c4ccccc4c(-c4cccc5oc6c7ccccc7ccc6c45)c4ccc(-c5ccccc5)cc34)cc2)cc1 ; c1ccc(-c2cccc(-c3c4ccccc4c(-c4cccc5oc6c7ccccc7ccc6c45)c4ccc(-c5ccccc5)cc34)c2)cc1]

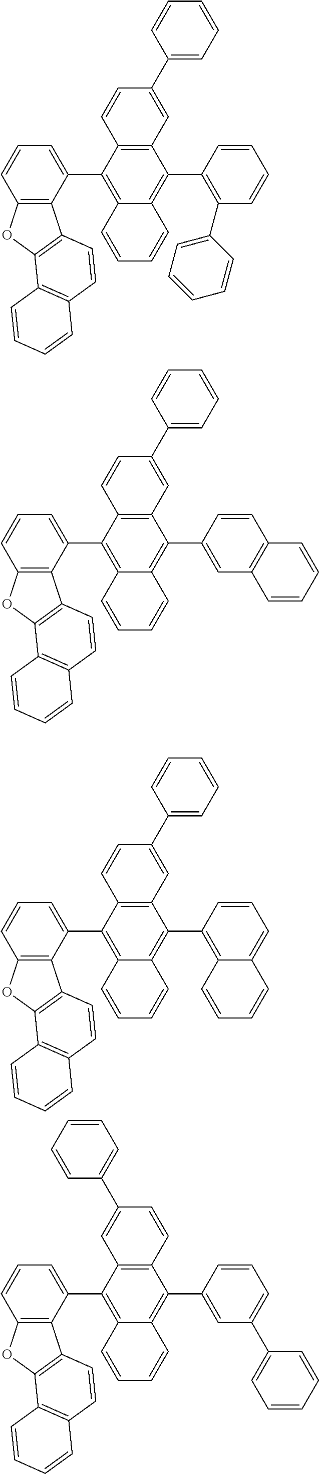

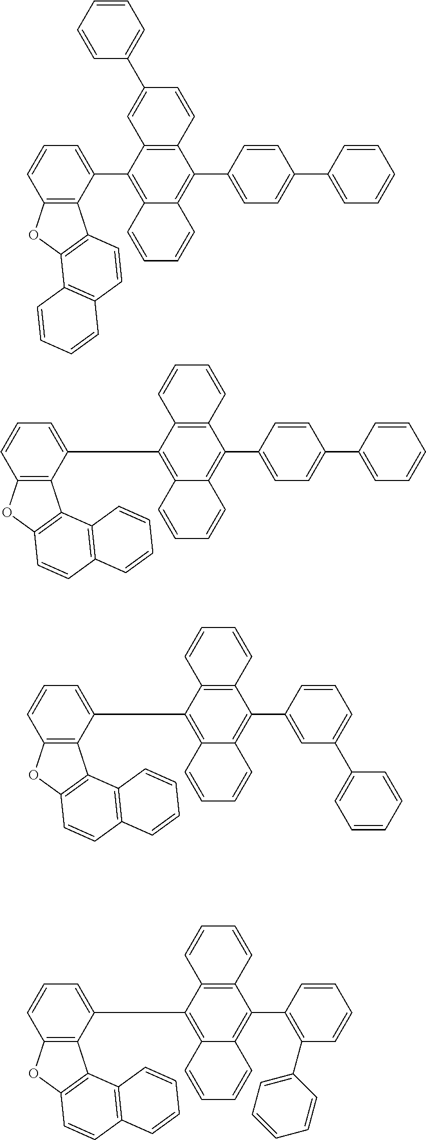 [SMILES: c1ccc(-c2ccc(-c3c4ccccc4c(-c4cccc5oc6c7ccccc7ccc6c45)c4cc(-c5ccccc5)ccc34)cc2)cc1 ; c1ccc(-c2ccc(-c3c4ccccc4c(-c4cccc5oc6ccc7ccccc7c6c45)c4ccccc34)cc2)cc1 ; c1ccc(-c2cccc(-c3c4ccccc4c(-c4cccc5oc6ccc7ccccc7c6c45)c4ccccc34)c2)cc1 ; c1ccc(-c2ccccc2-c2c3ccccc3c(-c3cccc4oc5ccc6ccccc6c5c34)c3ccccc23)cc1]

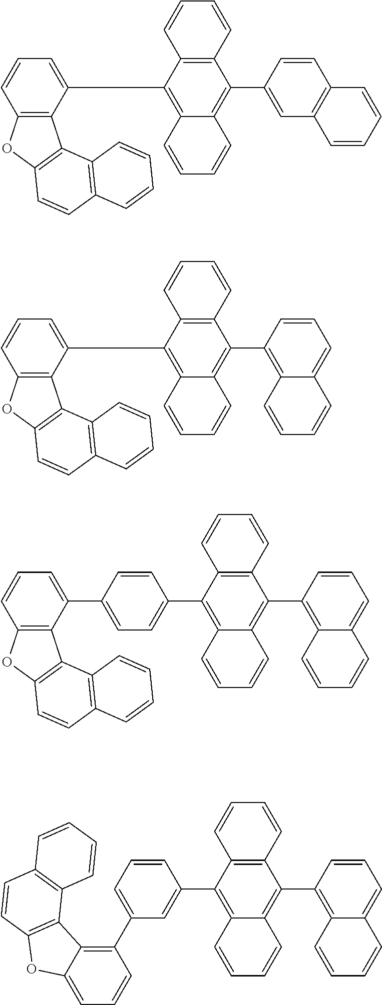 [SMILES: c1ccc2cc(-c3c4ccccc4c(-c4cccc5oc6ccc7ccccc7c6c45)c4ccccc34)ccc2c1 ; c1ccc2c(-c3c4ccccc4c(-c4cccc5oc6ccc7ccccc7c6c45)c4ccccc34)cccc2c1 ; c1ccc2c(-c3c4ccccc4c(-c4ccc(-c5cccc6oc7ccc8ccccc8c7c56)cc4)c4ccccc34)cccc2c1 ; c1cc(-c2c3ccccc3c(-c3cccc4ccccc34)c3ccccc23)cc(-c2cccc3oc4ccc5ccccc5c4c23)c1]

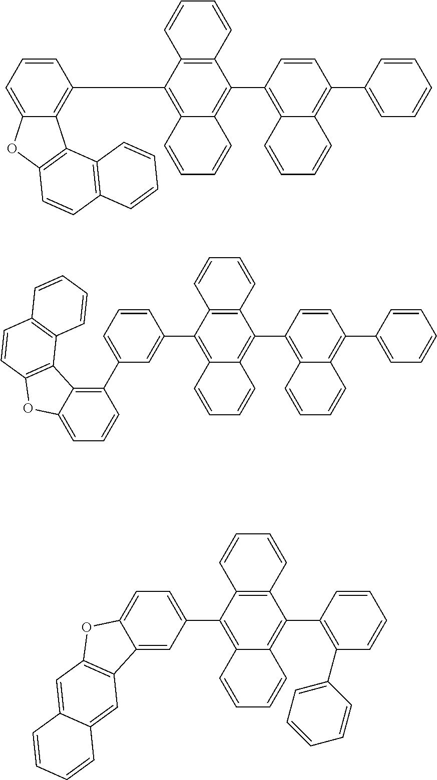 [SMILES: c1ccc(-c2ccc(-c3c4ccccc4c(-c4cccc5oc6ccc7ccccc7c6c45)c4ccccc34)c3ccccc23)cc1 ; c1ccc(-c2ccc(-c3c4ccccc4c(-c4cccc(-c5cccc6oc7ccc8ccccc8c7c56)c4)c4ccccc34)c3ccccc23)cc1 ; c1ccc(-c2ccccc2-c2c3ccccc3c(-c3ccc4oc5cc6ccccc6cc5c4c3)c3ccccc23)cc1]

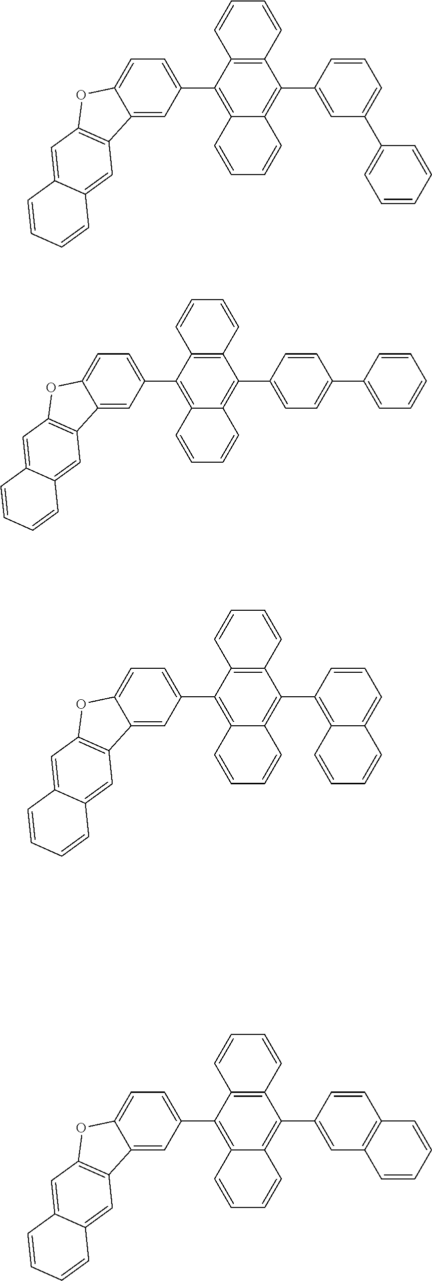 [SMILES: c1ccc(-c2cccc(-c3c4ccccc4c(-c4ccc5oc6cc7ccccc7cc6c5c4)c4ccccc34)c2)cc1 ; c1ccc(-c2ccc(-c3c4ccccc4c(-c4ccc5oc6cc7ccccc7cc6c5c4)c4ccccc34)cc2)cc1 ; c1ccc2cc3c(cc2c1)oc1ccc(-c2c4ccccc4c(-c4cccc5ccccc45)c4ccccc24)cc13 ; c1ccc2cc(-c3c4ccccc4c(-c4ccc5oc6cc7ccccc7cc6c5c4)c4ccccc34)ccc2c1]

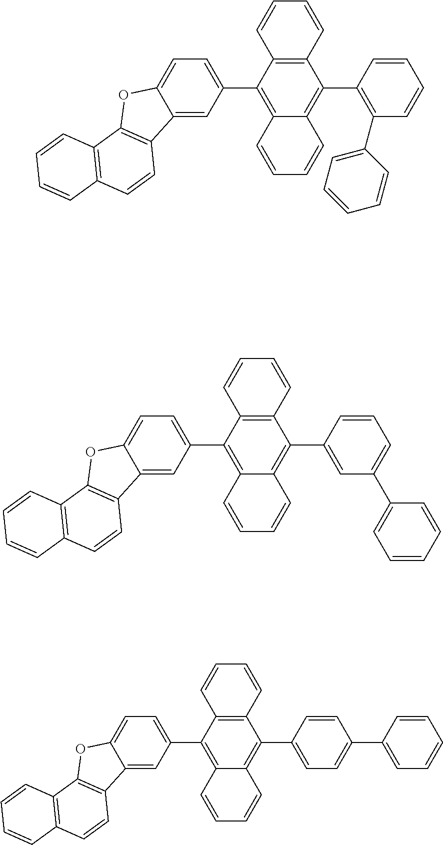 [SMILES: c1ccc(-c2ccccc2-c2c3ccccc3c(-c3ccc4oc5c6ccccc6ccc5c4c3)c3ccccc23)cc1 ; c1ccc(-c2cccc(-c3c4ccccc4c(-c4ccc5oc6c7ccccc7ccc6c5c4)c4ccccc34)c2)cc1 ; c1ccc(-c2ccc(-c3c4ccccc4c(-c4ccc5oc6c7ccccc7ccc6c5c4)c4ccccc34)cc2)cc1]

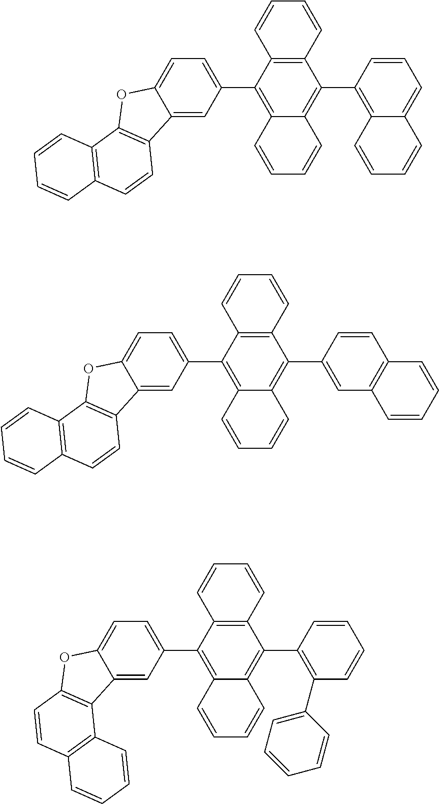 [SMILES: c1ccc2c(-c3c4ccccc4c(-c4ccc5oc6c7ccccc7ccc6c5c4)c4ccccc34)cccc2c1 ; c1ccc2cc(-c3c4ccccc4c(-c4ccc5oc6c7ccccc7ccc6c5c4)c4ccccc34)ccc2c1 ; c1ccc(-c2ccccc2-c2c3ccccc3c(-c3ccc4oc5ccc6ccccc6c5c4c3)c3ccccc23)cc1]

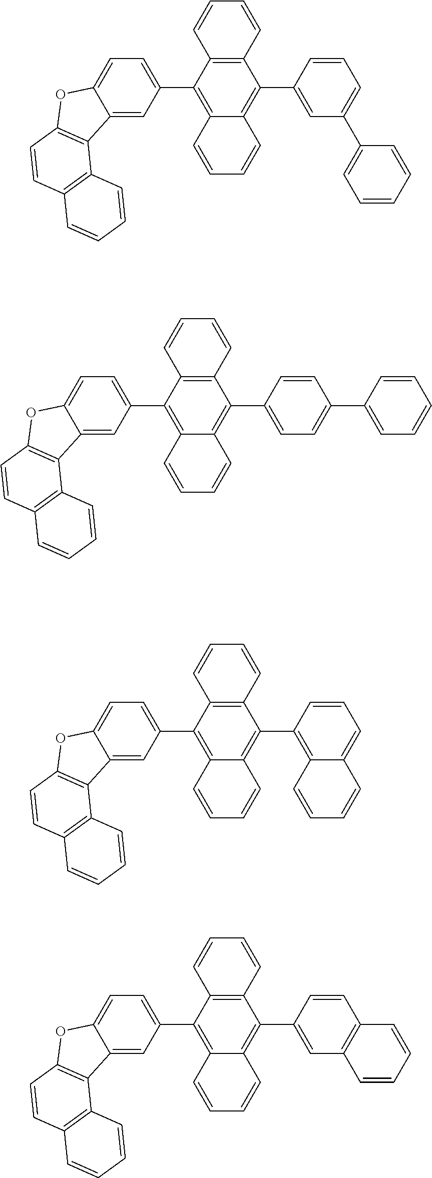 [SMILES: c1ccc(-c2cccc(-c3c4ccccc4c(-c4ccc5oc6ccc7ccccc7c6c5c4)c4ccccc34)c2)cc1 ; c1ccc(-c2ccc(-c3c4ccccc4c(-c4ccc5oc6ccc7ccccc7c6c5c4)c4ccccc34)cc2)cc1 ; c1ccc2c(-c3c4ccccc4c(-c4ccc5oc6ccc7ccccc7c6c5c4)c4ccccc34)cccc2c1 ; c1ccc2cc(-c3c4ccccc4c(-c4ccc5oc6ccc7ccccc7c6c5c4)c4ccccc34)ccc2c1]

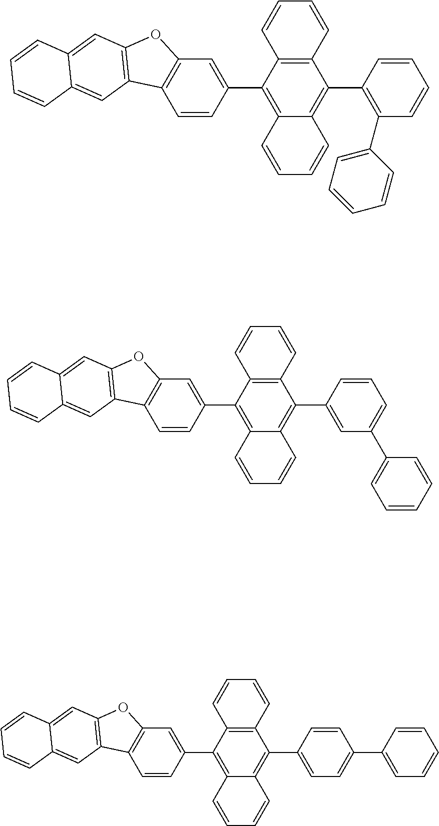 [SMILES: c1ccc(-c2ccccc2-c2c3ccccc3c(-c3ccc4c(c3)oc3cc5ccccc5cc34)c3ccccc23)cc1 ; c1ccc(-c2cccc(-c3c4ccccc4c(-c4ccc5c(c4)oc4cc6ccccc6cc45)c4ccccc34)c2)cc1 ; c1ccc(-c2ccc(-c3c4ccccc4c(-c4ccc5c(c4)oc4cc6ccccc6cc45)c4ccccc34)cc2)cc1]

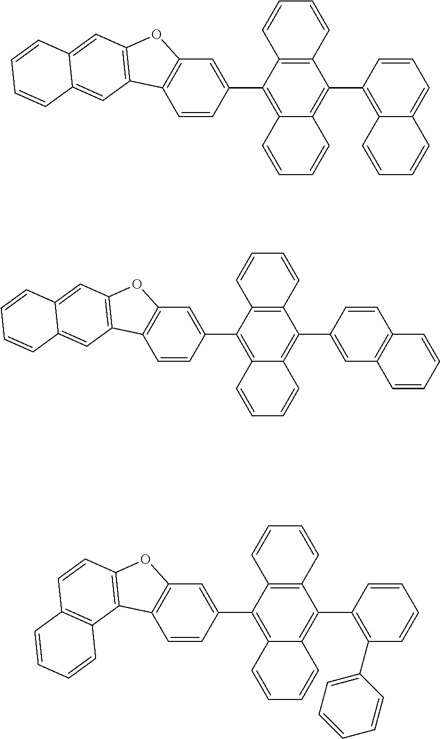 [SMILES: c1ccc2cc3c(cc2c1)oc1cc(-c2c4ccccc4c(-c4cccc5ccccc45)c4ccccc24)ccc13 ; c1ccc2cc(-c3c4ccccc4c(-c4ccc5c(c4)oc4cc6ccccc6cc45)c4ccccc34)ccc2c1 ; c1ccc(-c2ccccc2-c2c3ccccc3c(-c3ccc4c(c3)oc3ccc5ccccc5c34)c3ccccc23)cc1]

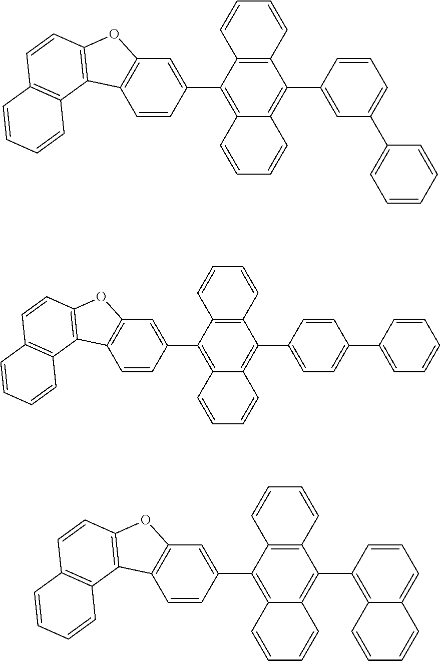 [SMILES: c1ccc(-c2cccc(-c3c4ccccc4c(-c4ccc5c(c4)oc4ccc6ccccc6c45)c4ccccc34)c2)cc1 ; c1ccc(-c2ccc(-c3c4ccccc4c(-c4ccc5c(c4)oc4ccc6ccccc6c45)c4ccccc34)cc2)cc1 ; c1ccc2c(-c3c4ccccc4c(-c4ccc5c(c4)oc4ccc6ccccc6c45)c4ccccc34)cccc2c1]

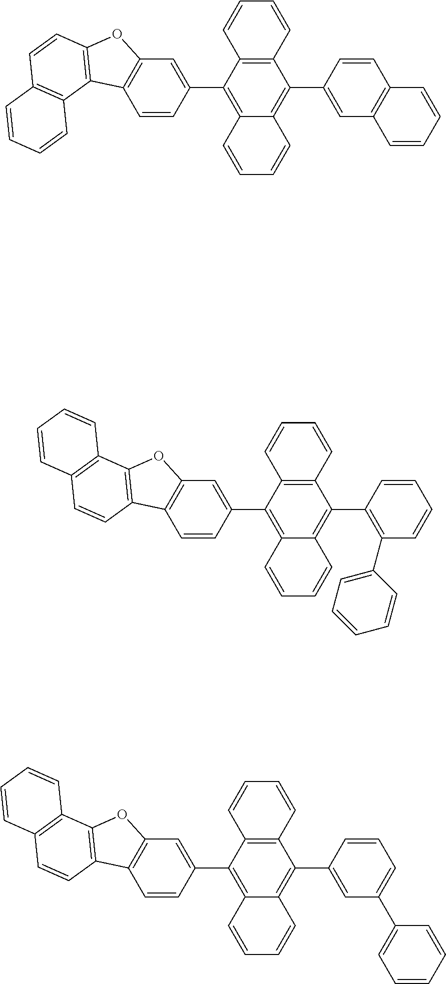 [SMILES: c1ccc2cc(-c3c4ccccc4c(-c4ccc5c(c4)oc4ccc6ccccc6c45)c4ccccc34)ccc2c1 ; c1ccc(-c2ccccc2-c2c3ccccc3c(-c3ccc4c(c3)oc3c5ccccc5ccc43)c3ccccc23)cc1 ; c1ccc(-c2cccc(-c3c4ccccc4c(-c4ccc5c(c4)oc4c6ccccc6ccc54)c4ccccc34)c2)cc1]

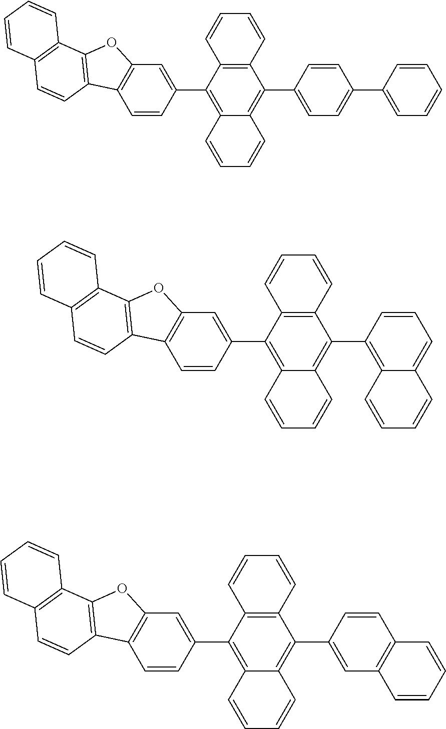 [SMILES: c1ccc(-c2ccc(-c3c4ccccc4c(-c4ccc5c(c4)oc4c6ccccc6ccc54)c4ccccc34)cc2)cc1 ; c1ccc2c(-c3c4ccccc4c(-c4ccc5c(c4)oc4c6ccccc6ccc54)c4ccccc34)cccc2c1 ; c1ccc2cc(-c3c4ccccc4c(-c4ccc5c(c4)oc4c6ccccc6ccc54)c4ccccc34)ccc2c1]

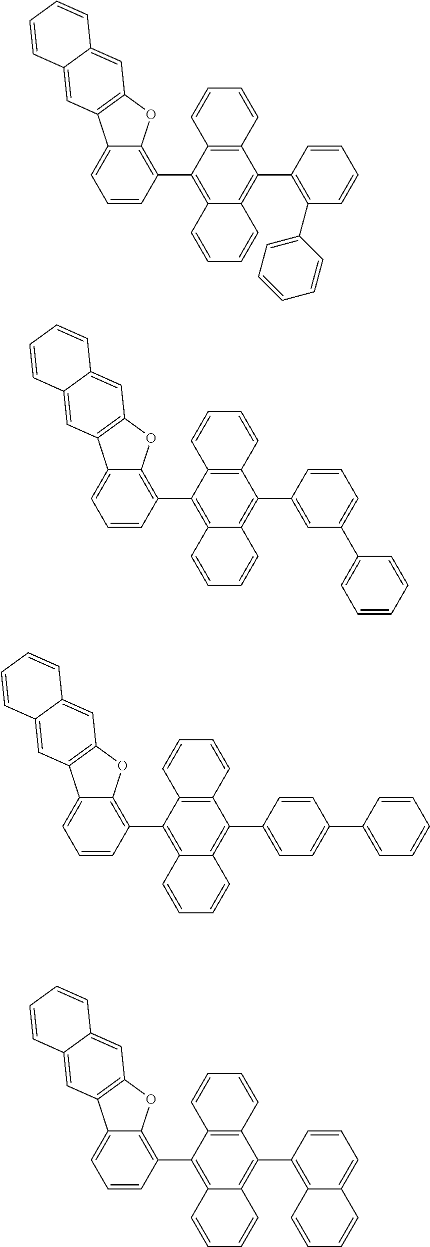 [SMILES: c1ccc(-c2ccccc2-c2c3ccccc3c(-c3cccc4c3oc3cc5ccccc5cc34)c3ccccc23)cc1 ; c1ccc(-c2cccc(-c3c4ccccc4c(-c4cccc5c4oc4cc6ccccc6cc45)c4ccccc34)c2)cc1 ; c1ccc(-c2ccc(-c3c4ccccc4c(-c4cccc5c4oc4cc6ccccc6cc45)c4ccccc34)cc2)cc1 ; c1ccc2cc3c(cc2c1)oc1c(-c2c4ccccc4c(-c4cccc5ccccc45)c4ccccc24)cccc13]

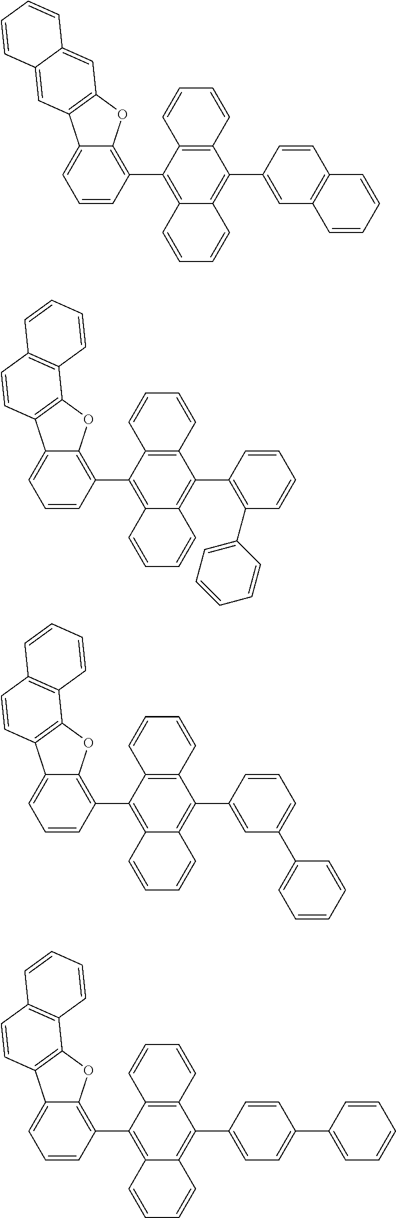 [SMILES: c1ccc2cc(-c3c4ccccc4c(-c4cccc5c4oc4cc6ccccc6cc45)c4ccccc34)ccc2c1 ; c1ccc(-c2ccccc2-c2c3ccccc3c(-c3cccc4c3oc3c5ccccc5ccc43)c3ccccc23)cc1 ; c1ccc(-c2cccc(-c3c4ccccc4c(-c4cccc5c4oc4c6ccccc6ccc54)c4ccccc34)c2)cc1 ; c1ccc(-c2ccc(-c3c4ccccc4c(-c4cccc5c4oc4c6ccccc6ccc54)c4ccccc34)cc2)cc1]

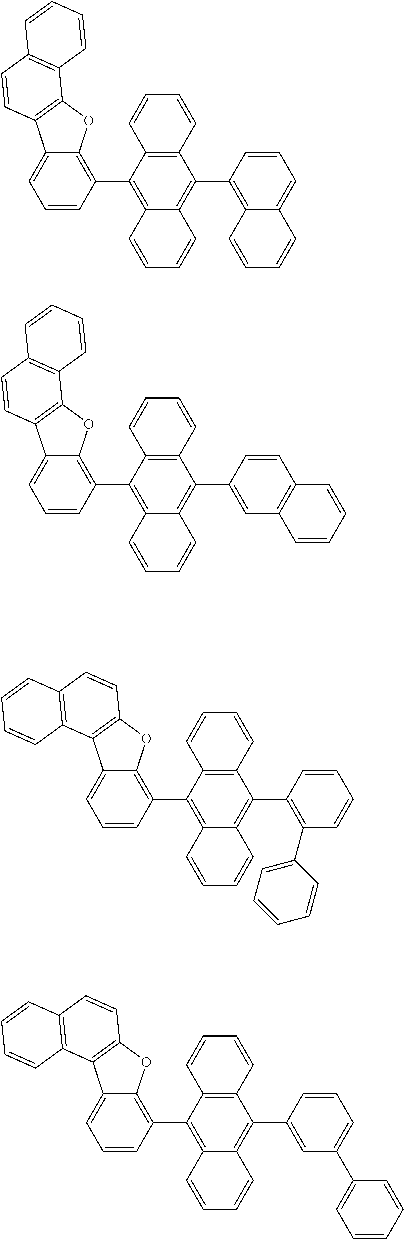 [SMILES: c1ccc2c(-c3c4ccccc4c(-c4cccc5c4oc4c6ccccc6ccc54)c4ccccc34)cccc2c1 ; c1ccc2cc(-c3c4ccccc4c(-c4cccc5c4oc4c6ccccc6ccc54)c4ccccc34)ccc2c1 ; c1ccc(-c2ccccc2-c2c3ccccc3c(-c3cccc4c3oc3ccc5ccccc5c34)c3ccccc23)cc1 ; c1ccc(-c2cccc(-c3c4ccccc4c(-c4cccc5c4oc4ccc6ccccc6c45)c4ccccc34)c2)cc1]

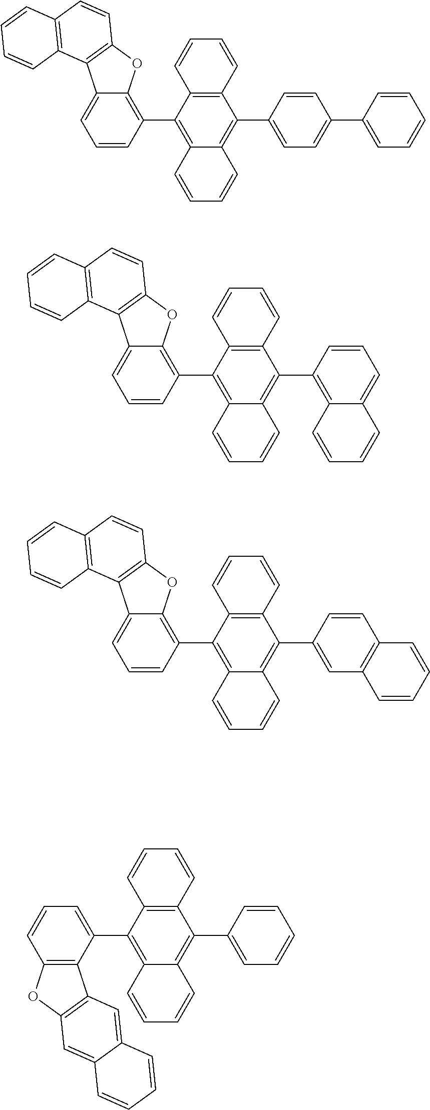 [SMILES: c1ccc(-c2ccc(-c3c4ccccc4c(-c4cccc5c4oc4ccc6ccccc6c45)c4ccccc34)cc2)cc1 ; c1ccc2c(-c3c4ccccc4c(-c4cccc5c4oc4ccc6ccccc6c45)c4ccccc34)cccc2c1 ; c1ccc2cc(-c3c4ccccc4c(-c4cccc5c4oc4ccc6ccccc6c45)c4ccccc34)ccc2c1 ; c1ccc(-c2c3ccccc3c(-c3cccc4oc5cc6ccccc6cc5c34)c3ccccc23)cc1]

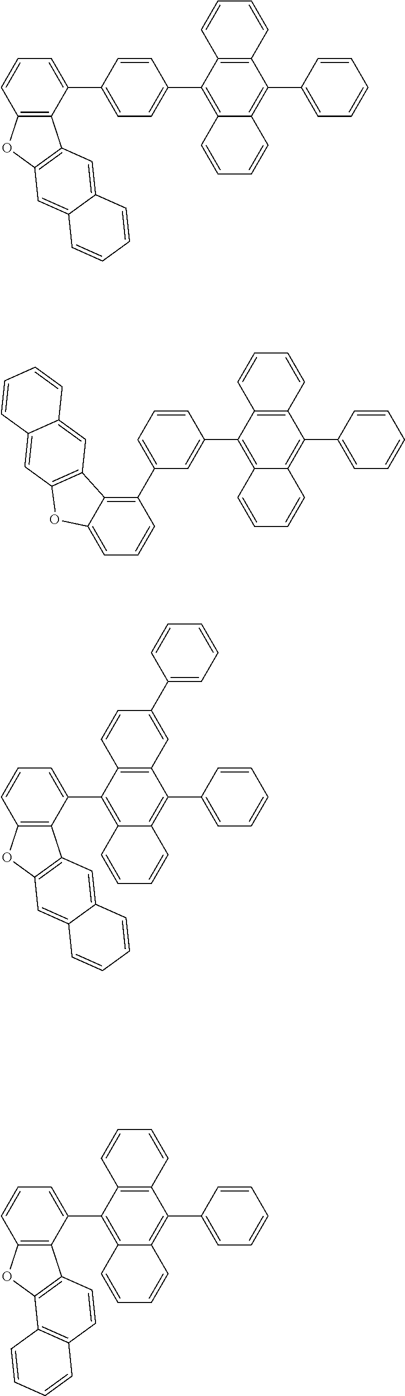 [SMILES: c1ccc(-c2c3ccccc3c(-c3ccc(-c4cccc5oc6cc7ccccc7cc6c45)cc3)c3ccccc23)cc1 ; c1ccc(-c2c3ccccc3c(-c3cccc(-c4cccc5oc6cc7ccccc7cc6c45)c3)c3ccccc23)cc1 ; c1ccc(-c2ccc3c(-c4cccc5oc6cc7ccccc7cc6c45)c4ccccc4c(-c4ccccc4)c3c2)cc1 ; c1ccc(-c2c3ccccc3c(-c3cccc4oc5c6ccccc6ccc5c34)c3ccccc23)cc1]

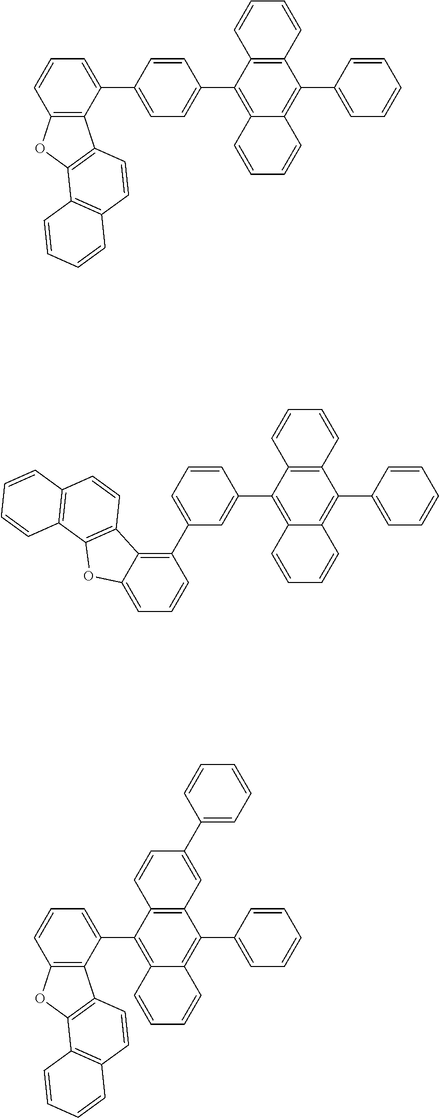 [SMILES: c1ccc(-c2c3ccccc3c(-c3ccc(-c4cccc5oc6c7ccccc7ccc6c45)cc3)c3ccccc23)cc1 ; c1ccc(-c2c3ccccc3c(-c3cccc(-c4cccc5oc6c7ccccc7ccc6c45)c3)c3ccccc23)cc1 ; c1ccc(-c2ccc3c(-c4cccc5oc6c7ccccc7ccc6c45)c4ccccc4c(-c4ccccc4)c3c2)cc1]

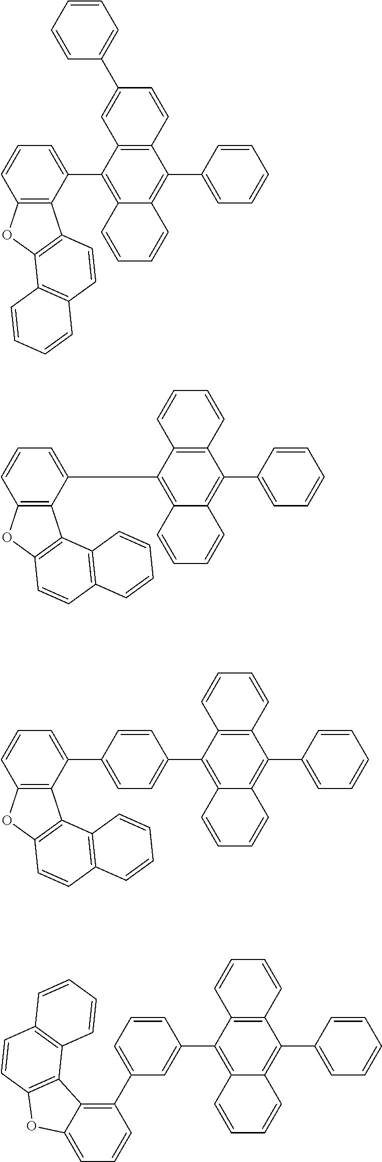 [SMILES: c1ccc(-c2ccc3c(-c4ccccc4)c4ccccc4c(-c4cccc5oc6c7ccccc7ccc6c45)c3c2)cc1 ; c1ccc(-c2c3ccccc3c(-c3cccc4oc5ccc6ccccc6c5c34)c3ccccc23)cc1 ; c1ccc(-c2c3ccccc3c(-c3ccc(-c4cccc5oc6ccc7ccccc7c6c45)cc3)c3ccccc23)cc1 ; c1ccc(-c2c3ccccc3c(-c3cccc(-c4cccc5oc6ccc7ccccc7c6c45)c3)c3ccccc23)cc1]

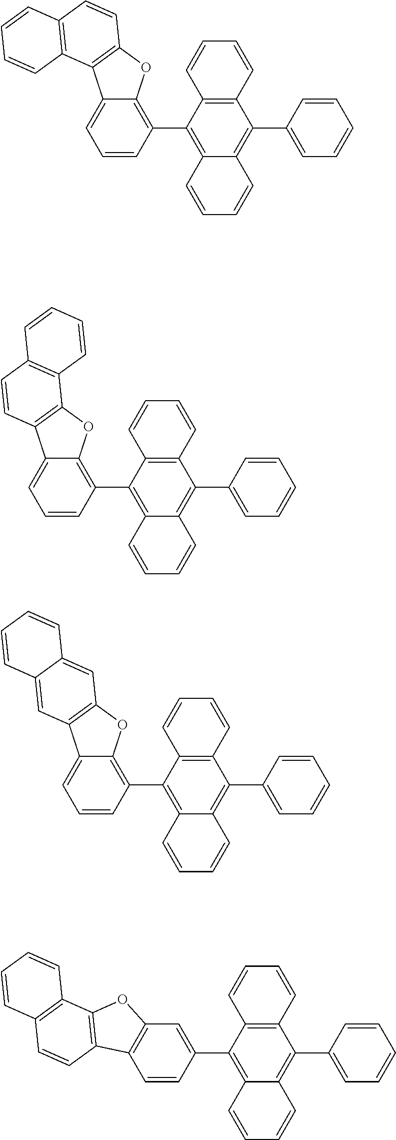 [SMILES: c1ccc(-c2c3ccccc3c(-c3cccc4c3oc3ccc5ccccc5c34)c3ccccc23)cc1 ; c1ccc(-c2c3ccccc3c(-c3cccc4c3oc3c5ccccc5ccc43)c3ccccc23)cc1 ; c1ccc(-c2c3ccccc3c(-c3cccc4c3oc3cc5ccccc5cc34)c3ccccc23)cc1 ; c1ccc(-c2c3ccccc3c(-c3ccc4c(c3)oc3c5ccccc5ccc43)c3ccccc23)cc1]

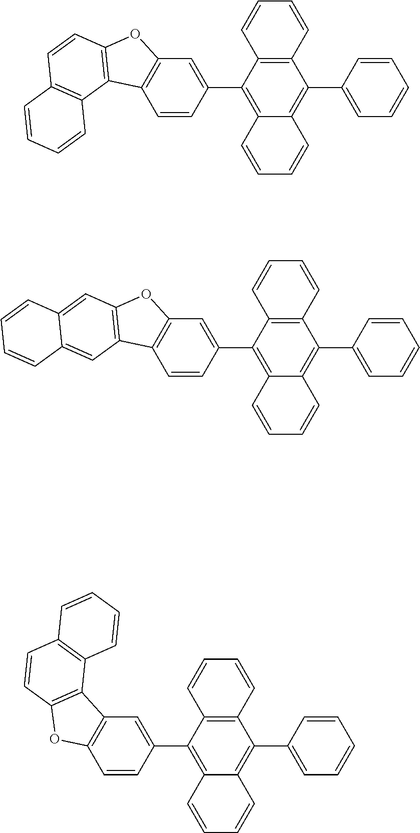 [SMILES: c1ccc(-c2c3ccccc3c(-c3ccc4c(c3)oc3ccc5ccccc5c34)c3ccccc23)cc1 ; c1ccc(-c2c3ccccc3c(-c3ccc4c(c3)oc3cc5ccccc5cc34)c3ccccc23)cc1 ; c1ccc(-c2c3ccccc3c(-c3ccc4oc5ccc6ccccc6c5c4c3)c3ccccc23)cc1]

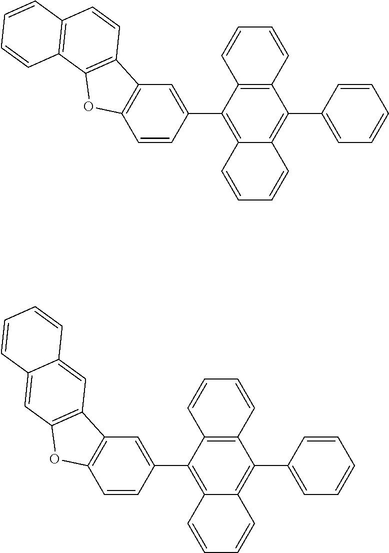 [SMILES: c1ccc(-c2c3ccccc3c(-c3ccc4oc5c6ccccc6ccc5c4c3)c3ccccc23)cc1 ; c1ccc(-c2c3ccccc3c(-c3ccc4oc5cc6ccccc6cc5c4c3)c3ccccc23)cc1]

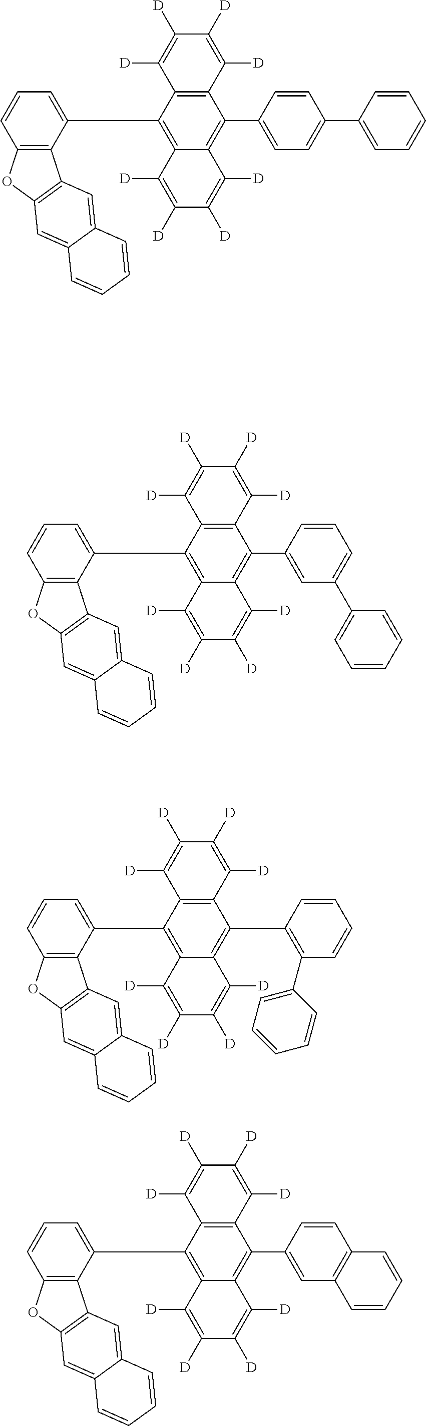 [SMILES: [2H]c1c([2H])c([2H])c2c(-c3cccc4oc5cc6ccccc6cc5c34)c3c([2H])c([2H])c([2H])c([2H])c3c(-c3ccc(-c4ccccc4)cc3)c2c1[2H] ; [2H]c1c([2H])c([2H])c2c(-c3cccc4oc5cc6ccccc6cc5c34)c3c([2H])c([2H])c([2H])c([2H])c3c(-c3cccc(-c4ccccc4)c3)c2c1[2H] ; [2H]c1c([2H])c([2H])c2c(-c3cccc4oc5cc6ccccc6cc5c34)c3c([2H])c([2H])c([2H])c([2H])c3c(-c3ccccc3-c3ccccc3)c2c1[2H] ; [2H]c1c([2H])c([2H])c2c(-c3cccc4oc5cc6ccccc6cc5c34)c3c([2H])c([2H])c([2H])c([2H])c3c(-c3ccc4ccccc4c3)c2c1[2H]]

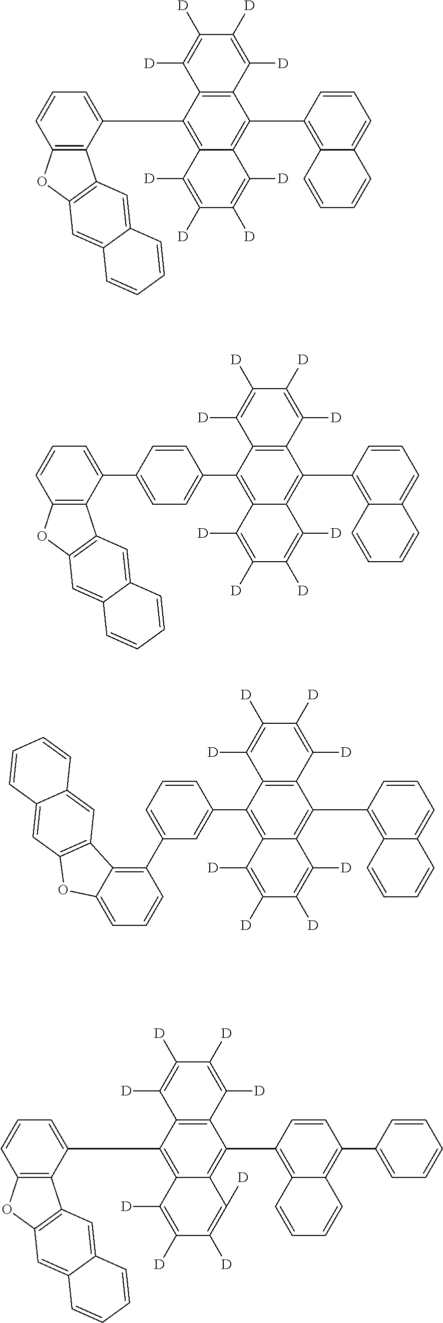 [SMILES: [2H]c1c([2H])c([2H])c2c(-c3cccc4oc5cc6ccccc6cc5c34)c3c([2H])c([2H])c([2H])c([2H])c3c(-c3cccc4ccccc34)c2c1[2H] ; [2H]c1c([2H])c([2H])c2c(-c3cccc4ccccc34)c3c([2H])c([2H])c([2H])c([2H])c3c(-c3ccc(-c4cccc5oc6cc7ccccc7cc6c45)cc3)c2c1[2H] ; [2H]c1c([2H])c([2H])c2c(-c3cccc4ccccc34)c3c([2H])c([2H])c([2H])c([2H])c3c(-c3cccc(-c4cccc5oc6cc7ccccc7cc6c45)c3)c2c1[2H] ; [2H]c1c([2H])c([2H])c2c(-c3cccc4oc5cc6ccccc6cc5c34)c3c([2H])c([2H])c([2H])c([2H])c3c(-c3ccc(-c4ccccc4)c4ccccc34)c2c1[2H]]

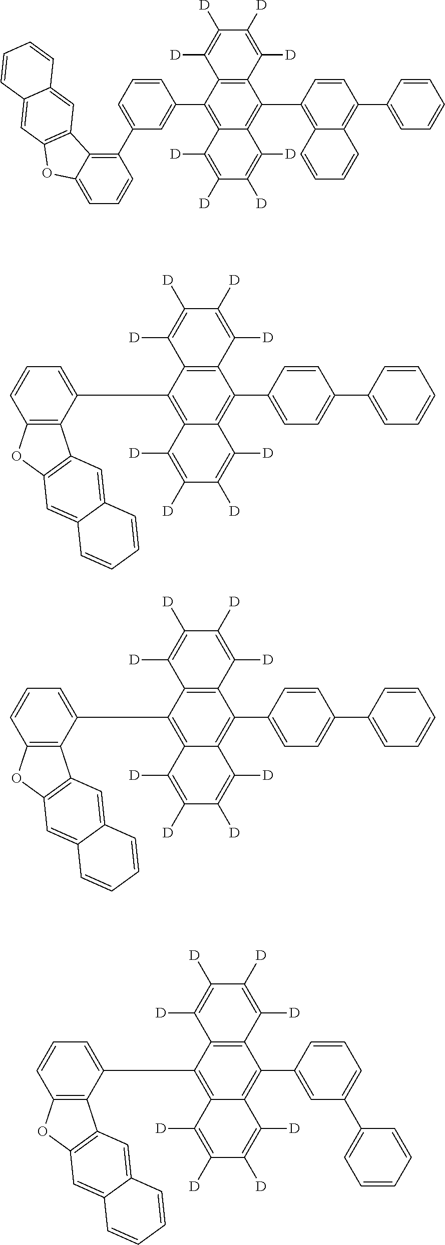 [SMILES: [2H]c1c([2H])c([2H])c2c(-c3ccc(-c4ccccc4)c4ccccc34)c3c([2H])c([2H])c([2H])c([2H])c3c(-c3cccc(-c4cccc5oc6cc7ccccc7cc6c45)c3)c2c1[2H] ; [2H]c1c([2H])c([2H])c2c(-c3cccc4oc5cc6ccccc6cc5c34)c3c([2H])c([2H])c([2H])c([2H])c3c(-c3ccc(-c4ccccc4)cc3)c2c1[2H] ; [2H]c1c([2H])c([2H])c2c(-c3cccc4oc5cc6ccccc6cc5c34)c3c([2H])c([2H])c([2H])c([2H])c3c(-c3ccc(-c4ccccc4)cc3)c2c1[2H] ; [2H]c1c([2H])c([2H])c2c(-c3cccc4oc5cc6ccccc6cc5c34)c3c([2H])c([2H])c([2H])c([2H])c3c(-c3cccc(-c4ccccc4)c3)c2c1[2H]]

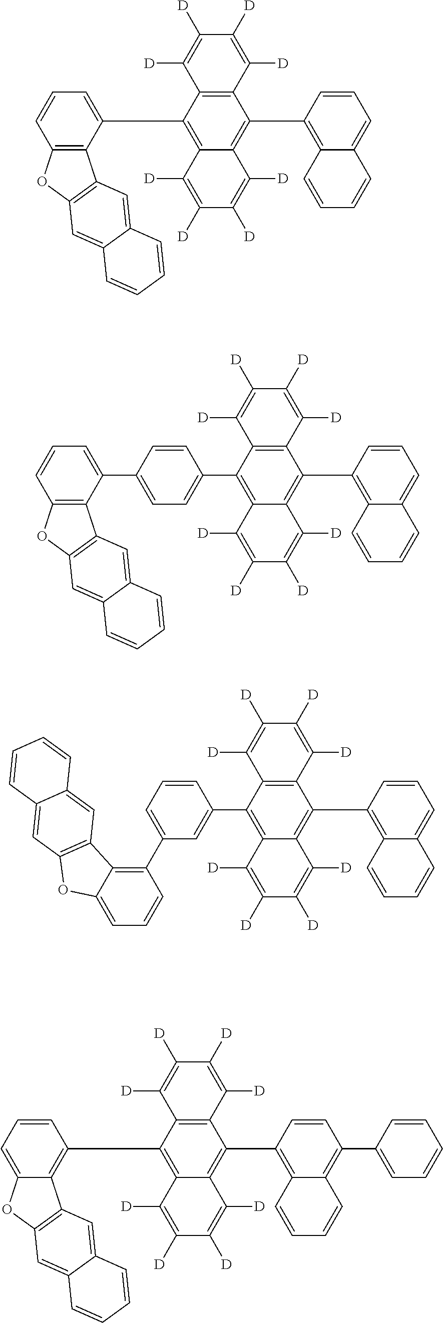 [SMILES: [2H]c1c([2H])c([2H])c2c(-c3cccc4oc5cc6ccccc6cc5c34)c3c([2H])c([2H])c([2H])c([2H])c3c(-c3cccc4ccccc34)c2c1[2H] ; [2H]c1c([2H])c([2H])c2c(-c3cccc4ccccc34)c3c([2H])c([2H])c([2H])c([2H])c3c(-c3ccc(-c4cccc5oc6cc7ccccc7cc6c45)cc3)c2c1[2H] ; [2H]c1c([2H])c([2H])c2c(-c3cccc4ccccc34)c3c([2H])c([2H])c([2H])c([2H])c3c(-c3cccc(-c4cccc5oc6cc7ccccc7cc6c45)c3)c2c1[2H] ; [2H]c1c([2H])c([2H])c2c(-c3cccc4oc5cc6ccccc6cc5c34)c3c([2H])c([2H])c([2H])c([2H])c3c(-c3ccc(-c4ccccc4)c4ccccc34)c2c1[2H]]

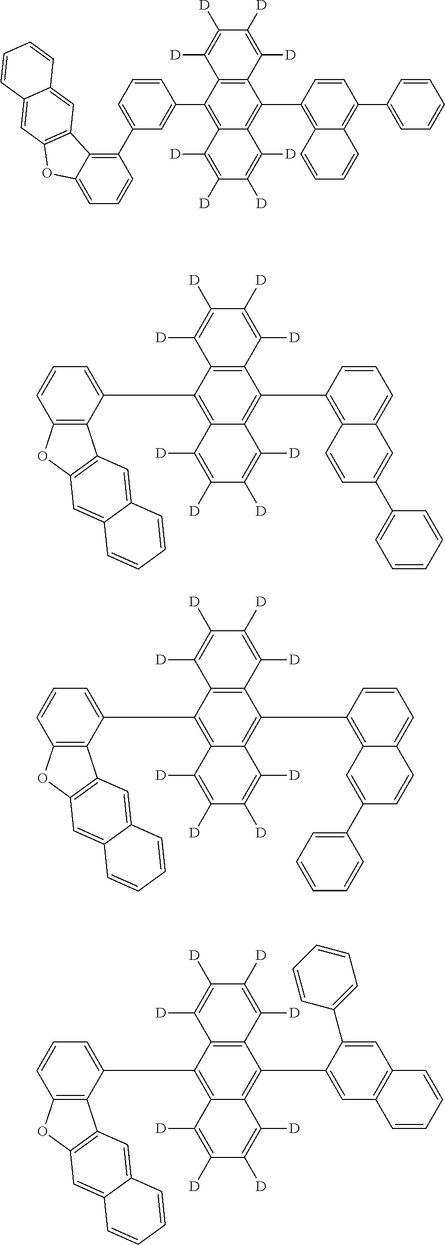 [SMILES: [2H]c1c([2H])c([2H])c2c(-c3ccc(-c4ccccc4)c4ccccc34)c3c([2H])c([2H])c([2H])c([2H])c3c(-c3cccc(-c4cccc5oc6cc7ccccc7cc6c45)c3)c2c1[2H] ; [2H]c1c([2H])c([2H])c2c(-c3cccc4oc5cc6ccccc6cc5c34)c3c([2H])c([2H])c([2H])c([2H])c3c(-c3cccc4cc(-c5ccccc5)ccc34)c2c1[2H] ; [2H]c1c([2H])c([2H])c2c(-c3cccc4oc5cc6ccccc6cc5c34)c3c([2H])c([2H])c([2H])c([2H])c3c(-c3cccc4ccc(-c5ccccc5)cc34)c2c1[2H] ; [2H]c1c([2H])c([2H])c2c(-c3cccc4oc5cc6ccccc6cc5c34)c3c([2H])c([2H])c([2H])c([2H])c3c(-c3cc4ccccc4cc3-c3ccccc3)c2c1[2H]]

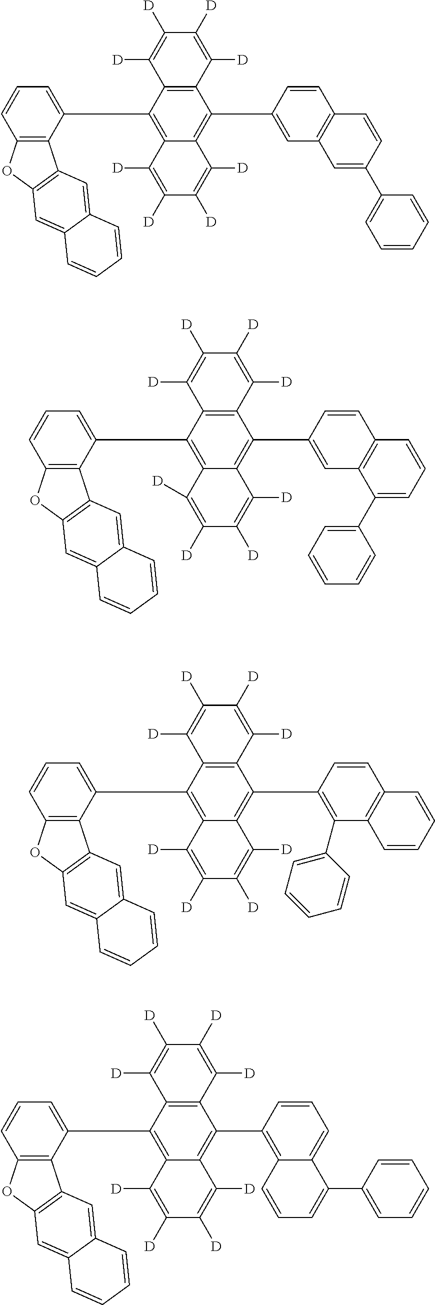 [SMILES: [2H]c1c([2H])c([2H])c2c(-c3cccc4oc5cc6ccccc6cc5c34)c3c([2H])c([2H])c([2H])c([2H])c3c(-c3ccc4ccc(-c5ccccc5)cc4c3)c2c1[2H] ; [2H]c1c([2H])c([2H])c2c(-c3cccc4oc5cc6ccccc6cc5c34)c3c([2H])c([2H])c([2H])c([2H])c3c(-c3ccc4cccc(-c5ccccc5)c4c3)c2c1[2H] ; [2H]c1c([2H])c([2H])c2c(-c3cccc4oc5cc6ccccc6cc5c34)c3c([2H])c([2H])c([2H])c([2H])c3c(-c3ccc4ccccc4c3-c3ccccc3)c2c1[2H] ; [2H]c1c([2H])c([2H])c2c(-c3cccc4oc5cc6ccccc6cc5c34)c3c([2H])c([2H])c([2H])c([2H])c3c(-c3cccc4c(-c5ccccc5)cccc34)c2c1[2H]]

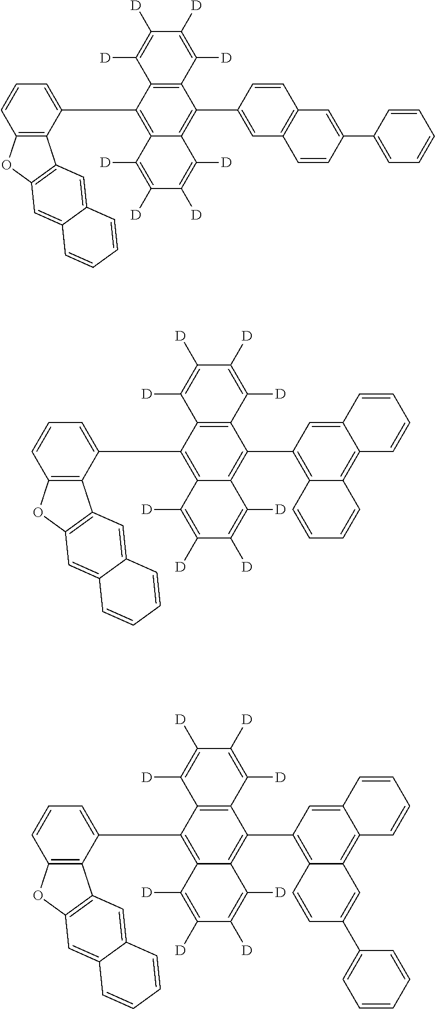 [SMILES: [2H]c1c([2H])c([2H])c2c(-c3cccc4oc5cc6ccccc6cc5c34)c3c([2H])c([2H])c([2H])c([2H])c3c(-c3ccc4cc(-c5ccccc5)ccc4c3)c2c1[2H] ; [2H]c1c([2H])c([2H])c2c(-c3cccc4oc5cc6ccccc6cc5c34)c3c([2H])c([2H])c([2H])c([2H])c3c(-c3cc4ccccc4c4ccccc34)c2c1[2H] ; [2H]c1c([2H])c([2H])c2c(-c3cccc4oc5cc6ccccc6cc5c34)c3c([2H])c([2H])c([2H])c([2H])c3c(-c3cc4ccccc4c4cc(-c5ccccc5)ccc34)c2c1[2H]]

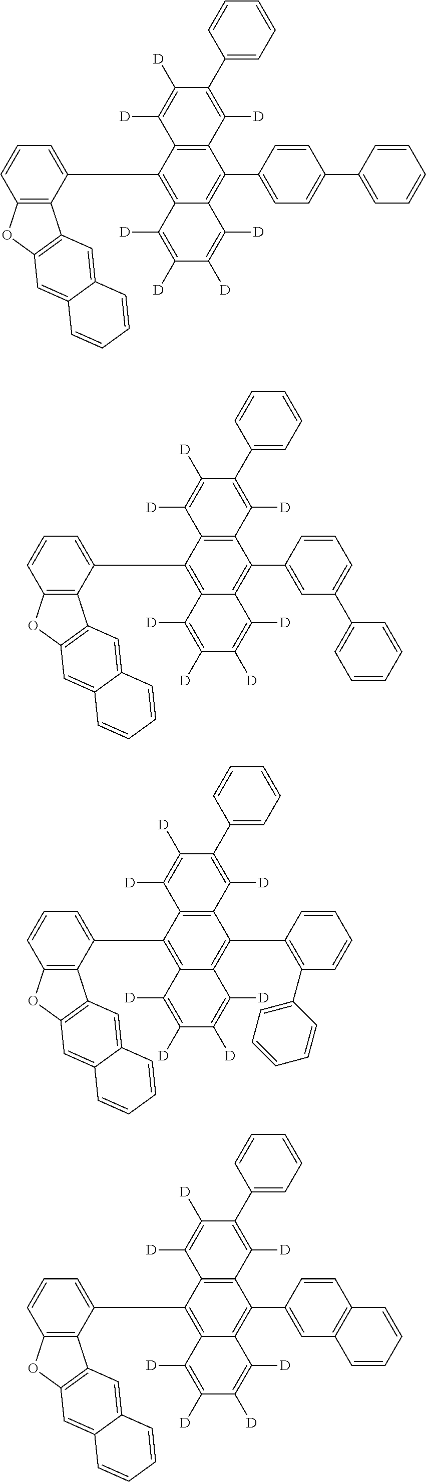 [SMILES: [2H]c1c([2H])c([2H])c2c(-c3cccc4oc5cc6ccccc6cc5c34)c3c([2H])c([2H])c(-c4ccccc4)c([2H])c3c(-c3ccc(-c4ccccc4)cc3)c2c1[2H] ; [2H]c1c([2H])c([2H])c2c(-c3cccc4oc5cc6ccccc6cc5c34)c3c([2H])c([2H])c(-c4ccccc4)c([2H])c3c(-c3cccc(-c4ccccc4)c3)c2c1[2H] ; [2H]c1c([2H])c([2H])c2c(-c3cccc4oc5cc6ccccc6cc5c34)c3c([2H])c([2H])c(-c4ccccc4)c([2H])c3c(-c3ccccc3-c3ccccc3)c2c1[2H] ; [2H]c1c([2H])c([2H])c2c(-c3cccc4oc5cc6ccccc6cc5c34)c3c([2H])c([2H])c(-c4ccccc4)c([2H])c3c(-c3ccc4ccccc4c3)c2c1[2H]]

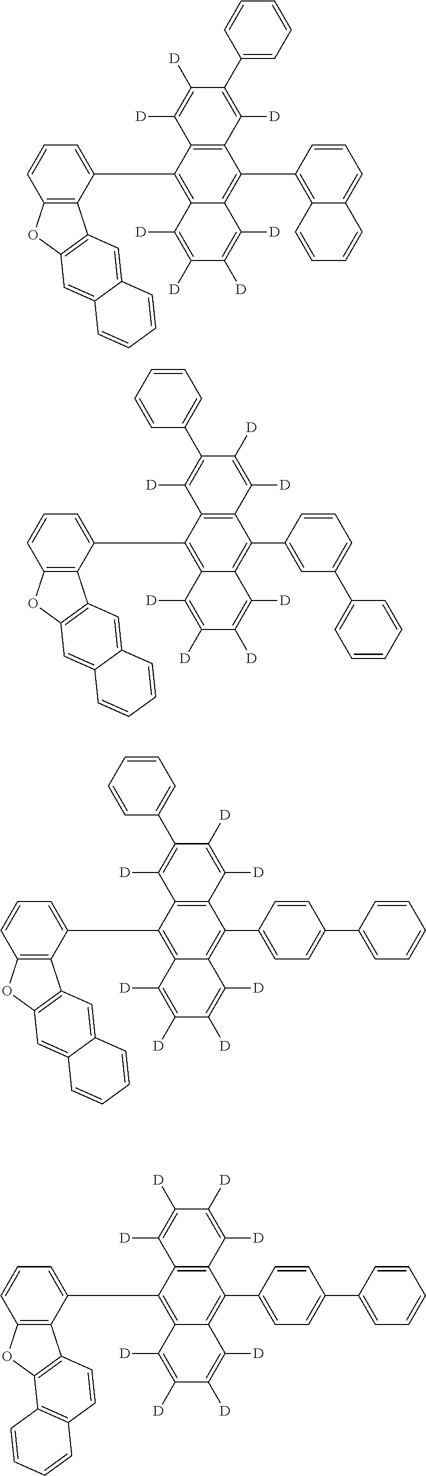

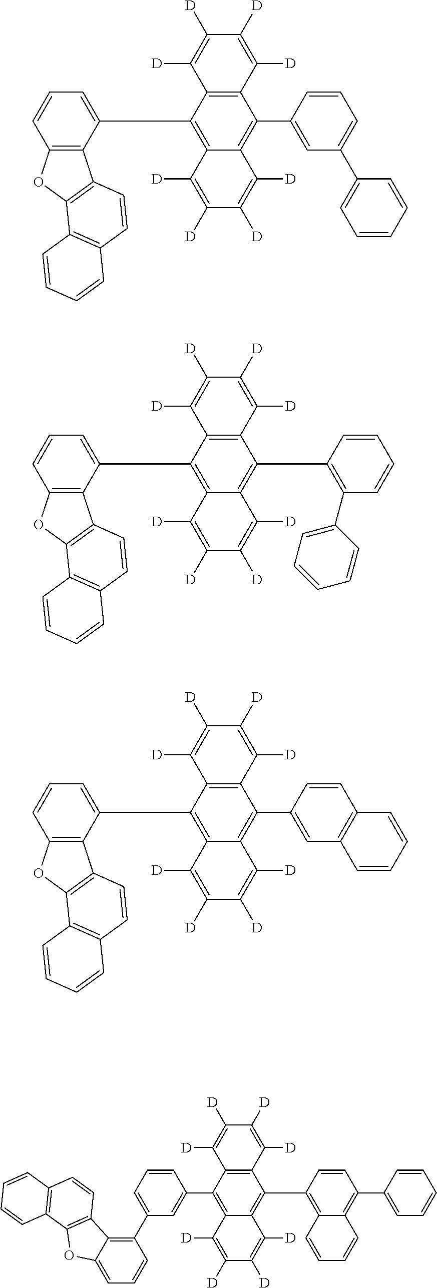 [SMILES: [2H]c1c([2H])c([2H])c2c(-c3cccc4oc5c6ccccc6ccc5c34)c3c([2H])c([2H])c([2H])c([2H])c3c(-c3cccc(-c4ccccc4)c3)c2c1[2H] ; [2H]c1c([2H])c([2H])c2c(-c3cccc4oc5c6ccccc6ccc5c34)c3c([2H])c([2H])c([2H])c([2H])c3c(-c3ccccc3-c3ccccc3)c2c1[2H] ; [2H]c1c([2H])c([2H])c2c(-c3cccc4oc5c6ccccc6ccc5c34)c3c([2H])c([2H])c([2H])c([2H])c3c(-c3ccc4ccccc4c3)c2c1[2H] ; [2H]c1c([2H])c([2H])c2c(-c3ccc(-c4ccccc4)c4ccccc34)c3c([2H])c([2H])c([2H])c([2H])c3c(-c3cccc(-c4cccc5oc6c7ccccc7ccc6c45)c3)c2c1[2H]]

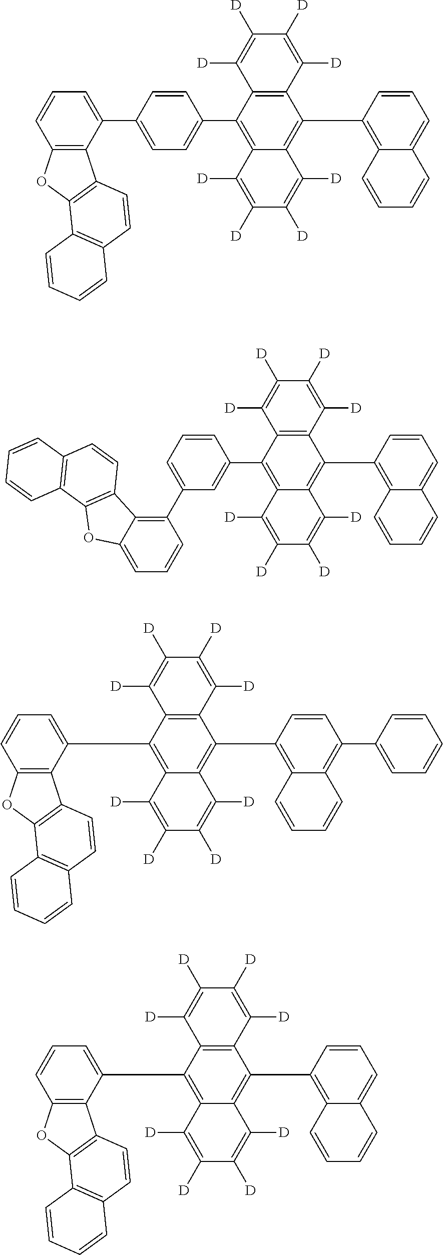 [SMILES: [2H]c1c([2H])c([2H])c2c(-c3cccc4ccccc34)c3c([2H])c([2H])c([2H])c([2H])c3c(-c3ccc(-c4cccc5oc6c7ccccc7ccc6c45)cc3)c2c1[2H] ; [2H]c1c([2H])c([2H])c2c(-c3cccc4ccccc34)c3c([2H])c([2H])c([2H])c([2H])c3c(-c3cccc(-c4cccc5oc6c7ccccc7ccc6c45)c3)c2c1[2H] ; [2H]c1c([2H])c([2H])c2c(-c3cccc4oc5c6ccccc6ccc5c34)c3c([2H])c([2H])c([2H])c([2H])c3c(-c3ccc(-c4ccccc4)c4ccccc34)c2c1[2H] ; [2H]c1c([2H])c([2H])c2c(-c3cccc4oc5c6ccccc6ccc5c34)c3c([2H])c([2H])c([2H])c([2H])c3c(-c3cccc4ccccc34)c2c1[2H]]

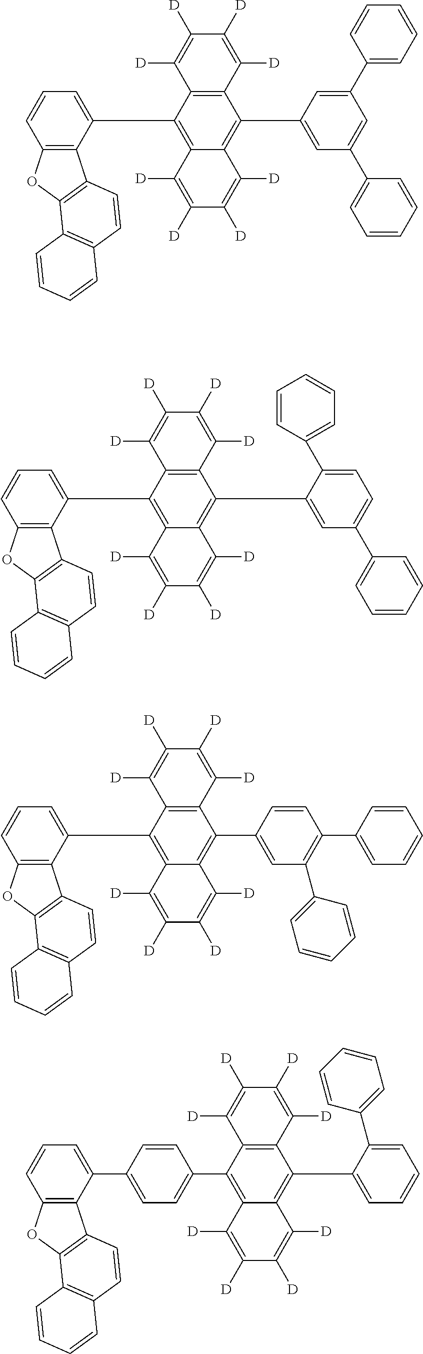

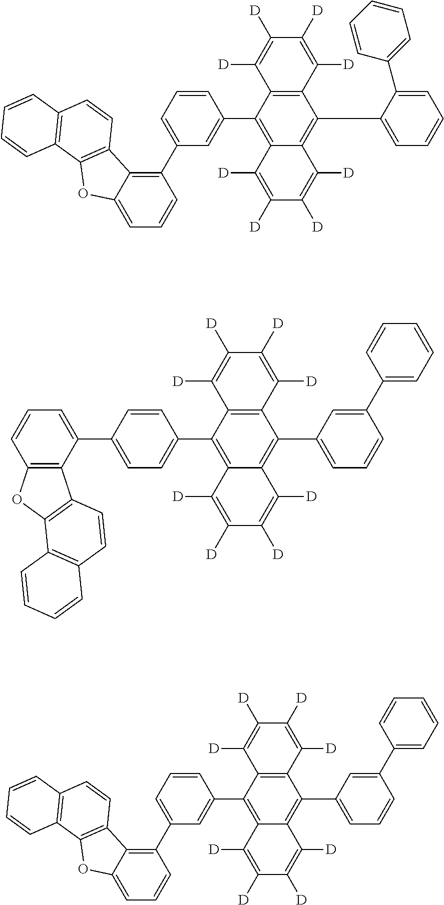 [SMILES: [2H]c1c([2H])c([2H])c2c(-c3ccccc3-c3ccccc3)c3c([2H])c([2H])c([2H])c([2H])c3c(-c3cccc(-c4cccc5oc6c7ccccc7ccc6c45)c3)c2c1[2H] ; [2H]c1c([2H])c([2H])c2c(-c3cccc(-c4ccccc4)c3)c3c([2H])c([2H])c([2H])c([2H])c3c(-c3ccc(-c4cccc5oc6c7ccccc7ccc6c45)cc3)c2c1[2H] ; [2H]c1c([2H])c([2H])c2c(-c3cccc(-c4cccc5oc6c7ccccc7ccc6c45)c3)c3c([2H])c([2H])c([2H])c([2H])c3c(-c3cccc(-c4ccccc4)c3)c2c1[2H]]

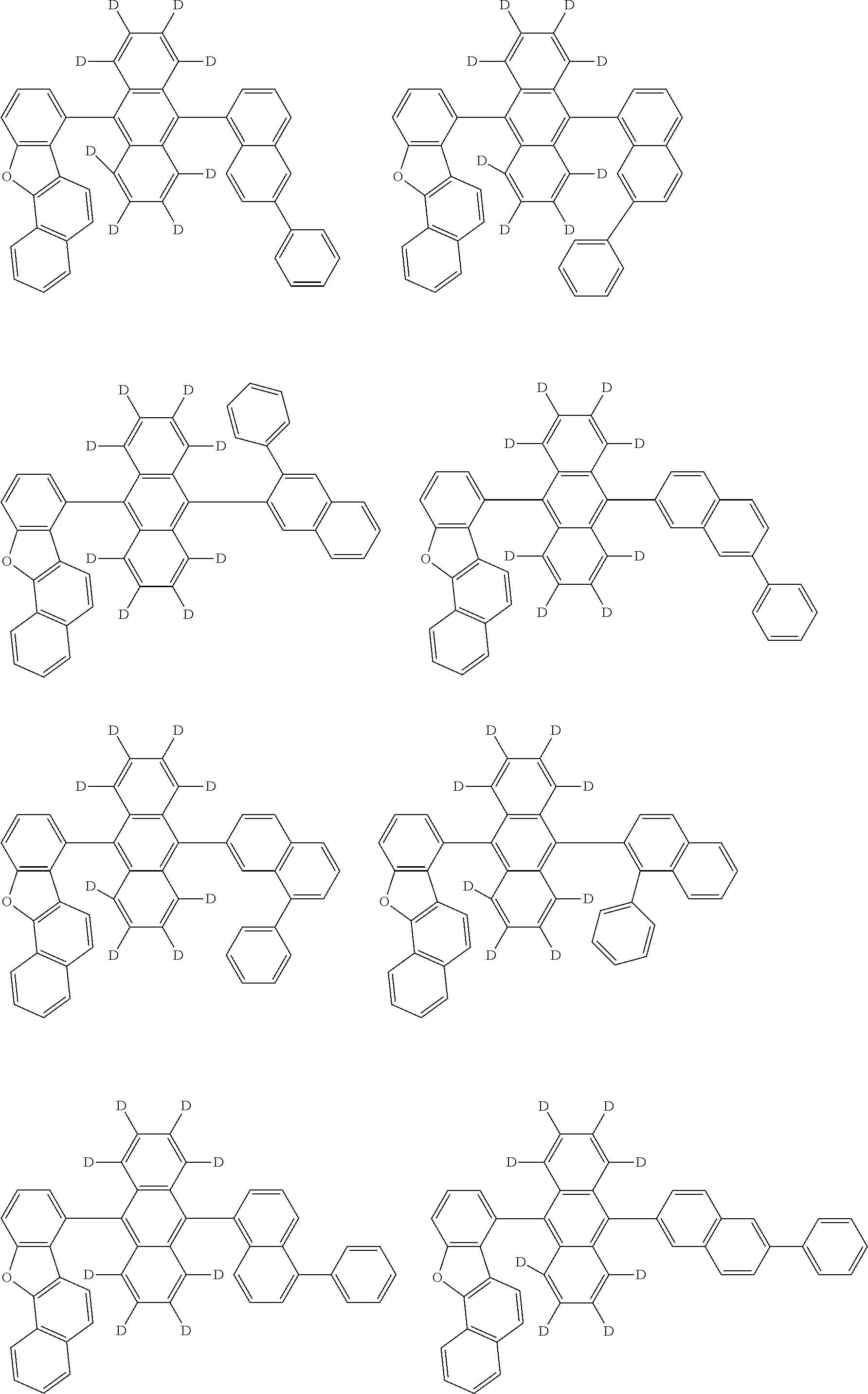

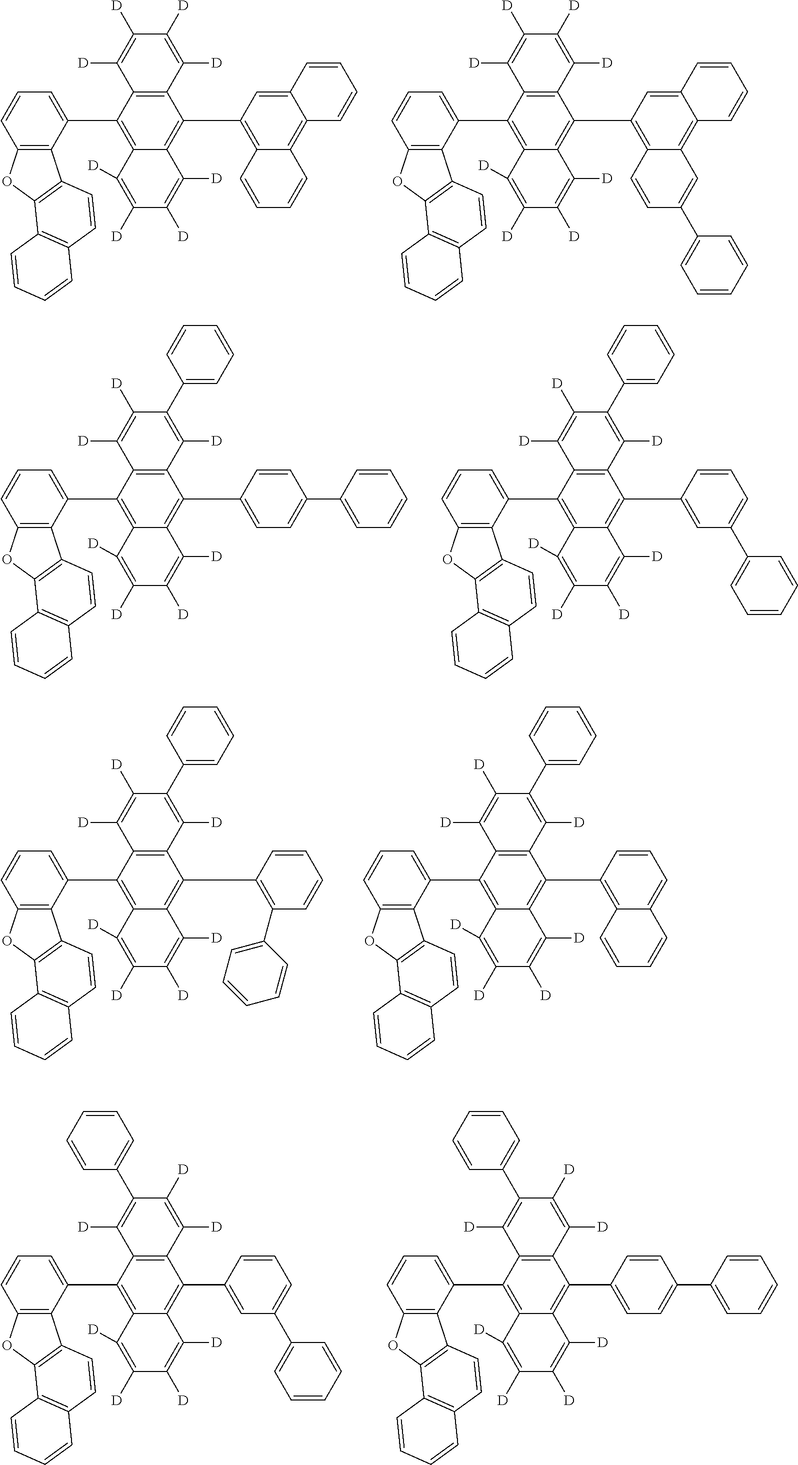

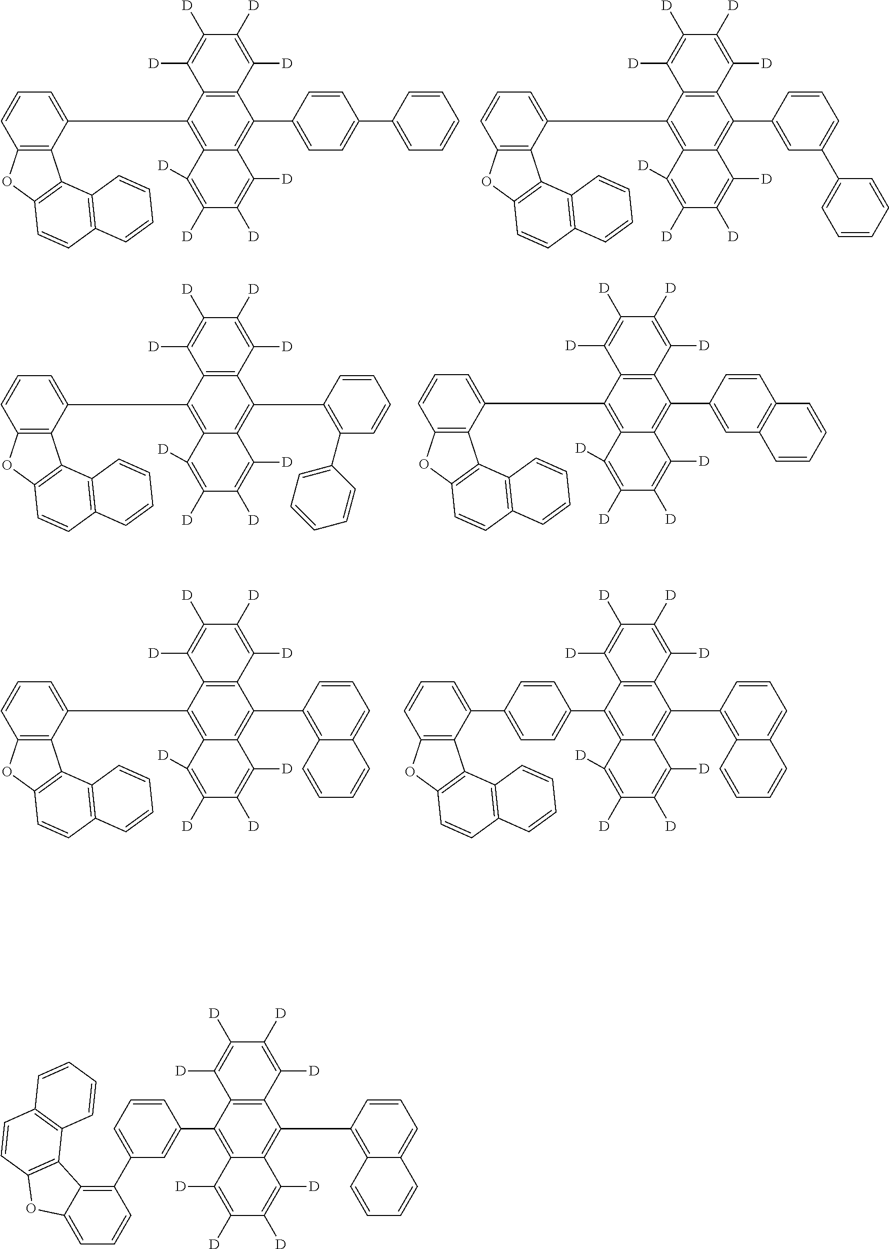

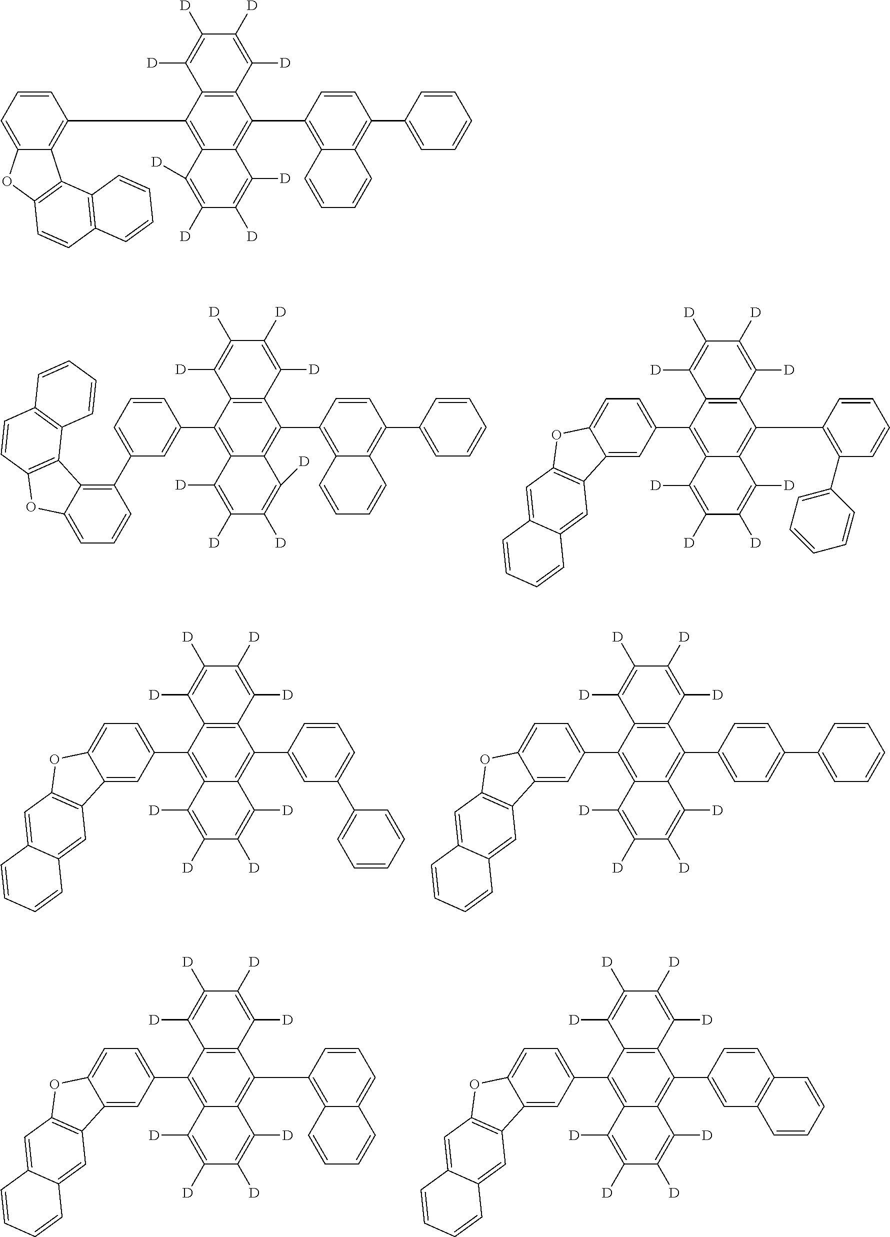

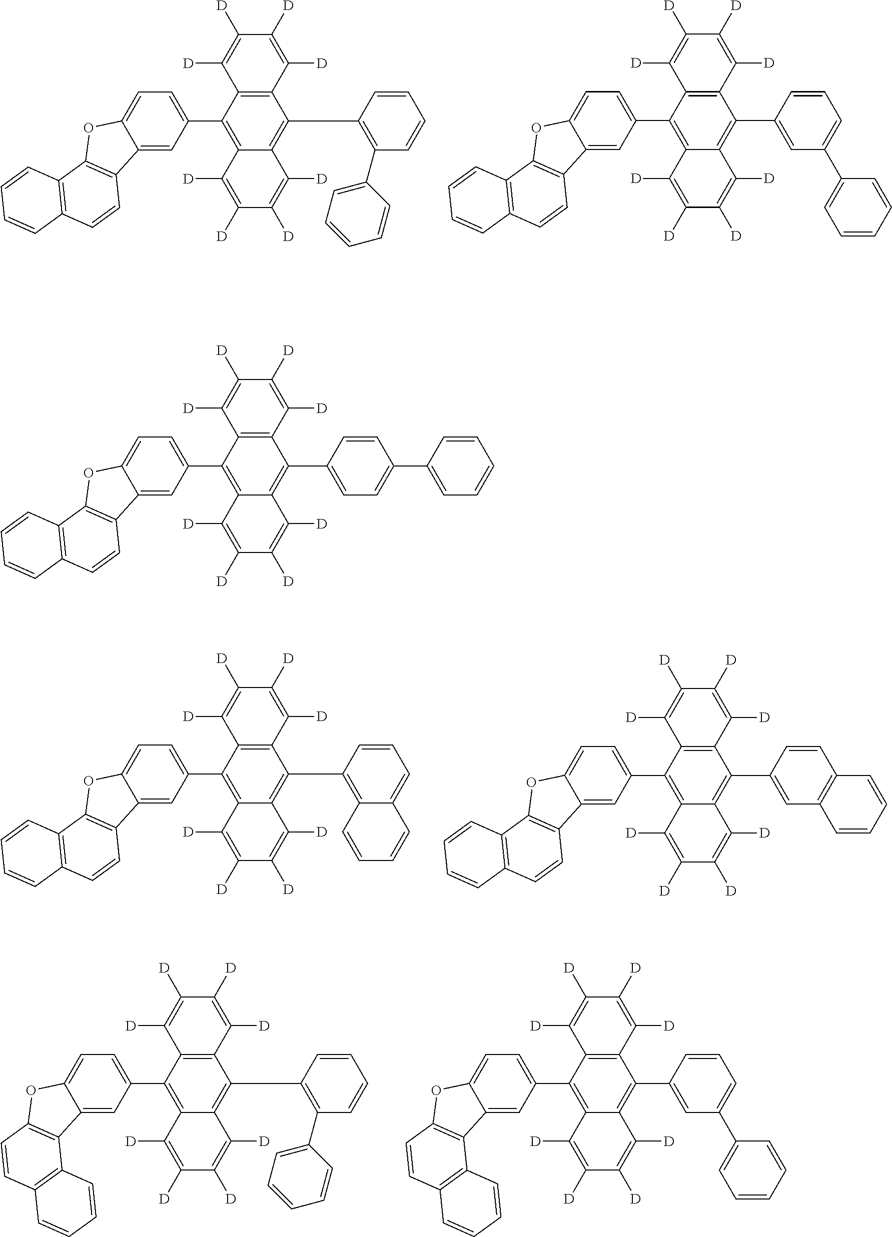

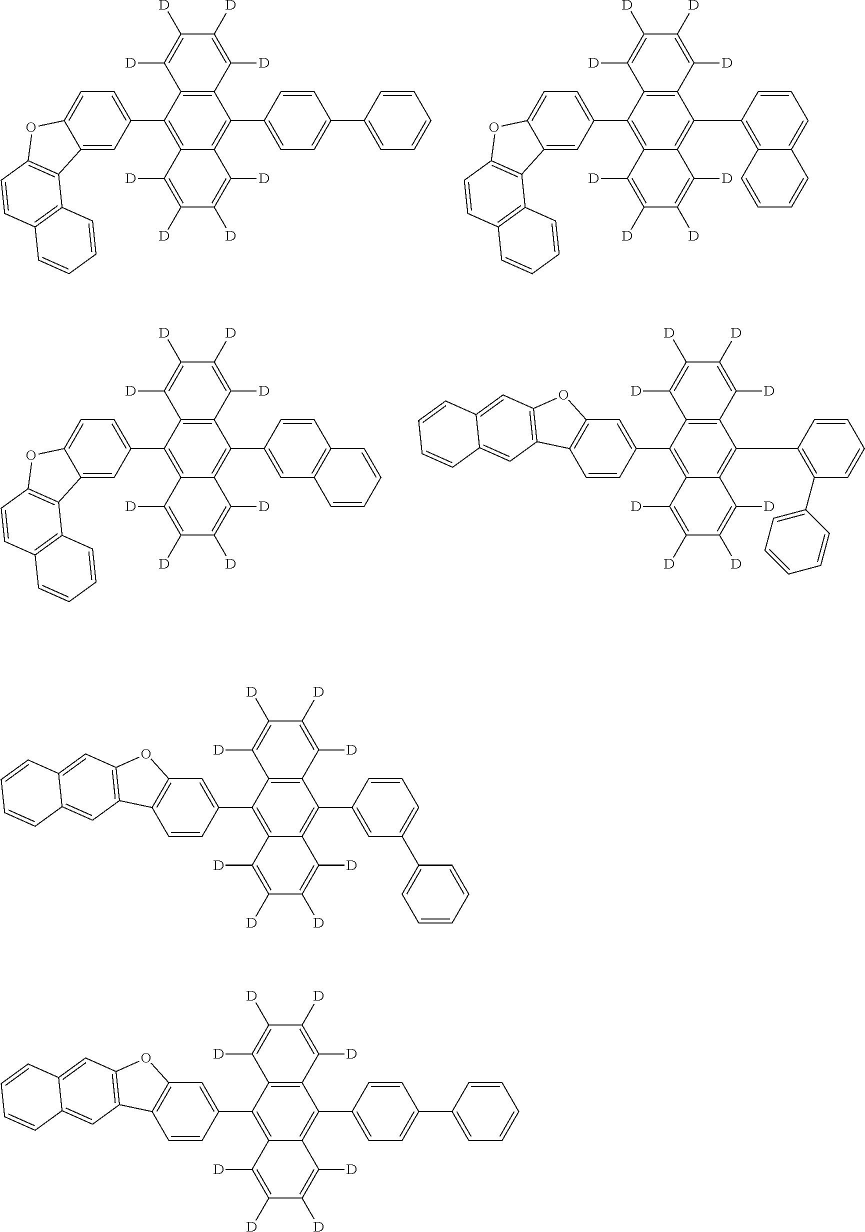

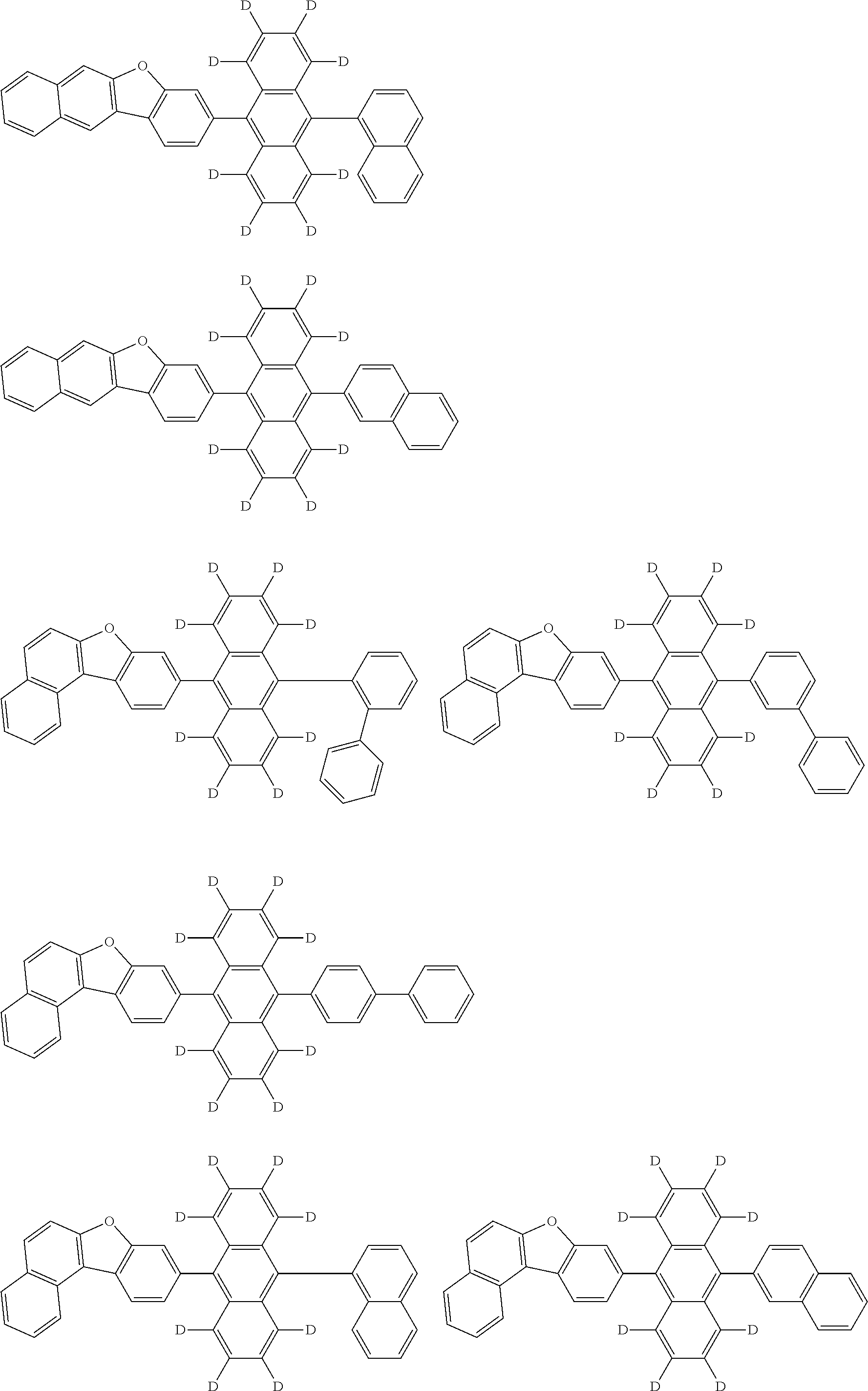

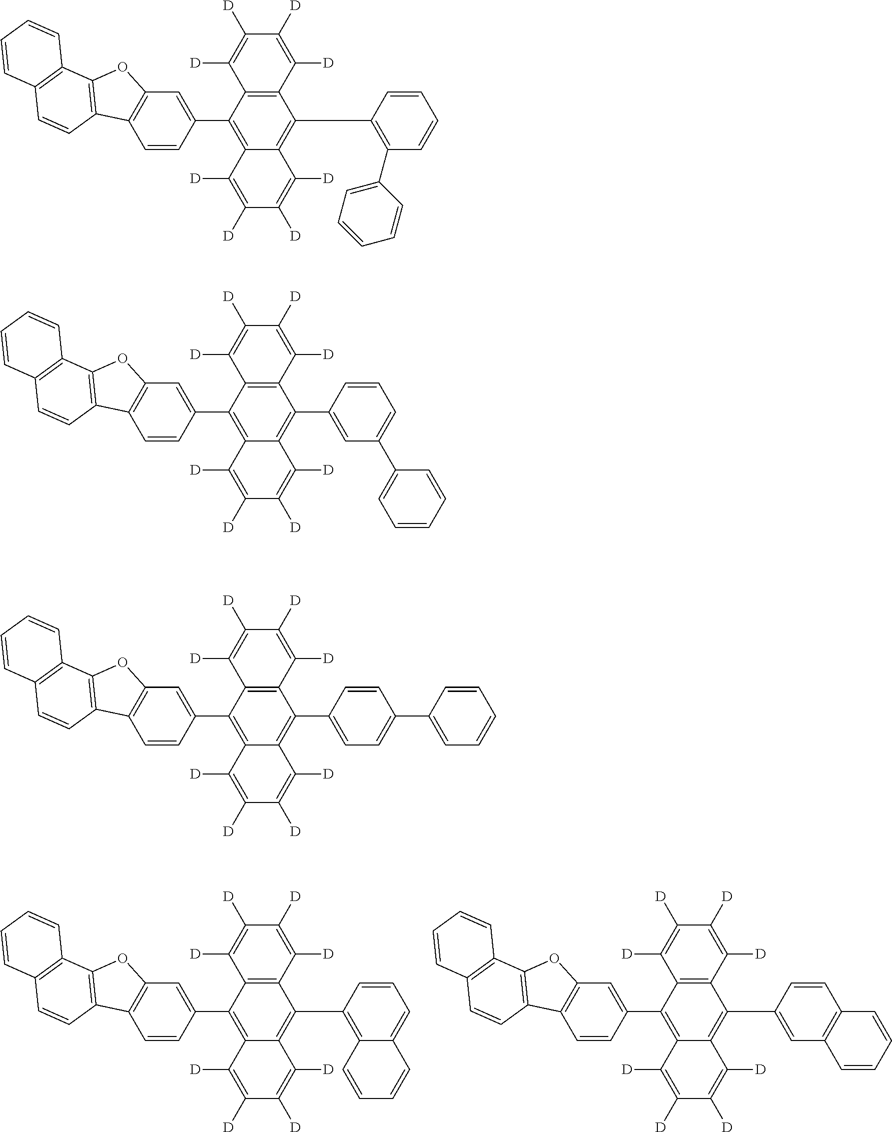

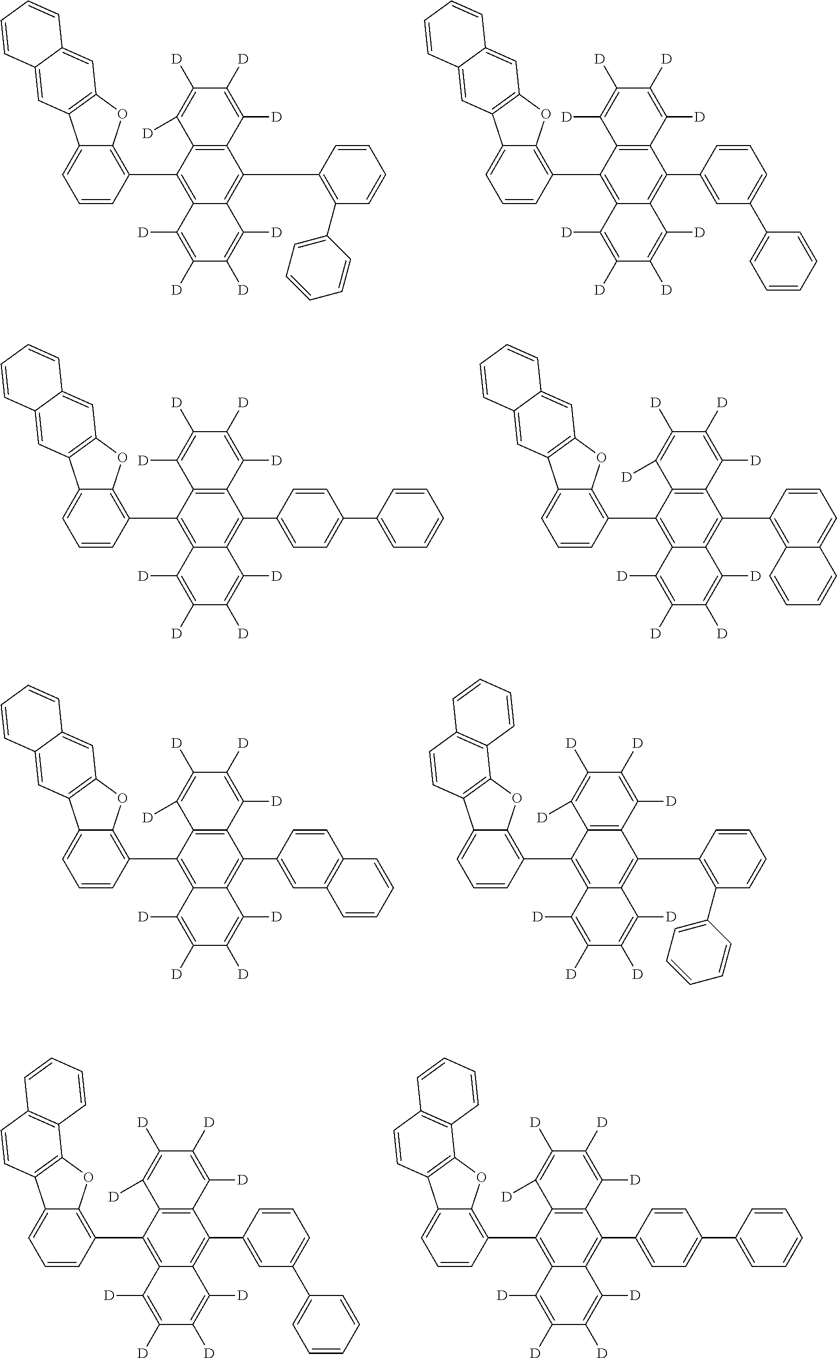

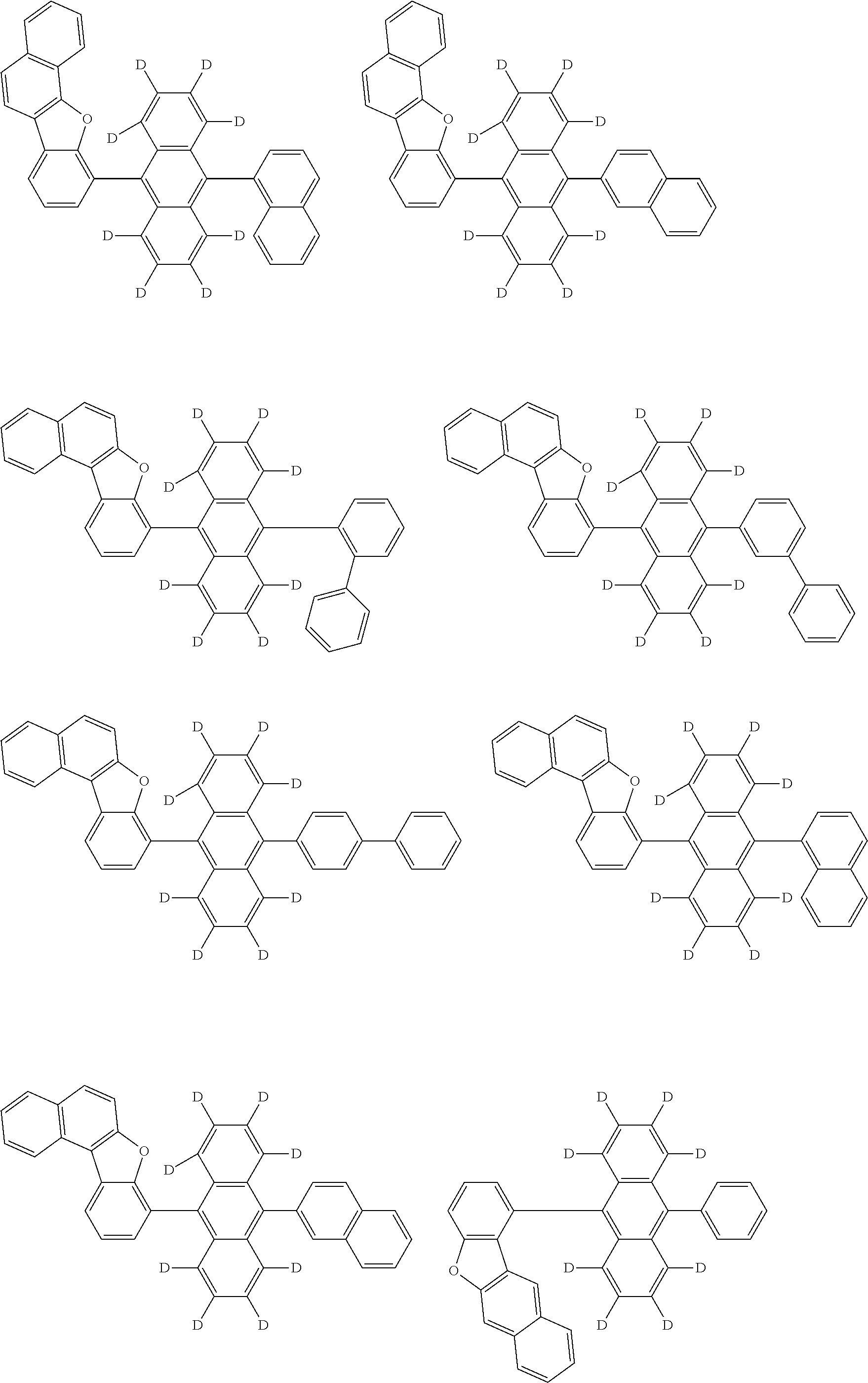

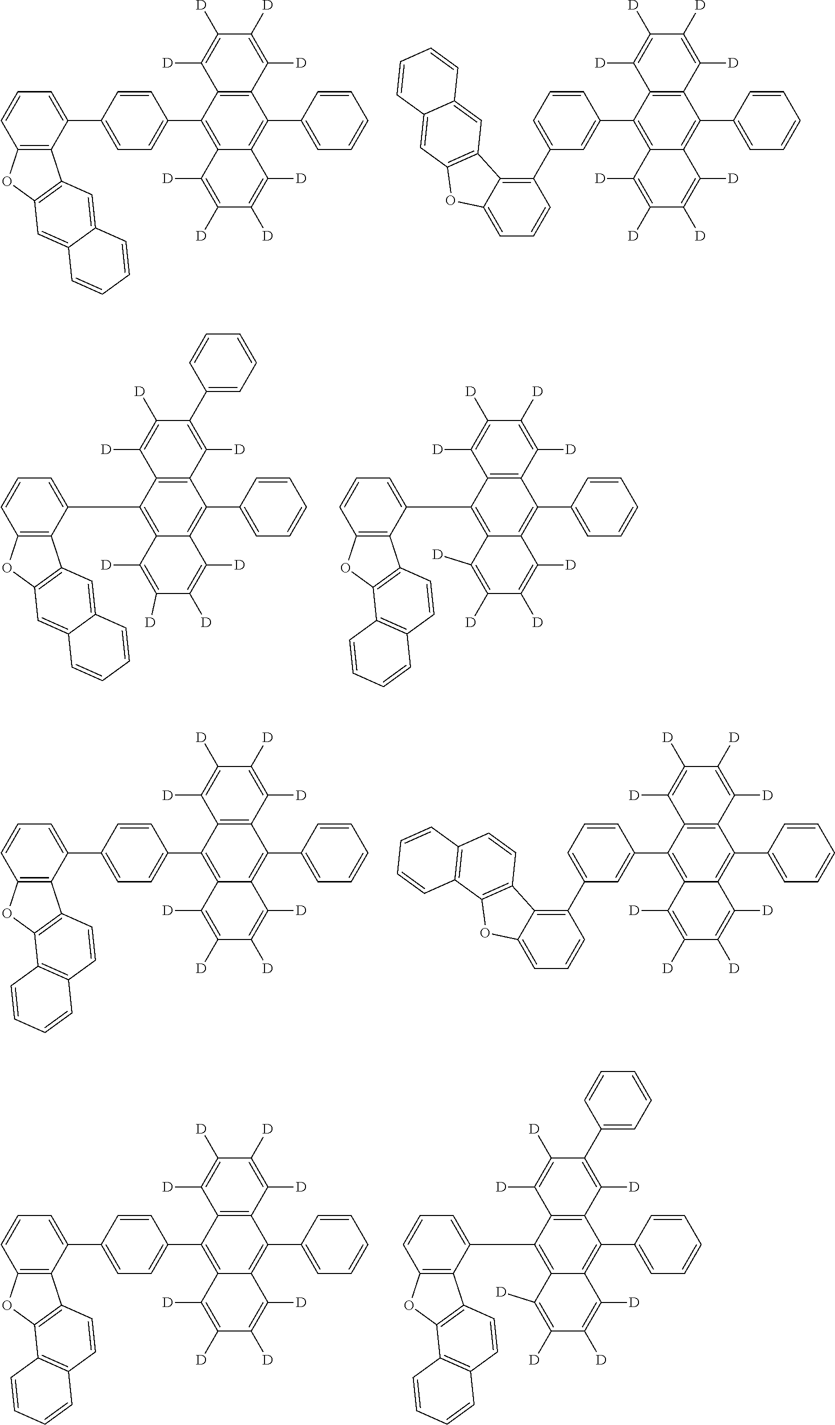

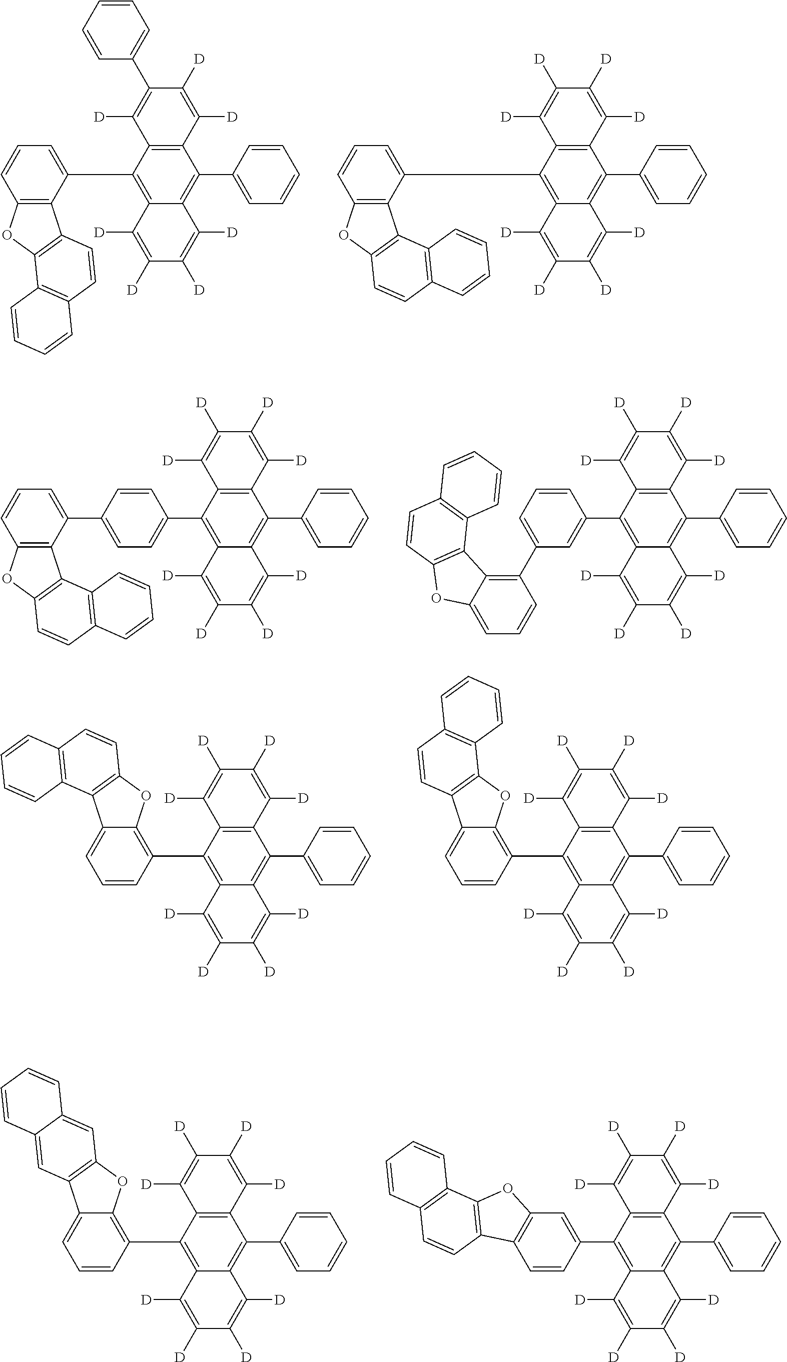

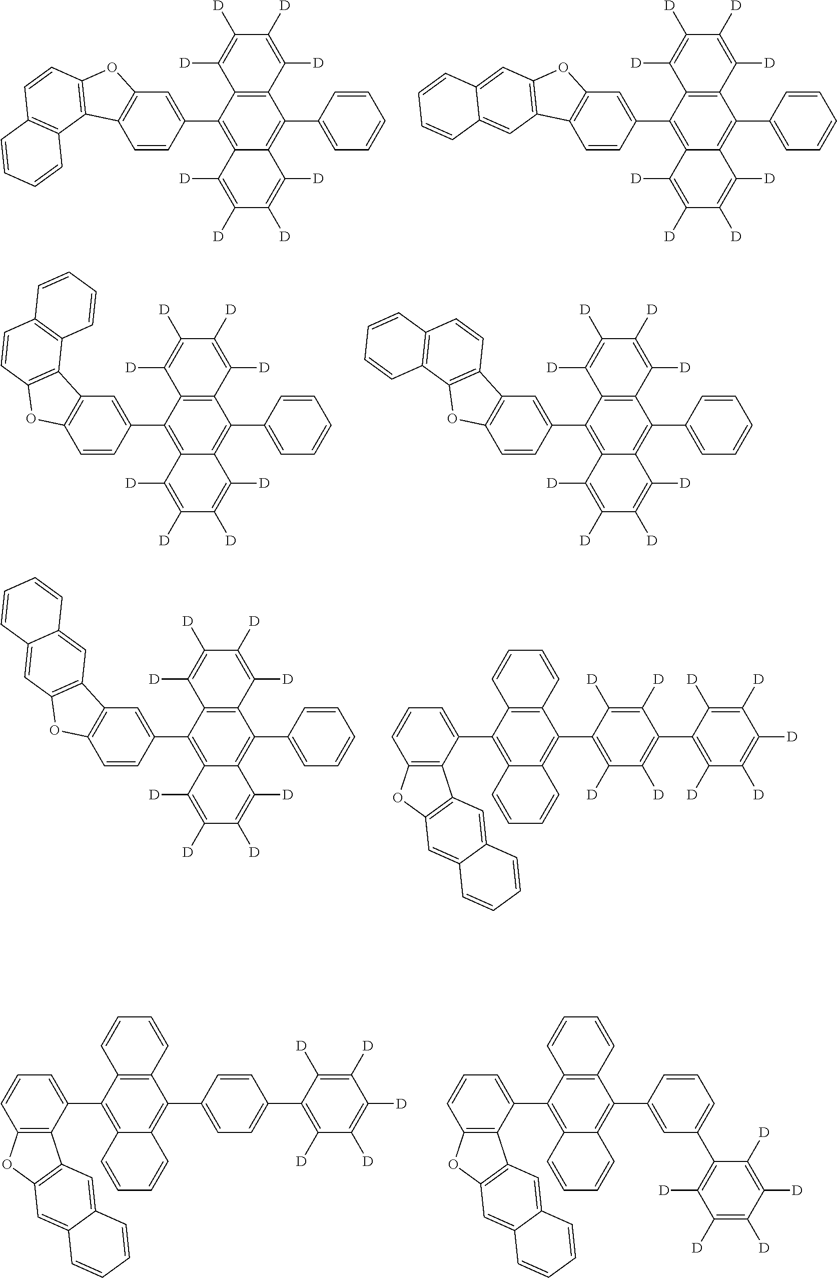

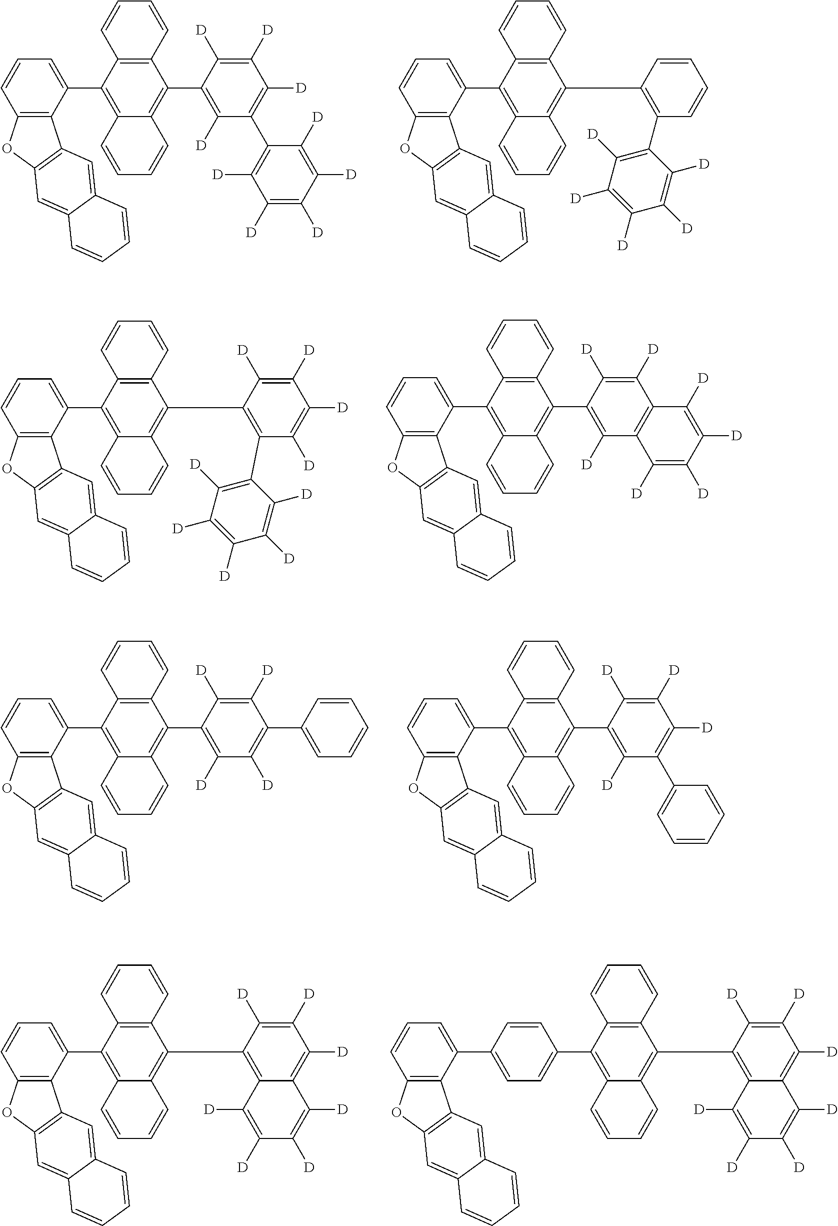

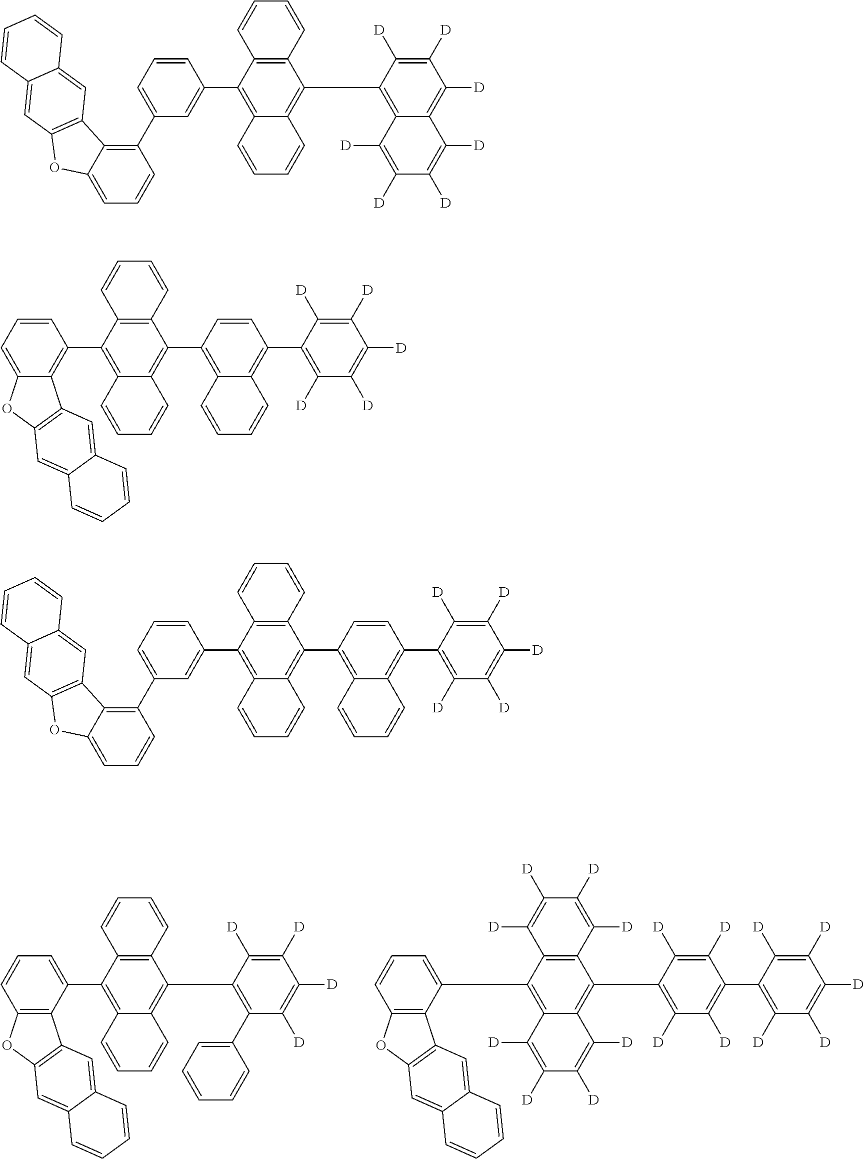

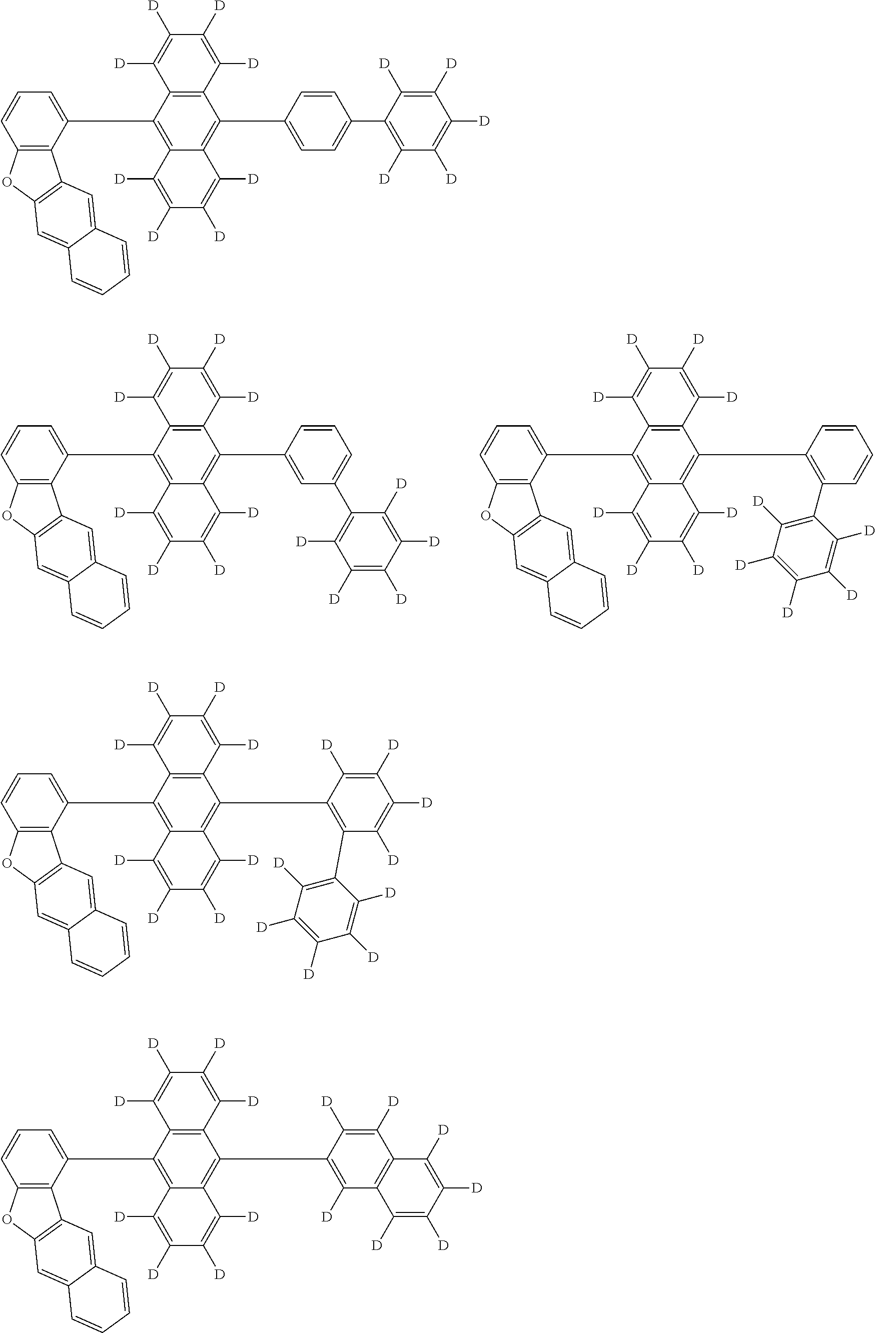

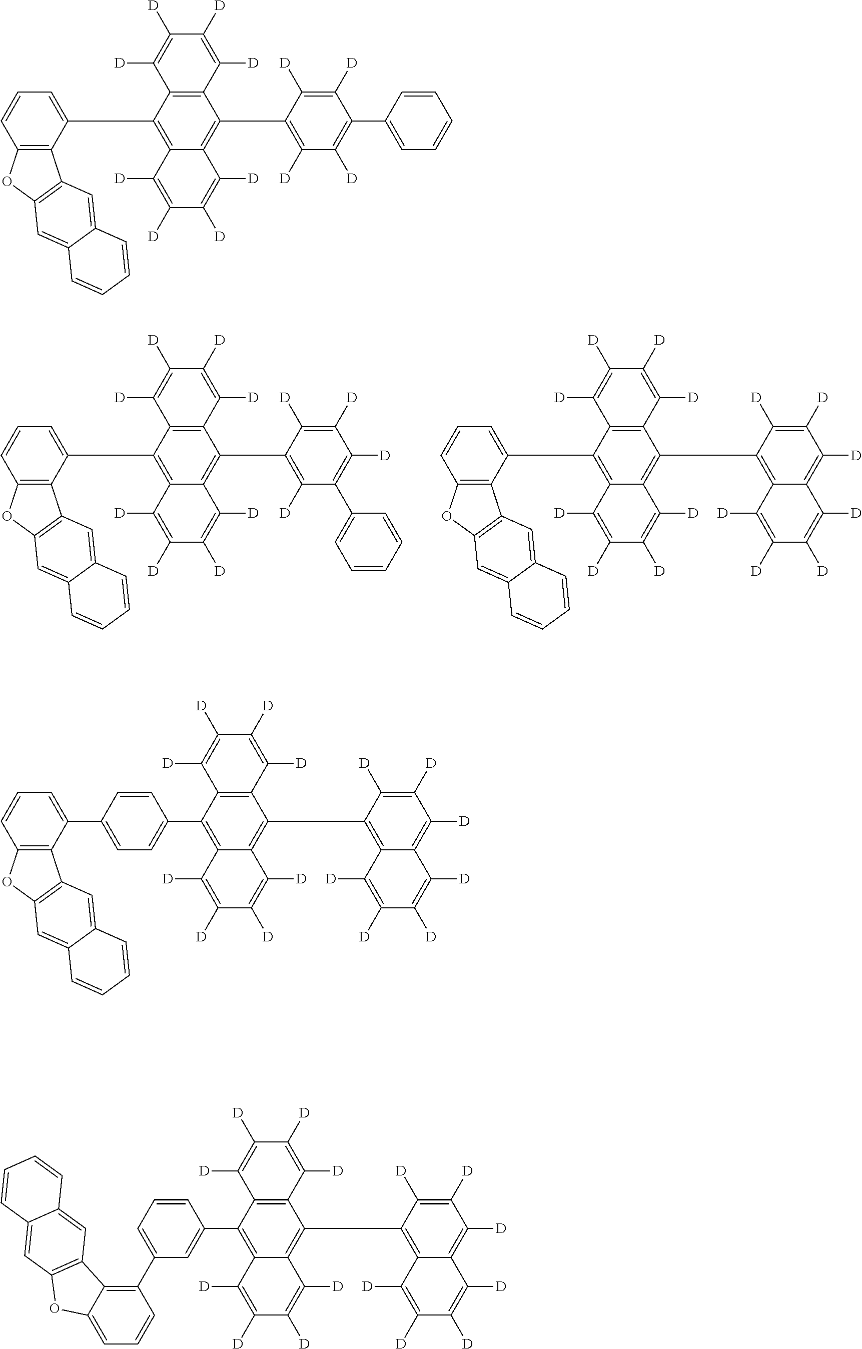

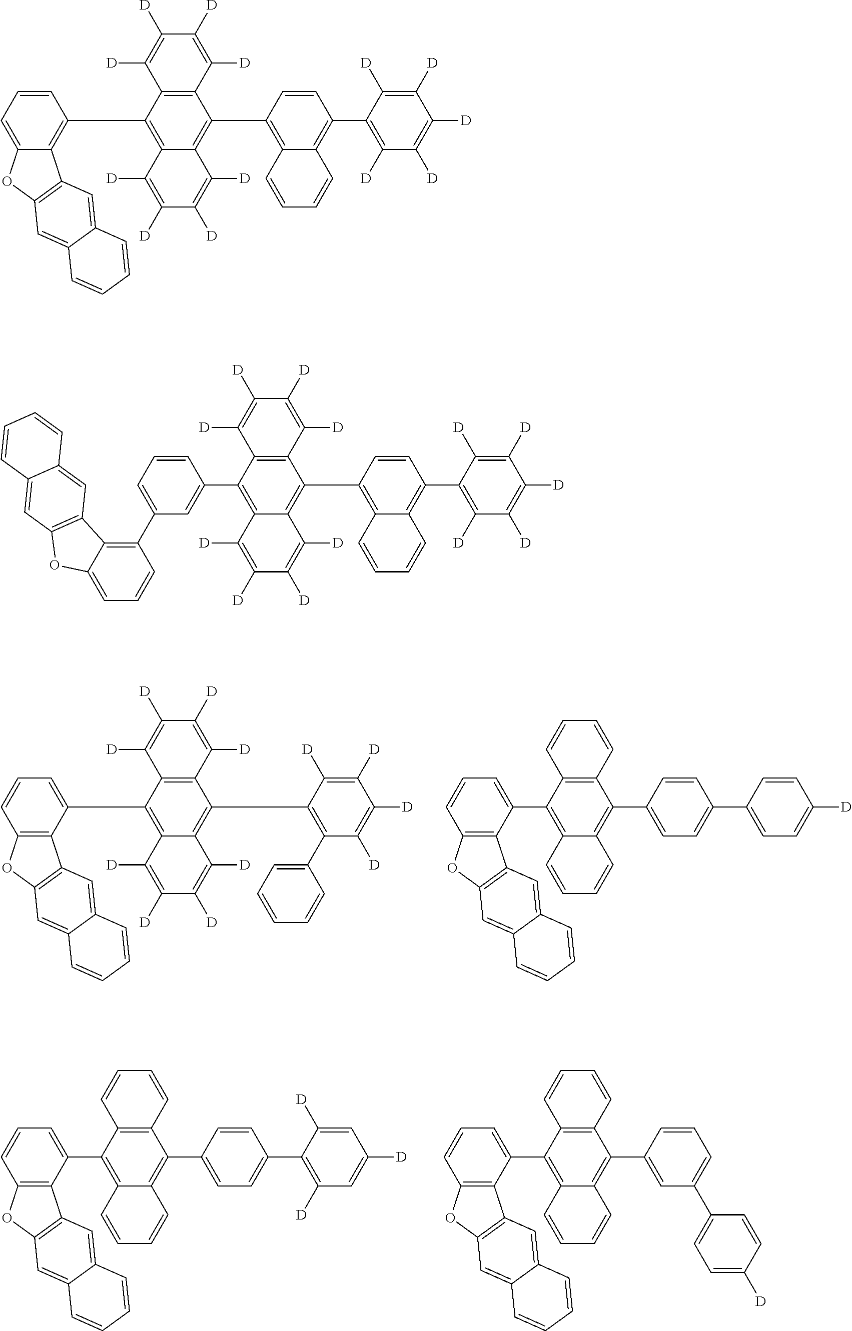

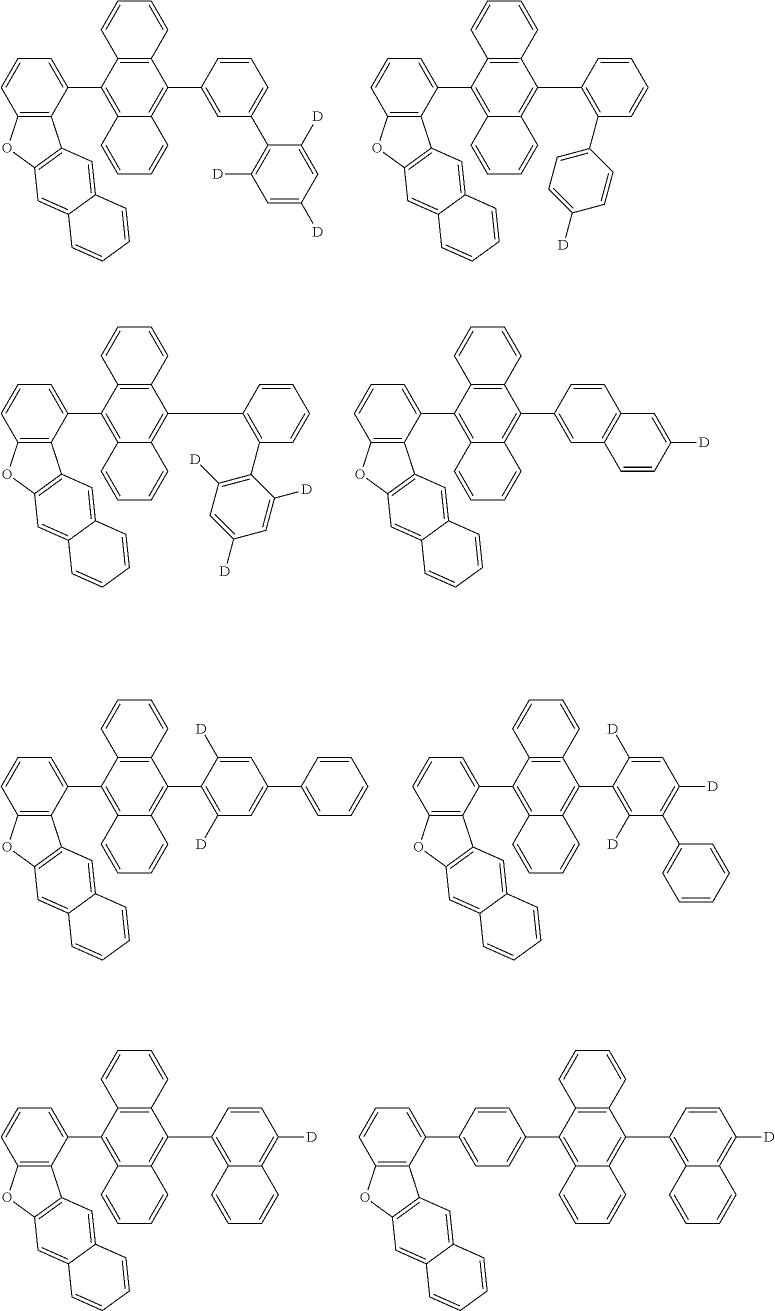

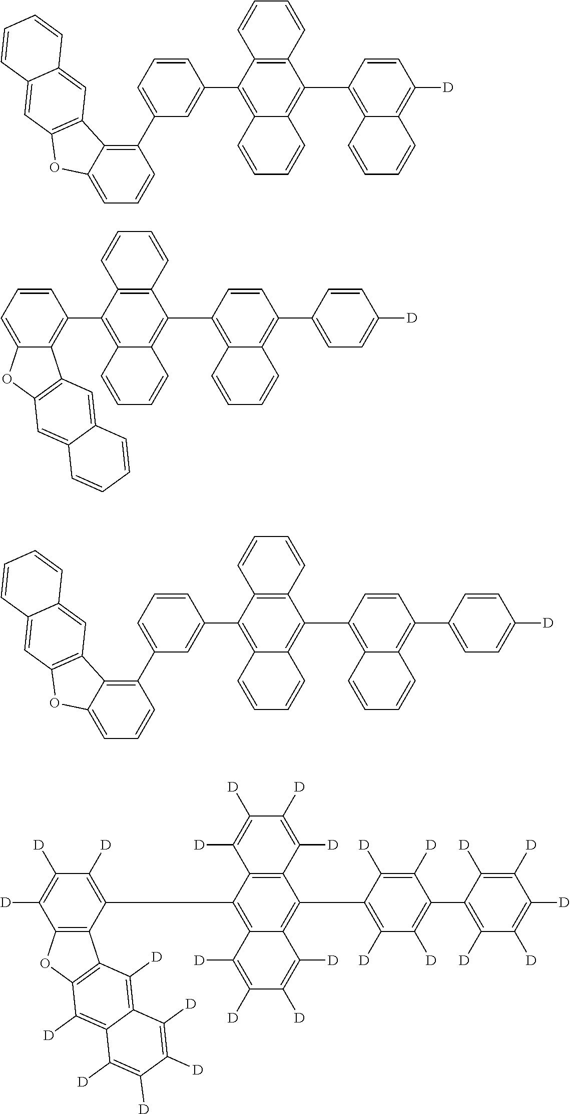

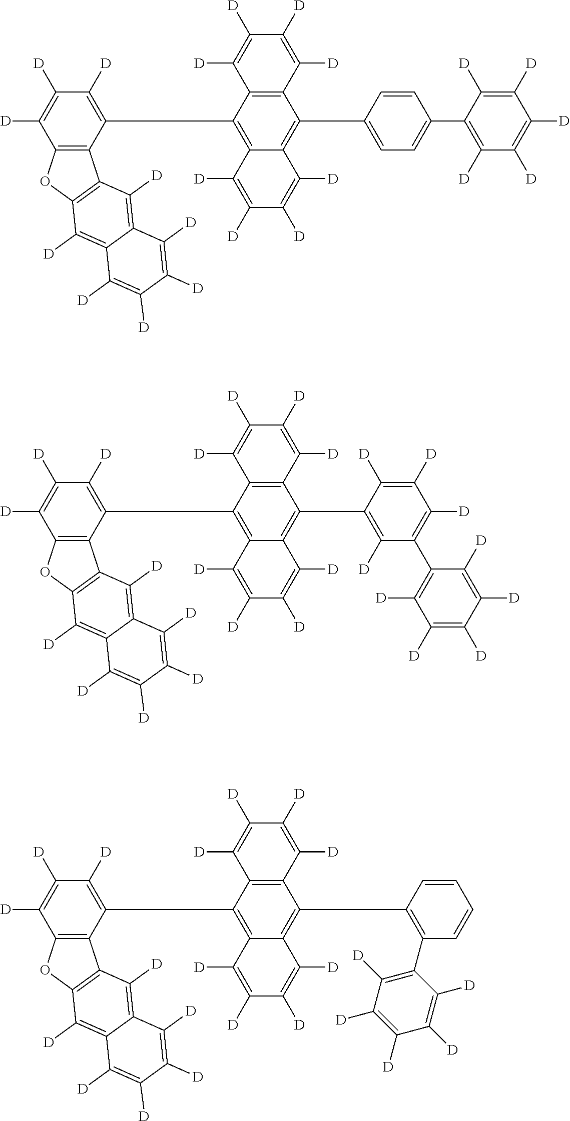

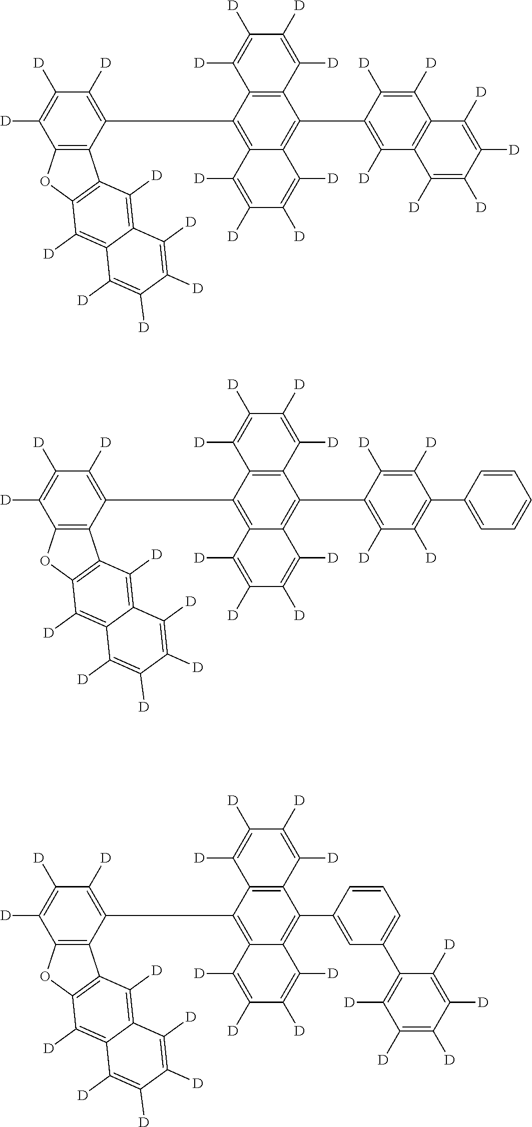

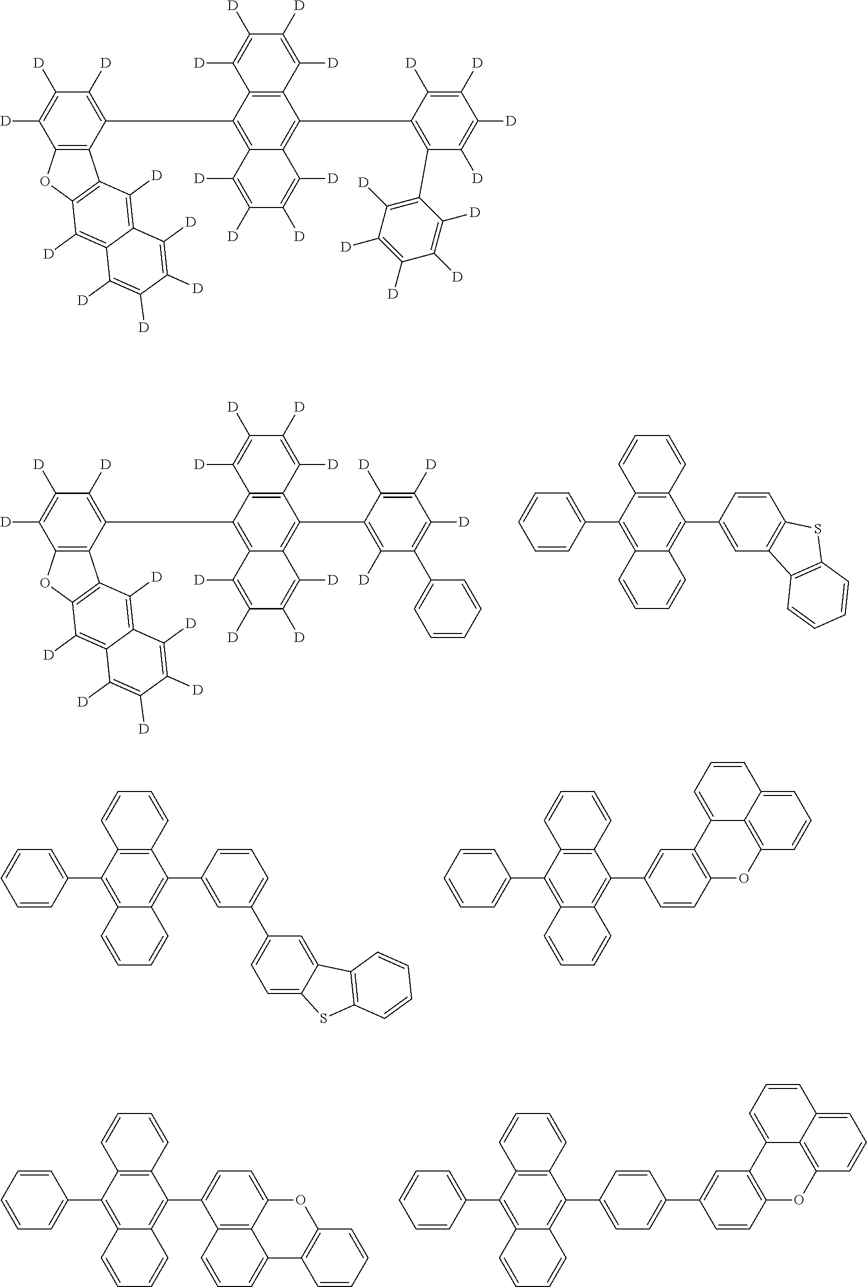

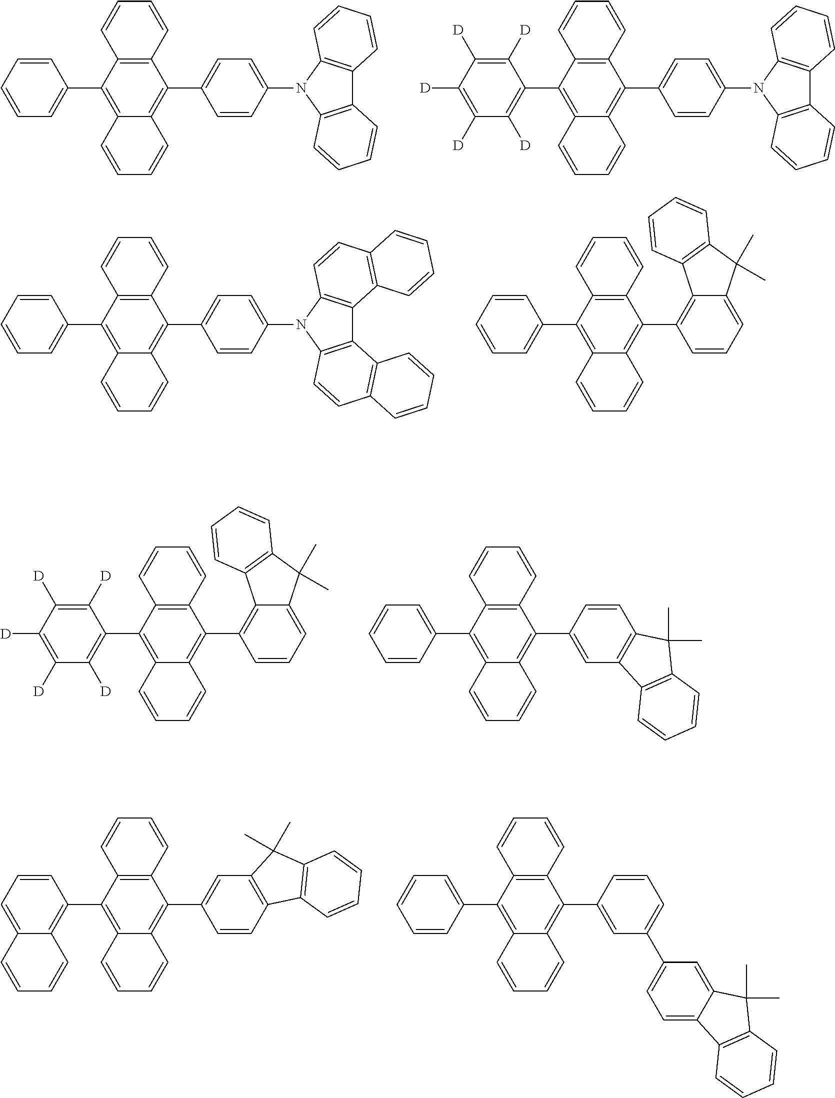

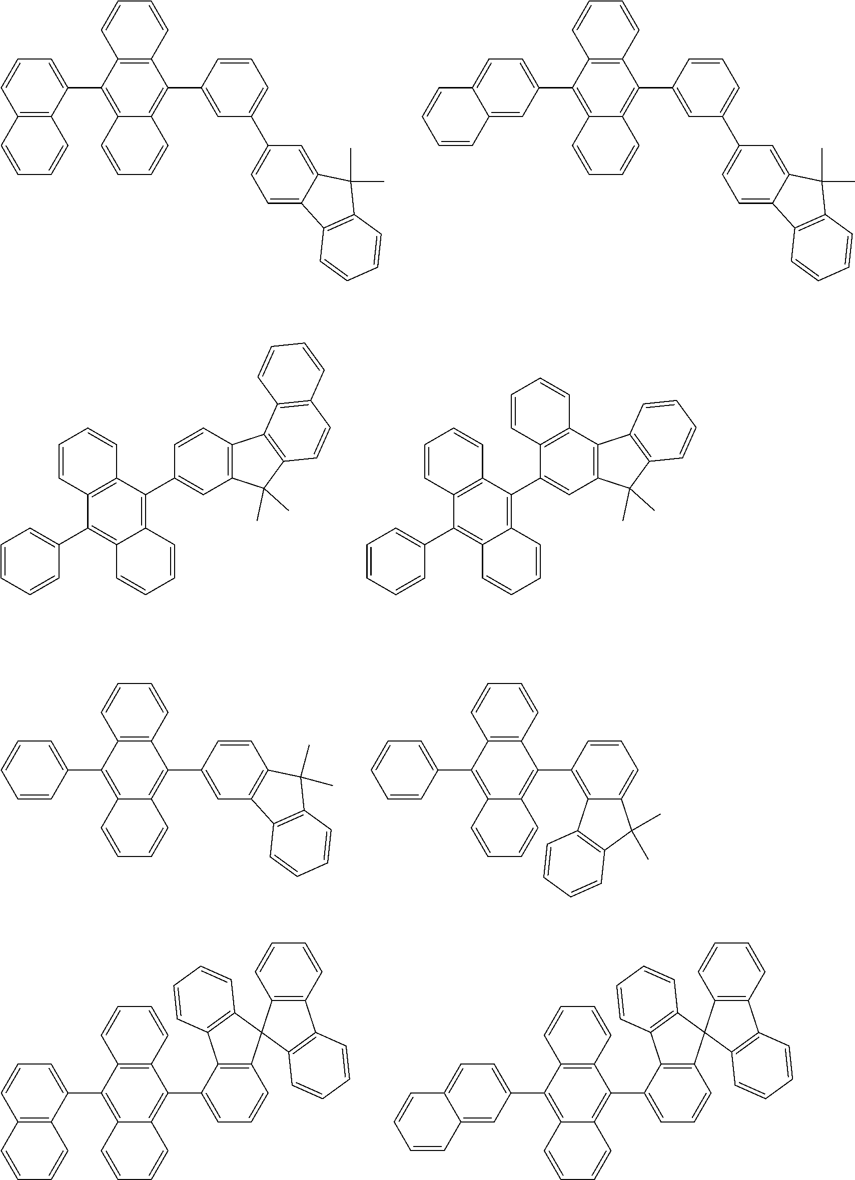

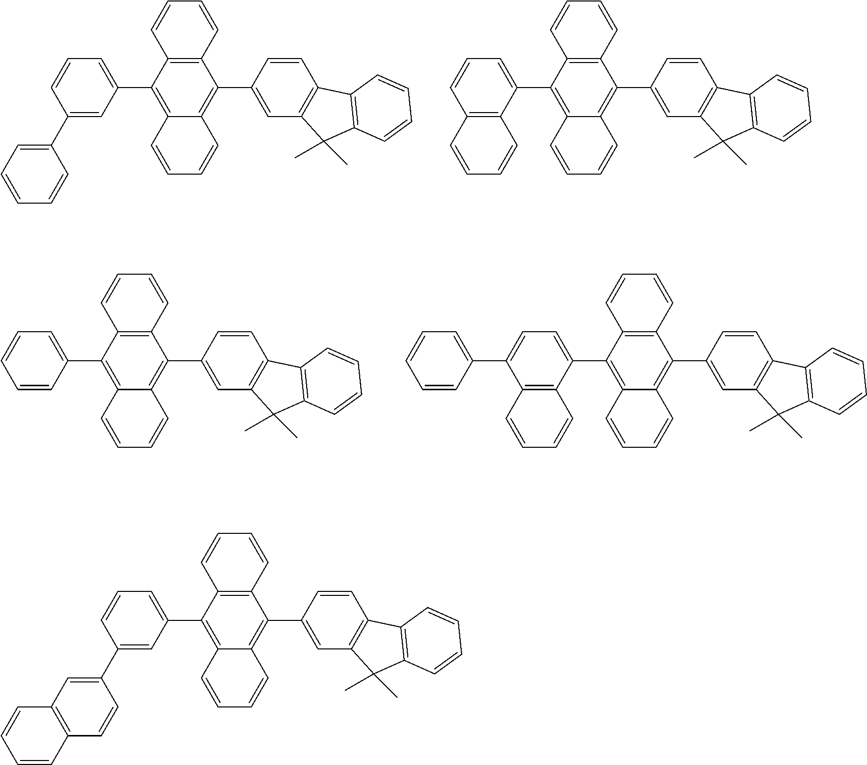

In specific examples of compounds below, D represents a deuterium atom; z, z1, z2, z3, z4, z5, and z6 each represent the number of deuterium atoms bonded to a ring; z is an integer in a range from 1 to 8; z1 is an integer in a range from 1 to 9; z2 to z5 each represent an integer in a range from 1 to 5; and z6 is an integer in a range from 1 to 7.

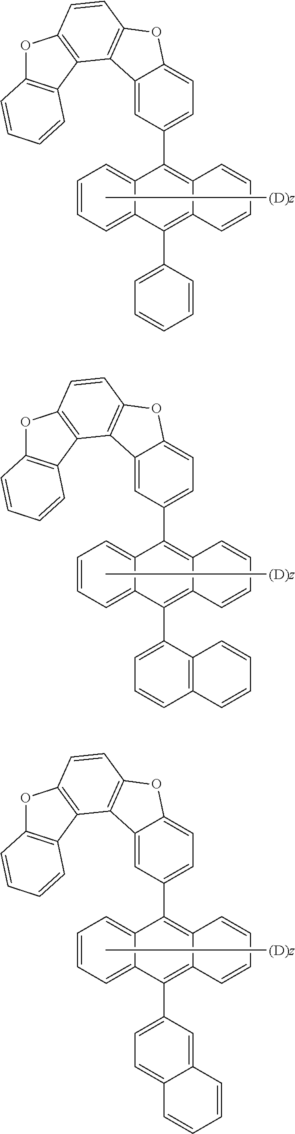

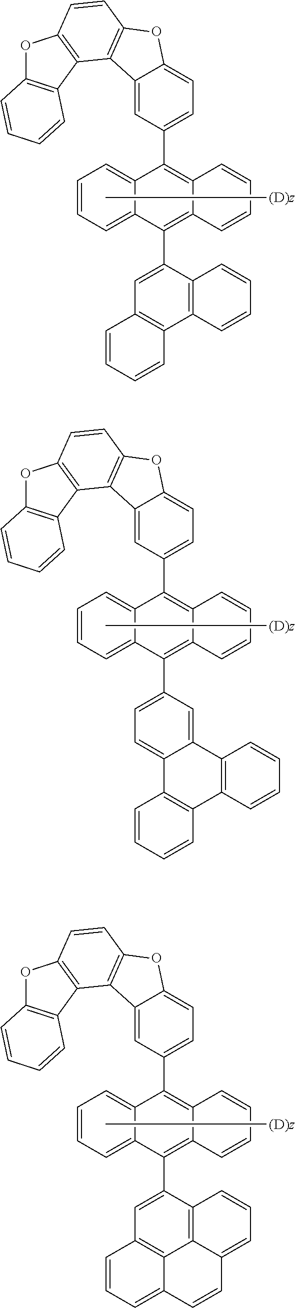

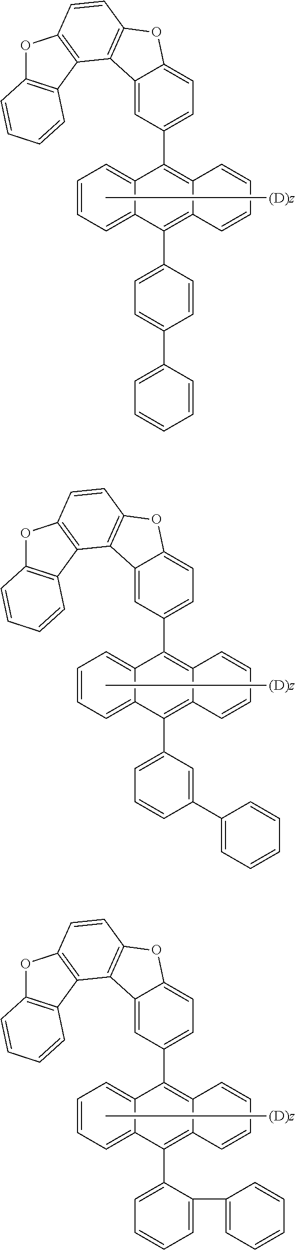

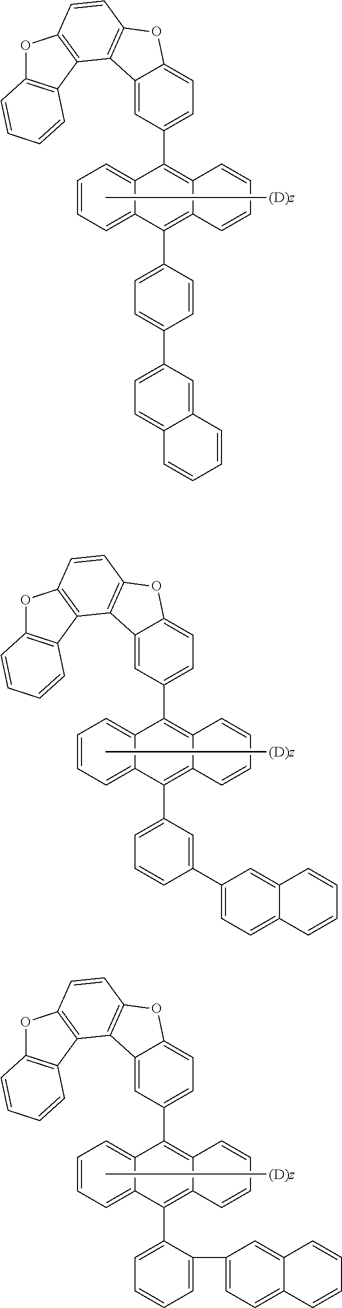

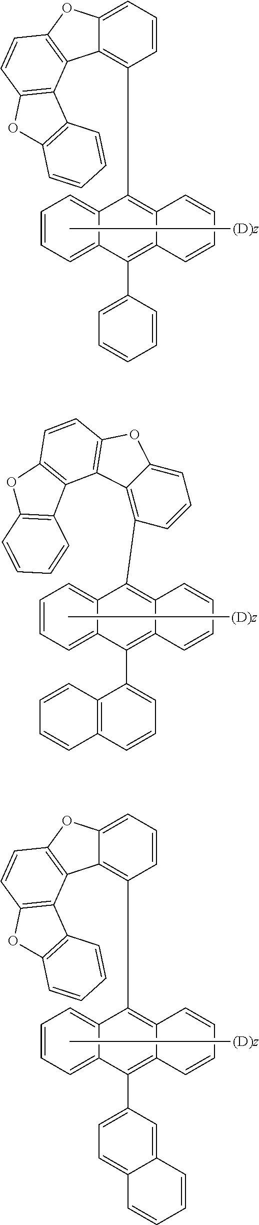

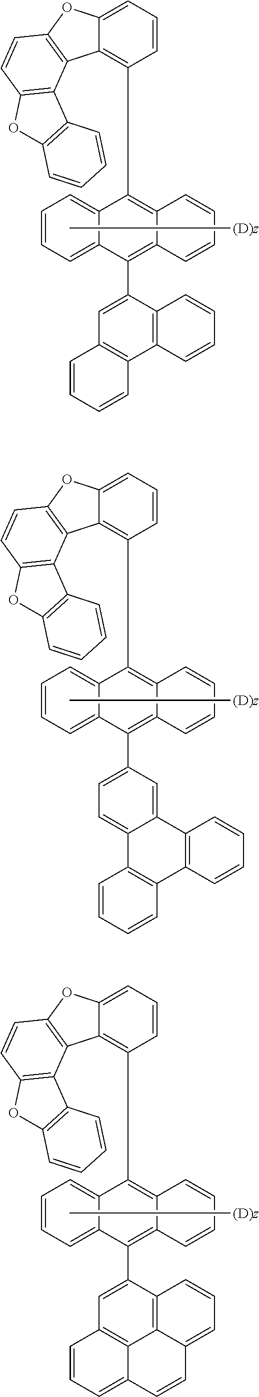

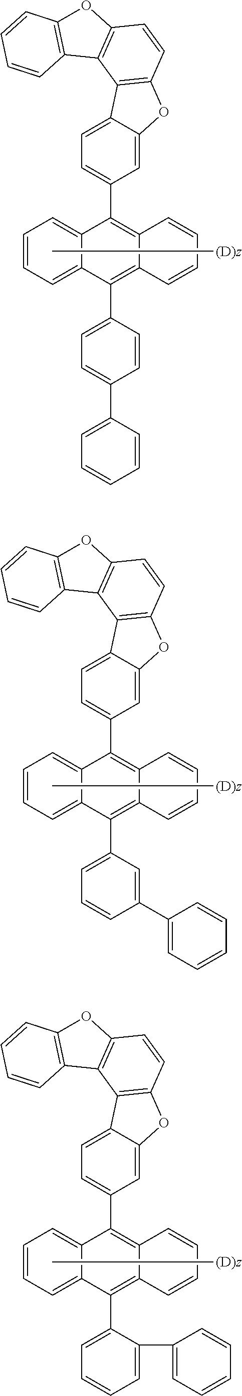

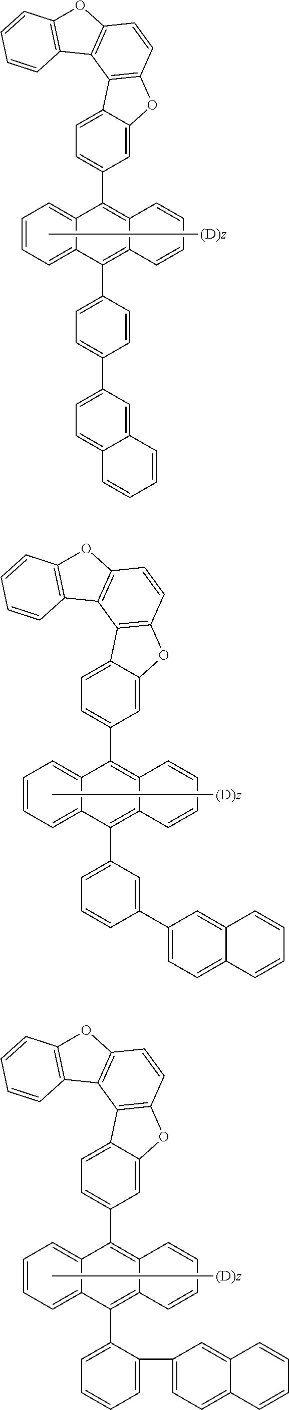

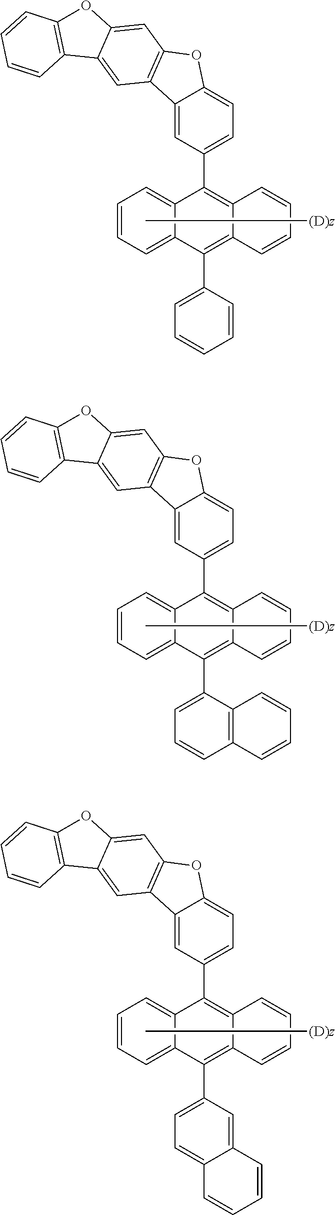

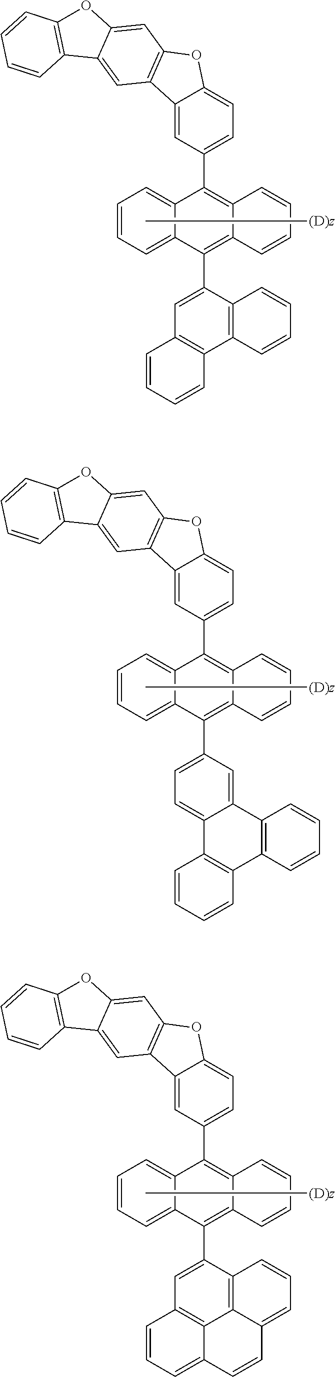

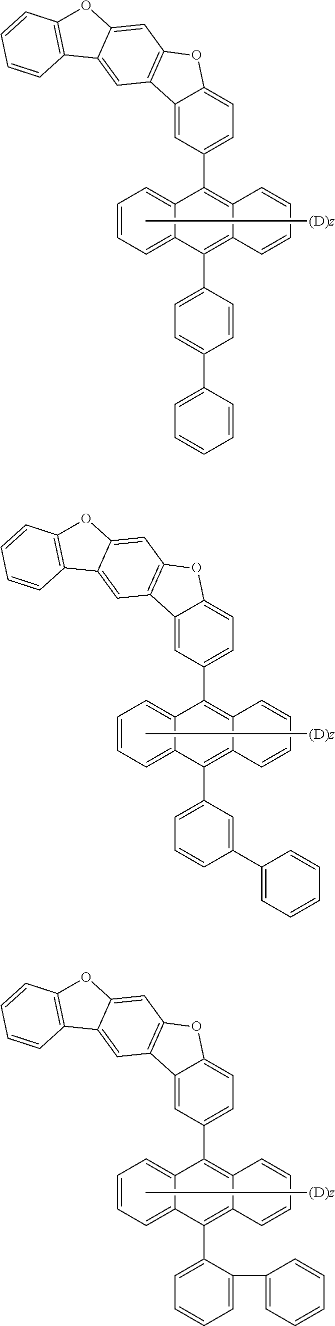

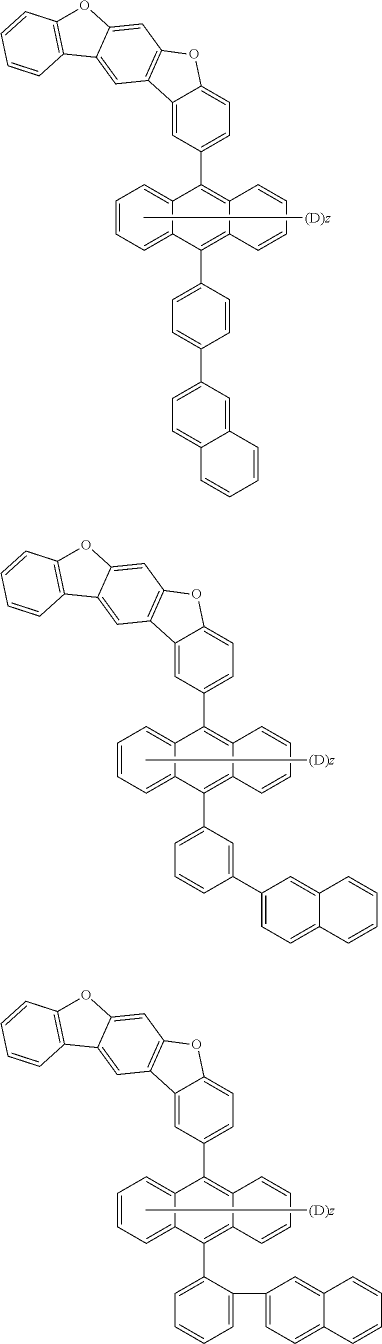

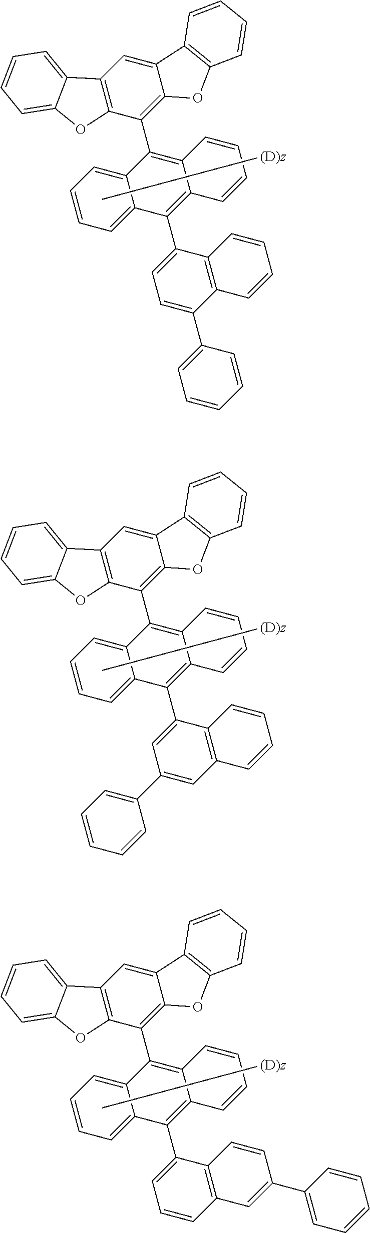

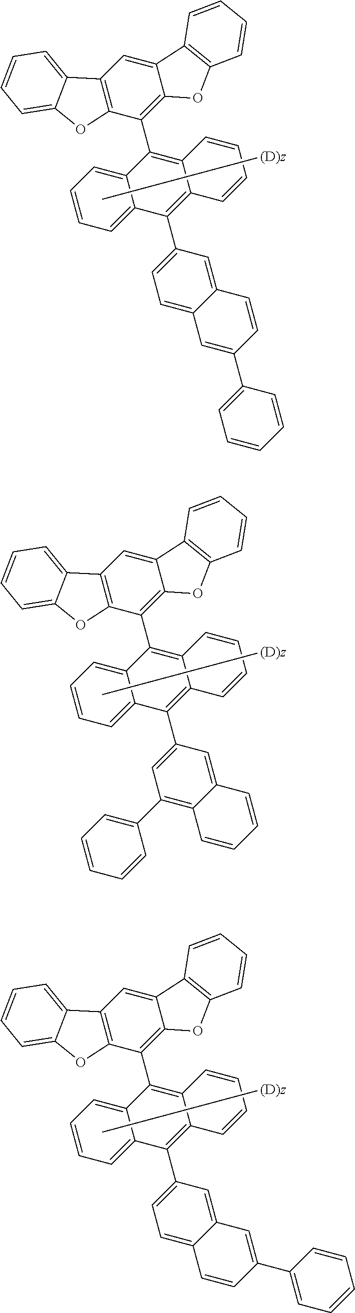

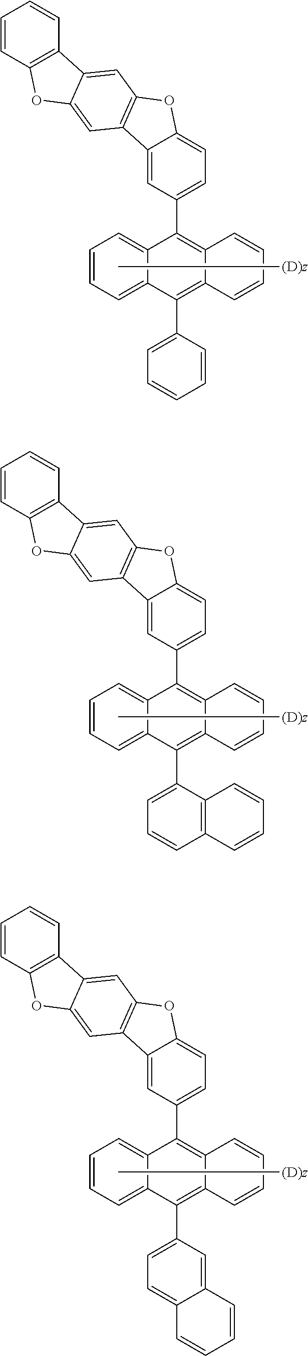

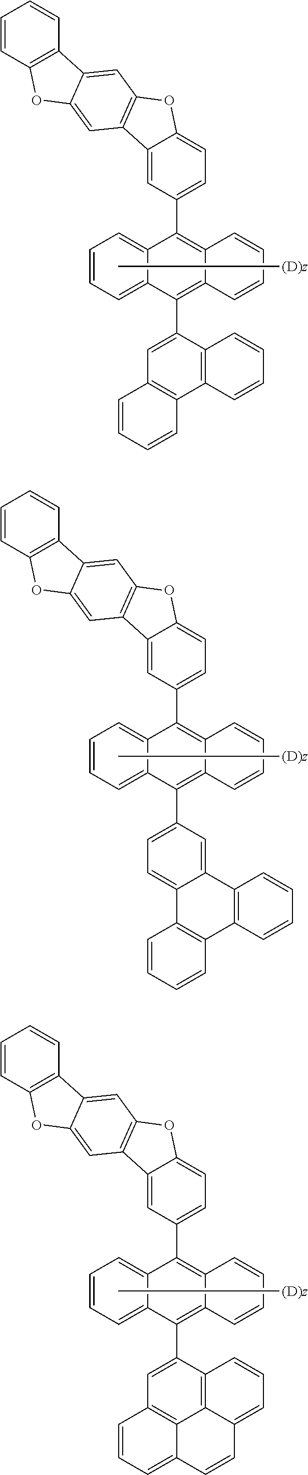

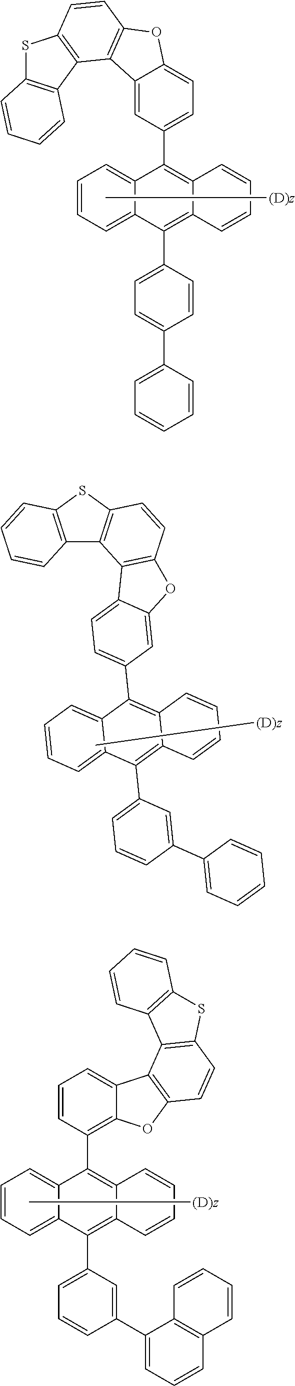

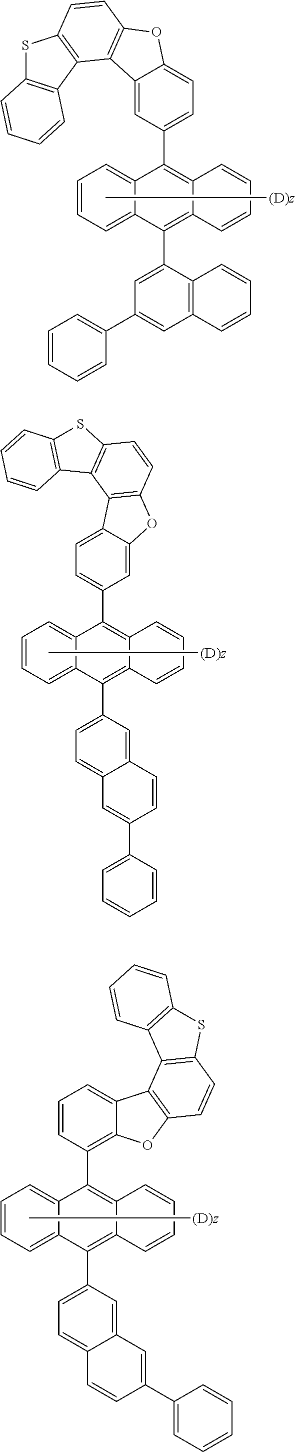

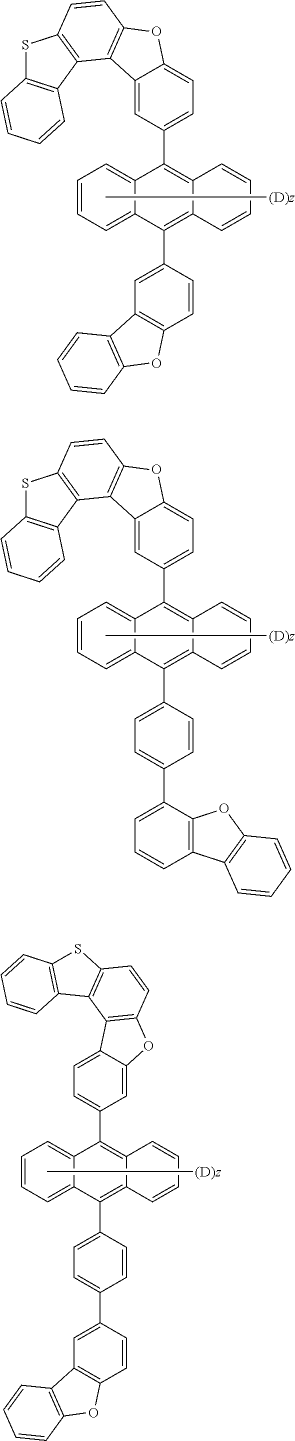

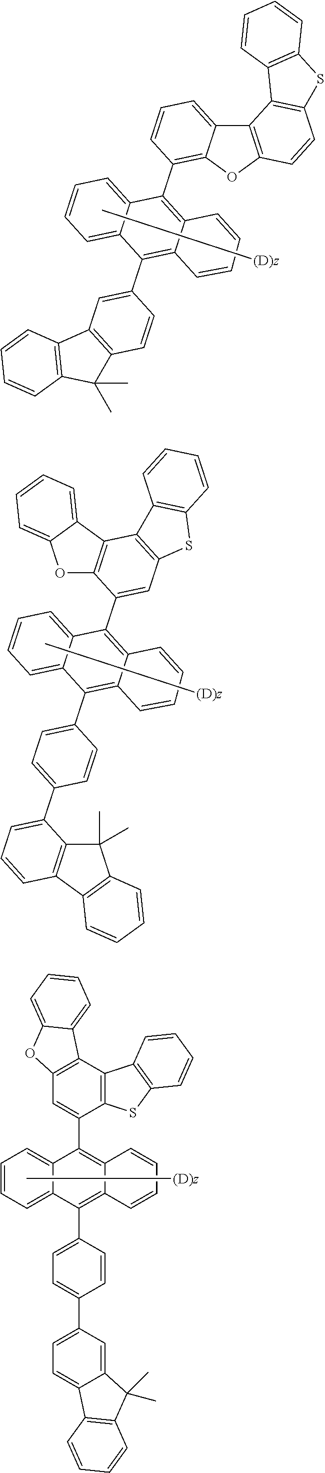

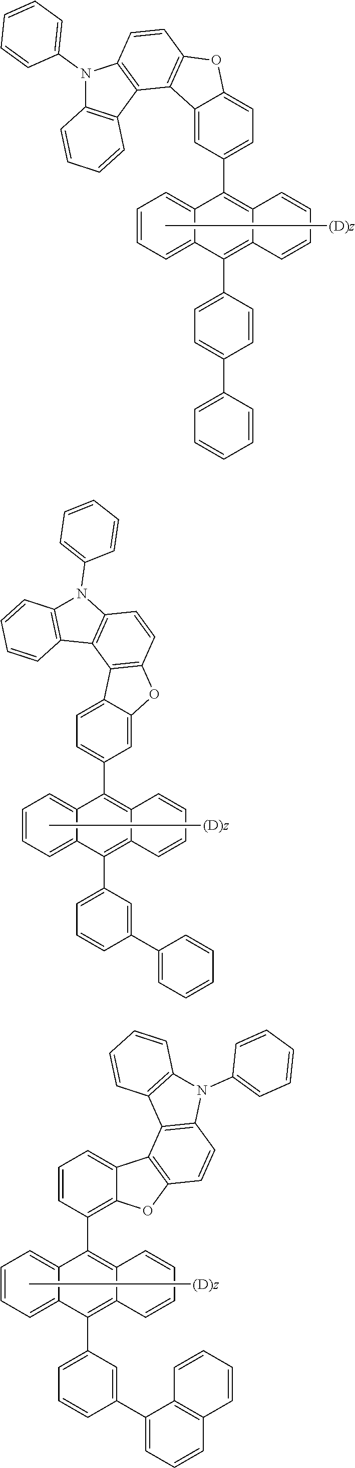

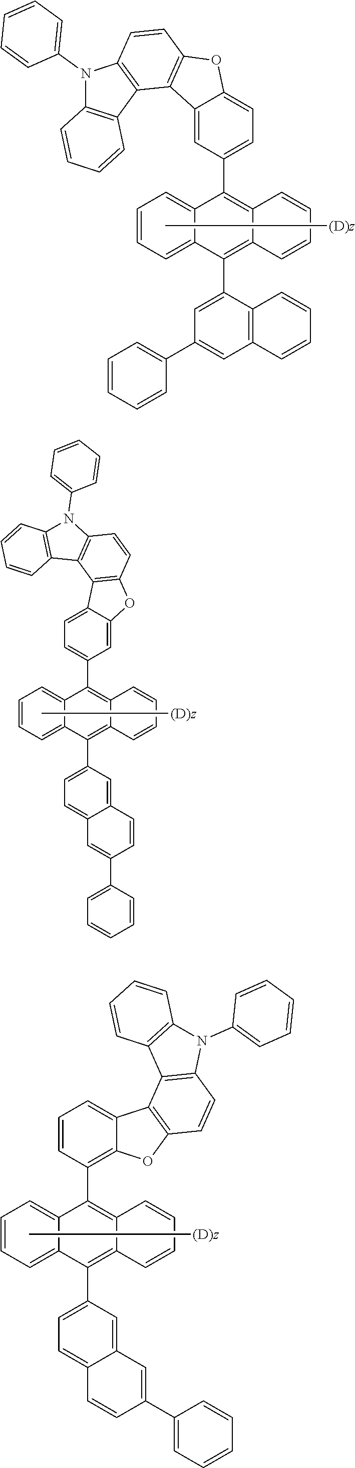

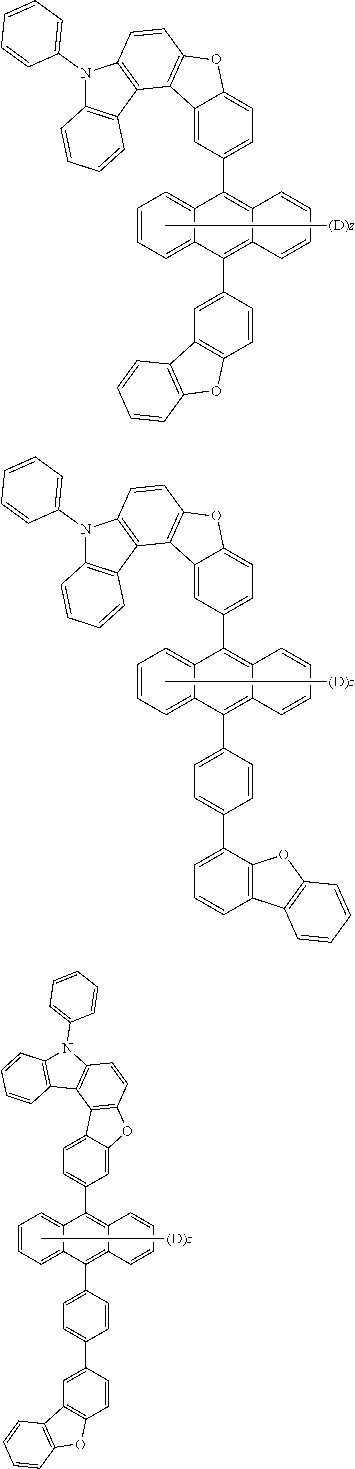

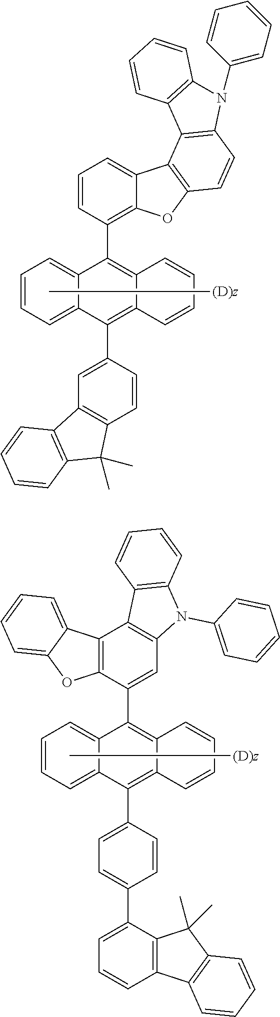

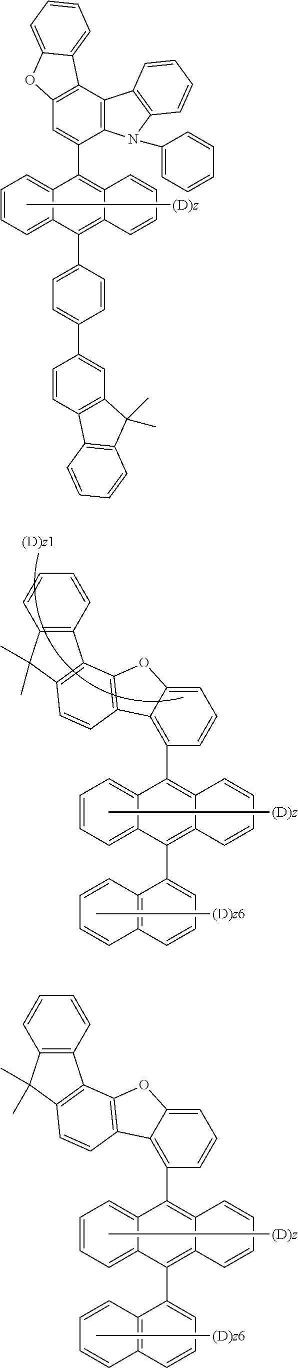

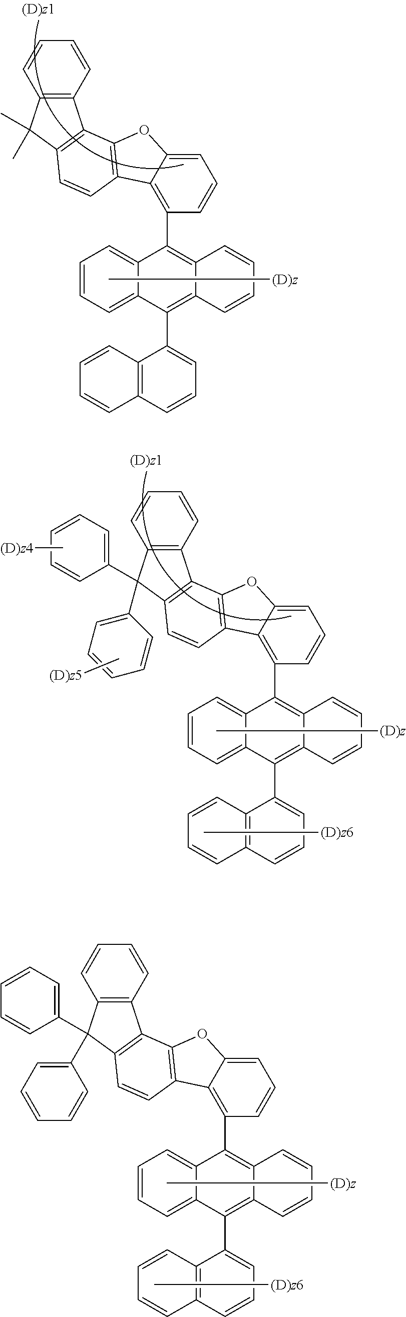

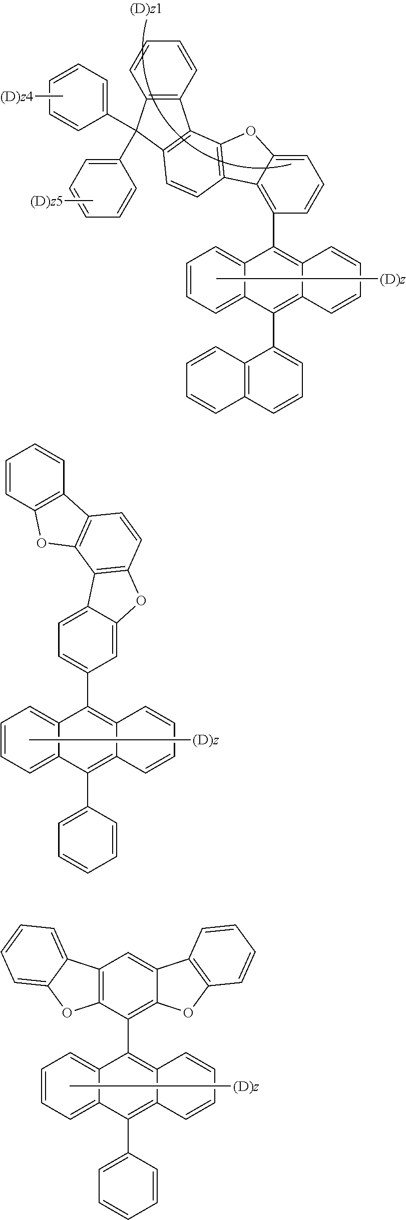

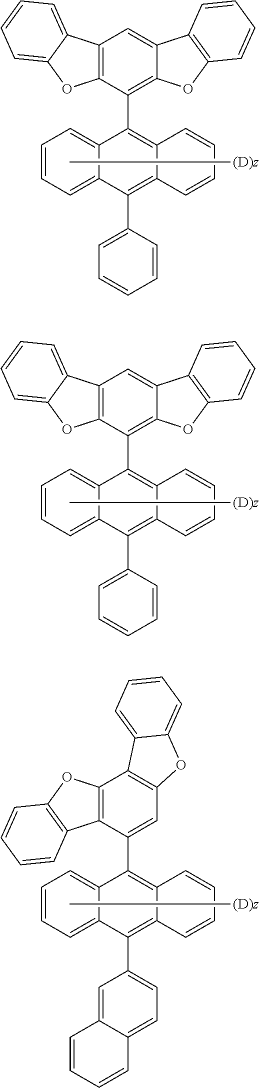

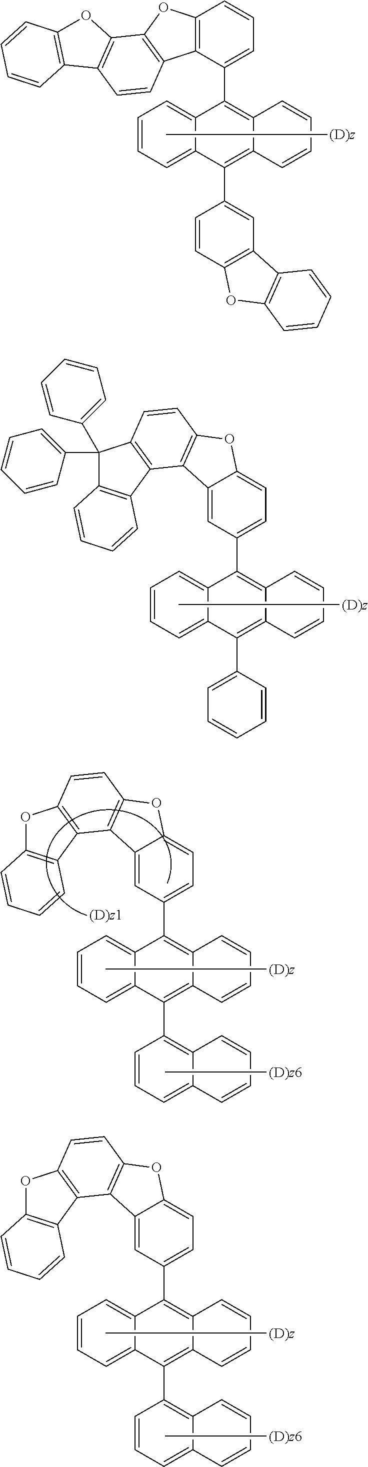

In an exemplary arrangement of the organic EL device of the exemplary embodiment, the first host material and the second host material are contained in the emitting layer, for instance, in a combination of two compounds selected from the specific examples of the compounds described above.

Further, in an exemplary arrangement of the organic EL device of the exemplary embodiment, the first host material and the second host material are contained in the emitting layer in a combination of two compounds selected from the group consisting of compounds BH-3, BH-4, and BH-A to BH-U below. Table 1 specifically shows exemplary combinations of compounds (combinations No. 1 to No. 36) as the first host material and the second host material. However, the invention is not limited to the specific examples.

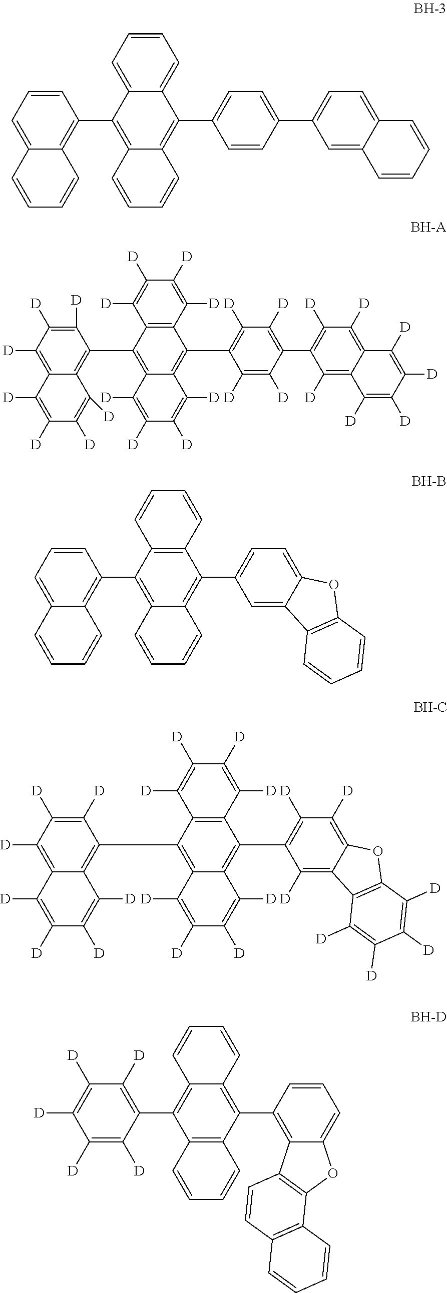

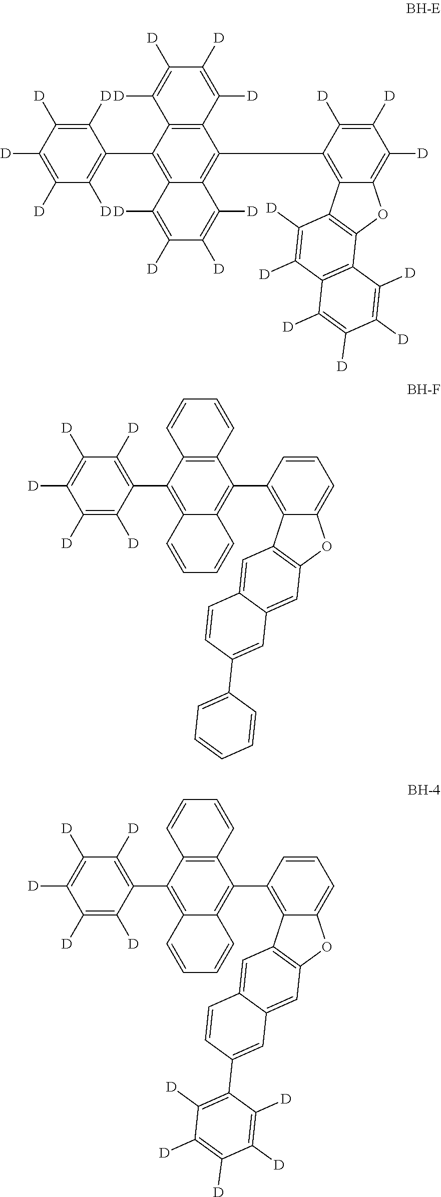

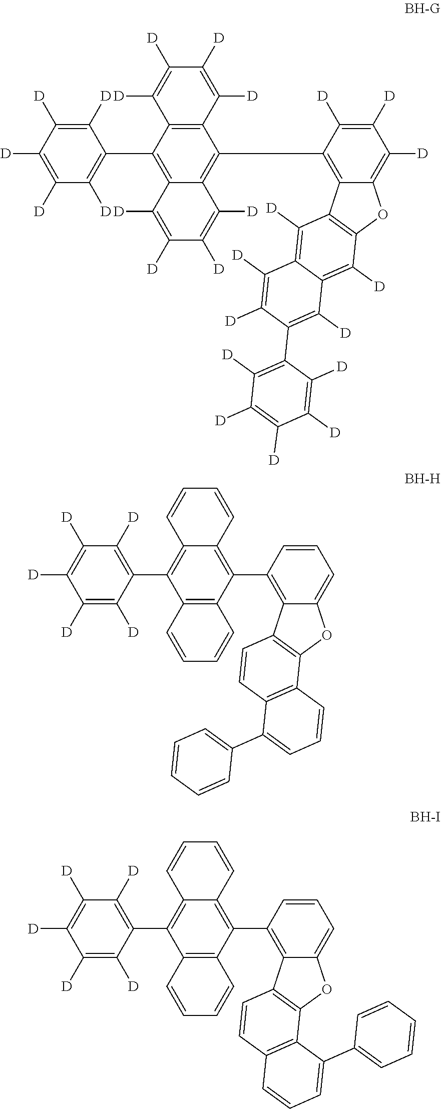 [SMILES: [2H]c1c([2H])c([2H])c(-c2c([2H])c([2H])c3c([2H])c4c(oc5c([2H])c([2H])c([2H])c(-c6c7c([2H])c([2H])c([2H])c([2H])c7c(-c7c([2H])c([2H])c([2H])c([2H])c7[2H])c7c([2H])c([2H])c([2H])c([2H])c67)c54)c([2H])c3c2[2H])c([2H])c1[2H] ; [2H]c1c([2H])c([2H])c(-c2c3ccccc3c(-c3cccc4oc5c6cccc(-c7ccccc7)c6ccc5c34)c3ccccc23)c([2H])c1[2H] ; [2H]c1c([2H])c([2H])c(-c2c3ccccc3c(-c3cccc4oc5c(ccc6cccc(-c7ccccc7)c65)c34)c3ccccc23)c([2H])c1[2H]]

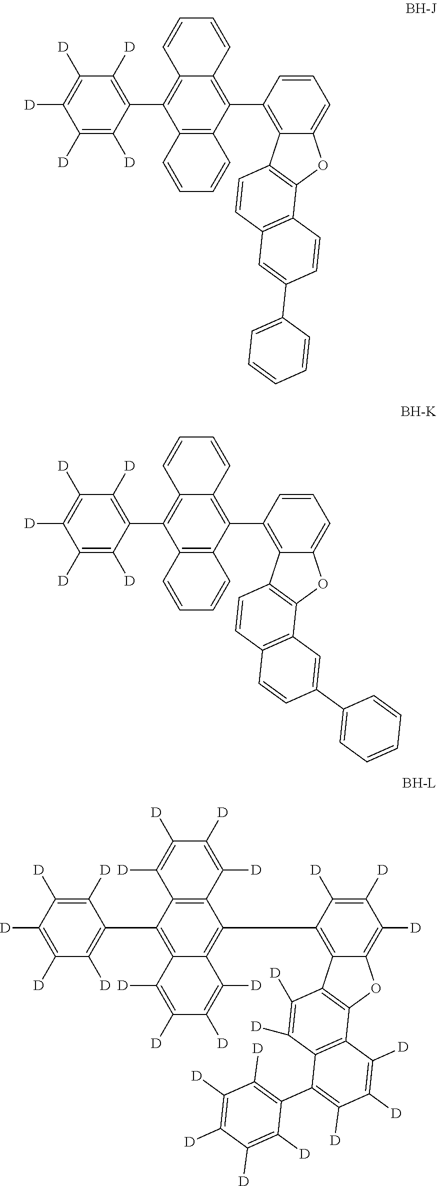 [SMILES: [2H]c1c([2H])c([2H])c(-c2c3ccccc3c(-c3cccc4oc5c6ccc(-c7ccccc7)cc6ccc5c34)c3ccccc23)c([2H])c1[2H] ; [2H]c1c([2H])c([2H])c(-c2c3ccccc3c(-c3cccc4oc5c6cc(-c7ccccc7)ccc6ccc5c34)c3ccccc23)c([2H])c1[2H] ; [2H]c1c([2H])c([2H])c(-c2c3c([2H])c([2H])c([2H])c([2H])c3c(-c3c([2H])c([2H])c([2H])c4oc5c6c([2H])c([2H])c([2H])c(-c7c([2H])c([2H])c([2H])c([2H])c7[2H])c6c([2H])c([2H])c5c34)c3c([2H])c([2H])c([2H])c([2H])c23)c([2H])c1[2H]]

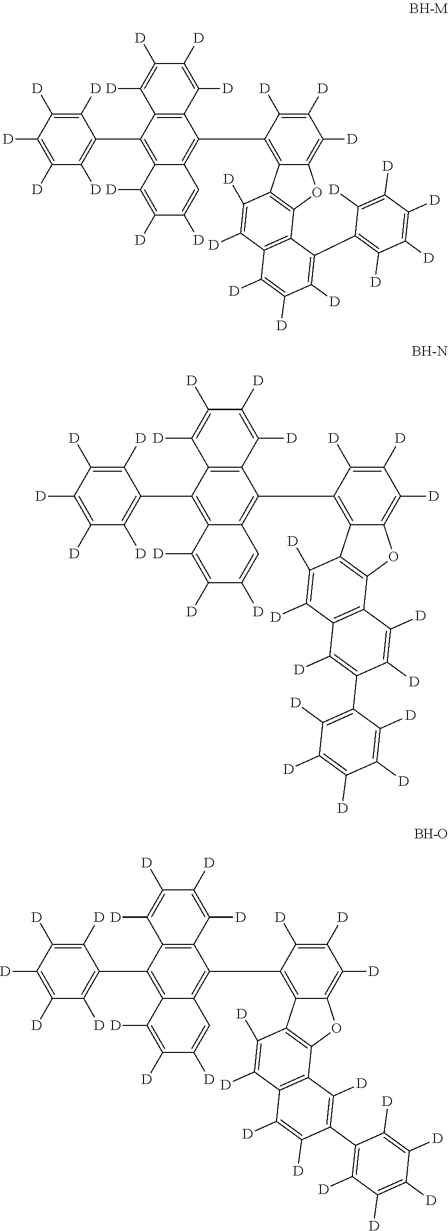

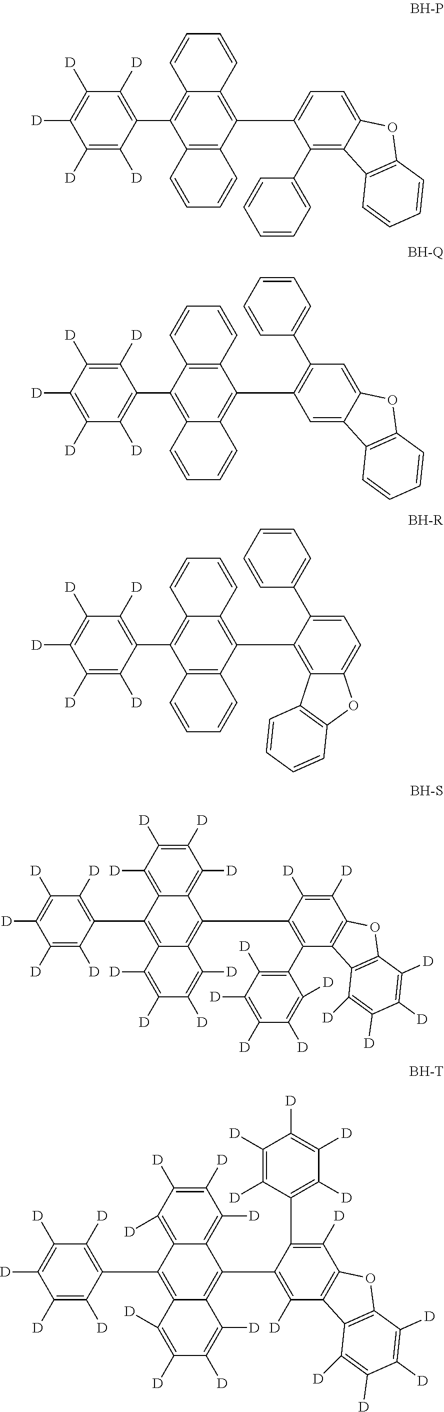

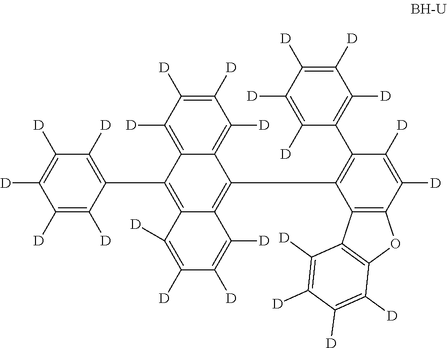 [SMILES: [2H]c1c([2H])c([2H])c(-c2c([2H])c([2H])c3oc4c([2H])c([2H])c([2H])c([2H])c4c3c2-c2c3c([2H])c([2H])c([2H])c([2H])c3c(-c3c([2H])c([2H])c([2H])c([2H])c3[2H])c3c([2H])c([2H])c([2H])c([2H])c23)c([2H])c1[2H]]

TABLE 1

| | |
|---|---|
| Combination | First host material and |
| No. | Second host material |

| | | |
|---|---|---|
| 1 | BH-3 | BH-B |
| 2 | BH-3 | BH-C |
| 3 | BH-3 | BH-F |
| 4 | BH-3 | BH-4 |
| 5 | BH-3 | BH-G |
| 6 | BH-A | BH-B |
| 7 | BH-A | BH-4 |
| 8 | BH-A | BH-C |
| 9 | BH-B | BH-H |
| 10 | BH-B | BH-I |
| 11 | BH-B | BH-J |
| 12 | BH-B | BH-K |
| 13 | BH-B | BH-L |
| 14 | BH-B | BH-M |
| 15 | BH-B | BH-N |
| 16 | BH-B | BH-O |
| 17 | BH-C | BH-H |
| 18 | BH-C | BH-I |
| 19 | BH-C | BH-J |
| 20 | BH-C | BH-K |
| 21 | BH-C | BH-L |
| 22 | BH-C | BH-M |
| 23 | BH-C | BH-N |
| 24 | BH-C | BH-O |
| 25 | BH-D | BH-P |
| 26 | BH-D | BH-Q |
| 27 | BH-D | BH-R |
| 28 | BH-D | BH-S |
| 29 | BH-D | BH-T |
| 30 | BH-D | BH-U |
| 31 | BH-E | BH-P |
| 32 | BH-E | BH-Q |
| 33 | BH-E | BH-R |
| 34 | BH-E | BH-S |
| 35 | BH-E | BH-T |
| 36 | BH-E | BH-U |

### Emitting Compound

In the organic EL device of the exemplary embodiment, the emitting compound is contained in the emitting layer.

In an exemplary arrangement of the organic EL device of the exemplary embodiment, the emitting compound is a compound that emits light having a maximum peak wavelength of 500 nm or less.

In an exemplary arrangement of the organic EL device of the exemplary embodiment, the emitting compound emits light having a maximum peak wavelength of 480 nm or less.

In an exemplary arrangement of the organic EL device of the exemplary embodiment, the emitting compound emits light having a maximum peak wavelength of 430 nm or more.

In an exemplary arrangement of the organic EL device of the exemplary embodiment, the emitting compound emits fluorescence having a maximum peak wavelength of 500 nm or less.

In an exemplary arrangement of the organic EL device of the exemplary embodiment, the emitting compound emits fluorescence having a maximum peak wavelength of 480 nm or less.

In an exemplary arrangement of the organic EL device of the exemplary embodiment, the emitting compound emits fluorescence having a maximum peak wavelength of 430 nm or more.

In an exemplary arrangement of the organic EL device of the exemplary embodiment, the emitting compound is a compound having no azine ring structure in a molecule.

In an exemplary arrangement of the organic EL device of the exemplary embodiment, the emitting compound is not a boron-containing complex. In an exemplary arrangement of the organic EL device of the exemplary embodiment, the emitting compound is not a complex.

A method of measuring the maximum peak wavelength of the compound is as follows. A toluene solution of a measurement target compound at a concentration of 5 μmol/L is prepared and put in a quartz cell. An emission spectrum (ordinate axis: luminous intensity, abscissa axis: wavelength) of this sample is measured at a normal temperature (300K). The emission spectrum can be measured using a spectrophotometer (machine name: F-7000) produced by Hitachi High-Tech Science Corporation. It should be noted that the machine for measuring the emission spectrum is not limited to the machine used herein.

A peak wavelength of the emission spectrum exhibiting a maximum luminous intensity is defined as the maximum peak wavelength. Herein, the maximum peak wavelength of fluorescence is occasionally referred to as a maximum fluorescence peak wavelength (FL-peak).

In an emission spectrum of the emitting compound in an exemplary arrangement of the organic EL device of the exemplary embodiment, where a peak exhibiting the maximum luminous intensity is defined as a maximum peak and a height of the maximum peak is defined as 1, heights of other peaks appearing in the emission spectrum are less than 0.6. It should be noted that the peaks in the emission spectrum are defined as local maximum values.

In an exemplary arrangement of the organic EL device of the exemplary embodiment, the number of peaks in the emission spectrum of the emitting compound is preferably less than three.

In an exemplary arrangement of the organic EL device of the exemplary embodiment, the emitting layer contains the emitting compound at 0.5 mass % or more with respect to the total mass of the emitting layer.

In an exemplary arrangement of the organic EL device of the exemplary embodiment, the emitting layer contains the emitting compound at 10 mass % or less, 7 mass % or less, or 5 mass % or less with respect to the total mass of the emitting layer.

In the emitting layer containing the first host material, the second host material, and the emitting compound, the upper limit of the total of the content ratios of the first host material, the second host material, and the emitting compound is 100 mass %.

### Compound Represented by Formula (5)

In an exemplary arrangement of the organic EL device of the exemplary embodiment, the emitting compound is a compound represented by a formula (5) below.

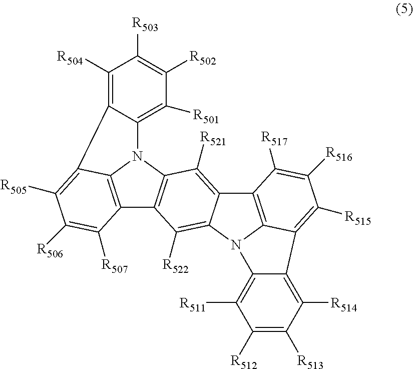

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded;
R₅₀₁ to R₅₀₇ and R₁₁₁ to R₅₁₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.
R₅₂₁ and R₅₂₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the emitting compound, R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
preferably, a substituted or unsubstituted alkyl group having 1 to 50 carbon atoms or a substituted or unsubstituted aryl group having 6 to 50 ring carbon atoms,
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₅₀₆, a combination of R₅₀₆ and R₅₀₇, and a combination of R₅₀₁, R₅₀₂, and R₅₀₃.

In an exemplary embodiment, the compound represented by the formula (5) is a compound represented by a formula (52) below.

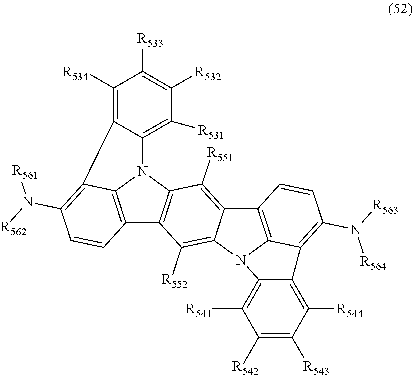

In the formula (52):
at least one combination of adjacent two or more of R₅₃₁ to R₅₃₄ and R₅₄₁ to R₅₄₄ are mutually bonded to form a substituted or unsubstituted monocyclic ring, mutually bonded to form a substituted or unsubstituted fused ring, or not mutually bonded;
R₅₃₁ to R₅₃₄ and R₅₄₁ to R₅₄₄ forming neither the substituted or unsubstituted monocyclic ring nor the substituted or unsubstituted fused ring, R₅₅₁ and R₅₅₂ are each independently a hydrogen atom, a substituted or unsubstituted aryl group having 6 to 50 ring carbon atoms, or a substituted or unsubstituted heterocyclic group having 5 to 50 ring atoms;
R₅₆₁ to R₅₆₄ are each independently a substituted or unsubstituted aryl group having 6 to 50 ring carbon atoms, or a substituted or unsubstituted heterocyclic group having 5 to 50 ring atoms.

### Compound Represented by Formula (6)

In an exemplary arrangement of the organic EL device of the exemplary embodiment, the emitting compound is a compound represented by a formula (6) below.

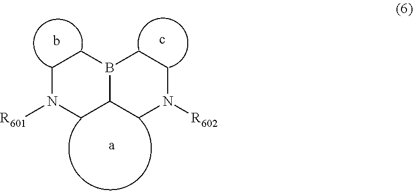

In the formula (6):
a ring a, a ring b and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀₂ are each independently bonded to the ring a, the ring b, or the ring c to form a substituted or unsubstituted heterocycle, or not bonded thereto to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, the ring a, the ring b, and the ring c are each a ring (a substituted or unsubstituted aromatic hydrocarbon ring having 6 to 50 ring carbon atoms, or a substituted or unsubstituted heterocycle having 5 to 50 ring atoms) fused with a fused bicyclic structure formed of a boron atom and two nitrogen atoms at the center of the formula (6).

The “aromatic hydrocarbon ring” for the rings a, b, and c has the same structure as a compound formed by introducing a hydrogen atom to the “aryl group” described above.

Ring atoms of the “aromatic hydrocarbon ring” for the ring a include three carbon atoms on the fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ may be each independently bonded with the ring a, the ring b, or the ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom, R₆₀₁ and R₉₀₂ being bonded with the ring a, the ring b, or the ring c specifically means that atoms forming R₆₀₁ and R₆₀₂ are bonded with atoms forming the ring a, the ring b, or the ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀₂ bonded with the ring a, and R₆₀₂ bonded with the ring c.

It is not indispensable that R₆₀₁ and R₆₀₂ are each independently bonded with the ring a, the ring b, or the ring c.

In an exemplary embodiment, the ring a, the ring b, and the ring c in the formula (6) are each independently a substituted or unsubstituted aromatic hydrocarbon ring having 6 to 50 ring carbon atoms.

In an exemplary embodiment, the ring a, the ring b, and the ring c in the formula (6) are each independently a substituted or unsubstituted benzene ring or a substituted or unsubstituted naphthalene ring.

In an exemplary embodiment, R₆₀₁ and R₆₀₂ in the formula (6) are each independently a substituted or unsubstituted aryl group having 6 to 50 ring carbon atoms, or a substituted or unsubstituted heterocyclic group having 5 to 50 ring atoms; and preferably, a substituted or unsubstituted aryl group having 6 to 50 ring carbon atoms.

In an exemplary embodiment, the compound represented by the formula (6) is a compound represented by a formula (62) below.

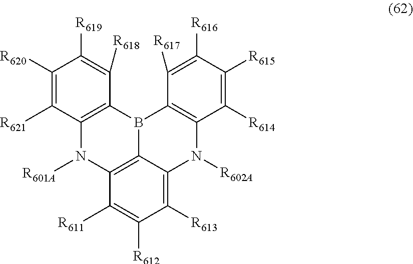

In the formula (62):
R_{601A} is bonded with at least one of R₆₁₁ or R₆₂₁ to form a substituted or unsubstituted heterocycle, or not bonded therewith to form no substituted or unsubstituted heterocycle;
R_{602A} is bonded with at least one of R₆₁₃ or R₆₁₄ to form a substituted or unsubstituted heterocycle, or not bonded therewith to form no substituted or unsubstituted heterocycle;
R_{601A} and R_{602A} not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one combination of adjacent two or more of R₆₁₁ to R₆₂₁ are mutually bonded to form a substituted or unsubstituted monocyclic ring, mutually bonded to form a substituted or unsubstituted fused ring, or not mutually bonded;
R₆₁₁ to R₆₂₁ not forming the substituted or unsubstituted heterocycle, not forming the substituted or unsubstituted monocyclic ring, and not forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms. In the formula (62), R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.
R_{601A} and R_{602A} in the formula (62) are groups corresponding to R₆₀₁ and R₆₀₂ in the formula (6), respectively.

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₁, R_{602A} bonded with R₆₁₃, and R_{602A} bonded with R₆₁₄.

At least one combination of adjacent two or more of R₆₁₁ to R₆₂₁ may be mutually bonded to form a substituted or unsubstituted monocyclic ring, or mutually bonded to form a substituted or unsubstituted fused ring.

For instance, R₆₁₁ and R₆₁₂ are optionally mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment, the compound represented by the formula (6) is a compound represented by a formula (42-2) below.

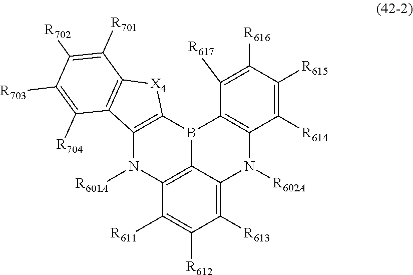

In the formula (42-2):
R₆₁₁ to R₆₁₇, R_{601A}, and R_{602A} each independently represent the same as R₆₁₁ to R₆₁₇, R_{601A}, and R_{602A} in the formula (62);
X₄ is an oxygen atom or a sulfur atom;
at least one combination of adjacent two or more of R₇₀₁ to R₇₀₄ are mutually bonded to form a substituted or unsubstituted monocyclic ring, mutually bonded to form a substituted or unsubstituted fused ring, or not mutually bonded;
R₇₀₁ to R₇₀₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (42-2), R₉₀₁, R₉₀₂, R₉₀₃, R₉₀₄, R₉₀₅, R₉₀₆, and R₉₀₇ each independently represent the same as R₉₀₁, R₉₀₂, R₉₀₃, R₉₀₄, R₉₀₅, R₉₀₆, and R₉₀₇ in the formula (62).

### Compound Represented by Formula (3A)

In an exemplary arrangement of the organic EL device of the exemplary embodiment, the emitting compound is a compound represented by a formula (3A) below.

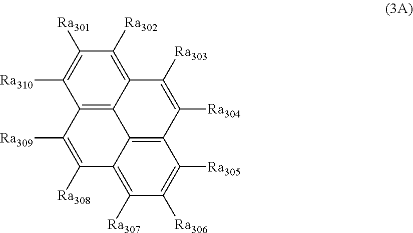

In the formula (3A):
at least one combination of adjacent two or more of Ra₃₀₁, Ra₃₀₂, Ra₃₀₃, Ra₃₀₄, Ra₃₀₅, Ra₃₀₆, Ra₃₀₇, Ra₃₀₈, Ra₃₀₈, and Ra₃₁₀ are mutually bonded to form a substituted or unsubstituted monocyclic ring, mutually bonded to form a substituted or unsubstituted fused ring, or not mutually bonded;
at least one of Ra₃₀₁ to Ra₃₁₀ is a monovalent group represented by a formula (31A) below; and
Ra₃₀₁ to Ra₃₁₀ not forming the monocyclic ring, not forming the fused ring, and not being the monovalent group represented by the formula (31A) are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

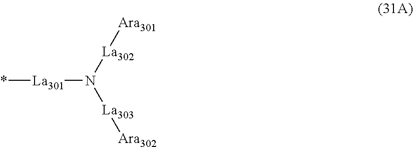

In the formula (31A):
Ara₃₀₁ and Ara₃₀₂ are each independently a substituted or unsubstituted aryl group having 6 to 50 ring carbon atoms, or a substituted or unsubstituted heterocyclic group having 5 to 50 ring atoms;
La₃₀₁, La₃₀₂, and La₃₀₃ are each independently a single bond, a substituted or unsubstituted arylene group having 6 to 30 ring carbon atoms, or a substituted or unsubstituted divalent heterocyclic group having 5 to 30 ring atoms; and
* represents a bonding position to a pyrene ring in the formula (3A).

### Specific Examples of Emitting Compound

Specific examples of the emitting compound are shown below. It should however be noted that these specific examples are merely exemplary and do not limit the emitting compound.

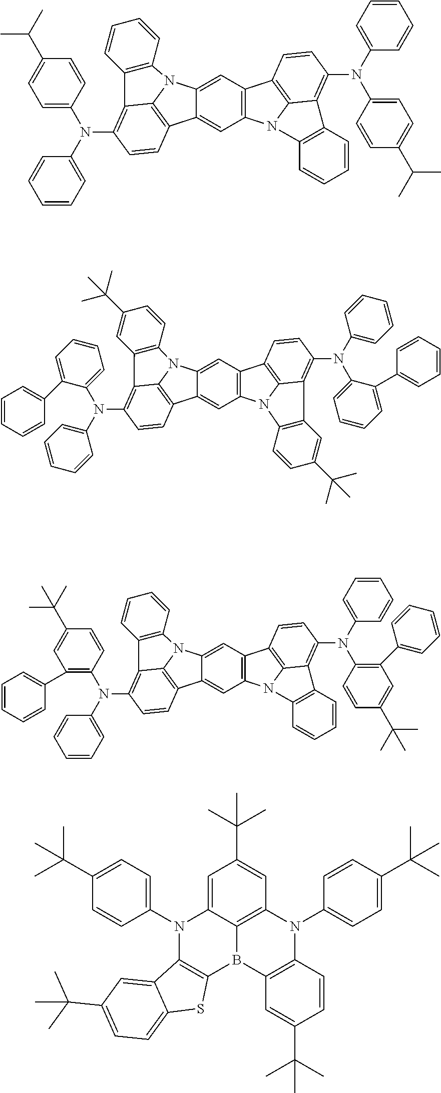

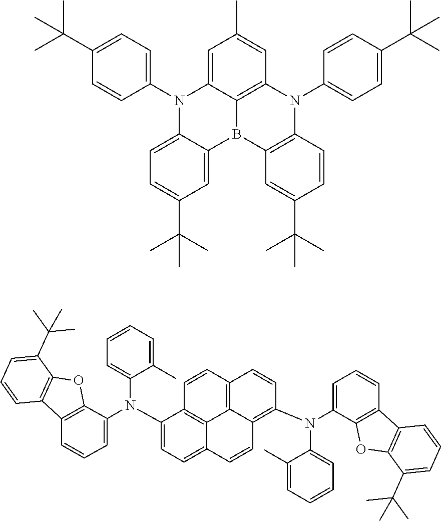 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; Cc1ccccc1N(c1ccc2ccc3c(N(c4ccccc4C)c4cccc5c4oc4c(C(C)(C)C)cccc45)ccc4ccc1c2c43)c1cccc2c1oc1c(C(C)(C)C)cccc12]

### Relationship Between First Host Material, Second Host Material, and Emitting Compound

In an exemplary arrangement of the organic EL device of the exemplary embodiment, a triplet energy of the first host material T₁(H1) and a triplet energy of the emitting compound T₁(D1) preferably satisfy a relationship of a numerical formula (Numerical Formula 6A) below.

T₁(D1)>T₁(H1) (Numerical Formula 6A)

When the first host material and the emitting compound satisfy the relationship of the numerical formula (Numerical Formula 6A), triplet excitons generated on the first host material do not transfer to the emitting compound having higher triplet energy. Triplet excitons generated on the emitting compound quickly energy-transfer to molecules of the first host material. That is, triplet excitons on the first host material collide with one another efficiently by TTF phenomenon without transferring to the emitting compound, thereby generating singlet excitons.

In an exemplary arrangement of the organic EL device of the exemplary embodiment, a triplet energy of the second host material T₁(H2) and a triplet energy of the emitting compound T₁(D1) preferably satisfy a relationship of a numerical formula (Numerical Formula 6B) below.

T₁(D1)>T₁(H2) (Numerical Formula 6B)

Similar to the case of the first host material, when the second host material and the emitting compound satisfy the relationship of the numerical formula (Numerical Formula 6B), triplet excitons on the second host material collide with one another efficiently by TTF phenomenon without transferring to the emitting compound, thereby generating singlet excitons.

In an exemplary arrangement of the organic EL device of the exemplary embodiment, a singlet energy of the first host material S₁(H1) and a singlet energy of the emitting compound S₁(D1) preferably satisfy a relationship of a numerical formula (Numerical Formula 5A) below. The singlet energy S₁ means an energy difference between a lowest singlet state and a ground state.

S₁(H1)>S₁(D1) (Numerical Formula 5A)

When the first host material and the emitting compound satisfy the relationship of the numerical formula (Numerical Formula 5A), singlet excitons generated on the first host material easily energy-transfer from the first host material to the emitting compound, thereby contributing to fluorescence of the emitting compound.

In an exemplary arrangement of the organic EL device of the exemplary embodiment, a singlet energy of the second host material S₁(H2) and a singlet energy of the emitting compound S₁(D1) preferably satisfy a relationship of a numerical formula (Numerical Formula 5B) below.

S₁(H2)>S₁(D1) (Numerical Formula 5B)

When the second host material and the emitting compound satisfy the relationship of the numerical formula (Numerical Formula 5B), singlet excitons generated on the second host material easily energy-transfer from the second host material to the emitting compound, thereby contributing to fluorescence of the emitting compound.

### Triplet Energy T₁

A method of measuring a triplet energy T₁ is exemplified by a method below.

A measurement target compound is dissolved in EPA (diethylether isopentane:ethanol=5:5:2 in volume ratio) so as to fall within a range from 10-mol/L to 10⁻⁴ mol/L, and the obtained solution is encapsulated in a quartz cell to provide a measurement sample. A phosphorescence spectrum (ordinate axis: phosphorescence intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value λ_{edge} [nm] at an intersection of the tangent and the abscissa axis. The calculated energy amount is defined as triplet energy T₁.

T₁ [eV]=1239.85/λ_{edge} Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (produced by Hitachi High-Technologies Corporation) is usable. Any device for phosphorescence measurement is usable. A combination of a cooling unit, a low temperature container, an excitation light source, and a light-receiving unit may be used for phosphorescence measurement.

### Singlet Energy S₁

A method of measuring a singlet energy S₁ with use of a solution (occasionally referred to as a solution method) is exemplified by a method below.

A toluene solution of a measurement target compound at a concentration ranging from 10⁻⁵ mol/L to 104 mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum on the long-wavelength side, and a wavelength value λedge (nm) at an intersection of the tangent and the abscissa axis is assigned to a conversion equation (F2) below to calculate singlet energy.

S₁ [eV]=1239.85/λ_{edge} Conversion Equation (F2):

Any device for measuring absorption spectrum is usable. For instance, a spectrophotometer (U3310 produced by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Additional Layers of Organic EL Device

In addition to the emitting layer(s) and the organic layer containing the compound represented by the formula (EB1), the organic EL device according to the exemplary embodiment may include one or more organic layers. Examples of the organic layer include at least one layer selected from the group consisting of a hole injecting layer, a hole transporting layer, an electron blocking layer, a hole blocking layer, an electron injecting layer, and an electron transporting layer.

The layers of the organic EL device according to the exemplary embodiment may consist of the emitting layer(s) and the organic layer containing the compound represented by the formula (EB1). Alternatively, the layers may further include, for instance, at least one layer selected from the group consisting of a hole injecting layer, a hole transporting layer, an electron blocking layer, a hole blocking layer, an electron injecting layer, and an electron transporting layer.

The FIGURE schematically shows an exemplary arrangement of an organic EL device according to the exemplary embodiment.

An organic EL device 1 includes a light-transmissive substrate 2, an anode 3, a cathode 4, and a plurality of organic layers 10 provided between the anode 3 and the cathode 4. The organic layers 10 of the organic EL device 1 include a hole injecting layer 61, a hole transporting layer 62, an electron blocking layer 63, an emitting layer 51, an electron transporting layer 71, and an electron injecting layer 72. In the organic EL device 1, the hole injecting layer 61, the hole transporting layer 62, the electron blocking layer 63, the emitting layer 51, the electron transporting layer 71, and the electron injecting layer 72 are layered on the anode 3 in this order. In the organic EL device 1, the hole transporting zone 6 includes the hole injecting layer 61, the hole transporting layer 62, and the electron blocking layer 63, and the emitting zone 5 includes the emitting layer 51.

The invention is not limited to the arrangement of the organic EL device shown in the FIGURE.

The arrangement of the organic EL device will be further described below. It should be noted that the reference numerals will be occasionally omitted below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Moreover, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, the alkali metal such as lithium (Li) and cesium (Cs), the alkaline earth metal such as magnesium (Mg), calcium (Ca) and strontium (Sr), alloys (e.g., MgAg and AlLi) including the alkali metal or the alkaline earth metal, the rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Electron Transporting Layer

Preferably, the organic EL device according to the exemplary embodiment includes the electron transporting layer between the cathode and the emitting layer.

The electron transporting layer is a layer containing a highly electron-transporting substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is suitably usable. The above-described substances mostly have an electron mobility of 10⁻⁶ cm²Ns or more. It should be noted that any substance other than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyridine-3,5-diyl)](abbreviation: PF-Py), poly[(9,9-dioctylfluorene-2,7-diyl)-co-(2,2′-bipyridine-6,6′-diyl)](abbreviation: PF-BPy) and the like are usable.

### Specific Examples of Electron Transporting Material

Specific examples of an electron transporting material usable for the electron transporting layer include compounds below. However, the invention is not limited to the specific examples of the electron transporting material.

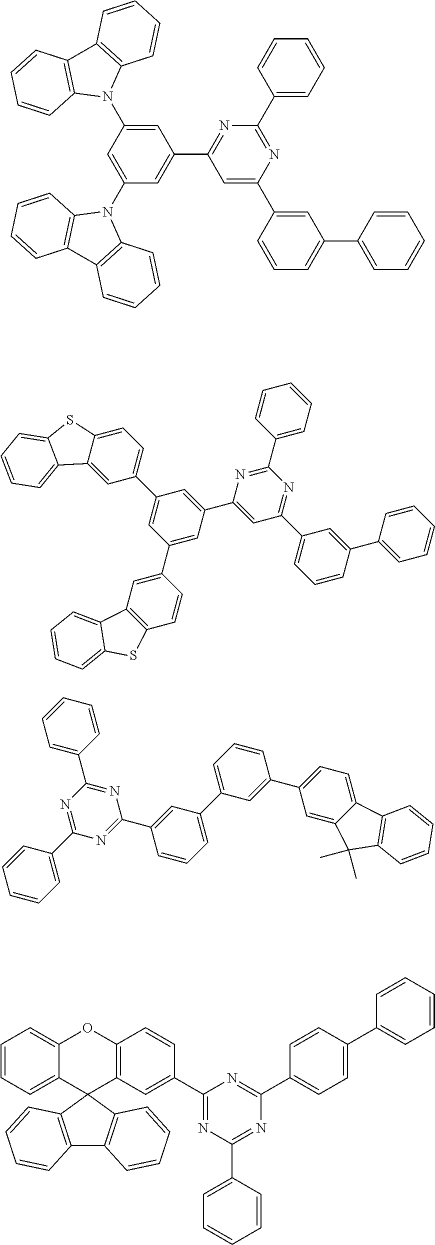

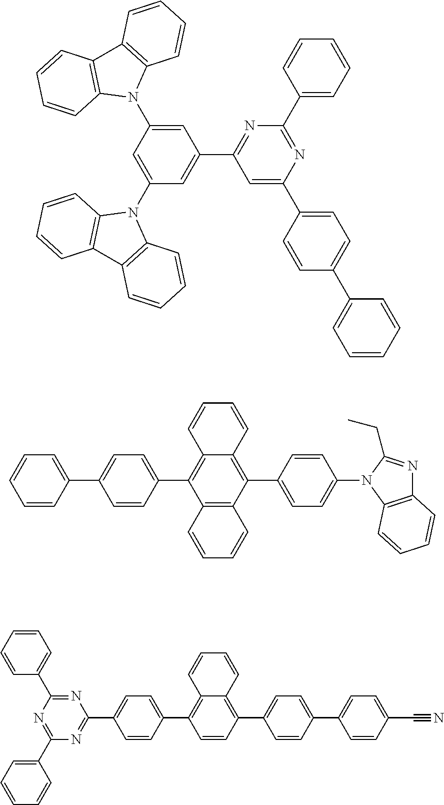 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; CCc1nc2ccccc2n1-c1ccc(-c2c3ccccc3c(-c3ccc(-c4ccccc4)cc3)c3ccccc23)cc1 ; N#Cc1ccc(-c2ccc(-c3ccc(-c4ccc(-c5nc(-c6ccccc6)nc(-c6ccccc6)n5)cc4)c4ccccc34)cc2)cc1]

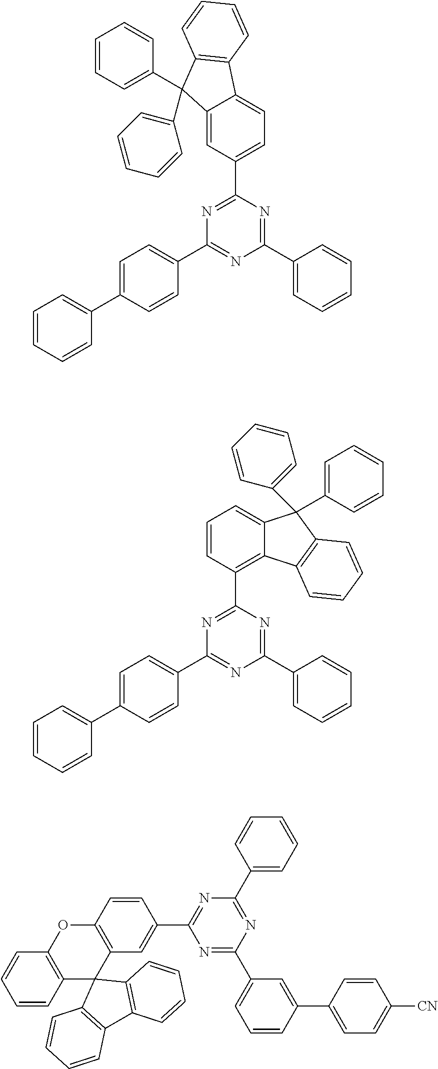 [SMILES: c1ccc(-c2ccc(-c3nc(-c4ccccc4)nc(-c4ccc5c(c4)C(c4ccccc4)(c4ccccc4)c4ccccc4-5)n3)cc2)cc1 ; c1ccc(-c2ccc(-c3nc(-c4ccccc4)nc(-c4cccc5c4-c4ccccc4C5(c4ccccc4)c4ccccc4)n3)cc2)cc1 ; N#Cc1ccc(-c2cccc(-c3nc(-c4ccccc4)nc(-c4ccc5c(c4)C4(c6ccccc6O5)c5ccccc5-c5ccccc54)n3)c2)cc1]

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

In the organic EL device of the exemplary embodiment, the emitting layer containing the first host material, the second host material, and the emitting compound is formable using a plurality of compounds by co-deposition; is formable, by vapor-deposition, using a mixture obtained by mixing in advance (premixing) a plurality of compounds; or formable, by coating, using a mixture obtained by mixing in advance (premixing) a plurality of compounds. The mixture obtained by mixing in advance (premixing) compounds may be powder or a solution. A method of mixing in advance a plurality of compounds is occasionally referred to as premix. The premix method is not particularly limited. For instance, a vapor-deposition ratio of compounds forming the mixture obtained by premix is adjustable by adjusting a substituent(s) or the like of the compound(s) forming the mixture to adjust a molecular weight of the compound(s) or adjusting its mixing ratio.

### Film Thickness

The film thickness of each of the organic layers of the organic EL device in the exemplary embodiment is not limited unless otherwise specified in the above. In general, the thickness preferably ranges from several nanometers to 1 μm because excessively small film thickness is likely to cause defects (e.g. pin holes) and excessively large thickness leads to the necessity of applying high voltage and consequent reduction in efficiency.

### Emission Wavelength of Organic EL Device

The organic electroluminescence device of the exemplary embodiment preferably emits, when being driven, light whose maximum peak wavelength is 500 nm or less or light whose maximum peak wavelength is in a range from 430 nm to 480 nm.

The maximum peak wavelength of the light emitted from the organic EL device when being driven is measured as follows. Voltage is applied to the organic EL device so that a current density is 10 mA/cm², where spectral radiance spectrum is measured by a spectroradiometer CS-2000 (produced by Konica Minolta, Inc.). A peak wavelength of an emission spectrum, at which the luminous intensity of the resultant spectral radiance spectrum is at the maximum, is measured and defined as a maximum peak wavelength (unit: nm).

### Second Exemplary Embodiment

### Electronic Device

An electronic device according to a second exemplary embodiment is installed with the organic EL device according to the above exemplary embodiment. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light. The light-emitting unit is also usable for a display device, for instance, as a backlight of the display device.

### Modification of Embodiment(s)

The scope of the invention is not limited to the above-described exemplary embodiments but includes any modification and improvement as long as such modification and improvement are compatible with the invention.

For instance, the number of emitting layers is not limited to one, and a plurality of emitting layers may be provided and layered with each other. When the organic EL device includes a plurality of emitting layers, it is only necessary that at least one of the emitting layers should satisfy the requirements described in the above exemplary embodiment. For instance, the rest of the emitting layers may be a fluorescent emitting layer or a phosphorescent emitting layer with use of emission caused by electron transfer from the triplet excited state directly to the ground state.

When the organic EL device includes a plurality of emitting layers, these emitting layers may be mutually adjacently provided, or may form a so-called tandem organic EL device, in which a plurality of emitting units are layered via an intermediate layer.

For instance, a blocking layer may be provided adjacent to at least one of a side of the emitting layer close to the anode or a side of the emitting layer close to the cathode. The blocking layer is preferably provided in contact with the emitting layer to block at least any of holes, electrons, excitons or combinations thereof.

For instance, when the blocking layer is provided in contact with the side of the emitting layer close to the cathode, the blocking layer permits transport of electrons and blocks holes from reaching a layer provided closer to the cathode (e.g., the electron transporting layer) beyond the blocking layer. When the organic EL device includes the electron transporting layer, the blocking layer is preferably interposed between the emitting layer and the electron transporting layer.

When the blocking layer is provided in contact with the side of the emitting layer close to the anode, the blocking layer permits transport of holes and blocks electrons from reaching a layer provided closer to the anode (e.g., the hole transporting layer) beyond the blocking layer. When the organic EL device includes the hole transporting layer, the blocking layer is preferably interposed between the emitting layer and the hole transporting layer.

Alternatively, the blocking layer may be provided adjacent to the emitting layer so that excitation energy does not leak out from the emitting layer toward neighboring layer(s). The blocking layer blocks excitons generated in the emitting layer from being transferred to a layer(s) (e.g., the electron transporting layer and the hole transporting layer) closer to the electrode(s) beyond the blocking layer.

The emitting layer is preferably bonded with the blocking layer.

Specific structure, shape and the like of the components in the invention may be designed in any manner as long as an object of the invention can be achieved.

### EXAMPLES

The invention will be described in further detail with reference to Examples. It should be noted that the scope of the invention is by no means limited to Examples.

### Compounds

Structures of compounds represented by the formula (EB1) that were used for producing organic EL devices in Examples 1-1 to 1-5, 2-1 to 2-4, and 3-1 are shown below.

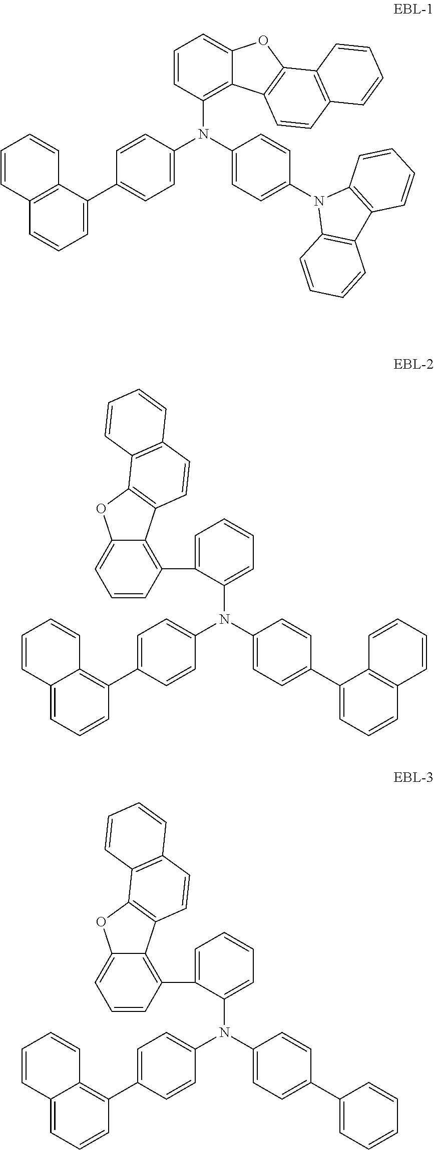 [SMILES: c1ccc2c(-c3ccc(N(c4ccc(-n5c6ccccc6c6ccccc65)cc4)c4cccc5oc6c7ccccc7ccc6c45)cc3)cccc2c1 ; c1ccc(N(c2ccc(-c3cccc4ccccc34)cc2)c2ccc(-c3cccc4ccccc34)cc2)c(-c2cccc3oc4c5ccccc5ccc4c23)c1 ; c1ccc(-c2ccc(N(c3ccc(-c4cccc5ccccc45)cc3)c3ccccc3-c3cccc4oc5c6ccccc6ccc5c34)cc2)cc1]

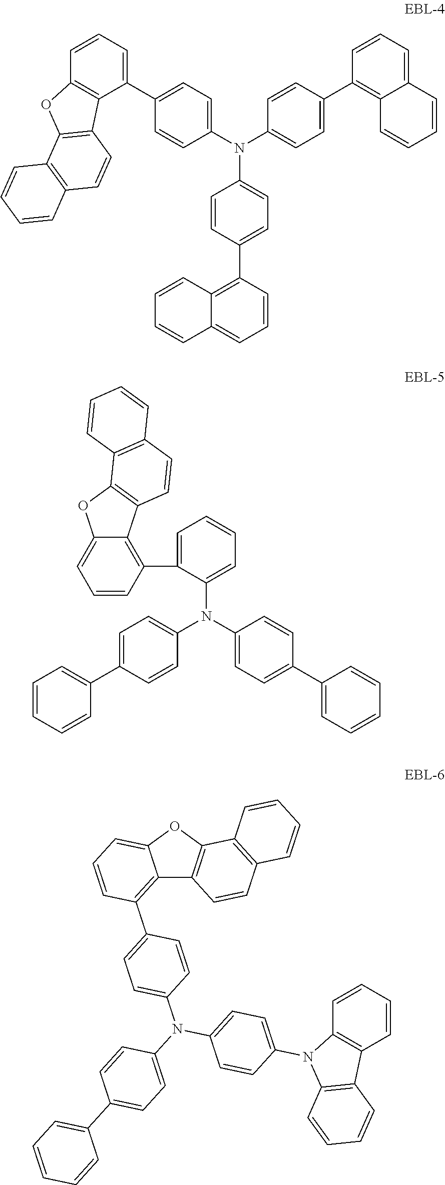 [SMILES: c1ccc2c(-c3ccc(N(c4ccc(-c5cccc6ccccc56)cc4)c4ccc(-c5cccc6oc7c8ccccc8ccc7c56)cc4)cc3)cccc2c1 ; c1ccc(-c2ccc(N(c3ccc(-c4ccccc4)cc3)c3ccccc3-c3cccc4oc5c6ccccc6ccc5c34)cc2)cc1 ; c1ccc(-c2ccc(N(c3ccc(-c4cccc5oc6c7ccccc7ccc6c45)cc3)c3ccc(-n4c5ccccc5c5ccccc54)cc3)cc2)cc1]

Structures of comparative compounds used for producing organic EL devices in Comparatives (Comparative Examples) 1-1, 2-1, and 3-1 are shown below.

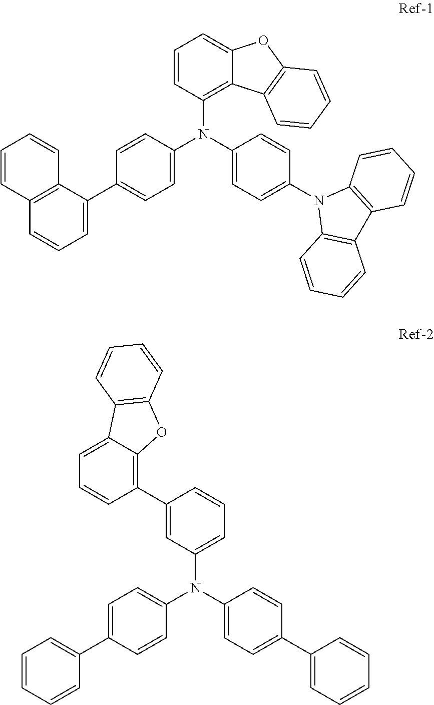 [SMILES: c1ccc2c(-c3ccc(N(c4ccc(-n5c6ccccc6c6ccccc65)cc4)c4cccc5oc6ccccc6c45)cc3)cccc2c1 ; c1ccc(-c2ccc(N(c3ccc(-c4ccccc4)cc3)c3cccc(-c4cccc5c4oc4ccccc45)c3)cc2)cc1]

Structures of other compounds used for producing organic EL devices in Examples 1-1 to 1-5, 2-1 to 2-4, and 3-1 and Comparatives 1-1, 2-1, and 3-1 are shown below.

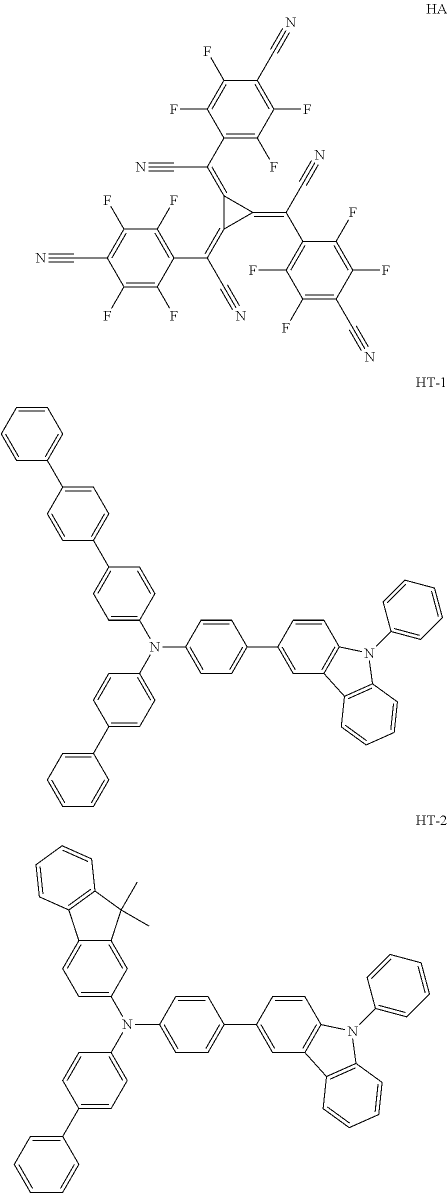

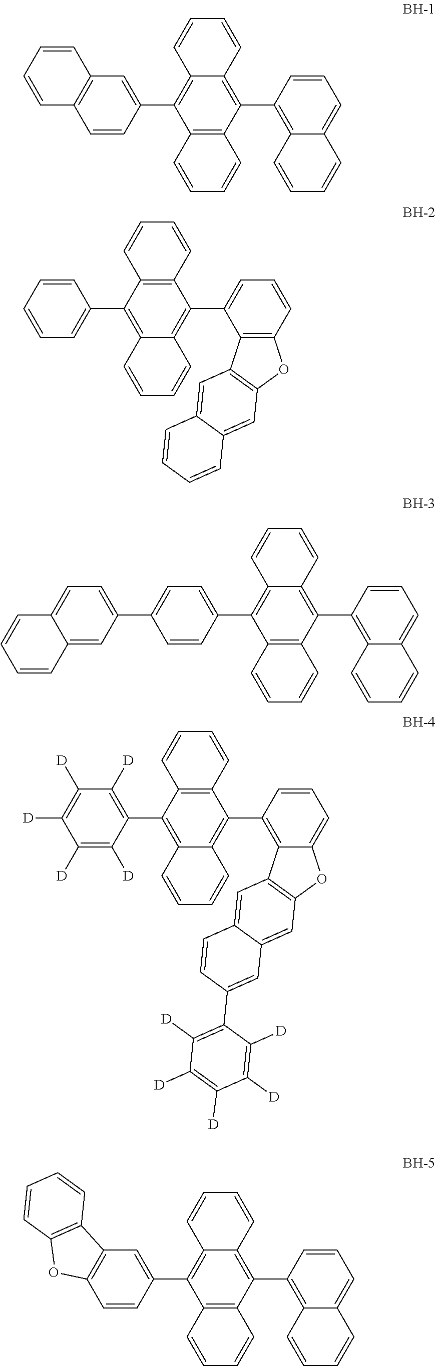

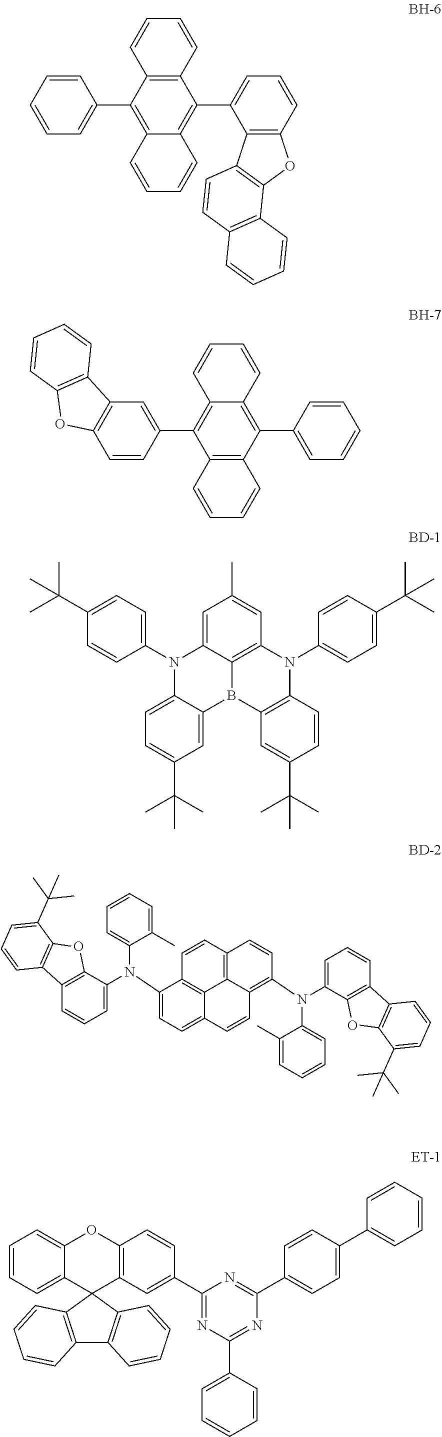

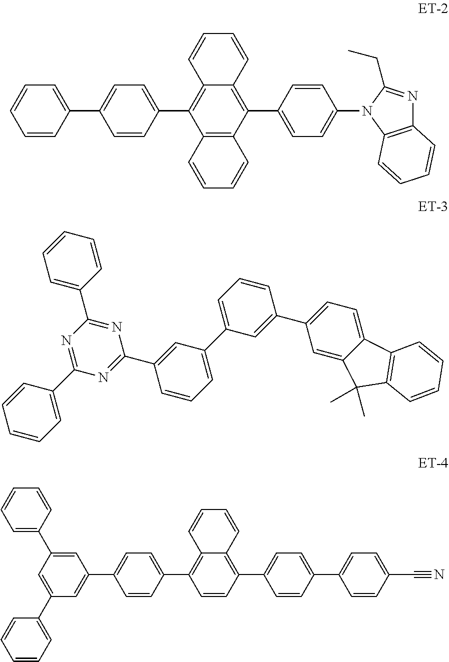 [SMILES: CCc1nc2ccccc2n1-c1ccc(-c2c3ccccc3c(-c3ccc(-c4ccccc4)cc3)c3ccccc23)cc1 ; CC1(C)c2ccccc2-c2ccc(-c3cccc(-c4cccc(-c5nc(-c6ccccc6)nc(-c6ccccc6)n5)c4)c3)cc21 ; N#Cc1ccc(-c2ccc(-c3ccc(-c4ccc(-c5cc(-c6ccccc6)cc(-c6ccccc6)c5)cc4)c4ccccc34)cc2)cc1]

### Production (1) of Organic EL Devices

Organic EL devices were produced as follows.

### Example 1-1

A glass substrate (size: 25 mm×75 mm×1.1 mm thick, produced by Geomatec Co., Ltd.) having an ITO (Indium Tin Oxide) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-1 and a compound HA were co-deposited on a surface of the glass substrate, where the transparent electrode line was provided, to cover the transparent electrode, thereby forming a 10-nm-thick hole injecting layer. The ratios of the compound HT-1 and the compound HA in the hole injecting layer were 97 mass % and 3 mass %, respectively.

The compound HT-1 was vapor-deposited on the hole injecting layer to form a 75-nm-thick hole transporting layer.

A compound EBL-1 was vapor-deposited on the hole transporting layer to form a 7.5-nm-thick electron blocking layer.

A compound BH-1 (first host material), a compound BH-2 (second host material), and a compound BD-1 (emitting compound) were co-deposited on the electron blocking layer to form a 20-nm-thick emitting layer. The ratios of the host materials (the total of compounds BH-1 and BH-2) and the compound BD-1 in the emitting layer were 98 mass % and 2 mass %, respectively. The mass ratio between the compound BH-1 and the compound BH-2 was 60:40.

A compound ET1 was vapor-deposited on the emitting layer to form a 3-nm-thick first electron transporting layer. The first electron transporting layer is occasionally referred to as hole blocking layer.

A compound ET-2 and a compound Liq were co-deposited on the first electron transporting layer to form a 30-nm-thick second electron transporting layer. The ratios of the compound ET-2 and the compound Liq in the second electron transporting layer were 67 mass % and 33 mass %, respectively. Liq is an abbreviation of (8-quinolinolato)lithium ((8-Quinolinolato)lithium).

A compound LiF (lithium fluoride) and ytterbium (Yb) were co-deposited on the second electron transporting layer to form a 1-nm-thick electron injecting layer. The ratios of the compound LiF and the ytterbium (Yb) in the electron injecting layer were 50 mass % and 50 mass %, respectively.

Metal Al was vapor-deposited on the electron injecting layer to form an 80-nm-thick cathode.

A device arrangement of the organic EL device of Example 1-1 is roughly shown as follows.

ITO(130)/HT-1:HA(10.97%:3%)/HT-1(75)/EBL-1(7.5)/BH-1:BH-2:BD-1(20.98%:2%)/ET-1(3)/ET-2:Liq(30.67%:33%)/LiF:Yb(1.50%:50%)/Al(80)

Numerals in parentheses represent a film thickness (unit: nm).

Regarding the device arrangement of the organic EL device in Example 1-1, the numerals (97%:3%) represented by percentage in the same parentheses indicate a ratio (mass %) between the compound HT-1 and the compound HA in the hole injecting layer, the numerals (98%:2%) represented by percentage in the same parentheses indicate a ratio (mass %) between the host materials (the total of compounds BH-1 and BH-2) and the emitting compound (compound BD-1) in the emitting layer, the numerals (67%:33%) represented by percentage in the same parentheses indicate a ratio (mass %) between the compound ET-2 and the compound Liq in the second electron transporting layer, and the numerals (50%:50%) represented by percentage in the same parentheses indicate a ratio (mass %) between the compound LiF and Yb in the electron injecting layer. Similar notations apply to the description below.

### Example 1-2 to Example 1-5

The organic EL devices in Example 1-2 to Example 1-5 were produced in the same manner as in Example 1-1 except that the third compound (compound EBL-1) used for forming the electron blocking layer was replaced with the third compound shown in Table 2.

### Comparative 1-1

The organic EL device in Comparative 1-1 was produced in the same manner as in Example 1-1 except that the third compound (compound EBL-1) used for forming the electron blocking layer was replaced with the third compound shown in Table 2.

### Evaluation (1) of Organic EL Devices

The respective organic EL devices produced in Examples 1-1 to 1-5 and Comparative 1-1 were evaluated as follows. Table 2 shows evaluation results.

### Drive Voltage

There was measured a voltage (unit: V) when electric current was applied between the anode and the cathode of the organic EL device produced in each Example so that the current density was 10 mA/cm². Table 2 shows a difference ΔV between a drive voltage in each Example and a drive voltage in Comparative 1-1, which was calculated based on a numerical formula (Numerical Formula X1) below.

ΔV=(Drive Voltage in each Example)−(Drive Voltage in Comparative 1-1) (Numerical Formula X1)

### Lifetime LT95

Voltage was applied to the organic EL device produced in each Example so that a current density was 50 mA/cm², where a time (LT95 (unit: h)) elapsed before a luminance intensity was reduced to 95% of the initial luminance intensity was measured as a lifetime. The luminance intensity was measured by a spectroradiometer CS-2000 (produced by Konica Minolta, Inc.).

Table 2 shows relative values of LT95 calculated based on a numerical formula (Numerical Formula X2) below. The unit for the relative value of LT95 is %.

LT95(Relative Value)=(LT95 in each Example/LT95 in Comparative 1-1)×100 (Numerical Formula X2)

TABLE 2

| | Electron blocking layer | | Emitting layer | | | | Device evaluation | | |
|---|---|---|---|---|---|---|---|---|---|
| | Third compound | | First host material | | Second host material | | | | LT95 |
| | | Hole mobility | | Ratio | | Ratio | | | (Relative |
| | Name | [cm²/Vs] | Name | [mass %] | Name | [mass %] | ΔV | | value) |
| Ex. 1-1 | EBL-1 | 2.50 × 10⁻⁵ | BH-1 | 60 | BH-2 | 40 | −0.06 | V | 133% |
| Ex. 1-2 | EBL-2 | 1.61 × 10⁻⁵ | BH-1 | 60 | BH-2 | 40 | −0.04 | V | 148% |
| Ex. 1-3 | EBL-3 | 4.37 × 10⁻⁵ | BH-1 | 60 | BH-2 | 40 | −0.08 | V | 192% |
| Ex. 1-4 | EBL-4 | 2.08 × 10⁻⁵ | BH-1 | 60 | BH-2 | 40 | −0.07 | V | 168% |
| Ex. 1-5 | EBL-6 | 3.14 × 10⁻⁵ | BH-1 | 60 | BH-2 | 40 | −0.14 | V | 130% |
| Comp. 1-1 | Ref-1 | 9.64 × 10⁻⁸ | BH-1 | 60 | BH-2 | 40 | 0.00 | V | 100% |

As shown in Table 2, the organic EL devices in Examples 1-1 to 1-5 each had a lower drive voltage and longer lifetime than Comparative 1-1. It was found out that, when the compound represented by the formula (EB1) was used for the electron blocking layer, the organic EL device was driven at low voltage and had a long lifetime.

### Production (2) of Organic EL Devices

Organic EL devices were produced as follows.

### Example 2-1

The organic EL device in Example 2-1 was produced in the same manner as in Example 1-1 except that the first host material (compound EH-1) and the second host material (compound EH-2) used for forming the emitting layer were replaced with the first host material and the second host material shown in Table 3.

A device arrangement of the organic EL device of Example 2-1 is roughly shown as follows.

ITO(130)/HT-1:HA(10.97%:3%)/HT-1(75)/EEL-1(7.5)/BH-3:BH-4:BD-1(20.98%:2%)/ET-1(3)/ET-2:Liq(30.67%:33%)/LiF:Yb(1.50%:50%)/Al(80)

### Example 2-2 to Example 2-4

The organic EL devices in Example 2-2 to Example 2-4 were produced in the same manner as in Example 2-1 except that the third compound (compound EBL-1) used for forming the electron blocking layer was replaced with the third compound shown in Table 3.

### Comparative 2-1

The organic EL device in Comparative 2-1 was produced in the same manner as in Example 2-1 except that the third compound (compound EBL-1) used for forming the electron blocking layer was replaced with the third compound shown in Table 3.

### Evaluation (2) of Organic EL Devices

The respective organic EL devices produced in Examples 2-1 to 2-4 and Comparative 2-1 were evaluated in the same manner as in Evaluation (1) of Organic EL Devices. Table 3 shows evaluation results. AV shown in Table 3 was calculated based on a numerical formula (Numerical Formula X3) below, and a relative value of LT95 was calculated based on a numerical formula (Numerical Formula X4) below.

ΔV=(Drive Voltage in each Example)−(Drive Voltage in Comparative 2-1) (Numerical Formula X3)

LT95(Relative Value)=(LT95 in each Example/LT95 in Comparative 2-1)×100 (Numerical Formula X4)

TABLE 3

| | Electron blocking layer | | Emitting layer | | | | Device evaluation | | |
|---|---|---|---|---|---|---|---|---|---|
| | Third compound | | First host material | | Second host material | | | | LT95 |
| | | Hole mobility | | Ratio | | Ratio | | | (Relative |
| | Name | [cm²/Vs] | Name | [mass %] | Name | [mass %] | ΔV | | value) |
| Ex. 2-1 | EBL-1 | 2.50 × 10⁻⁵ | BH-3 | 60 | BH-4 | 40 | −0.07 | V | 129% |
| Ex. 2-2 | EBL-2 | 1.61 × 10⁻⁵ | BH-3 | 60 | BH-4 | 40 | −0.06 | V | 140% |
| Ex. 2-3 | EBL-3 | 4.37 × 10⁻⁵ | BH-3 | 60 | BH-4 | 40 | −0.12 | V | 178% |
| Ex. 2-4 | EBL-4 | 2.08 × 10⁻⁵ | BH-3 | 60 | BH-4 | 40 | −0.12 | V | 159% |
| Comp. 2-1 | Ref-1 | 9.64 × 10⁻⁶ | BH-3 | 60 | BH-4 | 40 | 0.00 | V | 100% |

As shown in Table 3, the organic EL devices in Examples 2-1 to 2-4 each had a lower drive voltage and longer lifetime than Comparative 2-1. It was found out that, when the compound represented by the formula (EB1) was used for the electron blocking layer, the organic EL device was driven at low voltage and had a long lifetime.

### Production (3) of Organic EL Devices

Organic EL devices were produced as follows.

### Example 3-1

A glass substrate (size: 25 mm×75 mm×1.1 mm thick, produced by Geomatec Co., Ltd.) having an ITO (Indium Tin Oxide) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-2 and the compound HA were co-deposited on a surface of the glass substrate, where the transparent electrode line was provided, to cover the transparent electrode, thereby forming a 10-nm-thick hole injecting layer. The ratios of the compound HT-2 and the compound HA in the hole injecting layer were 97 mass % and 3 mass %, respectively.

The compound HT-2 was vapor-deposited on the hole injecting layer to form an 80-nm-thick hole transporting layer.

A compound EBL-5 was vapor-deposited on the hole transporting layer to form a 10-nm-thick electron blocking layer.

A compound BH-5 (first host material), a compound BH-6 (second host material), and a compound BD-2 (emitting compound) were co-deposited on the electron blocking layer to form a 25-nm-thick emitting layer. The ratios of the host materials (the total of compounds BH-5 and BH-6) and the compound BD-2 in the emitting layer were 96 mass % and 4 mass %, respectively. The mass ratio between the compound BH-5 and the compound BH-6 was 50:50.

A compound ET-3 was vapor-deposited on the emitting layer to form a 5-nm-thick first electron transporting layer. The first electron transporting layer is occasionally referred to as hole blocking layer.

A compound ET-4 and the compound Liq were co-deposited on the first electron transporting layer to form a 20-nm-thick second electron transporting layer. The ratios of the compound ET-4 and the compound Liq in the second electron transporting layer were 50 mass % and 50 mass %, respectively.

The compound LiF was vapor-deposited on the second electron transporting layer to form a 1-nm-thick electron injecting layer.

Metal Al was vapor-deposited on the electron injecting layer to form a 50-nm-thick cathode.

A device arrangement of the organic EL device of Example 3-1 is roughly shown as follows.

ITO(130)/HT-2:HA(10.97%:3%)/HT-2(80)/EBL-5(10)/BH-5:BH-6:BD-2(25.96%:4%)/ET-3(5)/ET-4:Liq(20.50%:50%)/LiF(1)/Al(50)

### Comparative 3-1

The organic EL device in Comparative 3-1 was produced in the same manner as in Example 3-1 except that the third compound (compound EBL-5) used for forming the electron blocking layer was replaced with the third compound shown in Table 4 and that the first host material and the emitting compound were used for forming the emitting layer. In Comparative 3-1, a compound BH-7 (first host material) and the compound BD-2 (emitting compound) were co-deposited on the electron blocking layer to form a 25-nm-thick emitting layer. The ratios of the compound BH-7 and the compound BD-2 in the emitting layer were 96 mass % and 4 mass %, respectively. The emitting layer of the organic EL device in Comparative 3-1 was formed using only one host material, specifically, the emitting layer was formed using only the first host material without the second host material.

### Evaluation (3) of Organic EL Devices

The respective organic EL devices produced in Example 3-1 and Comparative 3-1 were evaluated in the same manner as in Evaluation (1) of Organic EL Devices. Table 4 shows evaluation results. ΔV shown in Table 4 was calculated based on a numerical formula (Numerical Formula X5) below, and a relative value of LT95 was calculated based on a numerical formula (Numerical Formula X6) below.

Δ∇=(Drive Voltage in each Example)−(Drive Voltage in Comparative 3-1) (Numerical Formula X5)

LT95(Relative Value)=(LT95 in each Example/LT95 in Comparative 3-1)×100 (Numerical Formula X6)

TABLE 4

| | Electron blocking layer | | Emitting layer | | | | Device evaluation | | |
|---|---|---|---|---|---|---|---|---|---|
| | Third compound | | First host material | | Second host material | | | | LT95 |
| | | Hole mobility | | Ratio | | Ratio | | | (Relative |
| | Name | [cm²/Vs] | Name | [mass %] | Name | [mass %] | ΔV | | value) |
| Ex. 3-1 | EBL-5 | 6.57 × 10⁻⁵ | BH-5 | 50 | BH-6 | 50 | −0.04 | V | 118% |
| Comp. 3-1 | Ref-2 | — | BH-7 | 100 | — | — | 0.00 | V | 100% |

The emitting layer of the organic EL device in Comparative 3-1 contained only one host material. The organic EL device in Example 3-1, in which two host materials were used and the compound represented by the formula (EB1) was used for the electron blocking layer, had a lower drive voltage and longer lifetime than Comparative 3-1, as shown in Table 4. It was found out that, when two or more host materials were used for the emitting layer and the compound represented by the formula (EB1) was used for the electron blocking layer in the organic EL device, the organic EL device was driven at low voltage and had a long lifetime.

### Evaluation of Compounds

The above-described compounds were evaluated as follows. Tables 2 to 4 show evaluation results.

### Hole Mobility

Hole mobility PH was measured using a mobility evaluation device produced by the following steps.

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of ITO was 130 nm.

After the glass substrate was cleaned, the glass substrate was mounted on a substrate holder of a vacuum evaporation apparatus. First, a compound HA-2 was vapor-deposited on a surface of the glass substrate, where the transparent electrode line was provided, to cover the transparent electrode, thereby forming a 5-nm-thick hole injecting layer.

A compound HT-A was vapor-deposited on this formed hole transporting layer to form a 10-nm-thick hole transporting layer.

Subsequently, a compound Target to be measured for a hole mobility pH was vapor-deposited to form a 200-nm-thick measurement target layer.

Metal aluminum (Al) was vapor-deposited on this measurement target layer to form an 80-nm-thick metal cathode.

An arrangement of the mobility evaluation device above is roughly shown as follows.

ITO(130)/HA-2(5)/HT-A(10)/Target(200)/Al(80)

Numerals in parentheses represent a film thickness (unit: nm).

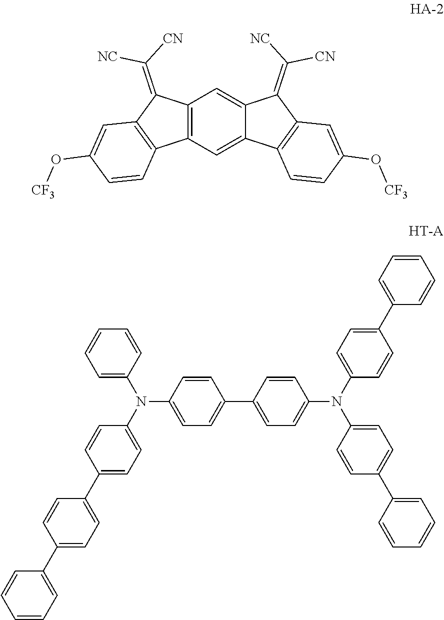 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

Subsequently, the hole mobility is measured by the following steps using the mobility evaluation device prepared as described above.

The mobility evaluation device was set in an impedance measurement device to perform impedance measurement.

In the impedance measurement, a measurement frequency was swept from 1 Hz to 1 MHz. At this time, an alternating current amplitude of 0.1 V and a direct current voltage V were applied to the device.

A modulus M was calculated from a measured impedance Z using a relationship of a calculation formula (C1) below.

M=jωZ Calculation Formula (C1):

In the calculation formula (C1), j is an imaginary unit whose square is −1 and ω is an angular frequency [rad/s].

In a bode plot in which an imaginary part of the modulus M is represented by an ordinate axis and the frequency [Hz] is represented by an abscissa axis, an electrical time constant τ of the mobility evaluation device was obtained from a frequency fmax showing a peak using a calculation formula (C2) below.

τ=1/(2πfmax) Calculation Formula (C2):

π in the calculation formula (C2) is a symbol representing a circumference ratio.

The hole mobility μ_{H} was calculated from a relationship of a calculation formula (C3) below using τ.

μ_{H}=d²/(Vτ) Calculation Formula (C3):

d in the calculation formula (C3) is a total film thickness of organic thin film(s) forming the device. As in the arrangement of the mobility evaluation device, d=215 [nm] is satisfied.

The mobility herein is a value obtained when a square root of an electric field intensity meets E^{1/2}=500 [V^{1/2}/cm^{1/2}]. The square root of the electric field intensity, E^{1/2}, can be calculated from a relationship of a calculation formula (C4) below.

E^{1/2}=V^{1/2}/d^{1/2} Calculation Formula (C4):

For the impedance measurement in Examples, a 1260 type by Solartron Analytical was used as the impedance measurement device, and a 1296 type dielectric constant measurement interface by Solartron Analytical was used together therewith to enhance measurement accuracy.

What is claimed is:

1. An organic electroluminescence device comprising:
an anode;
a cathode;
an emitting zone provided between the anode and the cathode; and
a hole transporting zone provided between the anode and the emitting zone, wherein
the emitting zone comprises at least one emitting layer, a first host material, a second host material, and an emitting compound being contained in a single emitting layer included in the at least one emitting layer,
the first host material and the second host material are each independently a compound represented by a formula (1) below, the first host material and the second host material being mutually different, and
the hole transporting zone comprises one or more organic layers, and at least one of the organic layers comprises a third compound represented by a formula (EB1) below, 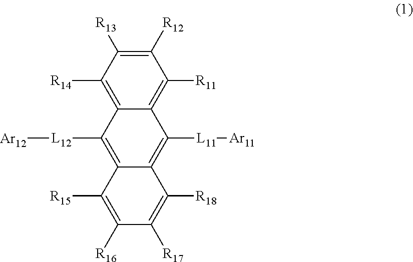
where, in the formula (1):
R₁₁ to R₁₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₁ and L₁₂ are each independently a single bond, a substituted or unsubstituted arylene group having 6 to 50 ring carbon atoms, or a substituted or unsubstituted divalent heterocyclic group having 5 to 50 ring atoms; and
Ar₁₁ and Ar₁₂ are each independently a substituted or unsubstituted aryl group having 6 to 50 ring carbon atoms, or a substituted or unsubstituted heterocyclic group having 5 to 50 ring atoms, 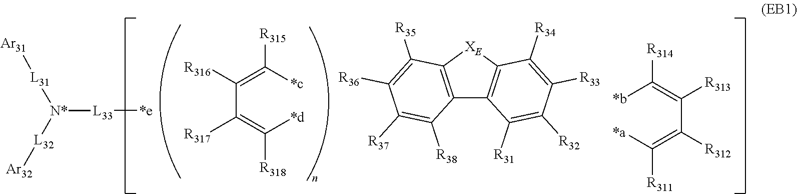
where, in the formula (EB1):
N* is a central nitrogen atom;
R₃₁ to R₃₈ and R₃₁₁ to R₃₁₈ are each independently a hydrogen atom, a halogen atom, a cyano group, a nitro group, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms;
n is 0 or 1;
when n is 0,
one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b;
one selected from R₃₁ to R₃₄ being neither the single bond with *a nor the single bond with *b, R₃₅ to R₃₈, and R₃₁₁ to R₃₁₄ is a single bond with *e;
when n is 1,
one of R₃₁ and R₃₂, one of R₃₂ and R₃₃, or one of R₃₃ and R₃₄ is a single bond with *a, and the other of R₃₁ and R₃₂, the other of R₃₂ and R₃₃, or the other of R₃₃ and R₃₄ is a single bond with *b;
one of R₃₅ and R₃₆, one of R₃₆ and R₃₇, or one of R₃₇ and R₃₈ is a single bond with *c, and the other of R₃₅ and R₃₆, the other of R₃₆ and R₃₇, or the other of R₃₇ and R₃₈ is a single bond with *d;
one selected from R₃₁ to R₃₄ being neither the single bond with *a nor the single bond with *b, R₃₅ to R₃₈ being neither the single bond with *c nor the single bond with *d, R₃₁₁ to R₃₁₄, and R₃₁₅ to R₃₁₈ is a single bond with *e;
X_{E} is an oxygen atom or a sulfur atom;
Ar₃₁ and Ar₃₂ are each independently a substituted or unsubstituted aryl group having 6 to 30 ring carbon atoms, or a substituted or unsubstituted heterocyclic group having 5 to 30 ring atoms;
L₃₁ to L₃₃ are each independently a single bond, a substituted or unsubstituted arylene group having 6 to 30 ring carbon atoms, or a substituted or unsubstituted divalent heterocyclic group having 5 to 30 ring atoms;
in the first host material, the second host material, and the third compound, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

2. The organic electroluminescence device according to claim 1, wherein the hole transporting zone comprises two or more organic layers, and at least one of the organic layers comprises the third compound represented by the formula (EB1).

3. The organic electroluminescence device according to claim 1, wherein the hole transporting zone comprises three or more organic layers, and at least one of the organic layers comprises the third compound represented by the formula (EB1).

4. The organic electroluminescence device according to claim 1, wherein one of the organic layers comprised in the hole transporting zone and disposed closest to the cathode comprises the third compound represented by the formula (EB1).

5. The organic electroluminescence device according to claim 1, wherein R₃₈ is a single bond with *e.

6. The organic electroluminescence device according to claim 1, wherein the third compound represented by the formula (EB1) is a compound represented by any of formulae (EB11) to (EB13) below, 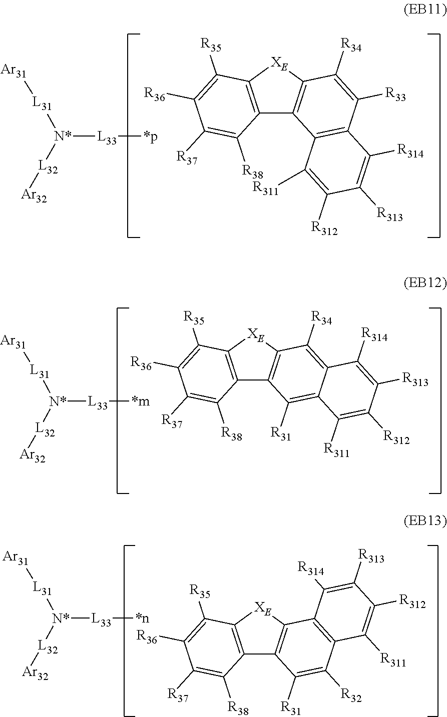
where, in the formulae (EB11) to (EB13):
N*, R₃₁ to R₃₈, R₃₁₁ to R₃₁₄, X_{E}, Ar₃₁, Ar₃₂, and L₃₁ to L₃₃ respectively represent the same as those defined in the formula (EB1);
when the compound represented by the formula (EB1) is a compound represented by the formula (EB11), one selected from R₃₃ to R₃₈ and R₃₁₁ to R₃₁₄ is a single bond with *p;
when the compound represented by the formula (EB1) is a compound represented by the formula (EB12), one selected from R₃₁, R₃₄ to R₃₈, and R₃₁₁ to R₃₁₄ is a single bond with *m; and
when the compound represented by the formula (EB1) is a compound represented by the formula (EB13), one selected from R₃₁, R₃₂, R₃₅ to R₃₈, and R₃₁₁ to R₃₁₄ is a single bond with *n.

7. The organic electroluminescence device according to claim 6, wherein the compound represented by the formula (EB1) is a compound represented by the formula (EB13).

8. The organic electroluminescence device according to claim 6, wherein R₃₈ in the formula (EB11), (EB12), or (EB13) is a single bond with *p, *m, or *n.

9. The organic electroluminescence device according to claim 1, wherein L₃₃ is a substituted or unsubstituted phenylene group.

10. The organic electroluminescence device according to claim 1, wherein L₃₃ is an unsubstituted phenylene group.

11. The organic electroluminescence device according to claim 1, wherein L₃₃ is a substituted or unsubstituted o-phenylene group or a substituted or unsubstituted p-phenylene group.

12. The organic electroluminescence device according to claim 1, wherein the compound represented by the formula (EB1) is a compound represented by a formula (EB131) below, 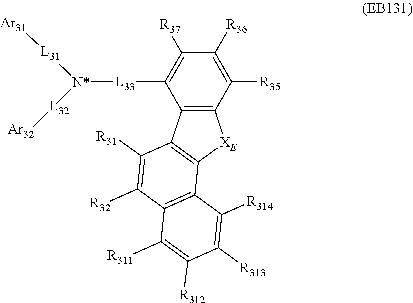
where, in the formula (EB131), N*, R₃₁, R₃₂, R₃₅ to R₃₇, R₃₁₁ to R₃₁₄, X_{E}, Ar₃₁, Ar₃₂, and L₃₁ to L₃₃ respectively represent the same as those defined in the formula (EB1).

13. The organic electroluminescence device according to claim 1, wherein X_{E} is an oxygen atom.

14. The organic electroluminescence device according to claim 1, wherein Ari and Ar₃₂ in the formula (EB1) are each independently a group represented by any of formulae (1-a) to (1-f) below;
when Ar₃₁ is a group represented by any of the formulae (1-a) to (1-f), L₃₁ is a single bond or an unsubstituted arylene group having 6 to 30 ring carbon atoms; and
when Ar₃₂ is a group represented by any of the formulae (1-a) to (1-f), L₃₂ is a single bond or an unsubstituted arylene group having 6 to 30 ring carbon atoms, 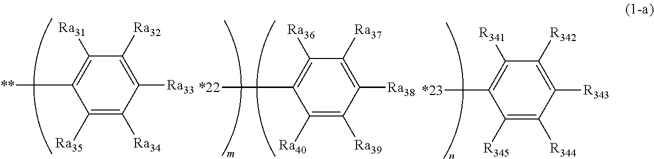
where, in the formula (1-a):
R₃₄₁ to R₃₄₅ are each independently a hydrogen atom, a substituted or unsubstituted alkyl group having 1 to 10 carbon atoms, or a substituted or unsubstituted aryl group having 6 to 12 ring carbon atoms;
adjacent two selected from R₃₄₁ to R₃₄₅ are not mutually bonded and thus form no ring;
one selected from Ra₃₁ to Ra₃₅ is a single bond with *22;
one selected from Ra₃₆ to Ra₄₀ is a single bond with *23;
Ra₃₁ to Ra₄₀ not being the single bond are each independently a hydrogen atom, an unsubstituted alkyl group having 1 to 10 carbon atoms, or an unsubstituted aryl group having 6 to 12 ring carbon atoms;
adjacent two selected from Ra₃₁ to Ra₃₅ not being the single bond are not mutually bonded and thus form no ring;
adjacent two selected from Ra₃₆ to Ra₄₀ not being the single bond are not mutually bonded and thus form no ring;
** represents a bonding position to L₃₁ or L₃₂;
m is 0 or 1, and n is 0 or 1;
when m and n are 0, *23 represents a bonding position to L₃₁ or L₃₂;
when m is 0 and n is 1, *22 represents a bonding position to L₃₁ or L₃₂;
when m is 1 and n is 0, one selected from Ra₃₁ to Ra₃₅ is a single bond with *23;
when L₃₁ is a single bond, **, *22, or *23 of the group represented by the formula (1-a), which is Ar₃₁, represents a bonding position to the central nitrogen atom N*; and
when L₃₂ is a single bond, **, *22, or *23 of the group represented by the formula (1-a), which is Ar₃₂, represents a bonding position to the central nitrogen atom N*, 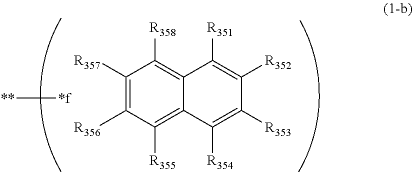
where, in the formula (1-b):
R₃₅₁ to R₃₅₈ are each independently a hydrogen atom, a substituted or unsubstituted alkyl group having 1 to 6 carbon atoms, or a substituted or unsubstituted aryl group having 6 to 12 ring carbon atoms;
one selected from R₃₅₁ to R₃₅₈ is a single bond with *f;
adjacent two selected from R₃₅₁ to R₃₅₈ not being the single bond are not mutually bonded and thus form no cyclic structure;
** represents a bonding position to L₃₁ or L₃₂;
when L₃₁ is a single bond, ** of the group represented by the formula (1-b), which is Ar₃₁, represents a bonding position to the central nitrogen atom N*; and
when L₃₂ is a single bond, ** of the group represented by the formula (1-b), which is Ar₃₂, represents a bonding position to the central nitrogen atom N*, 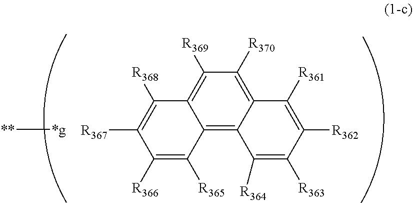
where, in the formula (1-c):
R₃₆₁ to R₃₇₀ are each independently a hydrogen atom, a substituted or unsubstituted alkyl group having 1 to 6 carbon atoms, or a substituted or unsubstituted aryl group having 6 to 12 ring carbon atoms;
one selected from R₃₆₁ to R₃₇₀ is a single bond with *g;
adjacent two selected from R₃₆₁ to R₃₇₀ not being the single bond are not mutually bonded and thus form no cyclic structure;
** represents a bonding position to L₃₁ or L₃₂;
when L₃₁ is a single bond, ** of the group represented by the formula (1-c), which is Ar₃₁, represents a bonding position to the central nitrogen atom N*; and
when L₃₂ is a single bond, ** of the group represented by the formula (1-c), which is Ar₃₂, represents a bonding position to the central nitrogen atom N*, 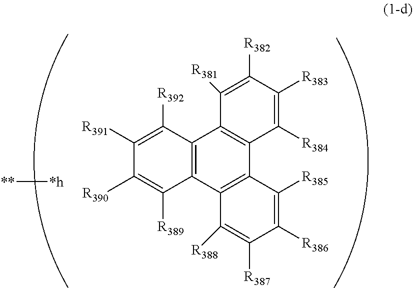
where, in the formula (1-d):
R₃₈₁ to R₃₉₂ are each independently a hydrogen atom, a substituted or unsubstituted alkyl group having 1 to 6 carbon atoms, or a substituted or unsubstituted aryl group having 6 to 12 ring carbon atoms;
one selected from R₃₈₁ to R₃₉₂ is a single bond with *h;
adjacent two selected from R₃₈₁ to R₃₉₂ not being the single bond are not mutually bonded and thus form no cyclic structure;
** represents a bonding position to L₃₁ or L₃₂;
when L₃₁ is a single bond, ** of the group represented by the formula (1-d), which is Ar₃₁, represents a bonding position to the central nitrogen atom N*; and
when L₃₂ is a single bond, ** of the group represented by the formula (1-d), which is Ar₃₂, represents a bonding position to the central nitrogen atom N*, 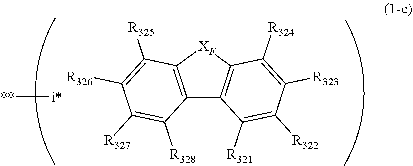
where, in the formula (1-e):
R₃₂₁ to R₃₂₈ are each independently a hydrogen atom, a substituted or unsubstituted alkyl group having 1 to 6 carbon atoms, a substituted or unsubstituted aryl group having 6 to 12 ring carbon atoms, or a substituted or unsubstituted aromatic heterocyclic group having 5 to 13 ring atoms;
X_{F} is an oxygen atom, a sulfur atom, NR_{F1}, or CR_{F2}R_{F3};
R_{F1} is a hydrogen atom, a substituted or unsubstituted alkyl group having 1 to 6 carbon atoms, a substituted or unsubstituted aryl group having 6 to 12 ring carbon atoms, or a substituted or unsubstituted aromatic heterocyclic group having to 13 ring atoms,
R_{F2} and R_{F3} are each independently a hydrogen atom, a substituted or unsubstituted alkyl group having 1 to 50 carbon atoms, or a substituted or unsubstituted aryl group having 6 to 50 ring carbon atoms,
R_{F2} and R_{F3} are mutually bonded to form a substituted or unsubstituted monocyclic ring, mutually bonded to form a substituted or unsubstituted fused ring, or not mutually bonded;
one selected from R₃₂₁ to R₃₂₈, R_{F1}, R_{F2}, and R_{F3} is a single bond with *i;
adjacent two selected from R₃₂₁ to R₃₂₈ not being the single bond are mutually bonded to form a substituted or unsubstituted benzene ring, or not mutually bonded;
** represents a bonding position to L₃₁ or L₃₂;
when L₃₁ is a single bond, ** of the group represented by the formula (1-e), which is Ar₃₁, represents a bonding position to the central nitrogen atom N*; and
when L₃₂ is a single bond, ** of the group represented by the formula (1-e), which is Ar₃₂, represents a bonding position to the central nitrogen atom N*, 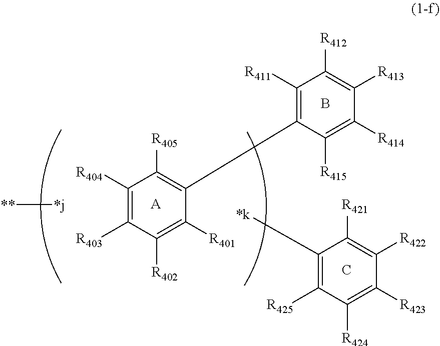
where, in the formula (1-f):
R₄₀₁ to R₄₀₅ are each independently a hydrogen atom, an unsubstituted alkyl group having 1 to 6 carbon atoms, or an unsubstituted phenyl group;
R₄₁₁ to R₄₁₅ and R₄₂₁ to R₄₂₅ are each independently a hydrogen atom or an unsubstituted alkyl group having 1 to 6 carbon atoms;
one selected from R₄₀₁ to R₄₀₅ is a single bond with *j;
any other one selected from R₄₀₁ to R₄₀₅ is a single bond with *k;
adjacent two selected from R₄₀₁ to R₄₀₅ not being the single bond are not mutually bonded and thus form no cyclic structure;
adjacent two selected from R₄₁₁ to R₄₁₅ and R₄₂₁ to R₄₂₅ are mutually bonded to form a substituted or unsubstituted benzene ring, or not mutually bonded;
** represents a bonding position to L₃₁ or L₃₂;
when L₃₁ is a single bond, ** of the group represented by the formula (1-f), which is Ar₃₁, represents a bonding position to the central nitrogen atom N*; and
when L₃₂ is a single bond, ** of the group represented by the formula (1-f), which is Ar₃₂, represents a bonding position to the central nitrogen atom N*.

15. The organic electroluminescence device according to claim 1, wherein L₃₁ and L₃₂ are each independently a single bond or a substituted or unsubstituted phenylene group.

16. The organic electroluminescence device according to claim 1, wherein the first host material is a compound represented by a formula (11) below, and the second host material is a compound represented by a formula (12) below, 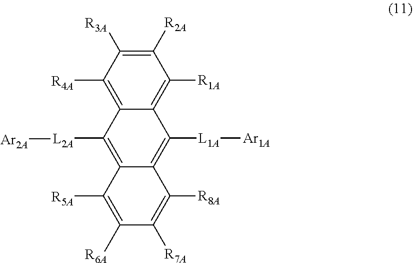
where, in the formula (11):
R_{1A} to R_{8A} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (11A) below; and
when two or more groups represented by the formula (11A) are present, the two or more groups represented by the formula (11A) are mutually the same or different,
*-L_{3A}-Ar_{3A} (11A)
L_{1A} and L_{2A} in the formula (11) and L_{3A} in the formula (11A) are each independently a single bond, a substituted or unsubstituted arylene group having 6 to 50 ring carbon atoms, or a substituted or unsubstituted divalent heterocyclic group having 5 to 50 ring atoms;
Ar_{1A} and Ar_{2A} in the formula (11) and Ar_{3A} in the formula (11A) are each independently a substituted or unsubstituted aryl group having 6 to 50 ring carbon atoms, or a substituted or unsubstituted heterocyclic group having 5 to 50 ring atoms; and
* in the formula (11A) represents a bonding position to an anthracene ring represented by the formula (11), 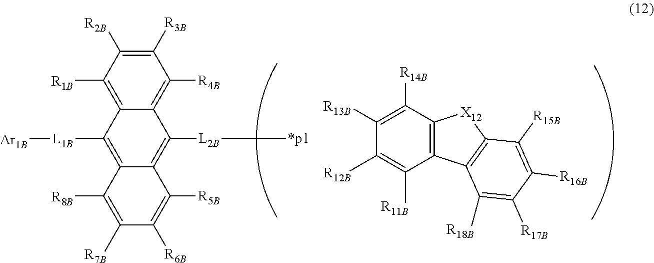
where, in the formula (12):
R_{1B} to R_{8B} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X₁₂ is an oxygen atom or a sulfur atom;
one of R_{11B} to R_{18B} is a single bond with *p1;
at least one combination of adjacent two or more of R_{11B} to R_{18B} not being the single bond with *p1 are mutually bonded to form a substituted or unsubstituted monocyclic ring, mutually bonded to form a substituted or unsubstituted fused ring, or not mutually bonded;
R_{11B} to R_{18B} not being the single bond with *p1, not forming the substituted or unsubstituted monocyclic ring, and not forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
L_{1B} and L_{2B} are each independently a single bond, a substituted or unsubstituted arylene group having 6 to 30 ring carbon atoms, or a substituted or unsubstituted divalent heterocyclic group having 5 to 30 ring atoms; and
Ar_{1B} is a substituted or unsubstituted aryl group having 6 to 50 ring carbon atoms, or a substituted or unsubstituted heterocyclic group having 5 to 50 ring atoms.

17. The organic electroluminescence device according to claim 16, wherein the compound represented by the formula (12) is a compound represented by a formula (121), (122), (123), or (124) below, 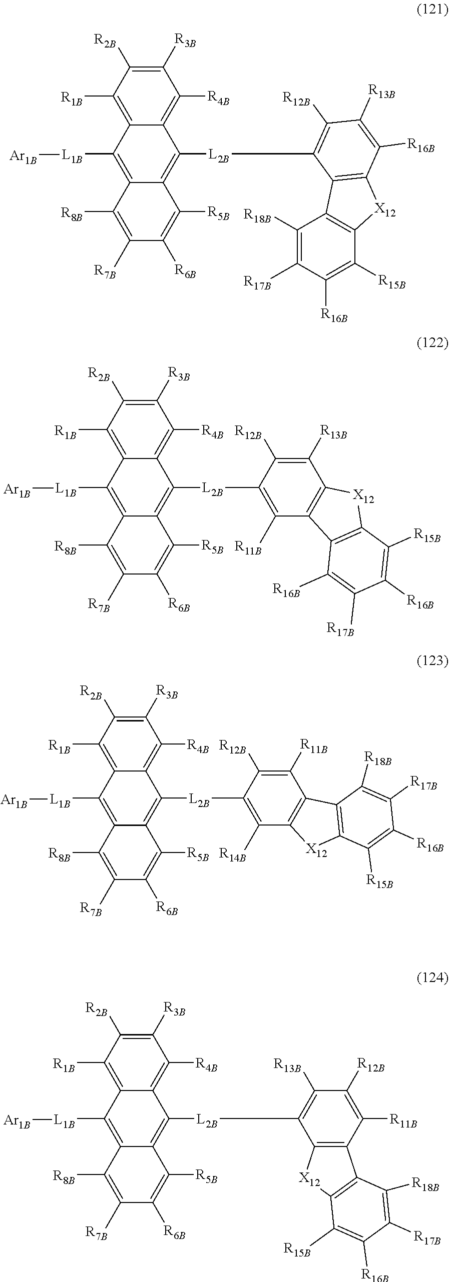
where, in the formulae (121) to (124), R_{1B} to R_{8B}, R_{11B} to R_{14B}, L_{1B}, L_{2B}, Ar_{1B}, and X₁₂ respectively represent the same as those defined in the formula (12).

18. The organic electroluminescence device according to claim 16, wherein at least one combination of adjacent two or more of R_{11B} to R_{18B} not being the single bond with *p1 are mutually bonded to form a substituted or unsubstituted monocyclic ring, or mutually bonded to form a substituted or unsubstituted fused ring.

19. The organic electroluminescence device according to claim 17, wherein none of combinations of adjacent two or more of R_{11B} to R_{14B} not being the single bond with *p1 are bonded to each other, and at least one combination of adjacent two or more of R_{15B} to R_{18B} not being the single bond with *p1 are mutually bonded to form a substituted or unsubstituted monocyclic ring, or mutually bonded to form a substituted or unsubstituted fused ring.

20. The organic electroluminescence device according to claim 16, wherein none of combinations of adjacent two or more of R_{11B} to R_{18B} not being the single bond with *p1 are bonded to each other.

21. The organic electroluminescence device according to claim 16, wherein L_{1B} and L_{2B} are each independently a single bond or a substituted or unsubstituted arylene group having 6 to 14 ring carbon atoms.

22. The organic electroluminescence device according to claim 16, wherein L_{1B} and L_{2B} are each independently a single bond, a substituted or unsubstituted phenylene group, or a substituted or unsubstituted naphthylene group.

23. The organic electroluminescence device according to claim 16, wherein Ar_{1B} is a substituted or unsubstituted aryl group having 6 to 50 ring carbon atoms.

24. The organic electroluminescence device according to claim 16, wherein Ar_{1B} is a group represented by a formula (12a), (12b), (12c), or (12d) below, 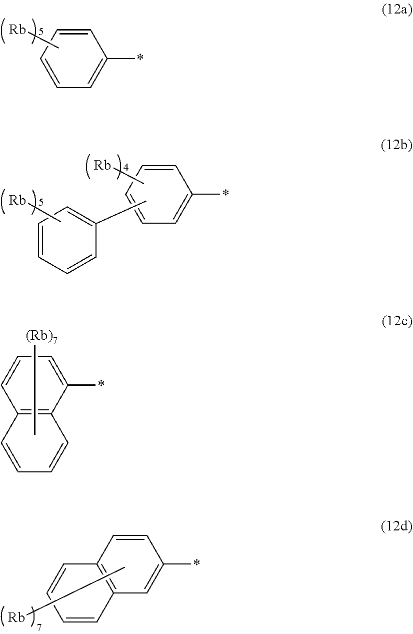
where, in the formulae (12a), (12b), (12c), and (12d):
at least one combination of adjacent two or more of a plurality of Rb are mutually bonded to form a substituted or unsubstituted monocyclic ring, mutually bonded to form a substituted or unsubstituted fused ring, or not mutually bonded,
Rb forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of Rb are mutually the same or different; and
* is a single bond with L_{1B}.

25. The organic electroluminescence device according to claim 16, wherein X₁₂ is an oxygen atom.

26. The organic electroluminescence device according to claim 16, wherein the compound represented by the formula (12) is a compound represented by a formula (125), (126), (127), (128), or (129) below, 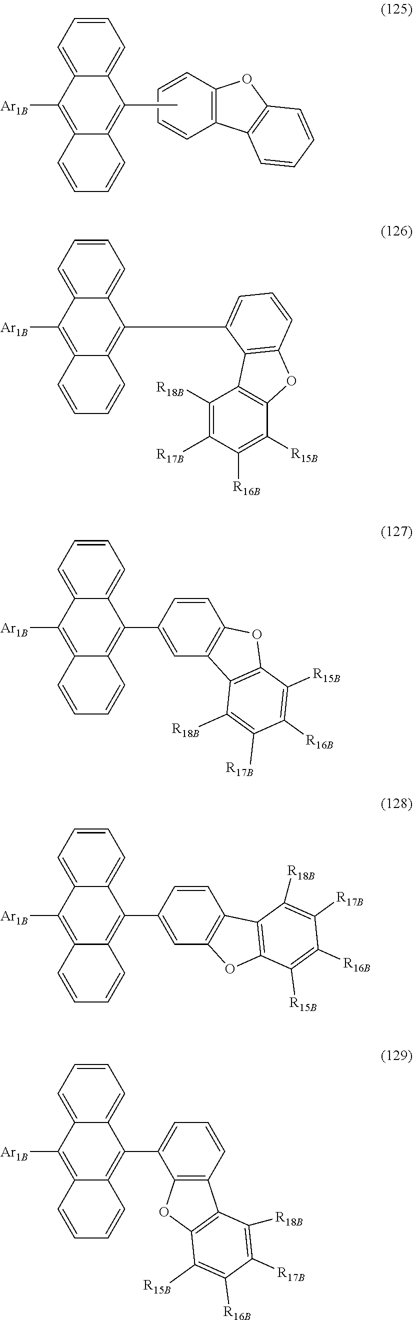
where, in the formulae (125) to (129), R_{15B} to R_{18B} and Ar_{1B} respectively represent the same as those defined in the formula (12).

27. The organic electroluminescence device according to claim 16, wherein the compound represented by the formula (11) is a compound represented by a formula (111) below, 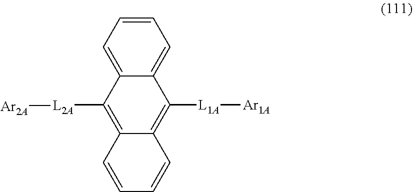
where, in the formula (111), L_{1A}, L_{2A}, Ar_{1A}, and Ar_{2A} respectively represent the same as those defined in the formula (11).

28. The organic electroluminescence device according to claim 16, wherein the compound represented by the formula (11) is a compound represented by a formula (112) below, 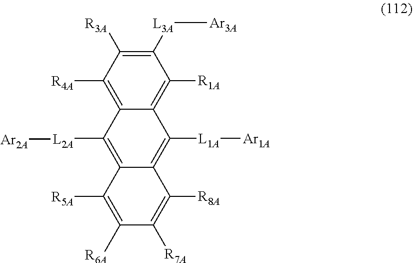
where, in the formula (112), R_{1A}, R_{3A} to R_{8A}, L_{1A}, L_{2A}, L_{3A}, Ar_{1A}, Ar_{2A}, and Ar_{3A} respectively represent the same as those defined in the formula (11) or (11A).

29. The organic electroluminescence device according to claim 16, wherein the compound represented by the formula (11) is a compound represented by a formula (113), (114), or (115) below, 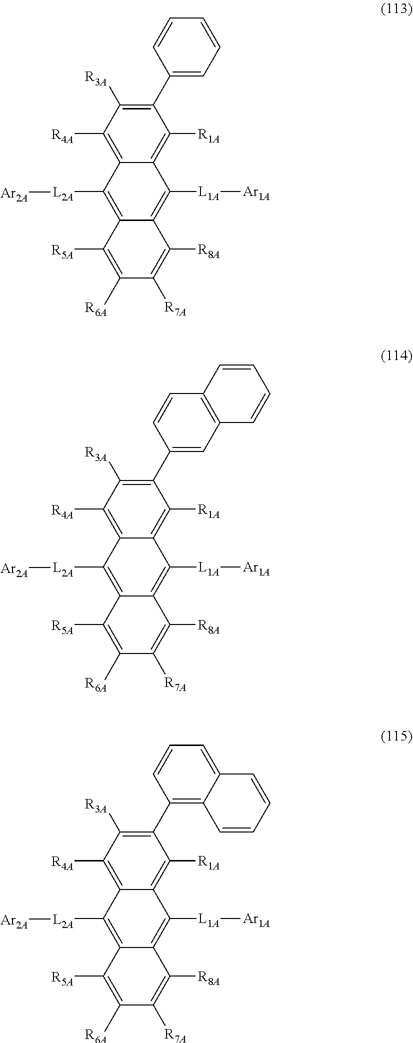
where, in the formulae (113), (114), and (115), R_{1A}, R_{3A} to R_{8A}, L_{1A}, L_{2A}, Ar_{1A}, and Ar_{2A} respectively represent the same as those defined in the formula (11).

30. The organic electroluminescence device according to claim 16, wherein the compound represented by the formula (11) is a compound represented by a formula (116) below, 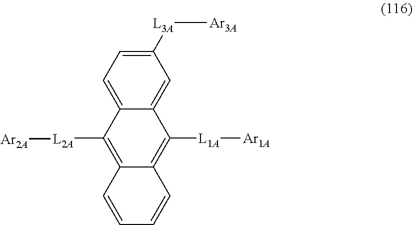
where, in the formula (116), L_{1A}, L_{2A}, L_{3A}, Ar_{1A}, Ar_{2A}, and Ar_{3A} respectively represent the same as those defined in the formula (11) or (11A).

31. The organic electroluminescence device according to claim 30, wherein the compound represented by the formula (11) is a compound represented by a formula (116A), (116B), or (116C) below, 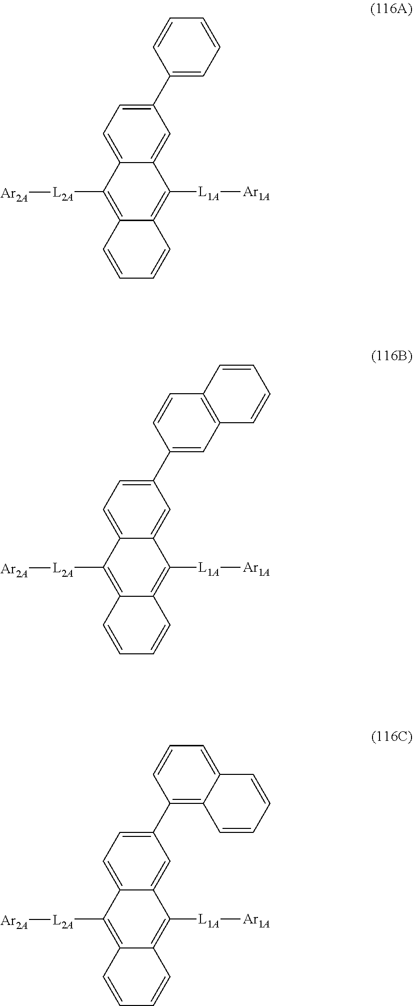
where, in the formulae (116A), (116B), and (116C), L_{1A}, L_{2A}, Ar_{1A}, and Ar_{2A} respectively represent the same as those defined in the formula (11).

32. The organic electroluminescence device according to claim 16, wherein L_{1A}, L_{2A}, and L_{3A} are each independently a single bond or a substituted or unsubstituted arylene group having 6 to 14 ring carbon atoms.

33. The organic electroluminescence device according to claim 16, wherein L_{1A}, L_{2A}, and L_{3A} are each independently a single bond, a substituted or unsubstituted phenylene group, or a substituted or unsubstituted naphthylene group.

34. The organic electroluminescence device according to claim 16, wherein Ar_{1A}, Ar_{2A}, and Ar_{3A} are each independently a substituted or unsubstituted aryl group having 6 to 50 ring carbon atoms.

35. The organic electroluminescence device according to claim 16, wherein Ar_{1A}, Ar_{2A}, and Ar_{3A} are each independently a group represented by a formula (11a), (11b), (11c), or (11d) below, 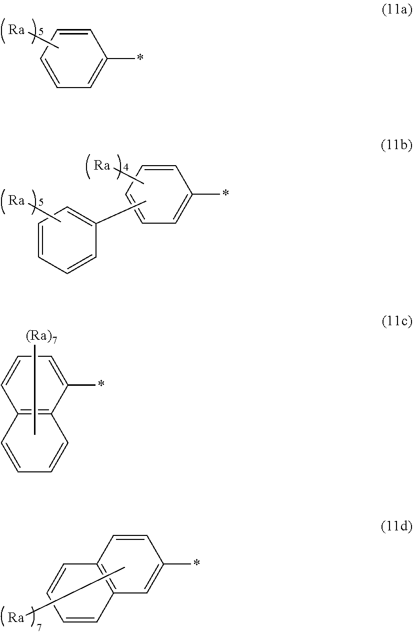
where, in the formulae (11a), (11 b), (11c), and (11d):
at least one combination of adjacent two or more of a plurality of Ra are mutually bonded to form a substituted or unsubstituted monocyclic ring, mutually bonded to form a substituted or unsubstituted fused ring, or not mutually bonded;
Ra forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of Ra are mutually the same or different; and
* is a single bond with L_{1A}, L_{2A}, or L_{3A}.

36. The organic electroluminescence device according to claim 1, wherein at least one of the first host material, the second host material, or the third compound comprises at least one deuterium atom in a molecule.

37. The organic electroluminescence device according to claim 1, wherein the emitting compound is a compound that emits light having a maximum peak wavelength of 500 nm or less.

38. The organic electroluminescence device according to claim 1, wherein the at least one emitting layer in the emitting zone is a single emitting layer.

39. An electronic device comprising the organic electroluminescence device according to claim 1.
